(19) United States
(12) Patent Application Publication
(10) Pub. No.: US 2023/0080974 A1
(43) Pub. Date: Mar. 16, 2023

(54) COMPOSITION FOR ORGANIC ELECTRONIC DEVICES

(71) Applicant: Merck Patent GmbH, Darmstadt (DE)

(72) Inventors: Amir PARHAM, Frankfurt am Main (DE); Jonas KROEBER, Frankfurt am Main (DE); Jens ENGELHART, Darmstadt (DE); Christian EHRENREICH, Darmstadt (DE); Christian EICKHOFF, Mannheim (DE)

(21) Appl. No.: 17/431,919

(22) PCT Filed: Dec. 20, 2019
(86) PCT No.: PCT/EP2019/086652

§ 371 Date: Aug. 18, 2021

(30) Foreign Application Priority Data
Feb. 18, 2019 (EP) 19157813.7

(51) Int. Cl. H01L 51/00

(52) U.S. Cl. CPC H01L 51/0072; H01L 51/0067; H01L 51/0073; H01L 51/5016; H01L 51/0061; H01L 51/006; H01L 51/0074

(57) ABSTRACT

The present invention relates to a composition comprising an electron-transporting host and a hole-transporting host, to the use thereof in electronic devices and electronic devices comprising said composition. The electron-transporting host is more preferably selected from the class of the triazine-dibenzofuran-carbazole systems or the class of the triazine-dibenzothiophene-carbazole systems. The hole-transporting host is preferably selected from the class of biscarbazoles.

The present invention relates to a composition comprising an electron-transporting host and a hole-transporting host, to the use thereof in electronic devices and electronic devices comprising said composition. The electron-transporting host is more preferably selected from the class of the triazine-dibenzofuran-carbazole systems or the class of the triazine-dibenzothiophene-carbazole systems. The hole-transporting host is preferably selected from the class of biscarbazoles.

The structure of organic electroluminescent devices (e.g. OLEDs—organic light-emitting diodes or OLECs—organic light-emitting electrochemical cells) in which organic semiconductors are used as functional materials has long been known. Emitting materials used here, aside from fluorescent emitters, are increasingly organometallic complexes which exhibit phosphorescence rather than fluorescence. For quantum-mechanical reasons, up to a fourfold increase in energy efficiency and power efficiency is possible using organometallic compounds as phosphorescent emitters. In general terms, however, there is still a need for improvement in OLEDs, especially also in OLEDs which exhibit triplet emission (phosphorescence), for example with regard to efficiency, operating voltage and lifetime.

The properties of organic electroluminescent devices are not only determined by the emitters used. Also of particular significance here are especially the other materials used, such as host and matrix materials, hole blocker materials, electron transport materials, hole transport materials and electron or exciton blocker materials, and among these especially the host or matrix materials. Improvements to these materials can lead to distinct improvements to electroluminescent devices.

Host materials for use in organic electronic devices are well known to the person skilled in the art. The term “matrix material” is also frequently used in the prior art when what is meant is a host material for phosphorescent emitters. This use of the term is also applicable to the present invention. In the meantime, a multitude of host materials has been developed both for fluorescent and for phosphorescent electronic devices.

A further means of improving the performance data of electronic devices, especially of organic electroluminescent devices, is to use combinations of two or more materials, especially host materials or matrix materials.

U.S. Pat. No. 6,392,250 B1 discloses the use of a mixture consisting of an electron transport material, a hole transport material and a fluorescent emitter in the emission layer of an OLED. With the aid of this mixture, it was possible to improve the lifetime of the OLED compared to the prior art.

U.S. Pat. No. 6,803,720 B1 discloses the use of a mixture comprising a phosphorescent emitter and a hole transport material and an electron transport material in the emission layer of an OLED. Both the hole transport material and the electron transport material are small organic molecules.

According to WO 2015/169412, it is likewise possible to use triazine-dibenzofuran-carbazole derivatives and triazine-dibenzothiophene-carbazole derivatives, for example, in a mixture. According to the description, the carbazole derivative is not bound to the dibenzofuran or dibenzothiophene base skeleton via the nitrogen atom of the carbazole. For example, the production of the OLED designated E34 is described, which contains, in the light-emitting layer, the host materials EG1, IC6 and the phosphorescent emitter TEG1. The structures of the compounds used are shown below:

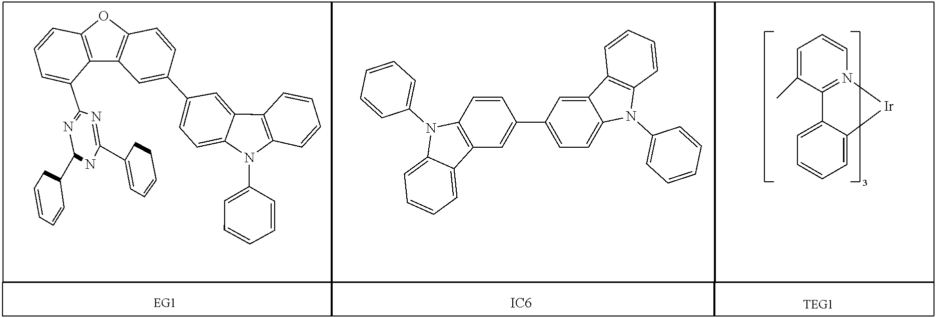

According to WO 2015/165563, it is likewise possible to use triazine-dibenzofuran-carbazole derivatives and triazine-dibenzothiophene-carbazole derivatives, for example, in a mixture. Carbazole derivative is also understood to mean compounds such as indenocarbazole and indolocarbazole. According to the description, the carbazole derivative is not bound to the dibenzofuran or dibenzothiophene base skeleton via the nitrogen atom of the carbazole at position 8 of the dibenzofuran/dibenzothiophene. The triazine substituent is bonded directly or via a linker in the 4 position of the dibenzofuran/dibenzothiophene. For example, the production of the OLED designated E9 is described, which contains, in the light-emitting layer, the host materials EG9, IC3 and the phosphorescent emitter TEG1. The structures of the compounds EG9 and IC3 used are shown below:

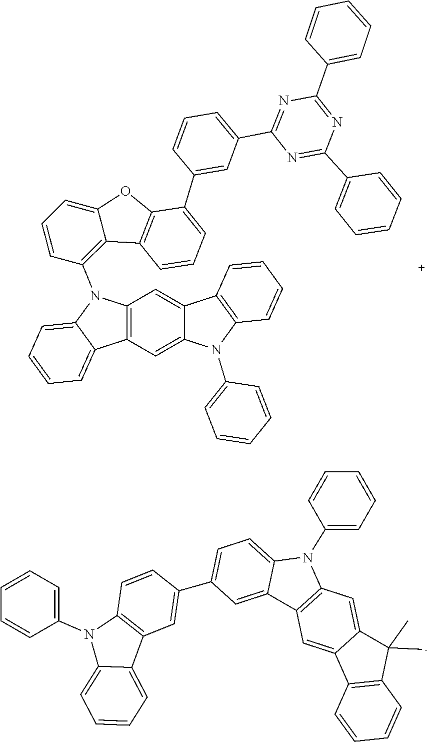 [SMILES: c1ccc(-c2nc(-c3ccccc3)nc(-c3cccc(-c4cccc5c4oc4cccc(-n6c7ccccc7c7cc8c(cc76)c6ccccc6n8-c6ccccc6)c45)c3)n2)cc1 ; CC1(C)c2ccccc2-c2cc3c4cc(-c5ccc6c(c5)c5ccccc5n6-c5ccccc5)ccc4n(-c4ccccc4)c3cc21]

According to WO 2015/014435, it is possible to use triazine-dibenzofuran-carbazole derivatives and triazine-dibenzothiophene-carbazole derivatives, for example, in a light-emitting layer as host material.

CN107973786 likewise describes triazine-dibenzofuran-carbazole and triazine-dibenzothiophene-carbazole compounds. The triazine substituent is bonded directly or via a linker in the 1 position of the dibenzofuran/dibenzothiophene. The carbazole derivative is bonded directly or via a linker in the 6 position of the dibenzofuran/dibenzothiophene. It is further reported that these materials can be mixed with a biscarbazole H2 in a ratio of 10:90 to 90:10.

KR20160046077 describes specific triazine-dibenzofuran-carbazole and triazine-dibenzothiophene-carbazole derivatives in a light-emitting layer together with a further host material.

US20160293853 describes specific dibenzofuran derivatives that can be used in combination with further host materials.

U.S. Pat. No. 9,771,373 describes an organic light-emitting device having a light-emitting layer containing two host materials, wherein the host materials are each selected from specific groups of compounds.

WO 2016/015810 describes triazine-dibenzofuran-carbazole and triazine-dibenzothiophene-carbazole compounds, wherein the triazine substituent is bonded directly or via a linker in the 1 position of the dibenzofuran/dibenzothiophene, and wherein the carbazole substituent is bonded via its nitrogen atom in 8 position of the dibenzofuran/dibenzothiophene. According to the description, the compounds mentioned may be used in a mixture with a further matrix material.

KR2018010149 describes similar compounds to those described in in WO 2016/015810.

Publications WO 2018/174678 and WO 2018/174679 disclose devices containing, in an organic layer, a mixture of carbazole-dibenzofuran derivatives with biscarbazoles, where the linkage of the carbazole unit to the dibenzofuran skeleton is possible at any position in the dibenzofuran, but preferably in the 6 or 7 position.

Publication EP3415512 describes, inter alia, dibenzofuran derivatives of the formula 1-1, wherein a phenyl, pyridine, pyrimidine or triazine substituent may be attached directly or via a linker in position 1 of the dibenzofuran, and wherein at least two identical L₂-Ar₃ substituents may be attached in 6 and 8 position of the dibenzofuran. Ar₃ here may be a carbazole bonded via N. In the examples, such compounds are used in combination with a specific biscarbazole.

However, there is still need for improvement in the case of use of these materials or in the case of use of mixtures of the materials, especially in relation to efficiency, operating voltage and/or lifetime of the organic electronic device.

The problem addressed by the present invention was therefore that of providing materials which are suitable for use in an organic electronic device, especially in an organic electroluminescent device, and especially in a phosphorescent OLED, and lead to good device properties, especially with regard to improved power efficiency, improved operating voltage and/or improved lifetime, and that of providing the corresponding electronic device.

It has now been found that this problem is solved and the disadvantages from the prior art are eliminated by compositions containing compounds of the formula (1) and comprising a hole-transporting host of the formula (2), and by organic electronic devices containing said composition. Such compositions lead to very good properties of organic electronic devices, especially organic electroluminescent devices, especially with regard to power efficiency, operating voltage and/or lifetime, and especially also in the presence of a light-emitting component in the emission layer, especially in combination with emitters of the formula (3), at concentrations between 2% and 25% by weight. The devices of the invention especially show very good power efficiency.

The present invention therefore firstly provides a composition comprising at least one compound of the formula (1) and at least one compound of the formula (2)

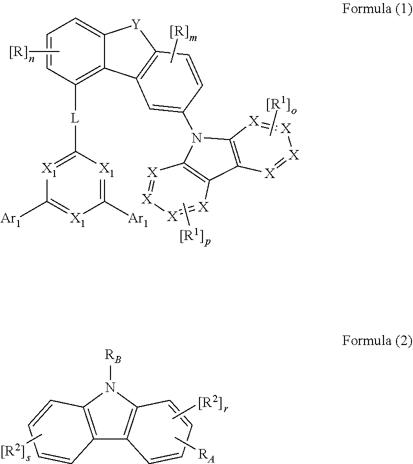

where the symbols and indices used are as follows:
X₁ is the same or different at each instance and is CR⁰ or N, with the proviso that at least one X₁ group is N;
X is the same or different at each instance and is C or N, where two adjacent X may be bonded to a ring system of the formula A,

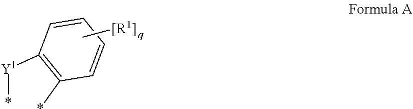

where * at each instance is the bonding site to an X,
Y¹ is selected from NAr₁, C(R*)₂, O and S;
Y is selected from O and S;
L is the same or different at each instance and is a single bond or an aromatic ring system which has 6 to 30 aromatic ring atoms and may be substituted by one or more R⁵ radicals;
n and m at each instance are independently 0, 1, 2 or 3,
o, p and q at each instance are independently 0, 1, 2, 3 or 4;
Ar₁ at each instance is independently an aryl or heteroaryl group which has 5 to 40 aromatic ring atoms and may be substituted by one or more R³ radicals;
R_{A} is H, -L₃-Ar₄ or -L₁-N(Ar)₂;
R_{B} is Ar₃ or -L₂-N(Ar)₂;
L₁, L₂ are the same or different at each instance and are a single bond or an aromatic or heteroaromatic ring system which has 5 to 30 aromatic ring atoms and may be substituted by one or more R³ radicals;
L₃ is a single bond or an aromatic or heteroaromatic ring system which has 5 to 30 aromatic ring atoms and may be substituted by one or more R³ radicals, where one substituent R³ may form a ring with a substituent R² on the carbazole;
Ar₃ is an aromatic ring system having 6 to 40 aromatic ring atoms or a heteroaromatic ring system having 10 to 40 aromatic ring atoms, which may be substituted by one or more R³ radicals;
Ar₄ is the same or different at each instance and is an unsubstituted or substituted 9-arylcarbazolyl or unsubstituted or substituted carbazol-9-yl, which may be substituted by one or more R⁴ radicals, and where one or more instances each of two R⁴ radicals or one R⁴ radical together with one R² radical may independently form a monocyclic or polycyclic, aliphatic, aromatic or heteroaromatic ring, where aryl is an aromatic or heteroaromatic ring system which has 5 to 30 aromatic ring atoms and may be substituted by R³;
R* is the same or different at each instance and is a straight-chain alkyl group having 1 to 10 carbon atoms or an aryl group having 6 to 12 carbon atoms, where two substituents R* together may form a monocyclic or polycyclic, aliphatic, aromatic or heteroaromatic ring system which may be substituted by one or more substituents R⁵;
R⁰, R, R¹, R² are the same or different at each instance and are selected from the group consisting of H, D, F, Cl, Br, I, CN, NO₂, N(Ar)₂, N(R³)₂, C(═O)Ar, C(═O)R³, P(═O)(Ar)₂, P(Ar)₂, B(Ar)₂, Si(Ar)₃, Si(R³)₃, a straight-chain alkyl, alkoxy or thioalkyl group having 1 to 20 carbon atoms or a branched or cyclic alkyl, alkoxy or thioalkyl group having 3 to 20 carbon atoms or an alkenyl group having 2 to 20 carbon atoms, each of which may be substituted by one or more R³ radicals, where one or more nonadjacent CH₂ groups may be replaced by R³C═CR³, Si(R³)₂, C═O, C═S, C═NR³, P(═O)(R³), SO, SO₂, NR³, O, S or CONR³ and where one or more hydrogen atoms may be replaced by D, F, Cl, Br, I, CN or NO₂, an aromatic or heteroaromatic ring system which has 5 to 40 aromatic ring atoms and may be substituted in each case by one or more R³ radicals, an aryloxy or heteroaryloxy group which has 5 to 40 aromatic ring atoms and may be substituted by one or more R³ radicals, or an aralkyl or heteroaralkyl group which has 5 to 40 aromatic ring atoms and may be substituted by one or more R³ radicals; at the same time, it is optionally possible for two substituents R⁰ and/or R and/or R¹ and/or R² bonded to the same carbon atom or to adjacent carbon atoms to form a monocyclic or polycyclic, aliphatic, aromatic or heteroaromatic ring system which may be substituted by one or more R³ radicals;
R³ is the same or different at each instance and is selected from the group consisting of H, D, F, CN, N(Ar)₂, an aliphatic hydrocarbyl radical having 1 to 20 carbon atoms, or an aromatic or heteroaromatic ring system having 5 to 30 aromatic ring atoms in which one or more hydrogen atoms may be replaced by D, F, Cl, Br, I or CN and which may be substituted by one or more alkyl groups each having 1 to 4 carbon atoms; at the same time, it is possible for two or more adjacent R³ substituents together to form a mono- or polycyclic, aliphatic ring system;
R⁴ is the same or different at each instance and is selected from the group consisting of H, D, F, CN, an aliphatic hydrocarbyl radical having 1 to 20 carbon atoms, or an aromatic or heteroaromatic ring system having 5 to 30 aromatic ring atoms in which one or more hydrogen atoms may be replaced by D, F, Cl, Br, I, a straight-chain or branched alkyl group having 1 to 4 carbon atoms or CN; at the same time, two or more adjacent R⁴ substituents together may form a mono- or polycyclic ring system;
R⁵ is the same or different at each instance and is selected from the group consisting of D, F, CN and an aryl group having 6 to 18 carbon atoms; at the same time, two or more adjacent substituents R⁵ together may form a mono- or polycyclic, aliphatic ring system;
Ar is the same or different at each instance and is an aromatic or heteroaromatic ring system which has 5 to 30 aromatic ring atoms and may be substituted by one or more nonaromatic R³ radicals; at the same time, two Ar radicals bonded to the same nitrogen atom, phosphorus atom or boron atom may also be bridged to one another by a single bond or a bridge selected from N(R³), C(R³)₂, O and S, and
   r at each instance is independently 0, 1, 2 or 3;
   s at each instance is independently 0, 1, 2, 3 or 4.

The invention further provides specific material combinations, formulations comprising compositions of this kind, for the use of these compositions in an organic electronic device, organic electronic devices, preferably electroluminescent devices, comprising compositions of this kind and preferably comprising the composition in one layer, and processes for producing devices of this kind. The corresponding preferred embodiments as described hereinafter likewise form part of the subject-matter of the present invention. The surprising and advantageous effects are achieved through specific selection of known materials, especially with regard to the selection of the compounds of the formula (1).

The layer comprising the composition comprising at least one compound of the formula (1) and at least one compound of the formula (2) as described above or described as preferred hereinafter is especially a light-emitting layer (EML), an electron transport layer (ETL), an electron injection layer (EIL) and/or a hole blocker layer (HBL).

When the layer is a light-emitting layer, it is preferably a phosphorescent layer which is characterized in that it comprises, in addition to the composition comprising the matrix materials of the formula (1) and formula (2) as described above, a phosphorescent emitter.

Adjacent carbon atoms in the context of the present invention are carbon atoms bonded directly to one another.

The wording that two or more radicals together may form a ring, in the context of the present description, should be understood to mean, inter alia, that the two radicals are joined to one another by a chemical bond with formal elimination of two hydrogen atoms. This is illustrated by the following scheme:

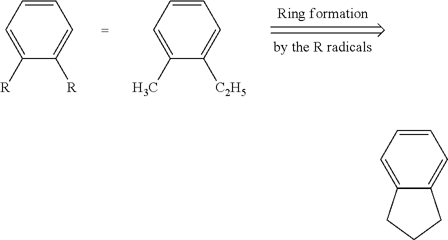

In addition, however, the abovementioned wording should also be understood to mean that, if one of the two radicals is hydrogen, the second radical binds to the position to which the hydrogen atom was bonded, forming a ring. This shall be illustrated by the following scheme:

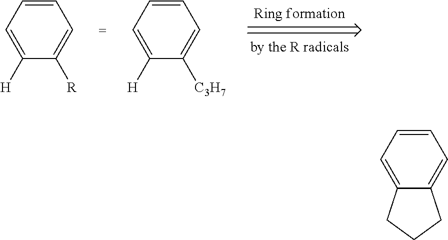

An aryl group in the context of this invention contains 6 to 40 aromatic ring atoms, preferably carbon atoms. A heteroaryl group in the context of this invention contains 5 to 40 aromatic ring atoms, where the ring atoms include carbon atoms and at least one heteroatom, with the proviso that the sum total of carbon atoms and heteroatoms adds up to at least 5. The heteroatoms are preferably selected from N, O and/or S. An aryl group or heteroaryl group is understood here to mean either a simple aromatic cycle, i.e. phenyl, derived from benzene, or a simple heteroaromatic cycle, for example derived from pyridine, pyrimidine or thiophene, or a fused aryl or heteroaryl group, for example derived from naphthalene, anthracene, phenanthrene, quinoline or isoquinoline. An aryl group having 6 to 18 carbon atoms is therefore preferably phenyl, naphthyl, phenanthryl or triphenylenyl, with no restriction in the attachment of the aryl group as substituent. An arylene group having 6 to 18 carbon atoms is therefore preferably phenylene, naphthylene, phenanthrylene or triphenylenylene, with no restriction in the linkage of the arylene group as linker.

An aromatic ring system in the context of this invention contains 6 to 40 carbon atoms in the ring system and may be substituted by one or more R³ radicals, where R³ has a definition described below. An aromatic ring system also contains aryl groups as described above.

An aromatic ring system having 6 to 18 carbon atoms is preferably selected from phenylene, biphenylene, naphthylene, phenanthrenylene and triphenylenylene, where the respective aromatic ring system may be substituted by one or more R⁵ radicals.

A heteroaromatic ring system in the context of this invention contains 5 to 40 ring atoms and at least one heteroatom and may be substituted by one or more R³ radicals, where R³ has a definition described below. A preferred heteroaromatic ring system has 10 to 40 ring atoms and at least one heteroatom and may be substituted by one or more R³ radicals, where R³ has a definition described below. A heteroaromatic ring system also contains heteroaryl groups as described above. The heteroatoms in the heteroaromatic ring system are preferably selected from N, O and/or S. An aromatic or heteroaromatic ring system in the context of this invention is understood to mean a system which does not necessarily contain only aryl or heteroaryl groups, but in which it is also possible for a plurality of aryl or heteroaryl groups to be interrupted by a nonaromatic unit (preferably less than 10% of the atoms other than H), for example a carbon, nitrogen or oxygen atom or a carbonyl group. For example, systems such as 9,9′-spirobifluorene, 9,9-diarylfluorene, triarylamine, diaryl ethers, stilbene, etc. shall thus also be regarded as aromatic or heteroaromatic ring systems in the context of this invention, and likewise systems in which two or more aryl groups are interrupted, for example, by a linear or cyclic alkyl group or by a silyl group. In addition, systems in which two or more aryl or heteroaryl groups are bonded directly to one another, for example biphenyl, terphenyl, quaterphenyl or bipyridine, are likewise encompassed by the definition of the aromatic or heteroaromatic ring system.

An aromatic or heteroaromatic ring system which has 5-40 aromatic ring atoms and may also be substituted in each case by the abovementioned R³ radicals and which may be joined to the aromatic or heteroaromatic system via any desired positions is understood to mean, for example, groups derived from benzene, naphthalene, anthracene, benzanthracene, phenanthrene, benzophenanthrene, pyrene, chrysene, perylene, fluoranthene, benzofluoranthene, naphthacene, pentacene, benzopyrene, biphenyl, biphenylene, terphenyl, terphenylene, fluorene, spirobifluorene, dihydrophenanthrene, dihydropyrene, tetrahydropyrene, cis- or trans-indenofluorene, cis- or trans-monobenzoindenofluorene, cis- or trans-dibenzoindenofluorene, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, indolocarbazole, indenocarbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubine, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

The abbreviation Ar is the same or different at each instance and is an aromatic or heteroaromatic ring system which has 5 to 30 aromatic ring atoms and may be substituted by one or more nonaromatic R³ radicals; at the same time, two Ar radicals bonded to the same nitrogen atom, phosphorus atom or boron atom may also be bridged to one another by a single bond or a bridge selected from N(R³), C(R³)₂, O and S. The substituent R³ has been described above or is described with preference hereinafter.

A cyclic alkyl, alkoxy or thioalkyl group in the context of this invention is understood to mean a monocyclic, bicyclic or polycyclic group.

In the context of the present invention, a C₁- to C₂₀-alkyl group in which individual hydrogen atoms or CH₂ groups may also be substituted by the abovementioned groups is understood to mean, for example, the methyl, ethyl, n-propyl, i-propyl, cyclopropyl, n-butyl, i-butyl, s-butyl, t-butyl, cyclobutyl, 2-methylbutyl, n-pentyl, s-pentyl, t-pentyl, 2-pentyl, neopentyl, cyclopentyl, n-hexyl, s-hexyl, t-hexyl, 2-hexyl, 3-hexyl, neohexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2.2.2]octyl, 2-bicyclo[2.2.2]octyl, 2-(2,6-dimethyl)octyl, 3-(3,7-dimethyl)octyl, adamantyl, trifluoromethyl, pentafluoroethyl, 2,2,2-trifluoroethyl, 1,1-dimethyl-n-hex-1-yl, 1,1-dimethyl-n-hept-1-yl, 1,1-dimethyl-n-oct-1-yl, 1,1-dimethyl-n-dec-1-yl, 1,1-dimethyl-n-dodec-1-yl, 1,1-dimethyl-n-tetradec-1-yl, 1,1-dimethyl-n-hexadec-1-yl, 1,1-dimethyl-n-octadec-1-yl, 1,1-diethyl-n-hex-1-yl, 1,1-diethyl-n-hept-1-yl, 1,1-diethyl-n-oct-1-yl, 1,1-diethyl-n-dec-1-yl, 1,1-diethyl-n-dodec-1-yl, 1,1-diethyl-n-tetradec-1-yl, 1,1-diethyl-n-hexadec-1-yl, 1,1-diethyl-n-octadec-1-yl, 1-(n-propyl)cyclohex-1-yl, 1-(n-butyl)cyclohex-1-yl, 1-(n-hexyl)cyclohex-1-yl, 1-(n-octyl)cyclohex-1-yl and 1-(n-decyl)cyclohex-1-yl radicals.

An alkenyl group is understood to mean, for example, ethenyl, propenyl, butenyl, pentenyl, cyclopentenyl, hexenyl, cyclohexenyl, heptenyl, cycloheptenyl, octenyl, cyclooctenyl or cyclooctadienyl.

An alkynyl group is understood to mean, for example, ethynyl, propynyl, butynyl, pentynyl, hexynyl, heptynyl or octynyl.

A C₁- to C₂₀-alkoxy group is understood to mean, for example, methoxy, trifluoromethoxy, ethoxy, n-propoxy, i-propoxy, n-butoxy, i-butoxy, s-butoxy, t-butoxy or 2-methylbutoxy.

A C₁- to C₂₀-thioalkyl group is understood to mean, for example S-alkyl groups, for example thiomethyl, 1-thioethyl, 1-thio-i-propyl, 1-thio-n-propyl, 1-thio-i-butyl, 1-thio-n-butyl or 1-thio-t-butyl.

An aryloxy or heteroaryloxy group having 5 to 40 aromatic ring atoms means O-aryl or O-heteroaryl and means that the aryl or heteroaryl group is bonded via an oxygen atom.

An aralkyl or heteroaralkyl group having 5 to 40 aromatic ring atoms means that an alkyl group as described above is substituted by an aryl group or heteroaryl group.

A phosphorescent emitter in the context of the present invention is a compound that exhibits luminescence from an excited state with higher spin multiplicity, i.e. a spin state >1, especially from an excited triplet state. In the context of this application, all luminescent complexes with transition metals or lanthanides are to be regarded as phosphorescent emitters. A more exact definition is given hereinafter.

When the composition comprising at least one compound of the formula (1) as described above or described as preferred hereinafter and at least one compound of the formula (2) as described above or described as preferred hereinafter is used as matrix material for a phosphorescent emitter, it is preferable when the triplet energy thereof is not significantly less than the triplet energy of the phosphorescent emitter. In respect of the triplet level, it is preferably the case that T₁(emitter)−T₁(matrix)≤0.2 eV, more preferably ≤0.15 eV, most preferably ≤0.1 eV. T₁(matrix) here is the triplet level of the matrix material in the emission layer, this condition being applicable to each of the two matrix materials, and T₁(emitter) is the triplet level of the phosphorescent emitter. If the emission layer contains more than two matrix materials, the abovementioned relationship is preferably also applicable to every further matrix material.

There follows a description of compounds of the formula (1) and preferred embodiments thereof that are present in the composition and/or apparatus according to the invention, for example as electron-transporting hosts.

The composition according to the invention contains at least one compound of the formula (1) as described above.

In compounds of the formula (1), Y is selected from O and S.

In a preferred embodiment of the invention, compounds of the formula (1) in which Y is O are selected.

In a preferred embodiment of the invention, compounds of the formula (1) in which Y is S are selected.

In compounds of the formula (1), the symbol X is N at at least one instance, preferably N at two instances and CR⁰ at one instance or N at three instances.

The substituent

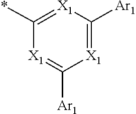

therefore has the following definitions, where * indicates the bonding site to the dibenzofuran or dibenzothiophene and R⁰ and Ar¹ have one of the definitions given above or a definition given as preferred:

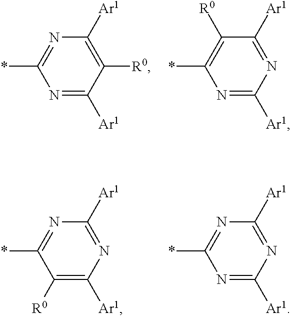

R⁰ is the same or different at each instance and is preferably selected from the group consisting of H, D, F or an aromatic or heteroaromatic ring system having 5 to 40 aromatic ring atoms. R⁰ at each instance is more preferably H.

Compounds of the formula (1) in which X₁ is N at each instance are represented by the formula (1a)

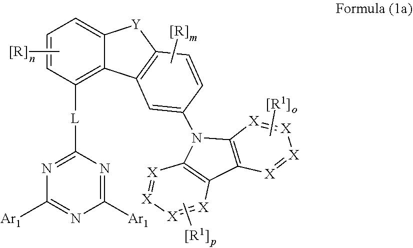

where Y, X, L, Ar₁, R, R¹, n, m, o and p have a definition given above or a definition given hereinafter.

More preferably, at least one compound of the formula (1a) having substituents described above, described as preferred or described hereinafter as preferred is selected for the composition.

The invention accordingly further provides a composition as described above, where the compound of the formula (1) conforms to the formula (1a), preferably when the symbol Y is O.

The invention accordingly further provides a composition as described above, where the compound of the formula (1) conforms to the formula (1a), preferably when the symbol Y is S.

When, in compounds of the formula (1) or (1a) or in compounds of the formula (1) or (1a) described as preferred, n or m is greater than 0, the substituent R is the same or different at each instance and is preferably selected from the group consisting of D, F, an alkyl group having 1 to 40 carbon atoms or an aromatic or heteroaromatic ring system having 5 to 40 aromatic ring atoms. The heteroaromatic ring system having 5 to 40 aromatic ring atoms in this case of R is preferably derived from dibenzofuran or dibenzothiophene. The aromatic ring system having 6 to 40 aromatic ring atoms in this case of R is preferably phenyl, biphenyl or terphenyl, more preferably phenyl or [1,1′,2′,1″ ]-terphenyl-5′-yl. The alkyl group having 1 to 40 carbon atoms in this case of R is preferably a linear or branched alkyl group having 1 to 4 carbon atoms, more preferably methyl, ethyl, n-propyl or n-butyl, most preferably methyl.

In compounds of the formula (1) or (1a), n and m are preferably 0.

In compounds of the formula (1) or (1a) or preferred compounds of the formula (1) or (1a), the symbol X is preferably C at eight instances and is correspondingly substituted by R¹, or the symbol X is preferably C at six instances and is correspondingly substituted by R¹ and the remaining two symbols X conform to the formula A.

Preferred compounds of the formula (1) or (1a) in which n and m are 0 and the symbols X have a definition as described above as preferred are accordingly compounds of the formulae (1b), (1c), (1d), (1e), (1f), (1g) and (1h)

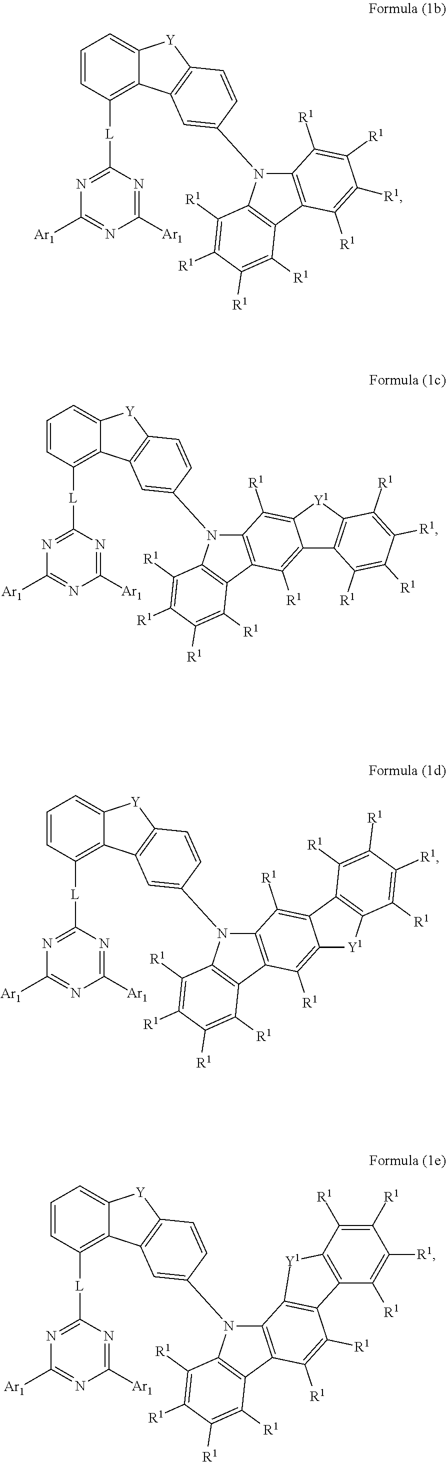

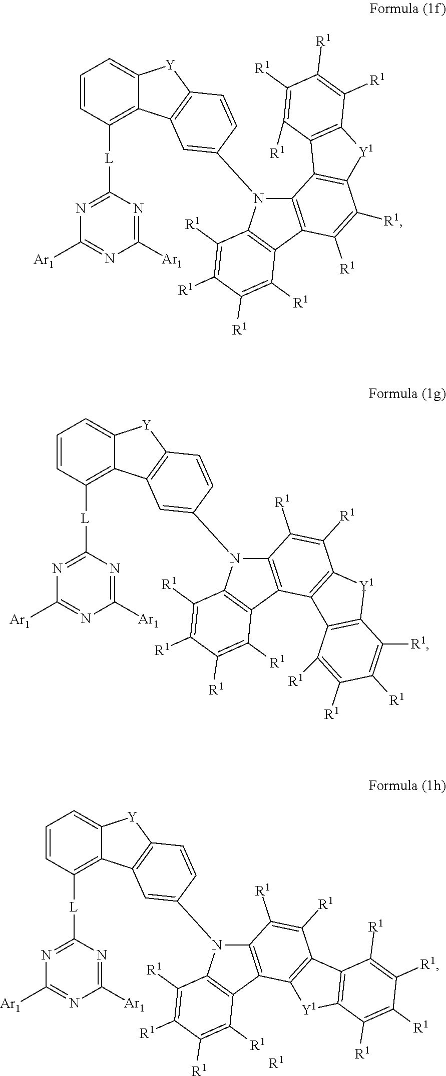

where Y, Y¹, L, Ar₁ and R¹ have a definition given above or a definition given hereinafter.

In compounds of the formulae (1), (1a) to (1h), or compounds of the formulae (1), (1a) to (1h) described with preference, the substituents R¹ are preferably each independently selected from the group of H, D or an aromatic or heteroaromatic ring system which has 5 to 40 aromatic ring atoms and may be substituted in each case by one or more R³ radicals, where R³ has a definition given above or given hereinafter, and where two substituents R¹ on adjacent carbon atoms form a monocyclic or polycyclic, aliphatic, aromatic or heteroaromatic ring system that may be substituted by one or more R³ radicals.

In one embodiment of the invention, the substituents R¹ in compounds of the formulae (1), (1a) and (1b) or compounds of the formulae (1), (1a) and (1b) described with preference are preferably each independently selected from the group of H, D or an aromatic ring system which has 5 to 40 aromatic ring atoms and may be substituted in each case by one or more R³ radicals, where R³ has a definition given above or given hereinafter. In this embodiment, preferably six or seven substituents R¹ are H and the remaining substituents have a definition as given above and are not H. In this embodiment, the carbazole in the compounds of the formulae (1), (1a) and (1b) preferably bears a substituent R¹ that is different from H and is an aromatic ring system having 5 to 40 aromatic ring atoms.

In one embodiment of the invention, the substituents R¹ in compounds of the formulae (1), (1a) and (1b) or compounds of the formulae (1), (1a) and (1b) described with preference are preferably each independently selected from the group of H, D or a heteroaromatic ring system which has 5 to 40 aromatic ring atoms and may be substituted in each case by one or more R³ radicals, where R³ has a definition given above or given hereinafter. In this embodiment, preferably seven substituents R¹ are H and the remaining substituent has a definition as given above and is not H. In this embodiment, the carbazole in the compounds of the formulae (1), (1a) and (1b) preferably bears a substituent R¹ that is different from H and is a heteroaromatic ring system having 5 to 40 aromatic ring atoms.

In compounds of the formulae (1), (1a) to (1h) or compounds of the formulae (1), (1a) to (1h) described with preference, the substituents R¹ are more preferably each independently selected from the group of H or unsubstituted or mono- or poly-R³-substituted phenyl, 1,2-biphenyl, 1,3-biphenyl, 1,4-biphenyl, triphenylenyl, 1-naphthyl, 2-naphthyl, carbazol-9-yl or 9-arylcarbazolyl, where aryl denotes an aromatic or heteroaromatic ring system which has 5 to 30 aromatic ring atoms and may be substituted in each case by one or more R³ radicals.

In compounds of the formula (1b), preferably six or seven substituents R¹ are defined as H and two or one substituent(s) R¹ have/has a different definition as described above or described as preferred.

In compounds of the formulae (1c) to (1h), all substituents R¹ are preferably H.

In compounds of the formulae (1), (1a) to (1h), or compounds of the formulae (1), (1a), (1b), (1c), (1d), (1e), (1f), (1g) or (1h) described with preference, Ar₁ at each instance is independently preferably an aryl group which has 6 to 40 carbon atoms, as described above or described as preferred, and may be substituted by one or more R³ radicals or is a dibenzofuranyl or dibenzothiophenyl group which may be substituted by one or more R³ radicals or a carbazolyl group which may be bonded either via C or via N and may be substituted by one or more R³ radicals. The bonding of the carbazolyl group via a carbon atom is not restricted here. Preferably, the carbazolyl group is bonded via N and is substituted by an R³ radical.

In compounds of the formulae (1), (1a) to (1h), or compounds of the formulae (1), (1a), (1b), (1c), (1d), (1e), (1f), (1g) or (1h) described with preference, Ar₁ at each instance is independently preferably an aryl group which has 6 to 40 carbon atoms, as described above or described as preferred, and may be substituted by one or more R³ radicals or is a dibenzofuranyl or dibenzothiophenyl group which may be substituted by one or more R³ radicals.

The bonding of the aryl group or of the dibenzofuranyl group or dibenzothiophenyl group is not restricted here.

Ar₁ may therefore preferably be selected from the following Ar₁-1 to Ar₁-12 groups, where R³ has a definition specified above or specified as preferred:

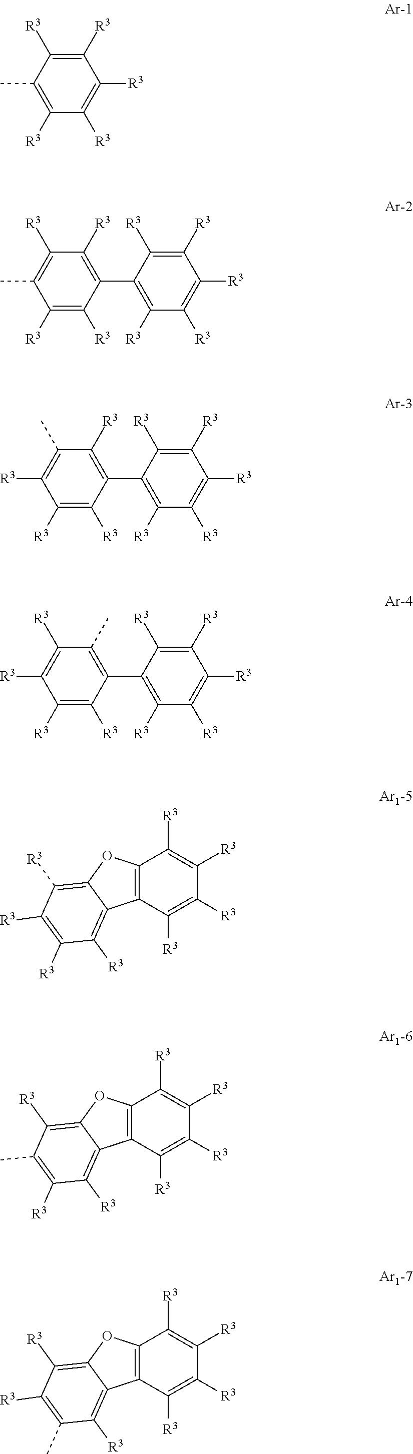

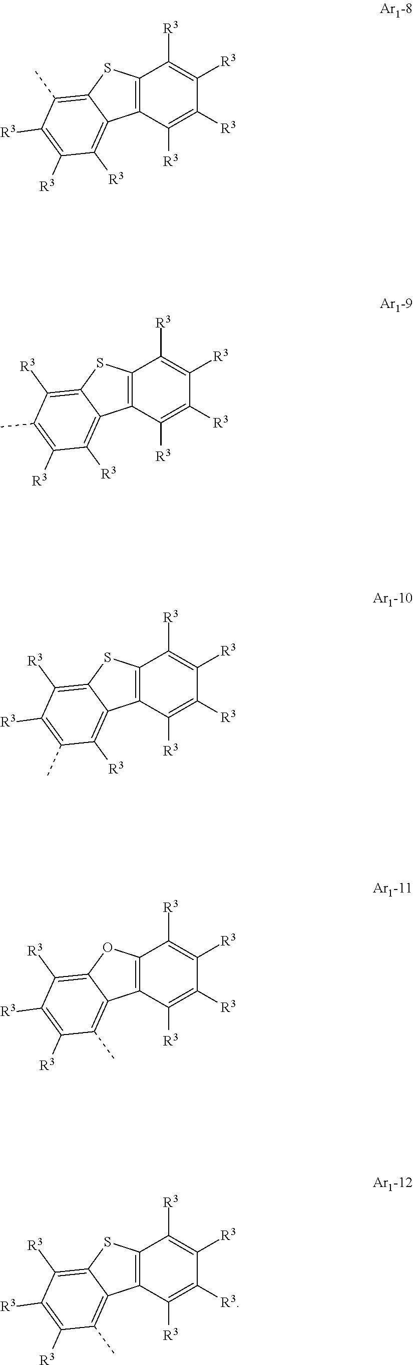

More preferably, at least one Ar₁ is Ar₁-1 and the other aromatic substituent Ar₁ is an alkyl group which has 6 to 40 carbon atoms and may be substituted by one or more R³ radicals or is a dibenzofuranyl or dibenzothiophenyl group, preferably selected from Ar₁-1 to Ar₁-12. More preferably, at least one Ar₁ is phenyl and the other aromatic substituent is a phenyl group which may be substituted by one or more R³ radicals or is dibenzofuranyl or dibenzothiophenyl. Most preferably, both Ar₁ groups are the same. Most preferably, both Ar₁ groups are phenyl. Preferably, both Ar₁ groups are each independently Ar₁-5, Ar₁-6, Ar₁-7 or Ar₁-11; more preferably, both Ar₁ groups are Ar₁-6.

When, in compounds of the formulae (1) or (1a) to (1h) or compounds of the formulae (1) or (1a) to (1h) described as preferred, Ar₁ is in each case independently, as described above or described as preferred, an aryl or heteroaryl group substituted by one or more R³ radicals, the substituent R³ is the same or different at each instance and is preferably selected from the group consisting of D, F or an aromatic or heteroaromatic ring system having 5 to 40 aromatic ring atoms. The heteroaromatic ring system having 5 to 40 aromatic ring atoms in this case of R³ is preferably derived from dibenzofuran or dibenzothiophene. The aromatic ring system having 6 to 40 aromatic ring atoms in this case of R³ is preferably phenyl, biphenyl or terphenyl, more preferably phenyl. Preferably, the aryl group or heteroaryl group in Ar₁ is in each case independently substituted once by R³. More preferably, the aryl group or heteroaryl group in Ar₁ is substituted once by R³.

The substituent R³ on the dibenzofuranyl or dibenzothiophenyl is preferably H. The substituent R³ on the aryl group having 6 to 40 carbon atoms, when it occurs, is preferably phenyl or H. Most preferably, the aryl group or heteroaryl group in Ar₁ is unsubstituted.

In compounds of the formulae (1), (1a), (1c), (1d), (1e), (1f), (1g) and (1h) or compounds of the formulae (1), (1a), (1c), (1d), (1e), (1f), (1g) and (1h) described as preferred, Y¹ is NAr₁, C(R*)₂, O or S, where Ar₁ has a definition given above or a definition given as preferred.

Preferably, NAr₁ is defined as N-phenyl. Y¹ is preferably NAr₁ or C(R*)₂.

In one embodiment of the invention, preference is given to compounds of the formulae (1), (1a) and (1c) or compounds of the formulae (1), (1a) and (1c) described as preferred in which Y¹ has a definition given above or in which Y¹ is NAr₁ and C(R*)₂, more preferably C(R*)₂.

In one embodiment of the invention, preference is given to compounds of the formulae (1), (1a), (1d) and (1e) or compounds of the formulae (1), (1a) (1d) and (1e) described as preferred in which Y¹ has a definition given above or in which Y¹ is NAr₁ and O, more preferably NAr₁.

In compounds of the formulae (1), (1a), (1c), (1d), (1e), (1f), (1g) and (1h) or compounds of the formulae (1), (1a), (1c), (1d), (1e), (1f), (1g) and (1h) described as preferred, the substituent R* is the same or different at each instance and is a straight-chain alkyl group having 1 to 10 carbon atoms or an aryl group having 6 to 12 carbon atoms, where the two substituents R* may together form a monocyclic or polycyclic, aliphatic, aromatic or heteroaromatic ring system that may be substituted by one or more substituents R⁵. R* is preferably the same at each instance, or two substituents R* together form a monocyclic or polycyclic, aliphatic, aromatic or heteroaromatic ring system. More preferably, R* is selected from methyl, ethyl and phenyl. More preferably, two substituents R* together with the carbon atom to which they are bonded form a ring system selected from cyclopentyl and dibenzocyclopentyl which may be substituted by one or more substituents R⁵. The ring system formed by two substituents R* is more preferably a spirobifluorene.

More preferably, Y¹ is selected from N-phenyl, C(methyl)₂, O and S. Most preferably, Y¹ is defined as C(methyl)₂.

In compounds of the formulae (1), (1a), (1b), (1c), (1d), (1e), (1f), (1g) or (1h) or in compounds of the formulae (1), (1a), (1b), (1c), (1d), (1e), (1f), (1g) or (1h) described as preferred, L is the same or different at each instance and is a single bond or an aromatic ring system which has 6 to 30 aromatic ring atoms and may be substituted by one or more R⁵ radicals, where R⁵ is defined as described above. R⁵ here is preferably selected from the group consisting of D and phenyl. L is preferably a single bond or an aromatic ring system having 6 to 18 carbon atoms, preferably phenylene, diphenylene, naphthylene, phenanthrenylene or triphenylenylene, where the attachment to the further substituents is not restricted. Phenylene here may be bonded to the dibenzofuran/dibenzothiophene unit in the ortho, meta or para position for example.

L may therefore preferably be selected from the following linkers L-1 to L-20 that may be unsubstituted or substituted by R⁵ as described above:

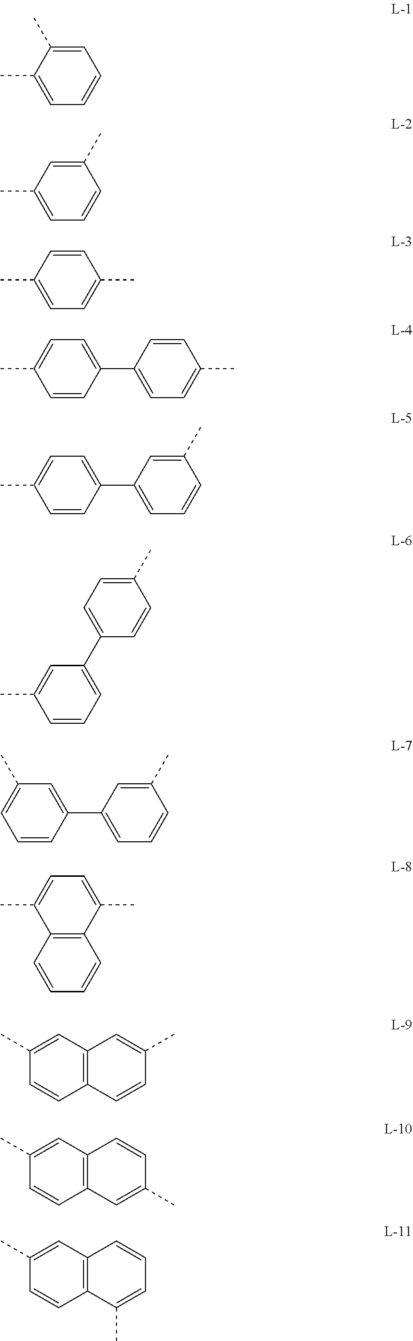

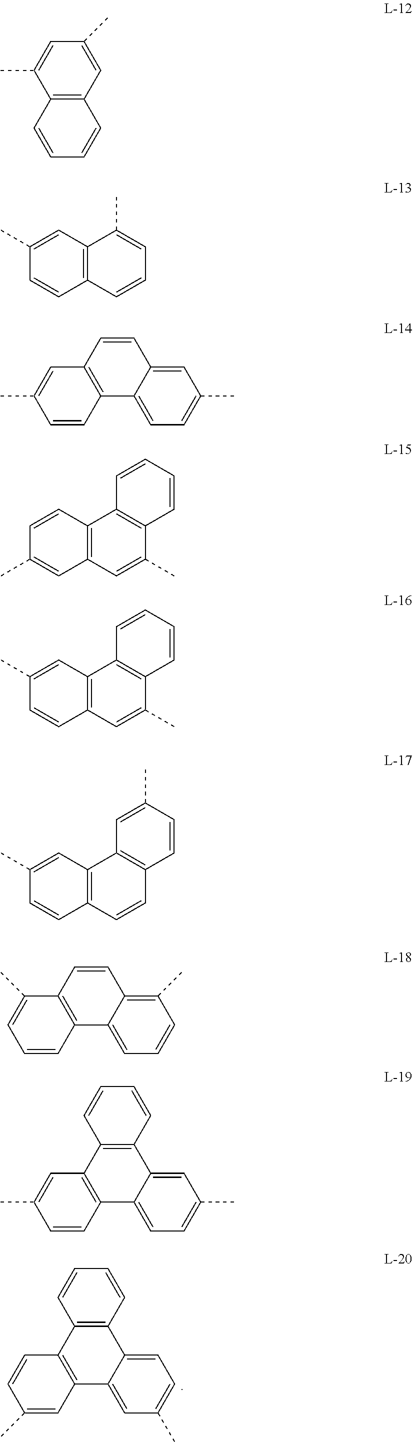

Preferably, the linkers L-1 to L-20 are unsubstituted.

Particular preference is given to using the linkers L-1 to L-7.

Preferably, L is a single bond or a linker selected from the group of L-1 to L-7 or L-2 and L-3. More preferably, L is a single bond.

Particularly preferred compounds of the formula (1) conform to the formulae (1b) and (1c), as described above.

In compounds of the formulae (1), (1b) and (1c), Y is preferably O, Y¹ is preferably C(R*)₂, Ar₁ independently at each instance is preferably phenyl, dibenzofuranyl, dibenzothiophenyl, carbazolyl-N-phenylenyl, dibenzofuranylphenylenyl, phenylcarbazol-N-yl, 1,3- and 1,4-biphenyl, as described above, and L is a single bond.

In compounds of the formulae (1), (1b) and (1c), Y is preferably O, Y¹ is preferably C(R*)₂, Ar₁ independently at each instance is preferably phenyl, dibenzofuranyl, dibenzothiophenyl and biphenyl, as described above, and L is a single bond.

In compounds of the formulae (1), (1b) and (1c), Y is preferably S, Y¹ is preferably C(R*)₂, Ar₁ independently at each instance is preferably phenyl, dibenzofuranyl, dibenzothiophenyl, carbazolyl-N-phenylenyl, dibenzofuranylphenylenyl, phenylcarbazol-N-yl, 1,3- and 1,4-biphenyl, as described above, and L is a single bond.

In compounds of the formulae (1), (1b) and (1c), Y is preferably S, Y¹ is preferably C(R*)₂, Ar₁ independently at each instance is preferably phenyl, dibenzofuranyl, carbazolyl-N-phenylenyl and 1,3-biphenyl, as described above, and L is a single bond.

Compounds of the formulae (1b) and (1c) with substituents Y, Y¹, Ar₁, L and R¹, as described above or described as preferred, are preferably selected for the composition of the invention.

Examples of suitable compounds of the formulae (1), (1a), (1b), (1c), (1d), (1e), (1f), (1g) or (1h) that are selected in accordance with the invention are the structures shown below in Table 1 or the compounds 1 to 36 and 67 to 81.

TABLE 1

| | |
|---|---|
| 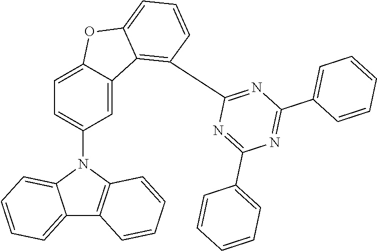 [SMILES: c1ccc(-c2nc(-c3ccccc3)nc(-c3cccc4oc5ccc(-n6c7ccccc7c7ccccc76)cc5c34)n2)cc1] | 1-1 |
| 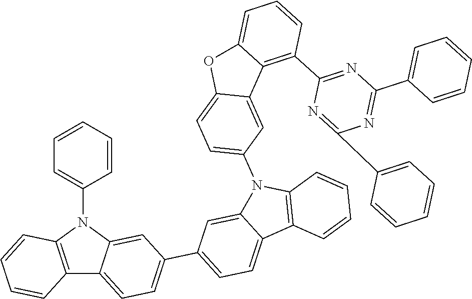 [SMILES: c1ccc(-c2nc(-c3ccccc3)nc(-c3cccc4oc5ccc(-n6c7ccccc7c7ccc(-c8ccc9c%10ccccc%10n(-c%10ccccc%10)c9c8)cc76)cc5c34)n2)cc1] | 1-2 |
| 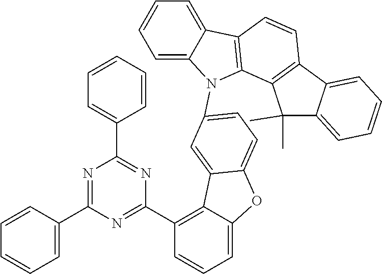 [SMILES: CC1(C)c2ccccc2-c2ccc3c4ccccc4n(-c4ccc5oc6cccc(-c7nc(-c8ccccc8)nc(-c8ccccc8)n7)c6c5c4)c3c21] | 1-3 |
| 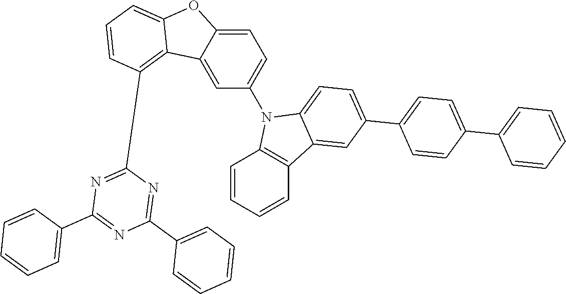 [SMILES: c1ccc(-c2ccc(-c3ccc4c(c3)c3ccccc3n4-c3ccc4oc5cccc(-c6nc(-c7ccccc7)nc(-c7ccccc7)n6)c5c4c3)cc2)cc1] | 1-4 |
| 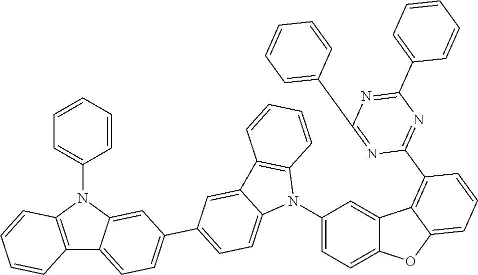 [SMILES: c1ccc(-c2nc(-c3ccccc3)nc(-c3cccc4oc5ccc(-n6c7ccccc7c7cc(-c8ccc9c%10ccccc%10n(-c%10ccccc%10)c9c8)ccc76)cc5c34)n2)cc1] | 1-5 |
| 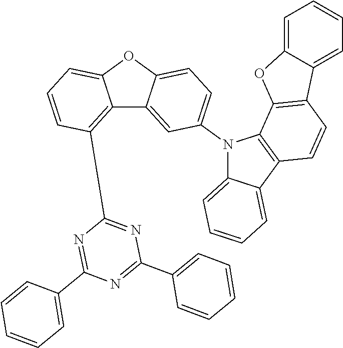 [SMILES: c1ccc(-c2nc(-c3ccccc3)nc(-c3cccc4oc5ccc(-n6c7ccccc7c7ccc8c9ccccc9oc8c76)cc5c34)n2)cc1] | 1-6 |
| 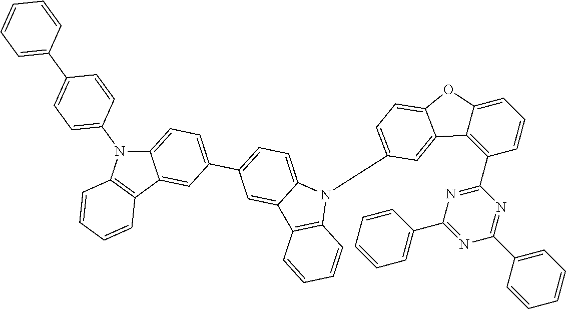 [SMILES: c1ccc(-c2ccc(-n3c4ccccc4c4cc(-c5ccc6c(c5)c5ccccc5n6-c5ccc6oc7cccc(-c8nc(-c9ccccc9)nc(-c9ccccc9)n8)c7c6c5)ccc43)cc2)cc1] | 1-7 |
| 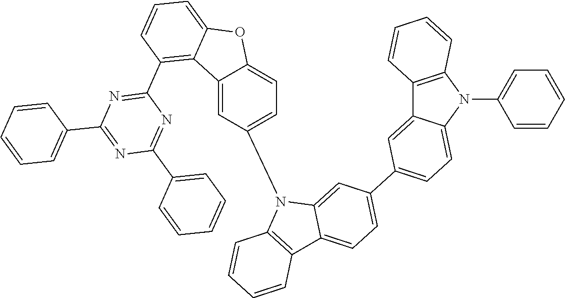 [SMILES: c1ccc(-c2nc(-c3ccccc3)nc(-c3cccc4oc5ccc(-n6c7ccccc7c7ccc(-c8ccc9c(c8)c8ccccc8n9-c8ccccc8)cc76)cc5c34)n2)cc1] | 1-8 |
| 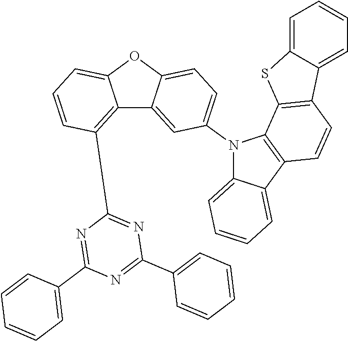 [SMILES: c1ccc(-c2nc(-c3ccccc3)nc(-c3cccc4oc5ccc(-n6c7ccccc7c7ccc8c9ccccc9sc8c76)cc5c34)n2)cc1] | 1-9 |
| 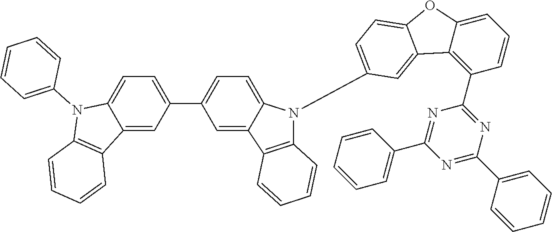 [SMILES: c1ccc(-c2nc(-c3ccccc3)nc(-c3cccc4oc5ccc(-n6c7ccccc7c7cc(-c8ccc9c(c8)c8ccccc8n9-c8ccccc8)ccc76)cc5c34)n2)cc1] | 1-10 |
| 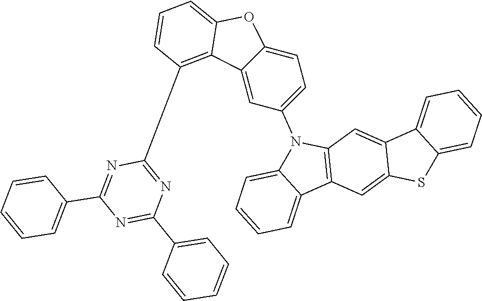 [SMILES: c1ccc(-c2nc(-c3ccccc3)nc(-c3cccc4oc5ccc(-n6c7ccccc7c7cc8sc9ccccc9c8cc76)cc5c34)n2)cc1] | 1-11 |
| 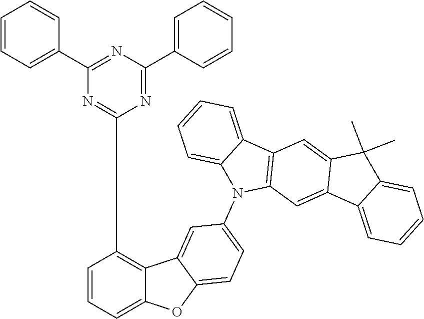 [SMILES: CC1(C)c2ccccc2-c2cc3c(cc21)c1ccccc1n3-c1ccc2oc3cccc(-c4nc(-c5ccccc5)nc(-c5ccccc5)n4)c3c2c1] | 1-12 |
| 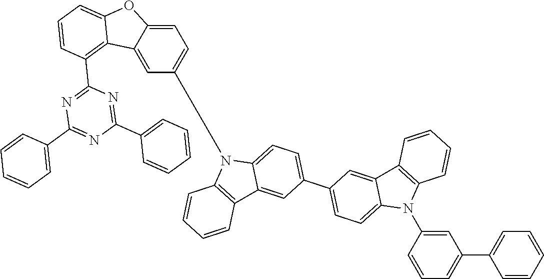 [SMILES: c1ccc(-c2cccc(-n3c4ccccc4c4cc(-c5ccc6c(c5)c5ccccc5n6-c5ccc6oc7cccc(-c8nc(-c9ccccc9)nc(-c9ccccc9)n8)c7c6c5)ccc43)c2)cc1] | 1-13 |
| 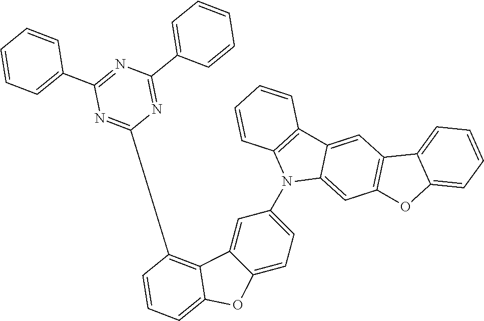 [SMILES: c1ccc(-c2nc(-c3ccccc3)nc(-c3cccc4oc5ccc(-n6c7ccccc7c7cc8c(cc76)oc6ccccc68)cc5c34)n2)cc1] | 1-14 |
| 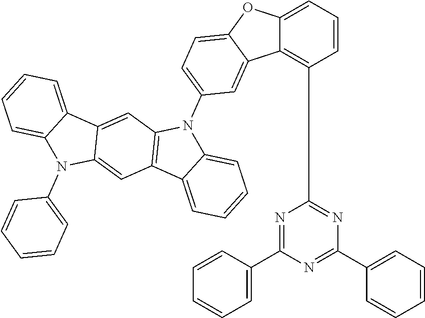 [SMILES: c1ccc(-c2nc(-c3ccccc3)nc(-c3cccc4oc5ccc(-n6c7ccccc7c7cc8c(cc76)c6ccccc6n8-c6ccccc6)cc5c34)n2)cc1] | 1-15 |
| 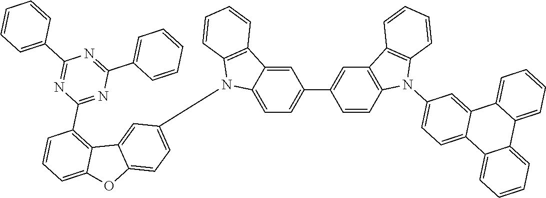 [SMILES: c1ccc(-c2nc(-c3ccccc3)nc(-c3cccc4oc5ccc(-n6c7ccccc7c7cc(-c8ccc9c(c8)c8ccccc8n9-c8ccc9c%10ccccc%10c%10ccccc%10c9c8)ccc76)cc5c34)n2)cc1] | 1-16 |
| 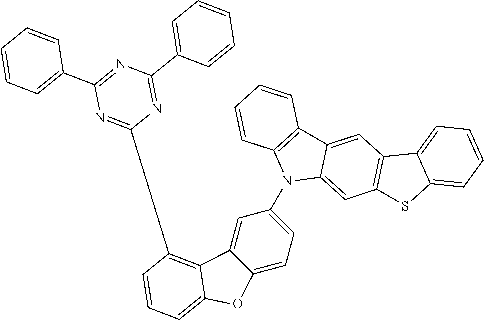 [SMILES: c1ccc(-c2nc(-c3ccccc3)nc(-c3cccc4oc5ccc(-n6c7ccccc7c7cc8c(cc76)sc6ccccc68)cc5c34)n2)cc1] | 1-17 |
| 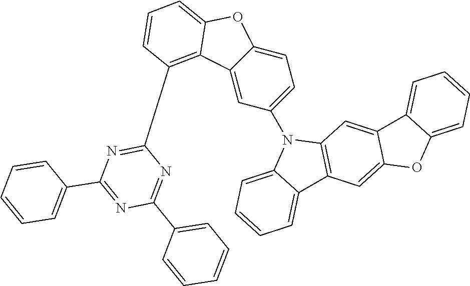 [SMILES: c1ccc(-c2nc(-c3ccccc3)nc(-c3cccc4oc5ccc(-n6c7ccccc7c7cc8oc9ccccc9c8cc76)cc5c34)n2)cc1] | 1-18 |
| 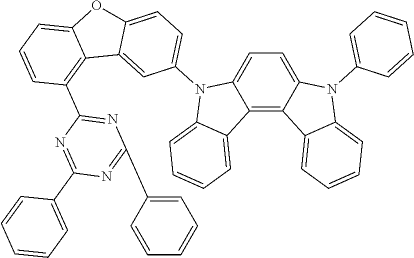 [SMILES: c1ccc(-c2nc(-c3ccccc3)nc(-c3cccc4oc5ccc(-n6c7ccccc7c7c8c9ccccc9n(-c9ccccc9)c8ccc76)cc5c34)n2)cc1] | 1-19 |
| 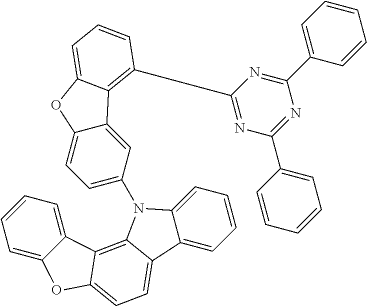 [SMILES: c1ccc(-c2nc(-c3ccccc3)nc(-c3cccc4oc5ccc(-n6c7ccccc7c7ccc8oc9ccccc9c8c76)cc5c34)n2)cc1] | 1-20 |
| 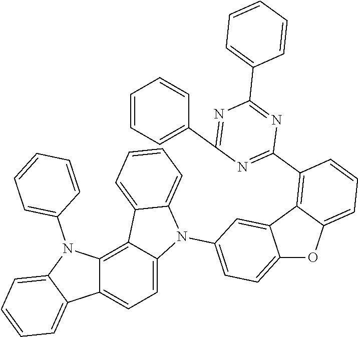 [SMILES: c1ccc(-c2nc(-c3ccccc3)nc(-c3cccc4oc5ccc(-n6c7ccccc7c7c6ccc6c8ccccc8n(-c8ccccc8)c67)cc5c34)n2)cc1] | 1-21 |
| 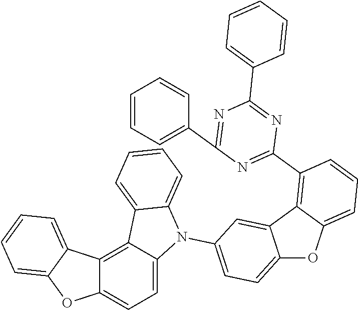 [SMILES: c1ccc(-c2nc(-c3ccccc3)nc(-c3cccc4oc5ccc(-n6c7ccccc7c7c8c(ccc76)oc6ccccc68)cc5c34)n2)cc1] | 1-22 |
| 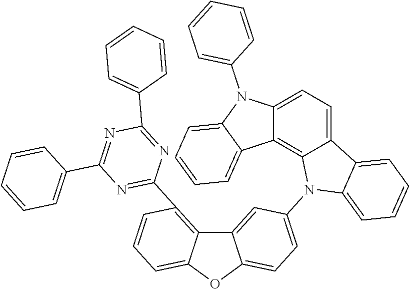 [SMILES: c1ccc(-c2nc(-c3ccccc3)nc(-c3cccc4oc5ccc(-n6c7ccccc7c7ccc8c(c9ccccc9n8-c8ccccc8)c76)cc5c34)n2)cc1] | 1-23 |
| 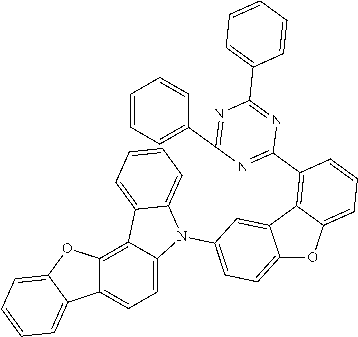 [SMILES: c1ccc(-c2nc(-c3ccccc3)nc(-c3cccc4oc5ccc(-n6c7ccccc7c7c8oc9ccccc9c8ccc76)cc5c34)n2)cc1] | 1-24 |
| 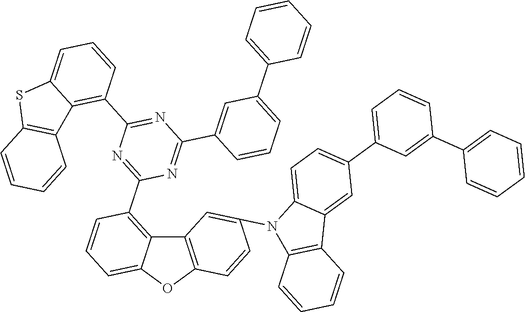 [SMILES: c1ccc(-c2cccc(-c3ccc4c(c3)c3ccccc3n4-c3ccc4oc5cccc(-c6nc(-c7cccc(-c8ccccc8)c7)nc(-c7cccc8sc9ccccc9c78)n6)c5c4c3)c2)cc1] | 1-25 |
| 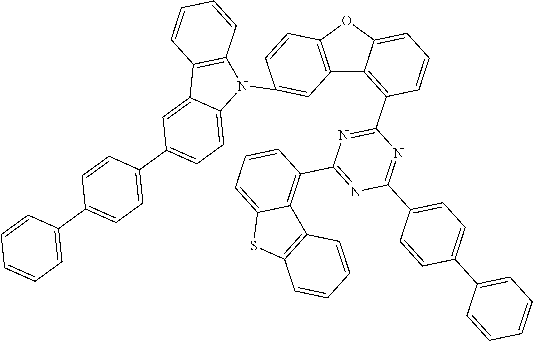 [SMILES: c1ccc(-c2ccc(-c3ccc4c(c3)c3ccccc3n4-c3ccc4oc5cccc(-c6nc(-c7ccc(-c8ccccc8)cc7)nc(-c7cccc8sc9ccccc9c78)n6)c5c4c3)cc2)cc1] | 1-26 |
| 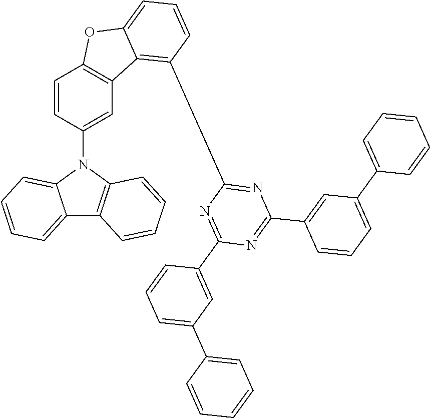 [SMILES: c1ccc(-c2cccc(-c3nc(-c4cccc(-c5ccccc5)c4)nc(-c4cccc5oc6ccc(-n7c8ccccc8c8ccccc87)cc6c45)n3)c2)cc1] | 1-27 |
| 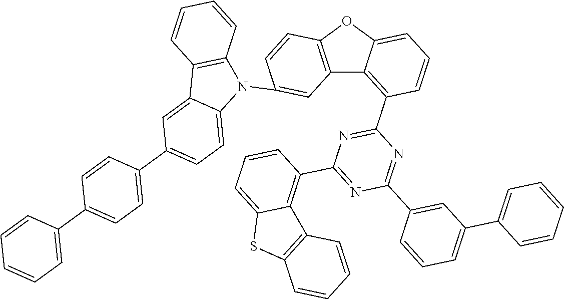 [SMILES: c1ccc(-c2ccc(-c3ccc4c(c3)c3ccccc3n4-c3ccc4oc5cccc(-c6nc(-c7cccc(-c8ccccc8)c7)nc(-c7cccc8sc9ccccc9c78)n6)c5c4c3)cc2)cc1] | 1-28 |
| 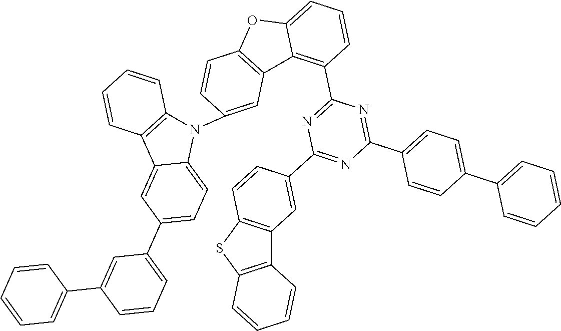 [SMILES: c1ccc(-c2ccc(-c3nc(-c4ccc5sc6ccccc6c5c4)nc(-c4cccc5oc6ccc(-n7c8ccccc8c8cc(-c9cccc(-c%10ccccc%10)c9)ccc87)cc6c45)n3)cc2)cc1] | 1-29 |
| 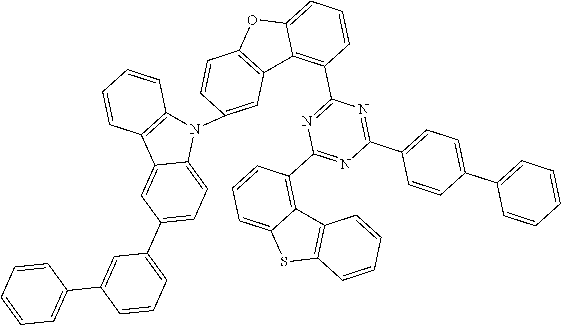 [SMILES: c1ccc(-c2ccc(-c3nc(-c4cccc5oc6ccc(-n7c8ccccc8c8cc(-c9cccc(-c%10ccccc%10)c9)ccc87)cc6c45)nc(-c4cccc5sc6ccccc6c45)n3)cc2)cc1] | 1-30 |
| 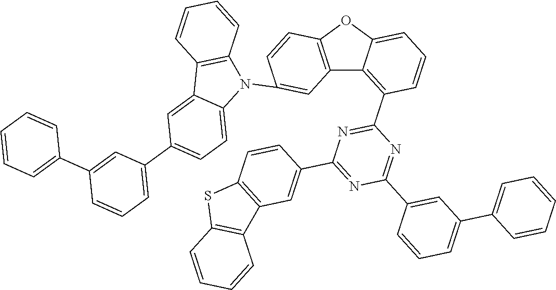 [SMILES: c1ccc(-c2cccc(-c3ccc4c(c3)c3ccccc3n4-c3ccc4oc5cccc(-c6nc(-c7cccc(-c8ccccc8)c7)nc(-c7ccc8sc9ccccc9c8c7)n6)c5c4c3)c2)cc1] | 1-31 |
| 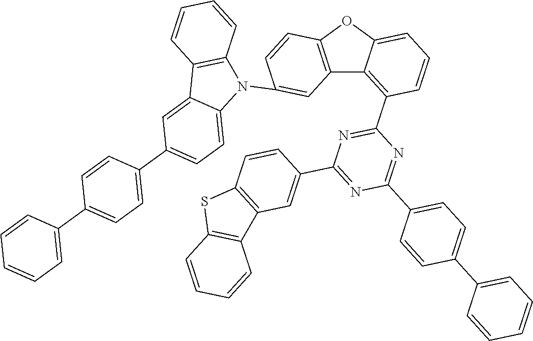 [SMILES: c1ccc(-c2ccc(-c3ccc4c(c3)c3ccccc3n4-c3ccc4oc5cccc(-c6nc(-c7ccc(-c8ccccc8)cc7)nc(-c7ccc8sc9ccccc9c8c7)n6)c5c4c3)cc2)cc1] | 1-32 |
| 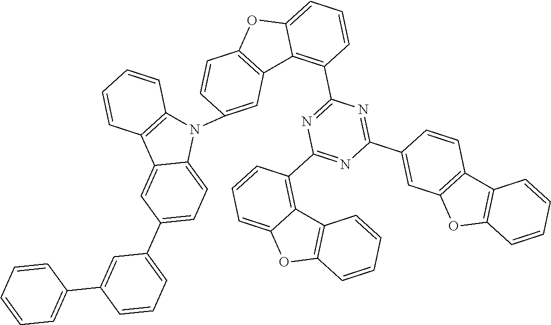 [SMILES: c1ccc(-c2cccc(-c3ccc4c(c3)c3ccccc3n4-c3ccc4oc5cccc(-c6nc(-c7ccc8c(c7)oc7ccccc78)nc(-c7cccc8oc9ccccc9c78)n6)c5c4c3)c2)cc1] | 1-33 |
| 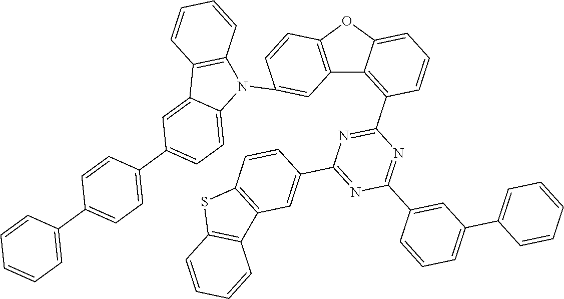 [SMILES: c1ccc(-c2ccc(-c3ccc4c(c3)c3ccccc3n4-c3ccc4oc5cccc(-c6nc(-c7cccc(-c8ccccc8)c7)nc(-c7ccc8sc9ccccc9c8c7)n6)c5c4c3)cc2)cc1] | 1-34 |
| 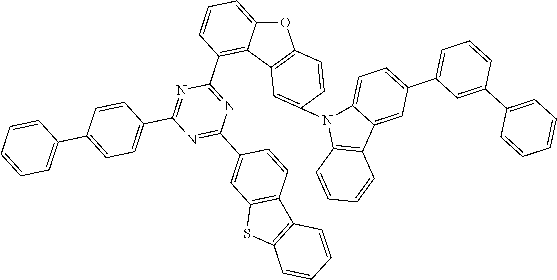 [SMILES: c1ccc(-c2ccc(-c3nc(-c4ccc5c(c4)sc4ccccc45)nc(-c4cccc5oc6ccc(-n7c8ccccc8c8cc(-c9cccc(-c%10ccccc%10)c9)ccc87)cc6c45)n3)cc2)cc1] | 1-35 |
| 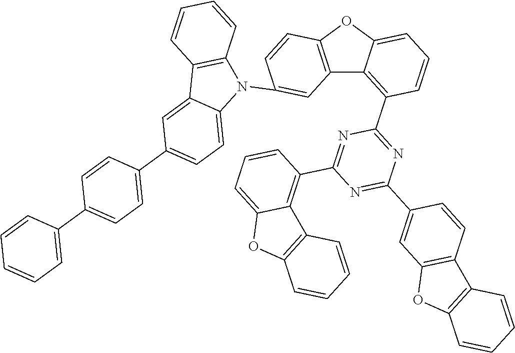 [SMILES: c1ccc(-c2ccc(-c3ccc4c(c3)c3ccccc3n4-c3ccc4oc5cccc(-c6nc(-c7ccc8c(c7)oc7ccccc78)nc(-c7cccc8oc9ccccc9c78)n6)c5c4c3)cc2)cc1] | 1-36 |
| 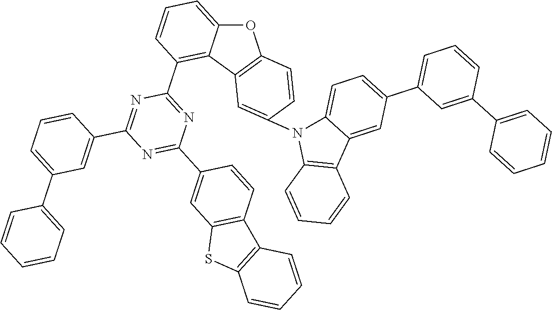 [SMILES: c1ccc(-c2cccc(-c3ccc4c(c3)c3ccccc3n4-c3ccc4oc5cccc(-c6nc(-c7cccc(-c8ccccc8)c7)nc(-c7ccc8c(c7)sc7ccccc78)n6)c5c4c3)c2)cc1] | 1-37 |
| 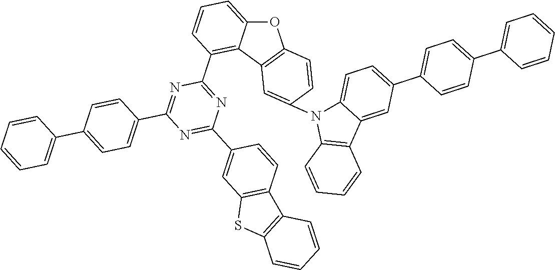 [SMILES: c1ccc(-c2ccc(-c3ccc4c(c3)c3ccccc3n4-c3ccc4oc5cccc(-c6nc(-c7ccc(-c8ccccc8)cc7)nc(-c7ccc8c(c7)sc7ccccc78)n6)c5c4c3)cc2)cc1] | 1-38 |
| 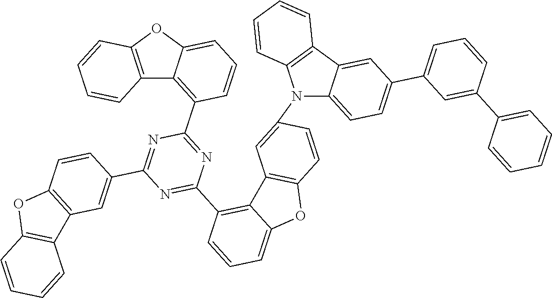 [SMILES: c1ccc(-c2cccc(-c3ccc4c(c3)c3ccccc3n4-c3ccc4oc5cccc(-c6nc(-c7ccc8oc9ccccc9c8c7)nc(-c7cccc8oc9ccccc9c78)n6)c5c4c3)c2)cc1] | 1-39 |
| 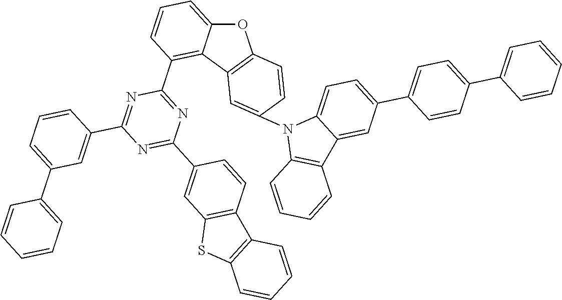 [SMILES: c1ccc(-c2ccc(-c3ccc4c(c3)c3ccccc3n4-c3ccc4oc5cccc(-c6nc(-c7cccc(-c8ccccc8)c7)nc(-c7ccc8c(c7)sc7ccccc78)n6)c5c4c3)cc2)cc1] | 1-40 |
| 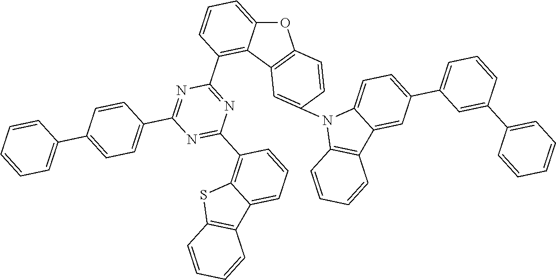 [SMILES: c1ccc(-c2ccc(-c3nc(-c4cccc5c4sc4ccccc45)nc(-c4cccc5oc6ccc(-n7c8ccccc8c8cc(-c9cccc(-c%10ccccc%10)c9)ccc87)cc6c45)n3)cc2)cc1] | 1-41 |
| 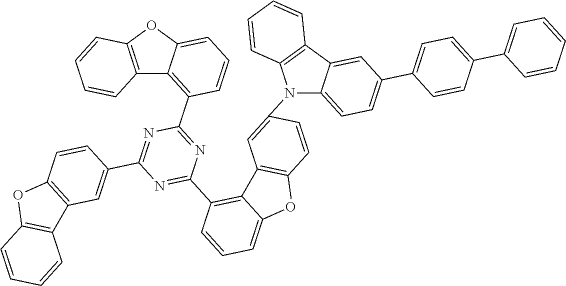 [SMILES: c1ccc(-c2ccc(-c3ccc4c(c3)c3ccccc3n4-c3ccc4oc5cccc(-c6nc(-c7ccc8oc9ccccc9c8c7)nc(-c7cccc8oc9ccccc9c78)n6)c5c4c3)cc2)cc1] | 1-42 |
| 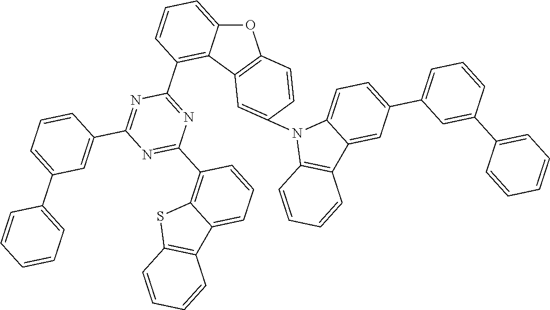 [SMILES: c1ccc(-c2cccc(-c3ccc4c(c3)c3ccccc3n4-c3ccc4oc5cccc(-c6nc(-c7cccc(-c8ccccc8)c7)nc(-c7cccc8c7sc7ccccc78)n6)c5c4c3)c2)cc1] | 1-43 |
| 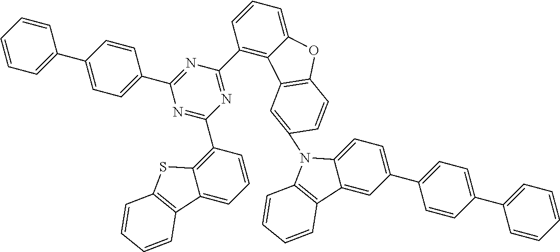 [SMILES: c1ccc(-c2ccc(-c3ccc4c(c3)c3ccccc3n4-c3ccc4oc5cccc(-c6nc(-c7ccc(-c8ccccc8)cc7)nc(-c7cccc8c7sc7ccccc78)n6)c5c4c3)cc2)cc1] | 1-44 |
| 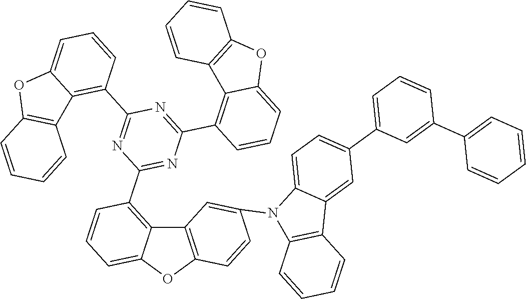 [SMILES: c1ccc(-c2cccc(-c3ccc4c(c3)c3ccccc3n4-c3ccc4oc5cccc(-c6nc(-c7cccc8oc9ccccc9c78)nc(-c7cccc8oc9ccccc9c78)n6)c5c4c3)c2)cc1] | 1-45 |
| 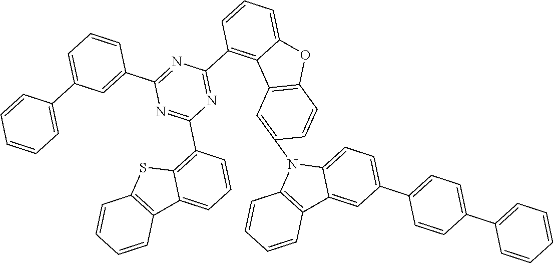 [SMILES: c1ccc(-c2ccc(-c3ccc4c(c3)c3ccccc3n4-c3ccc4oc5cccc(-c6nc(-c7cccc(-c8ccccc8)c7)nc(-c7cccc8c7sc7ccccc78)n6)c5c4c3)cc2)cc1] | 1-46 |
| 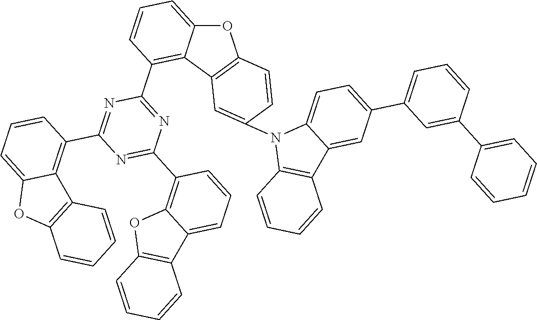 [SMILES: c1ccc(-c2cccc(-c3ccc4c(c3)c3ccccc3n4-c3ccc4oc5cccc(-c6nc(-c7cccc8c7oc7ccccc78)nc(-c7cccc8oc9ccccc9c78)n6)c5c4c3)c2)cc1] | 1-47 |
| 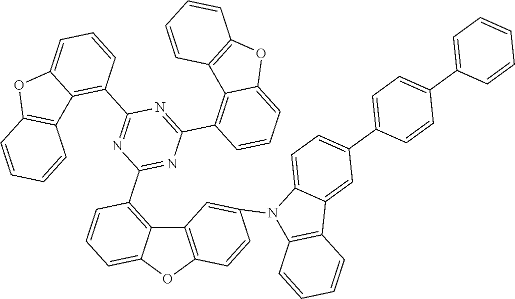 [SMILES: c1ccc(-c2ccc(-c3ccc4c(c3)c3ccccc3n4-c3ccc4oc5cccc(-c6nc(-c7cccc8oc9ccccc9c78)nc(-c7cccc8oc9ccccc9c78)n6)c5c4c3)cc2)cc1] | 1-48 |
| 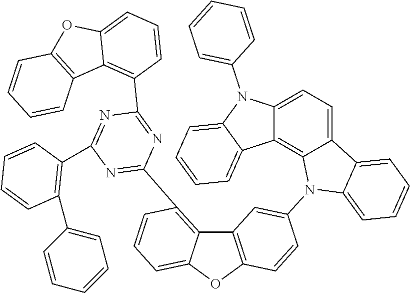 [SMILES: c1ccc(-c2ccccc2-c2nc(-c3cccc4oc5ccccc5c34)nc(-c3cccc4oc5ccc(-n6c7ccccc7c7ccc8c(c9ccccc9n8-c8ccccc8)c76)cc5c34)n2)cc1] | 1-49 |
| 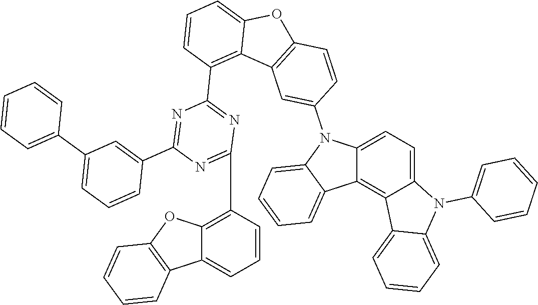 [SMILES: c1ccc(-c2cccc(-c3nc(-c4cccc5c4oc4ccccc45)nc(-c4cccc5oc6ccc(-n7c8ccccc8c8c9c%10ccccc%10n(-c%10ccccc%10)c9ccc87)cc6c45)n3)c2)cc1] | 1-50 |
| 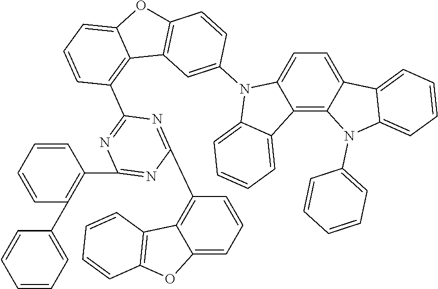 [SMILES: c1ccc(-c2ccccc2-c2nc(-c3cccc4oc5ccccc5c34)nc(-c3cccc4oc5ccc(-n6c7ccccc7c7c6ccc6c8ccccc8n(-c8ccccc8)c67)cc5c34)n2)cc1] | 1-51 |
| 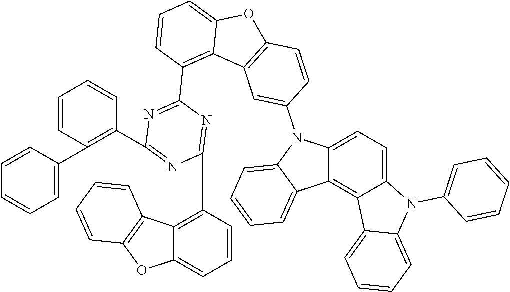 [SMILES: c1ccc(-c2ccccc2-c2nc(-c3cccc4oc5ccccc5c34)nc(-c3cccc4oc5ccc(-n6c7ccccc7c7c8c9ccccc9n(-c9ccccc9)c8ccc76)cc5c34)n2)cc1] | 1-52 |
| 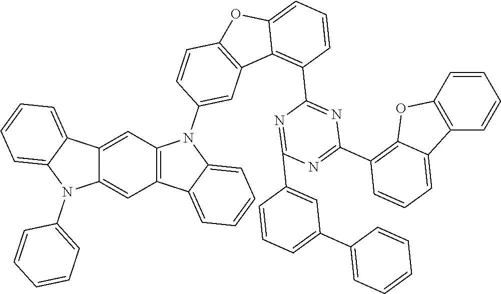 [SMILES: c1ccc(-c2cccc(-c3nc(-c4cccc5c4oc4ccccc45)nc(-c4cccc5oc6ccc(-n7c8ccccc8c8cc9c(cc87)c7ccccc7n9-c7ccccc7)cc6c45)n3)c2)cc1] | 1-53 |
| 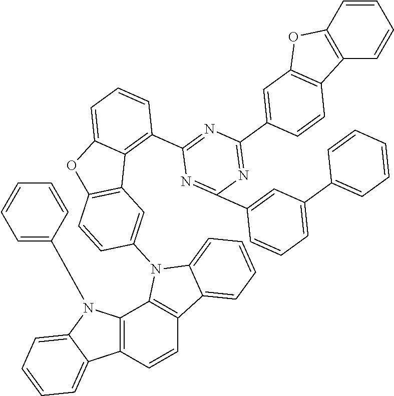 [SMILES: c1ccc(-c2cccc(-c3nc(-c4ccc5c(c4)oc4ccccc45)nc(-c4cccc5oc6ccc(-n7c8ccccc8c8ccc9c%10ccccc%10n(-c%10ccccc%10)c9c87)cc6c45)n3)c2)cc1] | 1-54 |
| 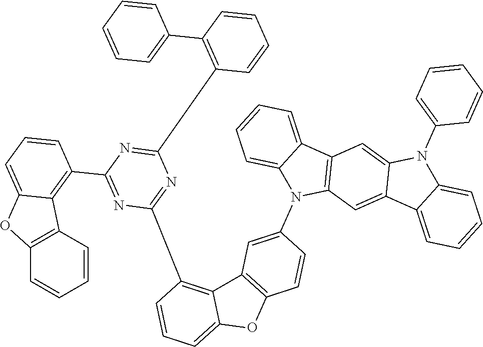 [SMILES: c1ccc(-c2ccccc2-c2nc(-c3cccc4oc5ccccc5c34)nc(-c3cccc4oc5ccc(-n6c7ccccc7c7cc8c(cc76)c6ccccc6n8-c6ccccc6)cc5c34)n2)cc1] | 1-55 |
| 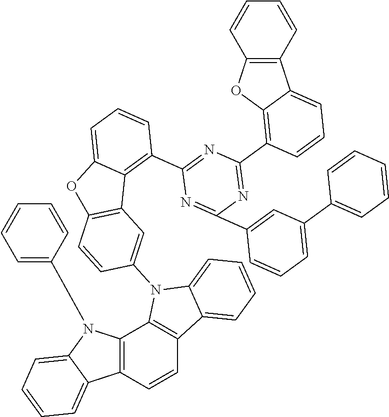 [SMILES: c1ccc(-c2cccc(-c3nc(-c4cccc5c4oc4ccccc45)nc(-c4cccc5oc6ccc(-n7c8ccccc8c8ccc9c%10ccccc%10n(-c%10ccccc%10)c9c87)cc6c45)n3)c2)cc1] | 1-56 |
| 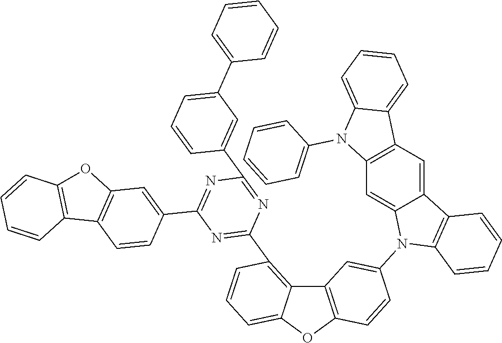 [SMILES: c1ccc(-c2cccc(-c3nc(-c4ccc5c(c4)oc4ccccc45)nc(-c4cccc5oc6ccc(-n7c8ccccc8c8cc9c%10ccccc%10n(-c%10ccccc%10)c9cc87)cc6c45)n3)c2)cc1] | 1-57 |
| 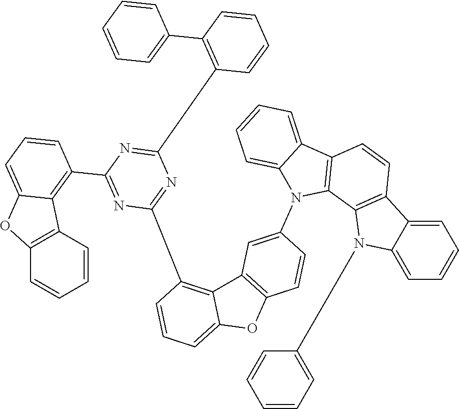 [SMILES: c1ccc(-c2ccccc2-c2nc(-c3cccc4oc5ccccc5c34)nc(-c3cccc4oc5ccc(-n6c7ccccc7c7ccc8c9ccccc9n(-c9ccccc9)c8c76)cc5c34)n2)cc1] | 1-58 |
| 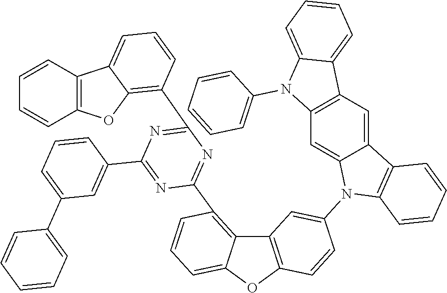 [SMILES: c1ccc(-c2cccc(-c3nc(-c4cccc5c4oc4ccccc45)nc(-c4cccc5oc6ccc(-n7c8ccccc8c8cc9c%10ccccc%10n(-c%10ccccc%10)c9cc87)cc6c45)n3)c2)cc1] | 1-59 |
| 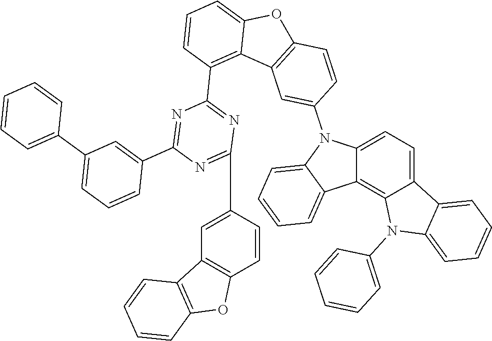 [SMILES: c1ccc(-c2cccc(-c3nc(-c4ccc5oc6ccccc6c5c4)nc(-c4cccc5oc6ccc(-n7c8ccccc8c8c7ccc7c9ccccc9n(-c9ccccc9)c78)cc6c45)n3)c2)cc1] | 1-60 |
| 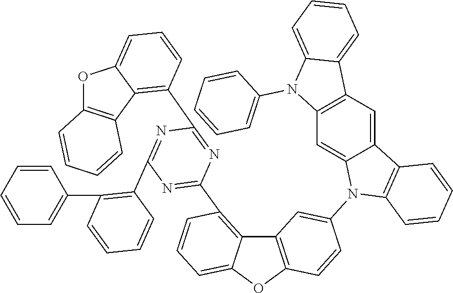 [SMILES: c1ccc(-c2ccccc2-c2nc(-c3cccc4oc5ccccc5c34)nc(-c3cccc4oc5ccc(-n6c7ccccc7c7cc8c9ccccc9n(-c9ccccc9)c8cc76)cc5c34)n2)cc1] | 1-61 |
| 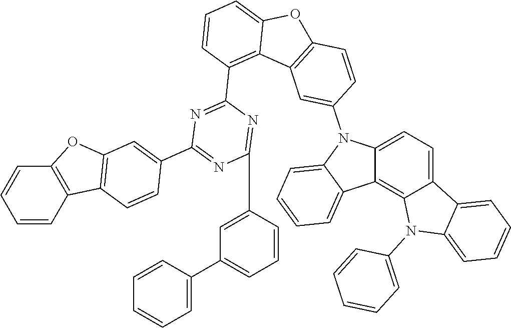 [SMILES: c1ccc(-c2cccc(-c3nc(-c4ccc5c(c4)oc4ccccc45)nc(-c4cccc5oc6ccc(-n7c8ccccc8c8c7ccc7c9ccccc9n(-c9ccccc9)c78)cc6c45)n3)c2)cc1] | 1-62 |
| 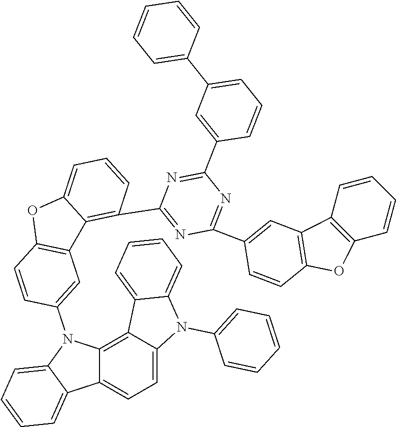 [SMILES: c1ccc(-c2cccc(-c3nc(-c4ccc5oc6ccccc6c5c4)nc(-c4cccc5oc6ccc(-n7c8ccccc8c8ccc9c(c%10ccccc%10n9-c9ccccc9)c87)cc6c45)n3)c2)cc1] | 1-63 |
| 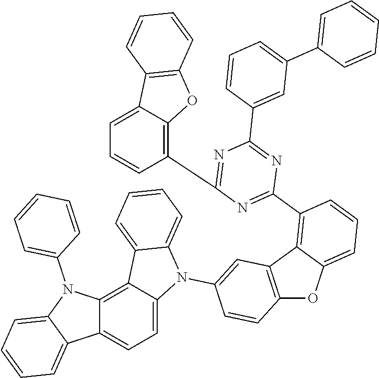 [SMILES: c1ccc(-c2cccc(-c3nc(-c4cccc5c4oc4ccccc45)nc(-c4cccc5oc6ccc(-n7c8ccccc8c8c7ccc7c9ccccc9n(-c9ccccc9)c78)cc6c45)n3)c2)cc1] | 1-64 |
| 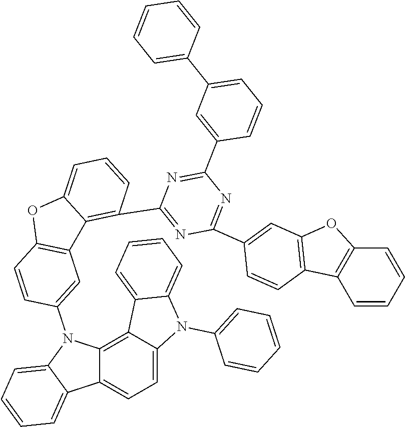 [SMILES: c1ccc(-c2cccc(-c3nc(-c4ccc5c(c4)oc4ccccc45)nc(-c4cccc5oc6ccc(-n7c8ccccc8c8ccc9c(c%10ccccc%10n9-c9ccccc9)c87)cc6c45)n3)c2)cc1] | 1-65 |
| 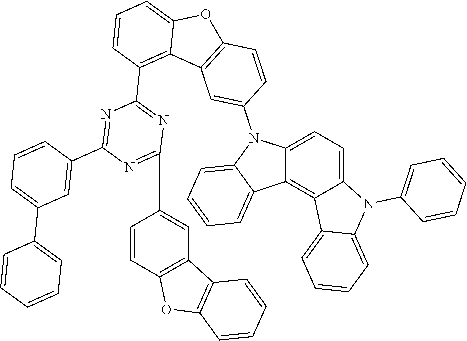 [SMILES: c1ccc(-c2cccc(-c3nc(-c4ccc5oc6ccccc6c5c4)nc(-c4cccc5oc6ccc(-n7c8ccccc8c8c9c%10ccccc%10n(-c%10ccccc%10)c9ccc87)cc6c45)n3)c2)cc1] | 1-66 |
| 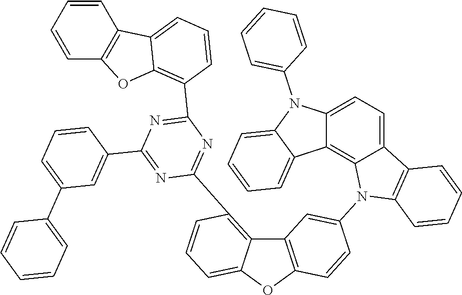 [SMILES: c1ccc(-c2cccc(-c3nc(-c4cccc5c4oc4ccccc45)nc(-c4cccc5oc6ccc(-n7c8ccccc8c8ccc9c(c%10ccccc%10n9-c9ccccc9)c87)cc6c45)n3)c2)cc1] | 1-67 |
| 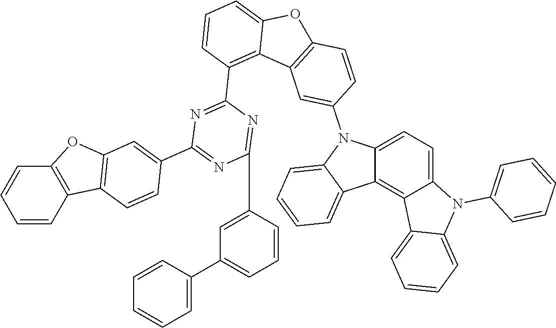 [SMILES: c1ccc(-c2cccc(-c3nc(-c4ccc5c(c4)oc4ccccc45)nc(-c4cccc5oc6ccc(-n7c8ccccc8c8c9c%10ccccc%10n(-c%10ccccc%10)c9ccc87)cc6c45)n3)c2)cc1] | 1-68 |
| 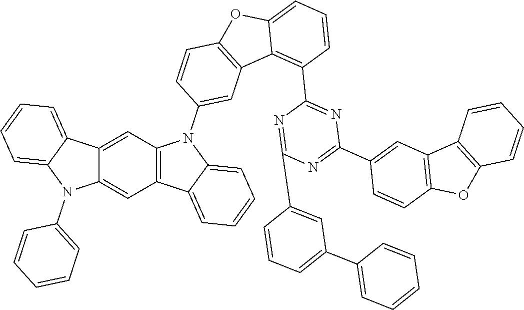 [SMILES: c1ccc(-c2cccc(-c3nc(-c4ccc5oc6ccccc6c5c4)nc(-c4cccc5oc6ccc(-n7c8ccccc8c8cc9c(cc87)c7ccccc7n9-c7ccccc7)cc6c45)n3)c2)cc1] | 1-69 |
| 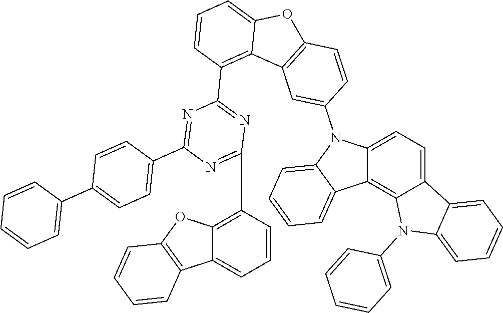 [SMILES: c1ccc(-c2ccc(-c3nc(-c4cccc5c4oc4ccccc45)nc(-c4cccc5oc6ccc(-n7c8ccccc8c8c7ccc7c9ccccc9n(-c9ccccc9)c78)cc6c45)n3)cc2)cc1] | 1-70 |
| 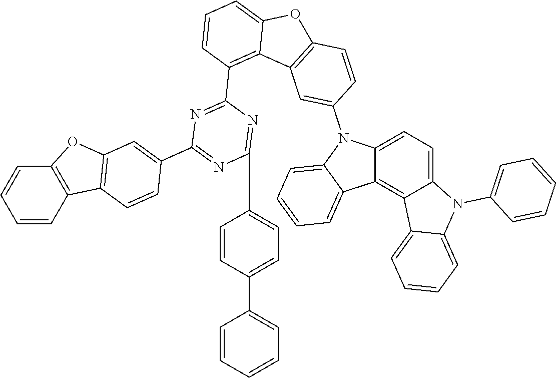 [SMILES: c1ccc(-c2ccc(-c3nc(-c4ccc5c(c4)oc4ccccc45)nc(-c4cccc5oc6ccc(-n7c8ccccc8c8c9c%10ccccc%10n(-c%10ccccc%10)c9ccc87)cc6c45)n3)cc2)cc1] | 1-71 |
| 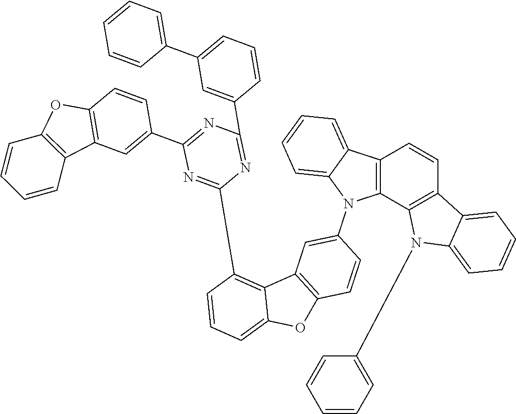 [SMILES: c1ccc(-c2cccc(-c3nc(-c4ccc5oc6ccccc6c5c4)nc(-c4cccc5oc6ccc(-n7c8ccccc8c8ccc9c%10ccccc%10n(-c%10ccccc%10)c9c87)cc6c45)n3)c2)cc1] | 1-72 |
| 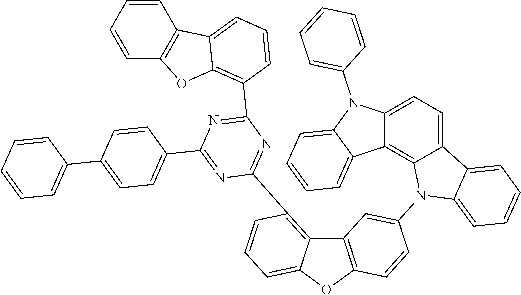 [SMILES: c1ccc(-c2ccc(-c3nc(-c4cccc5c4oc4ccccc45)nc(-c4cccc5oc6ccc(-n7c8ccccc8c8ccc9c(c%10ccccc%10n9-c9ccccc9)c87)cc6c45)n3)cc2)cc1] | 1-73 |
| 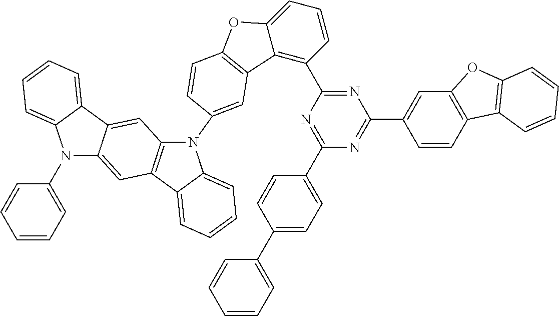 [SMILES: c1ccc(-c2ccc(-c3nc(-c4ccc5c(c4)oc4ccccc45)nc(-c4cccc5oc6ccc(-n7c8ccccc8c8cc9c(cc87)c7ccccc7n9-c7ccccc7)cc6c45)n3)cc2)cc1] | 1-74 |
| 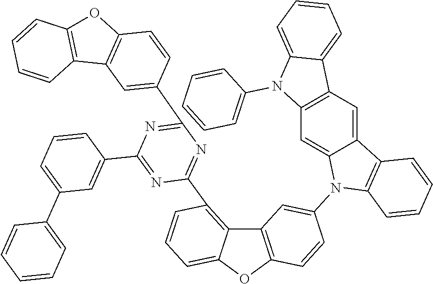 [SMILES: c1ccc(-c2cccc(-c3nc(-c4ccc5oc6ccccc6c5c4)nc(-c4cccc5oc6ccc(-n7c8ccccc8c8cc9c%10ccccc%10n(-c%10ccccc%10)c9cc87)cc6c45)n3)c2)cc1] | 1-75 |
| 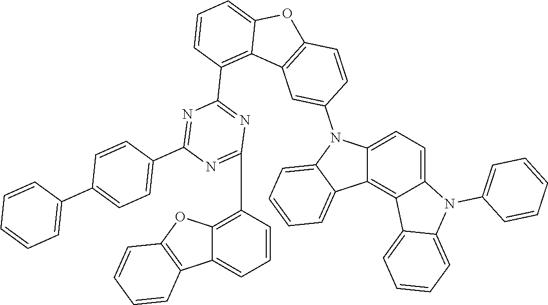 [SMILES: c1ccc(-c2ccc(-c3nc(-c4cccc5c4oc4ccccc45)nc(-c4cccc5oc6ccc(-n7c8ccccc8c8c9c%10ccccc%10n(-c%10ccccc%10)c9ccc87)cc6c45)n3)cc2)cc1] | 1-76 |
| 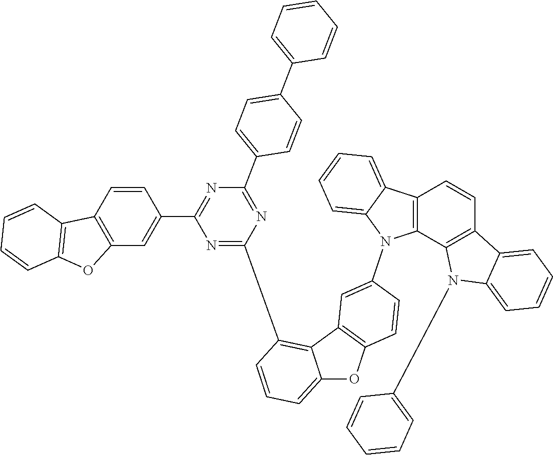 [SMILES: c1ccc(-c2ccc(-c3nc(-c4ccc5c(c4)oc4ccccc45)nc(-c4cccc5oc6ccc(-n7c8ccccc8c8ccc9c%10ccccc%10n(-c%10ccccc%10)c9c87)cc6c45)n3)cc2)cc1] | 1-77 |
| 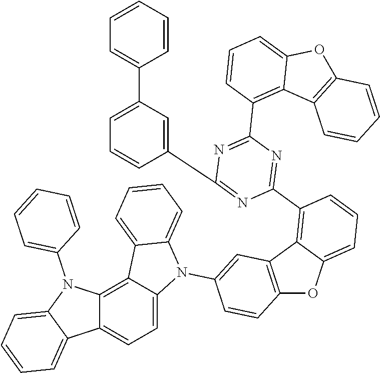 [SMILES: c1ccc(-c2cccc(-c3nc(-c4cccc5oc6ccccc6c45)nc(-c4cccc5oc6ccc(-n7c8ccccc8c8c7ccc7c9ccccc9n(-c9ccccc9)c78)cc6c45)n3)c2)cc1] | 1-78 |
| 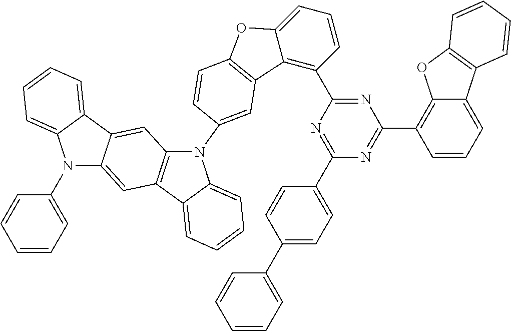 [SMILES: c1ccc(-c2ccc(-c3nc(-c4cccc5c4oc4ccccc45)nc(-c4cccc5oc6ccc(-n7c8ccccc8c8cc9c(cc87)c7ccccc7n9-c7ccccc7)cc6c45)n3)cc2)cc1] | 1-79 |
| 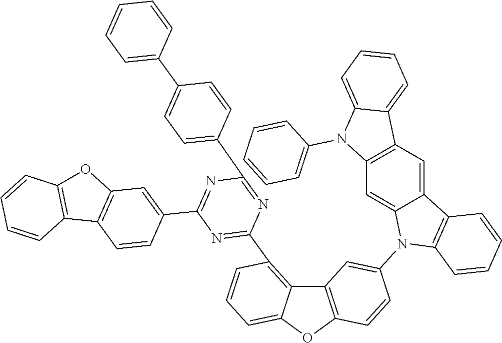 [SMILES: c1ccc(-c2ccc(-c3nc(-c4ccc5c(c4)oc4ccccc45)nc(-c4cccc5oc6ccc(-n7c8ccccc8c8cc9c%10ccccc%10n(-c%10ccccc%10)c9cc87)cc6c45)n3)cc2)cc1] | 1-80 |
| 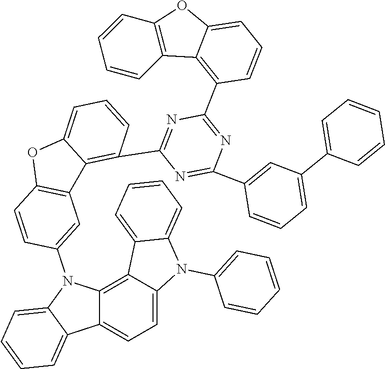 [SMILES: c1ccc(-c2cccc(-c3nc(-c4cccc5oc6ccccc6c45)nc(-c4cccc5oc6ccc(-n7c8ccccc8c8ccc9c(c%10ccccc%10n9-c9ccccc9)c87)cc6c45)n3)c2)cc1] | 1-81 |
| 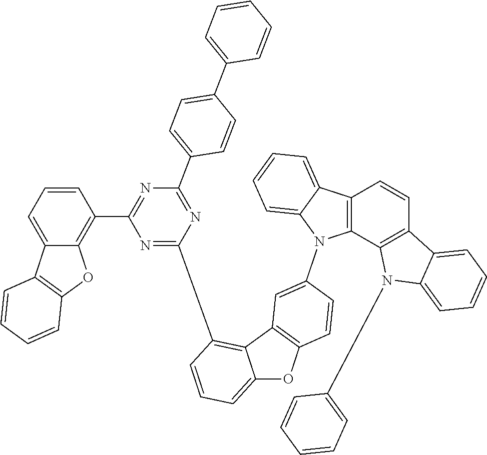 [SMILES: c1ccc(-c2ccc(-c3nc(-c4cccc5c4oc4ccccc45)nc(-c4cccc5oc6ccc(-n7c8ccccc8c8ccc9c%10ccccc%10n(-c%10ccccc%10)c9c87)cc6c45)n3)cc2)cc1] | 1-82 |
| 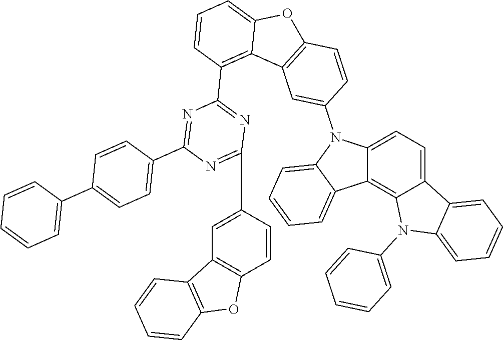 [SMILES: c1ccc(-c2ccc(-c3nc(-c4ccc5oc6ccccc6c5c4)nc(-c4cccc5oc6ccc(-n7c8ccccc8c8c7ccc7c9ccccc9n(-c9ccccc9)c78)cc6c45)n3)cc2)cc1] | 1-83 |
| 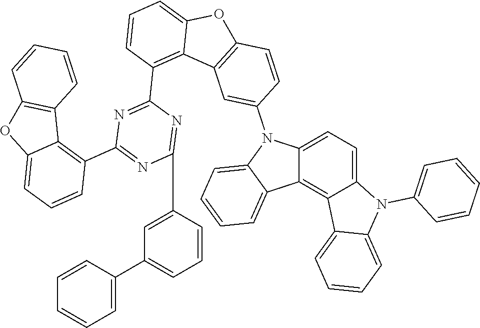 [SMILES: c1ccc(-c2cccc(-c3nc(-c4cccc5oc6ccccc6c45)nc(-c4cccc5oc6ccc(-n7c8ccccc8c8c9c%10ccccc%10n(-c%10ccccc%10)c9ccc87)cc6c45)n3)c2)cc1] | 1-84 |
| 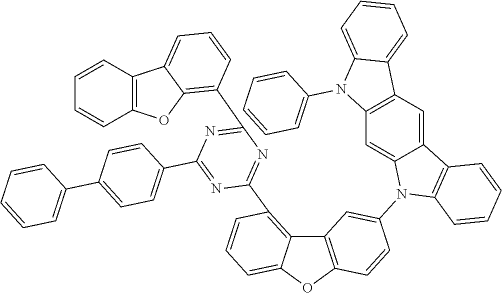 [SMILES: c1ccc(-c2ccc(-c3nc(-c4cccc5c4oc4ccccc45)nc(-c4cccc5oc6ccc(-n7c8ccccc8c8cc9c%10ccccc%10n(-c%10ccccc%10)c9cc87)cc6c45)n3)cc2)cc1] | 1-85 |
| 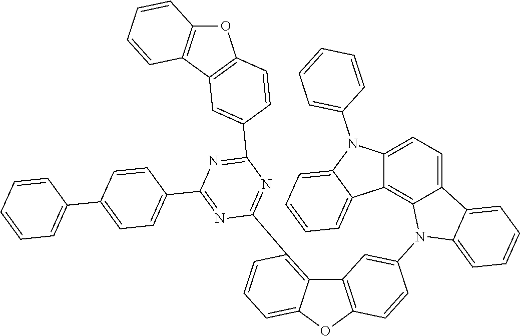 [SMILES: c1ccc(-c2ccc(-c3nc(-c4ccc5oc6ccccc6c5c4)nc(-c4cccc5oc6ccc(-n7c8ccccc8c8ccc9c(c%10ccccc%10n9-c9ccccc9)c87)cc6c45)n3)cc2)cc1] | 1-86 |
| 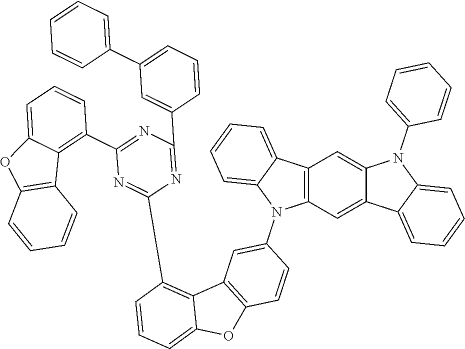 [SMILES: c1ccc(-c2cccc(-c3nc(-c4cccc5oc6ccccc6c45)nc(-c4cccc5oc6ccc(-n7c8ccccc8c8cc9c(cc87)c7ccccc7n9-c7ccccc7)cc6c45)n3)c2)cc1] | 1-87 |
| 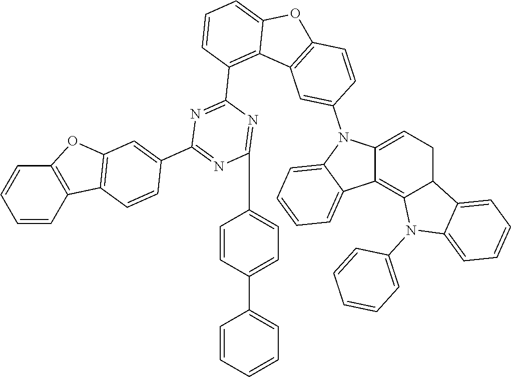 [SMILES: C1=c2c(c3ccccc3n2-c2ccc3oc4cccc(-c5nc(-c6ccc(-c7ccccc7)cc6)nc(-c6ccc7c(c6)oc6ccccc67)n5)c4c3c2)=C2C(C1)c1ccccc1N2c1ccccc1] | 1-88 |
| 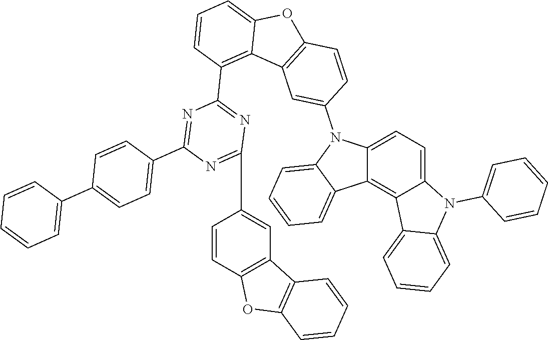 [SMILES: c1ccc(-c2ccc(-c3nc(-c4ccc5oc6ccccc6c5c4)nc(-c4cccc5oc6ccc(-n7c8ccccc8c8c9c%10ccccc%10n(-c%10ccccc%10)c9ccc87)cc6c45)n3)cc2)cc1] | 1-89 |
| 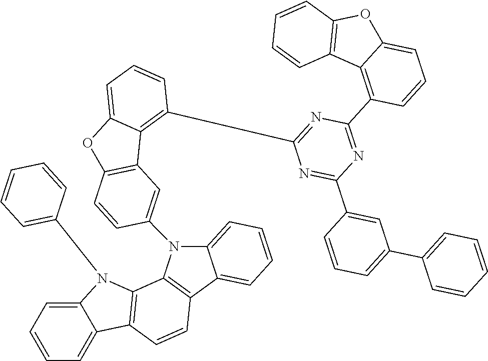 [SMILES: c1ccc(-c2cccc(-c3nc(-c4cccc5oc6ccccc6c45)nc(-c4cccc5oc6ccc(-n7c8ccccc8c8ccc9c%10ccccc%10n(-c%10ccccc%10)c9c87)cc6c45)n3)c2)cc1] | 1-90 |
| 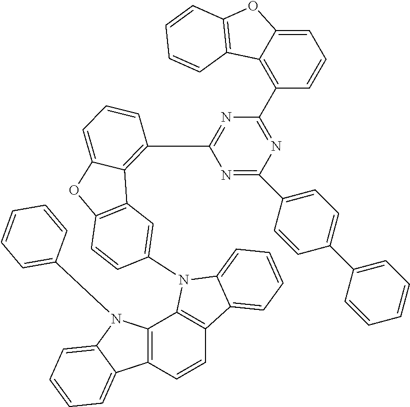 [SMILES: c1ccc(-c2ccc(-c3nc(-c4cccc5oc6ccccc6c45)nc(-c4cccc5oc6ccc(-n7c8ccccc8c8ccc9c%10ccccc%10n(-c%10ccccc%10)c9c87)cc6c45)n3)cc2)cc1] | 1-91 |
| 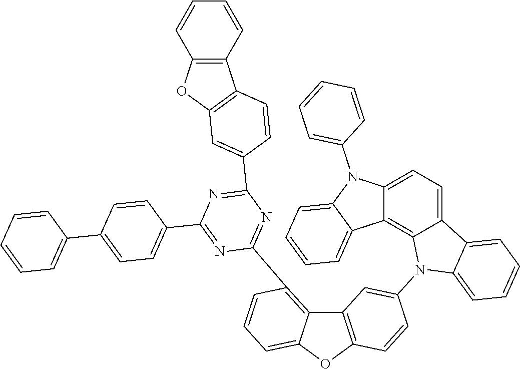 [SMILES: c1ccc(-c2ccc(-c3nc(-c4ccc5c(c4)oc4ccccc45)nc(-c4cccc5oc6ccc(-n7c8ccccc8c8ccc9c(c%10ccccc%10n9-c9ccccc9)c87)cc6c45)n3)cc2)cc1] | 1-92 |
| 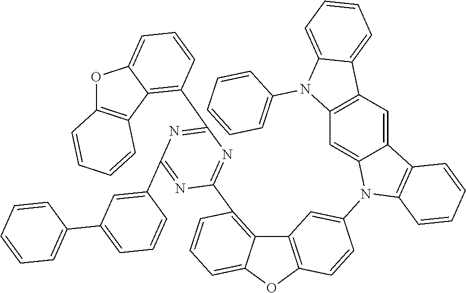 [SMILES: c1ccc(-c2cccc(-c3nc(-c4cccc5oc6ccccc6c45)nc(-c4cccc5oc6ccc(-n7c8ccccc8c8cc9c%10ccccc%10n(-c%10ccccc%10)c9cc87)cc6c45)n3)c2)cc1] | 1-93 |
| 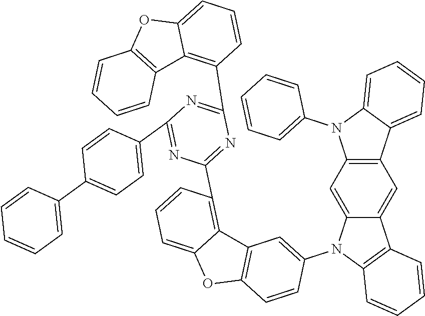 [SMILES: c1ccc(-c2ccc(-c3nc(-c4cccc5oc6ccccc6c45)nc(-c4cccc5oc6ccc(-n7c8ccccc8c8cc9c%10ccccc%10n(-c%10ccccc%10)c9cc87)cc6c45)n3)cc2)cc1] | 1-94 |
| 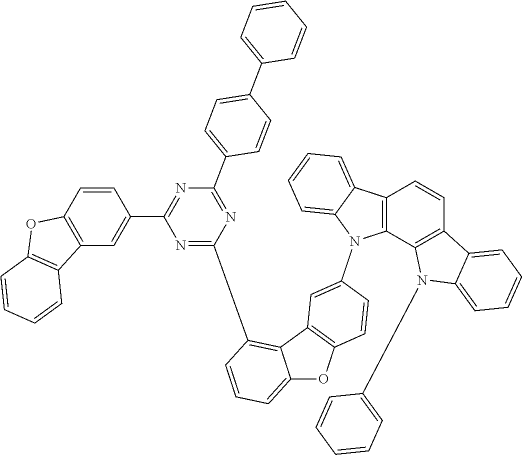 [SMILES: c1ccc(-c2ccc(-c3nc(-c4ccc5oc6ccccc6c5c4)nc(-c4cccc5oc6ccc(-n7c8ccccc8c8ccc9c%10ccccc%10n(-c%10ccccc%10)c9c87)cc6c45)n3)cc2)cc1] | 1-95 |
| 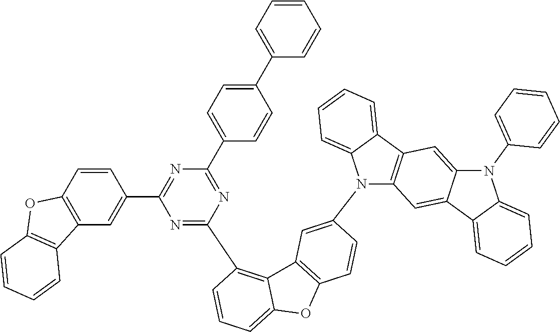 [SMILES: c1ccc(-c2ccc(-c3nc(-c4ccc5oc6ccccc6c5c4)nc(-c4cccc5oc6ccc(-n7c8ccccc8c8cc9c(cc87)c7ccccc7n9-c7ccccc7)cc6c45)n3)cc2)cc1] | 1-96 |
| 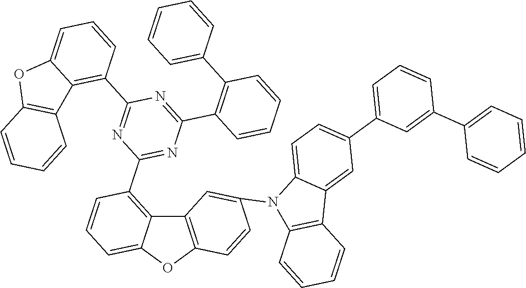 | 1-97 |
| 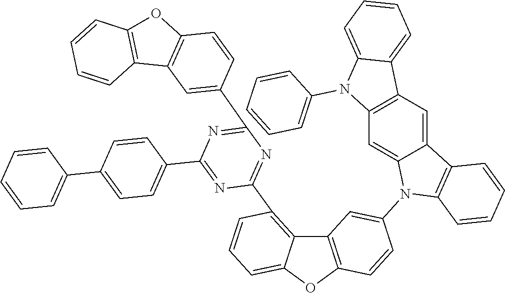 [SMILES: c1ccc(-c2ccc(-c3nc(-c4ccc5oc6ccccc6c5c4)nc(-c4cccc5oc6ccc(-n7c8ccccc8c8cc9c%10ccccc%10n(-c%10ccccc%10)c9cc87)cc6c45)n3)cc2)cc1] | 1-98 |
| 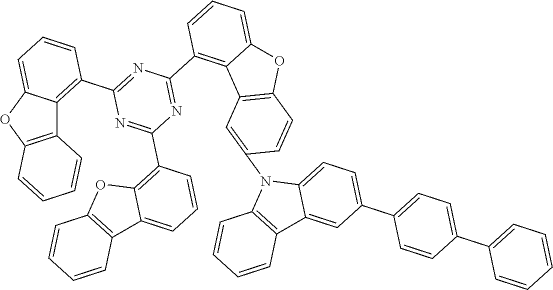 [SMILES: c1ccc(-c2ccc(-c3ccc4c(c3)c3ccccc3n4-c3ccc4oc5cccc(-c6nc(-c7cccc8c7oc7ccccc78)nc(-c7cccc8oc9ccccc9c78)n6)c5c4c3)cc2)cc1] | 1-99 |
| 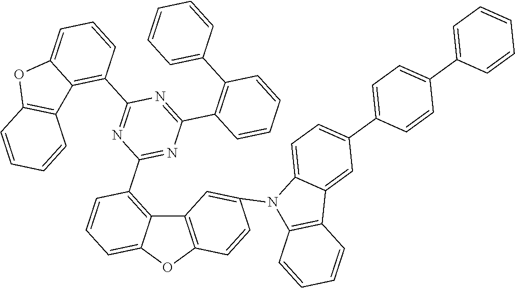 | 1-100 |
| 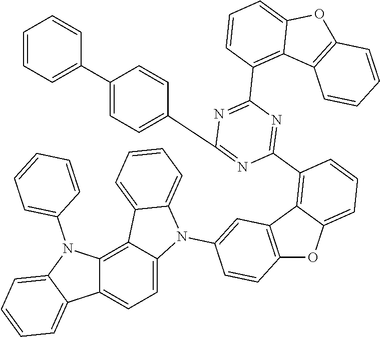 [SMILES: c1ccc(-c2ccc(-c3nc(-c4cccc5oc6ccccc6c45)nc(-c4cccc5oc6ccc(-n7c8ccccc8c8c7ccc7c9ccccc9n(-c9ccccc9)c78)cc6c45)n3)cc2)cc1] | 1-101 |
| 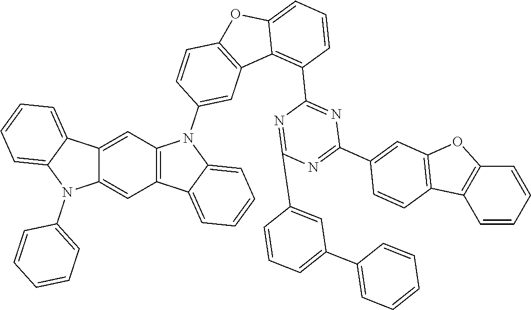 [SMILES: c1ccc(-c2cccc(-c3nc(-c4ccc5c(c4)oc4ccccc45)nc(-c4cccc5oc6ccc(-n7c8ccccc8c8cc9c(cc87)c7ccccc7n9-c7ccccc7)cc6c45)n3)c2)cc1] | 1-102 |
| 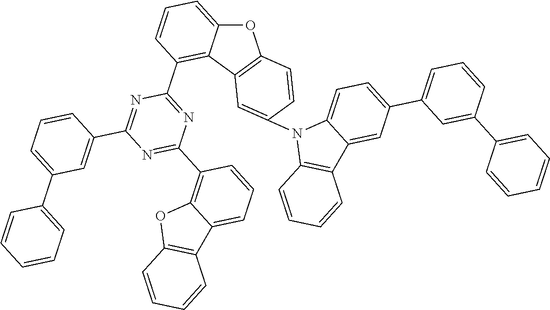 [SMILES: c1ccc(-c2cccc(-c3ccc4c(c3)c3ccccc3n4-c3ccc4oc5cccc(-c6nc(-c7cccc(-c8ccccc8)c7)nc(-c7cccc8c7oc7ccccc78)n6)c5c4c3)c2)cc1] | 1-103 |
| 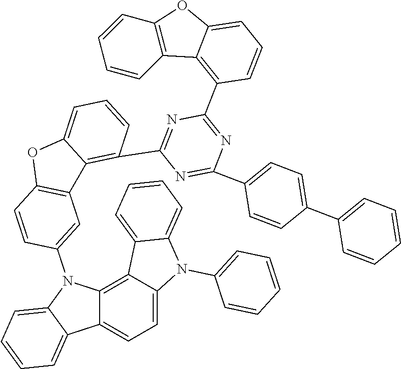 [SMILES: c1ccc(-c2ccc(-c3nc(-c4cccc5oc6ccccc6c45)nc(-c4cccc5oc6ccc(-n7c8ccccc8c8ccc9c(c%10ccccc%10n9-c9ccccc9)c87)cc6c45)n3)cc2)cc1] | 1-104 |
| 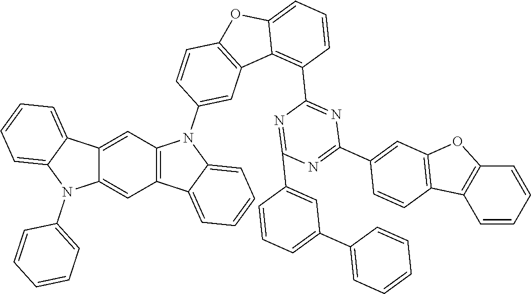 [SMILES: c1ccc(-c2cccc(-c3nc(-c4ccc5c(c4)oc4ccccc45)nc(-c4cccc5oc6ccc(-n7c8ccccc8c8cc9c(cc87)c7ccccc7n9-c7ccccc7)cc6c45)n3)c2)cc1] | 1-105 |
| 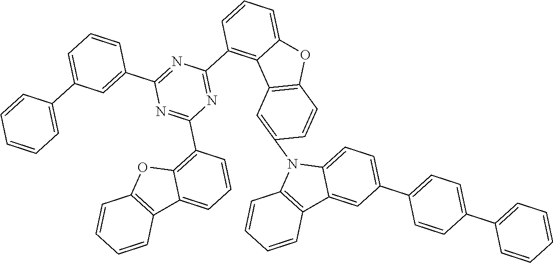 [SMILES: c1ccc(-c2ccc(-c3ccc4c(c3)c3ccccc3n4-c3ccc4oc5cccc(-c6nc(-c7cccc(-c8ccccc8)c7)nc(-c7cccc8c7oc7ccccc78)n6)c5c4c3)cc2)cc1] | 1-106 |
| 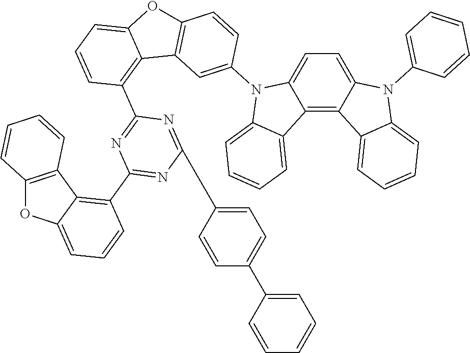 [SMILES: c1ccc(-c2ccc(-c3nc(-c4cccc5oc6ccccc6c45)nc(-c4cccc5oc6ccc(-n7c8ccccc8c8c9c%10ccccc%10n(-c%10ccccc%10)c9ccc87)cc6c45)n3)cc2)cc1] | 1-107 |
| 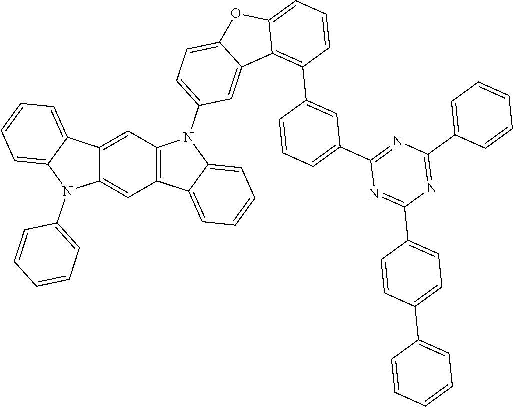 [SMILES: c1ccc(-c2ccc(-c3nc(-c4ccccc4)nc(-c4cccc(-c5cccc6oc7ccc(-n8c9ccccc9c9cc%10c(cc98)c8ccccc8n%10-c8ccccc8)cc7c56)c4)n3)cc2)cc1] | 1-108 |
| 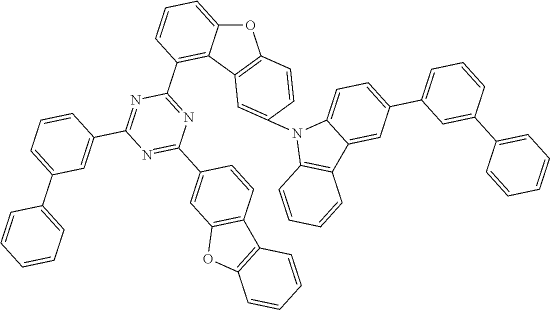 [SMILES: c1ccc(-c2cccc(-c3ccc4c(c3)c3ccccc3n4-c3ccc4oc5cccc(-c6nc(-c7cccc(-c8ccccc8)c7)nc(-c7ccc8c(c7)oc7ccccc78)n6)c5c4c3)c2)cc1] | 1-109 |
| 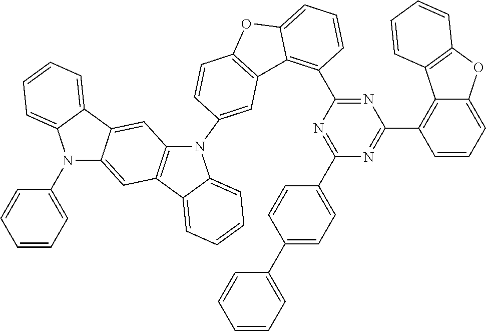 [SMILES: c1ccc(-c2ccc(-c3nc(-c4cccc5oc6ccccc6c45)nc(-c4cccc5oc6ccc(-n7c8ccccc8c8cc9c(cc87)c7ccccc7n9-c7ccccc7)cc6c45)n3)cc2)cc1] | 1-110 |
| 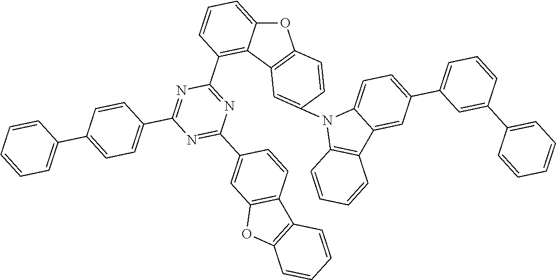 [SMILES: c1ccc(-c2ccc(-c3nc(-c4ccc5c(c4)oc4ccccc45)nc(-c4cccc5oc6ccc(-n7c8ccccc8c8cc(-c9cccc(-c%10ccccc%10)c9)ccc87)cc6c45)n3)cc2)cc1] | 1-111 |
| 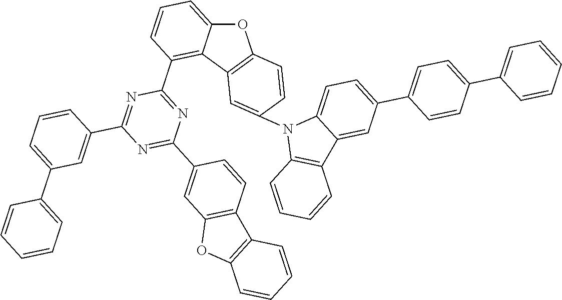 [SMILES: c1ccc(-c2ccc(-c3ccc4c(c3)c3ccccc3n4-c3ccc4oc5cccc(-c6nc(-c7cccc(-c8ccccc8)c7)nc(-c7ccc8c(c7)oc7ccccc78)n6)c5c4c3)cc2)cc1] | 1-112 |
| 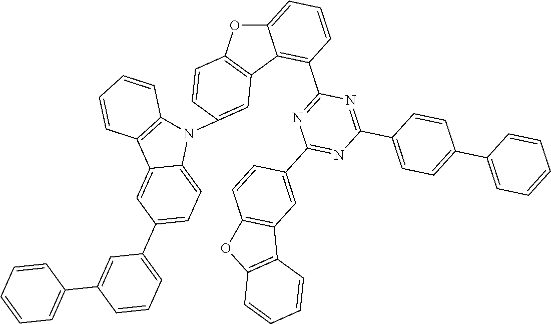 [SMILES: c1ccc(-c2ccc(-c3nc(-c4ccc5oc6ccccc6c5c4)nc(-c4cccc5oc6ccc(-n7c8ccccc8c8cc(-c9cccc(-c%10ccccc%10)c9)ccc87)cc6c45)n3)cc2)cc1] | 1-113 |
| 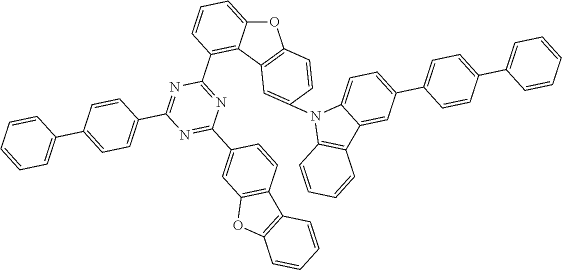 [SMILES: c1ccc(-c2ccc(-c3ccc4c(c3)c3ccccc3n4-c3ccc4oc5cccc(-c6nc(-c7ccc(-c8ccccc8)cc7)nc(-c7ccc8c(c7)oc7ccccc78)n6)c5c4c3)cc2)cc1] | 1-114 |
| 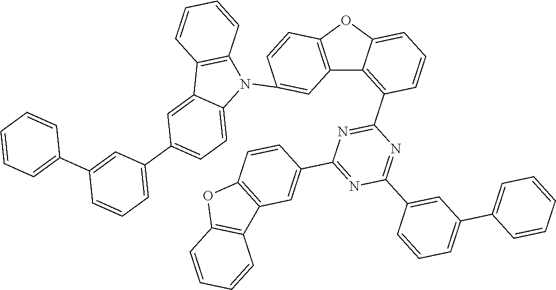 [SMILES: c1ccc(-c2cccc(-c3ccc4c(c3)c3ccccc3n4-c3ccc4oc5cccc(-c6nc(-c7cccc(-c8ccccc8)c7)nc(-c7ccc8oc9ccccc9c8c7)n6)c5c4c3)c2)cc1] | 1-115 |
| 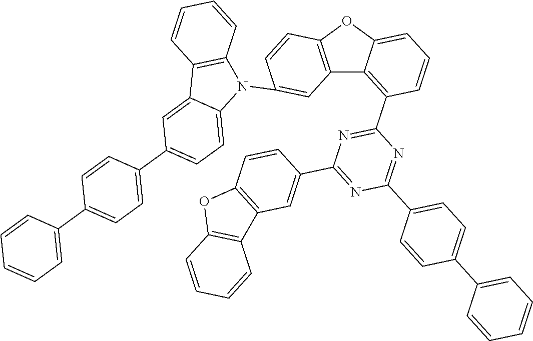 [SMILES: c1ccc(-c2ccc(-c3ccc4c(c3)c3ccccc3n4-c3ccc4oc5cccc(-c6nc(-c7ccc(-c8ccccc8)cc7)nc(-c7ccc8oc9ccccc9c8c7)n6)c5c4c3)cc2)cc1] | 1-116 |
| 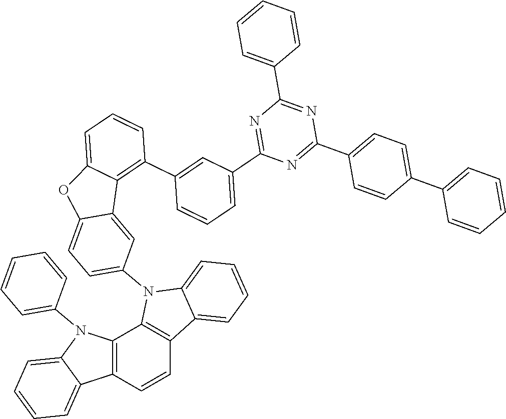 [SMILES: c1ccc(-c2ccc(-c3nc(-c4ccccc4)nc(-c4cccc(-c5cccc6oc7ccc(-n8c9ccccc9c9ccc%10c%11ccccc%11n(-c%11ccccc%11)c%10c98)cc7c56)c4)n3)cc2)cc1] | 1-117 |
| 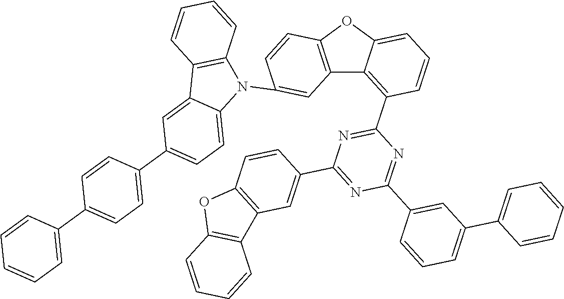 [SMILES: c1ccc(-c2ccc(-c3ccc4c(c3)c3ccccc3n4-c3ccc4oc5cccc(-c6nc(-c7cccc(-c8ccccc8)c7)nc(-c7ccc8oc9ccccc9c8c7)n6)c5c4c3)cc2)cc1] | 1-118 |
| 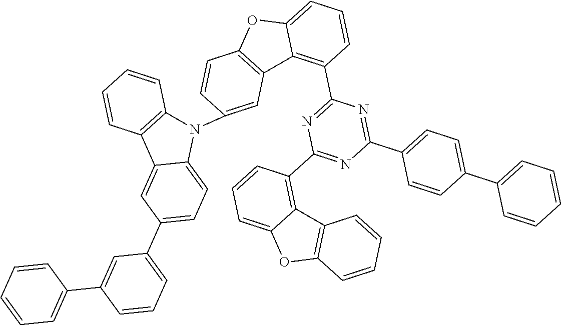 [SMILES: c1ccc(-c2ccc(-c3nc(-c4cccc5oc6ccccc6c45)nc(-c4cccc5oc6ccc(-n7c8ccccc8c8cc(-c9cccc(-c%10ccccc%10)c9)ccc87)cc6c45)n3)cc2)cc1] | 1-119 |
| 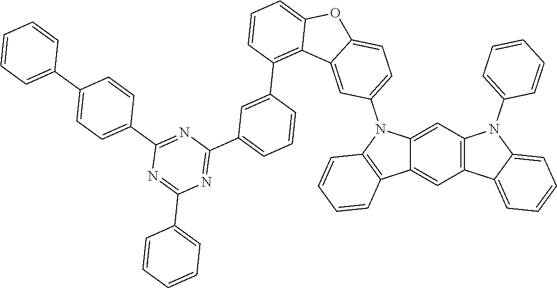 [SMILES: c1ccc(-c2ccc(-c3nc(-c4ccccc4)nc(-c4cccc(-c5cccc6oc7ccc(-n8c9ccccc9c9cc%10c%11ccccc%11n(-c%11ccccc%11)c%10cc98)cc7c56)c4)n3)cc2)cc1] | 1-120 |
| 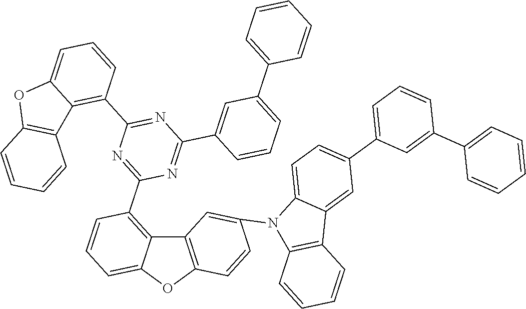 [SMILES: c1ccc(-c2cccc(-c3ccc4c(c3)c3ccccc3n4-c3ccc4oc5cccc(-c6nc(-c7cccc(-c8ccccc8)c7)nc(-c7cccc8oc9ccccc9c78)n6)c5c4c3)c2)cc1] | 1-121 |
| 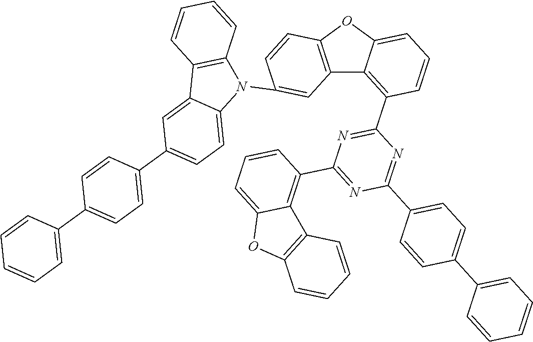 [SMILES: c1ccc(-c2ccc(-c3ccc4c(c3)c3ccccc3n4-c3ccc4oc5cccc(-c6nc(-c7ccc(-c8ccccc8)cc7)nc(-c7cccc8oc9ccccc9c78)n6)c5c4c3)cc2)cc1] | 1-122 |
| 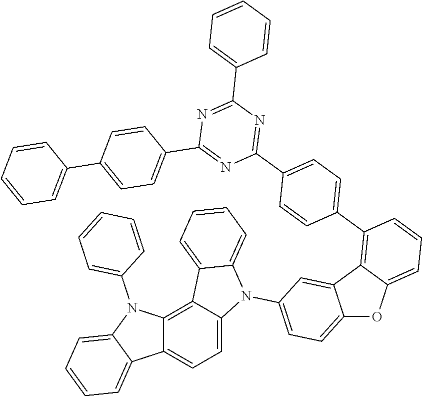 [SMILES: c1ccc(-c2ccc(-c3nc(-c4ccccc4)nc(-c4ccc(-c5cccc6oc7ccc(-n8c9ccccc9c9c8ccc8c%10ccccc%10n(-c%10ccccc%10)c89)cc7c56)cc4)n3)cc2)cc1] | 1-123 |
| 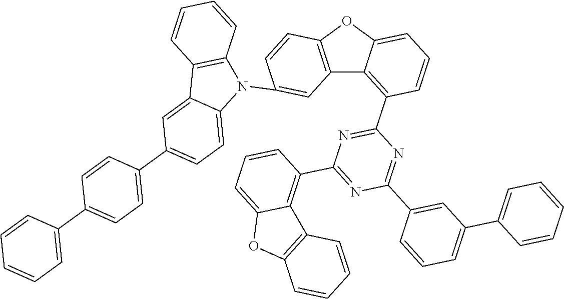 [SMILES: c1ccc(-c2ccc(-c3ccc4c(c3)c3ccccc3n4-c3ccc4oc5cccc(-c6nc(-c7cccc(-c8ccccc8)c7)nc(-c7cccc8oc9ccccc9c78)n6)c5c4c3)cc2)cc1] | 1-124 |
| 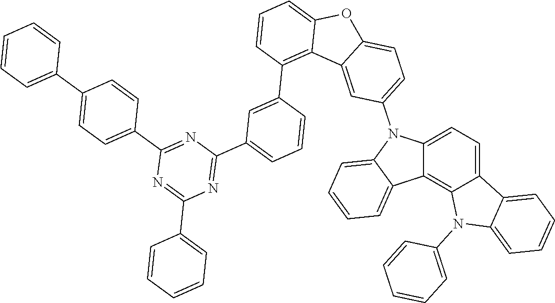 [SMILES: c1ccc(-c2ccc(-c3nc(-c4ccccc4)nc(-c4cccc(-c5cccc6oc7ccc(-n8c9ccccc9c9c8ccc8c%10ccccc%10n(-c%10ccccc%10)c89)cc7c56)c4)n3)cc2)cc1] | 1-125 |
| 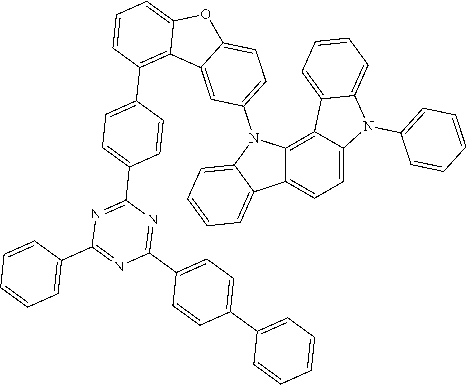 [SMILES: c1ccc(-c2ccc(-c3nc(-c4ccccc4)nc(-c4ccc(-c5cccc6oc7ccc(-n8c9ccccc9c9ccc%10c(c%11ccccc%11n%10-c%10ccccc%10)c98)cc7c56)cc4)n3)cc2)cc1] | 1-126 |
| 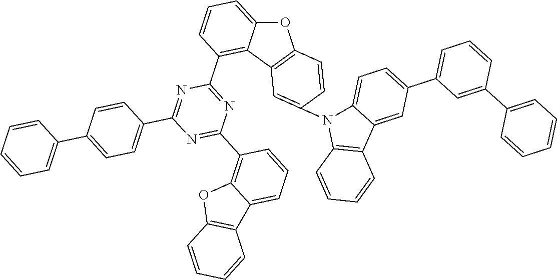 [SMILES: c1ccc(-c2ccc(-c3nc(-c4cccc5c4oc4ccccc45)nc(-c4cccc5oc6ccc(-n7c8ccccc8c8cc(-c9cccc(-c%10ccccc%10)c9)ccc87)cc6c45)n3)cc2)cc1] | 1-127 |
| 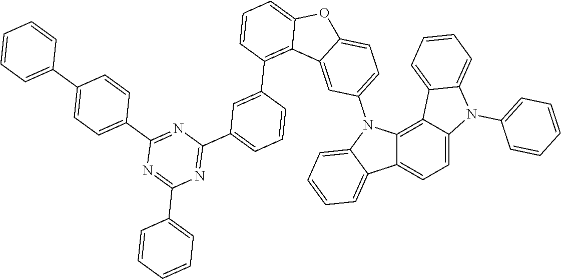 [SMILES: c1ccc(-c2ccc(-c3nc(-c4ccccc4)nc(-c4cccc(-c5cccc6oc7ccc(-n8c9ccccc9c9ccc%10c(c%11ccccc%11n%10-c%10ccccc%10)c98)cc7c56)c4)n3)cc2)cc1] | 1-128 |
| 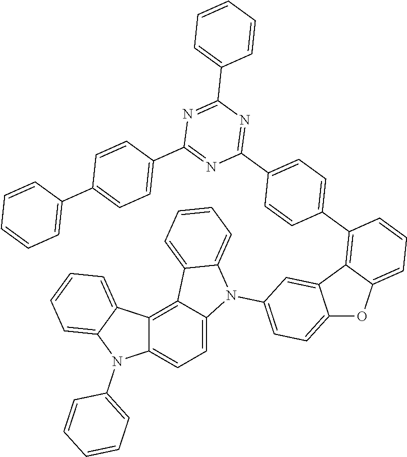 [SMILES: c1ccc(-c2ccc(-c3nc(-c4ccccc4)nc(-c4ccc(-c5cccc6oc7ccc(-n8c9ccccc9c9c%10c%11ccccc%11n(-c%11ccccc%11)c%10ccc98)cc7c56)cc4)n3)cc2)cc1] | 1-129 |
| 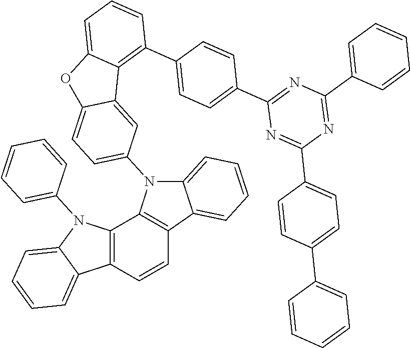 [SMILES: c1ccc(-c2ccc(-c3nc(-c4ccccc4)nc(-c4ccc(-c5cccc6oc7ccc(-n8c9ccccc9c9ccc%10c%11ccccc%11n(-c%11ccccc%11)c%10c98)cc7c56)cc4)n3)cc2)cc1] | 1-130 |
| 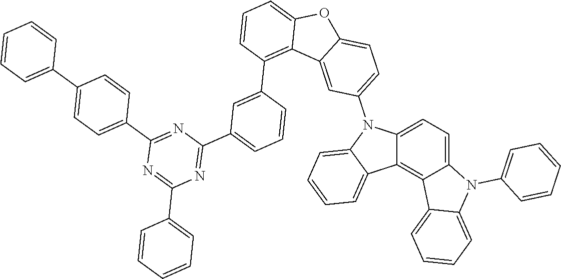 [SMILES: c1ccc(-c2ccc(-c3nc(-c4ccccc4)nc(-c4cccc(-c5cccc6oc7ccc(-n8c9ccccc9c9c%10c%11ccccc%11n(-c%11ccccc%11)c%10ccc98)cc7c56)c4)n3)cc2)cc1] | 1-131 |
| 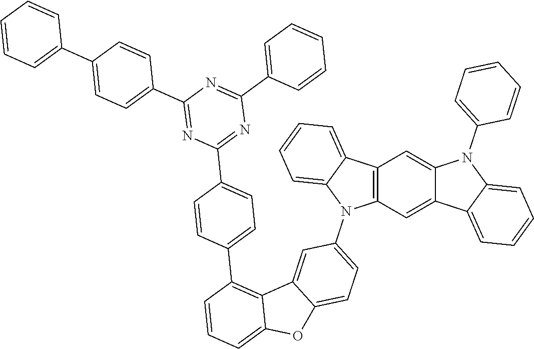 [SMILES: c1ccc(-c2ccc(-c3nc(-c4ccccc4)nc(-c4ccc(-c5cccc6oc7ccc(-n8c9ccccc9c9cc%10c(cc98)c8ccccc8n%10-c8ccccc8)cc7c56)cc4)n3)cc2)cc1] | 1-132 |
| 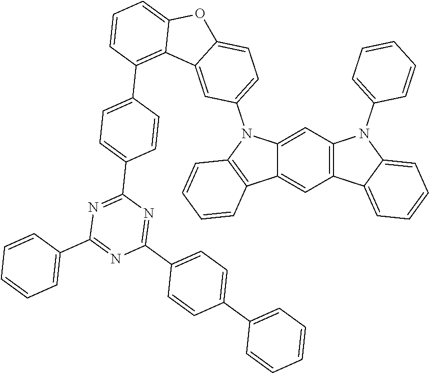 [SMILES: c1ccc(-c2ccc(-c3nc(-c4ccccc4)nc(-c4ccc(-c5cccc6oc7ccc(-n8c9ccccc9c9cc%10c%11ccccc%11n(-c%11ccccc%11)c%10cc98)cc7c56)cc4)n3)cc2)cc1] | 1-133 |
| 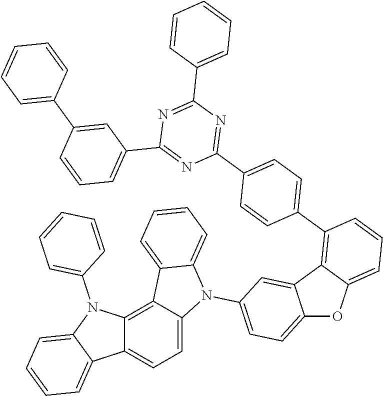 [SMILES: c1ccc(-c2cccc(-c3nc(-c4ccccc4)nc(-c4ccc(-c5cccc6oc7ccc(-n8c9ccccc9c9c8ccc8c%10ccccc%10n(-c%10ccccc%10)c89)cc7c56)cc4)n3)c2)cc1] | 1-134 |
| 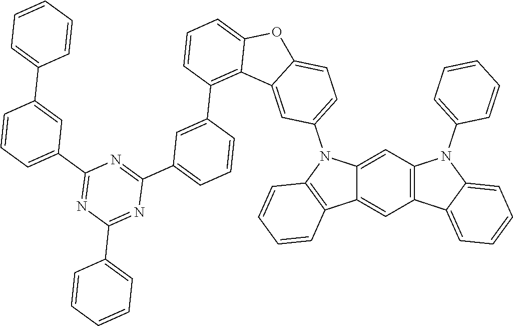 [SMILES: c1ccc(-c2cccc(-c3nc(-c4ccccc4)nc(-c4cccc(-c5cccc6oc7ccc(-n8c9ccccc9c9cc%10c%11ccccc%11n(-c%11ccccc%11)c%10cc98)cc7c56)c4)n3)c2)cc1] | 1-135 |
| 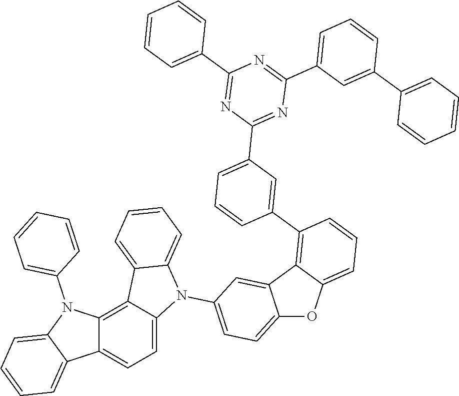 [SMILES: c1ccc(-c2cccc(-c3nc(-c4ccccc4)nc(-c4cccc(-c5cccc6oc7ccc(-n8c9ccccc9c9c8ccc8c%10ccccc%10n(-c%10ccccc%10)c89)cc7c56)c4)n3)c2)cc1] | 1-136 |
| 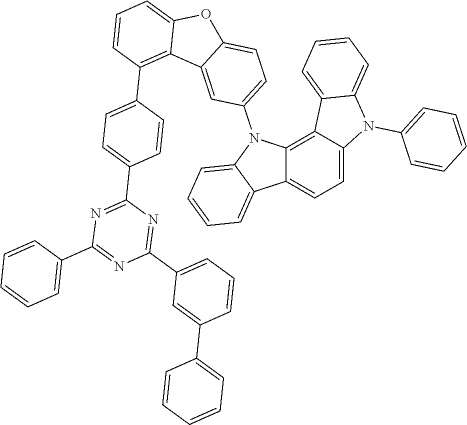 [SMILES: c1ccc(-c2cccc(-c3nc(-c4ccccc4)nc(-c4ccc(-c5cccc6oc7ccc(-n8c9ccccc9c9ccc%10c(c%11ccccc%11n%10-c%10ccccc%10)c98)cc7c56)cc4)n3)c2)cc1] | 1-137 |
| 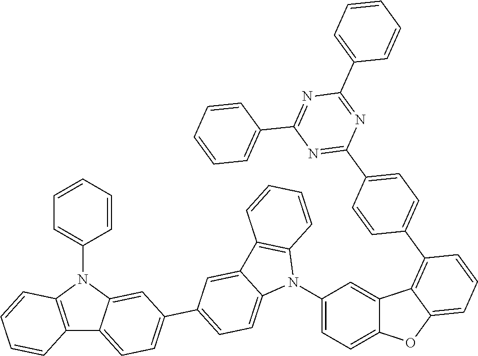 [SMILES: c1ccc(-c2nc(-c3ccccc3)nc(-c3ccc(-c4cccc5oc6ccc(-n7c8ccccc8c8cc(-c9ccc%10c%11ccccc%11n(-c%11ccccc%11)c%10c9)ccc87)cc6c45)cc3)n2)cc1] | 1-138 |
| 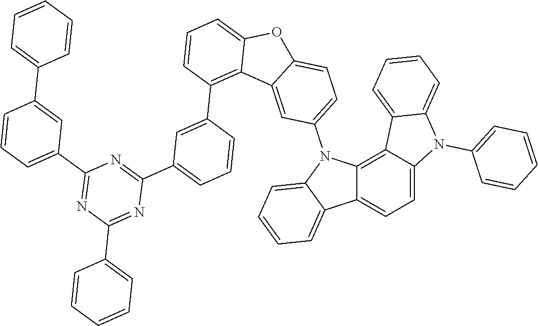 [SMILES: c1ccc(-c2cccc(-c3nc(-c4ccccc4)nc(-c4cccc(-c5cccc6oc7ccc(-n8c9ccccc9c9ccc%10c(c%11ccccc%11n%10-c%10ccccc%10)c98)cc7c56)c4)n3)c2)cc1] | 1-139 |
| 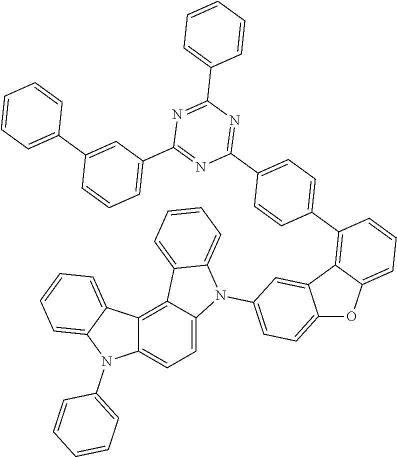 [SMILES: c1ccc(-c2cccc(-c3nc(-c4ccccc4)nc(-c4ccc(-c5cccc6oc7ccc(-n8c9ccccc9c9c%10c%11ccccc%11n(-c%11ccccc%11)c%10ccc98)cc7c56)cc4)n3)c2)cc1] | 1-140 |
| 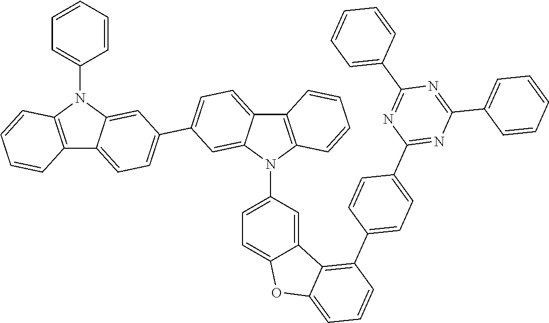 [SMILES: c1ccc(-c2nc(-c3ccccc3)nc(-c3ccc(-c4cccc5oc6ccc(-n7c8ccccc8c8ccc(-c9ccc%10c%11ccccc%11n(-c%11ccccc%11)c%10c9)cc87)cc6c45)cc3)n2)cc1] | 1-141 |
| 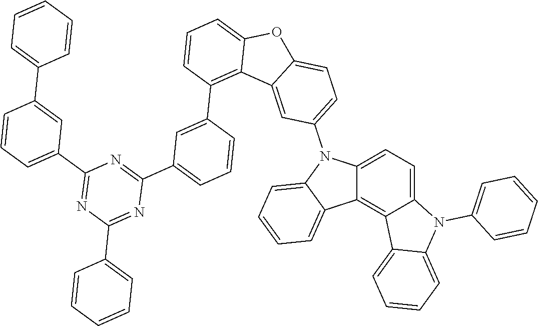 [SMILES: c1ccc(-c2cccc(-c3nc(-c4ccccc4)nc(-c4cccc(-c5cccc6oc7ccc(-n8c9ccccc9c9c%10c%11ccccc%11n(-c%11ccccc%11)c%10ccc98)cc7c56)c4)n3)c2)cc1] | 1-142 |
| 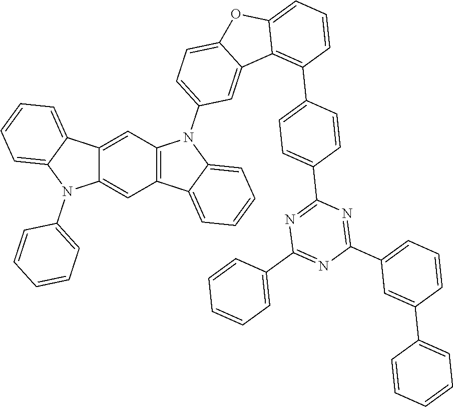 [SMILES: c1ccc(-c2cccc(-c3nc(-c4ccccc4)nc(-c4ccc(-c5cccc6oc7ccc(-n8c9ccccc9c9cc%10c(cc98)c8ccccc8n%10-c8ccccc8)cc7c56)cc4)n3)c2)cc1] | 1-143 |
| 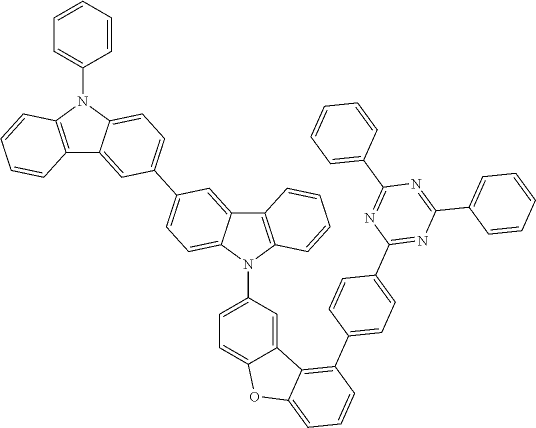 [SMILES: c1ccc(-c2nc(-c3ccccc3)nc(-c3ccc(-c4cccc5oc6ccc(-n7c8ccccc8c8cc(-c9ccc%10c(c9)c9ccccc9n%10-c9ccccc9)ccc87)cc6c45)cc3)n2)cc1] | 1-144 |
| 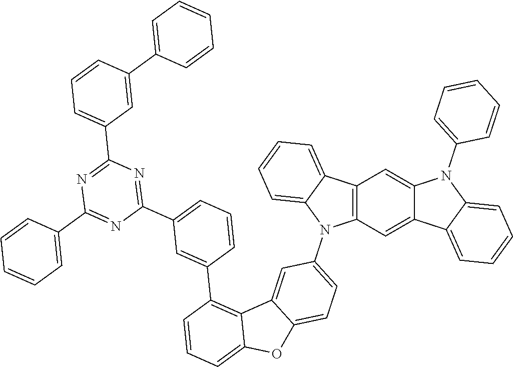 [SMILES: c1ccc(-c2cccc(-c3nc(-c4ccccc4)nc(-c4cccc(-c5cccc6oc7ccc(-n8c9ccccc9c9cc%10c(cc98)c8ccccc8n%10-c8ccccc8)cc7c56)c4)n3)c2)cc1] | 1-145 |
| 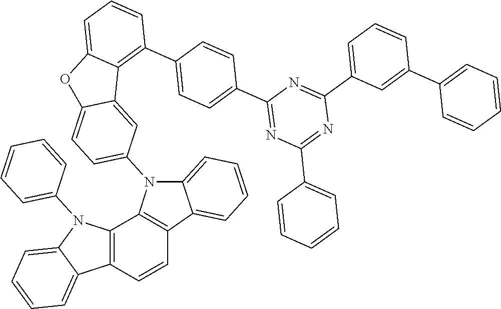 [SMILES: c1ccc(-c2cccc(-c3nc(-c4ccccc4)nc(-c4ccc(-c5cccc6oc7ccc(-n8c9ccccc9c9ccc%10c%11ccccc%11n(-c%11ccccc%11)c%10c98)cc7c56)cc4)n3)c2)cc1] | 1-146 |
| 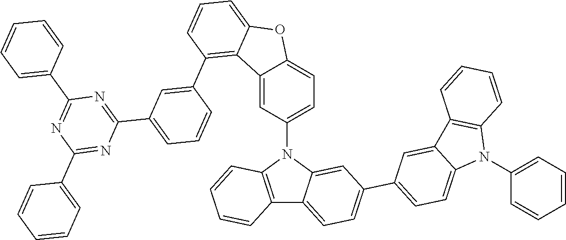 [SMILES: c1ccc(-c2nc(-c3ccccc3)nc(-c3cccc(-c4cccc5oc6ccc(-n7c8ccccc8c8ccc(-c9ccc%10c(c9)c9ccccc9n%10-c9ccccc9)cc87)cc6c45)c3)n2)cc1] | 1-147 |
| 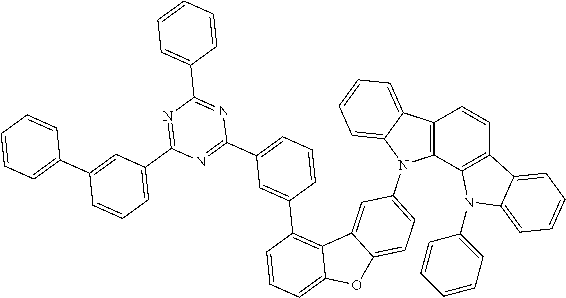 [SMILES: c1ccc(-c2cccc(-c3nc(-c4ccccc4)nc(-c4cccc(-c5cccc6oc7ccc(-n8c9ccccc9c9ccc%10c%11ccccc%11n(-c%11ccccc%11)c%10c98)cc7c56)c4)n3)c2)cc1] | 1-148 |
| 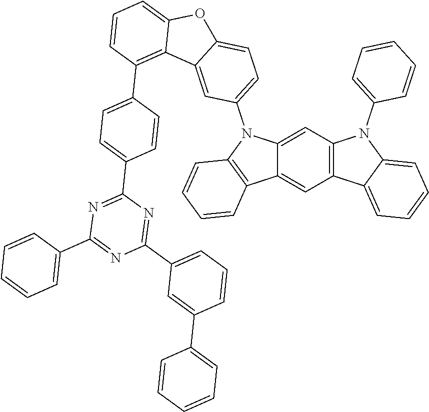 [SMILES: c1ccc(-c2cccc(-c3nc(-c4ccccc4)nc(-c4ccc(-c5cccc6oc7ccc(-n8c9ccccc9c9cc%10c%11ccccc%11n(-c%11ccccc%11)c%10cc98)cc7c56)cc4)n3)c2)cc1] | 1-149 |
| 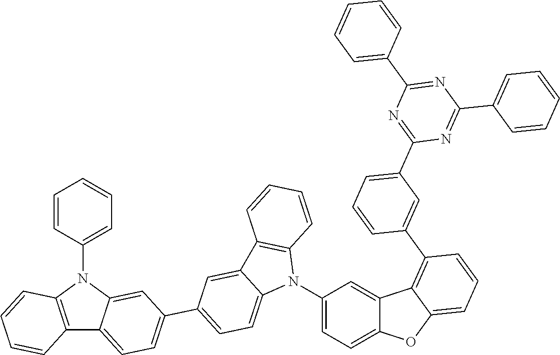 [SMILES: c1ccc(-c2nc(-c3ccccc3)nc(-c3cccc(-c4cccc5oc6ccc(-n7c8ccccc8c8cc(-c9ccc%10c%11ccccc%11n(-c%11ccccc%11)c%10c9)ccc87)cc6c45)c3)n2)cc1] | 1-150 |
| 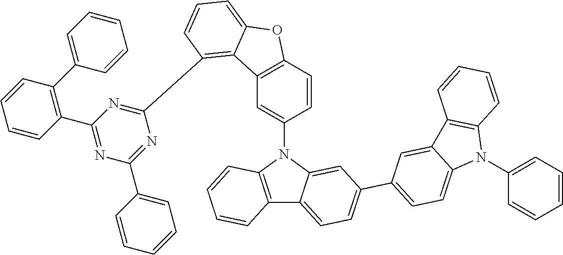 [SMILES: c1ccc(-c2nc(-c3ccccc3-c3ccccc3)nc(-c3cccc4oc5ccc(-n6c7ccccc7c7ccc(-c8ccc9c(c8)c8ccccc8n9-c8ccccc8)cc76)cc5c34)n2)cc1] | 1-151 |
| 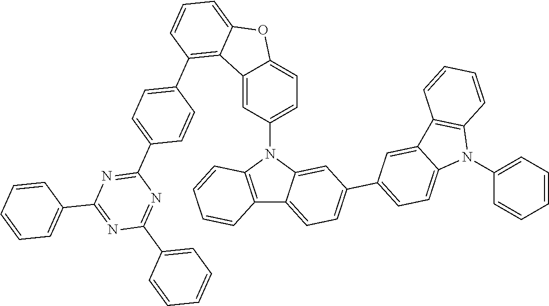 [SMILES: c1ccc(-c2nc(-c3ccccc3)nc(-c3ccc(-c4cccc5oc6ccc(-n7c8ccccc8c8ccc(-c9ccc%10c(c9)c9ccccc9n%10-c9ccccc9)cc87)cc6c45)cc3)n2)cc1] | 1-152 |
| 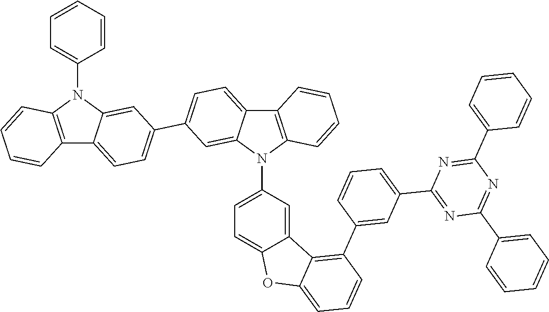 [SMILES: c1ccc(-c2nc(-c3ccccc3)nc(-c3cccc(-c4cccc5oc6ccc(-n7c8ccccc8c8ccc(-c9ccc%10c%11ccccc%11n(-c%11ccccc%11)c%10c9)cc87)cc6c45)c3)n2)cc1] | 1-153 |
| 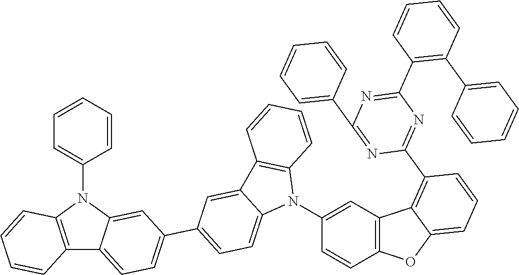 [SMILES: c1ccc(-c2nc(-c3ccccc3-c3ccccc3)nc(-c3cccc4oc5ccc(-n6c7ccccc7c7cc(-c8ccc9c%10ccccc%10n(-c%10ccccc%10)c9c8)ccc76)cc5c34)n2)cc1] | 1-154 |
| 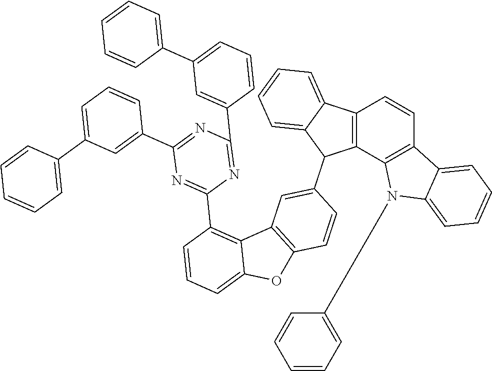 [SMILES: c1ccc(-c2cccc(-c3nc(-c4cccc(-c5ccccc5)c4)nc(-c4cccc5oc6ccc(C7c8ccccc8-c8ccc9c%10ccccc%10n(-c%10ccccc%10)c9c87)cc6c45)n3)c2)cc1] | 1-155 |
| 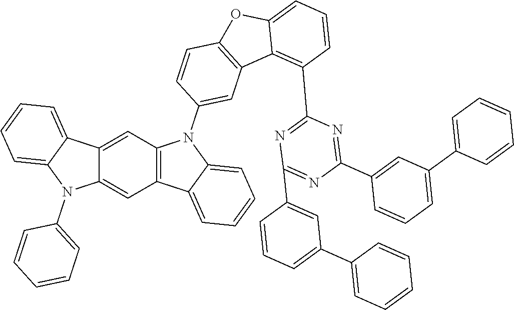 | 1-156 |
| 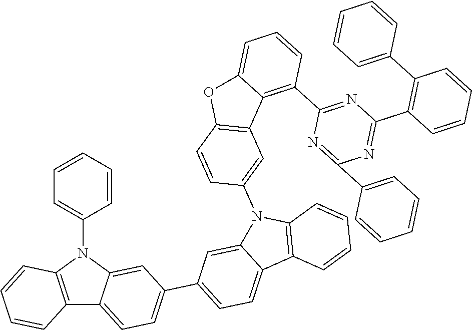 [SMILES: c1ccc(-c2nc(-c3ccccc3-c3ccccc3)nc(-c3cccc4oc5ccc(-n6c7ccccc7c7ccc(-c8ccc9c%10ccccc%10n(-c%10ccccc%10)c9c8)cc76)cc5c34)n2)cc1] | 1-157 |
| 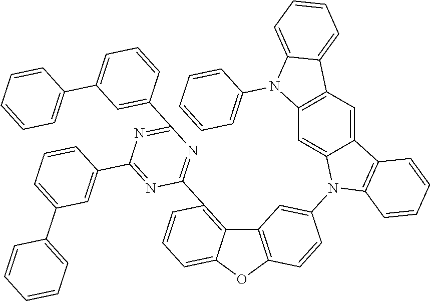 [SMILES: c1ccc(-c2cccc(-c3nc(-c4cccc(-c5ccccc5)c4)nc(-c4cccc5oc6ccc(-n7c8ccccc8c8cc9c%10ccccc%10n(-c%10ccccc%10)c9cc87)cc6c45)n3)c2)cc1] | 1-158 |
| 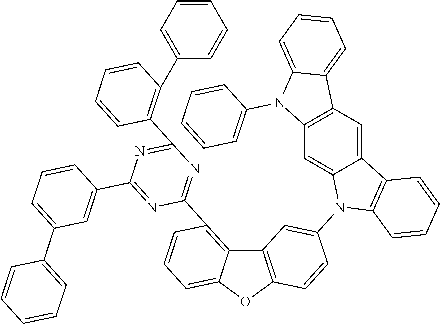 [SMILES: c1ccc(-c2cccc(-c3nc(-c4ccccc4-c4ccccc4)nc(-c4cccc5oc6ccc(-n7c8ccccc8c8cc9c%10ccccc%10n(-c%10ccccc%10)c9cc87)cc6c45)n3)c2)cc1] | 1-159 |
| 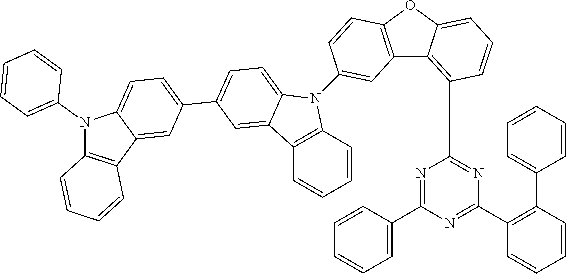 [SMILES: c1ccc(-c2nc(-c3ccccc3-c3ccccc3)nc(-c3cccc4oc5ccc(-n6c7ccccc7c7cc(-c8ccc9c(c8)c8ccccc8n9-c8ccccc8)ccc76)cc5c34)n2)cc1] | 1-160 |
| 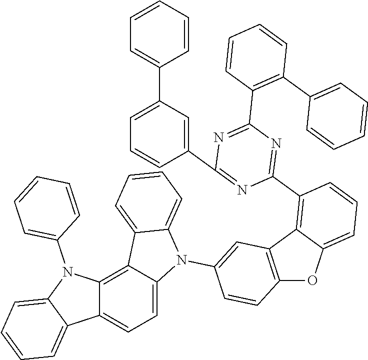 [SMILES: c1ccc(-c2cccc(-c3nc(-c4ccccc4-c4ccccc4)nc(-c4cccc5oc6ccc(-n7c8ccccc8c8c7ccc7c9ccccc9n(-c9ccccc9)c78)cc6c45)n3)c2)cc1] | 1-161 |
| 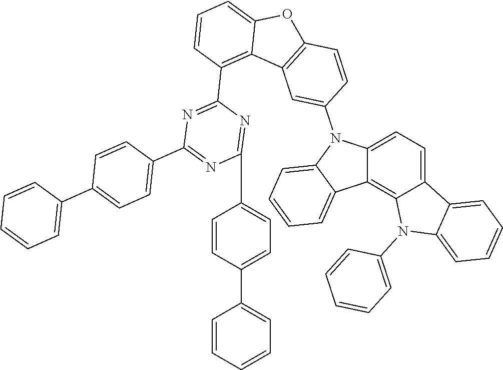 [SMILES: c1ccc(-c2ccc(-c3nc(-c4ccc(-c5ccccc5)cc4)nc(-c4cccc5oc6ccc(-n7c8ccccc8c8c7ccc7c9ccccc9n(-c9ccccc9)c78)cc6c45)n3)cc2)cc1] | 1-162 |
| 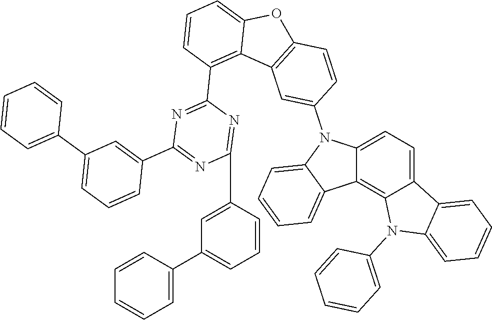 [SMILES: c1ccc(-c2cccc(-c3nc(-c4cccc(-c5ccccc5)c4)nc(-c4cccc5oc6ccc(-n7c8ccccc8c8c7ccc7c9ccccc9n(-c9ccccc9)c78)cc6c45)n3)c2)cc1] | 1-163 |
| 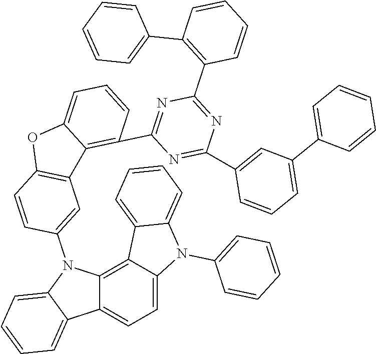 [SMILES: c1ccc(-c2cccc(-c3nc(-c4ccccc4-c4ccccc4)nc(-c4cccc5oc6ccc(-n7c8ccccc8c8ccc9c(c%10ccccc%10n9-c9ccccc9)c87)cc6c45)n3)c2)cc1] | 1-164 |
| 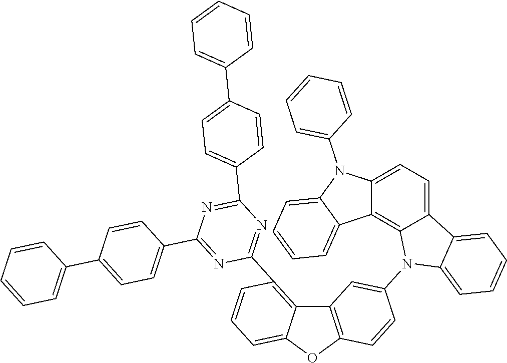 [SMILES: c1ccc(-c2ccc(-c3nc(-c4ccc(-c5ccccc5)cc4)nc(-c4cccc5oc6ccc(-n7c8ccccc8c8ccc9c(c%10ccccc%10n9-c9ccccc9)c87)cc6c45)n3)cc2)cc1] | 1-165 |
| 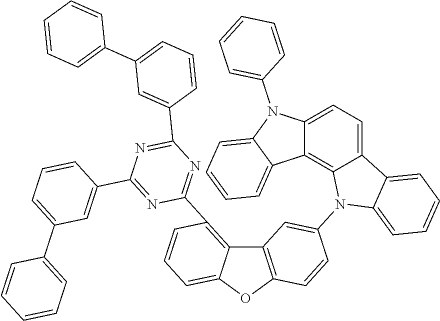 [SMILES: c1ccc(-c2cccc(-c3nc(-c4cccc(-c5ccccc5)c4)nc(-c4cccc5oc6ccc(-n7c8ccccc8c8ccc9c(c%10ccccc%10n9-c9ccccc9)c87)cc6c45)n3)c2)cc1] | 1-166 |
| 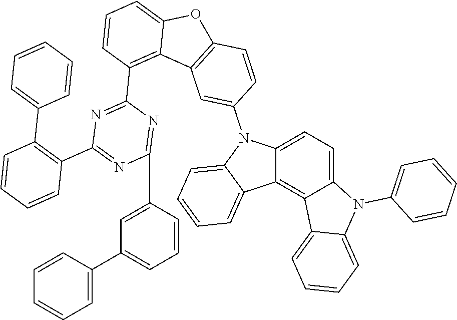 [SMILES: c1ccc(-c2cccc(-c3nc(-c4ccccc4-c4ccccc4)nc(-c4cccc5oc6ccc(-n7c8ccccc8c8c9c%10ccccc%10n(-c%10ccccc%10)c9ccc87)cc6c45)n3)c2)cc1] | 1-167 |
| 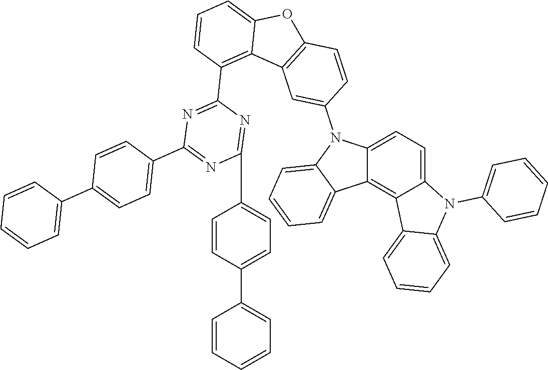 [SMILES: c1ccc(-c2ccc(-c3nc(-c4ccc(-c5ccccc5)cc4)nc(-c4cccc5oc6ccc(-n7c8ccccc8c8c9c%10ccccc%10n(-c%10ccccc%10)c9ccc87)cc6c45)n3)cc2)cc1] | 1-168 |
| 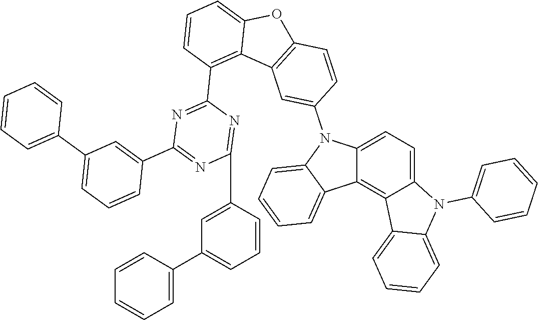 [SMILES: c1ccc(-c2cccc(-c3nc(-c4cccc(-c5ccccc5)c4)nc(-c4cccc5oc6ccc(-n7c8ccccc8c8c9c%10ccccc%10n(-c%10ccccc%10)c9ccc87)cc6c45)n3)c2)cc1] | 1-169 |
| 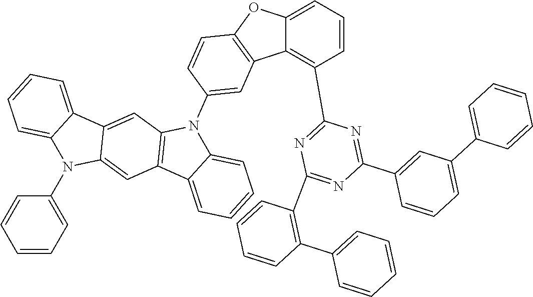 [SMILES: c1ccc(-c2cccc(-c3nc(-c4ccccc4-c4ccccc4)nc(-c4cccc5oc6ccc(-n7c8ccccc8c8cc9c(cc87)c7ccccc7n9-c7ccccc7)cc6c45)n3)c2)cc1] | 1-170 |
| 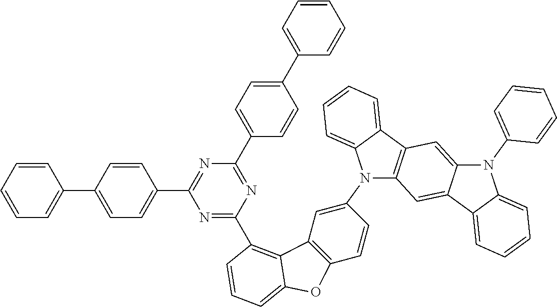 [SMILES: c1ccc(-c2ccc(-c3nc(-c4ccc(-c5ccccc5)cc4)nc(-c4cccc5oc6ccc(-n7c8ccccc8c8cc9c(cc87)c7ccccc7n9-c7ccccc7)cc6c45)n3)cc2)cc1] | 1-171 |
| 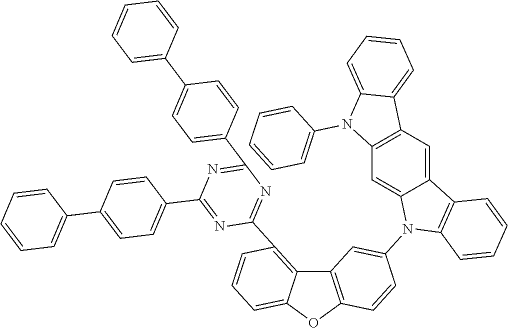 [SMILES: c1ccc(-c2ccc(-c3nc(-c4ccc(-c5ccccc5)cc4)nc(-c4cccc5oc6ccc(-n7c8ccccc8c8cc9c%10ccccc%10n(-c%10ccccc%10)c9cc87)cc6c45)n3)cc2)cc1] | 1-172 |
| 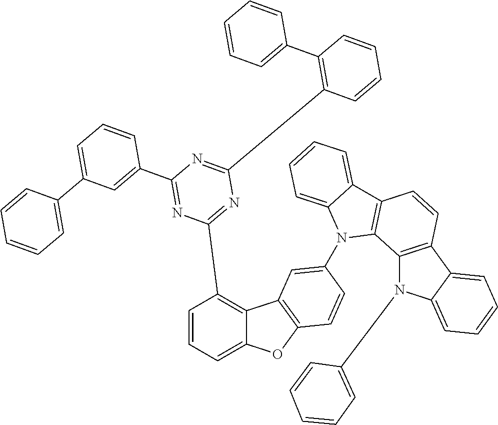 [SMILES: c1ccc(-c2cccc(-c3nc(-c4ccccc4-c4ccccc4)nc(-c4cccc5oc6ccc(-n7c8ccccc8c8ccc9c%10ccccc%10n(-c%10ccccc%10)c9c87)cc6c45)n3)c2)cc1] | 1-173 |
| 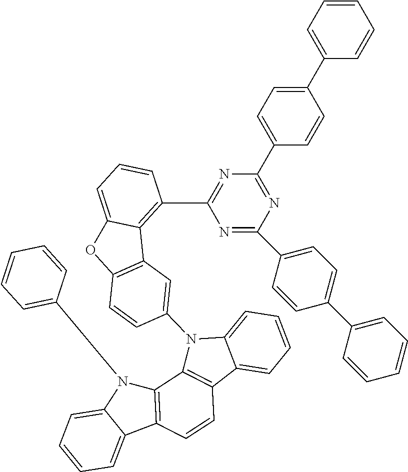 [SMILES: c1ccc(-c2ccc(-c3nc(-c4ccc(-c5ccccc5)cc4)nc(-c4cccc5oc6ccc(-n7c8ccccc8c8ccc9c%10ccccc%10n(-c%10ccccc%10)c9c87)cc6c45)n3)cc2)cc1] | 1-174 |
| 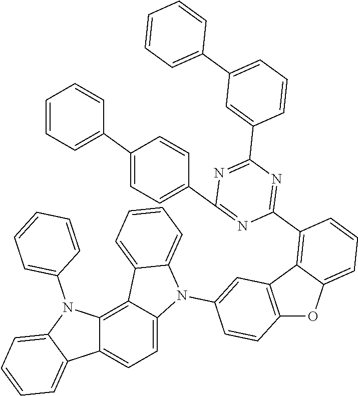 [SMILES: c1ccc(-c2ccc(-c3nc(-c4cccc(-c5ccccc5)c4)nc(-c4cccc5oc6ccc(-n7c8ccccc8c8c7ccc7c9ccccc9n(-c9ccccc9)c78)cc6c45)n3)cc2)cc1] | 1-175 |
| 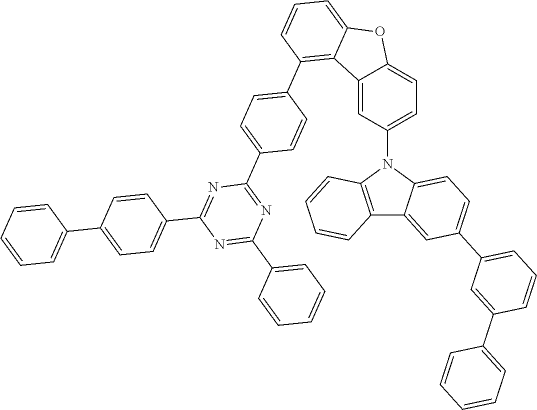 [SMILES: c1ccc(-c2ccc(-c3nc(-c4ccccc4)nc(-c4ccc(-c5cccc6oc7ccc(-n8c9ccccc9c9cc(-c%10cccc(-c%11ccccc%11)c%10)ccc98)cc7c56)cc4)n3)cc2)cc1] | 1-176 |
| 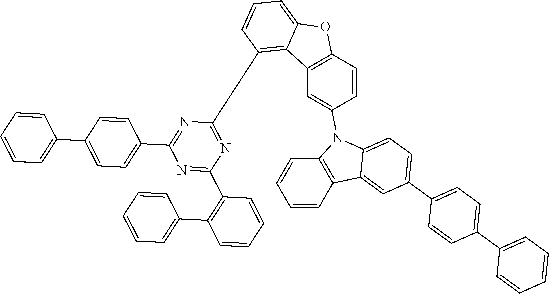 [SMILES: c1ccc(-c2ccc(-c3ccc4c(c3)c3ccccc3n4-c3ccc4oc5cccc(-c6nc(-c7ccc(-c8ccccc8)cc7)nc(-c7ccccc7-c7ccccc7)n6)c5c4c3)cc2)cc1] | 1-177 |
| 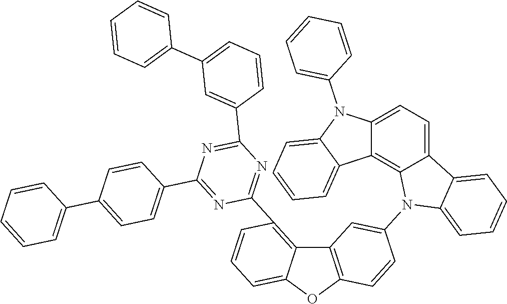 [SMILES: c1ccc(-c2ccc(-c3nc(-c4cccc(-c5ccccc5)c4)nc(-c4cccc5oc6ccc(-n7c8ccccc8c8ccc9c(c%10ccccc%10n9-c9ccccc9)c87)cc6c45)n3)cc2)cc1] | 1-178 |
| 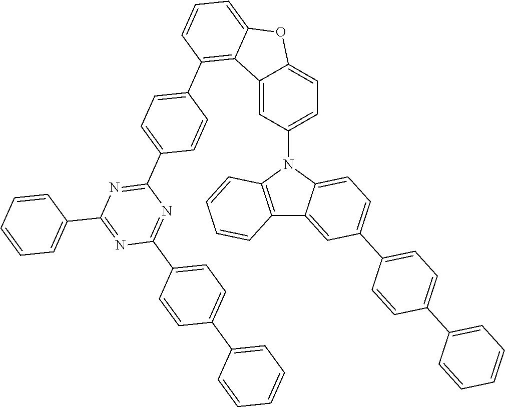 [SMILES: c1ccc(-c2ccc(-c3ccc4c(c3)c3ccccc3n4-c3ccc4oc5cccc(-c6ccc(-c7nc(-c8ccccc8)nc(-c8ccc(-c9ccccc9)cc8)n7)cc6)c5c4c3)cc2)cc1] | 1-179 |
| 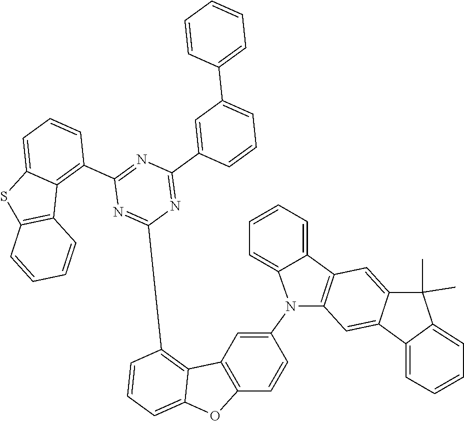 [SMILES: CC1(C)c2ccccc2-c2cc3c(cc21)c1ccccc1n3-c1ccc2oc3cccc(-c4nc(-c5cccc(-c6ccccc6)c5)nc(-c5cccc6sc7ccccc7c56)n4)c3c2c1] | 1-180 |
| 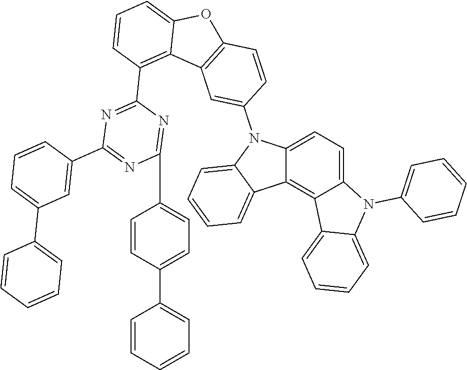 [SMILES: c1ccc(-c2ccc(-c3nc(-c4cccc(-c5ccccc5)c4)nc(-c4cccc5oc6ccc(-n7c8ccccc8c8c9c%10ccccc%10n(-c%10ccccc%10)c9ccc87)cc6c45)n3)cc2)cc1] | 1-181 |
| 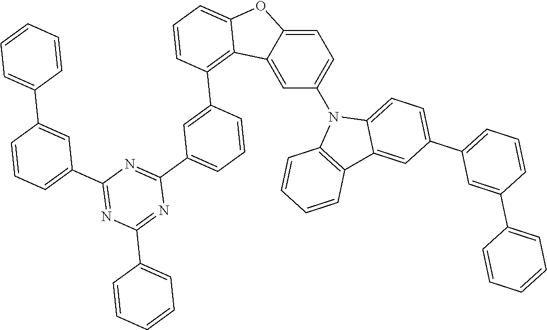 [SMILES: c1ccc(-c2cccc(-c3ccc4c(c3)c3ccccc3n4-c3ccc4oc5cccc(-c6cccc(-c7nc(-c8ccccc8)nc(-c8cccc(-c9ccccc9)c8)n7)c6)c5c4c3)c2)cc1] | 1-182 |
| 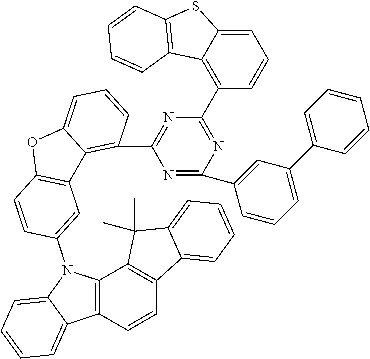 [SMILES: CC1(C)c2ccccc2-c2ccc3c4ccccc4n(-c4ccc5oc6cccc(-c7nc(-c8cccc(-c9ccccc9)c8)nc(-c8cccc9sc%10ccccc%10c89)n7)c6c5c4)c3c21] | 1-183 |
| 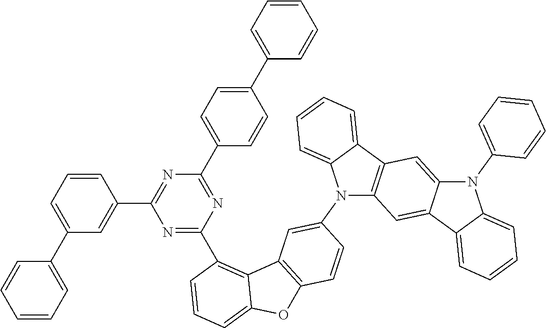 [SMILES: c1ccc(-c2ccc(-c3nc(-c4cccc(-c5ccccc5)c4)nc(-c4cccc5oc6ccc(-n7c8ccccc8c8cc9c(cc87)c7ccccc7n9-c7ccccc7)cc6c45)n3)cc2)cc1] | 1-184 |
| 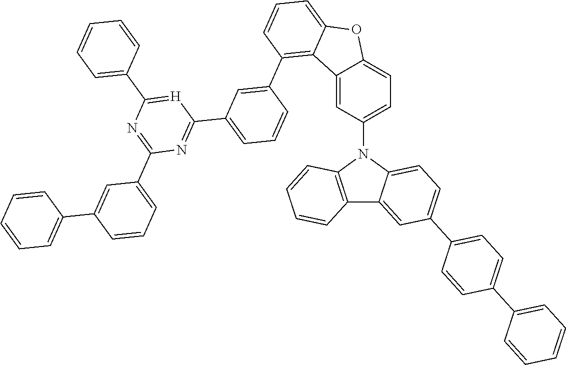 | 1-185 |
| 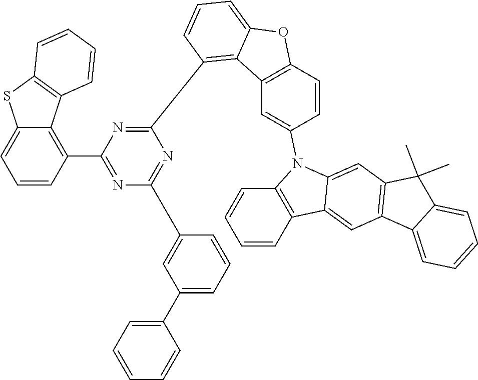 [SMILES: CC1(C)c2ccccc2-c2cc3c4ccccc4n(-c4ccc5oc6cccc(-c7nc(-c8cccc(-c9ccccc9)c8)nc(-c8cccc9sc%10ccccc%10c89)n7)c6c5c4)c3cc21] | 1-186 |
| 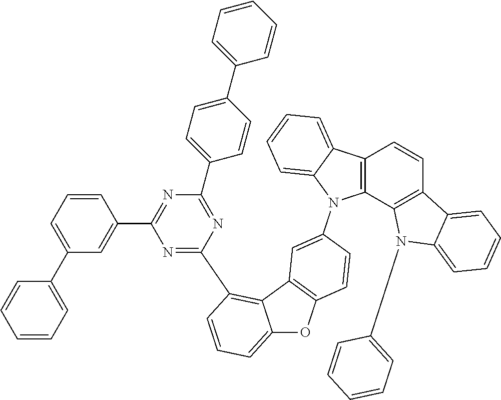 [SMILES: c1ccc(-c2ccc(-c3nc(-c4cccc(-c5ccccc5)c4)nc(-c4cccc5oc6ccc(-n7c8ccccc8c8ccc9c%10ccccc%10n(-c%10ccccc%10)c9c87)cc6c45)n3)cc2)cc1] | 1-187 |
| 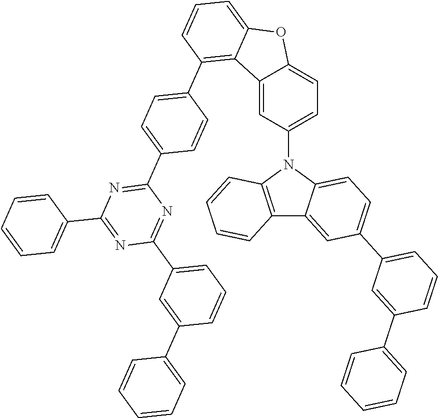 [SMILES: c1ccc(-c2cccc(-c3ccc4c(c3)c3ccccc3n4-c3ccc4oc5cccc(-c6ccc(-c7nc(-c8ccccc8)nc(-c8cccc(-c9ccccc9)c8)n7)cc6)c5c4c3)c2)cc1] | 1-188 |
| 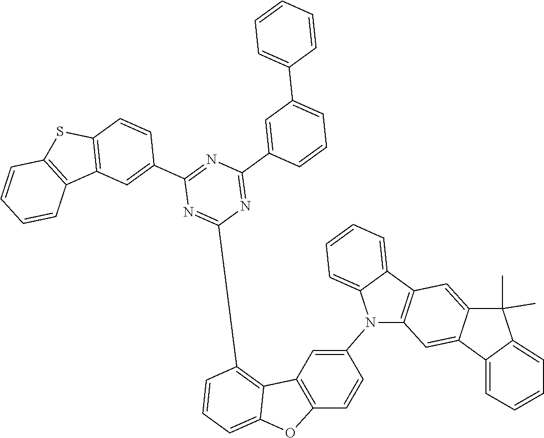 [SMILES: CC1(C)c2ccccc2-c2cc3c(cc21)c1ccccc1n3-c1ccc2oc3cccc(-c4nc(-c5cccc(-c6ccccc6)c5)nc(-c5ccc6sc7ccccc7c6c5)n4)c3c2c1] | 1-189 |
| 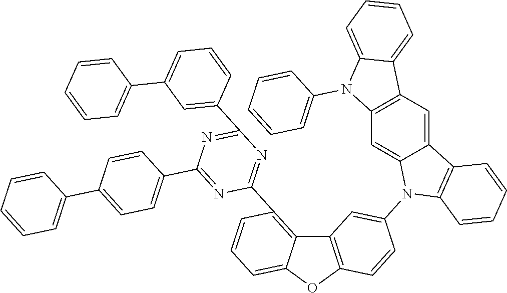 [SMILES: c1ccc(-c2ccc(-c3nc(-c4cccc(-c5ccccc5)c4)nc(-c4cccc5oc6ccc(-n7c8ccccc8c8cc9c%10ccccc%10n(-c%10ccccc%10)c9cc87)cc6c45)n3)cc2)cc1] | 1-190 |
| 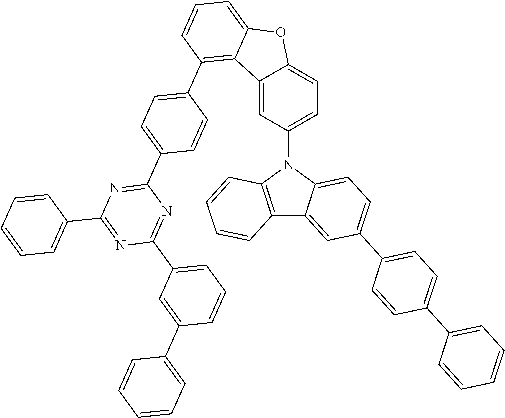 [SMILES: c1ccc(-c2ccc(-c3ccc4c(c3)c3ccccc3n4-c3ccc4oc5cccc(-c6ccc(-c7nc(-c8ccccc8)nc(-c8cccc(-c9ccccc9)c8)n7)cc6)c5c4c3)cc2)cc1] | 1-191 |
| 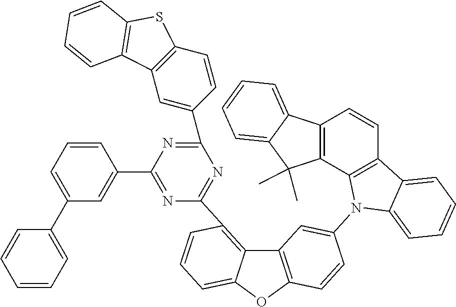 [SMILES: CC1(C)c2ccccc2-c2ccc3c4ccccc4n(-c4ccc5oc6cccc(-c7nc(-c8cccc(-c9ccccc9)c8)nc(-c8ccc9sc%10ccccc%10c9c8)n7)c6c5c4)c3c21] | 1-192 |
| 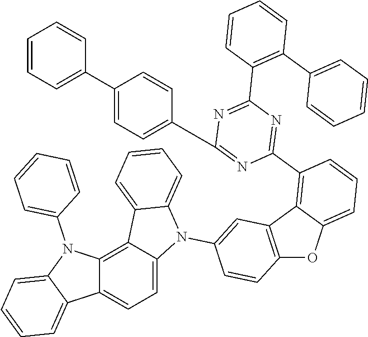 [SMILES: c1ccc(-c2ccc(-c3nc(-c4ccccc4-c4ccccc4)nc(-c4cccc5oc6ccc(-n7c8ccccc8c8c7ccc7c9ccccc9n(-c9ccccc9)c78)cc6c45)n3)cc2)cc1] | 1-193 |
| 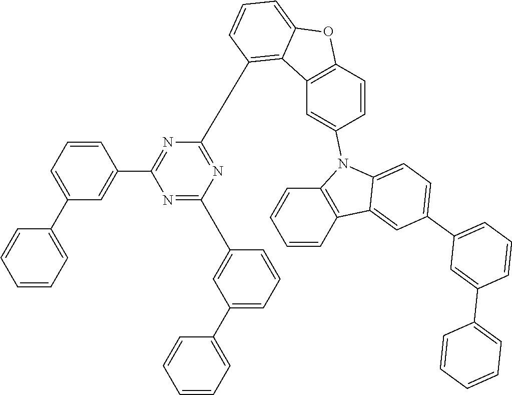 [SMILES: c1ccc(-c2cccc(-c3ccc4c(c3)c3ccccc3n4-c3ccc4oc5cccc(-c6nc(-c7cccc(-c8ccccc8)c7)nc(-c7cccc(-c8ccccc8)c7)n6)c5c4c3)c2)cc1] | 1-194 |
| 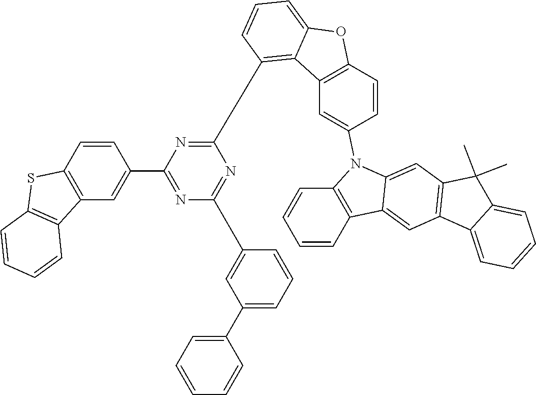 [SMILES: CC1(C)c2ccccc2-c2cc3c4ccccc4n(-c4ccc5oc6cccc(-c7nc(-c8cccc(-c9ccccc9)c8)nc(-c8ccc9sc%10ccccc%10c9c8)n7)c6c5c4)c3cc21] | 1-195 |
| 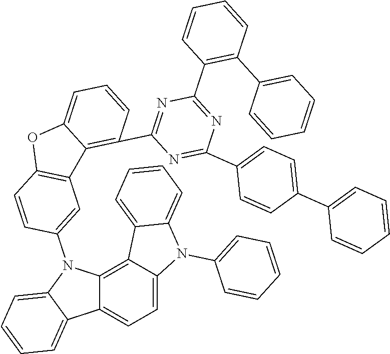 [SMILES: c1ccc(-c2ccc(-c3nc(-c4ccccc4-c4ccccc4)nc(-c4cccc5oc6ccc(-n7c8ccccc8c8ccc9c(c%10ccccc%10n9-c9ccccc9)c87)cc6c45)n3)cc2)cc1] | 1-196 |
| 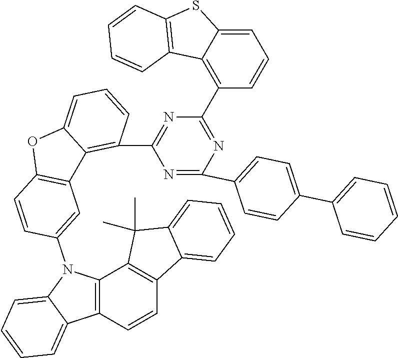 [SMILES: CC1(C)c2ccccc2-c2ccc3c4ccccc4n(-c4ccc5oc6cccc(-c7nc(-c8ccc(-c9ccccc9)cc8)nc(-c8cccc9sc%10ccccc%10c89)n7)c6c5c4)c3c21] | 1-197 |
| 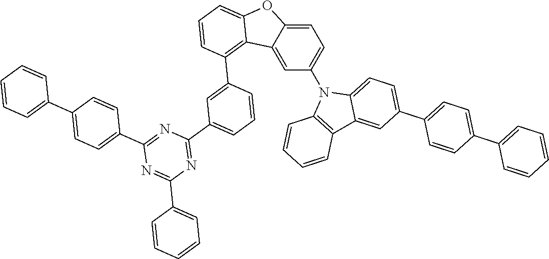 [SMILES: c1ccc(-c2ccc(-c3ccc4c(c3)c3ccccc3n4-c3ccc4oc5cccc(-c6cccc(-c7nc(-c8ccccc8)nc(-c8ccc(-c9ccccc9)cc8)n7)c6)c5c4c3)cc2)cc1] | 1-198 |
| 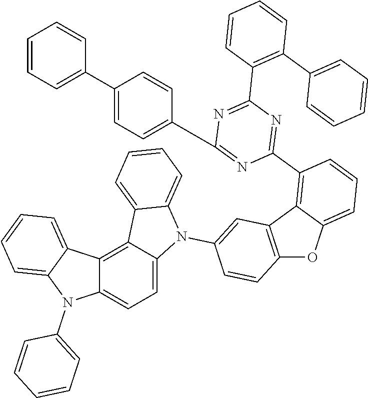 [SMILES: c1ccc(-c2ccc(-c3nc(-c4ccccc4-c4ccccc4)nc(-c4cccc5oc6ccc(-n7c8ccccc8c8c9c%10ccccc%10n(-c%10ccccc%10)c9ccc87)cc6c45)n3)cc2)cc1] | 1-199 |
| 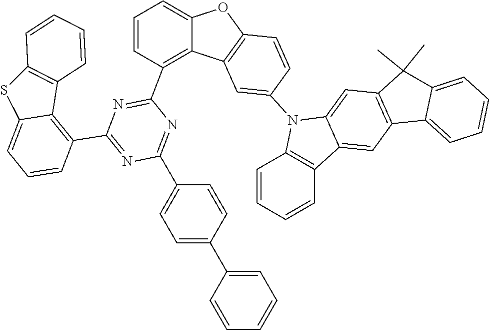 [SMILES: CC1(C)c2ccccc2-c2cc3c4ccccc4n(-c4ccc5oc6cccc(-c7nc(-c8ccc(-c9ccccc9)cc8)nc(-c8cccc9sc%10ccccc%10c89)n7)c6c5c4)c3cc21] | 1-200 |
| 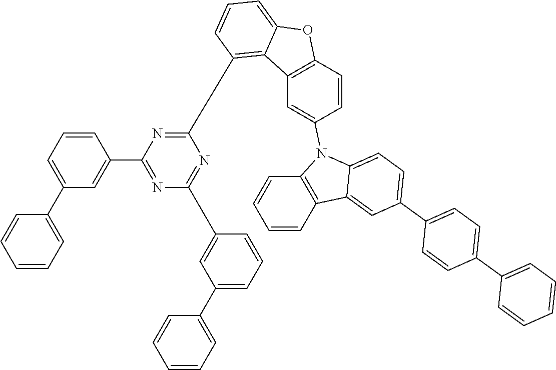 [SMILES: c1ccc(-c2ccc(-c3ccc4c(c3)c3ccccc3n4-c3ccc4oc5cccc(-c6nc(-c7cccc(-c8ccccc8)c7)nc(-c7cccc(-c8ccccc8)c7)n6)c5c4c3)cc2)cc1] | 1-201 |
| 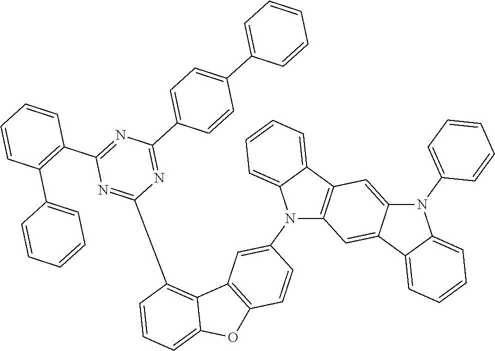 [SMILES: c1ccc(-c2ccc(-c3nc(-c4ccccc4-c4ccccc4)nc(-c4cccc5oc6ccc(-n7c8ccccc8c8cc9c(cc87)c7ccccc7n9-c7ccccc7)cc6c45)n3)cc2)cc1] | 1-202 |
| 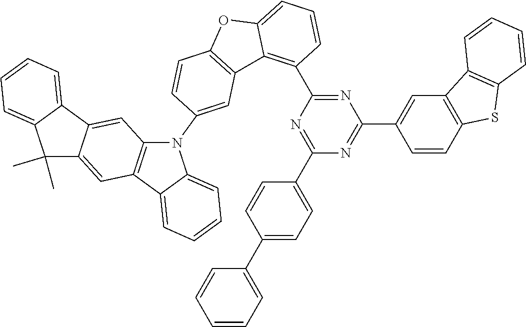 [SMILES: CC1(C)c2ccccc2-c2cc3c(cc21)c1ccccc1n3-c1ccc2oc3cccc(-c4nc(-c5ccc(-c6ccccc6)cc5)nc(-c5ccc6sc7ccccc7c6c5)n4)c3c2c1] | 1-203 |
| 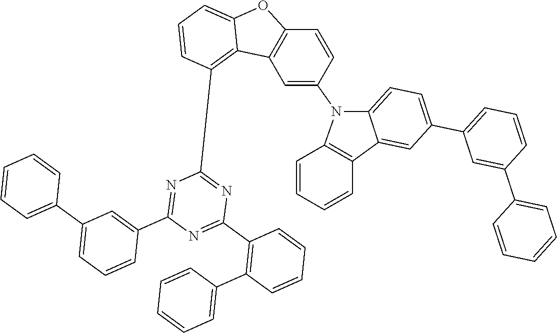 [SMILES: c1ccc(-c2cccc(-c3ccc4c(c3)c3ccccc3n4-c3ccc4oc5cccc(-c6nc(-c7cccc(-c8ccccc8)c7)nc(-c7ccccc7-c7ccccc7)n6)c5c4c3)c2)cc1] | 1-204 |
| 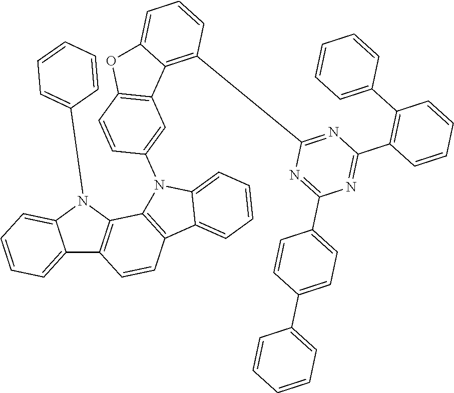 [SMILES: c1ccc(-c2ccc(-c3nc(-c4ccccc4-c4ccccc4)nc(-c4cccc5oc6ccc(-n7c8ccccc8c8ccc9c%10ccccc%10n(-c%10ccccc%10)c9c87)cc6c45)n3)cc2)cc1] | 1-205 |
| 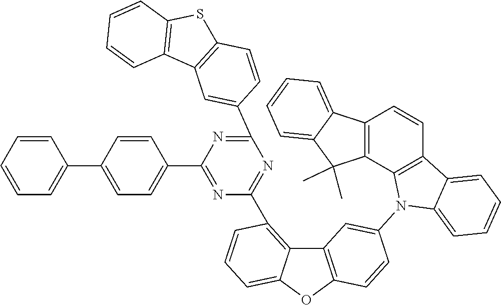 [SMILES: CC1(C)c2ccccc2-c2ccc3c4ccccc4n(-c4ccc5oc6cccc(-c7nc(-c8ccc(-c9ccccc9)cc8)nc(-c8ccc9sc%10ccccc%10c9c8)n7)c6c5c4)c3c21] | 1-206 |
| 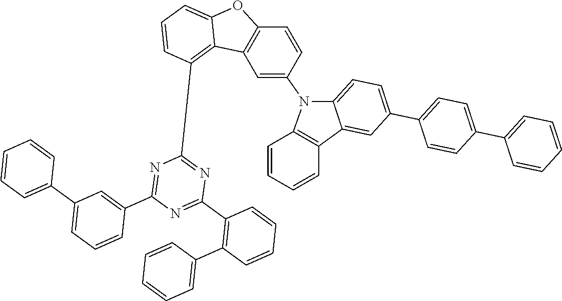 [SMILES: c1ccc(-c2ccc(-c3ccc4c(c3)c3ccccc3n4-c3ccc4oc5cccc(-c6nc(-c7cccc(-c8ccccc8)c7)nc(-c7ccccc7-c7ccccc7)n6)c5c4c3)cc2)cc1] | 1-207 |
| 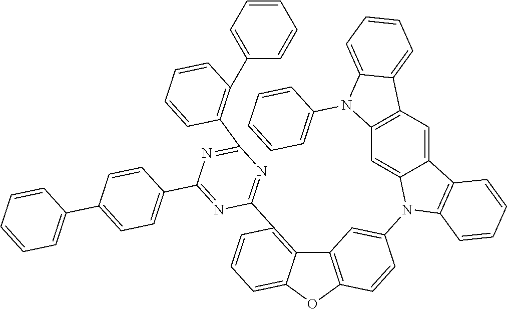 [SMILES: c1ccc(-c2ccc(-c3nc(-c4ccccc4-c4ccccc4)nc(-c4cccc5oc6ccc(-n7c8ccccc8c8cc9c%10ccccc%10n(-c%10ccccc%10)c9cc87)cc6c45)n3)cc2)cc1] | 1-208 |
| 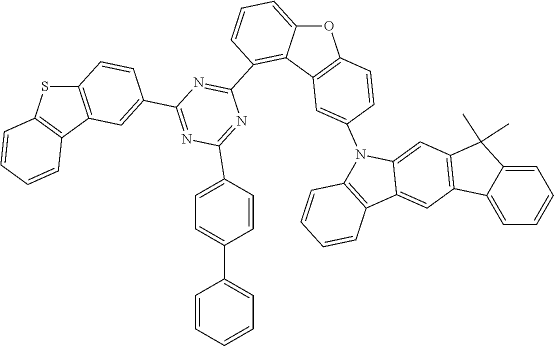 [SMILES: CC1(C)c2ccccc2-c2cc3c4ccccc4n(-c4ccc5oc6cccc(-c7nc(-c8ccc(-c9ccccc9)cc8)nc(-c8ccc9sc%10ccccc%10c9c8)n7)c6c5c4)c3cc21] | 1-209 |
| 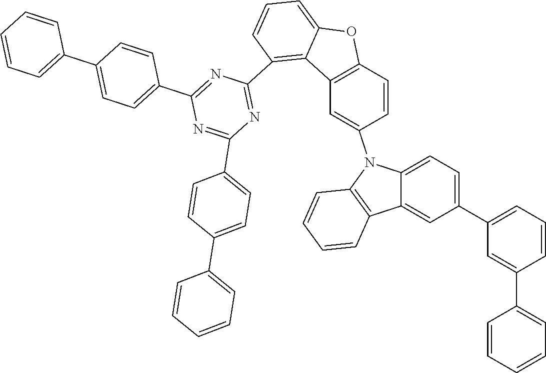 [SMILES: c1ccc(-c2ccc(-c3nc(-c4ccc(-c5ccccc5)cc4)nc(-c4cccc5oc6ccc(-n7c8ccccc8c8cc(-c9cccc(-c%10ccccc%10)c9)ccc87)cc6c45)n3)cc2)cc1] | 1-210 |
| 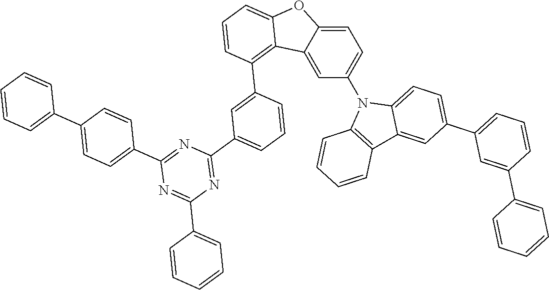 [SMILES: c1ccc(-c2ccc(-c3nc(-c4ccccc4)nc(-c4cccc(-c5cccc6oc7ccc(-n8c9ccccc9c9cc(-c%10cccc(-c%11ccccc%11)c%10)ccc98)cc7c56)c4)n3)cc2)cc1] | 1-211 |
| 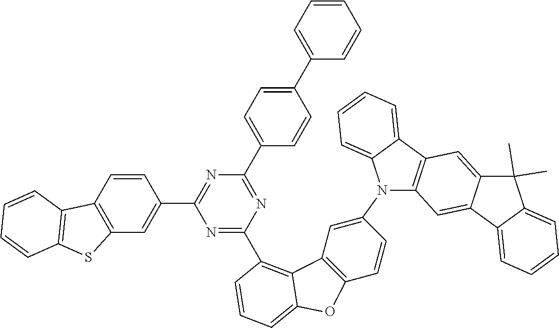 [SMILES: CC1(C)c2ccccc2-c2cc3c(cc21)c1ccccc1n3-c1ccc2oc3cccc(-c4nc(-c5ccc(-c6ccccc6)cc5)nc(-c5ccc6c(c5)sc5ccccc56)n4)c3c2c1] | 1-212 |
| 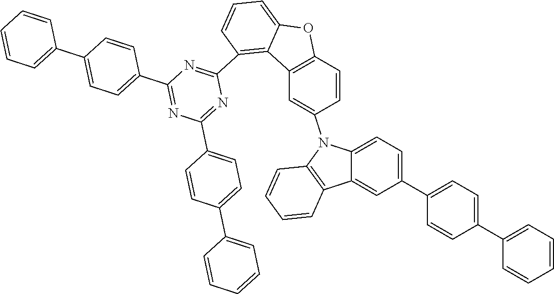 [SMILES: c1ccc(-c2ccc(-c3ccc4c(c3)c3ccccc3n4-c3ccc4oc5cccc(-c6nc(-c7ccc(-c8ccccc8)cc7)nc(-c7ccc(-c8ccccc8)cc7)n6)c5c4c3)cc2)cc1] | 1-213 |
| 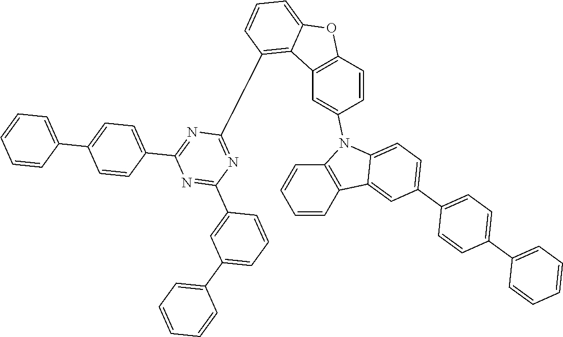 [SMILES: c1ccc(-c2ccc(-c3ccc4c(c3)c3ccccc3n4-c3ccc4oc5cccc(-c6nc(-c7ccc(-c8ccccc8)cc7)nc(-c7cccc(-c8ccccc8)c7)n6)c5c4c3)cc2)cc1] | 1-214 |
| 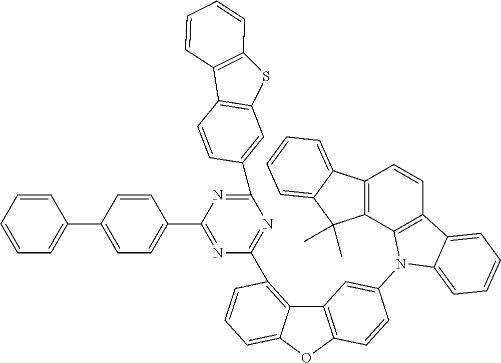 [SMILES: CC1(C)c2ccccc2-c2ccc3c4ccccc4n(-c4ccc5oc6cccc(-c7nc(-c8ccc(-c9ccccc9)cc8)nc(-c8ccc9c(c8)sc8ccccc89)n7)c6c5c4)c3c21] | 1-215 |
| 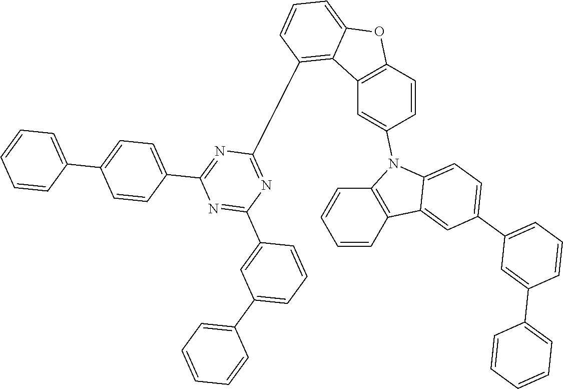 [SMILES: c1ccc(-c2ccc(-c3nc(-c4cccc(-c5ccccc5)c4)nc(-c4cccc5oc6ccc(-n7c8ccccc8c8cc(-c9cccc(-c%10ccccc%10)c9)ccc87)cc6c45)n3)cc2)cc1] | 1-216 |
| 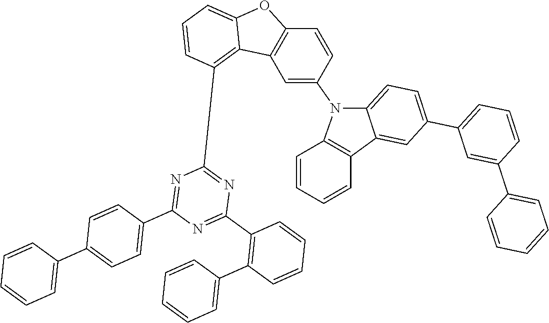 [SMILES: c1ccc(-c2ccc(-c3nc(-c4ccccc4-c4ccccc4)nc(-c4cccc5oc6ccc(-n7c8ccccc8c8cc(-c9cccc(-c%10ccccc%10)c9)ccc87)cc6c45)n3)cc2)cc1] | 1-217 |
| 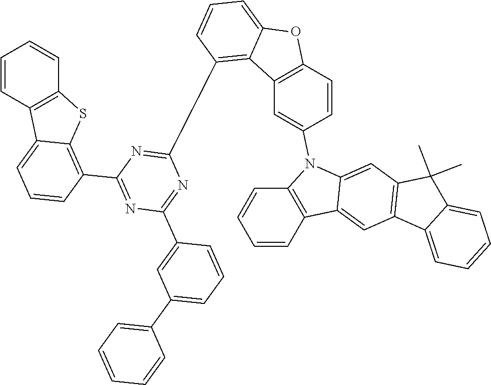 [SMILES: CC1(C)c2ccccc2-c2cc3c4ccccc4n(-c4ccc5oc6cccc(-c7nc(-c8cccc(-c9ccccc9)c8)nc(-c8cccc9c8sc8ccccc89)n7)c6c5c4)c3cc21] | 1-218 |
| 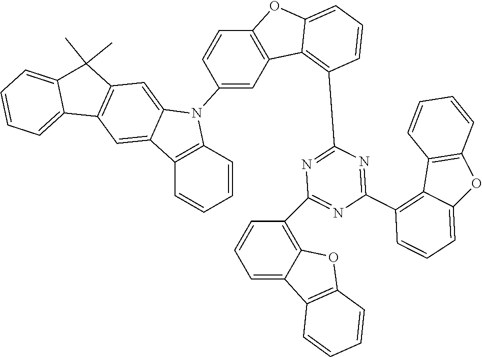 [SMILES: CC1(C)c2ccccc2-c2cc3c4ccccc4n(-c4ccc5oc6cccc(-c7nc(-c8cccc9c8oc8ccccc89)nc(-c8cccc9oc%10ccccc%10c89)n7)c6c5c4)c3cc21] | 1-219 |
| 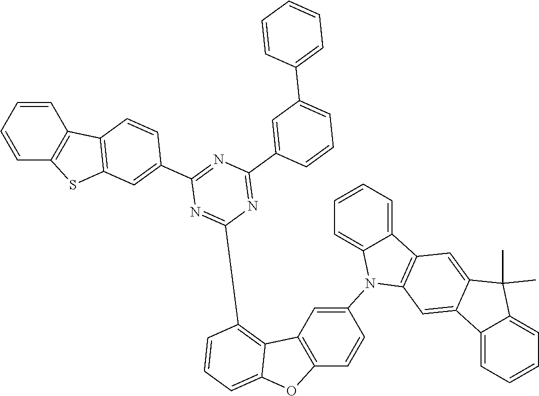 [SMILES: CC1(C)c2ccccc2-c2cc3c(cc21)c1ccccc1n3-c1ccc2oc3cccc(-c4nc(-c5cccc(-c6ccccc6)c5)nc(-c5ccc6c(c5)sc5ccccc56)n4)c3c2c1] | 1-220 |
| 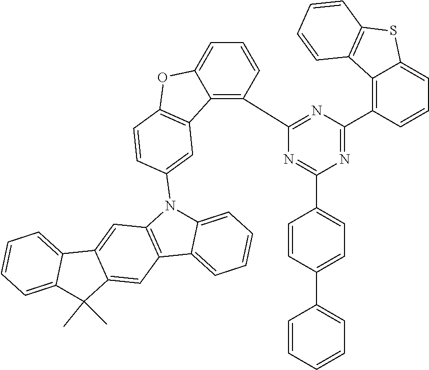 [SMILES: CC1(C)c2ccccc2-c2cc3c(cc21)c1ccccc1n3-c1ccc2oc3cccc(-c4nc(-c5ccc(-c6ccccc6)cc5)nc(-c5cccc6sc7ccccc7c56)n4)c3c2c1] | 1-221 |
| 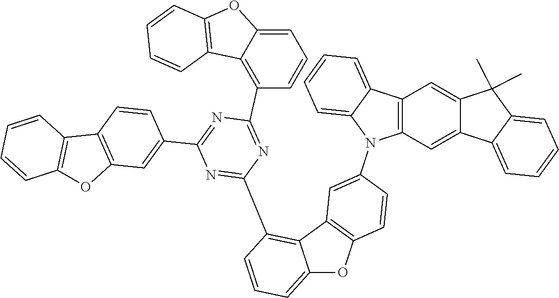 [SMILES: CC1(C)c2ccccc2-c2cc3c(cc21)c1ccccc1n3-c1ccc2oc3cccc(-c4nc(-c5ccc6c(c5)oc5ccccc56)nc(-c5cccc6oc7ccccc7c56)n4)c3c2c1] | 1-222 |
| 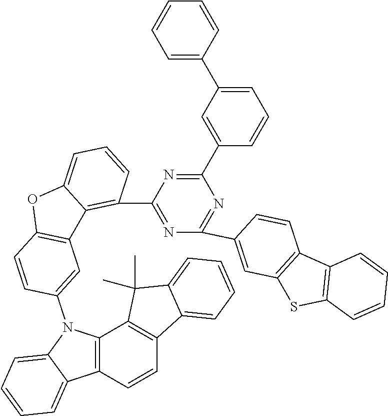 [SMILES: CC1(C)c2ccccc2-c2ccc3c4ccccc4n(-c4ccc5oc6cccc(-c7nc(-c8cccc(-c9ccccc9)c8)nc(-c8ccc9c(c8)sc8ccccc89)n7)c6c5c4)c3c21] | 1-223 |
| 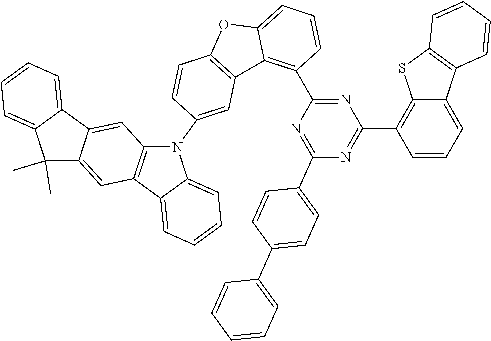 [SMILES: CC1(C)c2ccccc2-c2cc3c(cc21)c1ccccc1n3-c1ccc2oc3cccc(-c4nc(-c5ccc(-c6ccccc6)cc5)nc(-c5cccc6c5sc5ccccc56)n4)c3c2c1] | 1-224 |
| 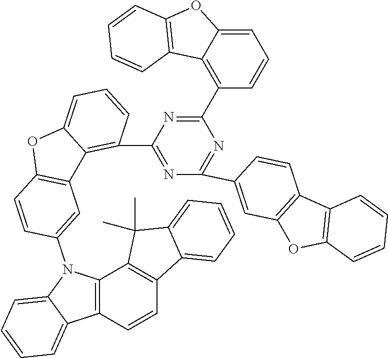 [SMILES: CC1(C)c2ccccc2-c2ccc3c4ccccc4n(-c4ccc5oc6cccc(-c7nc(-c8ccc9c(c8)oc8ccccc89)nc(-c8cccc9oc%10ccccc%10c89)n7)c6c5c4)c3c21] | 1-225 |
| 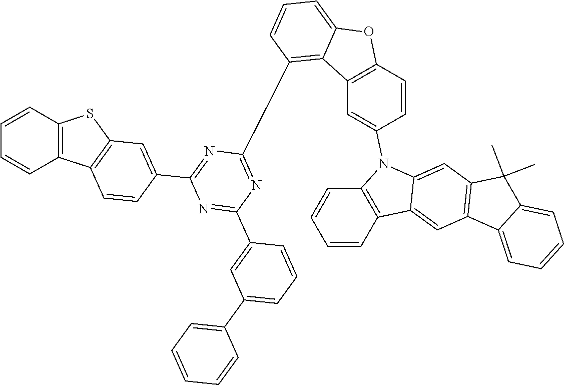 [SMILES: CC1(C)c2ccccc2-c2cc3c4ccccc4n(-c4ccc5oc6cccc(-c7nc(-c8cccc(-c9ccccc9)c8)nc(-c8ccc9c(c8)sc8ccccc89)n7)c6c5c4)c3cc21] | 1-226 |
| 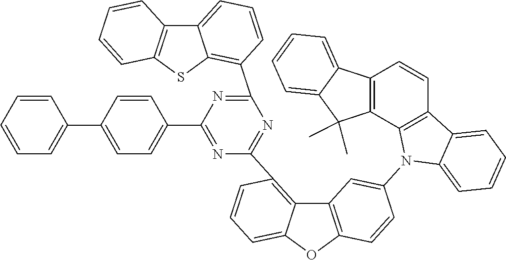 [SMILES: CC1(C)c2ccccc2-c2ccc3c4ccccc4n(-c4ccc5oc6cccc(-c7nc(-c8ccc(-c9ccccc9)cc8)nc(-c8cccc9c8sc8ccccc89)n7)c6c5c4)c3c21] | 1-227 |
| 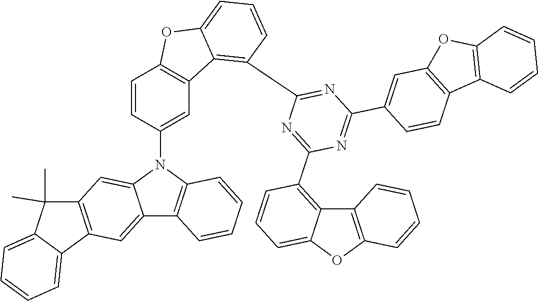 [SMILES: CC1(C)c2ccccc2-c2cc3c4ccccc4n(-c4ccc5oc6cccc(-c7nc(-c8ccc9c(c8)oc8ccccc89)nc(-c8cccc9oc%10ccccc%10c89)n7)c6c5c4)c3cc21] | 1-228 |
| 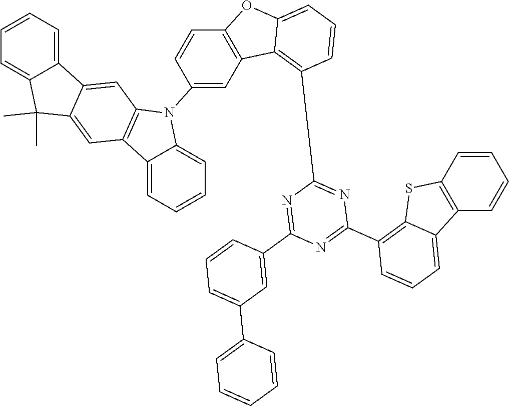 [SMILES: CC1(C)c2ccccc2-c2cc3c(cc21)c1ccccc1n3-c1ccc2oc3cccc(-c4nc(-c5cccc(-c6ccccc6)c5)nc(-c5cccc6c5sc5ccccc56)n4)c3c2c1] | 1-229 |
| 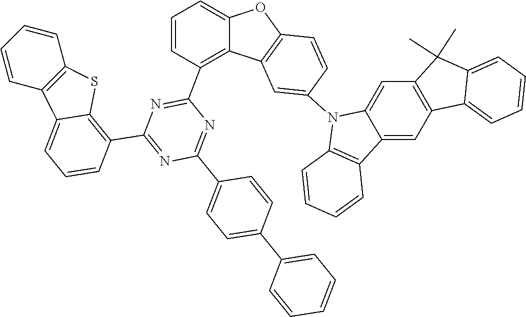 [SMILES: CC1(C)c2ccccc2-c2cc3c4ccccc4n(-c4ccc5oc6cccc(-c7nc(-c8ccc(-c9ccccc9)cc8)nc(-c8cccc9c8sc8ccccc89)n7)c6c5c4)c3cc21] | 1-230 |
| 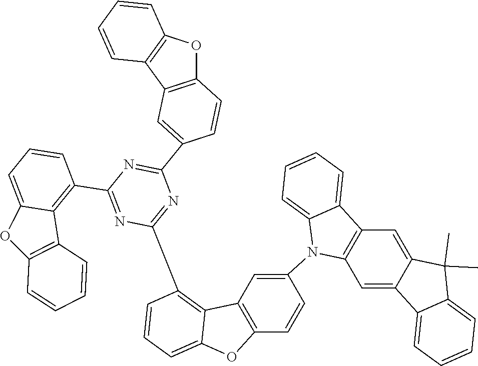 [SMILES: CC1(C)c2ccccc2-c2cc3c(cc21)c1ccccc1n3-c1ccc2oc3cccc(-c4nc(-c5ccc6oc7ccccc7c6c5)nc(-c5cccc6oc7ccccc7c56)n4)c3c2c1] | 1-231 |
| 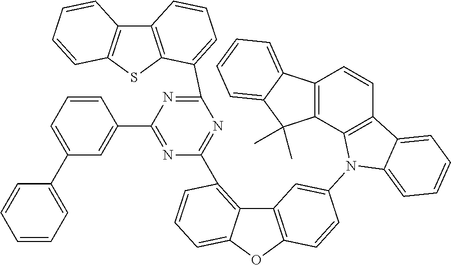 [SMILES: CC1(C)c2ccccc2-c2ccc3c4ccccc4n(-c4ccc5oc6cccc(-c7nc(-c8cccc(-c9ccccc9)c8)nc(-c8cccc9c8sc8ccccc89)n7)c6c5c4)c3c21] | 1-232 |
| 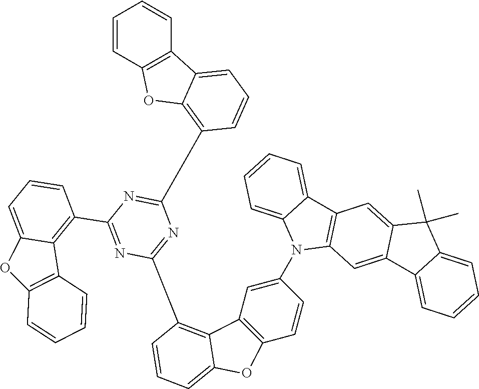 [SMILES: CC1(C)c2ccccc2-c2cc3c(cc21)c1ccccc1n3-c1ccc2oc3cccc(-c4nc(-c5cccc6c5oc5ccccc56)nc(-c5cccc6oc7ccccc7c56)n4)c3c2c1] | 1-233 |
| 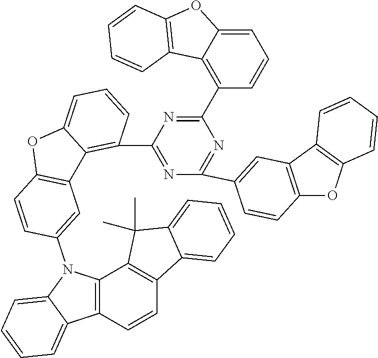 [SMILES: CC1(C)c2ccccc2-c2ccc3c4ccccc4n(-c4ccc5oc6cccc(-c7nc(-c8ccc9oc%10ccccc%10c9c8)nc(-c8cccc9oc%10ccccc%10c89)n7)c6c5c4)c3c21] | 1-234 |
| 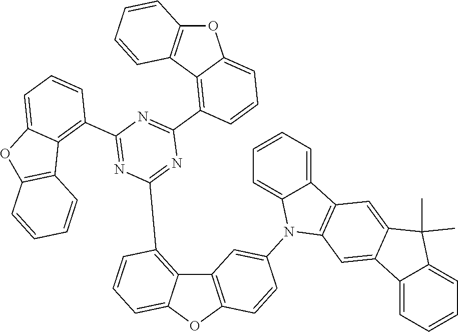 [SMILES: CC1(C)c2ccccc2-c2cc3c(cc21)c1ccccc1n3-c1ccc2oc3cccc(-c4nc(-c5cccc6oc7ccccc7c56)nc(-c5cccc6oc7ccccc7c56)n4)c3c2c1] | 1-235 |
| 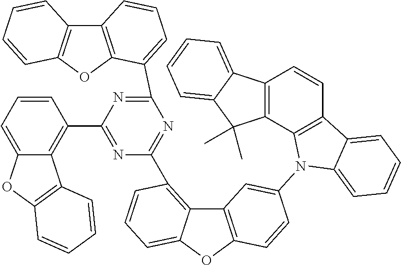 [SMILES: CC1(C)c2ccccc2-c2ccc3c4ccccc4n(-c4ccc5oc6cccc(-c7nc(-c8cccc9c8oc8ccccc89)nc(-c8cccc9oc%10ccccc%10c89)n7)c6c5c4)c3c21] | 1-236 |
| 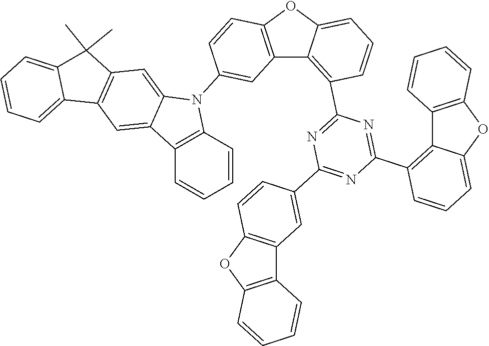 [SMILES: CC1(C)c2ccccc2-c2cc3c4ccccc4n(-c4ccc5oc6cccc(-c7nc(-c8ccc9oc%10ccccc%10c9c8)nc(-c8cccc9oc%10ccccc%10c89)n7)c6c5c4)c3cc21] | 1-237 |
| 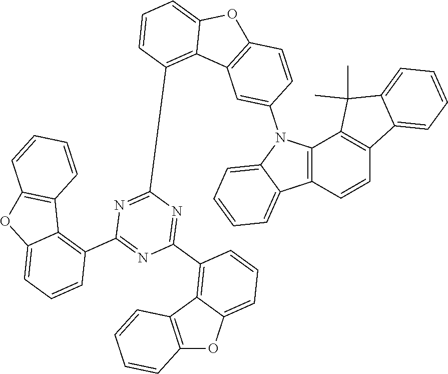 [SMILES: CC1(C)c2ccccc2-c2ccc3c4ccccc4n(-c4ccc5oc6cccc(-c7nc(-c8cccc9oc%10ccccc%10c89)nc(-c8cccc9oc%10ccccc%10c89)n7)c6c5c4)c3c21] | 1-238 |
| 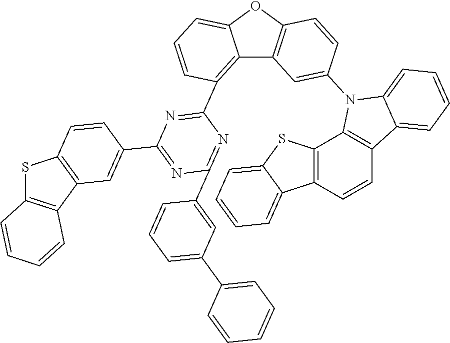 [SMILES: c1ccc(-c2cccc(-c3nc(-c4ccc5sc6ccccc6c5c4)nc(-c4cccc5oc6ccc(-n7c8ccccc8c8ccc9c%10ccccc%10sc9c87)cc6c45)n3)c2)cc1] | 1-239 |
| 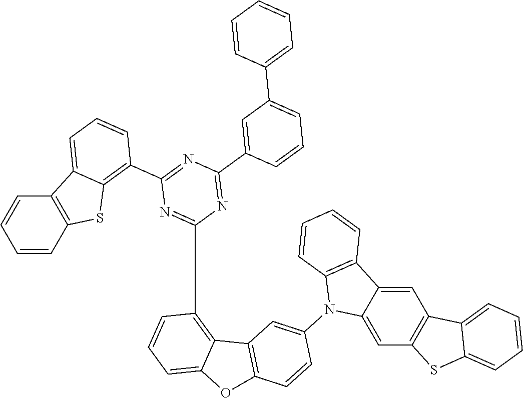 [SMILES: c1ccc(-c2cccc(-c3nc(-c4cccc5c4sc4ccccc45)nc(-c4cccc5oc6ccc(-n7c8ccccc8c8cc9c(cc87)sc7ccccc79)cc6c45)n3)c2)cc1] | 1-240 |
| 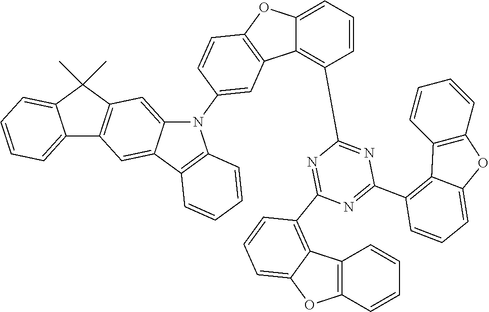 [SMILES: CC1(C)c2ccccc2-c2cc3c4ccccc4n(-c4ccc5oc6cccc(-c7nc(-c8cccc9oc%10ccccc%10c89)nc(-c8cccc9oc%10ccccc%10c89)n7)c6c5c4)c3cc21] | 1-241 |
| 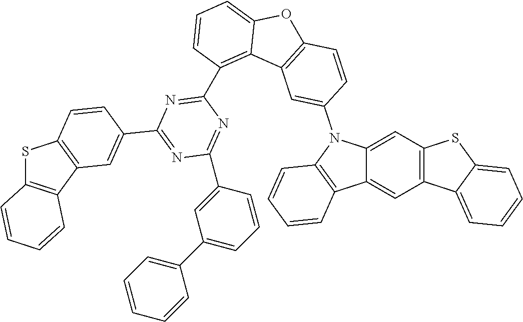 [SMILES: c1ccc(-c2cccc(-c3nc(-c4ccc5sc6ccccc6c5c4)nc(-c4cccc5oc6ccc(-n7c8ccccc8c8cc9c(cc87)sc7ccccc79)cc6c45)n3)c2)cc1] | 1-242 |
| 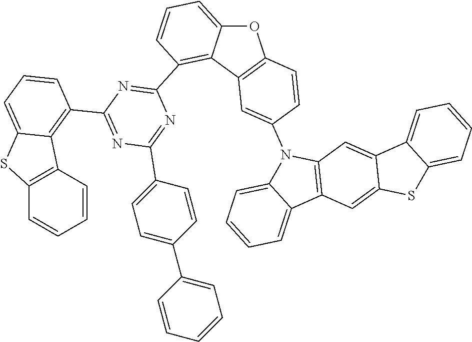 [SMILES: c1ccc(-c2ccc(-c3nc(-c4cccc5oc6ccc(-n7c8ccccc8c8cc9sc%10ccccc%10c9cc87)cc6c45)nc(-c4cccc5sc6ccccc6c45)n3)cc2)cc1] | 1-243 |
| 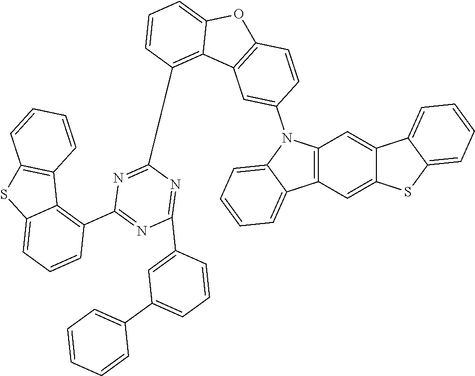 [SMILES: c1ccc(-c2cccc(-c3nc(-c4cccc5oc6ccc(-n7c8ccccc8c8cc9sc%10ccccc%10c9cc87)cc6c45)nc(-c4cccc5sc6ccccc6c45)n3)c2)cc1] | 1-244 |
| 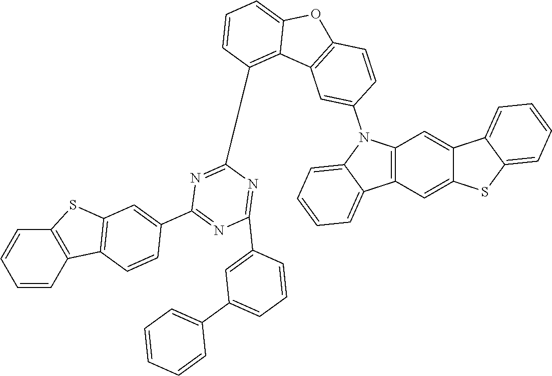 [SMILES: c1ccc(-c2cccc(-c3nc(-c4ccc5c(c4)sc4ccccc45)nc(-c4cccc5oc6ccc(-n7c8ccccc8c8cc9sc%10ccccc%10c9cc87)cc6c45)n3)c2)cc1] | 1-245 |
| 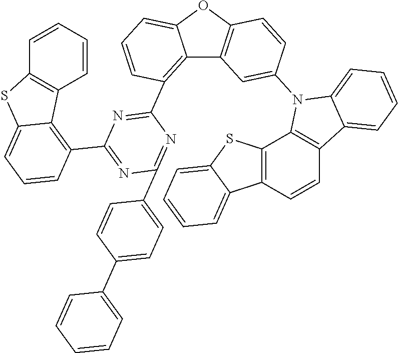 [SMILES: c1ccc(-c2ccc(-c3nc(-c4cccc5oc6ccc(-n7c8ccccc8c8ccc9c%10ccccc%10sc9c87)cc6c45)nc(-c4cccc5sc6ccccc6c45)n3)cc2)cc1] | 1-246 |
| 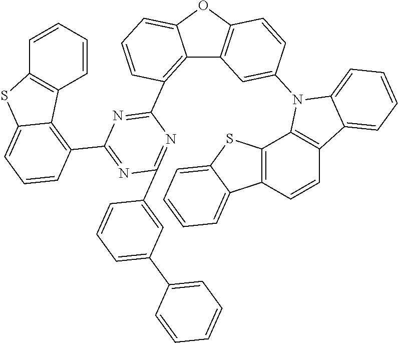 [SMILES: c1ccc(-c2cccc(-c3nc(-c4cccc5oc6ccc(-n7c8ccccc8c8ccc9c%10ccccc%10sc9c87)cc6c45)nc(-c4cccc5sc6ccccc6c45)n3)c2)cc1] | 1-247 |
| 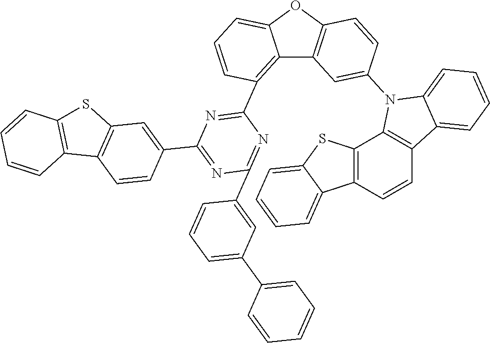 [SMILES: c1ccc(-c2cccc(-c3nc(-c4ccc5c(c4)sc4ccccc45)nc(-c4cccc5oc6ccc(-n7c8ccccc8c8ccc9c%10ccccc%10sc9c87)cc6c45)n3)c2)cc1] | 1-248 |
| 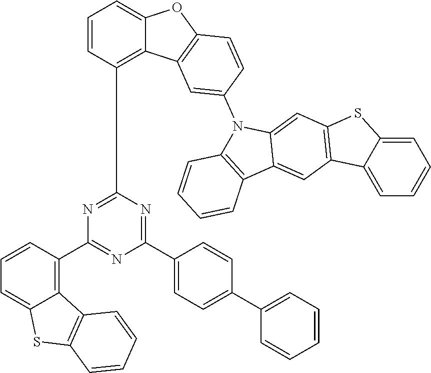 [SMILES: c1ccc(-c2ccc(-c3nc(-c4cccc5oc6ccc(-n7c8ccccc8c8cc9c(cc87)sc7ccccc79)cc6c45)nc(-c4cccc5sc6ccccc6c45)n3)cc2)cc1] | 1-249 |
| 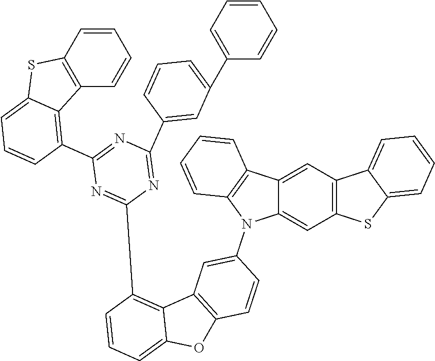 [SMILES: c1ccc(-c2cccc(-c3nc(-c4cccc5oc6ccc(-n7c8ccccc8c8cc9c(cc87)sc7ccccc79)cc6c45)nc(-c4cccc5sc6ccccc6c45)n3)c2)cc1] | 1-250 |
| 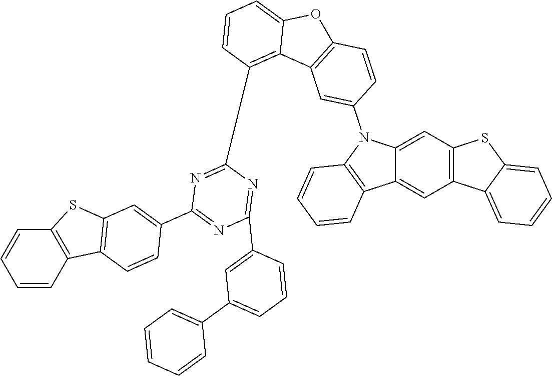 [SMILES: c1ccc(-c2cccc(-c3nc(-c4ccc5c(c4)sc4ccccc45)nc(-c4cccc5oc6ccc(-n7c8ccccc8c8cc9c(cc87)sc7ccccc79)cc6c45)n3)c2)cc1] | 1-251 |
| 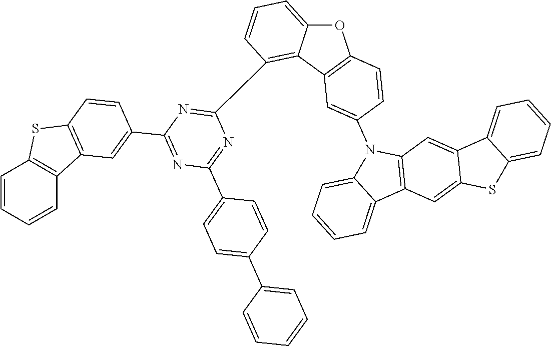 [SMILES: c1ccc(-c2ccc(-c3nc(-c4ccc5sc6ccccc6c5c4)nc(-c4cccc5oc6ccc(-n7c8ccccc8c8cc9sc%10ccccc%10c9cc87)cc6c45)n3)cc2)cc1] | 1-252 |
| 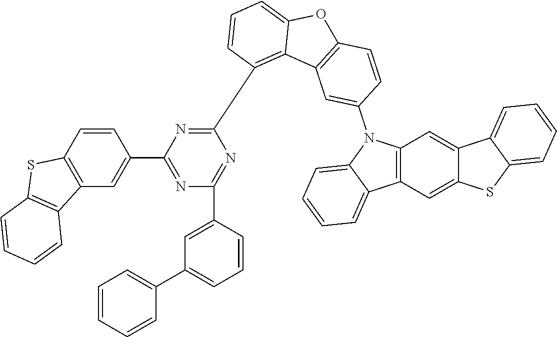 [SMILES: c1ccc(-c2cccc(-c3nc(-c4ccc5sc6ccccc6c5c4)nc(-c4cccc5oc6ccc(-n7c8ccccc8c8cc9sc%10ccccc%10c9cc87)cc6c45)n3)c2)cc1] | 1-253 |
| 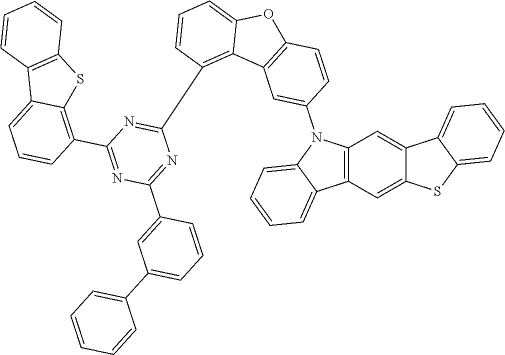 [SMILES: c1ccc(-c2cccc(-c3nc(-c4cccc5c4sc4ccccc45)nc(-c4cccc5oc6ccc(-n7c8ccccc8c8cc9sc%10ccccc%10c9cc87)cc6c45)n3)c2)cc1] | 1-254 |
| 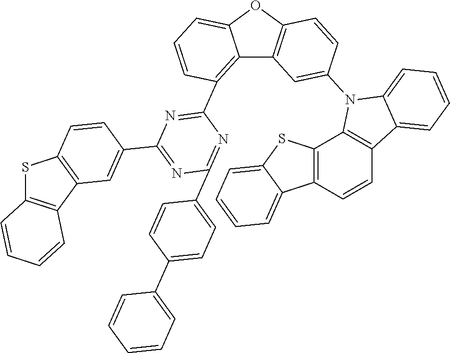 [SMILES: c1ccc(-c2ccc(-c3nc(-c4ccc5sc6ccccc6c5c4)nc(-c4cccc5oc6ccc(-n7c8ccccc8c8ccc9c%10ccccc%10sc9c87)cc6c45)n3)cc2)cc1] | 1-255 |
| 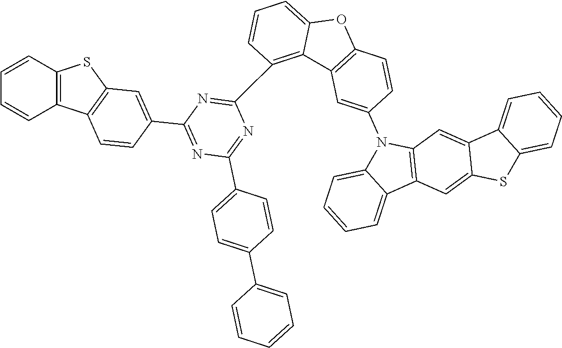 [SMILES: c1ccc(-c2ccc(-c3nc(-c4ccc5c(c4)sc4ccccc45)nc(-c4cccc5oc6ccc(-n7c8ccccc8c8cc9sc%10ccccc%10c9cc87)cc6c45)n3)cc2)cc1] | 1-256 |
| 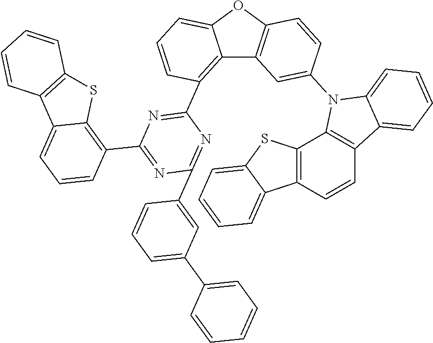 [SMILES: c1ccc(-c2cccc(-c3nc(-c4cccc5c4sc4ccccc45)nc(-c4cccc5oc6ccc(-n7c8ccccc8c8ccc9c%10ccccc%10sc9c87)cc6c45)n3)c2)cc1] | 1-257 |
| 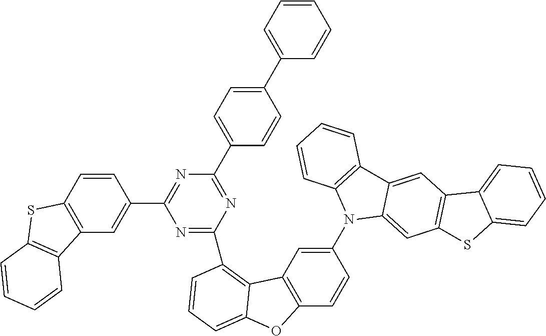 [SMILES: c1ccc(-c2ccc(-c3nc(-c4ccc5sc6ccccc6c5c4)nc(-c4cccc5oc6ccc(-n7c8ccccc8c8cc9c(cc87)sc7ccccc79)cc6c45)n3)cc2)cc1] | 1-258 |
| 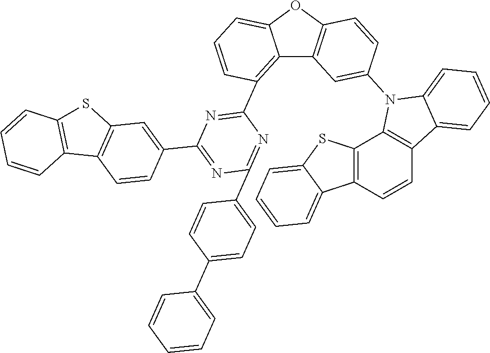 [SMILES: c1ccc(-c2ccc(-c3nc(-c4ccc5c(c4)sc4ccccc45)nc(-c4cccc5oc6ccc(-n7c8ccccc8c8ccc9c%10ccccc%10sc9c87)cc6c45)n3)cc2)cc1] | 1-259 |
| 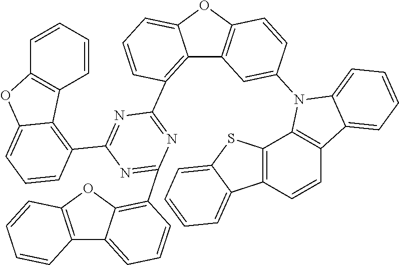 [SMILES: c1ccc2c(c1)oc1c(-c3nc(-c4cccc5oc6ccccc6c45)nc(-c4cccc5oc6ccc(-n7c8ccccc8c8ccc9c%10ccccc%10sc9c87)cc6c45)n3)cccc12] | 1-260 |
| 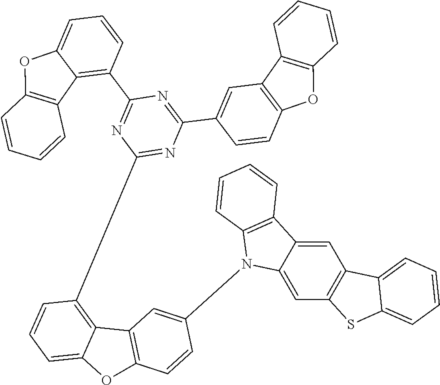 [SMILES: c1ccc2c(c1)oc1ccc(-c3nc(-c4cccc5oc6ccccc6c45)nc(-c4cccc5oc6ccc(-n7c8ccccc8c8cc9c(cc87)sc7ccccc79)cc6c45)n3)cc12] | 1-261 |
| 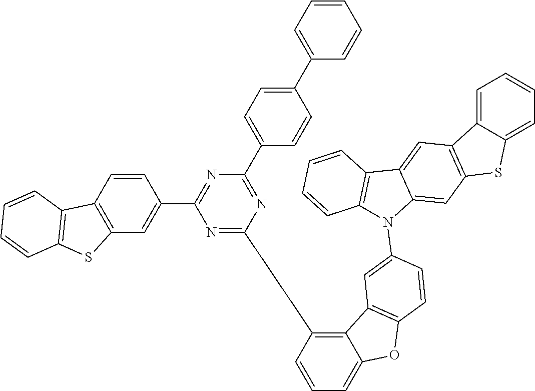 [SMILES: c1ccc(-c2ccc(-c3nc(-c4ccc5c(c4)sc4ccccc45)nc(-c4cccc5oc6ccc(-n7c8ccccc8c8cc9c(cc87)sc7ccccc79)cc6c45)n3)cc2)cc1] | 1-262 |
| 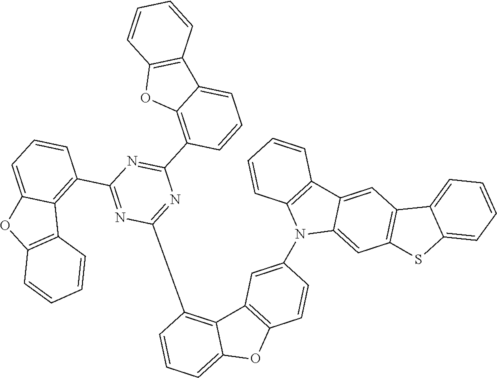 [SMILES: c1ccc2c(c1)oc1c(-c3nc(-c4cccc5oc6ccccc6c45)nc(-c4cccc5oc6ccc(-n7c8ccccc8c8cc9c(cc87)sc7ccccc79)cc6c45)n3)cccc12] | 1-263 |
| 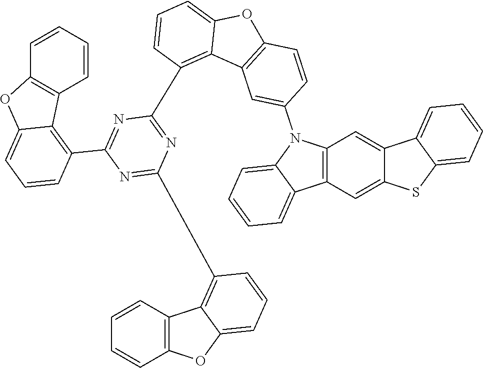 [SMILES: c1ccc2c(c1)oc1cccc(-c3nc(-c4cccc5oc6ccccc6c45)nc(-c4cccc5oc6ccc(-n7c8ccccc8c8cc9sc%10ccccc%10c9cc87)cc6c45)n3)c12] | 1-264 |
| 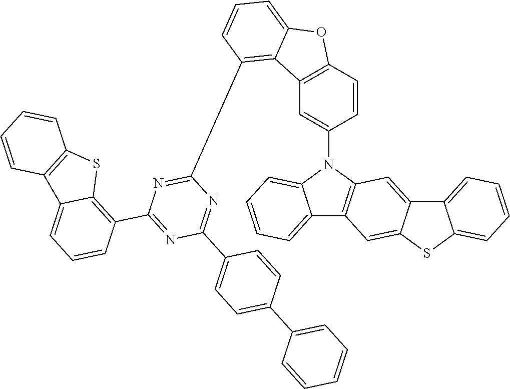 [SMILES: c1ccc(-c2ccc(-c3nc(-c4cccc5c4sc4ccccc45)nc(-c4cccc5oc6ccc(-n7c8ccccc8c8cc9sc%10ccccc%10c9cc87)cc6c45)n3)cc2)cc1] | 1-265 |
| 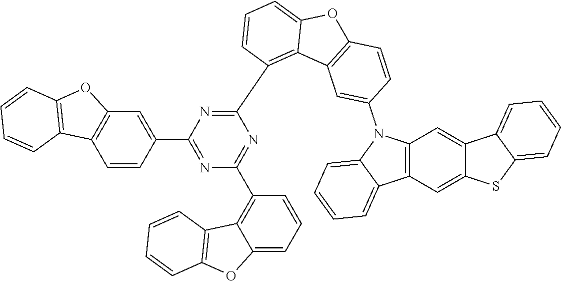 [SMILES: c1ccc2c(c1)oc1cc(-c3nc(-c4cccc5oc6ccccc6c45)nc(-c4cccc5oc6ccc(-n7c8ccccc8c8cc9sc%10ccccc%10c9cc87)cc6c45)n3)ccc12] | 1-266 |
| 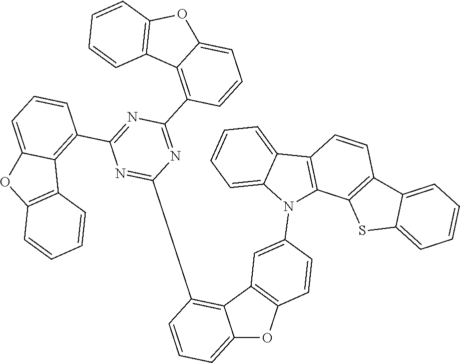 [SMILES: c1ccc2c(c1)oc1cccc(-c3nc(-c4cccc5oc6ccccc6c45)nc(-c4cccc5oc6ccc(-n7c8ccccc8c8ccc9c%10ccccc%10sc9c87)cc6c45)n3)c12] | 1-267 |
| 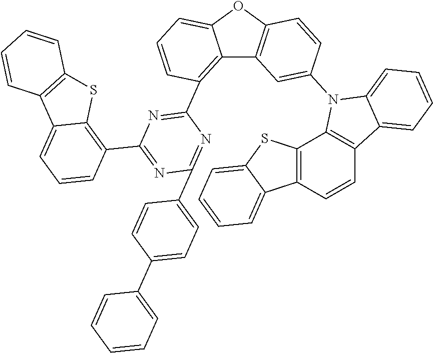 [SMILES: c1ccc(-c2ccc(-c3nc(-c4cccc5c4sc4ccccc45)nc(-c4cccc5oc6ccc(-n7c8ccccc8c8ccc9c%10ccccc%10sc9c87)cc6c45)n3)cc2)cc1] | 1-268 |
| 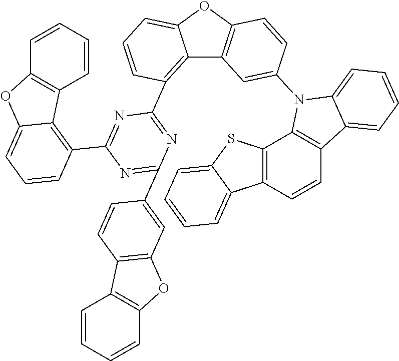 [SMILES: c1ccc2c(c1)oc1cc(-c3nc(-c4cccc5oc6ccccc6c45)nc(-c4cccc5oc6ccc(-n7c8ccccc8c8ccc9c%10ccccc%10sc9c87)cc6c45)n3)ccc12] | 1-269 |
| 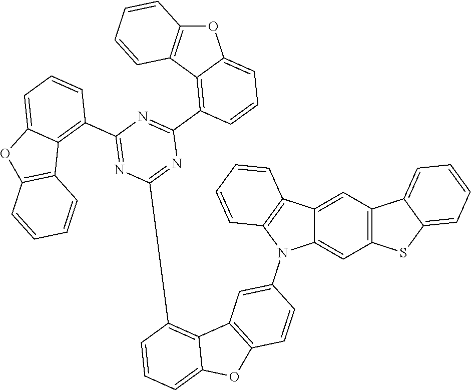 [SMILES: c1ccc2c(c1)oc1cccc(-c3nc(-c4cccc5oc6ccccc6c45)nc(-c4cccc5oc6ccc(-n7c8ccccc8c8cc9c(cc87)sc7ccccc79)cc6c45)n3)c12] | 1-270 |
| 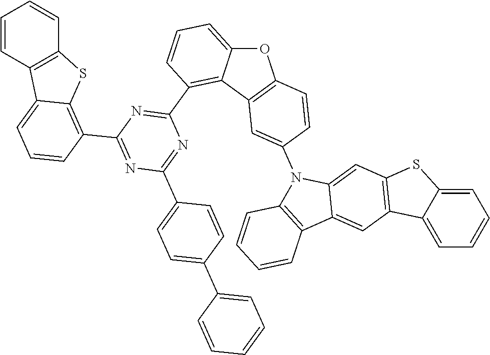 [SMILES: c1ccc(-c2ccc(-c3nc(-c4cccc5c4sc4ccccc45)nc(-c4cccc5oc6ccc(-n7c8ccccc8c8cc9c(cc87)sc7ccccc79)cc6c45)n3)cc2)cc1] | 1-271 |
| 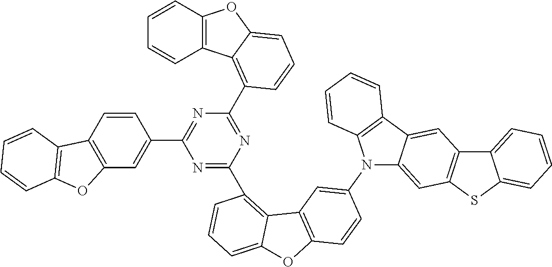 [SMILES: c1ccc2c(c1)oc1cc(-c3nc(-c4cccc5oc6ccccc6c45)nc(-c4cccc5oc6ccc(-n7c8ccccc8c8cc9c(cc87)sc7ccccc79)cc6c45)n3)ccc12] | 1-272 |
| 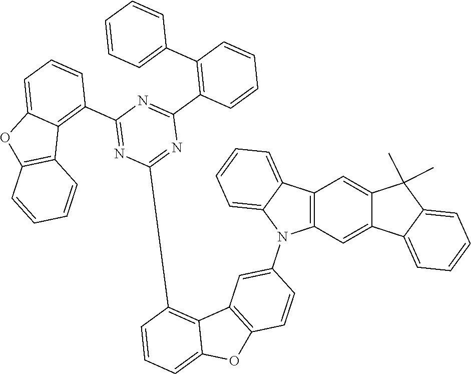 [SMILES: CC1(C)c2ccccc2-c2cc3c(cc21)c1ccccc1n3-c1ccc2oc3cccc(-c4nc(-c5ccccc5-c5ccccc5)nc(-c5cccc6oc7ccccc7c56)n4)c3c2c1] | 1-273 |
| 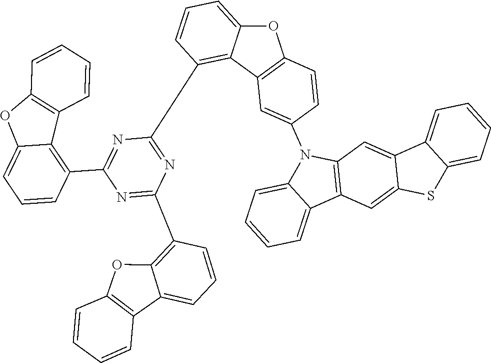 [SMILES: c1ccc2c(c1)oc1c(-c3nc(-c4cccc5oc6ccccc6c45)nc(-c4cccc5oc6ccc(-n7c8ccccc8c8cc9sc%10ccccc%10c9cc87)cc6c45)n3)cccc12] | 1-274 |
| 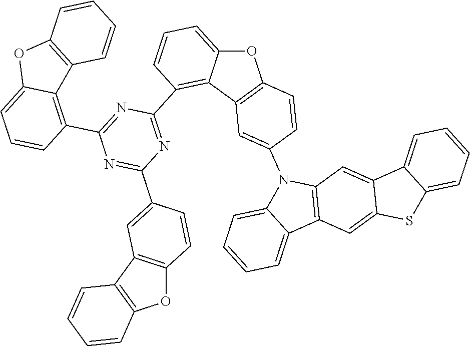 [SMILES: c1ccc2c(c1)oc1ccc(-c3nc(-c4cccc5oc6ccccc6c45)nc(-c4cccc5oc6ccc(-n7c8ccccc8c8cc9sc%10ccccc%10c9cc87)cc6c45)n3)cc12] | 1-275 |
| 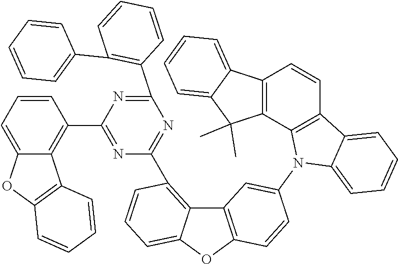 [SMILES: CC1(C)c2ccccc2-c2ccc3c4ccccc4n(-c4ccc5oc6cccc(-c7nc(-c8ccccc8-c8ccccc8)nc(-c8cccc9oc%10ccccc%10c89)n7)c6c5c4)c3c21] | 1-276 |
| 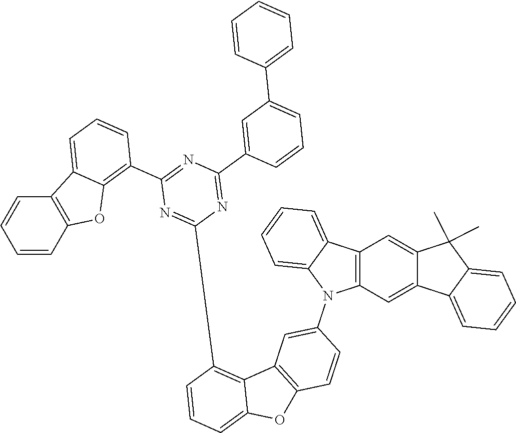 [SMILES: CC1(C)c2ccccc2-c2cc3c(cc21)c1ccccc1n3-c1ccc2oc3cccc(-c4nc(-c5cccc(-c6ccccc6)c5)nc(-c5cccc6c5oc5ccccc56)n4)c3c2c1] | 1-277 |
| 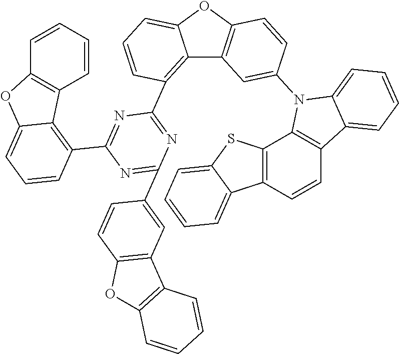 [SMILES: c1ccc2c(c1)oc1ccc(-c3nc(-c4cccc5oc6ccccc6c45)nc(-c4cccc5oc6ccc(-n7c8ccccc8c8ccc9c%10ccccc%10sc9c87)cc6c45)n3)cc12] | 1-278 |
| 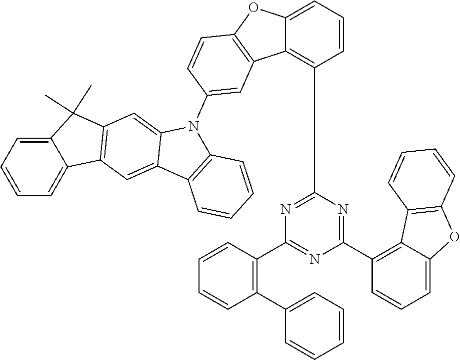 [SMILES: CC1(C)c2ccccc2-c2cc3c4ccccc4n(-c4ccc5oc6cccc(-c7nc(-c8ccccc8-c8ccccc8)nc(-c8cccc9oc%10ccccc%10c89)n7)c6c5c4)c3cc21] | 1-279 |
| 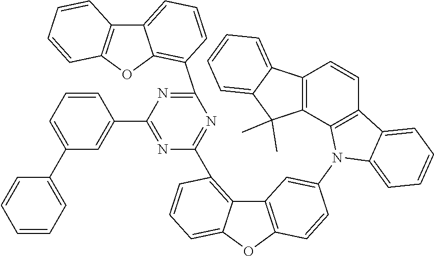 [SMILES: CC1(C)c2ccccc2-c2ccc3c4ccccc4n(-c4ccc5oc6cccc(-c7nc(-c8cccc(-c9ccccc9)c8)nc(-c8cccc9c8oc8ccccc89)n7)c6c5c4)c3c21] | 1-280 |
| 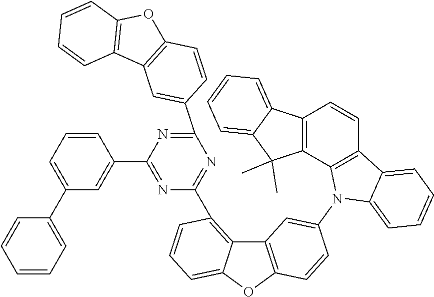 [SMILES: CC1(C)c2ccccc2-c2ccc3c4ccccc4n(-c4ccc5oc6cccc(-c7nc(-c8cccc(-c9ccccc9)c8)nc(-c8ccc9oc%10ccccc%10c9c8)n7)c6c5c4)c3c21] | 1-281 |
| 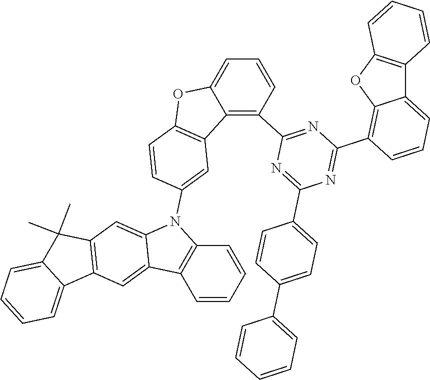 [SMILES: CC1(C)c2ccccc2-c2cc3c4ccccc4n(-c4ccc5oc6cccc(-c7nc(-c8ccc(-c9ccccc9)cc8)nc(-c8cccc9c8oc8ccccc89)n7)c6c5c4)c3cc21] | 1-282 |
| 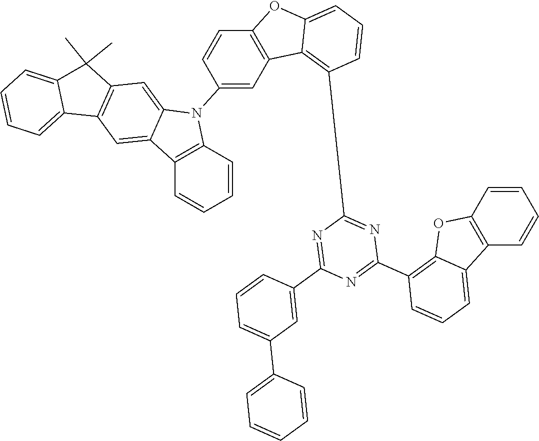 [SMILES: CC1(C)c2ccccc2-c2cc3c4ccccc4n(-c4ccc5oc6cccc(-c7nc(-c8cccc(-c9ccccc9)c8)nc(-c8cccc9c8oc8ccccc89)n7)c6c5c4)c3cc21] | 1-283 |
| 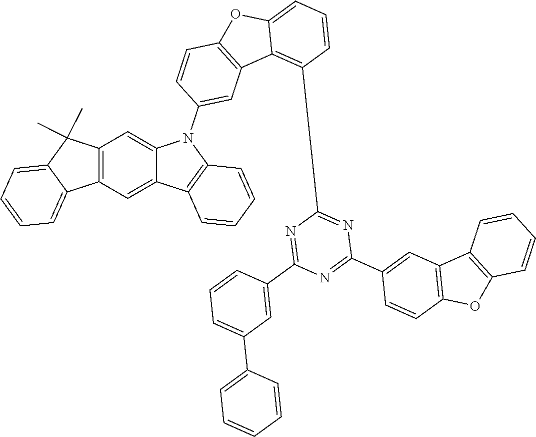 [SMILES: CC1(C)c2ccccc2-c2cc3c4ccccc4n(-c4ccc5oc6cccc(-c7nc(-c8cccc(-c9ccccc9)c8)nc(-c8ccc9oc%10ccccc%10c9c8)n7)c6c5c4)c3cc21] | 1-284 |
| 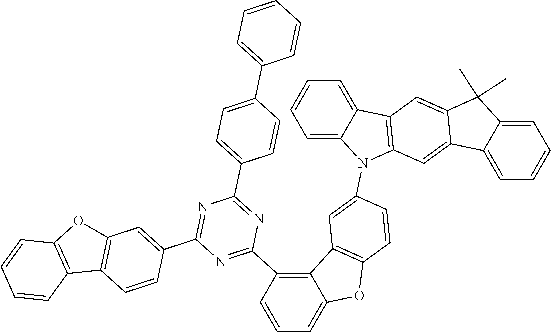 [SMILES: CC1(C)c2ccccc2-c2cc3c(cc21)c1ccccc1n3-c1ccc2oc3cccc(-c4nc(-c5ccc(-c6ccccc6)cc5)nc(-c5ccc6c(c5)oc5ccccc56)n4)c3c2c1] | 1-285 |
| 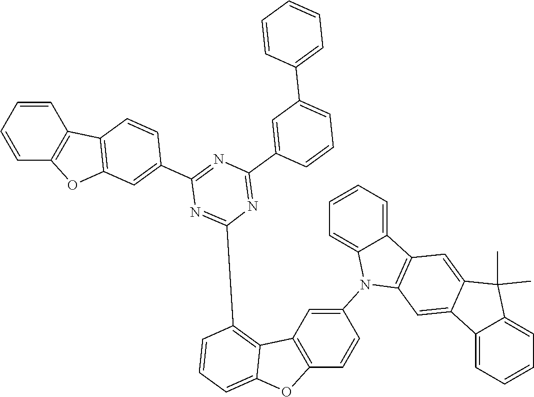 [SMILES: CC1(C)c2ccccc2-c2cc3c(cc21)c1ccccc1n3-c1ccc2oc3cccc(-c4nc(-c5cccc(-c6ccccc6)c5)nc(-c5ccc6c(c5)oc5ccccc56)n4)c3c2c1] | 1-286 |
| 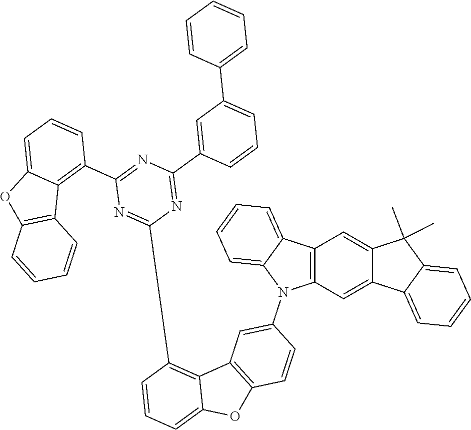 [SMILES: CC1(C)c2ccccc2-c2cc3c(cc21)c1ccccc1n3-c1ccc2oc3cccc(-c4nc(-c5cccc(-c6ccccc6)c5)nc(-c5cccc6oc7ccccc7c56)n4)c3c2c1] | 1-287 |
| 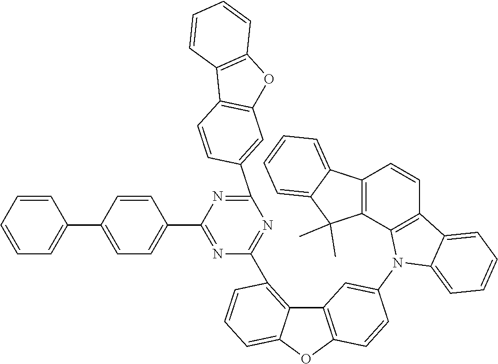 [SMILES: CC1(C)c2ccccc2-c2ccc3c4ccccc4n(-c4ccc5oc6cccc(-c7nc(-c8ccc(-c9ccccc9)cc8)nc(-c8ccc9c(c8)oc8ccccc89)n7)c6c5c4)c3c21] | 1-288 |
| 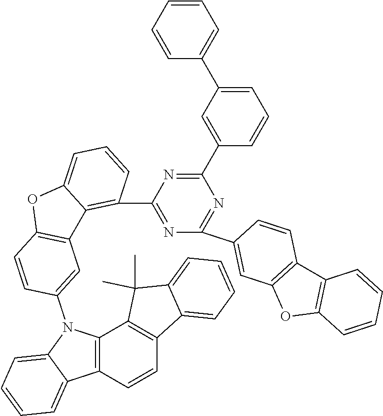 [SMILES: CC1(C)c2ccccc2-c2ccc3c4ccccc4n(-c4ccc5oc6cccc(-c7nc(-c8cccc(-c9ccccc9)c8)nc(-c8ccc9c(c8)oc8ccccc89)n7)c6c5c4)c3c21] | 1-289 |
| 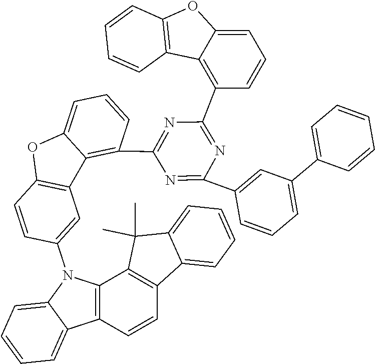 [SMILES: CC1(C)c2ccccc2-c2ccc3c4ccccc4n(-c4ccc5oc6cccc(-c7nc(-c8cccc(-c9ccccc9)c8)nc(-c8cccc9oc%10ccccc%10c89)n7)c6c5c4)c3c21] | 1-290 |
| 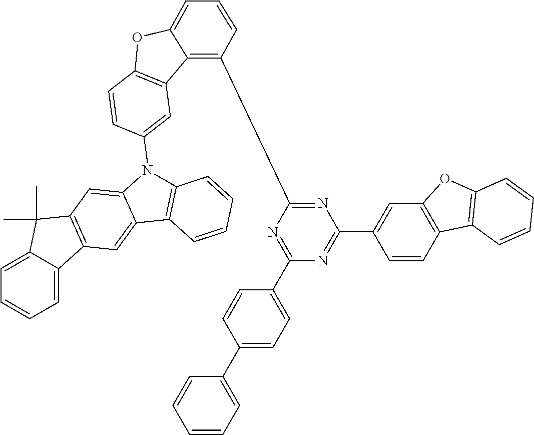 [SMILES: CC1(C)c2ccccc2-c2cc3c4ccccc4n(-c4ccc5oc6cccc(-c7nc(-c8ccc(-c9ccccc9)cc8)nc(-c8ccc9c(c8)oc8ccccc89)n7)c6c5c4)c3cc21] | 1-291 |
| 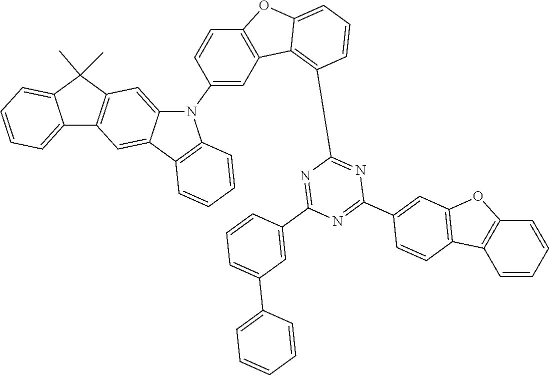 [SMILES: CC1(C)c2ccccc2-c2cc3c4ccccc4n(-c4ccc5oc6cccc(-c7nc(-c8cccc(-c9ccccc9)c8)nc(-c8ccc9c(c8)oc8ccccc89)n7)c6c5c4)c3cc21] | 1-292 |
| 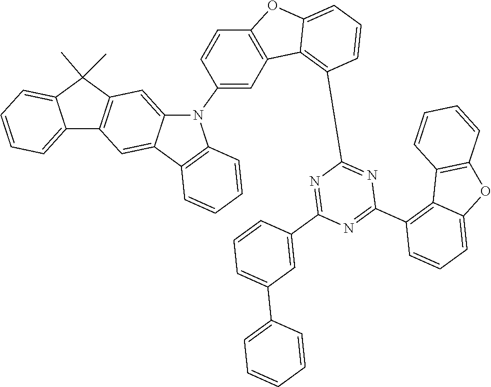 [SMILES: CC1(C)c2ccccc2-c2cc3c4ccccc4n(-c4ccc5oc6cccc(-c7nc(-c8cccc(-c9ccccc9)c8)nc(-c8cccc9oc%10ccccc%10c89)n7)c6c5c4)c3cc21] | 1-293 |
| 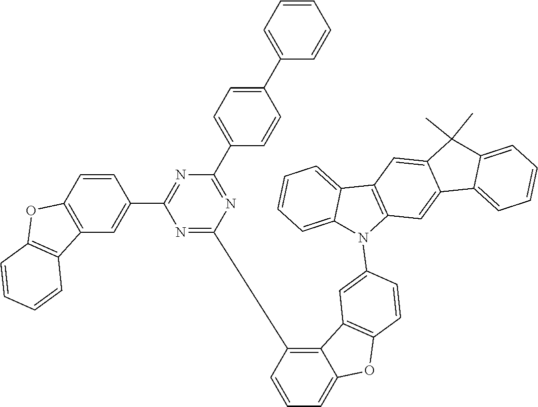 [SMILES: CC1(C)c2ccccc2-c2cc3c(cc21)c1ccccc1n3-c1ccc2oc3cccc(-c4nc(-c5ccc(-c6ccccc6)cc5)nc(-c5ccc6oc7ccccc7c6c5)n4)c3c2c1] | 1-294 |
| 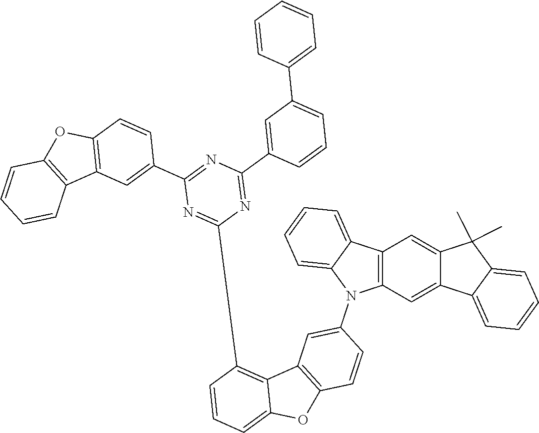 [SMILES: CC1(C)c2ccccc2-c2cc3c(cc21)c1ccccc1n3-c1ccc2oc3cccc(-c4nc(-c5cccc(-c6ccccc6)c5)nc(-c5ccc6oc7ccccc7c6c5)n4)c3c2c1] | 1-295 |
| 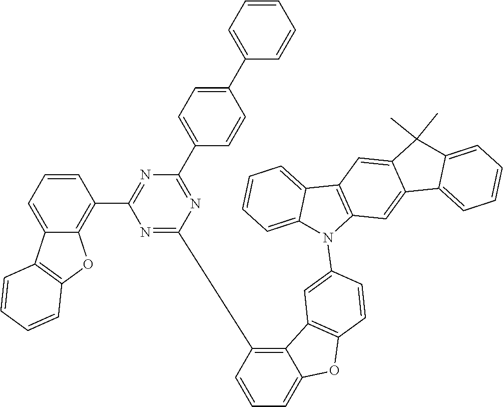 [SMILES: CC1(C)c2ccccc2-c2cc3c(cc21)c1ccccc1n3-c1ccc2oc3cccc(-c4nc(-c5ccc(-c6ccccc6)cc5)nc(-c5cccc6c5oc5ccccc56)n4)c3c2c1] | 1-296 |
| 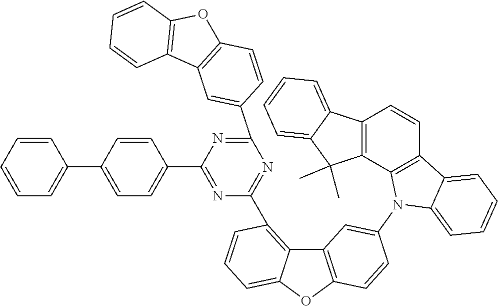 [SMILES: CC1(C)c2ccccc2-c2ccc3c4ccccc4n(-c4ccc5oc6cccc(-c7nc(-c8ccc(-c9ccccc9)cc8)nc(-c8ccc9oc%10ccccc%10c9c8)n7)c6c5c4)c3c21] | 1-297 |
| 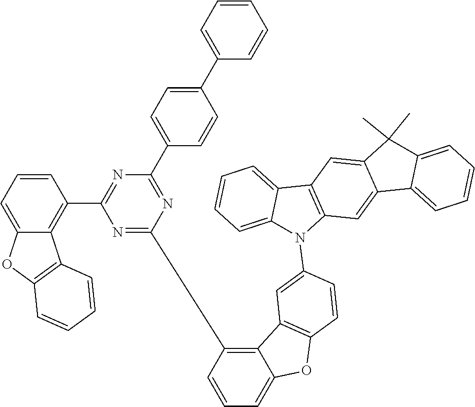 [SMILES: CC1(C)c2ccccc2-c2cc3c(cc21)c1ccccc1n3-c1ccc2oc3cccc(-c4nc(-c5ccc(-c6ccccc6)cc5)nc(-c5cccc6oc7ccccc7c56)n4)c3c2c1] | 1-298 |
| 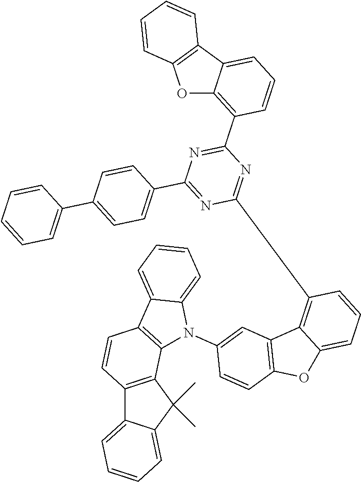 [SMILES: CC1(C)c2ccccc2-c2ccc3c4ccccc4n(-c4ccc5oc6cccc(-c7nc(-c8ccc(-c9ccccc9)cc8)nc(-c8cccc9c8oc8ccccc89)n7)c6c5c4)c3c21] | 1-299 |
| 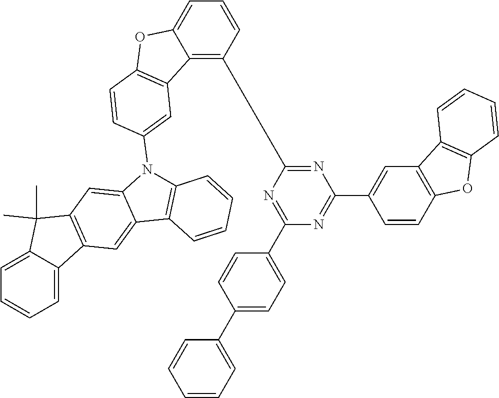 [SMILES: CC1(C)c2ccccc2-c2cc3c4ccccc4n(-c4ccc5oc6cccc(-c7nc(-c8ccc(-c9ccccc9)cc8)nc(-c8ccc9oc%10ccccc%10c9c8)n7)c6c5c4)c3cc21] | 1-300 |
| 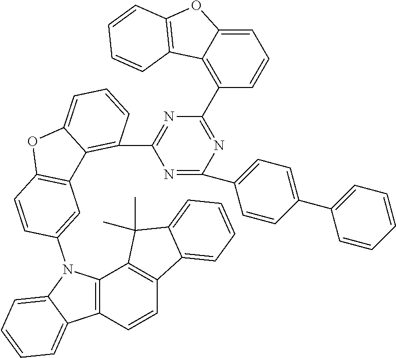 [SMILES: CC1(C)c2ccccc2-c2ccc3c4ccccc4n(-c4ccc5oc6cccc(-c7nc(-c8ccc(-c9ccccc9)cc8)nc(-c8cccc9oc%10ccccc%10c89)n7)c6c5c4)c3c21] | 1-301 |
| 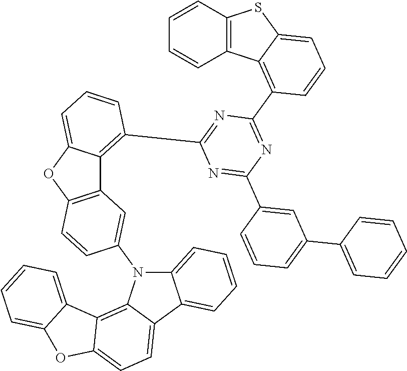 [SMILES: c1ccc(-c2cccc(-c3nc(-c4cccc5oc6ccc(-n7c8ccccc8c8ccc9oc%10ccccc%10c9c87)cc6c45)nc(-c4cccc5sc6ccccc6c45)n3)c2)cc1] | 1-302 |
| 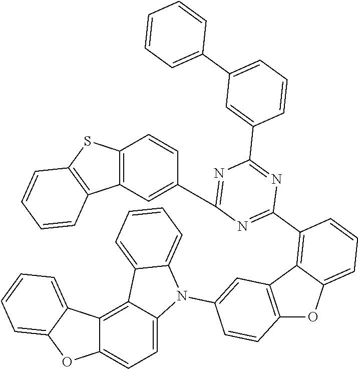 [SMILES: c1ccc(-c2cccc(-c3nc(-c4ccc5sc6ccccc6c5c4)nc(-c4cccc5oc6ccc(-n7c8ccccc8c8c9c(ccc87)oc7ccccc79)cc6c45)n3)c2)cc1] | 1-303 |
| 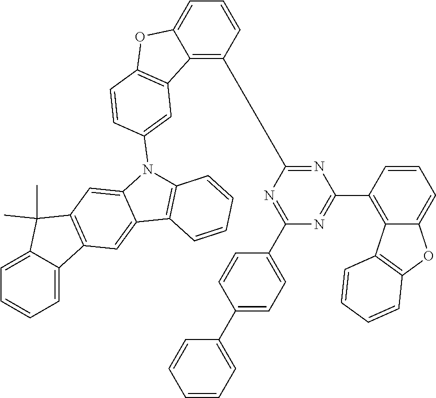 [SMILES: CC1(C)c2ccccc2-c2cc3c4ccccc4n(-c4ccc5oc6cccc(-c7nc(-c8ccc(-c9ccccc9)cc8)nc(-c8cccc9oc%10ccccc%10c89)n7)c6c5c4)c3cc21] | 1-304 |
| 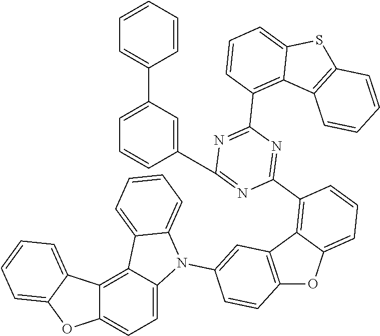 [SMILES: c1ccc(-c2cccc(-c3nc(-c4cccc5oc6ccc(-n7c8ccccc8c8c9c(ccc87)oc7ccccc79)cc6c45)nc(-c4cccc5sc6ccccc6c45)n3)c2)cc1] | 1-305 |
| 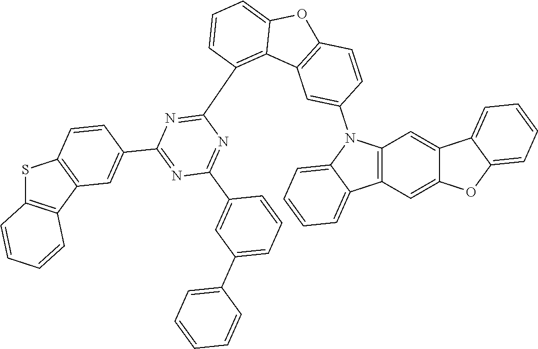 [SMILES: c1ccc(-c2cccc(-c3nc(-c4ccc5sc6ccccc6c5c4)nc(-c4cccc5oc6ccc(-n7c8ccccc8c8cc9oc%10ccccc%10c9cc87)cc6c45)n3)c2)cc1] | 1-306 |
| 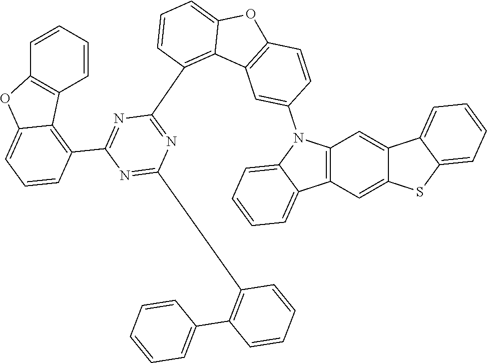 [SMILES: c1ccc(-c2ccccc2-c2nc(-c3cccc4oc5ccccc5c34)nc(-c3cccc4oc5ccc(-n6c7ccccc7c7cc8sc9ccccc9c8cc76)cc5c34)n2)cc1] | 1-307 |
| 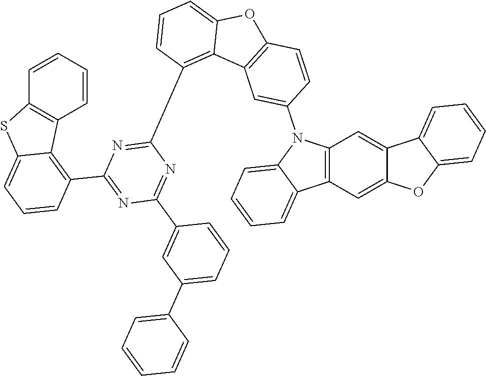 [SMILES: c1ccc(-c2cccc(-c3nc(-c4cccc5oc6ccc(-n7c8ccccc8c8cc9oc%10ccccc%10c9cc87)cc6c45)nc(-c4cccc5sc6ccccc6c45)n3)c2)cc1] | 1-308 |
| 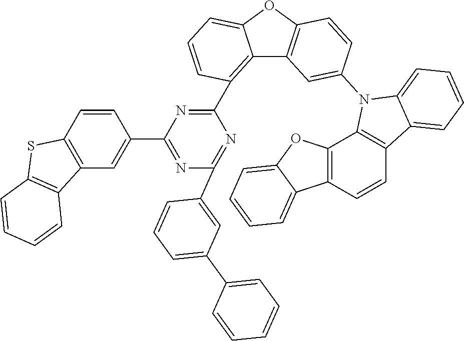 [SMILES: c1ccc(-c2cccc(-c3nc(-c4ccc5sc6ccccc6c5c4)nc(-c4cccc5oc6ccc(-n7c8ccccc8c8ccc9c%10ccccc%10oc9c87)cc6c45)n3)c2)cc1] | 1-309 |
| 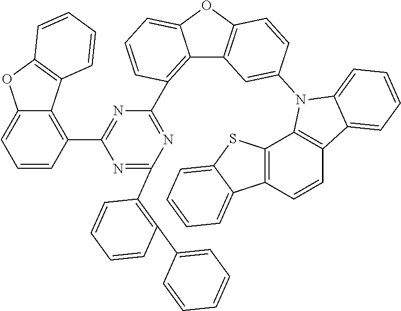 [SMILES: c1ccc(-c2ccccc2-c2nc(-c3cccc4oc5ccccc5c34)nc(-c3cccc4oc5ccc(-n6c7ccccc7c7ccc8c9ccccc9sc8c76)cc5c34)n2)cc1] | 1-310 |
| 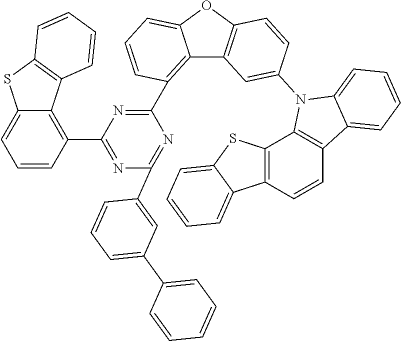 [SMILES: c1ccc(-c2cccc(-c3nc(-c4cccc5oc6ccc(-n7c8ccccc8c8ccc9c%10ccccc%10sc9c87)cc6c45)nc(-c4cccc5sc6ccccc6c45)n3)c2)cc1] | 1-311 |
| 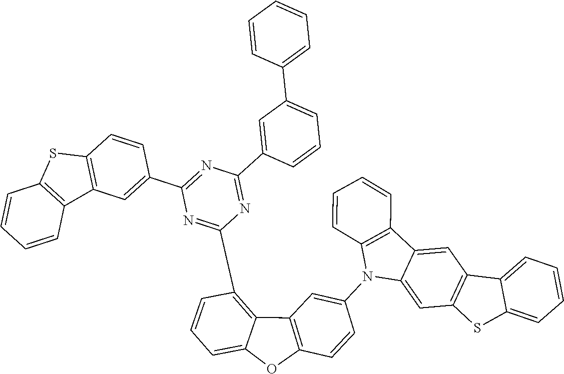 [SMILES: c1ccc(-c2cccc(-c3nc(-c4ccc5sc6ccccc6c5c4)nc(-c4cccc5oc6ccc(-n7c8ccccc8c8cc9c(cc87)sc7ccccc79)cc6c45)n3)c2)cc1] | 1-312 |
| 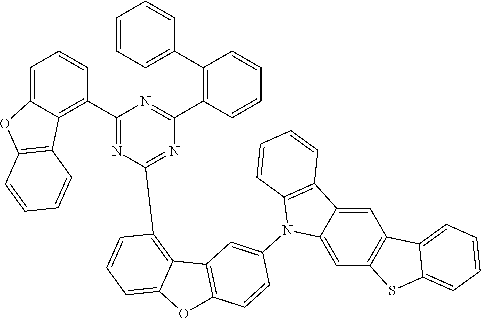 [SMILES: c1ccc(-c2ccccc2-c2nc(-c3cccc4oc5ccccc5c34)nc(-c3cccc4oc5ccc(-n6c7ccccc7c7cc8c(cc76)sc6ccccc68)cc5c34)n2)cc1] | 1-313 |
| 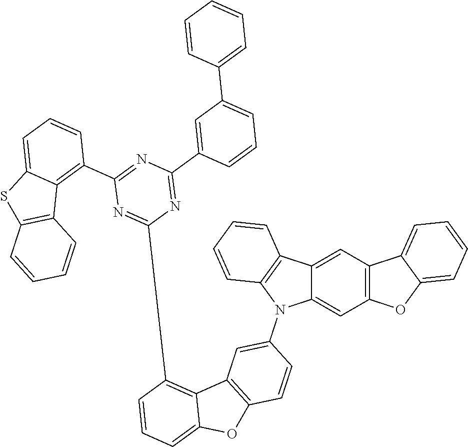 [SMILES: c1ccc(-c2cccc(-c3nc(-c4cccc5oc6ccc(-n7c8ccccc8c8cc9c(cc87)oc7ccccc79)cc6c45)nc(-c4cccc5sc6ccccc6c45)n3)c2)cc1] | 1-314 |
| 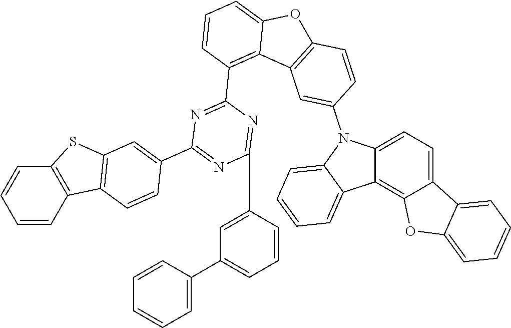 [SMILES: c1ccc(-c2cccc(-c3nc(-c4ccc5c(c4)sc4ccccc45)nc(-c4cccc5oc6ccc(-n7c8ccccc8c8c9oc%10ccccc%10c9ccc87)cc6c45)n3)c2)cc1] | 1-315 |
| 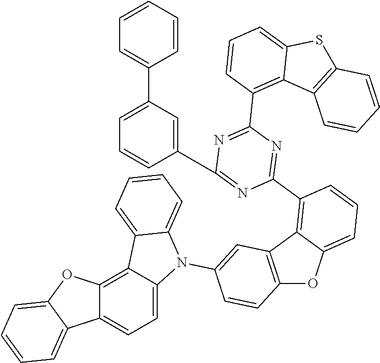 [SMILES: c1ccc(-c2cccc(-c3nc(-c4cccc5oc6ccc(-n7c8ccccc8c8c9oc%10ccccc%10c9ccc87)cc6c45)nc(-c4cccc5sc6ccccc6c45)n3)c2)cc1] | 1-316 |
| 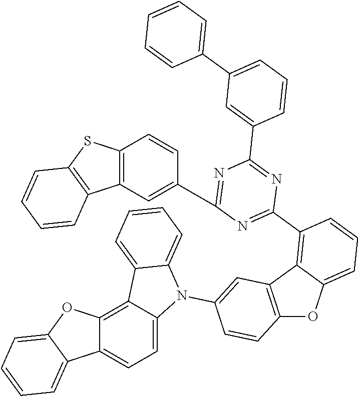 [SMILES: c1ccc(-c2cccc(-c3nc(-c4ccc5sc6ccccc6c5c4)nc(-c4cccc5oc6ccc(-n7c8ccccc8c8c9oc%10ccccc%10c9ccc87)cc6c45)n3)c2)cc1] | 1-317 |
| 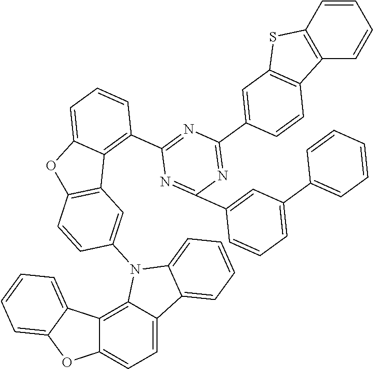 [SMILES: c1ccc(-c2cccc(-c3nc(-c4ccc5c(c4)sc4ccccc45)nc(-c4cccc5oc6ccc(-n7c8ccccc8c8ccc9oc%10ccccc%10c9c87)cc6c45)n3)c2)cc1] | 1-318 |
| 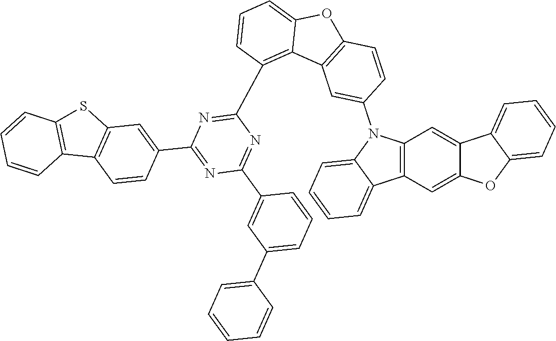 [SMILES: c1ccc(-c2cccc(-c3nc(-c4ccc5c(c4)sc4ccccc45)nc(-c4cccc5oc6ccc(-n7c8ccccc8c8cc9oc%10ccccc%10c9cc87)cc6c45)n3)c2)cc1] | 1-319 |
| 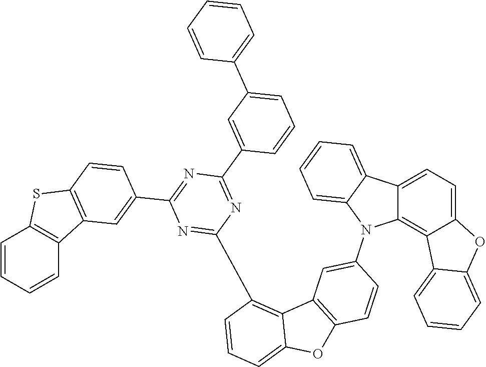 [SMILES: c1ccc(-c2cccc(-c3nc(-c4ccc5sc6ccccc6c5c4)nc(-c4cccc5oc6ccc(-n7c8ccccc8c8ccc9oc%10ccccc%10c9c87)cc6c45)n3)c2)cc1] | 1-320 |
| 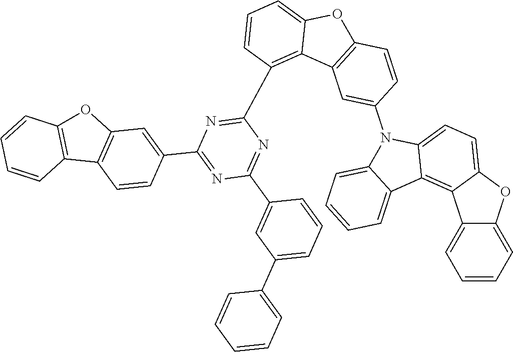 [SMILES: c1ccc(-c2cccc(-c3nc(-c4ccc5c(c4)oc4ccccc45)nc(-c4cccc5oc6ccc(-n7c8ccccc8c8c9c(ccc87)oc7ccccc79)cc6c45)n3)c2)cc1] | 1-321 |
| 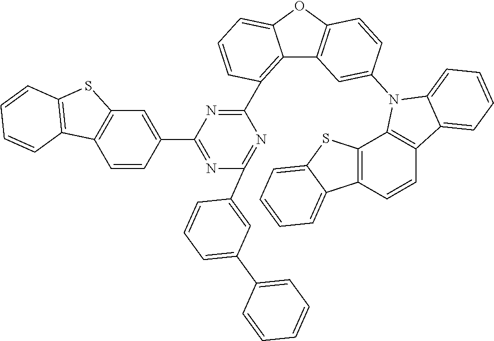 [SMILES: c1ccc(-c2cccc(-c3nc(-c4ccc5c(c4)sc4ccccc45)nc(-c4cccc5oc6ccc(-n7c8ccccc8c8ccc9c%10ccccc%10sc9c87)cc6c45)n3)c2)cc1] | 1-322 |
| 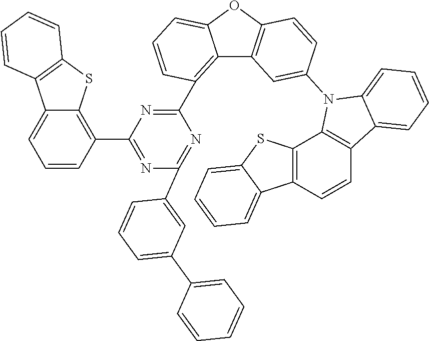 [SMILES: c1ccc(-c2cccc(-c3nc(-c4cccc5c4sc4ccccc45)nc(-c4cccc5oc6ccc(-n7c8ccccc8c8ccc9c%10ccccc%10sc9c87)cc6c45)n3)c2)cc1] | 1-323 |
| 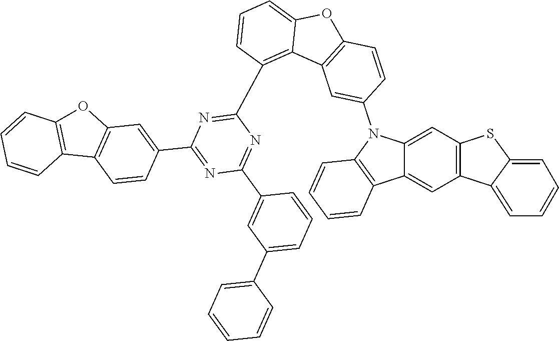 [SMILES: c1ccc(-c2cccc(-c3nc(-c4ccc5c(c4)oc4ccccc45)nc(-c4cccc5oc6ccc(-n7c8ccccc8c8cc9c(cc87)sc7ccccc79)cc6c45)n3)c2)cc1] | 1-324 |
| 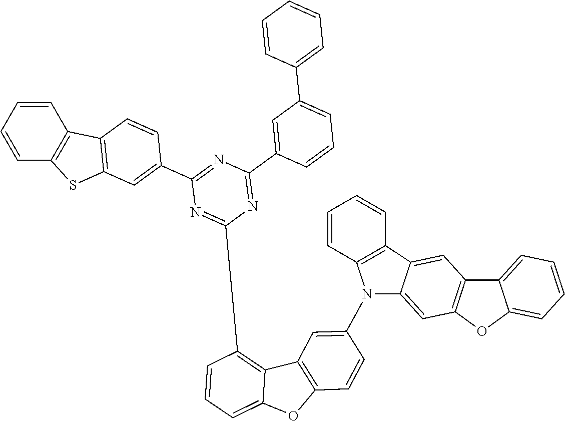 [SMILES: c1ccc(-c2cccc(-c3nc(-c4ccc5c(c4)sc4ccccc45)nc(-c4cccc5oc6ccc(-n7c8ccccc8c8cc9c(cc87)oc7ccccc79)cc6c45)n3)c2)cc1] | 1-325 |
| 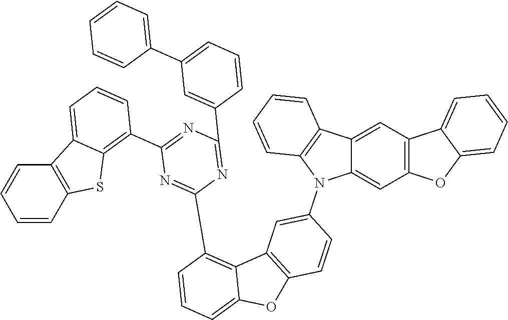 [SMILES: c1ccc(-c2cccc(-c3nc(-c4cccc5c4sc4ccccc45)nc(-c4cccc5oc6ccc(-n7c8ccccc8c8cc9c(cc87)oc7ccccc79)cc6c45)n3)c2)cc1] | 1-326 |
| 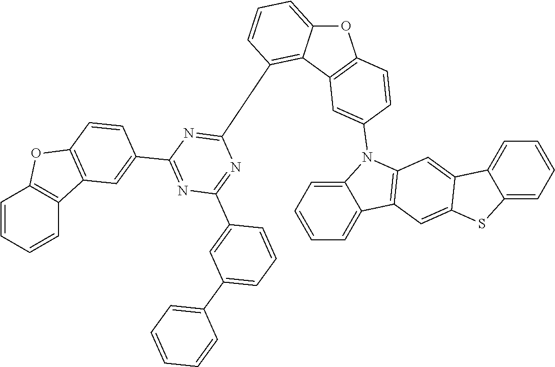 [SMILES: c1ccc(-c2cccc(-c3nc(-c4ccc5oc6ccccc6c5c4)nc(-c4cccc5oc6ccc(-n7c8ccccc8c8cc9sc%10ccccc%10c9cc87)cc6c45)n3)c2)cc1] | 1-327 |
| 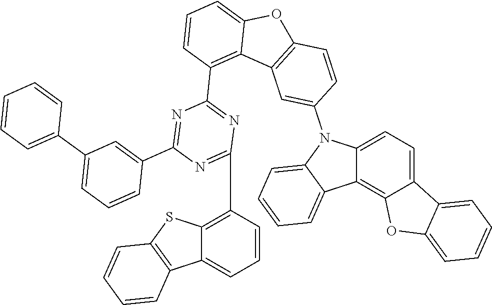 [SMILES: c1ccc(-c2cccc(-c3nc(-c4cccc5c4sc4ccccc45)nc(-c4cccc5oc6ccc(-n7c8ccccc8c8c9oc%10ccccc%10c9ccc87)cc6c45)n3)c2)cc1] | 1-328 |
| 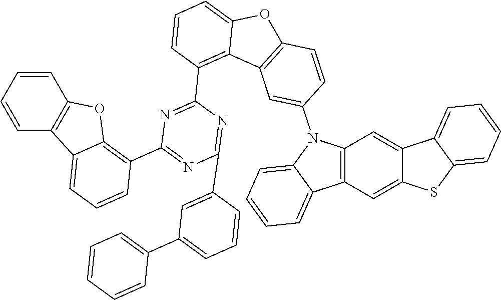 [SMILES: c1ccc(-c2cccc(-c3nc(-c4cccc5c4oc4ccccc45)nc(-c4cccc5oc6ccc(-n7c8ccccc8c8cc9sc%10ccccc%10c9cc87)cc6c45)n3)c2)cc1] | 1-329 |
| 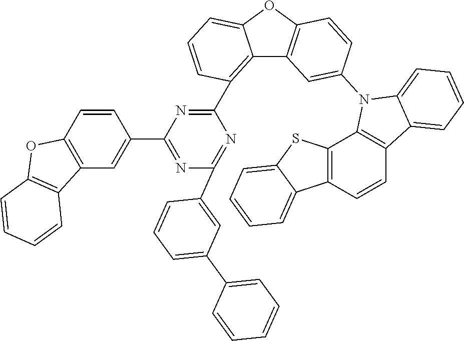 [SMILES: c1ccc(-c2cccc(-c3nc(-c4ccc5oc6ccccc6c5c4)nc(-c4cccc5oc6ccc(-n7c8ccccc8c8ccc9c%10ccccc%10sc9c87)cc6c45)n3)c2)cc1] | 1-330 |
| 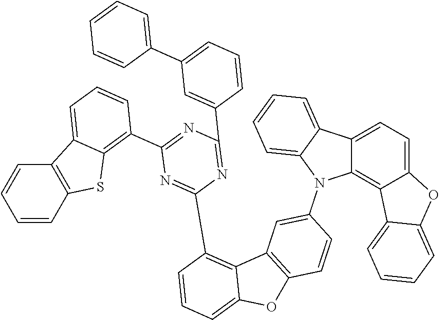 [SMILES: c1ccc(-c2cccc(-c3nc(-c4cccc5c4sc4ccccc45)nc(-c4cccc5oc6ccc(-n7c8ccccc8c8ccc9oc%10ccccc%10c9c87)cc6c45)n3)c2)cc1] | 1-331 |
| 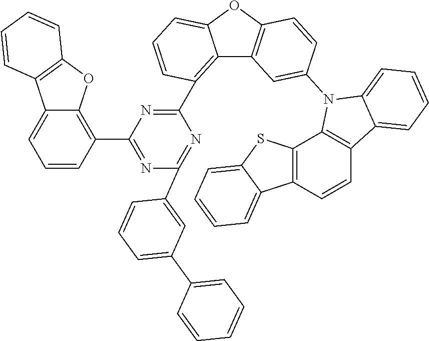 [SMILES: c1ccc(-c2cccc(-c3nc(-c4cccc5c4oc4ccccc45)nc(-c4cccc5oc6ccc(-n7c8ccccc8c8ccc9c%10ccccc%10sc9c87)cc6c45)n3)c2)cc1] | 1-332 |
| 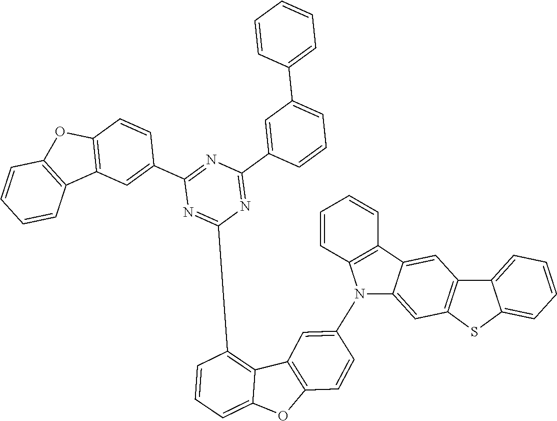 [SMILES: c1ccc(-c2cccc(-c3nc(-c4ccc5oc6ccccc6c5c4)nc(-c4cccc5oc6ccc(-n7c8ccccc8c8cc9c(cc87)sc7ccccc79)cc6c45)n3)c2)cc1] | 1-333 |
| 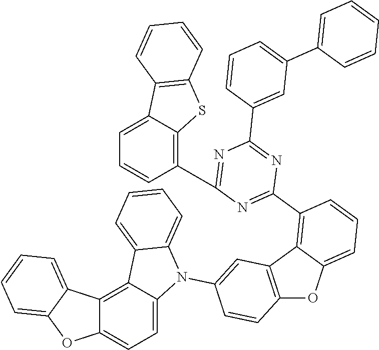 [SMILES: c1ccc(-c2cccc(-c3nc(-c4cccc5c4sc4ccccc45)nc(-c4cccc5oc6ccc(-n7c8ccccc8c8c9c(ccc87)oc7ccccc79)cc6c45)n3)c2)cc1] | 1-334 |
| 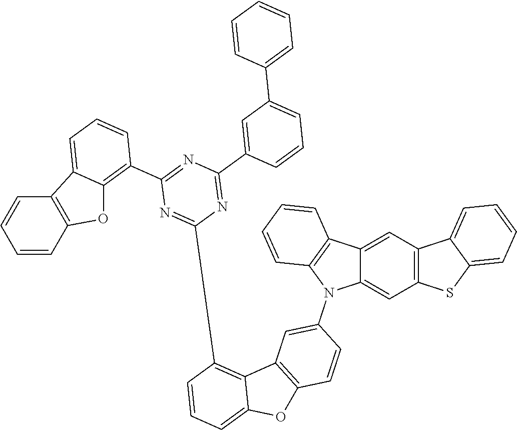 [SMILES: c1ccc(-c2cccc(-c3nc(-c4cccc5c4oc4ccccc45)nc(-c4cccc5oc6ccc(-n7c8ccccc8c8cc9c(cc87)sc7ccccc79)cc6c45)n3)c2)cc1] | 1-335 |
| 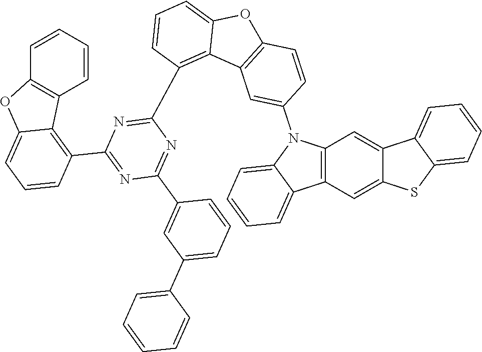 [SMILES: c1ccc(-c2cccc(-c3nc(-c4cccc5oc6ccccc6c45)nc(-c4cccc5oc6ccc(-n7c8ccccc8c8cc9sc%10ccccc%10c9cc87)cc6c45)n3)c2)cc1] | 1-336 |
| 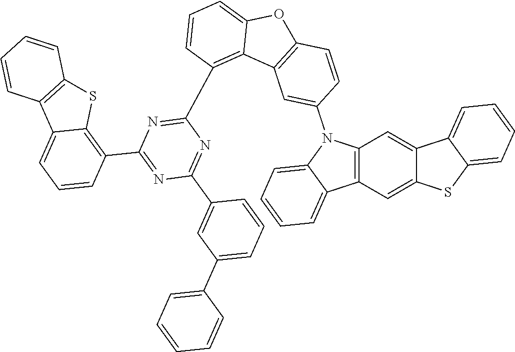 [SMILES: c1ccc(-c2cccc(-c3nc(-c4cccc5c4sc4ccccc45)nc(-c4cccc5oc6ccc(-n7c8ccccc8c8cc9sc%10ccccc%10c9cc87)cc6c45)n3)c2)cc1] | 1-337 |
| 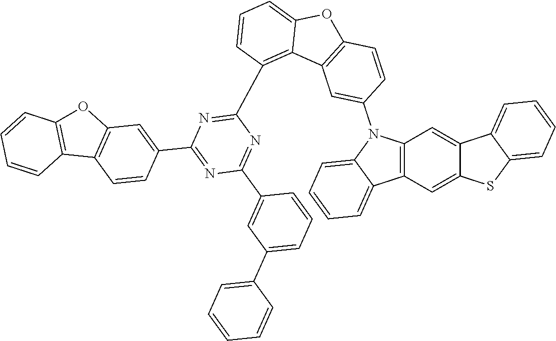 [SMILES: c1ccc(-c2cccc(-c3nc(-c4ccc5c(c4)oc4ccccc45)nc(-c4cccc5oc6ccc(-n7c8ccccc8c8cc9sc%10ccccc%10c9cc87)cc6c45)n3)c2)cc1] | 1-338 |
| 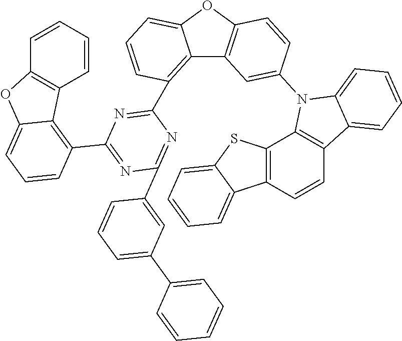 [SMILES: c1ccc(-c2cccc(-c3nc(-c4cccc5oc6ccccc6c45)nc(-c4cccc5oc6ccc(-n7c8ccccc8c8ccc9c%10ccccc%10sc9c87)cc6c45)n3)c2)cc1] | 1-339 |
| 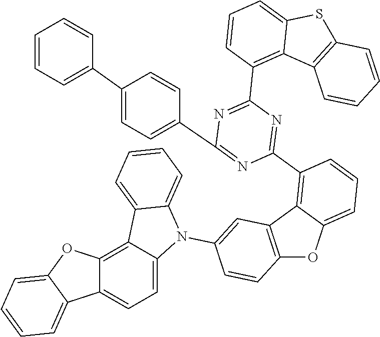 [SMILES: c1ccc(-c2ccc(-c3nc(-c4cccc5oc6ccc(-n7c8ccccc8c8c9oc%10ccccc%10c9ccc87)cc6c45)nc(-c4cccc5sc6ccccc6c45)n3)cc2)cc1] | 1-340 |
| 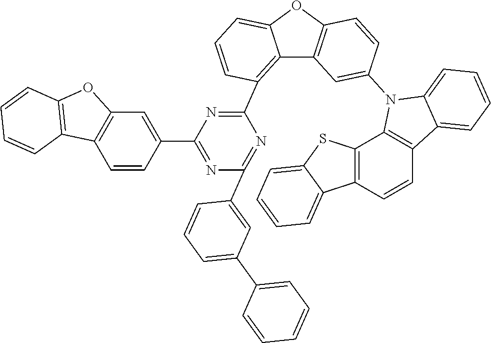 [SMILES: c1ccc(-c2cccc(-c3nc(-c4ccc5c(c4)oc4ccccc45)nc(-c4cccc5oc6ccc(-n7c8ccccc8c8ccc9c%10ccccc%10sc9c87)cc6c45)n3)c2)cc1] | 1-341 |
| 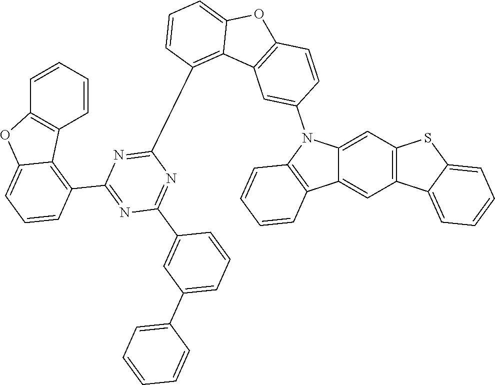 [SMILES: c1ccc(-c2cccc(-c3nc(-c4cccc5oc6ccccc6c45)nc(-c4cccc5oc6ccc(-n7c8ccccc8c8cc9c(cc87)sc7ccccc79)cc6c45)n3)c2)cc1] | 1-342 |
| 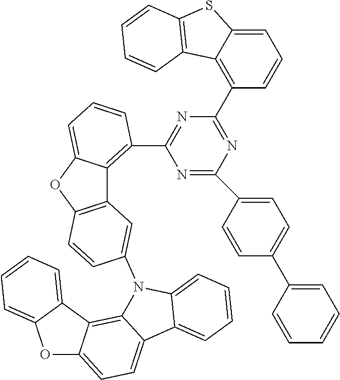 [SMILES: c1ccc(-c2ccc(-c3nc(-c4cccc5oc6ccc(-n7c8ccccc8c8ccc9oc%10ccccc%10c9c87)cc6c45)nc(-c4cccc5sc6ccccc6c45)n3)cc2)cc1] | 1-343 |
| 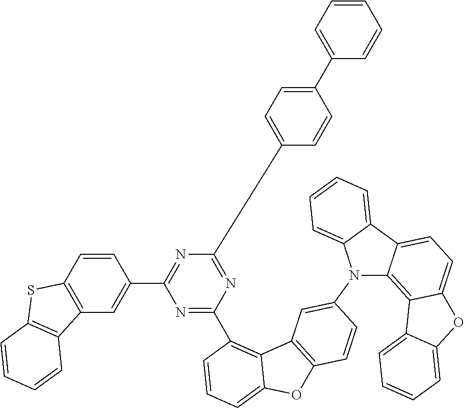 [SMILES: c1ccc(-c2ccc(-c3nc(-c4ccc5sc6ccccc6c5c4)nc(-c4cccc5oc6ccc(-n7c8ccccc8c8ccc9oc%10ccccc%10c9c87)cc6c45)n3)cc2)cc1] | 1-344 |
| 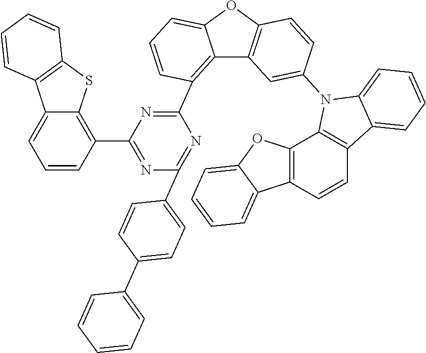 [SMILES: c1ccc(-c2ccc(-c3nc(-c4cccc5c4sc4ccccc45)nc(-c4cccc5oc6ccc(-n7c8ccccc8c8ccc9c%10ccccc%10oc9c87)cc6c45)n3)cc2)cc1] | 1-345 |
| 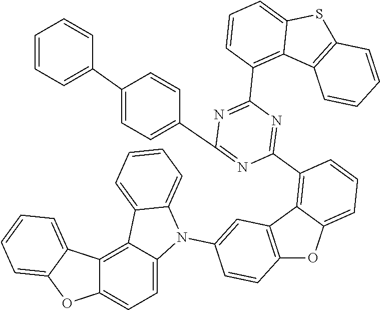 [SMILES: c1ccc(-c2ccc(-c3nc(-c4cccc5oc6ccc(-n7c8ccccc8c8c9c(ccc87)oc7ccccc79)cc6c45)nc(-c4cccc5sc6ccccc6c45)n3)cc2)cc1] | 1-346 |
| 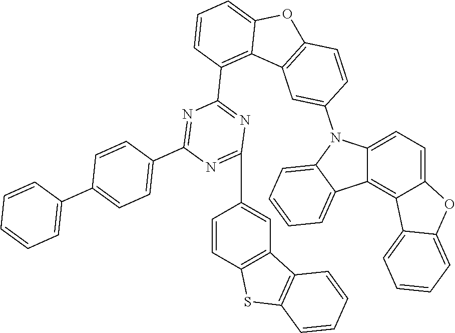 [SMILES: c1ccc(-c2ccc(-c3nc(-c4ccc5sc6ccccc6c5c4)nc(-c4cccc5oc6ccc(-n7c8ccccc8c8c9c(ccc87)oc7ccccc79)cc6c45)n3)cc2)cc1] | 1-347 |
| 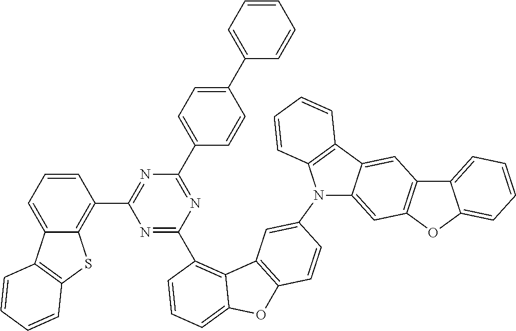 [SMILES: c1ccc(-c2ccc(-c3nc(-c4cccc5c4sc4ccccc45)nc(-c4cccc5oc6ccc(-n7c8ccccc8c8cc9c(cc87)oc7ccccc79)cc6c45)n3)cc2)cc1] | 1-348 |
| 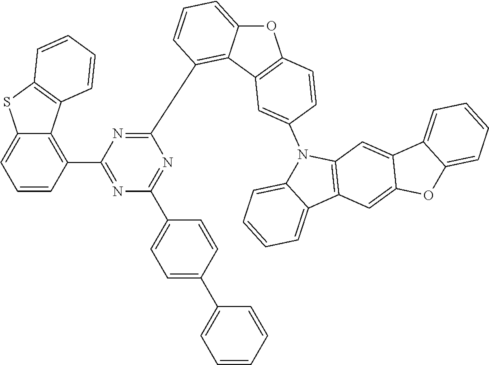 [SMILES: c1ccc(-c2ccc(-c3nc(-c4cccc5oc6ccc(-n7c8ccccc8c8cc9oc%10ccccc%10c9cc87)cc6c45)nc(-c4cccc5sc6ccccc6c45)n3)cc2)cc1] | 1-349 |
| 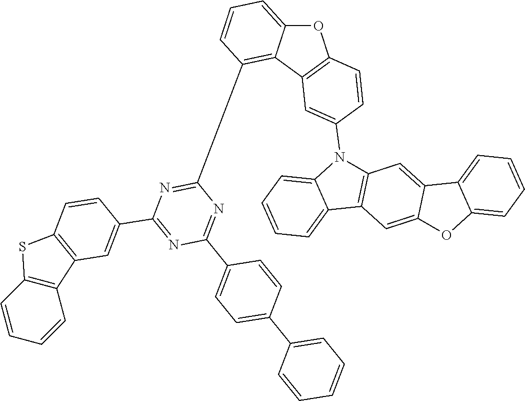 [SMILES: c1ccc(-c2ccc(-c3nc(-c4ccc5sc6ccccc6c5c4)nc(-c4cccc5oc6ccc(-n7c8ccccc8c8cc9oc%10ccccc%10c9cc87)cc6c45)n3)cc2)cc1] | 1-350 |
| 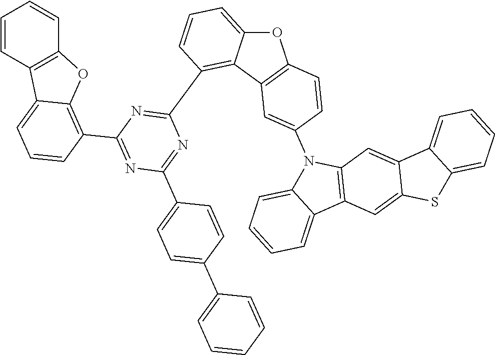 [SMILES: c1ccc(-c2ccc(-c3nc(-c4cccc5c4oc4ccccc45)nc(-c4cccc5oc6ccc(-n7c8ccccc8c8cc9sc%10ccccc%10c9cc87)cc6c45)n3)cc2)cc1] | 1-351 |
| 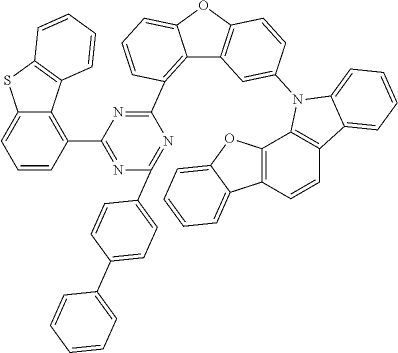 [SMILES: c1ccc(-c2ccc(-c3nc(-c4cccc5oc6ccc(-n7c8ccccc8c8ccc9c%10ccccc%10oc9c87)cc6c45)nc(-c4cccc5sc6ccccc6c45)n3)cc2)cc1] | 1-352 |
| 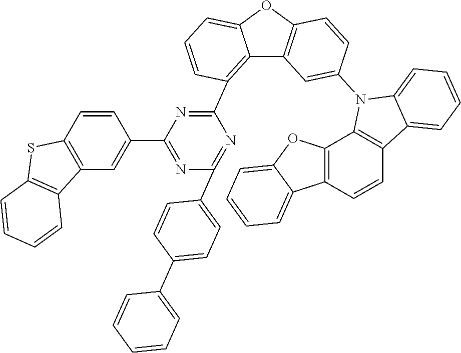 [SMILES: c1ccc(-c2ccc(-c3nc(-c4ccc5sc6ccccc6c5c4)nc(-c4cccc5oc6ccc(-n7c8ccccc8c8ccc9c%10ccccc%10oc9c87)cc6c45)n3)cc2)cc1] | 1-353 |
| 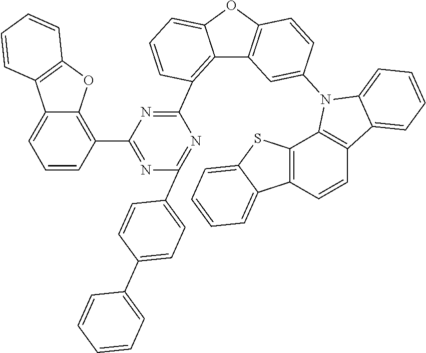 [SMILES: c1ccc(-c2ccc(-c3nc(-c4cccc5c4oc4ccccc45)nc(-c4cccc5oc6ccc(-n7c8ccccc8c8ccc9c%10ccccc%10sc9c87)cc6c45)n3)cc2)cc1] | 1-354 |
| 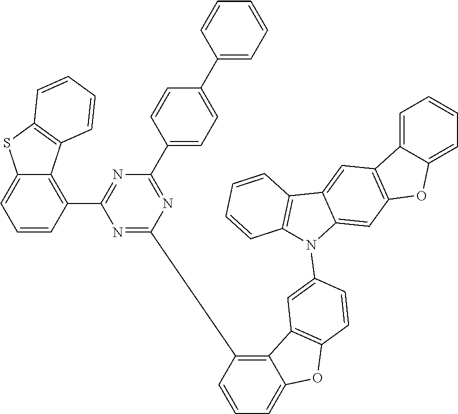 [SMILES: c1ccc(-c2ccc(-c3nc(-c4cccc5oc6ccc(-n7c8ccccc8c8cc9c(cc87)oc7ccccc79)cc6c45)nc(-c4cccc5sc6ccccc6c45)n3)cc2)cc1] | 1-355 |
| 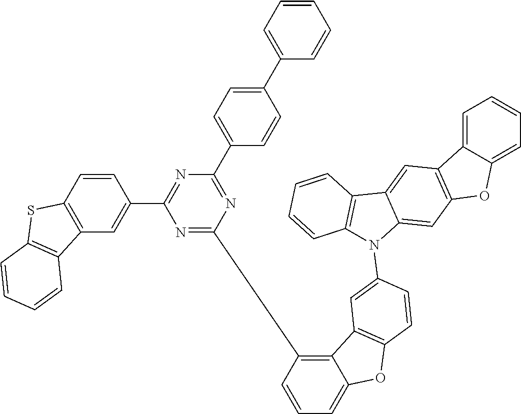 [SMILES: c1ccc(-c2ccc(-c3nc(-c4ccc5sc6ccccc6c5c4)nc(-c4cccc5oc6ccc(-n7c8ccccc8c8cc9c(cc87)oc7ccccc79)cc6c45)n3)cc2)cc1] | 1-356 |
| 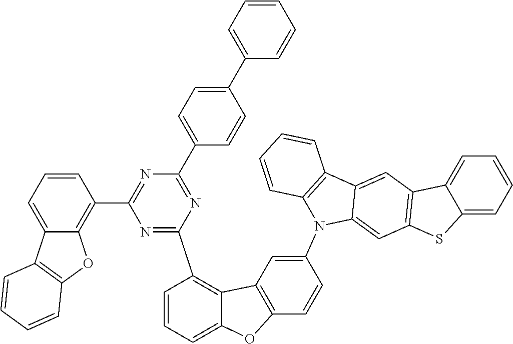 [SMILES: c1ccc(-c2ccc(-c3nc(-c4cccc5c4oc4ccccc45)nc(-c4cccc5oc6ccc(-n7c8ccccc8c8cc9c(cc87)sc7ccccc79)cc6c45)n3)cc2)cc1] | 1-357 |
| 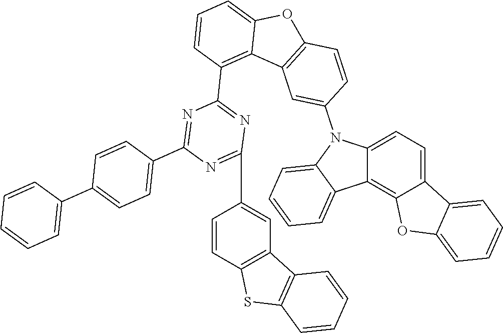 [SMILES: c1ccc(-c2ccc(-c3nc(-c4ccc5sc6ccccc6c5c4)nc(-c4cccc5oc6ccc(-n7c8ccccc8c8c9oc%10ccccc%10c9ccc87)cc6c45)n3)cc2)cc1] | 1-358 |
| 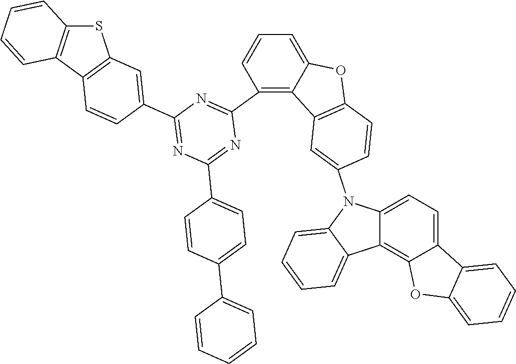 [SMILES: c1ccc(-c2ccc(-c3nc(-c4ccc5c(c4)sc4ccccc45)nc(-c4cccc5oc6ccc(-n7c8ccccc8c8c9oc%10ccccc%10c9ccc87)cc6c45)n3)cc2)cc1] | 1-359 |
| 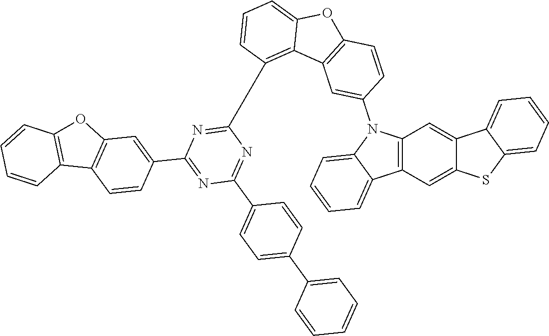 [SMILES: c1ccc(-c2ccc(-c3nc(-c4ccc5c(c4)oc4ccccc45)nc(-c4cccc5oc6ccc(-n7c8ccccc8c8cc9sc%10ccccc%10c9cc87)cc6c45)n3)cc2)cc1] | 1-360 |
| 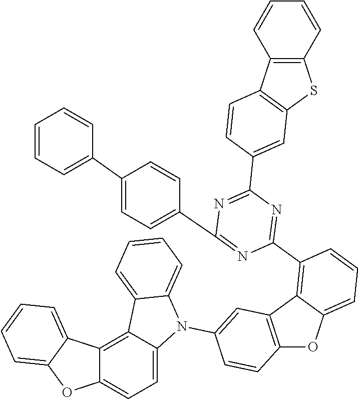 [SMILES: c1ccc(-c2ccc(-c3nc(-c4ccc5c(c4)sc4ccccc45)nc(-c4cccc5oc6ccc(-n7c8ccccc8c8c9c(ccc87)oc7ccccc79)cc6c45)n3)cc2)cc1] | 1-361 |
| 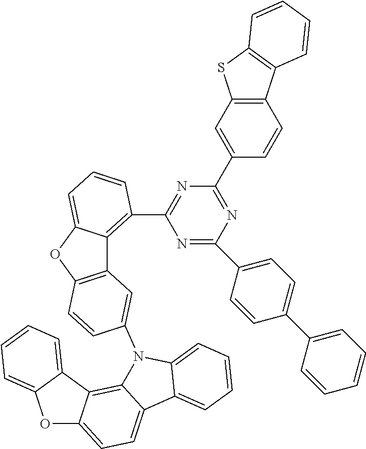 [SMILES: c1ccc(-c2ccc(-c3nc(-c4ccc5c(c4)sc4ccccc45)nc(-c4cccc5oc6ccc(-n7c8ccccc8c8ccc9oc%10ccccc%10c9c87)cc6c45)n3)cc2)cc1] | 1-362 |
| 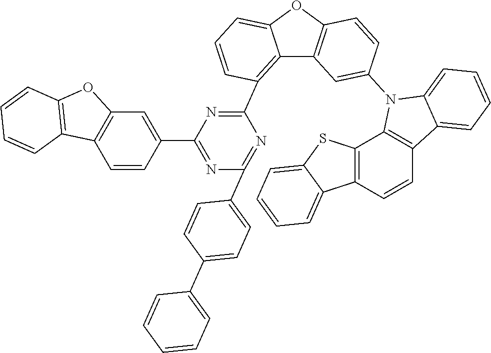 [SMILES: c1ccc(-c2ccc(-c3nc(-c4ccc5c(c4)oc4ccccc45)nc(-c4cccc5oc6ccc(-n7c8ccccc8c8ccc9c%10ccccc%10sc9c87)cc6c45)n3)cc2)cc1] | 1-363 |
| 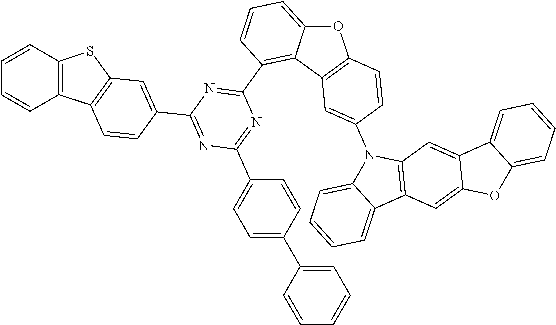 [SMILES: c1ccc(-c2ccc(-c3nc(-c4ccc5c(c4)sc4ccccc45)nc(-c4cccc5oc6ccc(-n7c8ccccc8c8cc9oc%10ccccc%10c9cc87)cc6c45)n3)cc2)cc1] | 1-364 |
| 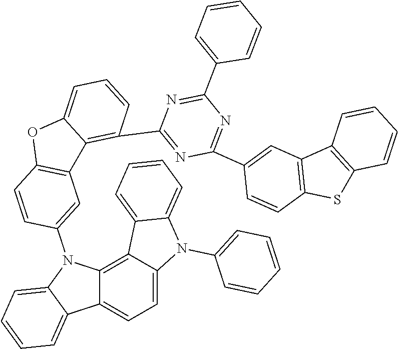 [SMILES: c1ccc(-c2nc(-c3ccc4sc5ccccc5c4c3)nc(-c3cccc4oc5ccc(-n6c7ccccc7c7ccc8c(c9ccccc9n8-c8ccccc8)c76)cc5c34)n2)cc1] | 1-365 |
| 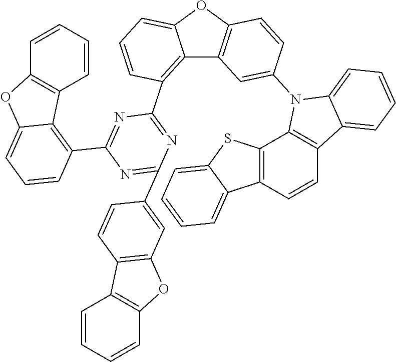 [SMILES: c1ccc2c(c1)oc1cc(-c3nc(-c4cccc5oc6ccccc6c45)nc(-c4cccc5oc6ccc(-n7c8ccccc8c8ccc9c%10ccccc%10sc9c87)cc6c45)n3)ccc12] | 1-366 |
| 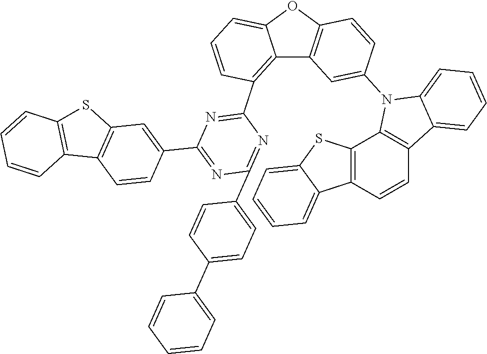 [SMILES: c1ccc(-c2ccc(-c3nc(-c4ccc5c(c4)sc4ccccc45)nc(-c4cccc5oc6ccc(-n7c8ccccc8c8ccc9c%10ccccc%10sc9c87)cc6c45)n3)cc2)cc1] | 1-367 |
| 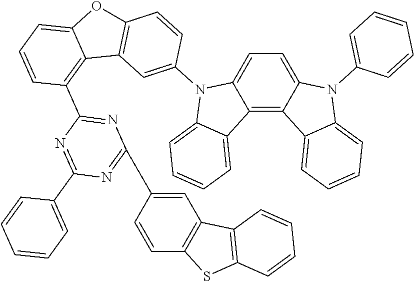 [SMILES: c1ccc(-c2nc(-c3ccc4sc5ccccc5c4c3)nc(-c3cccc4oc5ccc(-n6c7ccccc7c7c8c9ccccc9n(-c9ccccc9)c8ccc76)cc5c34)n2)cc1] | 1-368 |
| 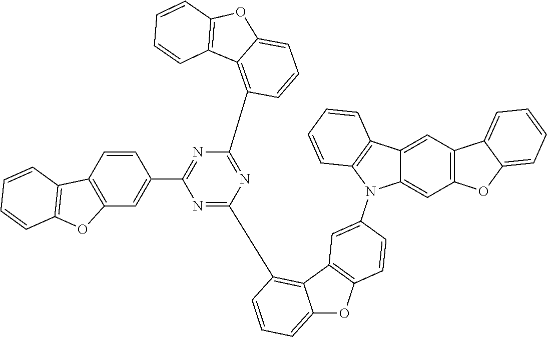 [SMILES: c1ccc2c(c1)oc1cc(-c3nc(-c4cccc5oc6ccccc6c45)nc(-c4cccc5oc6ccc(-n7c8ccccc8c8cc9c(cc87)oc7ccccc79)cc6c45)n3)ccc12] | 1-369 |
| 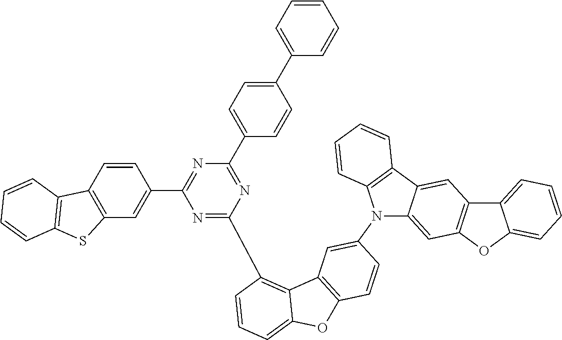 [SMILES: c1ccc(-c2ccc(-c3nc(-c4ccc5c(c4)sc4ccccc45)nc(-c4cccc5oc6ccc(-n7c8ccccc8c8cc9c(cc87)oc7ccccc79)cc6c45)n3)cc2)cc1] | 1-370 |
| 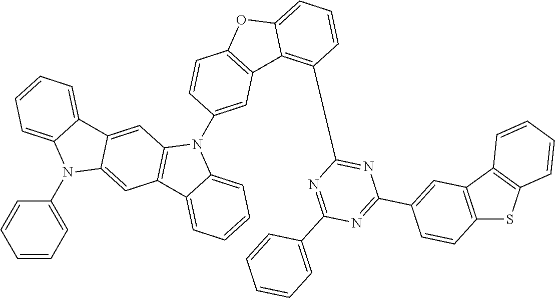 [SMILES: c1ccc(-c2nc(-c3ccc4sc5ccccc5c4c3)nc(-c3cccc4oc5ccc(-n6c7ccccc7c7cc8c(cc76)c6ccccc6n8-c6ccccc6)cc5c34)n2)cc1] | 1-371 |
| 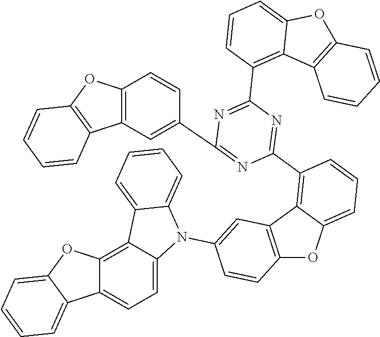 [SMILES: c1ccc2c(c1)oc1ccc(-c3nc(-c4cccc5oc6ccccc6c45)nc(-c4cccc5oc6ccc(-n7c8ccccc8c8c9oc%10ccccc%10c9ccc87)cc6c45)n3)cc12] | 1-372 |
| 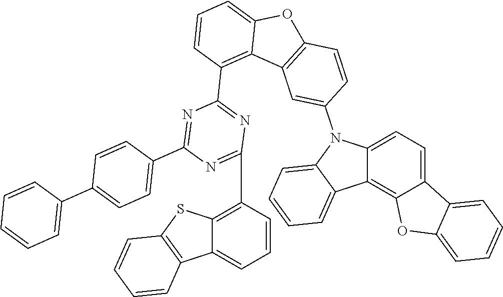 [SMILES: c1ccc(-c2ccc(-c3nc(-c4cccc5c4sc4ccccc45)nc(-c4cccc5oc6ccc(-n7c8ccccc8c8c9oc%10ccccc%10c9ccc87)cc6c45)n3)cc2)cc1] | 1-373 |
| 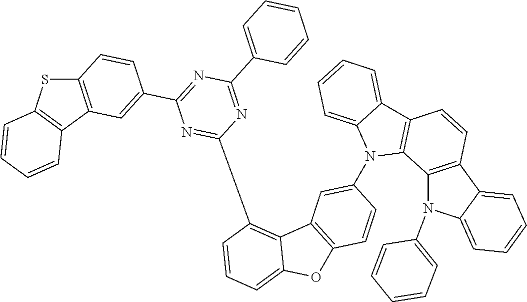 [SMILES: c1ccc(-c2nc(-c3ccc4sc5ccccc5c4c3)nc(-c3cccc4oc5ccc(-n6c7ccccc7c7ccc8c9ccccc9n(-c9ccccc9)c8c76)cc5c34)n2)cc1] | 1-374 |
| 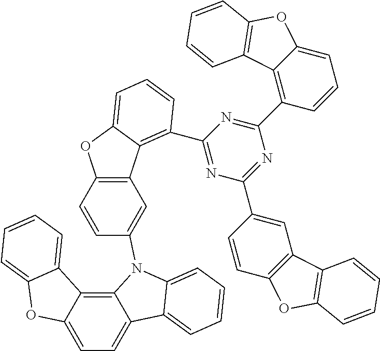 [SMILES: c1ccc2c(c1)oc1ccc(-c3nc(-c4cccc5oc6ccccc6c45)nc(-c4cccc5oc6ccc(-n7c8ccccc8c8ccc9oc%10ccccc%10c9c87)cc6c45)n3)cc12] | 1-375 |
| 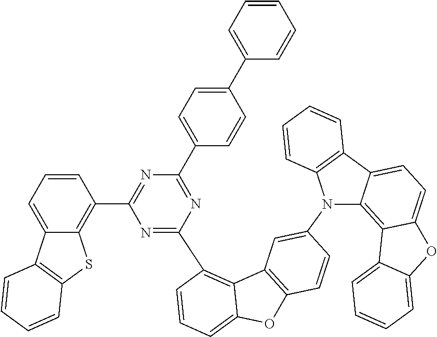 [SMILES: c1ccc(-c2ccc(-c3nc(-c4cccc5c4sc4ccccc45)nc(-c4cccc5oc6ccc(-n7c8ccccc8c8ccc9oc%10ccccc%10c9c87)cc6c45)n3)cc2)cc1] | 1-376 |
| 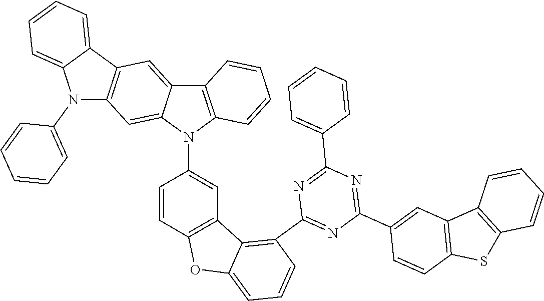 [SMILES: c1ccc(-c2nc(-c3ccc4sc5ccccc5c4c3)nc(-c3cccc4oc5ccc(-n6c7ccccc7c7cc8c9ccccc9n(-c9ccccc9)c8cc76)cc5c34)n2)cc1] | 1-377 |
| 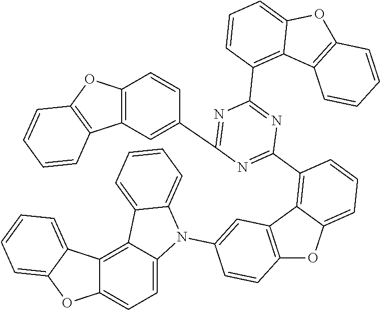 [SMILES: c1ccc2c(c1)oc1ccc(-c3nc(-c4cccc5oc6ccccc6c45)nc(-c4cccc5oc6ccc(-n7c8ccccc8c8c9c(ccc87)oc7ccccc79)cc6c45)n3)cc12] | 1-378 |
| 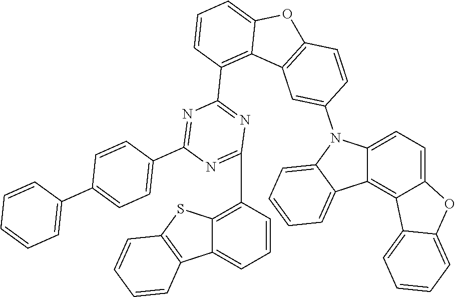 [SMILES: c1ccc(-c2ccc(-c3nc(-c4cccc5c4sc4ccccc45)nc(-c4cccc5oc6ccc(-n7c8ccccc8c8c9c(ccc87)oc7ccccc79)cc6c45)n3)cc2)cc1] | 1-379 |
| 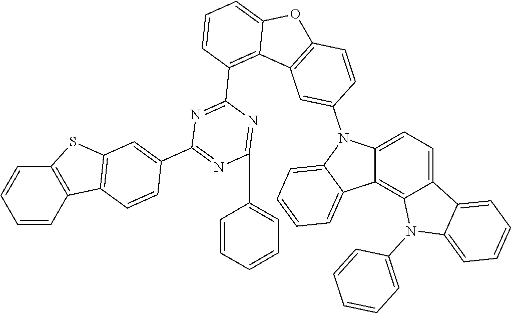 [SMILES: c1ccc(-c2nc(-c3ccc4c(c3)sc3ccccc34)nc(-c3cccc4oc5ccc(-n6c7ccccc7c7c6ccc6c8ccccc8n(-c8ccccc8)c67)cc5c34)n2)cc1] | 1-380 |
| 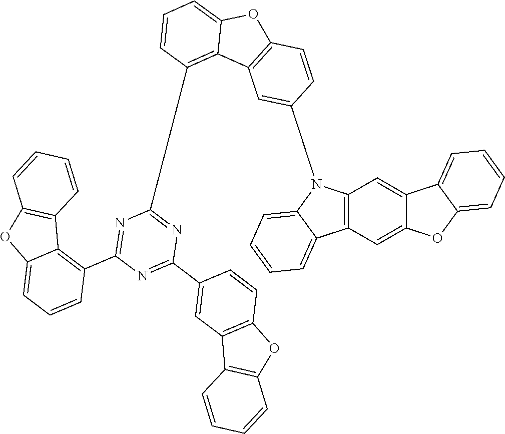 [SMILES: c1ccc2c(c1)oc1ccc(-c3nc(-c4cccc5oc6ccccc6c45)nc(-c4cccc5oc6ccc(-n7c8ccccc8c8cc9oc%10ccccc%10c9cc87)cc6c45)n3)cc12] | 1-381 |
| 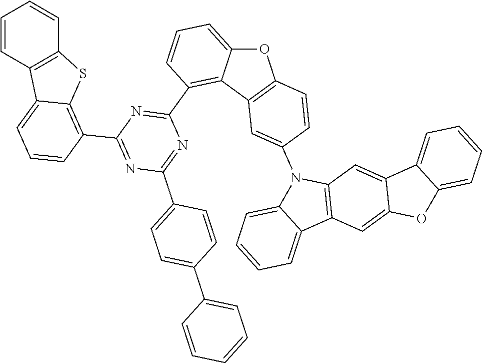 [SMILES: c1ccc(-c2ccc(-c3nc(-c4cccc5c4sc4ccccc45)nc(-c4cccc5oc6ccc(-n7c8ccccc8c8cc9oc%10ccccc%10c9cc87)cc6c45)n3)cc2)cc1] | 1-382 |
| 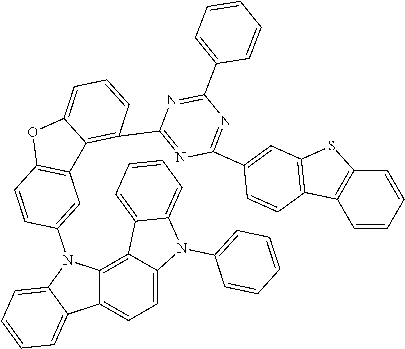 [SMILES: c1ccc(-c2nc(-c3ccc4c(c3)sc3ccccc34)nc(-c3cccc4oc5ccc(-n6c7ccccc7c7ccc8c(c9ccccc9n8-c8ccccc8)c76)cc5c34)n2)cc1] | 1-383 |
| 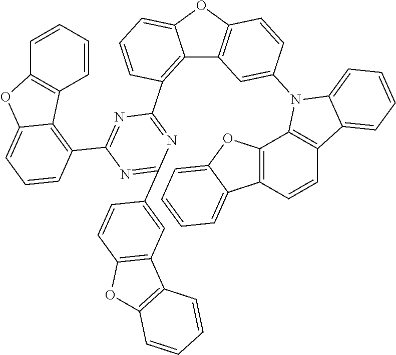 [SMILES: c1ccc2c(c1)oc1ccc(-c3nc(-c4cccc5oc6ccccc6c45)nc(-c4cccc5oc6ccc(-n7c8ccccc8c8ccc9c%10ccccc%10oc9c87)cc6c45)n3)cc12] | 1-384 |
| 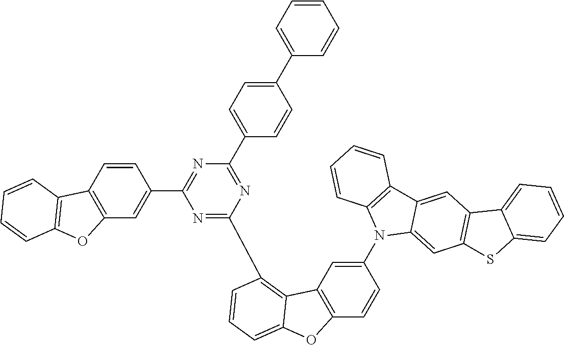 [SMILES: c1ccc(-c2ccc(-c3nc(-c4ccc5c(c4)oc4ccccc45)nc(-c4cccc5oc6ccc(-n7c8ccccc8c8cc9c(cc87)sc7ccccc79)cc6c45)n3)cc2)cc1] | 1-385 |
| 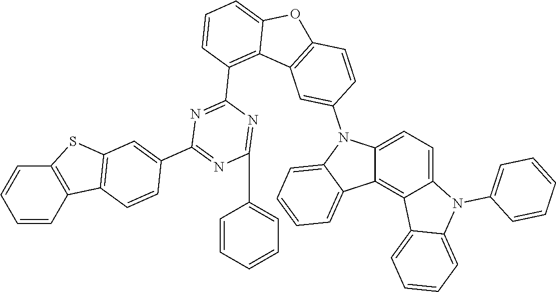 [SMILES: c1ccc(-c2nc(-c3ccc4c(c3)sc3ccccc34)nc(-c3cccc4oc5ccc(-n6c7ccccc7c7c8c9ccccc9n(-c9ccccc9)c8ccc76)cc5c34)n2)cc1] | 1-386 |
| 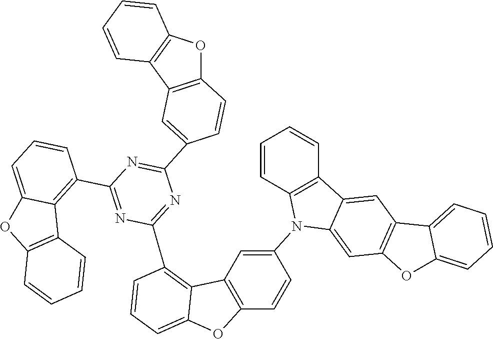 [SMILES: c1ccc2c(c1)oc1ccc(-c3nc(-c4cccc5oc6ccccc6c45)nc(-c4cccc5oc6ccc(-n7c8ccccc8c8cc9c(cc87)oc7ccccc79)cc6c45)n3)cc12] | 1-387 |
| 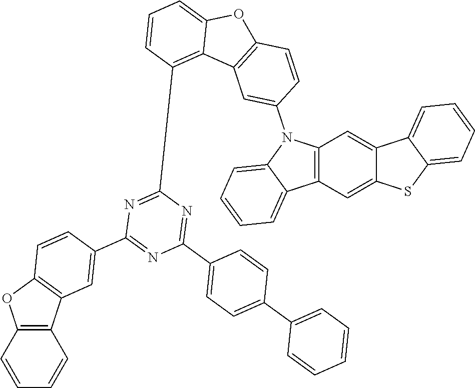 [SMILES: c1ccc(-c2ccc(-c3nc(-c4ccc5oc6ccccc6c5c4)nc(-c4cccc5oc6ccc(-n7c8ccccc8c8cc9sc%10ccccc%10c9cc87)cc6c45)n3)cc2)cc1] | 1-388 |
| 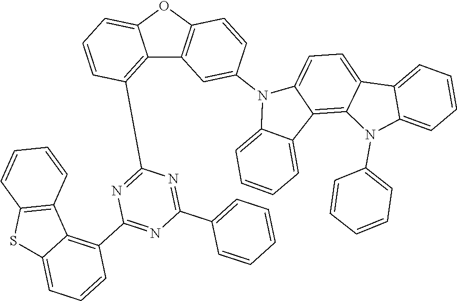 [SMILES: c1ccc(-c2nc(-c3cccc4oc5ccc(-n6c7ccccc7c7c6ccc6c8ccccc8n(-c8ccccc8)c67)cc5c34)nc(-c3cccc4sc5ccccc5c34)n2)cc1] | 1-389 |
| 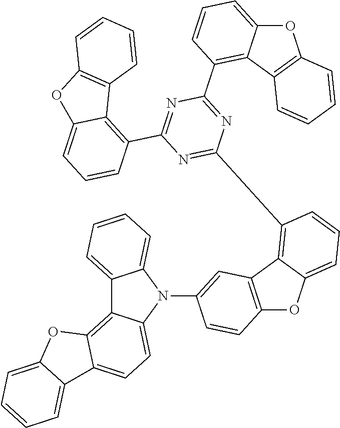 [SMILES: c1ccc2c(c1)oc1c2ccc2c1c1ccccc1n2-c1ccc2oc3cccc(-c4nc(-c5cccc6oc7ccccc7c56)nc(-c5cccc6oc7ccccc7c56)n4)c3c2c1] | 1-390 |
| 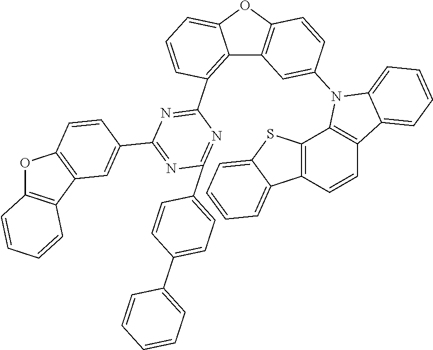 [SMILES: c1ccc(-c2ccc(-c3nc(-c4ccc5oc6ccccc6c5c4)nc(-c4cccc5oc6ccc(-n7c8ccccc8c8ccc9c%10ccccc%10sc9c87)cc6c45)n3)cc2)cc1] | 1-391 |
| 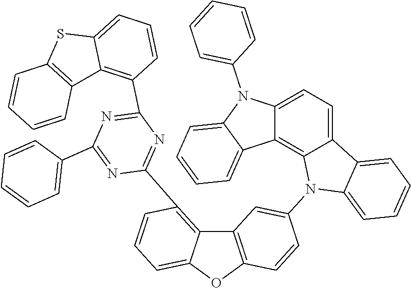 [SMILES: c1ccc(-c2nc(-c3cccc4oc5ccc(-n6c7ccccc7c7ccc8c(c9ccccc9n8-c8ccccc8)c76)cc5c34)nc(-c3cccc4sc5ccccc5c34)n2)cc1] | 1-392 |
| 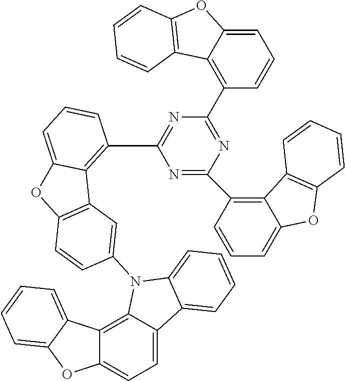 [SMILES: c1ccc2c(c1)oc1cccc(-c3nc(-c4cccc5oc6ccccc6c45)nc(-c4cccc5oc6ccc(-n7c8ccccc8c8ccc9oc%10ccccc%10c9c87)cc6c45)n3)c12] | 1-393 |
| 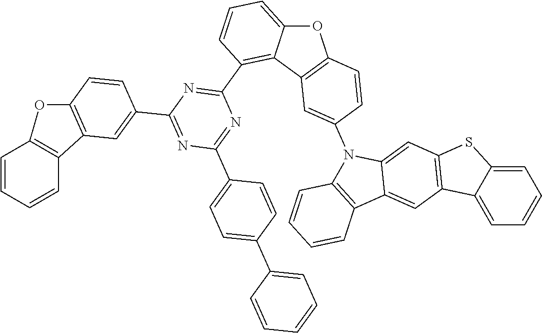 [SMILES: c1ccc(-c2ccc(-c3nc(-c4ccc5oc6ccccc6c5c4)nc(-c4cccc5oc6ccc(-n7c8ccccc8c8cc9c(cc87)sc7ccccc79)cc6c45)n3)cc2)cc1] | 1-394 |
| 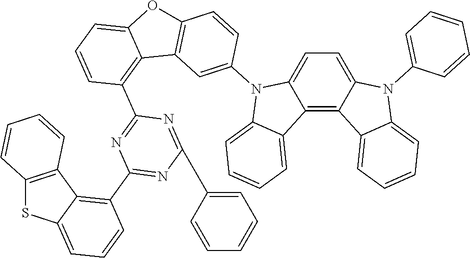 [SMILES: c1ccc(-c2nc(-c3cccc4oc5ccc(-n6c7ccccc7c7c8c9ccccc9n(-c9ccccc9)c8ccc76)cc5c34)nc(-c3cccc4sc5ccccc5c34)n2)cc1] | 1-395 |
| 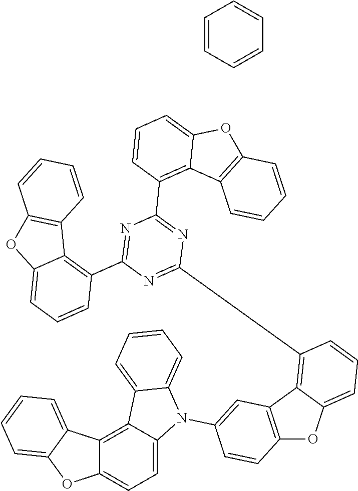 [SMILES: c1ccccc1 ; c1ccc2c(c1)oc1cccc(-c3nc(-c4cccc5oc6ccccc6c45)nc(-c4cccc5oc6ccc(-n7c8ccccc8c8c9c(ccc87)oc7ccccc79)cc6c45)n3)c12] | 1-396 |
| 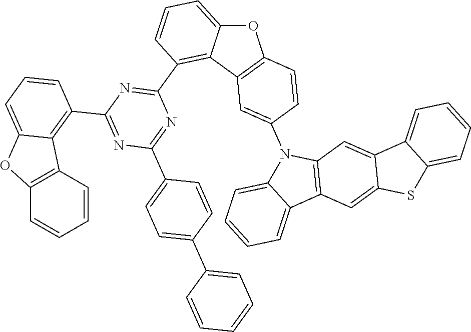 [SMILES: c1ccc(-c2ccc(-c3nc(-c4cccc5oc6ccccc6c45)nc(-c4cccc5oc6ccc(-n7c8ccccc8c8cc9sc%10ccccc%10c9cc87)cc6c45)n3)cc2)cc1] | 1-397 |
| 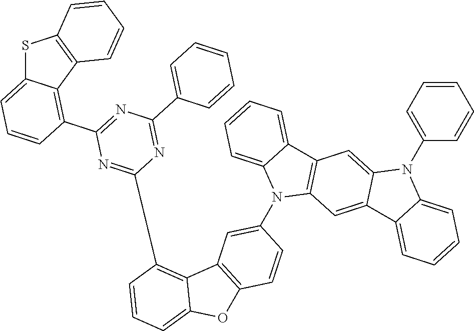 [SMILES: c1ccc(-c2nc(-c3cccc4oc5ccc(-n6c7ccccc7c7cc8c(cc76)c6ccccc6n8-c6ccccc6)cc5c34)nc(-c3cccc4sc5ccccc5c34)n2)cc1] | 1-398 |
| 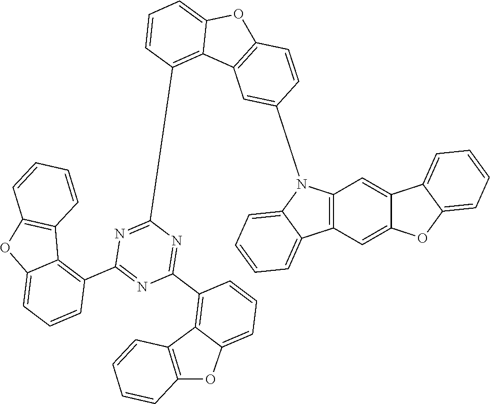 [SMILES: c1ccc2c(c1)oc1cc3c4ccccc4n(-c4ccc5oc6cccc(-c7nc(-c8cccc9oc%10ccccc%10c89)nc(-c8cccc9oc%10ccccc%10c89)n7)c6c5c4)c3cc12] | 1-399 |
| 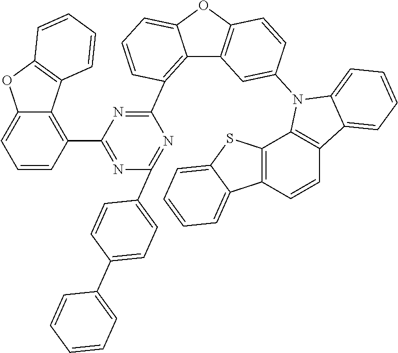 [SMILES: c1ccc(-c2ccc(-c3nc(-c4cccc5oc6ccccc6c45)nc(-c4cccc5oc6ccc(-n7c8ccccc8c8ccc9c%10ccccc%10sc9c87)cc6c45)n3)cc2)cc1] | 1-400 |
| 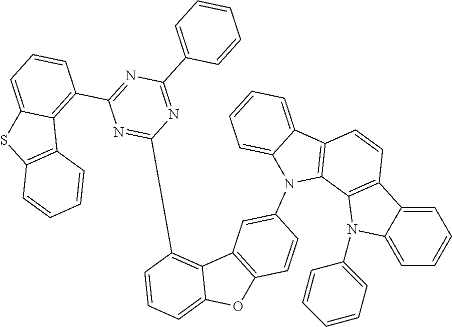 [SMILES: c1ccc(-c2nc(-c3cccc4oc5ccc(-n6c7ccccc7c7ccc8c9ccccc9n(-c9ccccc9)c8c76)cc5c34)nc(-c3cccc4sc5ccccc5c34)n2)cc1] | 1-401 |
| 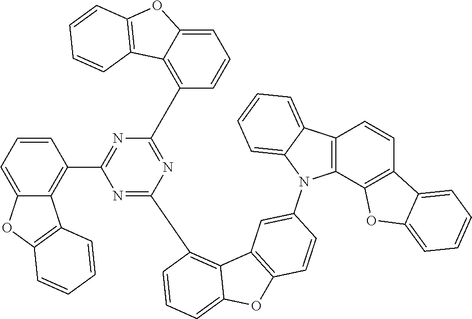 [SMILES: c1ccc2c(c1)oc1c2ccc2c3ccccc3n(-c3ccc4oc5cccc(-c6nc(-c7cccc8oc9ccccc9c78)nc(-c7cccc8oc9ccccc9c78)n6)c5c4c3)c21] | 1-402 |
| 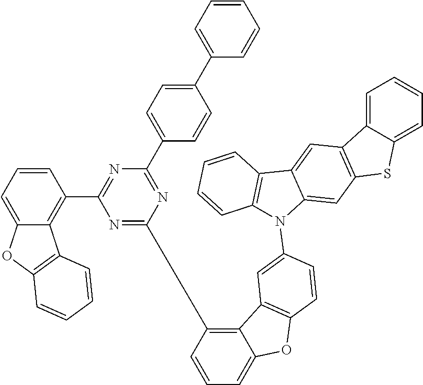 [SMILES: c1ccc(-c2ccc(-c3nc(-c4cccc5oc6ccccc6c45)nc(-c4cccc5oc6ccc(-n7c8ccccc8c8cc9c(cc87)sc7ccccc79)cc6c45)n3)cc2)cc1] | 1-403 |
| 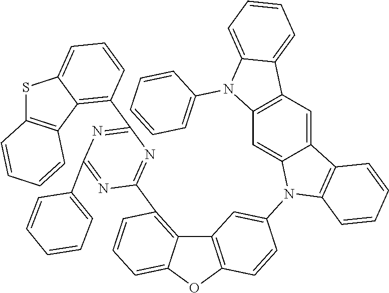 [SMILES: c1ccc(-c2nc(-c3cccc4oc5ccc(-n6c7ccccc7c7cc8c9ccccc9n(-c9ccccc9)c8cc76)cc5c34)nc(-c3cccc4sc5ccccc5c34)n2)cc1] | 1-404 |
| 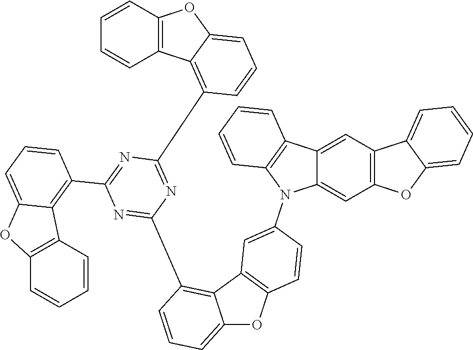 [SMILES: c1ccc2c(c1)oc1cc3c(cc12)c1ccccc1n3-c1ccc2oc3cccc(-c4nc(-c5cccc6oc7ccccc7c56)nc(-c5cccc6oc7ccccc7c56)n4)c3c2c1] | 1-405 |
| 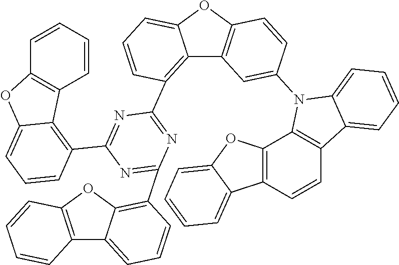 [SMILES: c1ccc2c(c1)oc1c(-c3nc(-c4cccc5oc6ccccc6c45)nc(-c4cccc5oc6ccc(-n7c8ccccc8c8ccc9c%10ccccc%10oc9c87)cc6c45)n3)cccc12] | 1-406 |
| 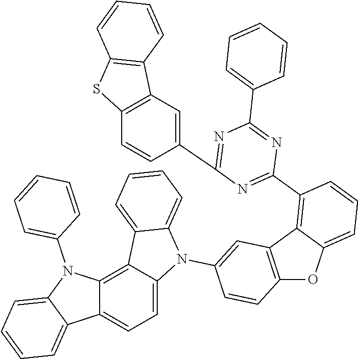 [SMILES: c1ccc(-c2nc(-c3ccc4sc5ccccc5c4c3)nc(-c3cccc4oc5ccc(-n6c7ccccc7c7c6ccc6c8ccccc8n(-c8ccccc8)c67)cc5c34)n2)cc1] | 1-407 |
| 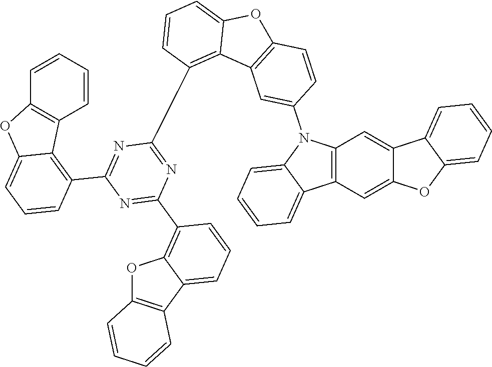 [SMILES: c1ccc2c(c1)oc1cc3c4ccccc4n(-c4ccc5oc6cccc(-c7nc(-c8cccc9c8oc8ccccc89)nc(-c8cccc9oc%10ccccc%10c89)n7)c6c5c4)c3cc12] | 1-408 |
| 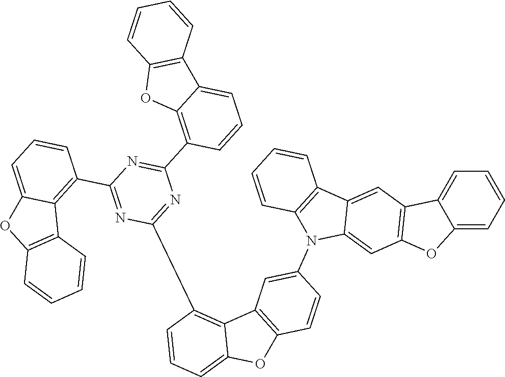 [SMILES: c1ccc2c(c1)oc1cc3c(cc12)c1ccccc1n3-c1ccc2oc3cccc(-c4nc(-c5cccc6c5oc5ccccc56)nc(-c5cccc6oc7ccccc7c56)n4)c3c2c1] | 1-409 |
| 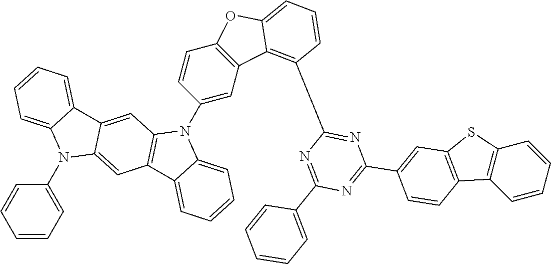 [SMILES: c1ccc(-c2nc(-c3ccc4c(c3)sc3ccccc34)nc(-c3cccc4oc5ccc(-n6c7ccccc7c7cc8c(cc76)c6ccccc6n8-c6ccccc6)cc5c34)n2)cc1] | 1-410 |
| 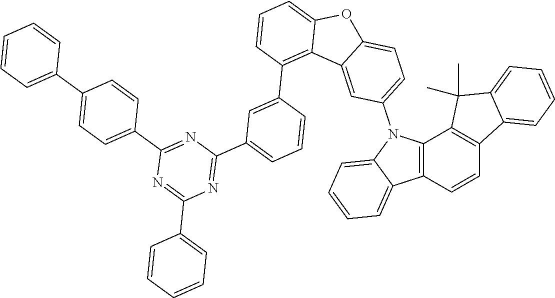 [SMILES: CC1(C)c2ccccc2-c2ccc3c4ccccc4n(-c4ccc5oc6cccc(-c7cccc(-c8nc(-c9ccccc9)nc(-c9ccc(-c%10ccccc%10)cc9)n8)c7)c6c5c4)c3c21] | 1-411 |
| 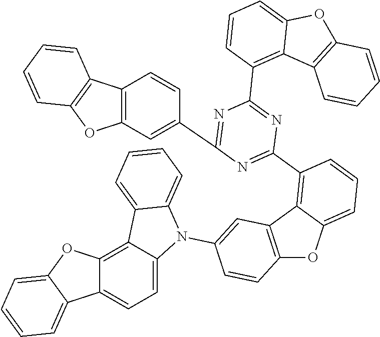 [SMILES: c1ccc2c(c1)oc1cc(-c3nc(-c4cccc5oc6ccccc6c45)nc(-c4cccc5oc6ccc(-n7c8ccccc8c8c9oc%10ccccc%10c9ccc87)cc6c45)n3)ccc12] | 1-412 |
| 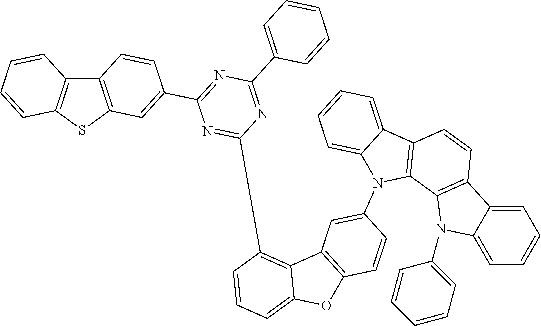 [SMILES: c1ccc(-c2nc(-c3ccc4c(c3)sc3ccccc34)nc(-c3cccc4oc5ccc(-n6c7ccccc7c7ccc8c9ccccc9n(-c9ccccc9)c8c76)cc5c34)n2)cc1] | 1-413 |
| 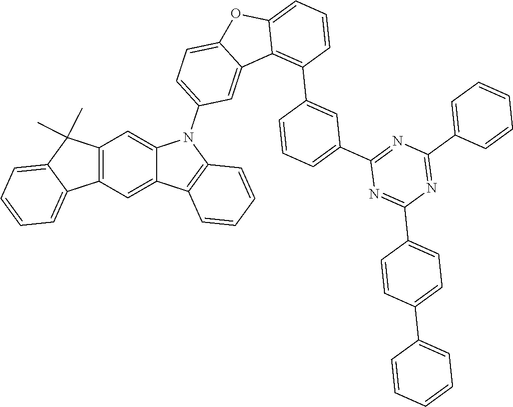 [SMILES: CC1(C)c2ccccc2-c2cc3c4ccccc4n(-c4ccc5oc6cccc(-c7cccc(-c8nc(-c9ccccc9)nc(-c9ccc(-c%10ccccc%10)cc9)n8)c7)c6c5c4)c3cc21] | 1-414 |
| 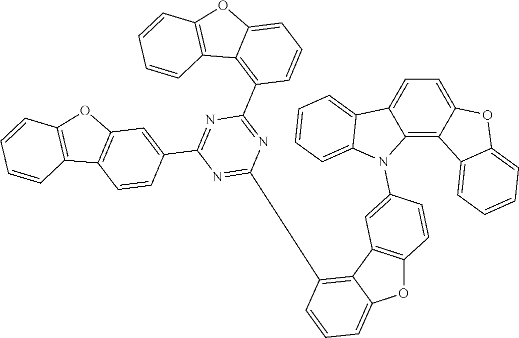 [SMILES: c1ccc2c(c1)oc1cc(-c3nc(-c4cccc5oc6ccccc6c45)nc(-c4cccc5oc6ccc(-n7c8ccccc8c8ccc9oc%10ccccc%10c9c87)cc6c45)n3)ccc12] | 1-415 |
| 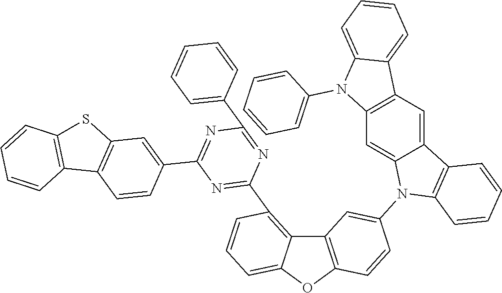 [SMILES: c1ccc(-c2nc(-c3ccc4c(c3)sc3ccccc34)nc(-c3cccc4oc5ccc(-n6c7ccccc7c7cc8c9ccccc9n(-c9ccccc9)c8cc76)cc5c34)n2)cc1] | 1-416 |
| 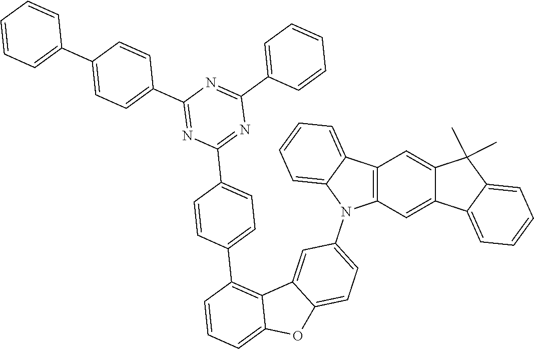 [SMILES: CC1(C)c2ccccc2-c2cc3c(cc21)c1ccccc1n3-c1ccc2oc3cccc(-c4ccc(-c5nc(-c6ccccc6)nc(-c6ccc(-c7ccccc7)cc6)n5)cc4)c3c2c1] | 1-417 |
| 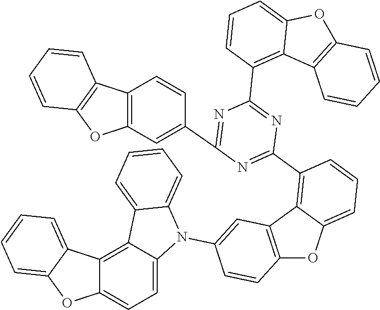 [SMILES: c1ccc2c(c1)oc1cc(-c3nc(-c4cccc5oc6ccccc6c45)nc(-c4cccc5oc6ccc(-n7c8ccccc8c8c9c(ccc87)oc7ccccc79)cc6c45)n3)ccc12] | 1-418 |
| 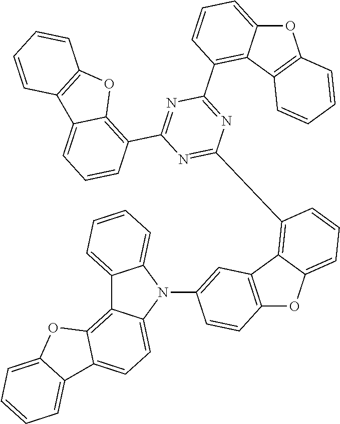 [SMILES: c1ccc2c(c1)oc1c(-c3nc(-c4cccc5oc6ccccc6c45)nc(-c4cccc5oc6ccc(-n7c8ccccc8c8c9oc%10ccccc%10c9ccc87)cc6c45)n3)cccc12] | 1-419 |
| 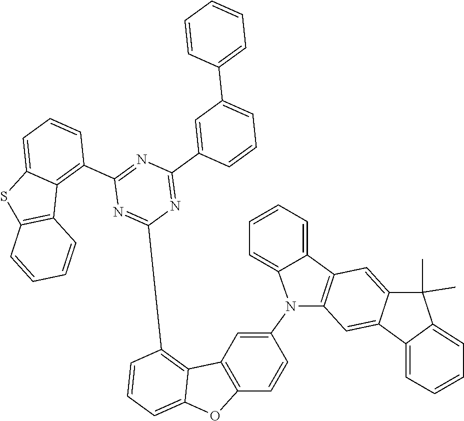 [SMILES: CC1(C)c2ccccc2-c2cc3c(cc21)c1ccccc1n3-c1ccc2oc3cccc(-c4nc(-c5cccc(-c6ccccc6)c5)nc(-c5cccc6sc7ccccc7c56)n4)c3c2c1] | 1-420 |
| 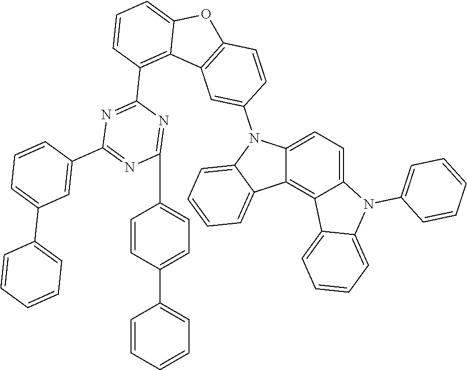 [SMILES: c1ccc(-c2ccc(-c3nc(-c4cccc(-c5ccccc5)c4)nc(-c4cccc5oc6ccc(-n7c8ccccc8c8c9c%10ccccc%10n(-c%10ccccc%10)c9ccc87)cc6c45)n3)cc2)cc1] | 1-421 |
| 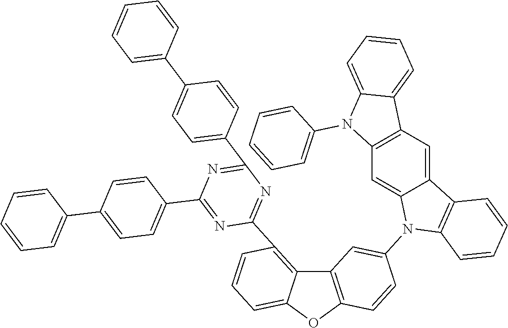 [SMILES: c1ccc(-c2ccc(-c3nc(-c4ccc(-c5ccccc5)cc4)nc(-c4cccc5oc6ccc(-n7c8ccccc8c8cc9c%10ccccc%10n(-c%10ccccc%10)c9cc87)cc6c45)n3)cc2)cc1] | 1-422 |
| 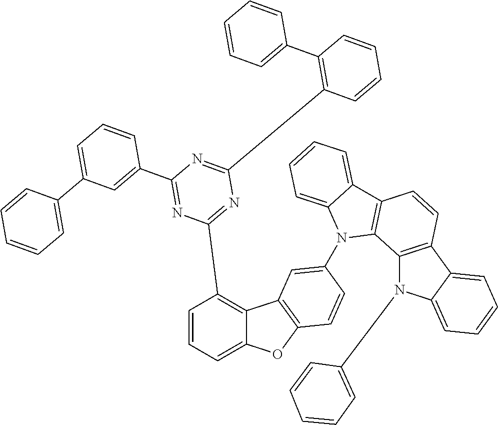 [SMILES: c1ccc(-c2cccc(-c3nc(-c4ccccc4-c4ccccc4)nc(-c4cccc5oc6ccc(-n7c8ccccc8c8ccc9c%10ccccc%10n(-c%10ccccc%10)c9c87)cc6c45)n3)c2)cc1] | 1-423 |
| 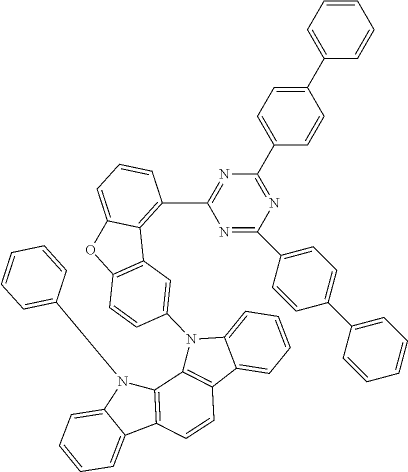 [SMILES: c1ccc(-c2ccc(-c3nc(-c4ccc(-c5ccccc5)cc4)nc(-c4cccc5oc6ccc(-n7c8ccccc8c8ccc9c%10ccccc%10n(-c%10ccccc%10)c9c87)cc6c45)n3)cc2)cc1] | 1-424 |
| 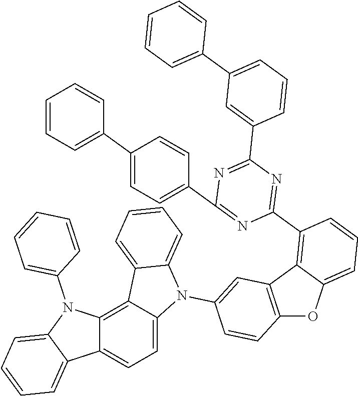 [SMILES: c1ccc(-c2ccc(-c3nc(-c4cccc(-c5ccccc5)c4)nc(-c4cccc5oc6ccc(-n7c8ccccc8c8c7ccc7c9ccccc9n(-c9ccccc9)c78)cc6c45)n3)cc2)cc1] | 1-425 |
| 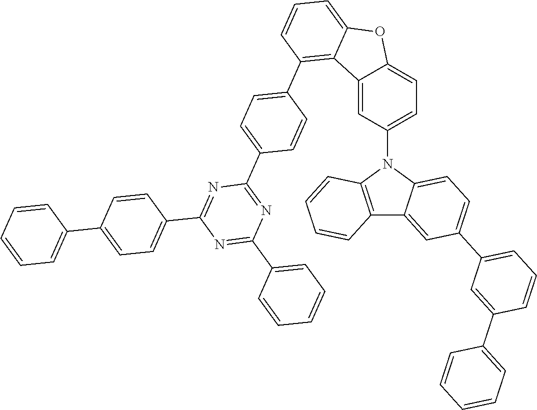 [SMILES: c1ccc(-c2ccc(-c3nc(-c4ccccc4)nc(-c4ccc(-c5cccc6oc7ccc(-n8c9ccccc9c9cc(-c%10cccc(-c%11ccccc%11)c%10)ccc98)cc7c56)cc4)n3)cc2)cc1] | 1-426 |
| 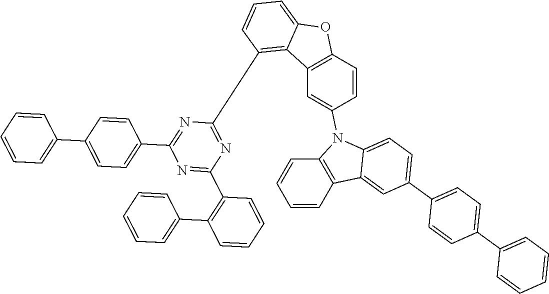 [SMILES: c1ccc(-c2ccc(-c3ccc4c(c3)c3ccccc3n4-c3ccc4oc5cccc(-c6nc(-c7ccc(-c8ccccc8)cc7)nc(-c7ccccc7-c7ccccc7)n6)c5c4c3)cc2)cc1] | 1-427 |
| 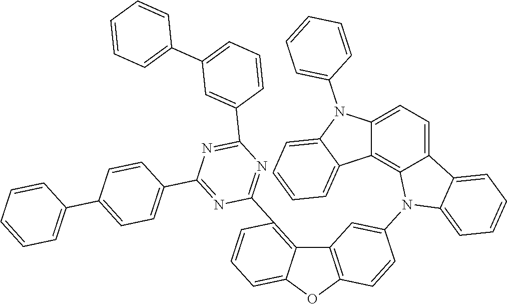 [SMILES: c1ccc(-c2ccc(-c3nc(-c4cccc(-c5ccccc5)c4)nc(-c4cccc5oc6ccc(-n7c8ccccc8c8ccc9c(c%10ccccc%10n9-c9ccccc9)c87)cc6c45)n3)cc2)cc1] | 1-428 |
| 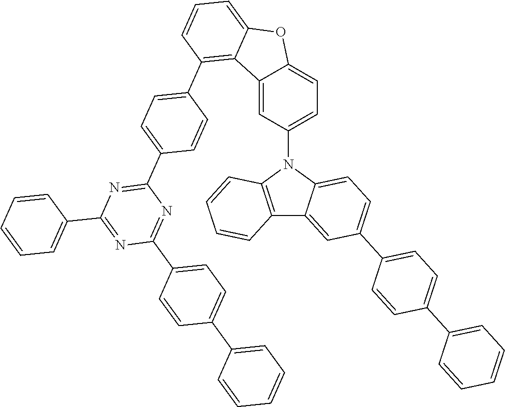 [SMILES: c1ccc(-c2ccc(-c3ccc4c(c3)c3ccccc3n4-c3ccc4oc5cccc(-c6ccc(-c7nc(-c8ccccc8)nc(-c8ccc(-c9ccccc9)cc8)n7)cc6)c5c4c3)cc2)cc1] | 1-429 |
| 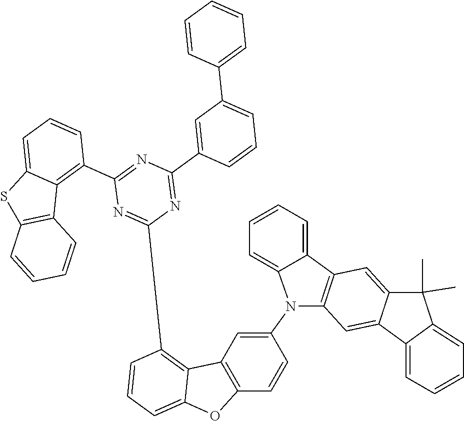 [SMILES: CC1(C)c2ccccc2-c2cc3c(cc21)c1ccccc1n3-c1ccc2oc3cccc(-c4nc(-c5cccc(-c6ccccc6)c5)nc(-c5cccc6sc7ccccc7c56)n4)c3c2c1] | 1-430 |
| 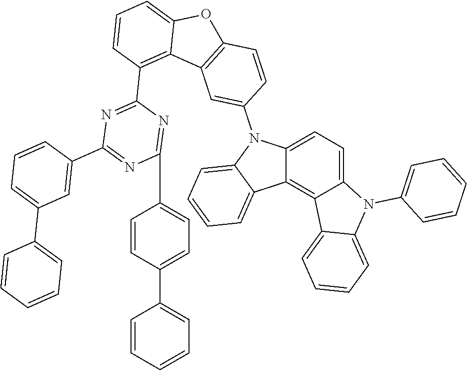 [SMILES: c1ccc(-c2ccc(-c3nc(-c4cccc(-c5ccccc5)c4)nc(-c4cccc5oc6ccc(-n7c8ccccc8c8c9c%10ccccc%10n(-c%10ccccc%10)c9ccc87)cc6c45)n3)cc2)cc1] | 1-431 |
| 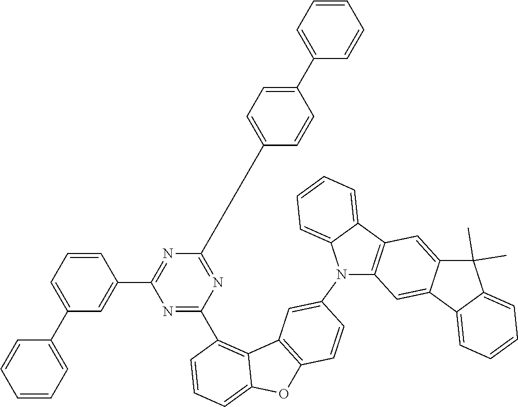 [SMILES: CC1(C)c2ccccc2-c2cc3c(cc21)c1ccccc1n3-c1ccc2oc3cccc(-c4nc(-c5ccc(-c6ccccc6)cc5)nc(-c5cccc(-c6ccccc6)c5)n4)c3c2c1] | 1-432 |
| 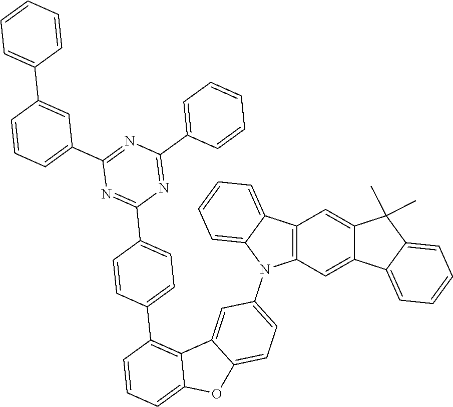 [SMILES: CC1(C)c2ccccc2-c2cc3c(cc21)c1ccccc1n3-c1ccc2oc3cccc(-c4ccc(-c5nc(-c6ccccc6)nc(-c6cccc(-c7ccccc7)c6)n5)cc4)c3c2c1] | 1-433 |
| 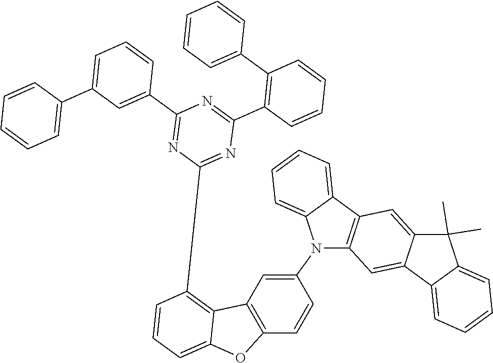 [SMILES: CC1(C)c2ccccc2-c2cc3c(cc21)c1ccccc1n3-c1ccc2oc3cccc(-c4nc(-c5cccc(-c6ccccc6)c5)nc(-c5ccccc5-c5ccccc5)n4)c3c2c1] | 1-434 |
| 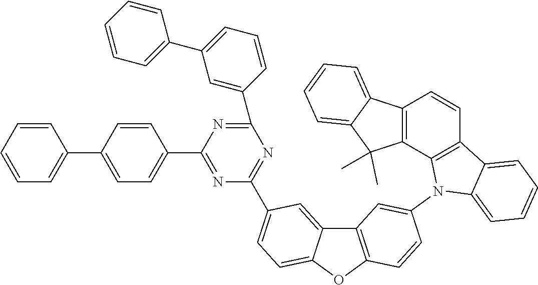 [SMILES: CC1(C)c2ccccc2-c2ccc3c4ccccc4n(-c4ccc5oc6ccc(-c7nc(-c8ccc(-c9ccccc9)cc8)nc(-c8cccc(-c9ccccc9)c8)n7)cc6c5c4)c3c21] | 1-435 |
| 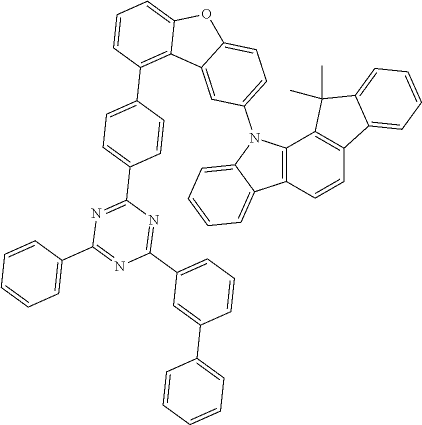 [SMILES: CC1(C)c2ccccc2-c2ccc3c4ccccc4n(-c4ccc5oc6cccc(-c7ccc(-c8nc(-c9ccccc9)nc(-c9cccc(-c%10ccccc%10)c9)n8)cc7)c6c5c4)c3c21] | 1-436 |
| 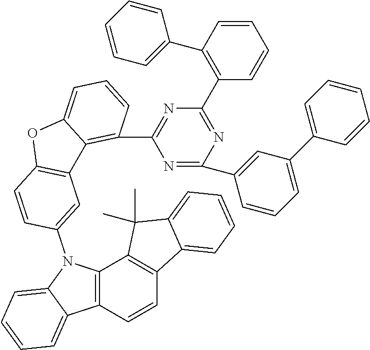 [SMILES: CC1(C)c2ccccc2-c2ccc3c4ccccc4n(-c4ccc5oc6cccc(-c7nc(-c8cccc(-c9ccccc9)c8)nc(-c8ccccc8-c8ccccc8)n7)c6c5c4)c3c21] | 1-437 |
| 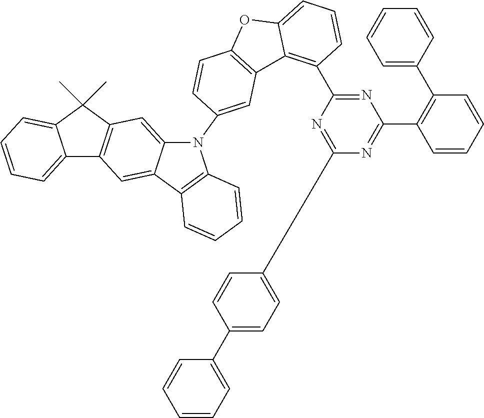 [SMILES: CC1(C)c2ccccc2-c2cc3c4ccccc4n(-c4ccc5oc6cccc(-c7nc(-c8ccc(-c9ccccc9)cc8)nc(-c8ccccc8-c8ccccc8)n7)c6c5c4)c3cc21] | 1-438 |
| 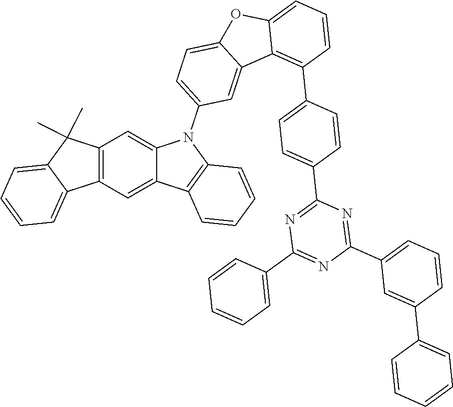 [SMILES: CC1(C)c2ccccc2-c2cc3c4ccccc4n(-c4ccc5oc6cccc(-c7ccc(-c8nc(-c9ccccc9)nc(-c9cccc(-c%10ccccc%10)c9)n8)cc7)c6c5c4)c3cc21] | 1-439 |
| 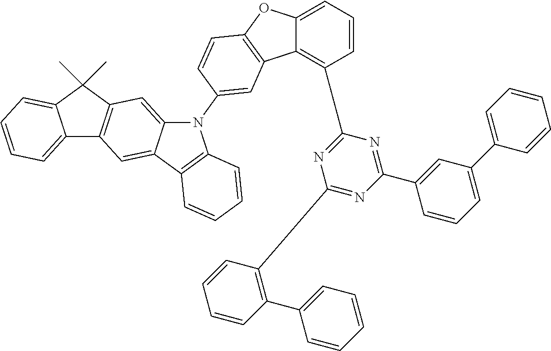 [SMILES: CC1(C)c2ccccc2-c2cc3c4ccccc4n(-c4ccc5oc6cccc(-c7nc(-c8cccc(-c9ccccc9)c8)nc(-c8ccccc8-c8ccccc8)n7)c6c5c4)c3cc21] | 1-440 |
| 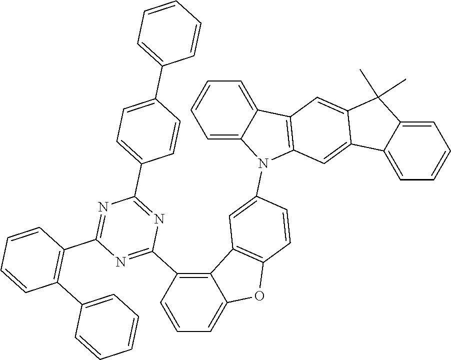 [SMILES: CC1(C)c2ccccc2-c2cc3c(cc21)c1ccccc1n3-c1ccc2oc3cccc(-c4nc(-c5ccc(-c6ccccc6)cc5)nc(-c5ccccc5-c5ccccc5)n4)c3c2c1] | 1-441 |
| 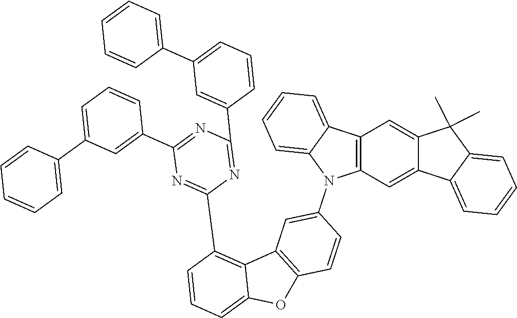 | 1-442 |
| 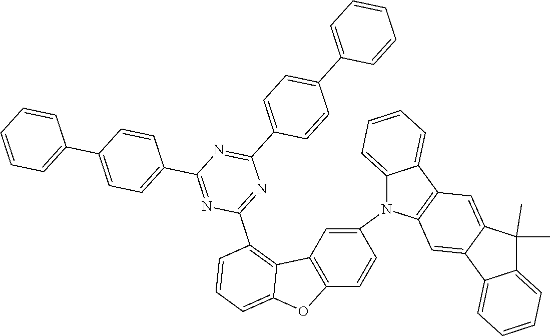 [SMILES: CC1(C)c2ccccc2-c2cc3c(cc21)c1ccccc1n3-c1ccc2oc3cccc(-c4nc(-c5ccc(-c6ccccc6)cc5)nc(-c5ccc(-c6ccccc6)cc5)n4)c3c2c1] | 1-443 |
| 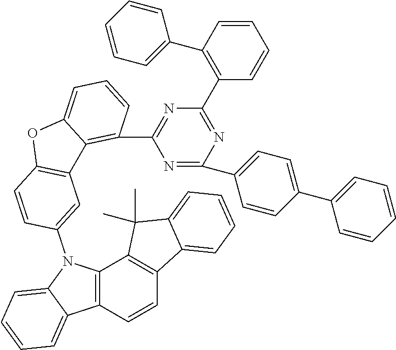 [SMILES: CC1(C)c2ccccc2-c2ccc3c4ccccc4n(-c4ccc5oc6cccc(-c7nc(-c8ccc(-c9ccccc9)cc8)nc(-c8ccccc8-c8ccccc8)n7)c6c5c4)c3c21] | 1-444 |
| 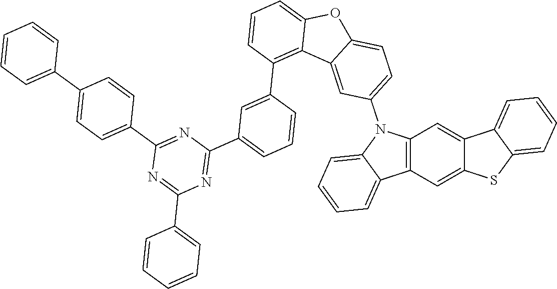 [SMILES: c1ccc(-c2ccc(-c3nc(-c4ccccc4)nc(-c4cccc(-c5cccc6oc7ccc(-n8c9ccccc9c9cc%10sc%11ccccc%11c%10cc98)cc7c56)c4)n3)cc2)cc1] | 1-445 |
| 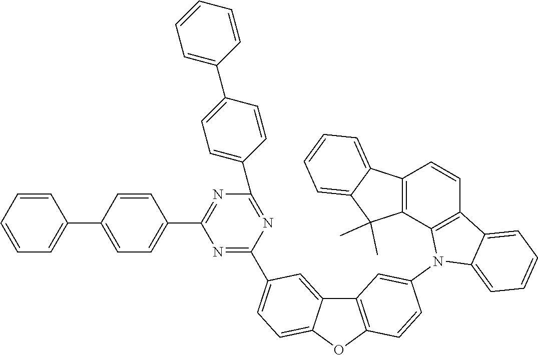 [SMILES: CC1(C)c2ccccc2-c2ccc3c4ccccc4n(-c4ccc5oc6ccc(-c7nc(-c8ccc(-c9ccccc9)cc8)nc(-c8ccc(-c9ccccc9)cc8)n7)cc6c5c4)c3c21] | 1-446 |
| 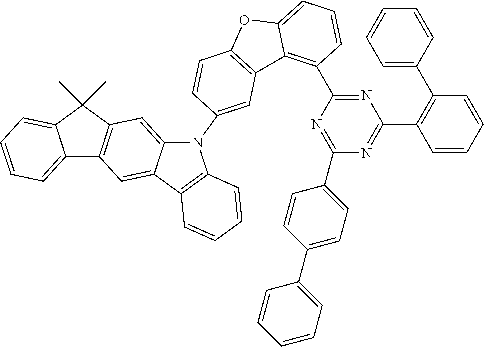 [SMILES: CC1(C)c2ccccc2-c2cc3c4ccccc4n(-c4ccc5oc6cccc(-c7nc(-c8ccc(-c9ccccc9)cc8)nc(-c8ccccc8-c8ccccc8)n7)c6c5c4)c3cc21] | 1-447 |
| 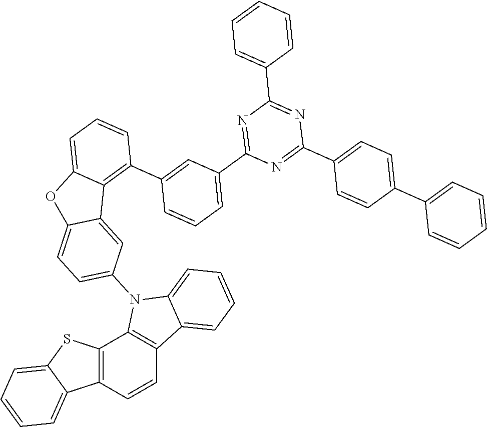 [SMILES: c1ccc(-c2ccc(-c3nc(-c4ccccc4)nc(-c4cccc(-c5cccc6oc7ccc(-n8c9ccccc9c9ccc%10c%11ccccc%11sc%10c98)cc7c56)c4)n3)cc2)cc1] | 1-448 |
| 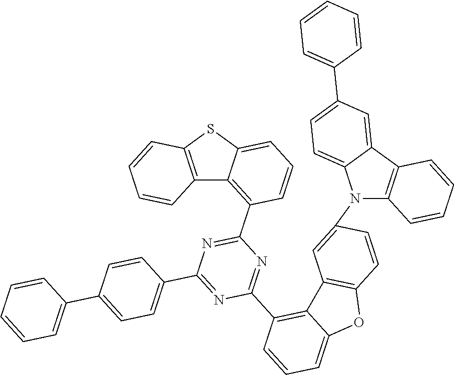 [SMILES: c1ccc(-c2ccc(-c3nc(-c4cccc5oc6ccc(-n7c8ccccc8c8cc(-c9ccccc9)ccc87)cc6c45)nc(-c4cccc5sc6ccccc6c45)n3)cc2)cc1] | 1-449 |
| 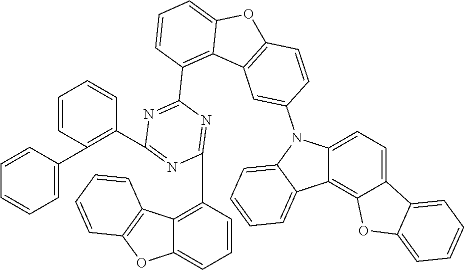 [SMILES: c1ccc(-c2ccccc2-c2nc(-c3cccc4oc5ccccc5c34)nc(-c3cccc4oc5ccc(-n6c7ccccc7c7c8oc9ccccc9c8ccc76)cc5c34)n2)cc1] | 1-450 |
| 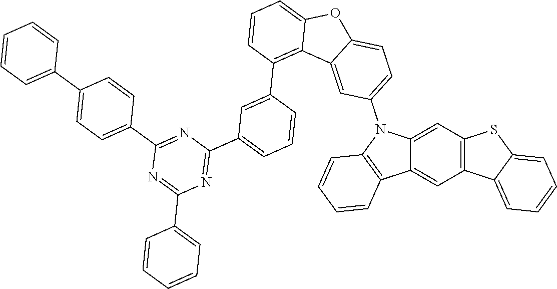 [SMILES: c1ccc(-c2ccc(-c3nc(-c4ccccc4)nc(-c4cccc(-c5cccc6oc7ccc(-n8c9ccccc9c9cc%10c(cc98)sc8ccccc8%10)cc7c56)c4)n3)cc2)cc1] | 1-451 |
| 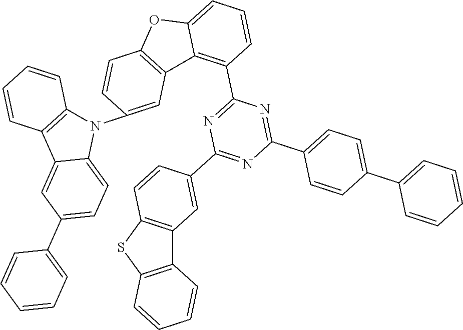 [SMILES: c1ccc(-c2ccc(-c3nc(-c4ccc5sc6ccccc6c5c4)nc(-c4cccc5oc6ccc(-n7c8ccccc8c8cc(-c9ccccc9)ccc87)cc6c45)n3)cc2)cc1] | 1-452 |
| 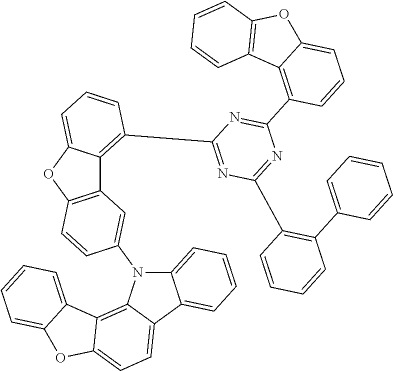 [SMILES: c1ccc(-c2ccccc2-c2nc(-c3cccc4oc5ccccc5c34)nc(-c3cccc4oc5ccc(-n6c7ccccc7c7ccc8oc9ccccc9c8c76)cc5c34)n2)cc1] | 1-453 |
| 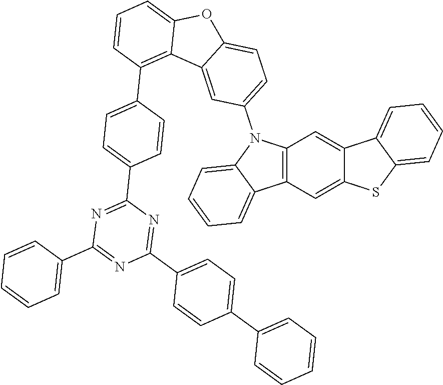 [SMILES: c1ccc(-c2ccc(-c3nc(-c4ccccc4)nc(-c4ccc(-c5cccc6oc7ccc(-n8c9ccccc9c9cc%10sc%11ccccc%11c%10cc98)cc7c56)cc4)n3)cc2)cc1] | 1-454 |
| 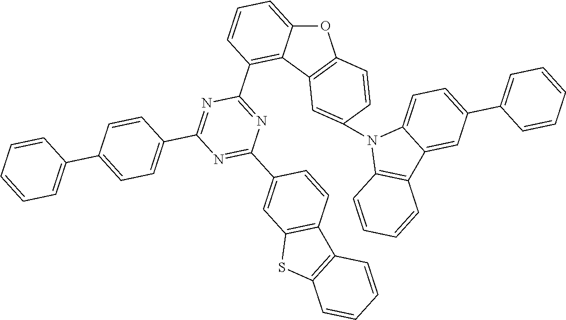 [SMILES: c1ccc(-c2ccc(-c3nc(-c4ccc5c(c4)sc4ccccc45)nc(-c4cccc5oc6ccc(-n7c8ccccc8c8cc(-c9ccccc9)ccc87)cc6c45)n3)cc2)cc1] | 1-455 |
| 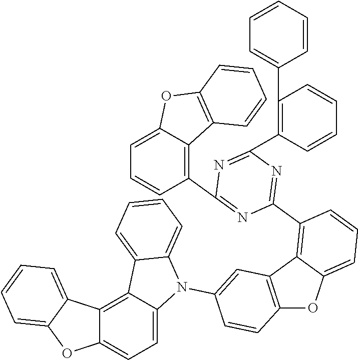 [SMILES: c1ccc(-c2ccccc2-c2nc(-c3cccc4oc5ccccc5c34)nc(-c3cccc4oc5ccc(-n6c7ccccc7c7c8c(ccc76)oc6ccccc68)cc5c34)n2)cc1] | 1-456 |
| 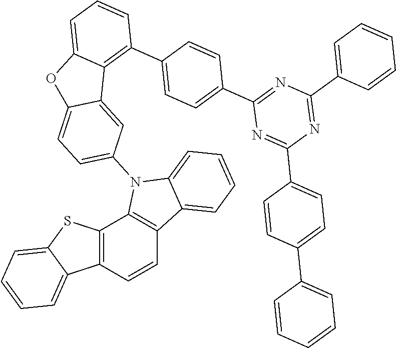 [SMILES: c1ccc(-c2ccc(-c3nc(-c4ccccc4)nc(-c4ccc(-c5cccc6oc7ccc(-n8c9ccccc9c9ccc%10c%11ccccc%11sc%10c98)cc7c56)cc4)n3)cc2)cc1] | 1-457 |
| 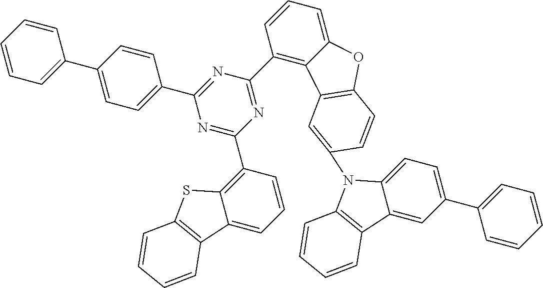 [SMILES: c1ccc(-c2ccc(-c3nc(-c4cccc5c4sc4ccccc45)nc(-c4cccc5oc6ccc(-n7c8ccccc8c8cc(-c9ccccc9)ccc87)cc6c45)n3)cc2)cc1] | 1-458 |
| 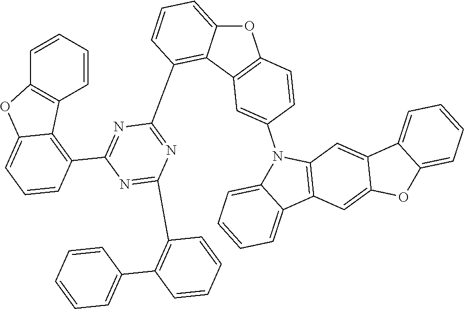 [SMILES: c1ccc(-c2ccccc2-c2nc(-c3cccc4oc5ccccc5c34)nc(-c3cccc4oc5ccc(-n6c7ccccc7c7cc8oc9ccccc9c8cc76)cc5c34)n2)cc1] | 1-459 |
| 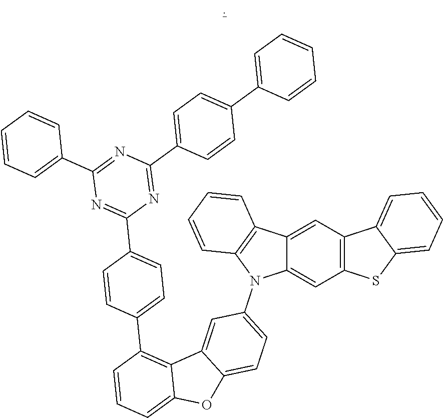 [SMILES: c1ccc(-c2ccc(-c3nc(-c4ccccc4)nc(-c4ccc(-c5cccc6oc7ccc(-n8c9ccccc9c9cc%10c(cc98)sc8ccccc8%10)cc7c56)cc4)n3)cc2)cc1] | 1-460 |
| 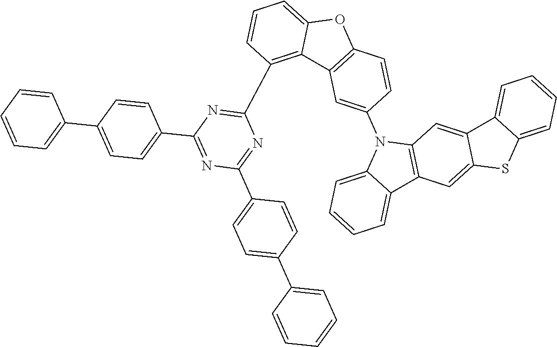 [SMILES: c1ccc(-c2ccc(-c3nc(-c4ccc(-c5ccccc5)cc4)nc(-c4cccc5oc6ccc(-n7c8ccccc8c8cc9sc%10ccccc%10c9cc87)cc6c45)n3)cc2)cc1] | 1-461 |
| 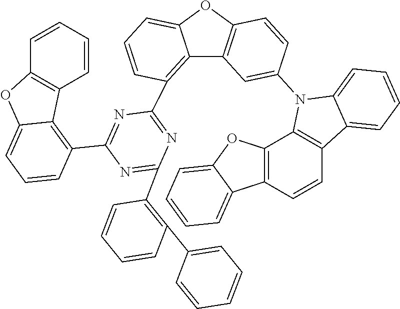 [SMILES: c1ccc(-c2ccccc2-c2nc(-c3cccc4oc5ccccc5c34)nc(-c3cccc4oc5ccc(-n6c7ccccc7c7ccc8c9ccccc9oc8c76)cc5c34)n2)cc1] | 1-462 |
| 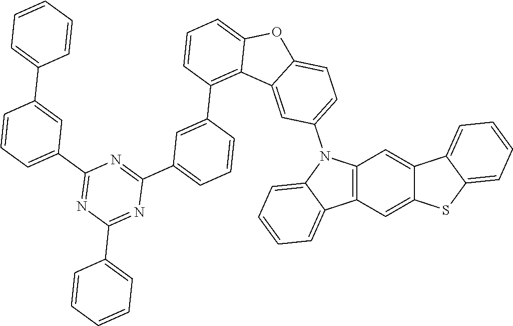 [SMILES: c1ccc(-c2cccc(-c3nc(-c4ccccc4)nc(-c4cccc(-c5cccc6oc7ccc(-n8c9ccccc9c9cc%10sc%11ccccc%11c%10cc98)cc7c56)c4)n3)c2)cc1] | 1-463 |
| 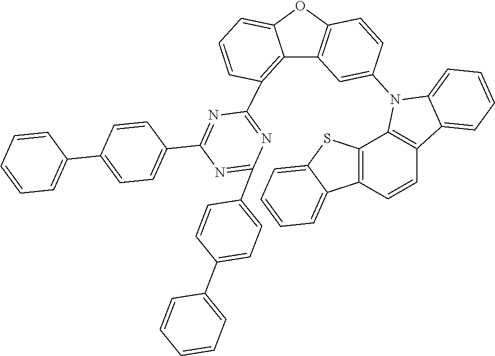 [SMILES: c1ccc(-c2ccc(-c3nc(-c4ccc(-c5ccccc5)cc4)nc(-c4cccc5oc6ccc(-n7c8ccccc8c8ccc9c%10ccccc%10sc9c87)cc6c45)n3)cc2)cc1] | 1-464 |
| 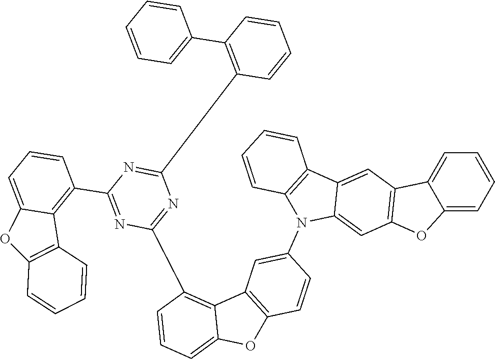 [SMILES: c1ccc(-c2ccccc2-c2nc(-c3cccc4oc5ccccc5c34)nc(-c3cccc4oc5ccc(-n6c7ccccc7c7cc8c(cc76)oc6ccccc68)cc5c34)n2)cc1] | 1-465 |
| 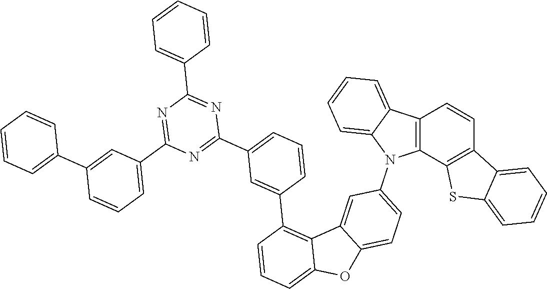 [SMILES: c1ccc(-c2cccc(-c3nc(-c4ccccc4)nc(-c4cccc(-c5cccc6oc7ccc(-n8c9ccccc9c9ccc%10c%11ccccc%11sc%10c98)cc7c56)c4)n3)c2)cc1] | 1-466 |
| 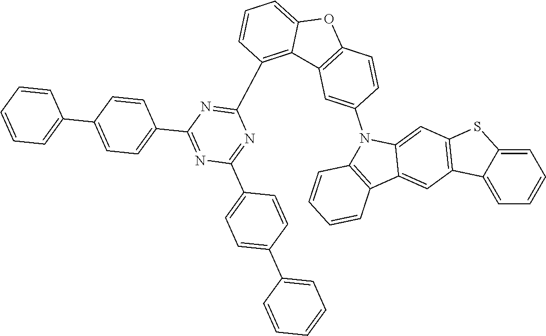 [SMILES: c1ccc(-c2ccc(-c3nc(-c4ccc(-c5ccccc5)cc4)nc(-c4cccc5oc6ccc(-n7c8ccccc8c8cc9c(cc87)sc7ccccc79)cc6c45)n3)cc2)cc1] | 1-467 |
| 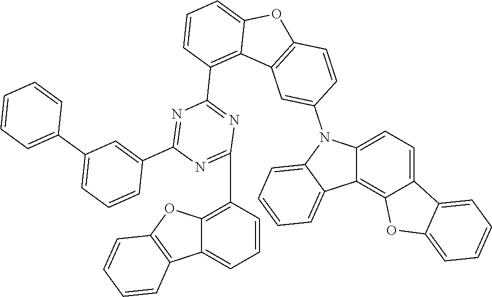 [SMILES: c1ccc(-c2cccc(-c3nc(-c4cccc5c4oc4ccccc45)nc(-c4cccc5oc6ccc(-n7c8ccccc8c8c9oc%10ccccc%10c9ccc87)cc6c45)n3)c2)cc1] | 1-468 |
| 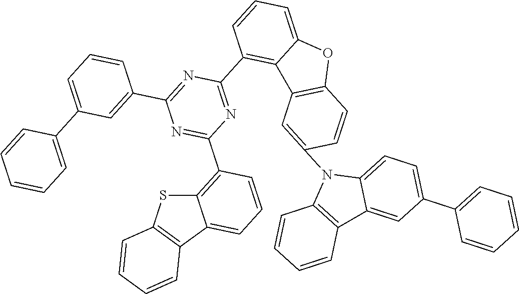 [SMILES: c1ccc(-c2cccc(-c3nc(-c4cccc5c4sc4ccccc45)nc(-c4cccc5oc6ccc(-n7c8ccccc8c8cc(-c9ccccc9)ccc87)cc6c45)n3)c2)cc1] | 1-469 |
| 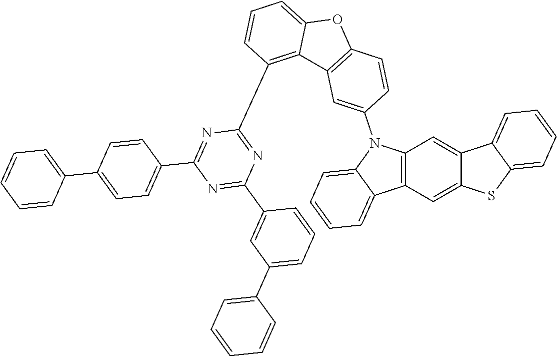 [SMILES: c1ccc(-c2ccc(-c3nc(-c4cccc(-c5ccccc5)c4)nc(-c4cccc5oc6ccc(-n7c8ccccc8c8cc9sc%10ccccc%10c9cc87)cc6c45)n3)cc2)cc1] | 1-470 |
| 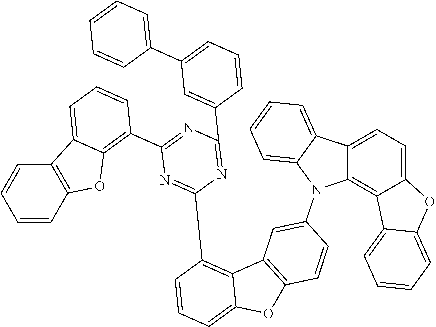 [SMILES: c1ccc(-c2cccc(-c3nc(-c4cccc5c4oc4ccccc45)nc(-c4cccc5oc6ccc(-n7c8ccccc8c8ccc9oc%10ccccc%10c9c87)cc6c45)n3)c2)cc1] | 1-471 |
| 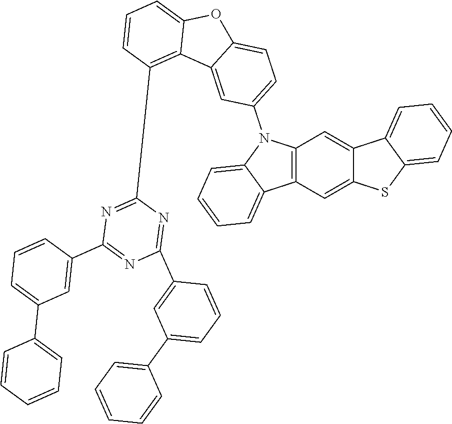 [SMILES: c1ccc(-c2cccc(-c3nc(-c4cccc(-c5ccccc5)c4)nc(-c4cccc5oc6ccc(-n7c8ccccc8c8cc9sc%10ccccc%10c9cc87)cc6c45)n3)c2)cc1] | 1-472 |
| 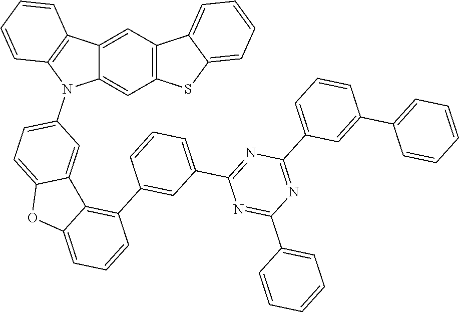 [SMILES: c1ccc(-c2cccc(-c3nc(-c4ccccc4)nc(-c4cccc(-c5cccc6oc7ccc(-n8c9ccccc9c9cc%10c(cc98)sc8ccccc8%10)cc7c56)c4)n3)c2)cc1] | 1-473 |
| 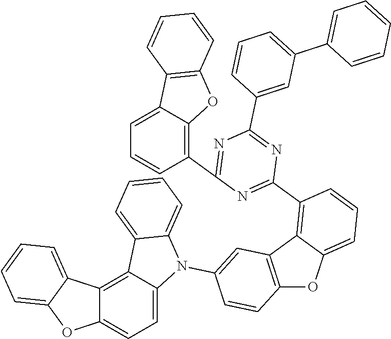 [SMILES: c1ccc(-c2cccc(-c3nc(-c4cccc5c4oc4ccccc45)nc(-c4cccc5oc6ccc(-n7c8ccccc8c8c9c(ccc87)oc7ccccc79)cc6c45)n3)c2)cc1] | 1-474 |
| 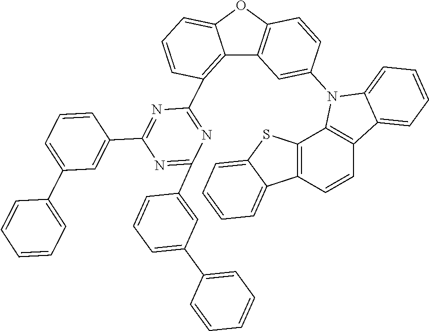 [SMILES: c1ccc(-c2cccc(-c3nc(-c4cccc(-c5ccccc5)c4)nc(-c4cccc5oc6ccc(-n7c8ccccc8c8ccc9c%10ccccc%10sc9c87)cc6c45)n3)c2)cc1] | 1-475 |
| 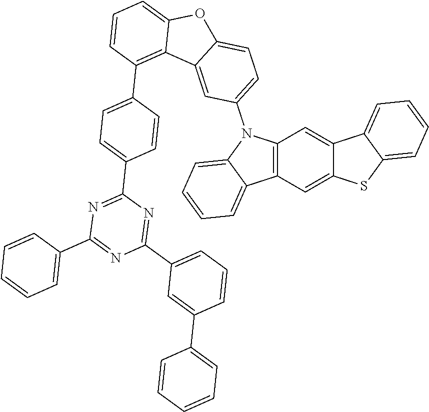 [SMILES: c1ccc(-c2cccc(-c3nc(-c4ccccc4)nc(-c4ccc(-c5cccc6oc7ccc(-n8c9ccccc9c9cc%10sc%11ccccc%11c%10cc98)cc7c56)cc4)n3)c2)cc1] | 1-476 |
| 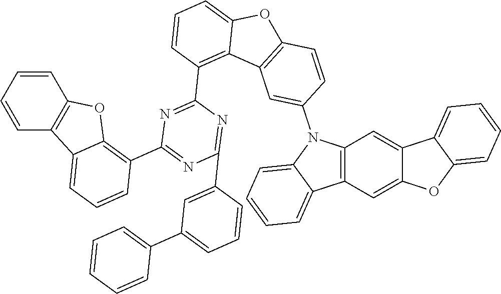 [SMILES: c1ccc(-c2cccc(-c3nc(-c4cccc5c4oc4ccccc45)nc(-c4cccc5oc6ccc(-n7c8ccccc8c8cc9oc%10ccccc%10c9cc87)cc6c45)n3)c2)cc1] | 1-477 |
| 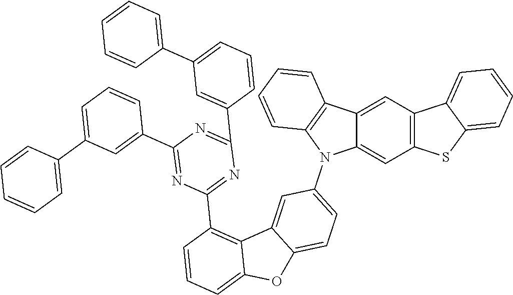 [SMILES: c1ccc(-c2cccc(-c3nc(-c4cccc(-c5ccccc5)c4)nc(-c4cccc5oc6ccc(-n7c8ccccc8c8cc9c(cc87)sc7ccccc79)cc6c45)n3)c2)cc1] | 1-478 |
| 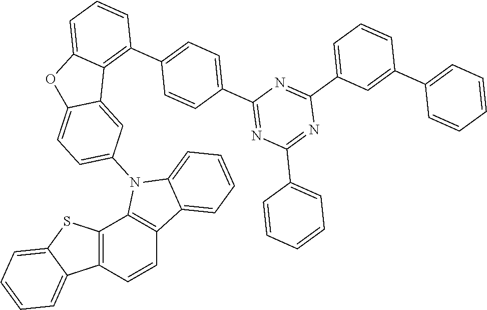 [SMILES: c1ccc(-c2cccc(-c3nc(-c4ccccc4)nc(-c4ccc(-c5cccc6oc7ccc(-n8c9ccccc9c9ccc%10c%11ccccc%11sc%10c98)cc7c56)cc4)n3)c2)cc1] | 1-479 |
| 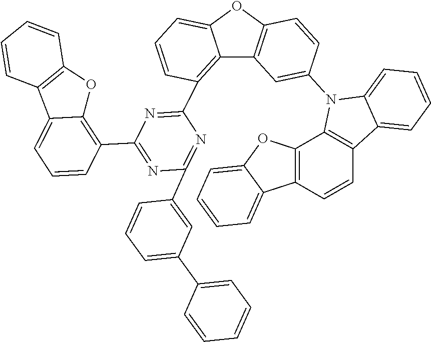 [SMILES: c1ccc(-c2cccc(-c3nc(-c4cccc5c4oc4ccccc45)nc(-c4cccc5oc6ccc(-n7c8ccccc8c8ccc9c%10ccccc%10oc9c87)cc6c45)n3)c2)cc1] | 1-480 |
| 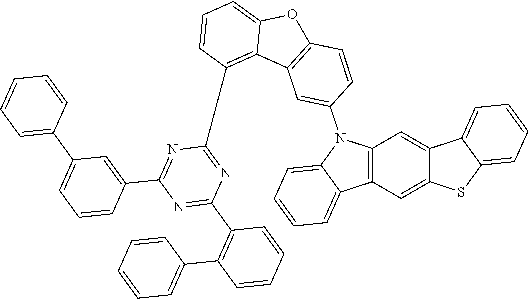 [SMILES: c1ccc(-c2cccc(-c3nc(-c4ccccc4-c4ccccc4)nc(-c4cccc5oc6ccc(-n7c8ccccc8c8cc9sc%10ccccc%10c9cc87)cc6c45)n3)c2)cc1] | 1-481 |
| 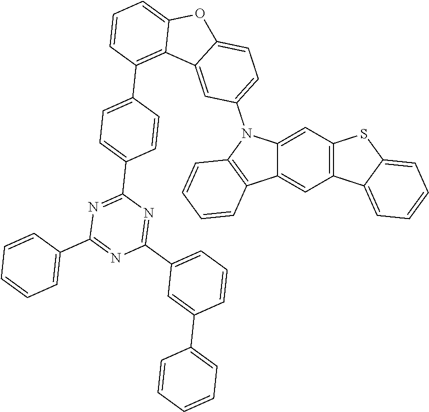 [SMILES: c1ccc(-c2cccc(-c3nc(-c4ccccc4)nc(-c4ccc(-c5cccc6oc7ccc(-n8c9ccccc9c9cc%10c(cc98)sc8ccccc8%10)cc7c56)cc4)n3)c2)cc1] | 1-482 |
| 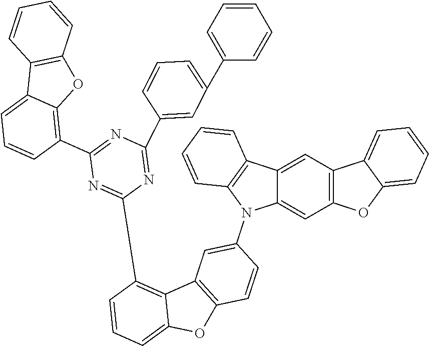 [SMILES: c1ccc(-c2cccc(-c3nc(-c4cccc5c4oc4ccccc45)nc(-c4cccc5oc6ccc(-n7c8ccccc8c8cc9c(cc87)oc7ccccc79)cc6c45)n3)c2)cc1] | 1-483 |
| 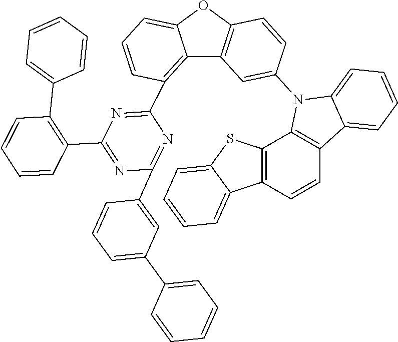 [SMILES: c1ccc(-c2cccc(-c3nc(-c4ccccc4-c4ccccc4)nc(-c4cccc5oc6ccc(-n7c8ccccc8c8ccc9c%10ccccc%10sc9c87)cc6c45)n3)c2)cc1] | 1-484 |
| 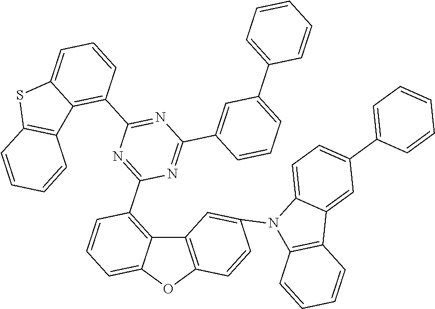 [SMILES: c1ccc(-c2cccc(-c3nc(-c4cccc5oc6ccc(-n7c8ccccc8c8cc(-c9ccccc9)ccc87)cc6c45)nc(-c4cccc5sc6ccccc6c45)n3)c2)cc1] | 1-485 |
| 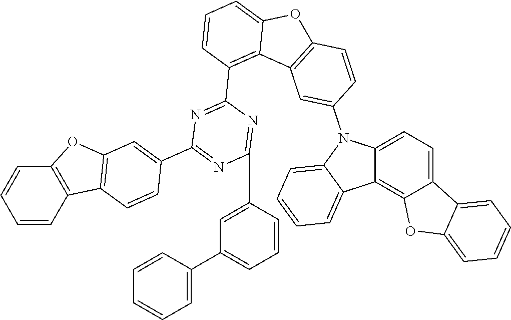 [SMILES: c1ccc(-c2cccc(-c3nc(-c4ccc5c(c4)oc4ccccc45)nc(-c4cccc5oc6ccc(-n7c8ccccc8c8c9oc%10ccccc%10c9ccc87)cc6c45)n3)c2)cc1] | 1-486 |
| 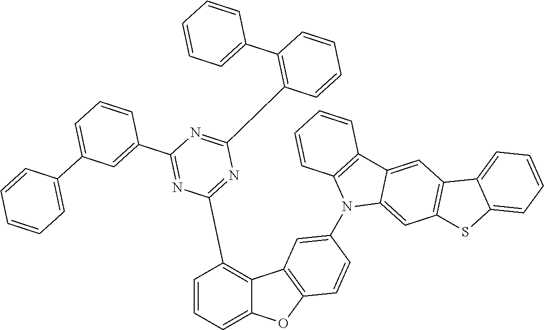 [SMILES: c1ccc(-c2cccc(-c3nc(-c4ccccc4-c4ccccc4)nc(-c4cccc5oc6ccc(-n7c8ccccc8c8cc9c(cc87)sc7ccccc79)cc6c45)n3)c2)cc1] | 1-487 |
| 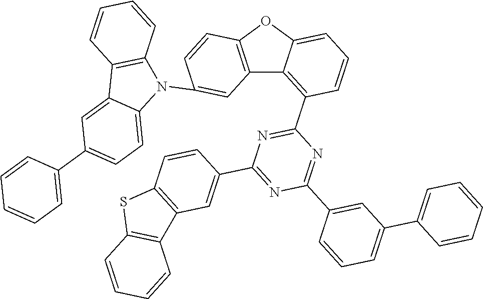 [SMILES: c1ccc(-c2cccc(-c3nc(-c4ccc5sc6ccccc6c5c4)nc(-c4cccc5oc6ccc(-n7c8ccccc8c8cc(-c9ccccc9)ccc87)cc6c45)n3)c2)cc1] | 1-488 |
| 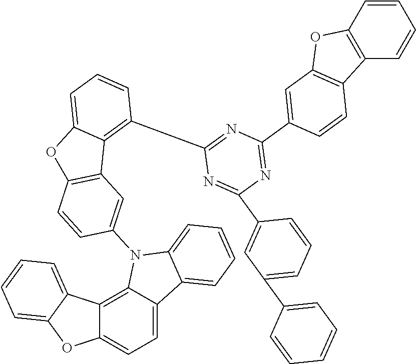 [SMILES: c1ccc(-c2cccc(-c3nc(-c4ccc5c(c4)oc4ccccc45)nc(-c4cccc5oc6ccc(-n7c8ccccc8c8ccc9oc%10ccccc%10c9c87)cc6c45)n3)c2)cc1] | 1-489 |
| 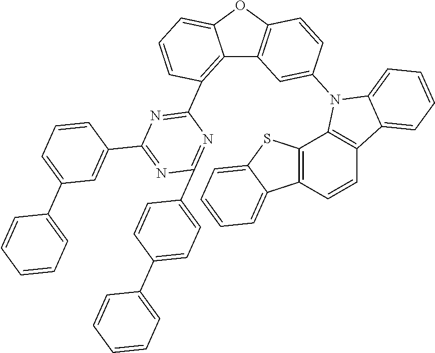 [SMILES: c1ccc(-c2ccc(-c3nc(-c4cccc(-c5ccccc5)c4)nc(-c4cccc5oc6ccc(-n7c8ccccc8c8ccc9c%10ccccc%10sc9c87)cc6c45)n3)cc2)cc1] | 1-490 |
| 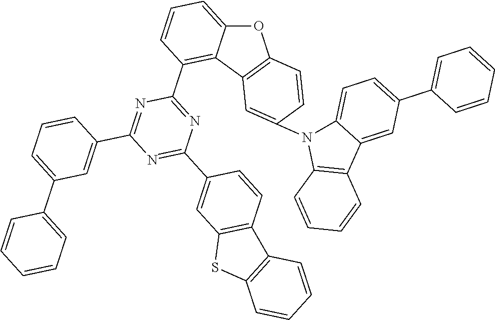 [SMILES: c1ccc(-c2cccc(-c3nc(-c4ccc5c(c4)sc4ccccc45)nc(-c4cccc5oc6ccc(-n7c8ccccc8c8cc(-c9ccccc9)ccc87)cc6c45)n3)c2)cc1] | 1-491 |
| 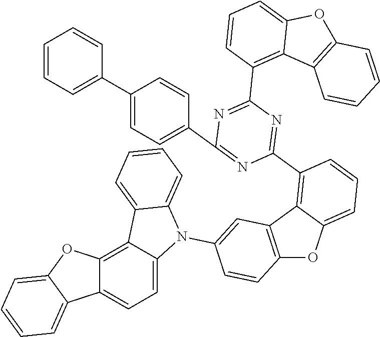 [SMILES: c1ccc(-c2ccc(-c3nc(-c4cccc5oc6ccccc6c45)nc(-c4cccc5oc6ccc(-n7c8ccccc8c8c9oc%10ccccc%10c9ccc87)cc6c45)n3)cc2)cc1] | 1-492 |
| 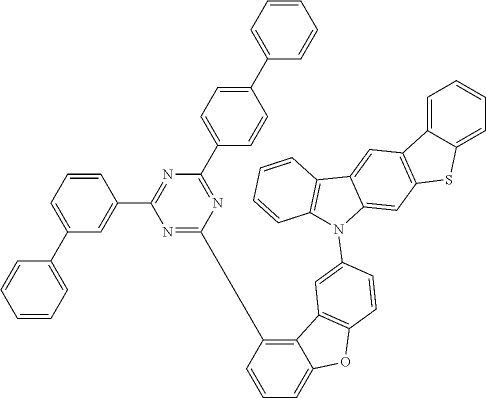 [SMILES: c1ccc(-c2ccc(-c3nc(-c4cccc(-c5ccccc5)c4)nc(-c4cccc5oc6ccc(-n7c8ccccc8c8cc9c(cc87)sc7ccccc79)cc6c45)n3)cc2)cc1] | 1-493 |
| 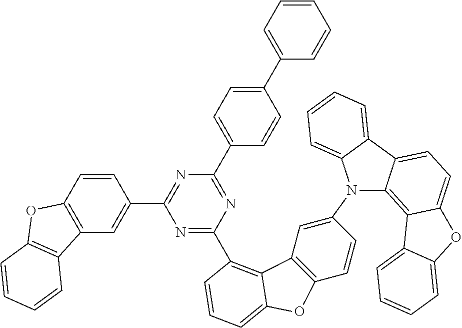 [SMILES: c1ccc(-c2ccc(-c3nc(-c4ccc5oc6ccccc6c5c4)nc(-c4cccc5oc6ccc(-n7c8ccccc8c8ccc9oc%10ccccc%10c9c87)cc6c45)n3)cc2)cc1] | 1-494 |
| 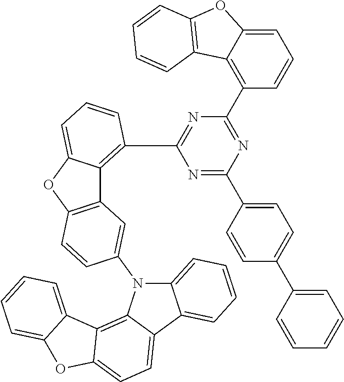 [SMILES: c1ccc(-c2ccc(-c3nc(-c4cccc5oc6ccccc6c45)nc(-c4cccc5oc6ccc(-n7c8ccccc8c8ccc9oc%10ccccc%10c9c87)cc6c45)n3)cc2)cc1] | 1-495 |
| 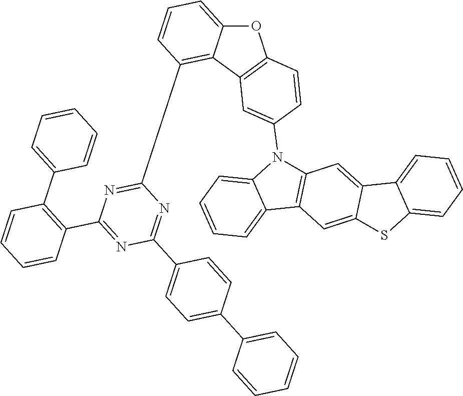 [SMILES: c1ccc(-c2ccc(-c3nc(-c4ccccc4-c4ccccc4)nc(-c4cccc5oc6ccc(-n7c8ccccc8c8cc9sc%10ccccc%10c9cc87)cc6c45)n3)cc2)cc1] | 1-496 |
| 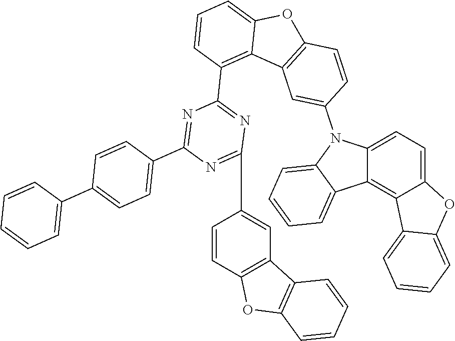 [SMILES: c1ccc(-c2ccc(-c3nc(-c4ccc5oc6ccccc6c5c4)nc(-c4cccc5oc6ccc(-n7c8ccccc8c8c9c(ccc87)oc7ccccc79)cc6c45)n3)cc2)cc1] | 1-497 |
| 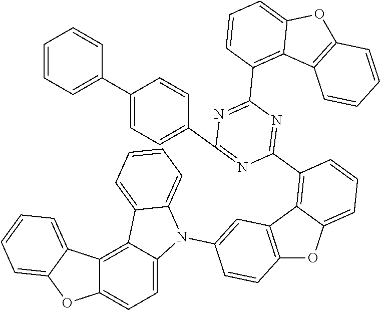 [SMILES: c1ccc(-c2ccc(-c3nc(-c4cccc5oc6ccccc6c45)nc(-c4cccc5oc6ccc(-n7c8ccccc8c8c9c(ccc87)oc7ccccc79)cc6c45)n3)cc2)cc1] | 1-498 |
| 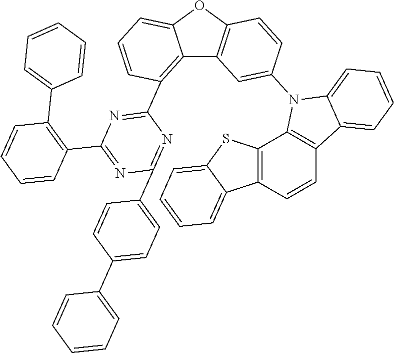 [SMILES: c1ccc(-c2ccc(-c3nc(-c4ccccc4-c4ccccc4)nc(-c4cccc5oc6ccc(-n7c8ccccc8c8ccc9c%10ccccc%10sc9c87)cc6c45)n3)cc2)cc1] | 1-499 |
| 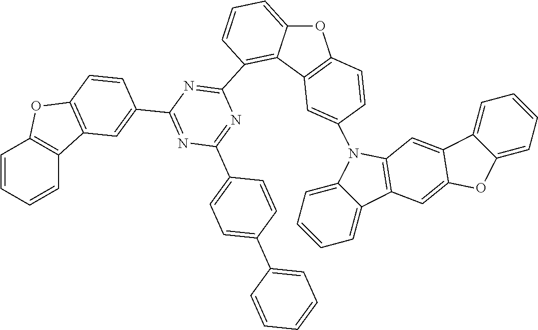 [SMILES: c1ccc(-c2ccc(-c3nc(-c4ccc5oc6ccccc6c5c4)nc(-c4cccc5oc6ccc(-n7c8ccccc8c8cc9oc%10ccccc%10c9cc87)cc6c45)n3)cc2)cc1] | 1-500 |
| 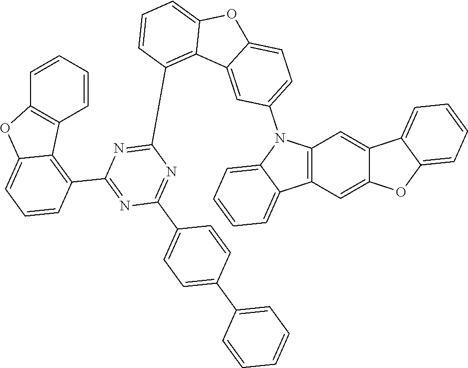 [SMILES: c1ccc(-c2ccc(-c3nc(-c4cccc5oc6ccccc6c45)nc(-c4cccc5oc6ccc(-n7c8ccccc8c8cc9oc%10ccccc%10c9cc87)cc6c45)n3)cc2)cc1] | 1-501 |
| 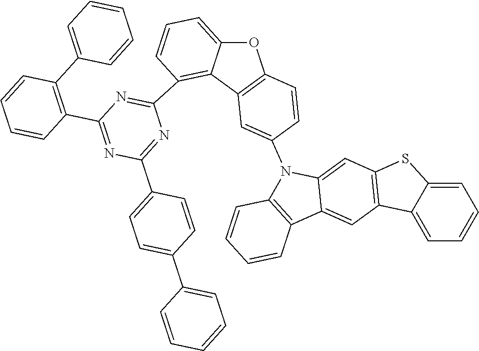 [SMILES: c1ccc(-c2ccc(-c3nc(-c4ccccc4-c4ccccc4)nc(-c4cccc5oc6ccc(-n7c8ccccc8c8cc9c(cc87)sc7ccccc79)cc6c45)n3)cc2)cc1] | 1-502 |
| 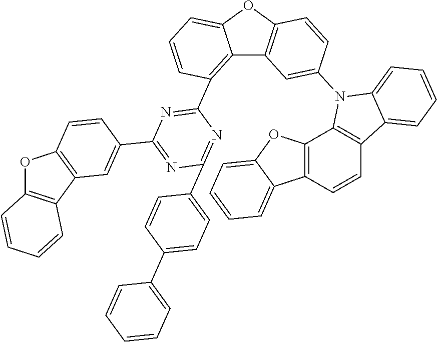 [SMILES: c1ccc(-c2ccc(-c3nc(-c4ccc5oc6ccccc6c5c4)nc(-c4cccc5oc6ccc(-n7c8ccccc8c8ccc9c%10ccccc%10oc9c87)cc6c45)n3)cc2)cc1] | 1-503 |
| 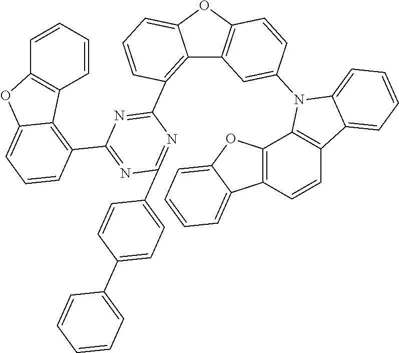 [SMILES: c1ccc(-c2ccc(-c3nc(-c4cccc5oc6ccccc6c45)nc(-c4cccc5oc6ccc(-n7c8ccccc8c8ccc9c%10ccccc%10oc9c87)cc6c45)n3)cc2)cc1] | 1-504 |
| 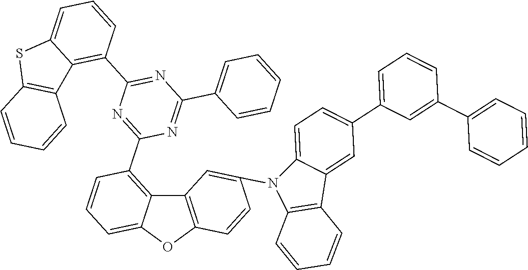 [SMILES: c1ccc(-c2cccc(-c3ccc4c(c3)c3ccccc3n4-c3ccc4oc5cccc(-c6nc(-c7ccccc7)nc(-c7cccc8sc9ccccc9c78)n6)c5c4c3)c2)cc1] | 1-505 |
| 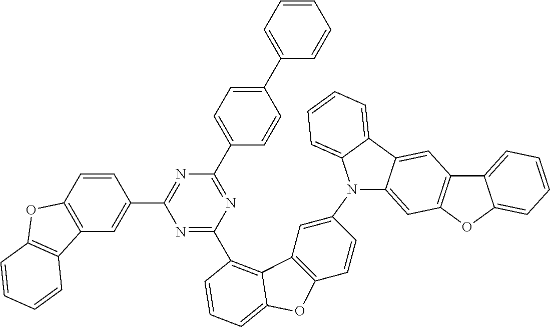 [SMILES: c1ccc(-c2ccc(-c3nc(-c4ccc5oc6ccccc6c5c4)nc(-c4cccc5oc6ccc(-n7c8ccccc8c8cc9c(cc87)oc7ccccc79)cc6c45)n3)cc2)cc1] | 1-506 |
| 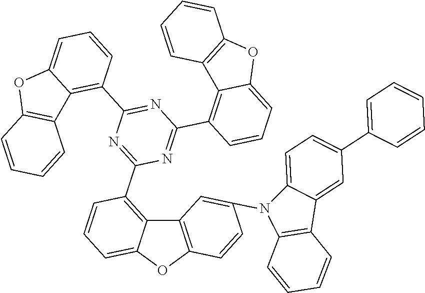 [SMILES: c1ccc(-c2ccc3c(c2)c2ccccc2n3-c2ccc3oc4cccc(-c5nc(-c6cccc7oc8ccccc8c67)nc(-c6cccc7oc8ccccc8c67)n5)c4c3c2)cc1] | 1-507 |
| 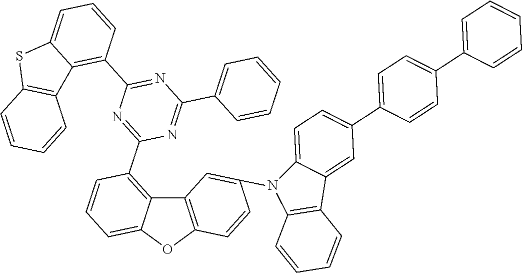 [SMILES: c1ccc(-c2ccc(-c3ccc4c(c3)c3ccccc3n4-c3ccc4oc5cccc(-c6nc(-c7ccccc7)nc(-c7cccc8sc9ccccc9c78)n6)c5c4c3)cc2)cc1] | 1-508 |
| 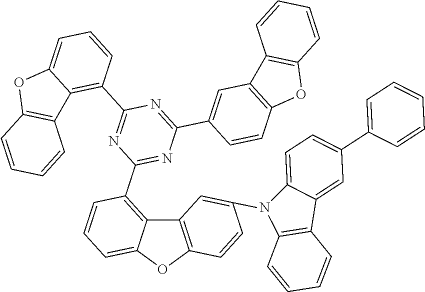 [SMILES: c1ccc(-c2ccc3c(c2)c2ccccc2n3-c2ccc3oc4cccc(-c5nc(-c6ccc7oc8ccccc8c7c6)nc(-c6cccc7oc8ccccc8c67)n5)c4c3c2)cc1] | 1-509 |
| 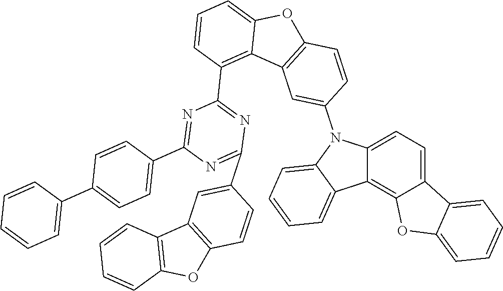 [SMILES: c1ccc(-c2ccc(-c3nc(-c4ccc5oc6ccccc6c5c4)nc(-c4cccc5oc6ccc(-n7c8ccccc8c8c9oc%10ccccc%10c9ccc87)cc6c45)n3)cc2)cc1] | 1-510 |
| 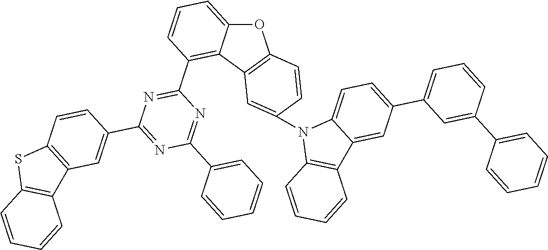 [SMILES: c1ccc(-c2cccc(-c3ccc4c(c3)c3ccccc3n4-c3ccc4oc5cccc(-c6nc(-c7ccccc7)nc(-c7ccc8sc9ccccc9c8c7)n6)c5c4c3)c2)cc1] | 1-511 |
| 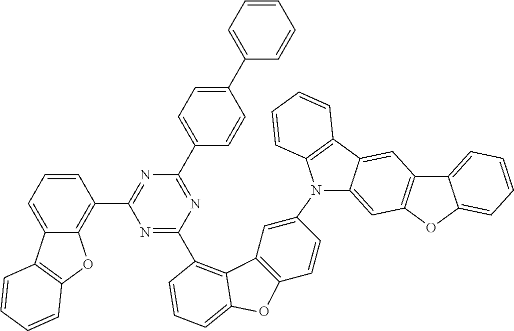 [SMILES: c1ccc(-c2ccc(-c3nc(-c4cccc5c4oc4ccccc45)nc(-c4cccc5oc6ccc(-n7c8ccccc8c8cc9c(cc87)oc7ccccc79)cc6c45)n3)cc2)cc1] | 1-512 |
| 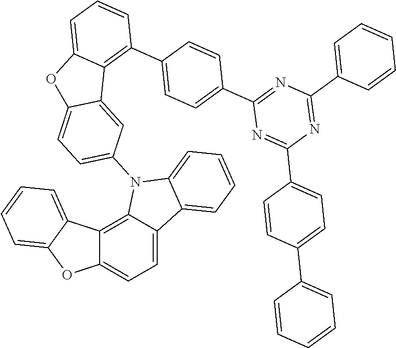 [SMILES: c1ccc(-c2ccc(-c3nc(-c4ccccc4)nc(-c4ccc(-c5cccc6oc7ccc(-n8c9ccccc9c9ccc%10oc%11ccccc%11c%10c98)cc7c56)cc4)n3)cc2)cc1] | 1-513 |
| 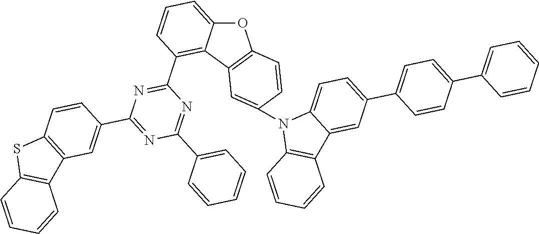 [SMILES: c1ccc(-c2ccc(-c3ccc4c(c3)c3ccccc3n4-c3ccc4oc5cccc(-c6nc(-c7ccccc7)nc(-c7ccc8sc9ccccc9c8c7)n6)c5c4c3)cc2)cc1] | 1-514 |
| 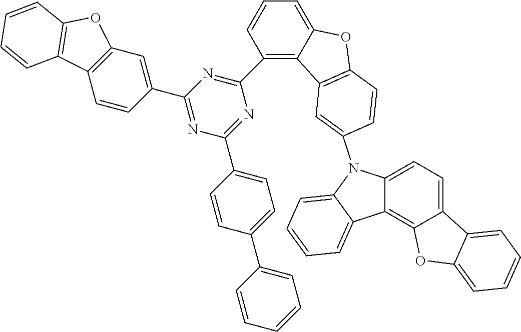 [SMILES: c1ccc(-c2ccc(-c3nc(-c4ccc5c(c4)oc4ccccc45)nc(-c4cccc5oc6ccc(-n7c8ccccc8c8c9oc%10ccccc%10c9ccc87)cc6c45)n3)cc2)cc1] | 1-515 |
| 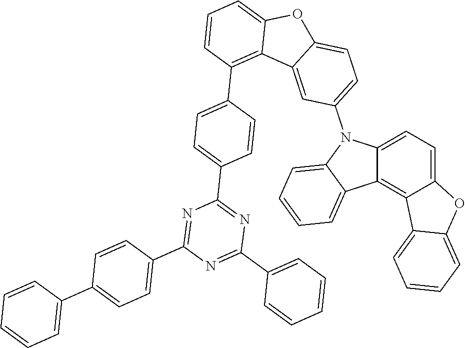 [SMILES: c1ccc(-c2ccc(-c3nc(-c4ccccc4)nc(-c4ccc(-c5cccc6oc7ccc(-n8c9ccccc9c9c%10c(ccc98)oc8ccccc8%10)cc7c56)cc4)n3)cc2)cc1] | 1-516 |
| 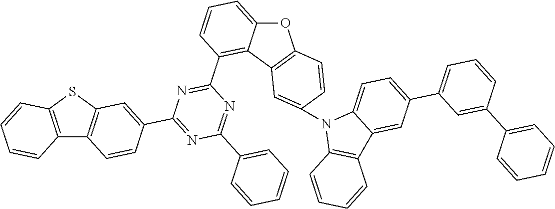 [SMILES: c1ccc(-c2cccc(-c3ccc4c(c3)c3ccccc3n4-c3ccc4oc5cccc(-c6nc(-c7ccccc7)nc(-c7ccc8c(c7)sc7ccccc78)n6)c5c4c3)c2)cc1] | 1-517 |
| 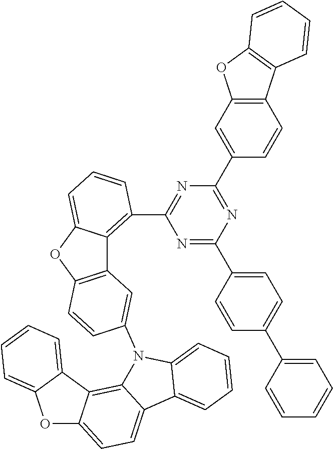 [SMILES: c1ccc(-c2ccc(-c3nc(-c4ccc5c(c4)oc4ccccc45)nc(-c4cccc5oc6ccc(-n7c8ccccc8c8ccc9oc%10ccccc%10c9c87)cc6c45)n3)cc2)cc1] | 1-518 |
| 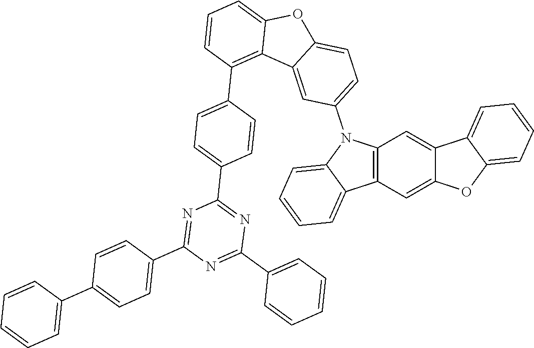 [SMILES: c1ccc(-c2ccc(-c3nc(-c4ccccc4)nc(-c4ccc(-c5cccc6oc7ccc(-n8c9ccccc9c9cc%10oc%11ccccc%11c%10cc98)cc7c56)cc4)n3)cc2)cc1] | 1-519 |
| 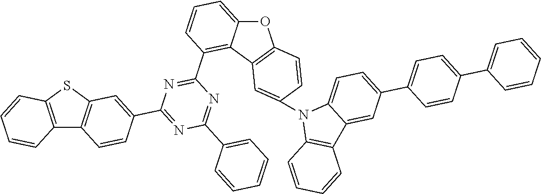 [SMILES: c1ccc(-c2ccc(-c3ccc4c(c3)c3ccccc3n4-c3ccc4oc5cccc(-c6nc(-c7ccccc7)nc(-c7ccc8c(c7)sc7ccccc78)n6)c5c4c3)cc2)cc1] | 1-520 |
| 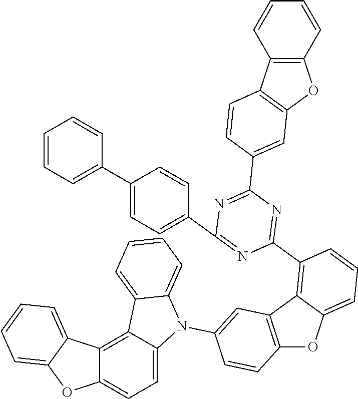 [SMILES: c1ccc(-c2ccc(-c3nc(-c4ccc5c(c4)oc4ccccc45)nc(-c4cccc5oc6ccc(-n7c8ccccc8c8c9c(ccc87)oc7ccccc79)cc6c45)n3)cc2)cc1] | 1-521 |
| 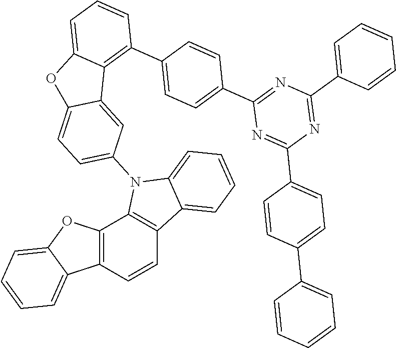 [SMILES: c1ccc(-c2ccc(-c3nc(-c4ccccc4)nc(-c4ccc(-c5cccc6oc7ccc(-n8c9ccccc9c9ccc%10c%11ccccc%11oc%10c98)cc7c56)cc4)n3)cc2)cc1] | 1-522 |
| 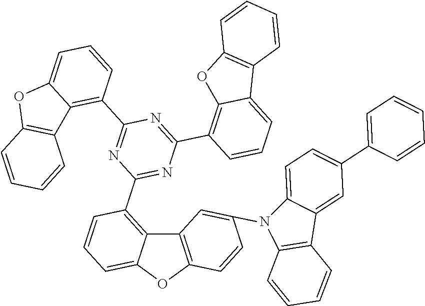 [SMILES: c1ccc(-c2ccc3c(c2)c2ccccc2n3-c2ccc3oc4cccc(-c5nc(-c6cccc7c6oc6ccccc67)nc(-c6cccc7oc8ccccc8c67)n5)c4c3c2)cc1] | 1-523 |
| 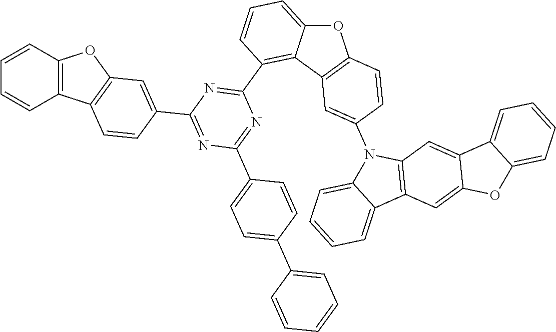 [SMILES: c1ccc(-c2ccc(-c3nc(-c4ccc5c(c4)oc4ccccc45)nc(-c4cccc5oc6ccc(-n7c8ccccc8c8cc9oc%10ccccc%10c9cc87)cc6c45)n3)cc2)cc1] | 1-524 |
| 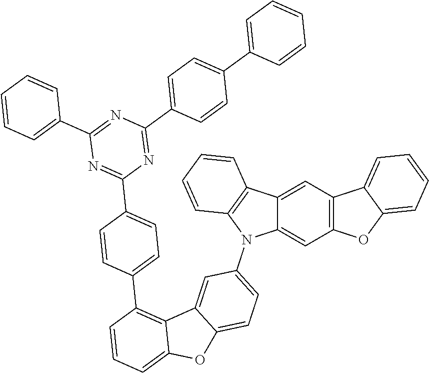 [SMILES: c1ccc(-c2ccc(-c3nc(-c4ccccc4)nc(-c4ccc(-c5cccc6oc7ccc(-n8c9ccccc9c9cc%10c(cc98)oc8ccccc8%10)cc7c56)cc4)n3)cc2)cc1] | 1-525 |
| 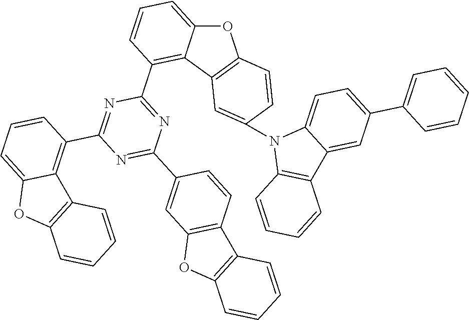 [SMILES: c1ccc(-c2ccc3c(c2)c2ccccc2n3-c2ccc3oc4cccc(-c5nc(-c6ccc7c(c6)oc6ccccc67)nc(-c6cccc7oc8ccccc8c67)n5)c4c3c2)cc1] | 1-526 |
| 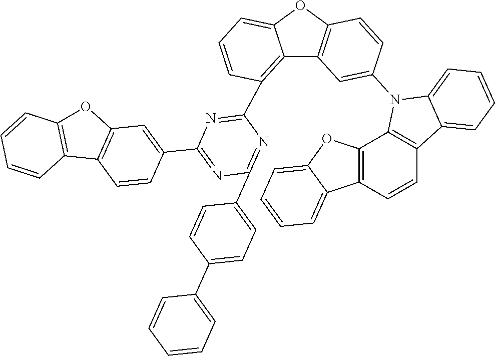 [SMILES: c1ccc(-c2ccc(-c3nc(-c4ccc5c(c4)oc4ccccc45)nc(-c4cccc5oc6ccc(-n7c8ccccc8c8ccc9c%10ccccc%10oc9c87)cc6c45)n3)cc2)cc1] | 1-527 |
| 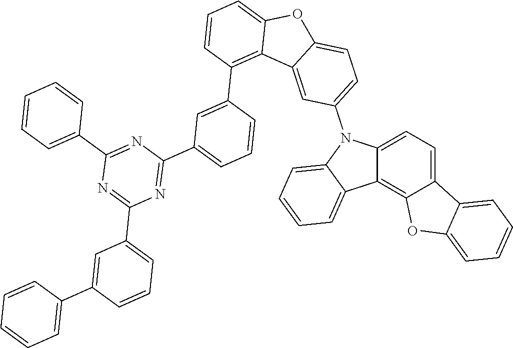 [SMILES: c1ccc(-c2cccc(-c3nc(-c4ccccc4)nc(-c4cccc(-c5cccc6oc7ccc(-n8c9ccccc9c9c%10oc%11ccccc%11c%10ccc98)cc7c56)c4)n3)c2)cc1] | 1-528 |
| 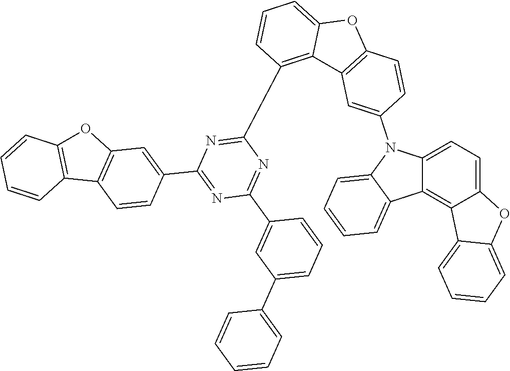 [SMILES: c1ccc(-c2cccc(-c3nc(-c4ccc5c(c4)oc4ccccc45)nc(-c4cccc5oc6ccc(-n7c8ccccc8c8c9c(ccc87)oc7ccccc79)cc6c45)n3)c2)cc1] | 1-529 |
| 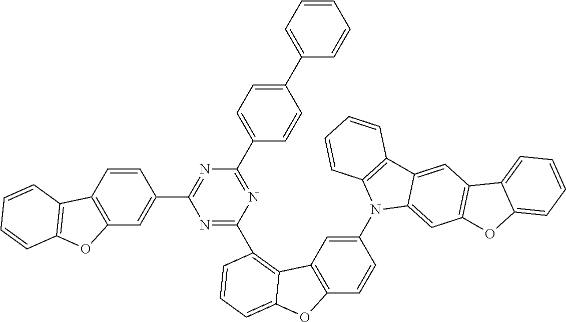 [SMILES: c1ccc(-c2ccc(-c3nc(-c4ccc5c(c4)oc4ccccc45)nc(-c4cccc5oc6ccc(-n7c8ccccc8c8cc9c(cc87)oc7ccccc79)cc6c45)n3)cc2)cc1] | 1-530 |
| 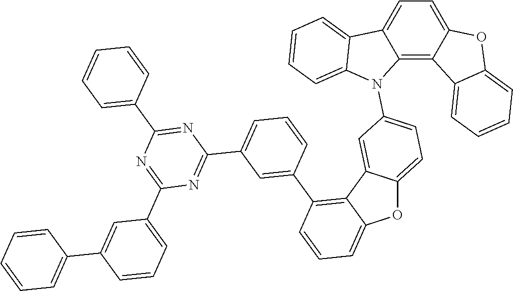 [SMILES: c1ccc(-c2cccc(-c3nc(-c4ccccc4)nc(-c4cccc(-c5cccc6oc7ccc(-n8c9ccccc9c9ccc%10oc%11ccccc%11c%10c98)cc7c56)c4)n3)c2)cc1] | 1-531 |
| 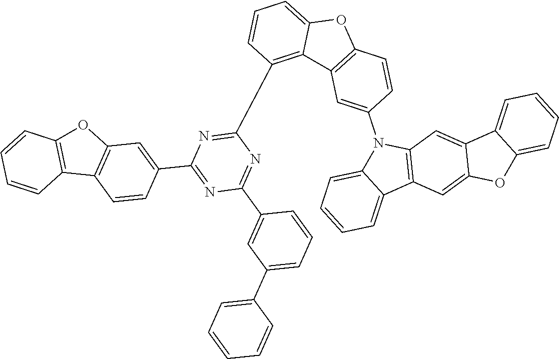 [SMILES: c1ccc(-c2cccc(-c3nc(-c4ccc5c(c4)oc4ccccc45)nc(-c4cccc5oc6ccc(-n7c8ccccc8c8cc9oc%10ccccc%10c9cc87)cc6c45)n3)c2)cc1] | 1-532 |
| 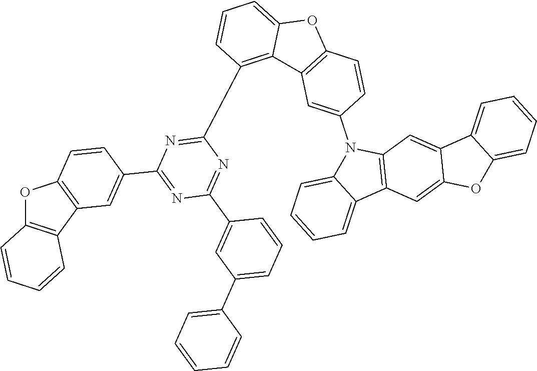 [SMILES: c1ccc(-c2cccc(-c3nc(-c4ccc5oc6ccccc6c5c4)nc(-c4cccc5oc6ccc(-n7c8ccccc8c8cc9oc%10ccccc%10c9cc87)cc6c45)n3)c2)cc1] | 1-533 |
| 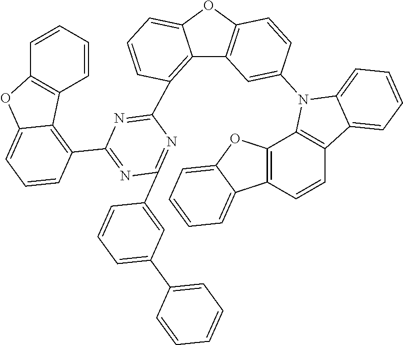 [SMILES: c1ccc(-c2cccc(-c3nc(-c4cccc5oc6ccccc6c45)nc(-c4cccc5oc6ccc(-n7c8ccccc8c8ccc9c%10ccccc%10oc9c87)cc6c45)n3)c2)cc1] | 1-534 |
| 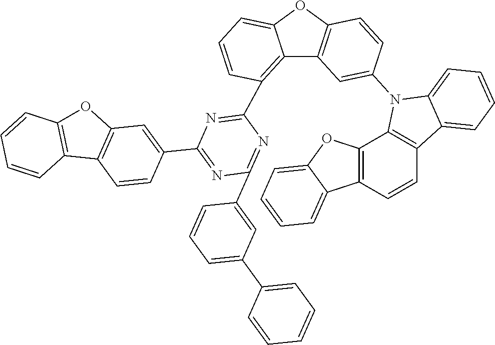 [SMILES: c1ccc(-c2cccc(-c3nc(-c4ccc5c(c4)oc4ccccc45)nc(-c4cccc5oc6ccc(-n7c8ccccc8c8ccc9c%10ccccc%10oc9c87)cc6c45)n3)c2)cc1] | 1-535 |
| 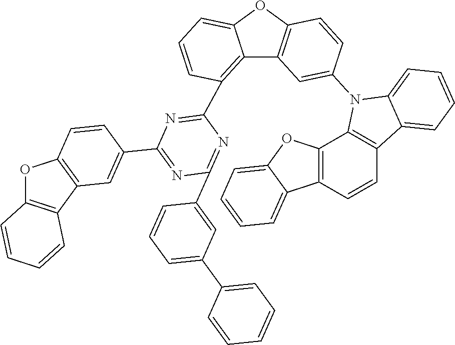 [SMILES: c1ccc(-c2cccc(-c3nc(-c4ccc5oc6ccccc6c5c4)nc(-c4cccc5oc6ccc(-n7c8ccccc8c8ccc9c%10ccccc%10oc9c87)cc6c45)n3)c2)cc1] | 1-536 |
| 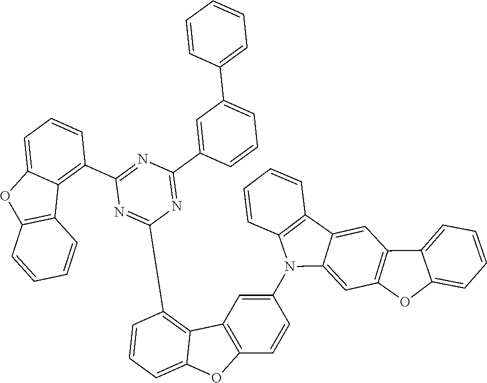 [SMILES: c1ccc(-c2cccc(-c3nc(-c4cccc5oc6ccccc6c45)nc(-c4cccc5oc6ccc(-n7c8ccccc8c8cc9c(cc87)oc7ccccc79)cc6c45)n3)c2)cc1] | 1-537 |
| 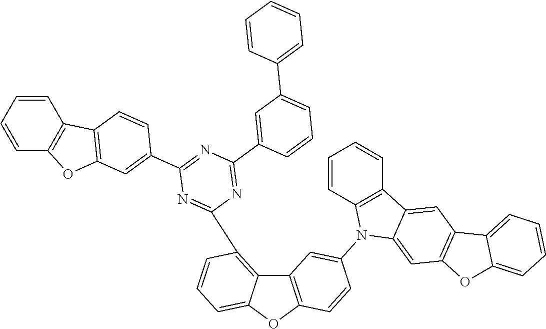 [SMILES: c1ccc(-c2cccc(-c3nc(-c4ccc5c(c4)oc4ccccc45)nc(-c4cccc5oc6ccc(-n7c8ccccc8c8cc9c(cc87)oc7ccccc79)cc6c45)n3)c2)cc1] | 1-538 |
| 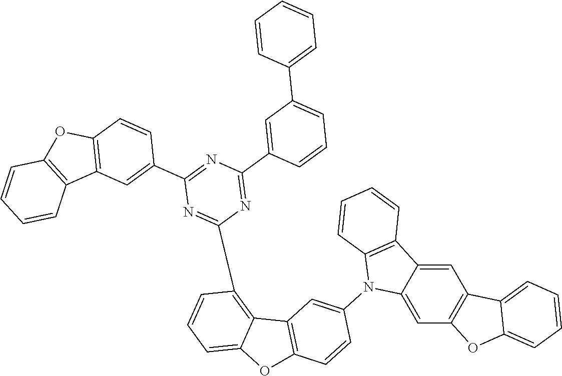 [SMILES: c1ccc(-c2cccc(-c3nc(-c4ccc5oc6ccccc6c5c4)nc(-c4cccc5oc6ccc(-n7c8ccccc8c8cc9c(cc87)oc7ccccc79)cc6c45)n3)c2)cc1] | 1-539 |
| 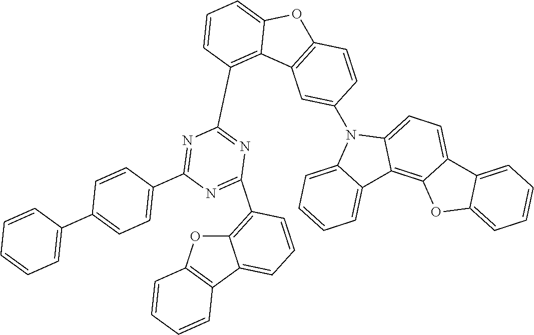 [SMILES: c1ccc(-c2ccc(-c3nc(-c4cccc5c4oc4ccccc45)nc(-c4cccc5oc6ccc(-n7c8ccccc8c8c9oc%10ccccc%10c9ccc87)cc6c45)n3)cc2)cc1] | 1-540 |
| 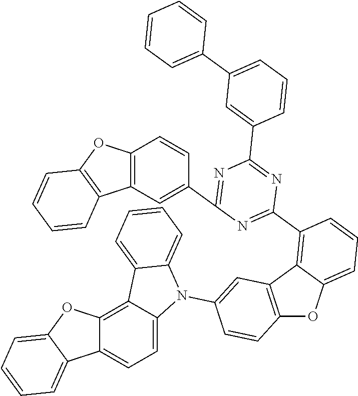 [SMILES: c1ccc(-c2cccc(-c3nc(-c4ccc5oc6ccccc6c5c4)nc(-c4cccc5oc6ccc(-n7c8ccccc8c8c9oc%10ccccc%10c9ccc87)cc6c45)n3)c2)cc1] | 1-541 |
| 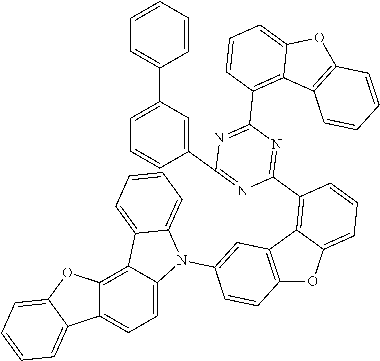 [SMILES: c1ccc(-c2cccc(-c3nc(-c4cccc5oc6ccccc6c45)nc(-c4cccc5oc6ccc(-n7c8ccccc8c8c9oc%10ccccc%10c9ccc87)cc6c45)n3)c2)cc1] | 1-542 |
| 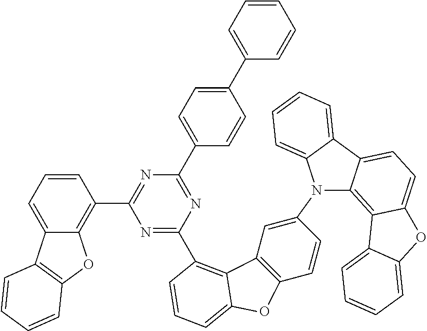 [SMILES: c1ccc(-c2ccc(-c3nc(-c4cccc5c4oc4ccccc45)nc(-c4cccc5oc6ccc(-n7c8ccccc8c8ccc9oc%10ccccc%10c9c87)cc6c45)n3)cc2)cc1] | 1-543 |
| 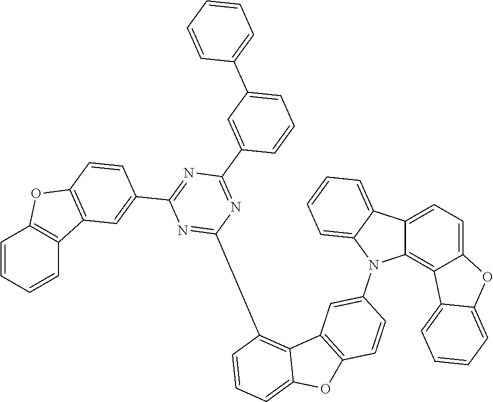 [SMILES: c1ccc(-c2cccc(-c3nc(-c4ccc5oc6ccccc6c5c4)nc(-c4cccc5oc6ccc(-n7c8ccccc8c8ccc9oc%10ccccc%10c9c87)cc6c45)n3)c2)cc1] | 1-544 |
| 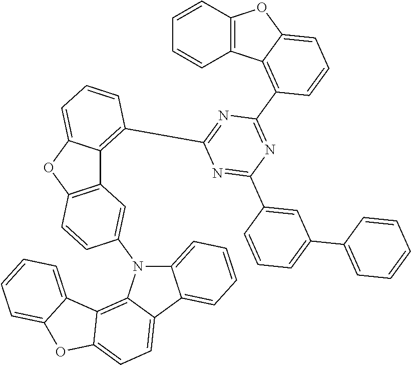 [SMILES: c1ccc(-c2cccc(-c3nc(-c4cccc5oc6ccccc6c45)nc(-c4cccc5oc6ccc(-n7c8ccccc8c8ccc9oc%10ccccc%10c9c87)cc6c45)n3)c2)cc1] | 1-545 |
| 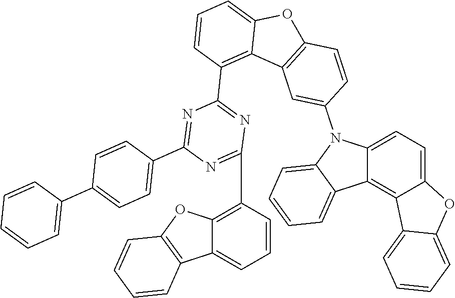 [SMILES: c1ccc(-c2ccc(-c3nc(-c4cccc5c4oc4ccccc45)nc(-c4cccc5oc6ccc(-n7c8ccccc8c8c9c(ccc87)oc7ccccc79)cc6c45)n3)cc2)cc1] | 1-546 |
| 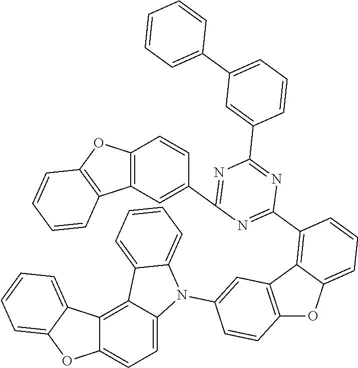 [SMILES: c1ccc(-c2cccc(-c3nc(-c4ccc5oc6ccccc6c5c4)nc(-c4cccc5oc6ccc(-n7c8ccccc8c8c9c(ccc87)oc7ccccc79)cc6c45)n3)c2)cc1] | 1-547 |
| 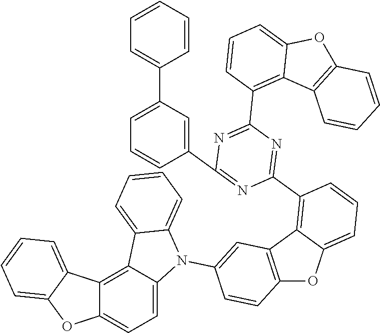 [SMILES: c1ccc(-c2cccc(-c3nc(-c4cccc5oc6ccccc6c45)nc(-c4cccc5oc6ccc(-n7c8ccccc8c8c9c(ccc87)oc7ccccc79)cc6c45)n3)c2)cc1] | 1-548 |
| 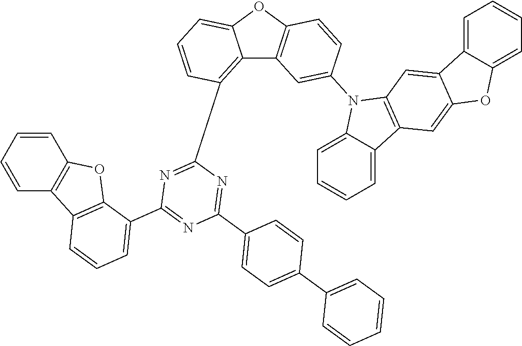 [SMILES: c1ccc(-c2ccc(-c3nc(-c4cccc5c4oc4ccccc45)nc(-c4cccc5oc6ccc(-n7c8ccccc8c8cc9oc%10ccccc%10c9cc87)cc6c45)n3)cc2)cc1] | 1-549 |
| 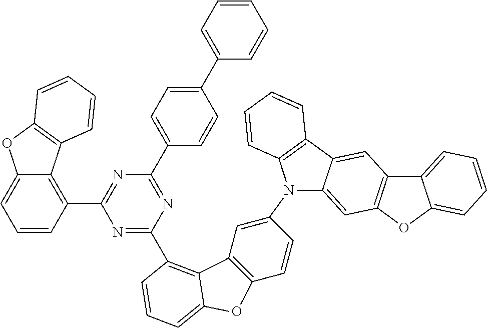 [SMILES: c1ccc(-c2ccc(-c3nc(-c4cccc5oc6ccccc6c45)nc(-c4cccc5oc6ccc(-n7c8ccccc8c8cc9c(cc87)oc7ccccc79)cc6c45)n3)cc2)cc1] | 1-550 |
| 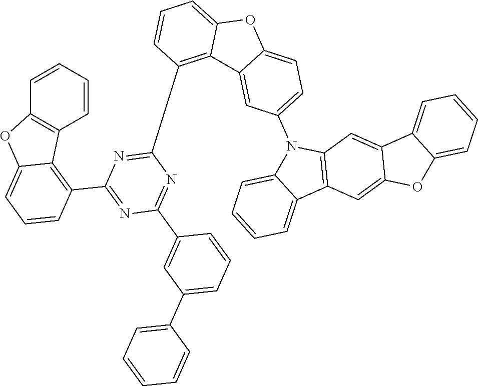 [SMILES: c1ccc(-c2cccc(-c3nc(-c4cccc5oc6ccccc6c45)nc(-c4cccc5oc6ccc(-n7c8ccccc8c8cc9oc%10ccccc%10c9cc87)cc6c45)n3)c2)cc1] | 1-551 |
| 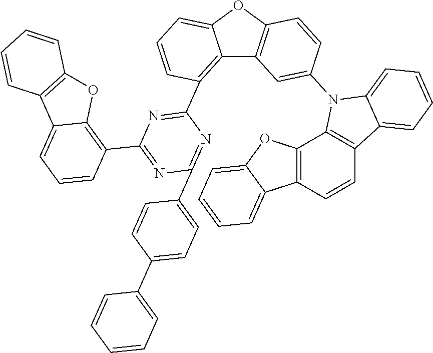 [SMILES: c1ccc(-c2ccc(-c3nc(-c4cccc5c4oc4ccccc45)nc(-c4cccc5oc6ccc(-n7c8ccccc8c8ccc9c%10ccccc%10oc9c87)cc6c45)n3)cc2)cc1] | 1-552 |
| 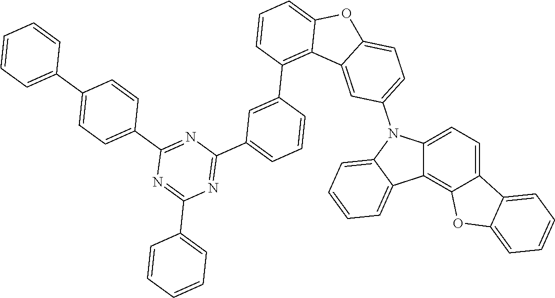 [SMILES: c1ccc(-c2ccc(-c3nc(-c4ccccc4)nc(-c4cccc(-c5cccc6oc7ccc(-n8c9ccccc9c9c%10oc%11ccccc%11c%10ccc98)cc7c56)c4)n3)cc2)cc1] | 1-553 |
| 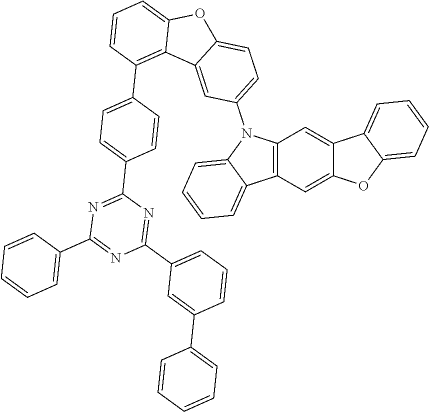 [SMILES: c1ccc(-c2cccc(-c3nc(-c4ccccc4)nc(-c4ccc(-c5cccc6oc7ccc(-n8c9ccccc9c9cc%10oc%11ccccc%11c%10cc98)cc7c56)cc4)n3)c2)cc1] | 1-554 |
| 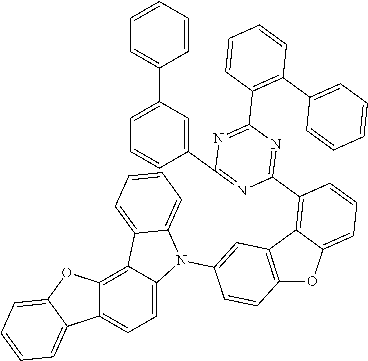 [SMILES: c1ccc(-c2cccc(-c3nc(-c4ccccc4-c4ccccc4)nc(-c4cccc5oc6ccc(-n7c8ccccc8c8c9oc%10ccccc%10c9ccc87)cc6c45)n3)c2)cc1] | 1-555 |
| 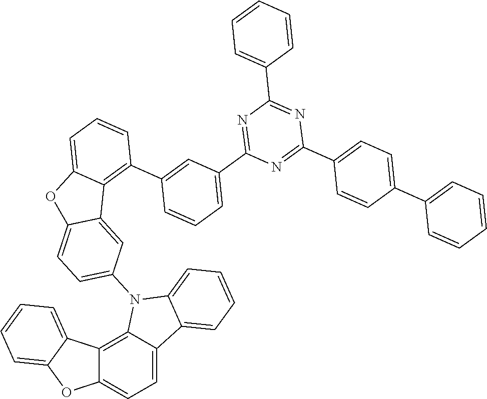 [SMILES: c1ccc(-c2ccc(-c3nc(-c4ccccc4)nc(-c4cccc(-c5cccc6oc7ccc(-n8c9ccccc9c9ccc%10oc%11ccccc%11c%10c98)cc7c56)c4)n3)cc2)cc1] | 1-556 |
| 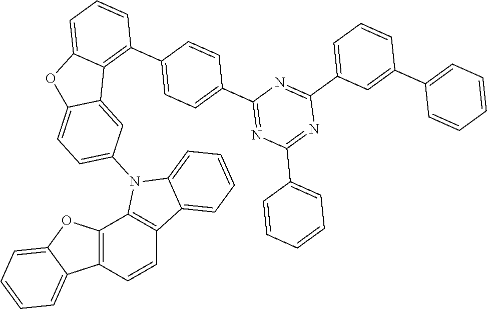 [SMILES: c1ccc(-c2cccc(-c3nc(-c4ccccc4)nc(-c4ccc(-c5cccc6oc7ccc(-n8c9ccccc9c9ccc%10c%11ccccc%11oc%10c98)cc7c56)cc4)n3)c2)cc1] | 1-557 |
| 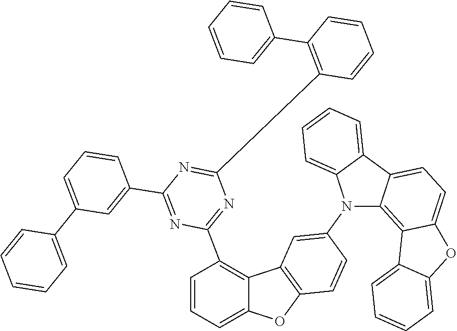 [SMILES: c1ccc(-c2cccc(-c3nc(-c4ccccc4-c4ccccc4)nc(-c4cccc5oc6ccc(-n7c8ccccc8c8ccc9oc%10ccccc%10c9c87)cc6c45)n3)c2)cc1] | 1-558 |
| 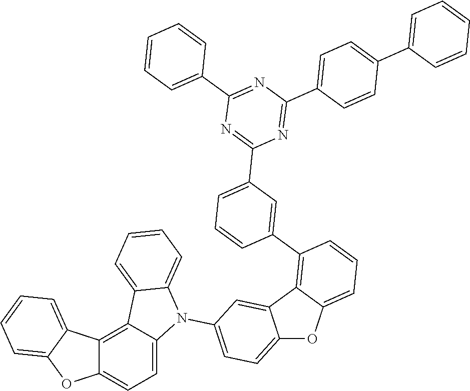 [SMILES: c1ccc(-c2ccc(-c3nc(-c4ccccc4)nc(-c4cccc(-c5cccc6oc7ccc(-n8c9ccccc9c9c%10c(ccc98)oc8ccccc8%10)cc7c56)c4)n3)cc2)cc1] | 1-559 |
| 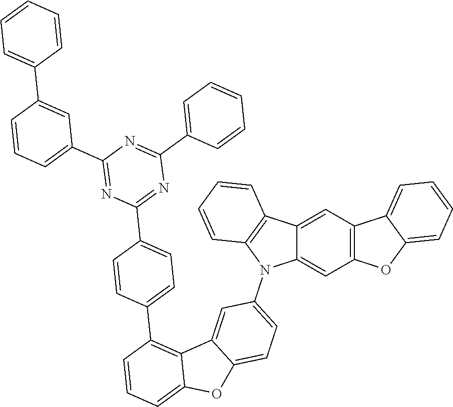 [SMILES: c1ccc(-c2cccc(-c3nc(-c4ccccc4)nc(-c4ccc(-c5cccc6oc7ccc(-n8c9ccccc9c9cc%10c(cc98)oc8ccccc8%10)cc7c56)cc4)n3)c2)cc1] | 1-560 |
| 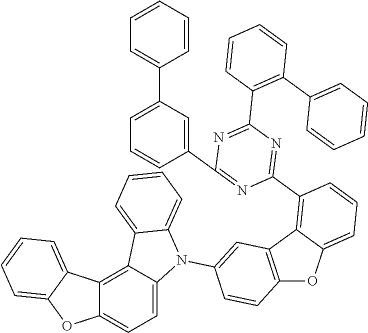 [SMILES: c1ccc(-c2cccc(-c3nc(-c4ccccc4-c4ccccc4)nc(-c4cccc5oc6ccc(-n7c8ccccc8c8c9c(ccc87)oc7ccccc79)cc6c45)n3)c2)cc1] | 1-561 |
| 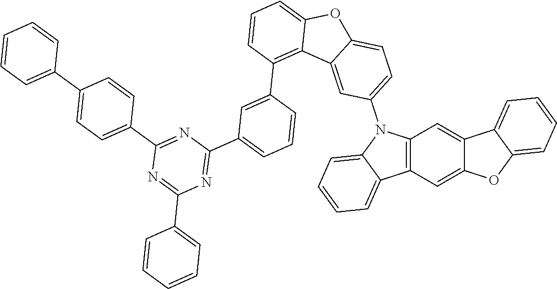 [SMILES: c1ccc(-c2ccc(-c3nc(-c4ccccc4)nc(-c4cccc(-c5cccc6oc7ccc(-n8c9ccccc9c9cc%10oc%11ccccc%11c%10cc98)cc7c56)c4)n3)cc2)cc1] | 1-562 |
| 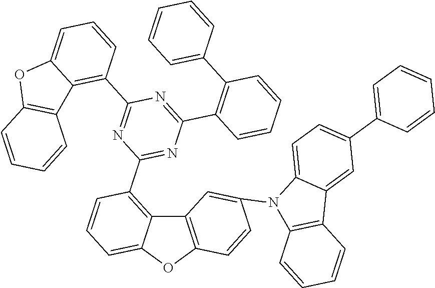 [SMILES: c1ccc(-c2ccc3c(c2)c2ccccc2n3-c2ccc3oc4cccc(-c5nc(-c6ccccc6-c6ccccc6)nc(-c6cccc7oc8ccccc8c67)n5)c4c3c2)cc1] | 1-563 |
| 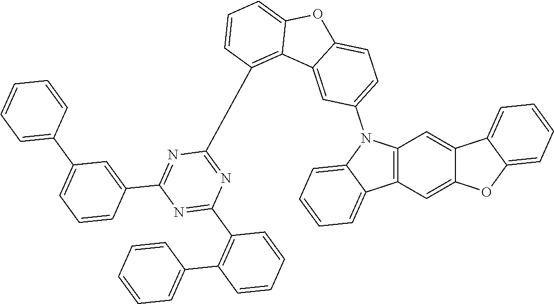 [SMILES: c1ccc(-c2cccc(-c3nc(-c4ccccc4-c4ccccc4)nc(-c4cccc5oc6ccc(-n7c8ccccc8c8cc9oc%10ccccc%10c9cc87)cc6c45)n3)c2)cc1] | 1-564 |
| 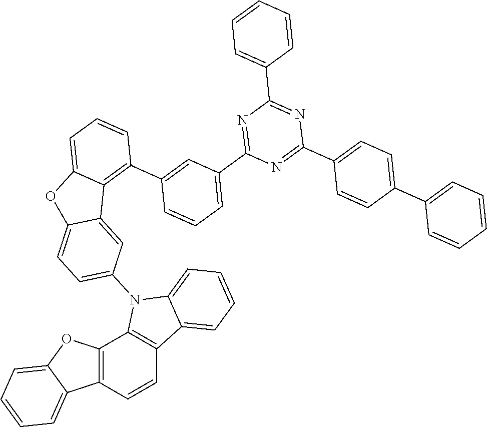 [SMILES: c1ccc(-c2ccc(-c3nc(-c4ccccc4)nc(-c4cccc(-c5cccc6oc7ccc(-n8c9ccccc9c9ccc%10c%11ccccc%11oc%10c98)cc7c56)c4)n3)cc2)cc1] | 1-565 |
| 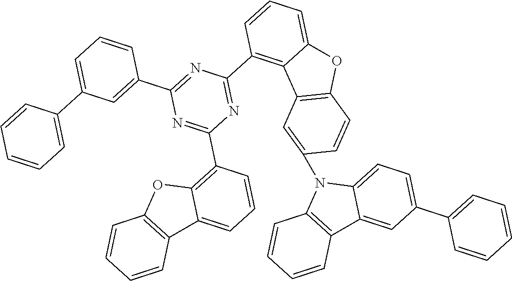 [SMILES: c1ccc(-c2cccc(-c3nc(-c4cccc5c4oc4ccccc45)nc(-c4cccc5oc6ccc(-n7c8ccccc8c8cc(-c9ccccc9)ccc87)cc6c45)n3)c2)cc1] | 1-566 |
| 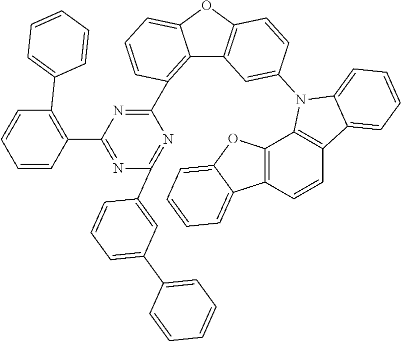 [SMILES: c1ccc(-c2cccc(-c3nc(-c4ccccc4-c4ccccc4)nc(-c4cccc5oc6ccc(-n7c8ccccc8c8ccc9c%10ccccc%10oc9c87)cc6c45)n3)c2)cc1] | 1-567 |
| 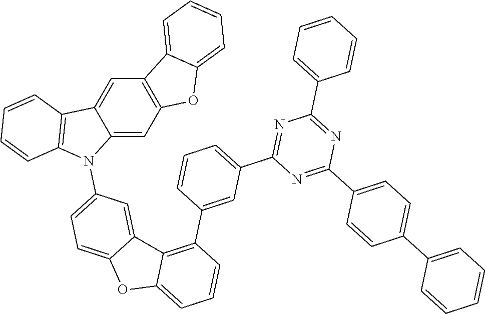 [SMILES: c1ccc(-c2ccc(-c3nc(-c4ccccc4)nc(-c4cccc(-c5cccc6oc7ccc(-n8c9ccccc9c9cc%10c(cc98)oc8ccccc8%10)cc7c56)c4)n3)cc2)cc1] | 1-568 |
| 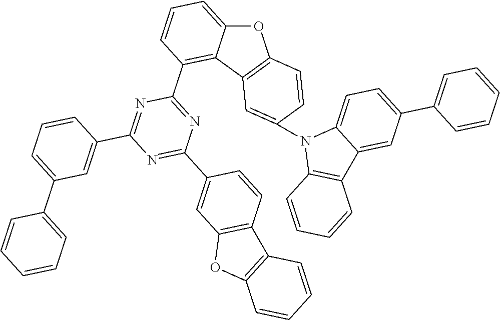 [SMILES: c1ccc(-c2cccc(-c3nc(-c4ccc5c(c4)oc4ccccc45)nc(-c4cccc5oc6ccc(-n7c8ccccc8c8cc(-c9ccccc9)ccc87)cc6c45)n3)c2)cc1] | 1-569 |
| 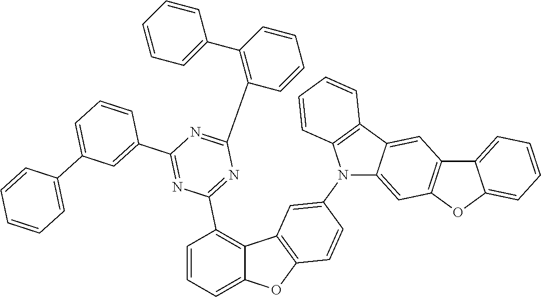 [SMILES: c1ccc(-c2cccc(-c3nc(-c4ccccc4-c4ccccc4)nc(-c4cccc5oc6ccc(-n7c8ccccc8c8cc9c(cc87)oc7ccccc79)cc6c45)n3)c2)cc1] | 1-570 |
| 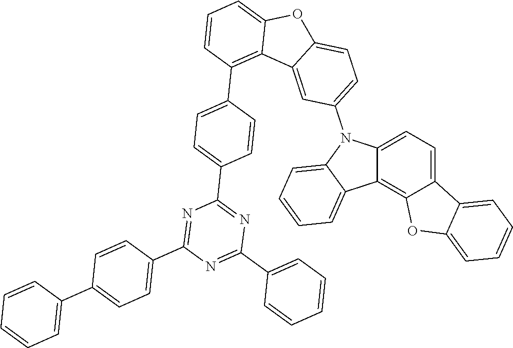 [SMILES: c1ccc(-c2ccc(-c3nc(-c4ccccc4)nc(-c4ccc(-c5cccc6oc7ccc(-n8c9ccccc9c9c%10oc%11ccccc%11c%10ccc98)cc7c56)cc4)n3)cc2)cc1] | 1-571 |
| 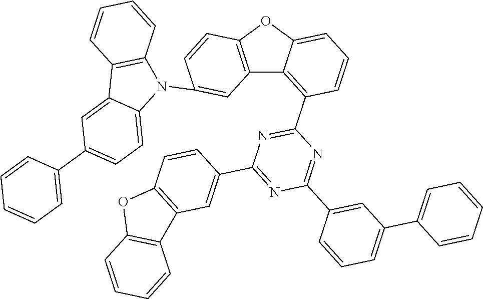 [SMILES: c1ccc(-c2cccc(-c3nc(-c4ccc5oc6ccccc6c5c4)nc(-c4cccc5oc6ccc(-n7c8ccccc8c8cc(-c9ccccc9)ccc87)cc6c45)n3)c2)cc1] | 1-572 |
| 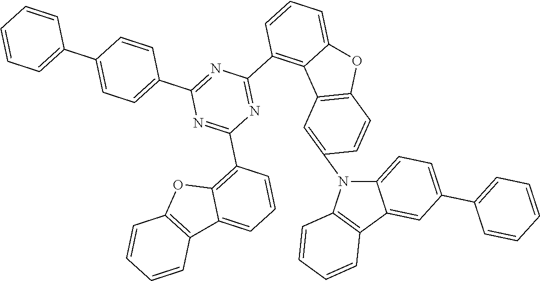 [SMILES: c1ccc(-c2ccc(-c3nc(-c4cccc5c4oc4ccccc45)nc(-c4cccc5oc6ccc(-n7c8ccccc8c8cc(-c9ccccc9)ccc87)cc6c45)n3)cc2)cc1] | 1-573 |
| 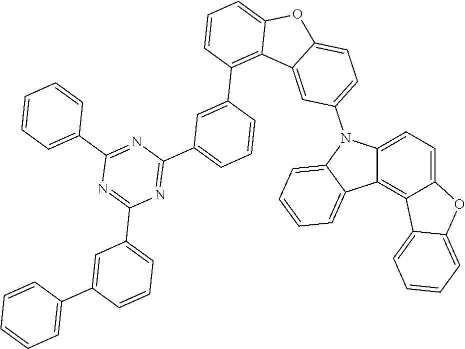 [SMILES: c1ccc(-c2cccc(-c3nc(-c4ccccc4)nc(-c4cccc(-c5cccc6oc7ccc(-n8c9ccccc9c9c%10c(ccc98)oc8ccccc8%10)cc7c56)c4)n3)c2)cc1] | 1-574 |
| 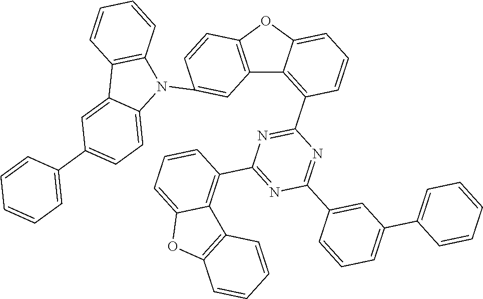 [SMILES: c1ccc(-c2cccc(-c3nc(-c4cccc5oc6ccccc6c45)nc(-c4cccc5oc6ccc(-n7c8ccccc8c8cc(-c9ccccc9)ccc87)cc6c45)n3)c2)cc1] | 1-575 |
| 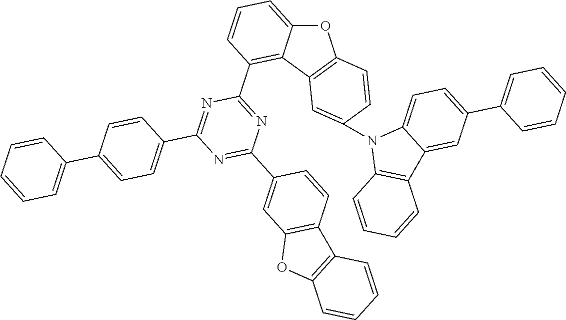 [SMILES: c1ccc(-c2ccc(-c3nc(-c4ccc5c(c4)oc4ccccc45)nc(-c4cccc5oc6ccc(-n7c8ccccc8c8cc(-c9ccccc9)ccc87)cc6c45)n3)cc2)cc1] | 1-576 |
| 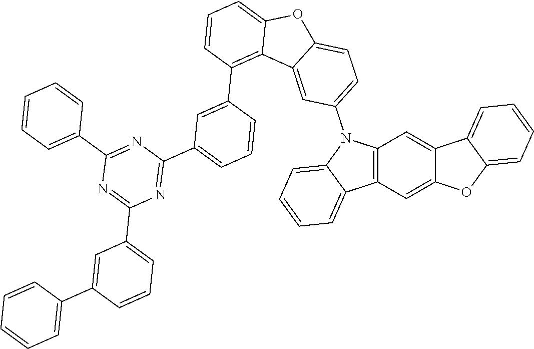 [SMILES: c1ccc(-c2cccc(-c3nc(-c4ccccc4)nc(-c4cccc(-c5cccc6oc7ccc(-n8c9ccccc9c9cc%10oc%11ccccc%11c%10cc98)cc7c56)c4)n3)c2)cc1] | 1-577 |
| 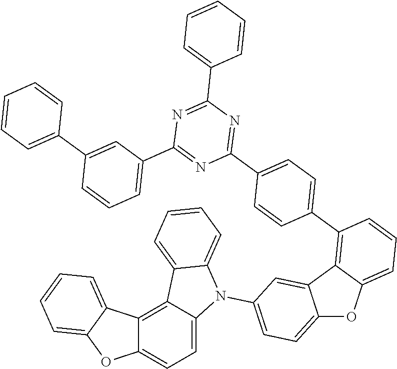 [SMILES: c1ccc(-c2cccc(-c3nc(-c4ccccc4)nc(-c4ccc(-c5cccc6oc7ccc(-n8c9ccccc9c9c%10c(ccc98)oc8ccccc8%10)cc7c56)cc4)n3)c2)cc1] | 1-578 |
| 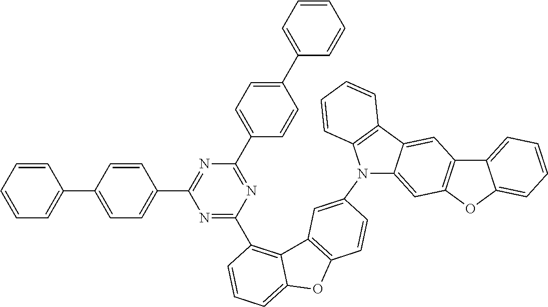 [SMILES: c1ccc(-c2ccc(-c3nc(-c4ccc(-c5ccccc5)cc4)nc(-c4cccc5oc6ccc(-n7c8ccccc8c8cc9c(cc87)oc7ccccc79)cc6c45)n3)cc2)cc1] | 1-579 |
| 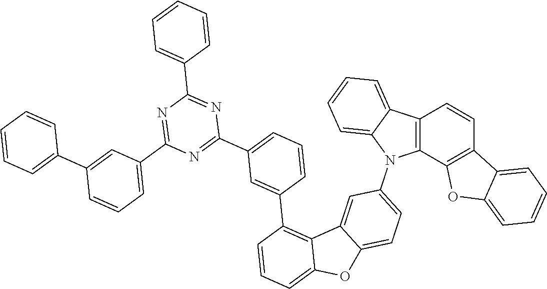 [SMILES: c1ccc(-c2cccc(-c3nc(-c4ccccc4)nc(-c4cccc(-c5cccc6oc7ccc(-n8c9ccccc9c9ccc%10c%11ccccc%11oc%10c98)cc7c56)c4)n3)c2)cc1] | 1-580 |
| 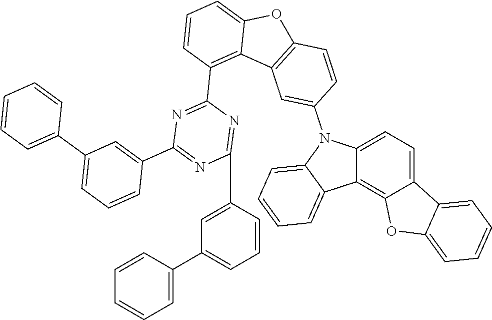 [SMILES: c1ccc(-c2cccc(-c3nc(-c4cccc(-c5ccccc5)c4)nc(-c4cccc5oc6ccc(-n7c8ccccc8c8c9oc%10ccccc%10c9ccc87)cc6c45)n3)c2)cc1] | 1-581 |
| 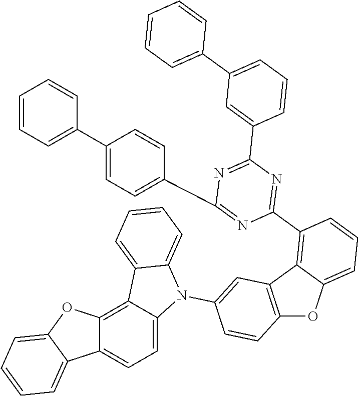 [SMILES: c1ccc(-c2ccc(-c3nc(-c4cccc(-c5ccccc5)c4)nc(-c4cccc5oc6ccc(-n7c8ccccc8c8c9oc%10ccccc%10c9ccc87)cc6c45)n3)cc2)cc1] | 1-582 |
| 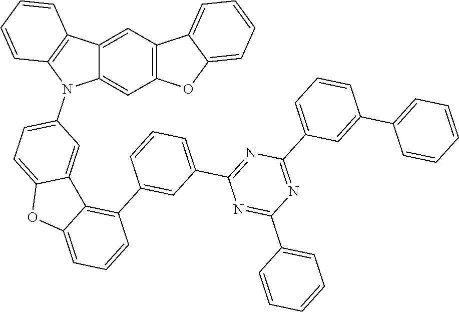 [SMILES: c1ccc(-c2cccc(-c3nc(-c4ccccc4)nc(-c4cccc(-c5cccc6oc7ccc(-n8c9ccccc9c9cc%10c(cc98)oc8ccccc8%10)cc7c56)c4)n3)c2)cc1] | 1-583 |
| 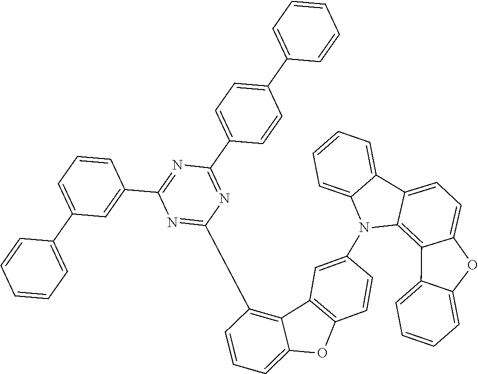 [SMILES: c1ccc(-c2ccc(-c3nc(-c4cccc(-c5ccccc5)c4)nc(-c4cccc5oc6ccc(-n7c8ccccc8c8ccc9oc%10ccccc%10c9c87)cc6c45)n3)cc2)cc1] | 1-584 |
| 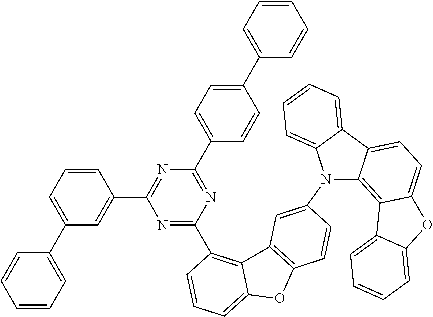 [SMILES: c1ccc(-c2ccc(-c3nc(-c4cccc(-c5ccccc5)c4)nc(-c4cccc5oc6ccc(-n7c8ccccc8c8ccc9oc%10ccccc%10c9c87)cc6c45)n3)cc2)cc1] | 1-585 |
| 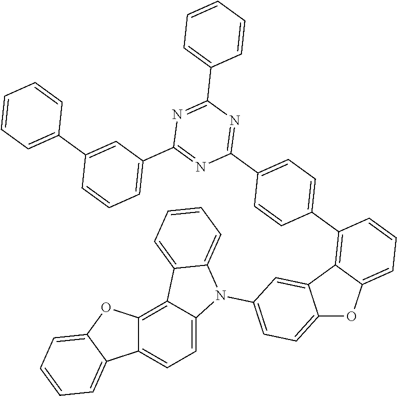 [SMILES: c1ccc(-c2cccc(-c3nc(-c4ccccc4)nc(-c4ccc(-c5cccc6oc7ccc(-n8c9ccccc9c9c%10oc%11ccccc%11c%10ccc98)cc7c56)cc4)n3)c2)cc1] | 1-586 |
| 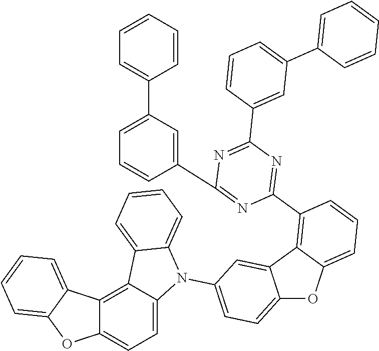 [SMILES: c1ccc(-c2cccc(-c3nc(-c4cccc(-c5ccccc5)c4)nc(-c4cccc5oc6ccc(-n7c8ccccc8c8c9c(ccc87)oc7ccccc79)cc6c45)n3)c2)cc1] | 1-587 |
| 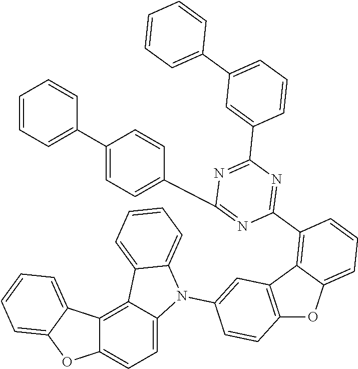 [SMILES: c1ccc(-c2ccc(-c3nc(-c4cccc(-c5ccccc5)c4)nc(-c4cccc5oc6ccc(-n7c8ccccc8c8c9c(ccc87)oc7ccccc79)cc6c45)n3)cc2)cc1] | 1-588 |
| 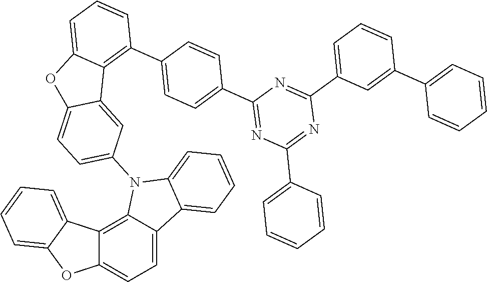 [SMILES: c1ccc(-c2cccc(-c3nc(-c4ccccc4)nc(-c4ccc(-c5cccc6oc7ccc(-n8c9ccccc9c9ccc%10oc%11ccccc%11c%10c98)cc7c56)cc4)n3)c2)cc1] | 1-589 |
| 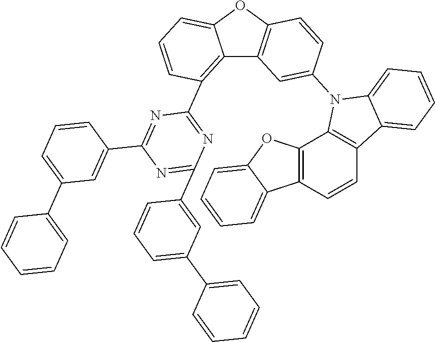 [SMILES: c1ccc(-c2cccc(-c3nc(-c4cccc(-c5ccccc5)c4)nc(-c4cccc5oc6ccc(-n7c8ccccc8c8ccc9c%10ccccc%10oc9c87)cc6c45)n3)c2)cc1] | 1-590 |
| 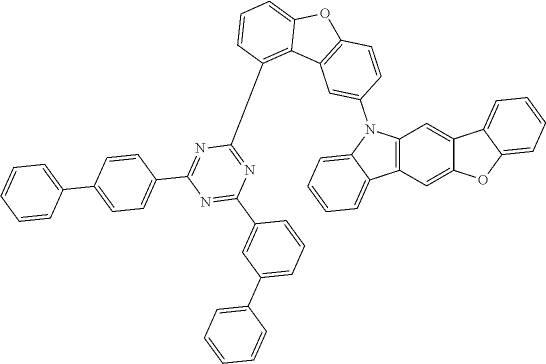 [SMILES: c1ccc(-c2ccc(-c3nc(-c4cccc(-c5ccccc5)c4)nc(-c4cccc5oc6ccc(-n7c8ccccc8c8cc9oc%10ccccc%10c9cc87)cc6c45)n3)cc2)cc1] | 1-591 |
| 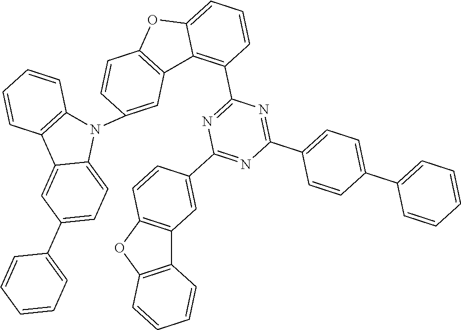 [SMILES: c1ccc(-c2ccc(-c3nc(-c4ccc5oc6ccccc6c5c4)nc(-c4cccc5oc6ccc(-n7c8ccccc8c8cc(-c9ccccc9)ccc87)cc6c45)n3)cc2)cc1] | 1-592 |
| 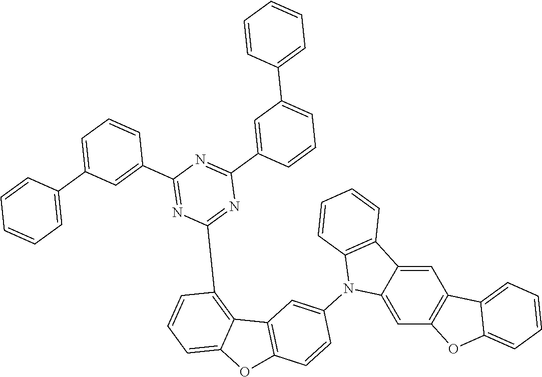 [SMILES: c1ccc(-c2cccc(-c3nc(-c4cccc(-c5ccccc5)c4)nc(-c4cccc5oc6ccc(-n7c8ccccc8c8cc9c(cc87)oc7ccccc79)cc6c45)n3)c2)cc1] | 1-593 |
| 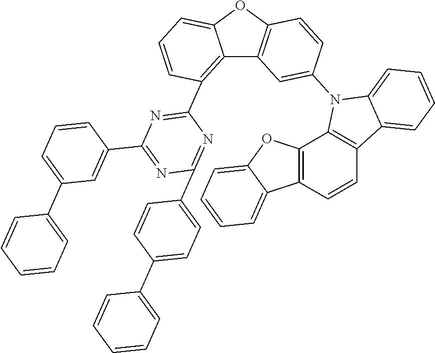 [SMILES: c1ccc(-c2ccc(-c3nc(-c4cccc(-c5ccccc5)c4)nc(-c4cccc5oc6ccc(-n7c8ccccc8c8ccc9c%10ccccc%10oc9c87)cc6c45)n3)cc2)cc1] | 1-594 |
| 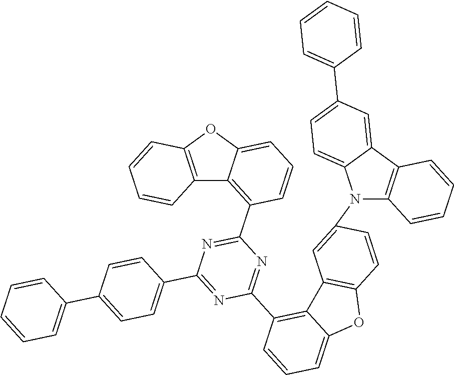 [SMILES: c1ccc(-c2ccc(-c3nc(-c4cccc5oc6ccccc6c45)nc(-c4cccc5oc6ccc(-n7c8ccccc8c8cc(-c9ccccc9)ccc87)cc6c45)n3)cc2)cc1] | 1-595 |
| 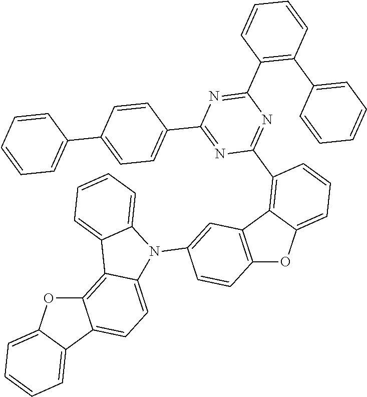 [SMILES: c1ccc(-c2ccc(-c3nc(-c4ccccc4-c4ccccc4)nc(-c4cccc5oc6ccc(-n7c8ccccc8c8c9oc%10ccccc%10c9ccc87)cc6c45)n3)cc2)cc1] | 1-596 |
| 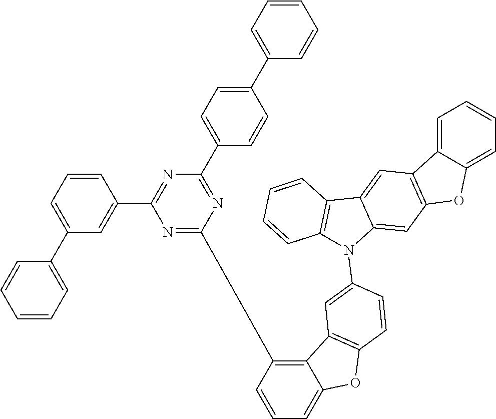 [SMILES: c1ccc(-c2ccc(-c3nc(-c4cccc(-c5ccccc5)c4)nc(-c4cccc5oc6ccc(-n7c8ccccc8c8cc9c(cc87)oc7ccccc79)cc6c45)n3)cc2)cc1] | 1-597 |
| 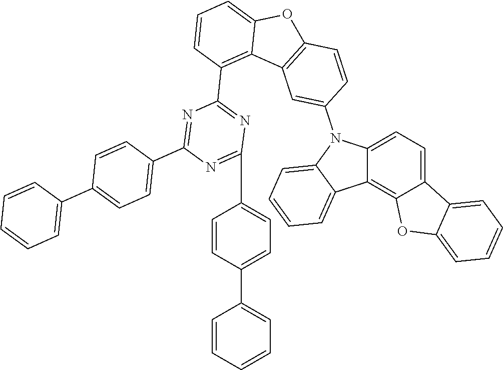 [SMILES: c1ccc(-c2ccc(-c3nc(-c4ccc(-c5ccccc5)cc4)nc(-c4cccc5oc6ccc(-n7c8ccccc8c8c9oc%10ccccc%10c9ccc87)cc6c45)n3)cc2)cc1] | 1-598 |
| 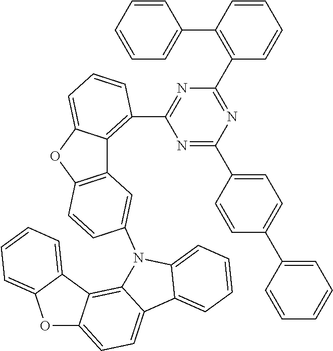 [SMILES: c1ccc(-c2ccc(-c3nc(-c4ccccc4-c4ccccc4)nc(-c4cccc5oc6ccc(-n7c8ccccc8c8ccc9oc%10ccccc%10c9c87)cc6c45)n3)cc2)cc1] | 1-599 |
| 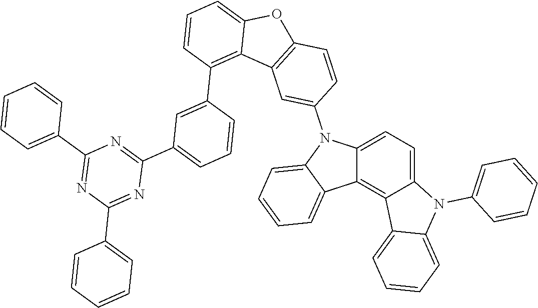 [SMILES: c1ccc(-c2nc(-c3ccccc3)nc(-c3cccc(-c4cccc5oc6ccc(-n7c8ccccc8c8c9c%10ccccc%10n(-c%10ccccc%10)c9ccc87)cc6c45)c3)n2)cc1] | 1-600 |
| 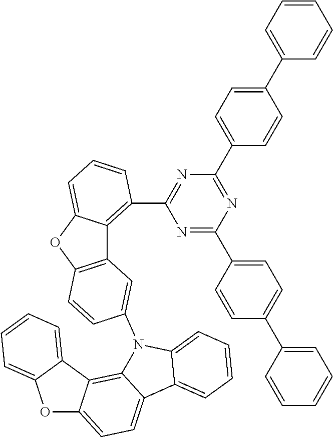 [SMILES: c1ccc(-c2ccc(-c3nc(-c4ccc(-c5ccccc5)cc4)nc(-c4cccc5oc6ccc(-n7c8ccccc8c8ccc9oc%10ccccc%10c9c87)cc6c45)n3)cc2)cc1] | 1-601 |
| 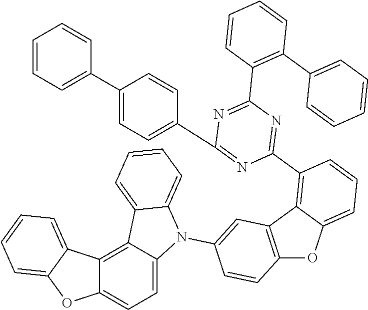 [SMILES: c1ccc(-c2ccc(-c3nc(-c4ccccc4-c4ccccc4)nc(-c4cccc5oc6ccc(-n7c8ccccc8c8c9c(ccc87)oc7ccccc79)cc6c45)n3)cc2)cc1] | 1-602 |
| 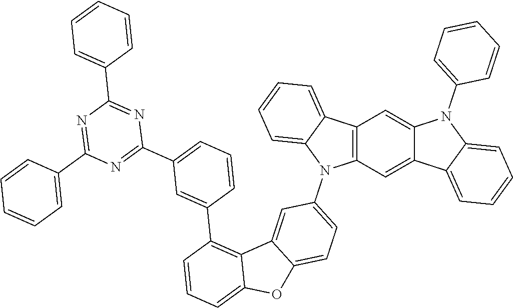 [SMILES: c1ccc(-c2nc(-c3ccccc3)nc(-c3cccc(-c4cccc5oc6ccc(-n7c8ccccc8c8cc9c(cc87)c7ccccc7n9-c7ccccc7)cc6c45)c3)n2)cc1] | 1-603 |
| 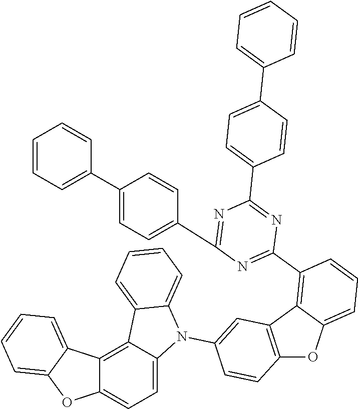 [SMILES: c1ccc(-c2ccc(-c3nc(-c4ccc(-c5ccccc5)cc4)nc(-c4cccc5oc6ccc(-n7c8ccccc8c8c9c(ccc87)oc7ccccc79)cc6c45)n3)cc2)cc1] | 1-604 |
| 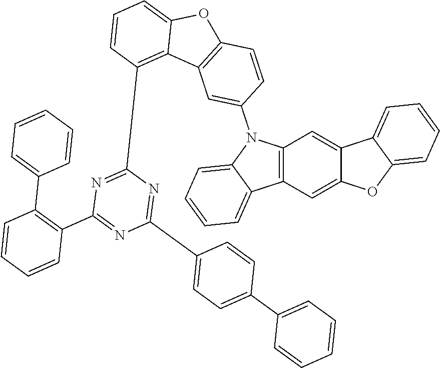 [SMILES: c1ccc(-c2ccc(-c3nc(-c4ccccc4-c4ccccc4)nc(-c4cccc5oc6ccc(-n7c8ccccc8c8cc9oc%10ccccc%10c9cc87)cc6c45)n3)cc2)cc1] | 1-605 |
| 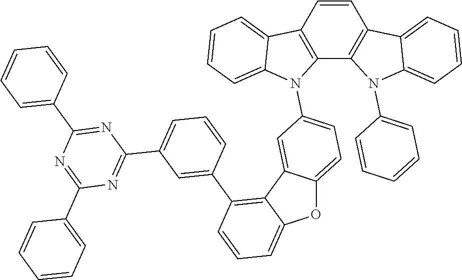 [SMILES: c1ccc(-c2nc(-c3ccccc3)nc(-c3cccc(-c4cccc5oc6ccc(-n7c8ccccc8c8ccc9c%10ccccc%10n(-c%10ccccc%10)c9c87)cc6c45)c3)n2)cc1] | 1-606 |
| 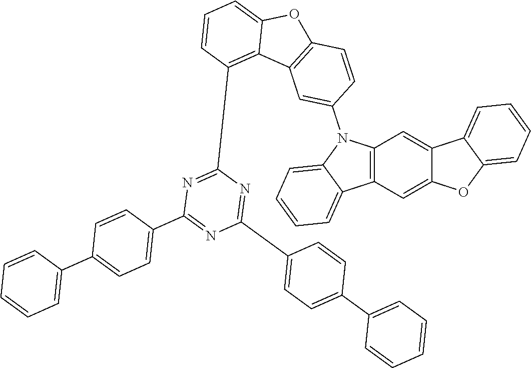 [SMILES: c1ccc(-c2ccc(-c3nc(-c4ccc(-c5ccccc5)cc4)nc(-c4cccc5oc6ccc(-n7c8ccccc8c8cc9oc%10ccccc%10c9cc87)cc6c45)n3)cc2)cc1] | 1-607 |
| 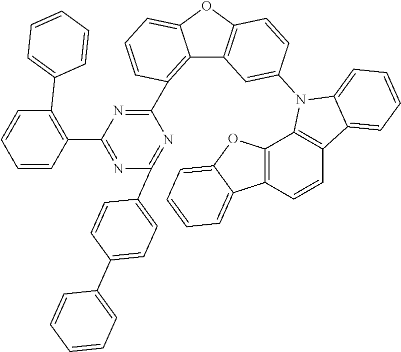 [SMILES: c1ccc(-c2ccc(-c3nc(-c4ccccc4-c4ccccc4)nc(-c4cccc5oc6ccc(-n7c8ccccc8c8ccc9c%10ccccc%10oc9c87)cc6c45)n3)cc2)cc1] | 1-608 |
| 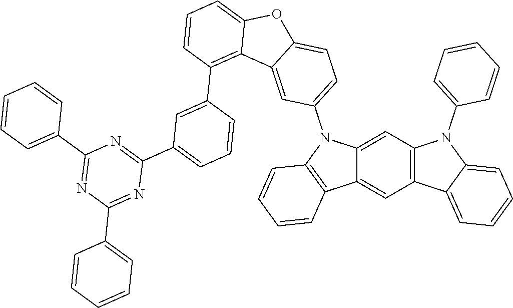 [SMILES: c1ccc(-c2nc(-c3ccccc3)nc(-c3cccc(-c4cccc5oc6ccc(-n7c8ccccc8c8cc9c%10ccccc%10n(-c%10ccccc%10)c9cc87)cc6c45)c3)n2)cc1] | 1-609 |
| 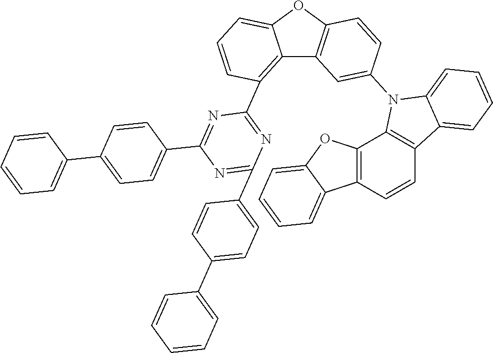 [SMILES: c1ccc(-c2ccc(-c3nc(-c4ccc(-c5ccccc5)cc4)nc(-c4cccc5oc6ccc(-n7c8ccccc8c8ccc9c%10ccccc%10oc9c87)cc6c45)n3)cc2)cc1] | 1-610 |
| 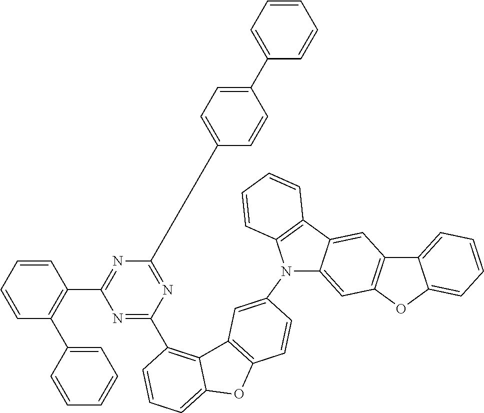 [SMILES: c1ccc(-c2ccc(-c3nc(-c4ccccc4-c4ccccc4)nc(-c4cccc5oc6ccc(-n7c8ccccc8c8cc9c(cc87)oc7ccccc79)cc6c45)n3)cc2)cc1] | 1-611 |
| 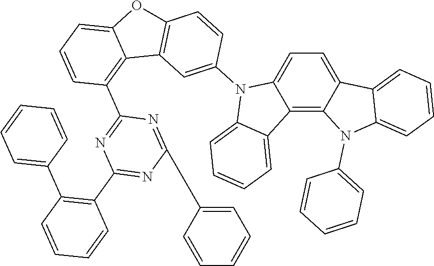 [SMILES: c1ccc(-c2nc(-c3ccccc3-c3ccccc3)nc(-c3cccc4oc5ccc(-n6c7ccccc7c7c6ccc6c8ccccc8n(-c8ccccc8)c67)cc5c34)n2)cc1] | 1-612 |
| 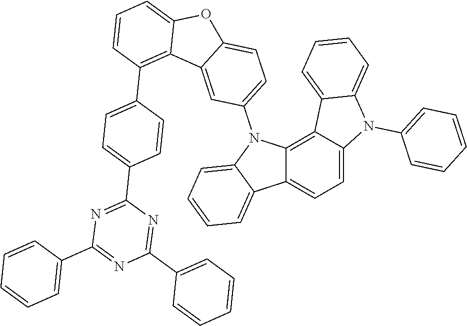 [SMILES: c1ccc(-c2nc(-c3ccccc3)nc(-c3ccc(-c4cccc5oc6ccc(-n7c8ccccc8c8ccc9c(c%10ccccc%10n9-c9ccccc9)c87)cc6c45)cc3)n2)cc1] | 1-613 |
| 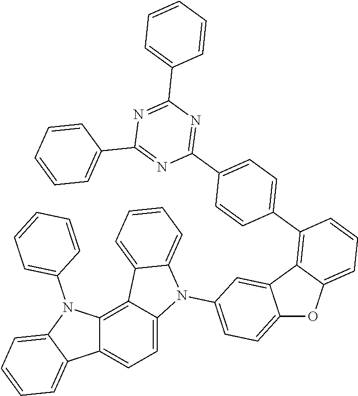 [SMILES: c1ccc(-c2nc(-c3ccccc3)nc(-c3ccc(-c4cccc5oc6ccc(-n7c8ccccc8c8c7ccc7c9ccccc9n(-c9ccccc9)c78)cc6c45)cc3)n2)cc1] | 1-614 |
| 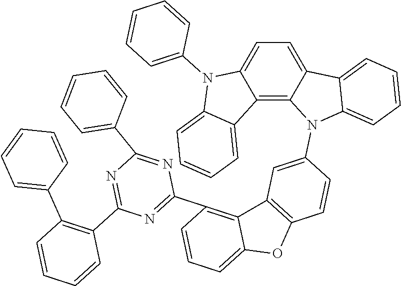 [SMILES: c1ccc(-c2nc(-c3ccccc3-c3ccccc3)nc(-c3cccc4oc5ccc(-n6c7ccccc7c7ccc8c(c9ccccc9n8-c8ccccc8)c76)cc5c34)n2)cc1] | 1-615 |
| 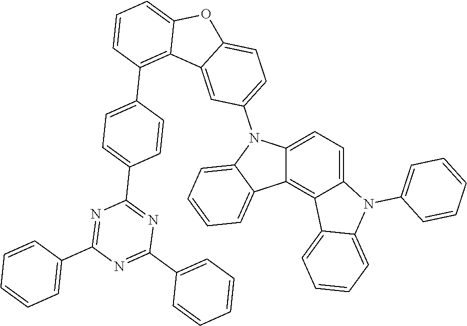 [SMILES: c1ccc(-c2nc(-c3ccccc3)nc(-c3ccc(-c4cccc5oc6ccc(-n7c8ccccc8c8c9c%10ccccc%10n(-c%10ccccc%10)c9ccc87)cc6c45)cc3)n2)cc1] | 1-616 |
| 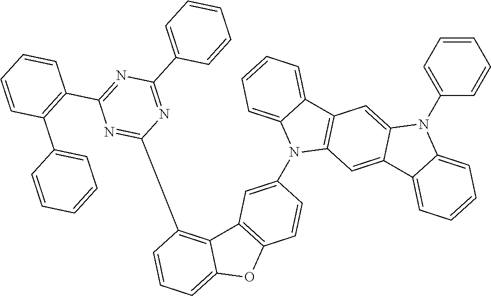 [SMILES: c1ccc(-c2nc(-c3ccccc3-c3ccccc3)nc(-c3cccc4oc5ccc(-n6c7ccccc7c7cc8c(cc76)c6ccccc6n8-c6ccccc6)cc5c34)n2)cc1] | 1-617 |
| 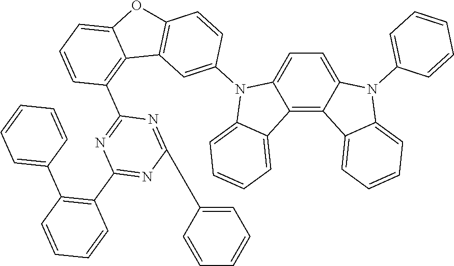 [SMILES: c1ccc(-c2nc(-c3ccccc3-c3ccccc3)nc(-c3cccc4oc5ccc(-n6c7ccccc7c7c8c9ccccc9n(-c9ccccc9)c8ccc76)cc5c34)n2)cc1] | 1-618 |
| 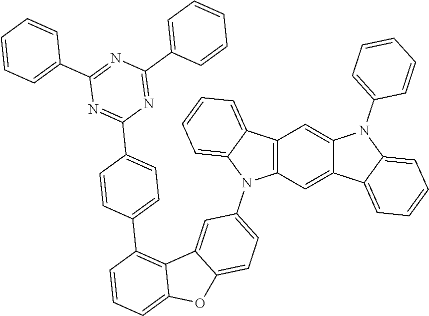 [SMILES: c1ccc(-c2nc(-c3ccccc3)nc(-c3ccc(-c4cccc5oc6ccc(-n7c8ccccc8c8cc9c(cc87)c7ccccc7n9-c7ccccc7)cc6c45)cc3)n2)cc1] | 1-619 |
| 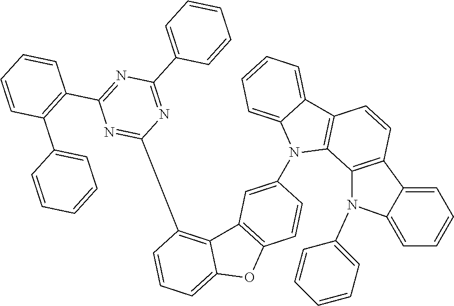 [SMILES: c1ccc(-c2nc(-c3ccccc3-c3ccccc3)nc(-c3cccc4oc5ccc(-n6c7ccccc7c7ccc8c9ccccc9n(-c9ccccc9)c8c76)cc5c34)n2)cc1] | 1-620 |
| 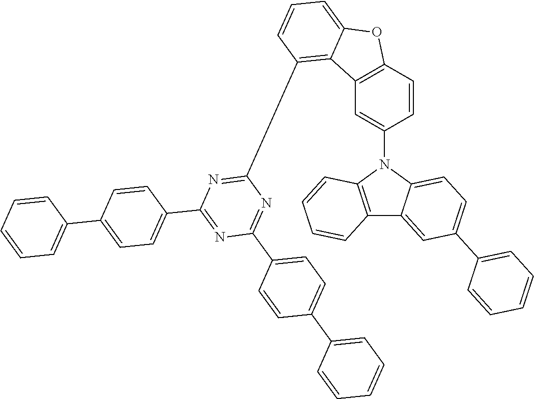 [SMILES: c1ccc(-c2ccc(-c3nc(-c4ccc(-c5ccccc5)cc4)nc(-c4cccc5oc6ccc(-n7c8ccccc8c8cc(-c9ccccc9)ccc87)cc6c45)n3)cc2)cc1] | 1-621 |
| 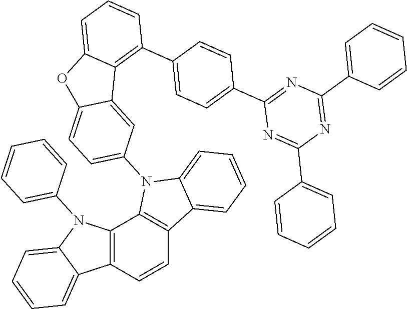 [SMILES: c1ccc(-c2nc(-c3ccccc3)nc(-c3ccc(-c4cccc5oc6ccc(-n7c8ccccc8c8ccc9c%10ccccc%10n(-c%10ccccc%10)c9c87)cc6c45)cc3)n2)cc1] | 1-622 |
| 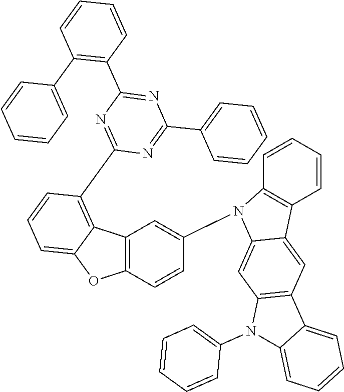 [SMILES: c1ccc(-c2nc(-c3ccccc3-c3ccccc3)nc(-c3cccc4oc5ccc(-n6c7ccccc7c7cc8c9ccccc9n(-c9ccccc9)c8cc76)cc5c34)n2)cc1] | 1-623 |
| 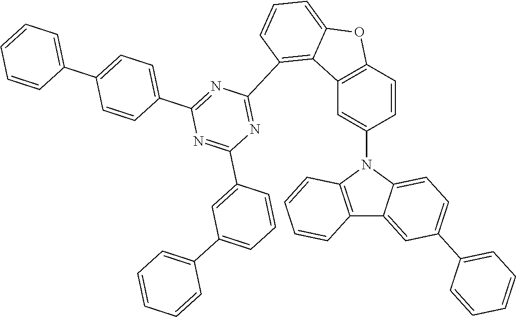 [SMILES: c1ccc(-c2ccc(-c3nc(-c4cccc(-c5ccccc5)c4)nc(-c4cccc5oc6ccc(-n7c8ccccc8c8cc(-c9ccccc9)ccc87)cc6c45)n3)cc2)cc1] | 1-624 |
| 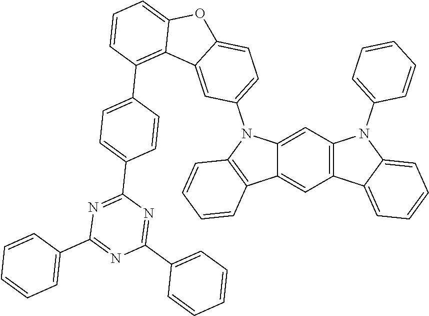 [SMILES: c1ccc(-c2nc(-c3ccccc3)nc(-c3ccc(-c4cccc5oc6ccc(-n7c8ccccc8c8cc9c%10ccccc%10n(-c%10ccccc%10)c9cc87)cc6c45)cc3)n2)cc1] | 1-625 |
| 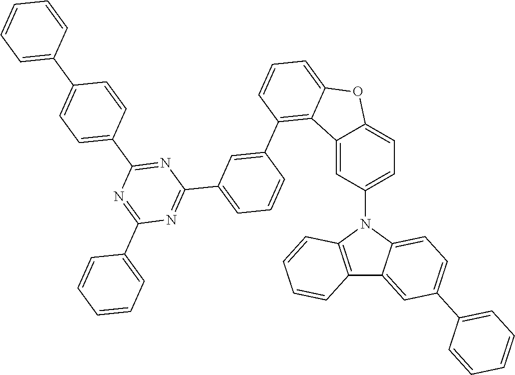 [SMILES: c1ccc(-c2ccc(-c3nc(-c4ccccc4)nc(-c4cccc(-c5cccc6oc7ccc(-n8c9ccccc9c9cc(-c%10ccccc%10)ccc98)cc7c56)c4)n3)cc2)cc1] | 1-626 |
| 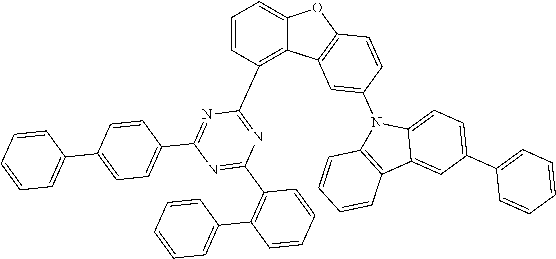 [SMILES: c1ccc(-c2ccc(-c3nc(-c4ccccc4-c4ccccc4)nc(-c4cccc5oc6ccc(-n7c8ccccc8c8cc(-c9ccccc9)ccc87)cc6c45)n3)cc2)cc1] | 1-627 |
| 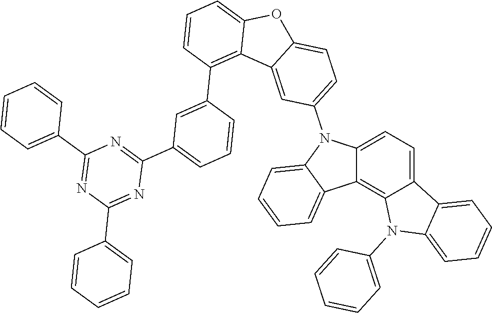 [SMILES: c1ccc(-c2nc(-c3ccccc3)nc(-c3cccc(-c4cccc5oc6ccc(-n7c8ccccc8c8c7ccc7c9ccccc9n(-c9ccccc9)c78)cc6c45)c3)n2)cc1] | 1-628 |
| 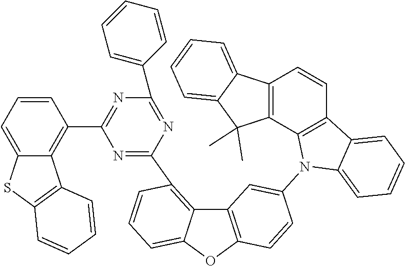 [SMILES: CC1(C)c2ccccc2-c2ccc3c4ccccc4n(-c4ccc5oc6cccc(-c7nc(-c8ccccc8)nc(-c8cccc9sc%10ccccc%10c89)n7)c6c5c4)c3c21] | 1-629 |
| 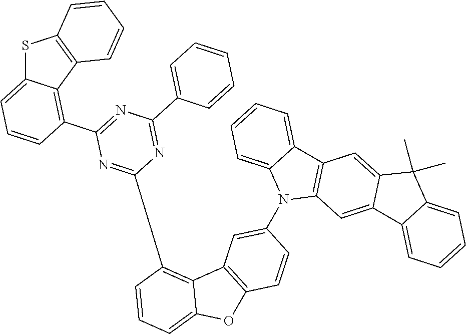 [SMILES: CC1(C)c2ccccc2-c2cc3c(cc21)c1ccccc1n3-c1ccc2oc3cccc(-c4nc(-c5ccccc5)nc(-c5cccc6sc7ccccc7c56)n4)c3c2c1] | 1-630 |
| 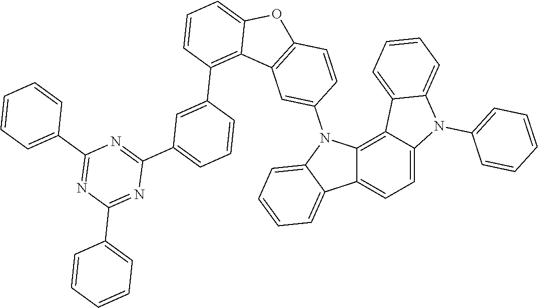 [SMILES: c1ccc(-c2nc(-c3ccccc3)nc(-c3cccc(-c4cccc5oc6ccc(-n7c8ccccc8c8ccc9c(c%10ccccc%10n9-c9ccccc9)c87)cc6c45)c3)n2)cc1] | 1-631 |
| 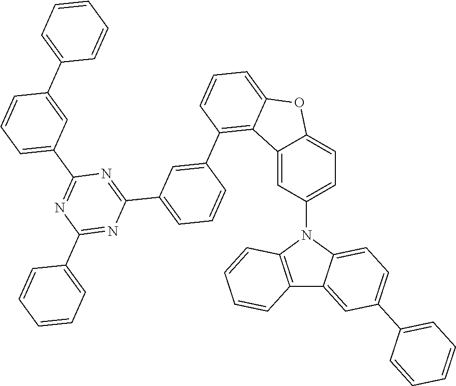 [SMILES: c1ccc(-c2cccc(-c3nc(-c4ccccc4)nc(-c4cccc(-c5cccc6oc7ccc(-n8c9ccccc9c9cc(-c%10ccccc%10)ccc98)cc7c56)c4)n3)c2)cc1] | 1-632 |
| 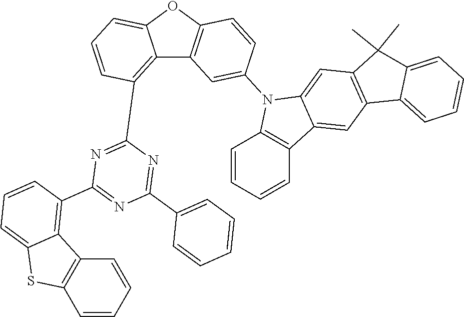 [SMILES: CC1(C)c2ccccc2-c2cc3c4ccccc4n(-c4ccc5oc6cccc(-c7nc(-c8ccccc8)nc(-c8cccc9sc%10ccccc%10c89)n7)c6c5c4)c3cc21] | 1-633 |
| 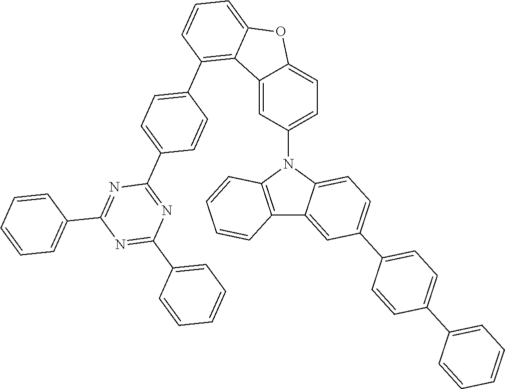 [SMILES: c1ccc(-c2ccc(-c3ccc4c(c3)c3ccccc3n4-c3ccc4oc5cccc(-c6ccc(-c7nc(-c8ccccc8)nc(-c8ccccc8)n7)cc6)c5c4c3)cc2)cc1] | 1-634 |
| 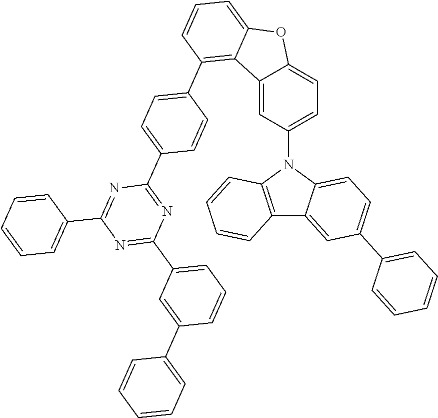 [SMILES: c1ccc(-c2cccc(-c3nc(-c4ccccc4)nc(-c4ccc(-c5cccc6oc7ccc(-n8c9ccccc9c9cc(-c%10ccccc%10)ccc98)cc7c56)cc4)n3)c2)cc1] | 1-635 |
| 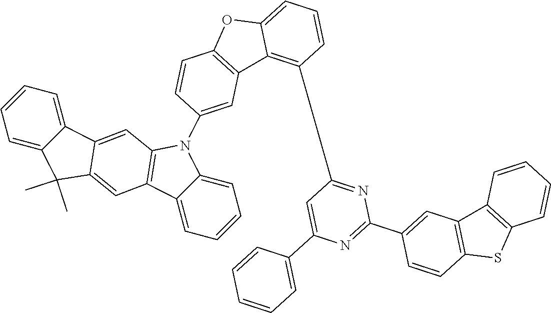 [SMILES: CC1(C)c2ccccc2-c2cc3c(cc21)c1ccccc1n3-c1ccc2oc3cccc(-c4cc(-c5ccccc5)nc(-c5ccc6sc7ccccc7c6c5)n4)c3c2c1] | 1-636 |
| 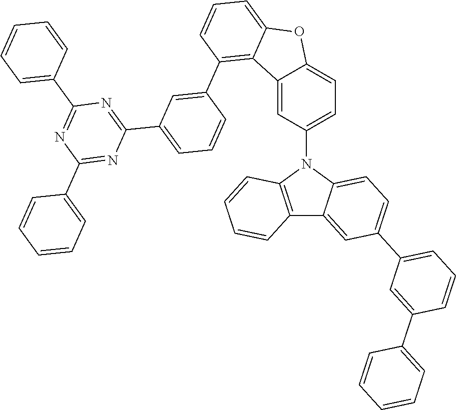 [SMILES: c1ccc(-c2cccc(-c3ccc4c(c3)c3ccccc3n4-c3ccc4oc5cccc(-c6cccc(-c7nc(-c8ccccc8)nc(-c8ccccc8)n7)c6)c5c4c3)c2)cc1] | 1-637 |
| 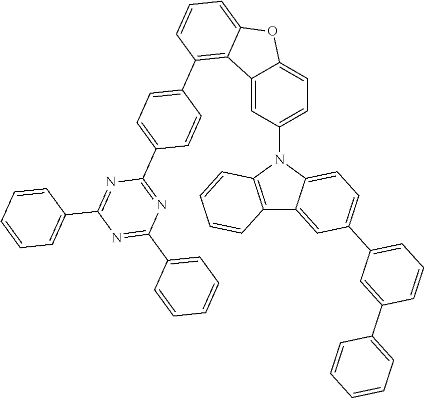 [SMILES: c1ccc(-c2cccc(-c3ccc4c(c3)c3ccccc3n4-c3ccc4oc5cccc(-c6ccc(-c7nc(-c8ccccc8)nc(-c8ccccc8)n7)cc6)c5c4c3)c2)cc1] | 1-638 |
| 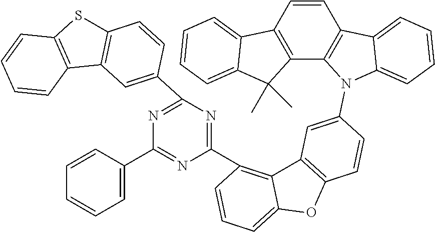 [SMILES: CC1(C)c2ccccc2-c2ccc3c4ccccc4n(-c4ccc5oc6cccc(-c7nc(-c8ccccc8)nc(-c8ccc9sc%10ccccc%10c9c8)n7)c6c5c4)c3c21] | 1-639 |
| 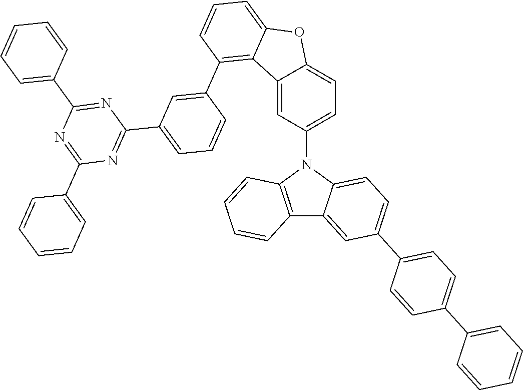 [SMILES: c1ccc(-c2ccc(-c3ccc4c(c3)c3ccccc3n4-c3ccc4oc5cccc(-c6cccc(-c7nc(-c8ccccc8)nc(-c8ccccc8)n7)c6)c5c4c3)cc2)cc1] | 1-640 |
| 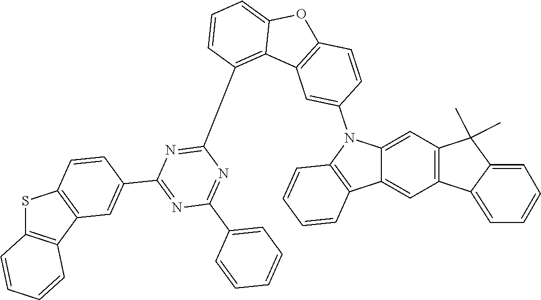 [SMILES: CC1(C)c2ccccc2-c2cc3c4ccccc4n(-c4ccc5oc6cccc(-c7nc(-c8ccccc8)nc(-c8ccc9sc%10ccccc%10c9c8)n7)c6c5c4)c3cc21] | 1-641 |
| 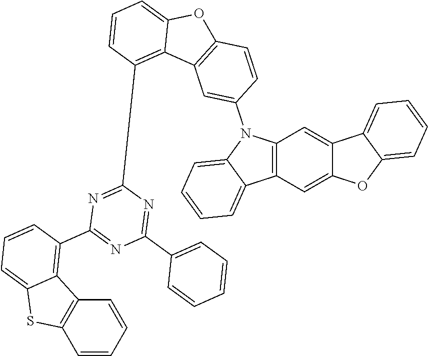 [SMILES: c1ccc(-c2nc(-c3cccc4oc5ccc(-n6c7ccccc7c7cc8oc9ccccc9c8cc76)cc5c34)nc(-c3cccc4sc5ccccc5c34)n2)cc1] | 1-642 |
| 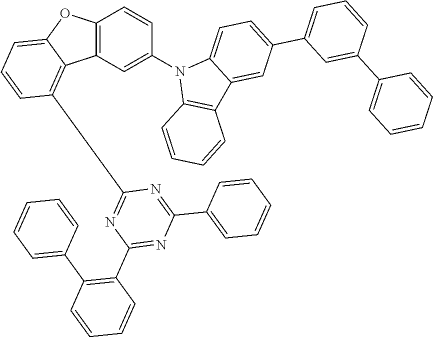 [SMILES: c1ccc(-c2cccc(-c3ccc4c(c3)c3ccccc3n4-c3ccc4oc5cccc(-c6nc(-c7ccccc7)nc(-c7ccccc7-c7ccccc7)n6)c5c4c3)c2)cc1] | 1-643 |
| 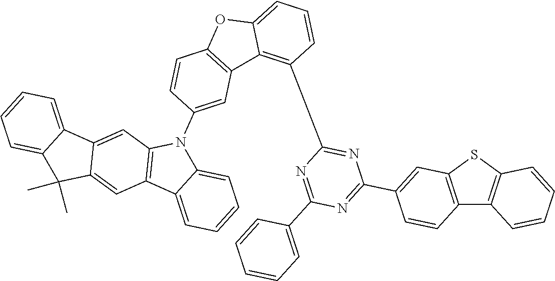 [SMILES: CC1(C)c2ccccc2-c2cc3c(cc21)c1ccccc1n3-c1ccc2oc3cccc(-c4nc(-c5ccccc5)nc(-c5ccc6c(c5)sc5ccccc56)n4)c3c2c1] | 1-644 |
| 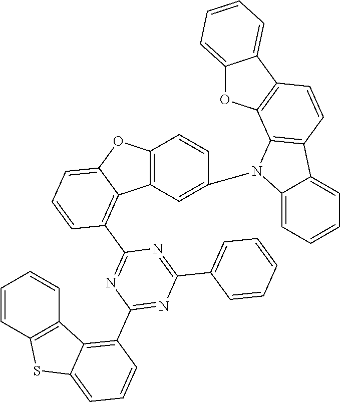 [SMILES: c1ccc(-c2nc(-c3cccc4oc5ccc(-n6c7ccccc7c7ccc8c9ccccc9oc8c76)cc5c34)nc(-c3cccc4sc5ccccc5c34)n2)cc1] | 1-645 |
| 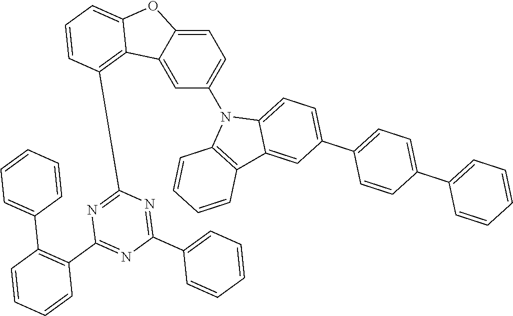 [SMILES: c1ccc(-c2ccc(-c3ccc4c(c3)c3ccccc3n4-c3ccc4oc5cccc(-c6nc(-c7ccccc7)nc(-c7ccccc7-c7ccccc7)n6)c5c4c3)cc2)cc1] | 1-646 |
| 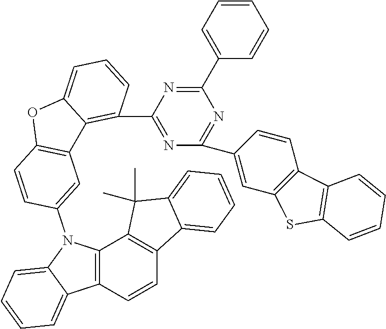 [SMILES: CC1(C)c2ccccc2-c2ccc3c4ccccc4n(-c4ccc5oc6cccc(-c7nc(-c8ccccc8)nc(-c8ccc9c(c8)sc8ccccc89)n7)c6c5c4)c3c21] | 1-647 |
| 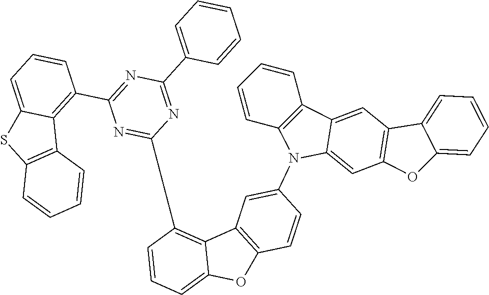 [SMILES: c1ccc(-c2nc(-c3cccc4oc5ccc(-n6c7ccccc7c7cc8c(cc76)oc6ccccc68)cc5c34)nc(-c3cccc4sc5ccccc5c34)n2)cc1] | 1-648 |
| 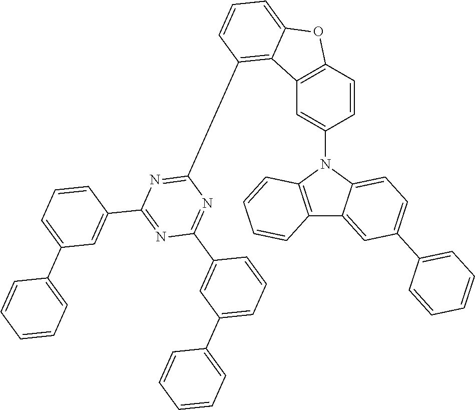 [SMILES: c1ccc(-c2cccc(-c3nc(-c4cccc(-c5ccccc5)c4)nc(-c4cccc5oc6ccc(-n7c8ccccc8c8cc(-c9ccccc9)ccc87)cc6c45)n3)c2)cc1] | 1-649 |
| 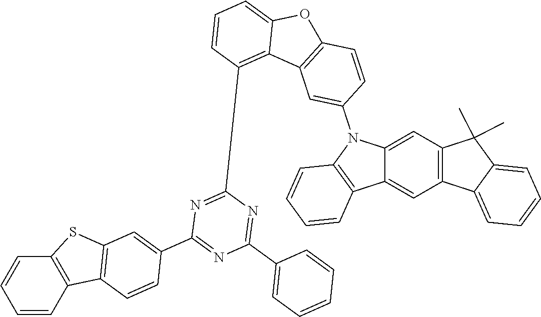 [SMILES: CC1(C)c2ccccc2-c2cc3c4ccccc4n(-c4ccc5oc6cccc(-c7nc(-c8ccccc8)nc(-c8ccc9c(c8)sc8ccccc89)n7)c6c5c4)c3cc21] | 1-650 |
| 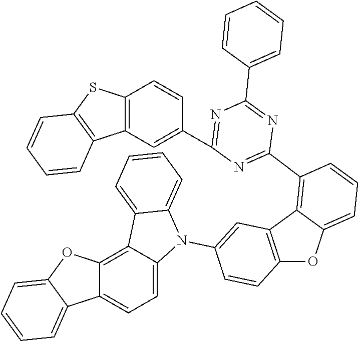 [SMILES: c1ccc(-c2nc(-c3ccc4sc5ccccc5c4c3)nc(-c3cccc4oc5ccc(-n6c7ccccc7c7c8oc9ccccc9c8ccc76)cc5c34)n2)cc1] | 1-651 |
| 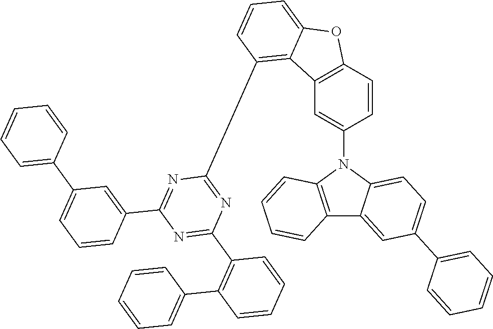 [SMILES: c1ccc(-c2cccc(-c3nc(-c4ccccc4-c4ccccc4)nc(-c4cccc5oc6ccc(-n7c8ccccc8c8cc(-c9ccccc9)ccc87)cc6c45)n3)c2)cc1] | 1-652 |
| 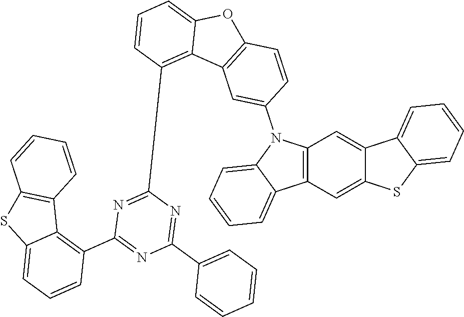 [SMILES: c1ccc(-c2nc(-c3cccc4oc5ccc(-n6c7ccccc7c7cc8sc9ccccc9c8cc76)cc5c34)nc(-c3cccc4sc5ccccc5c34)n2)cc1] | 1-653 |
| 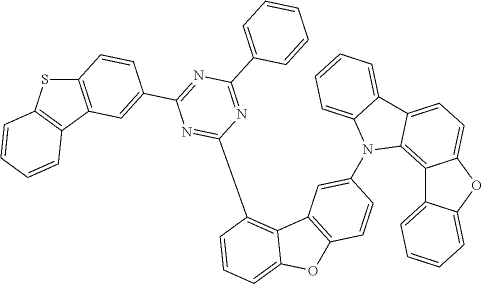 [SMILES: c1ccc(-c2nc(-c3ccc4sc5ccccc5c4c3)nc(-c3cccc4oc5ccc(-n6c7ccccc7c7ccc8oc9ccccc9c8c76)cc5c34)n2)cc1] | 1-654 |
| 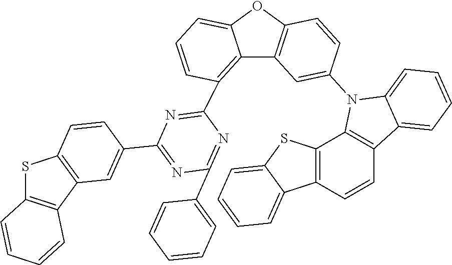 [SMILES: c1ccc(-c2nc(-c3ccc4sc5ccccc5c4c3)nc(-c3cccc4oc5ccc(-n6c7ccccc7c7ccc8c9ccccc9sc8c76)cc5c34)n2)cc1] | 1-655 |
| 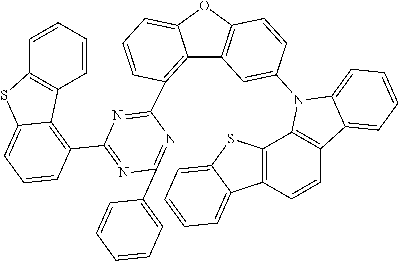 [SMILES: c1ccc(-c2nc(-c3cccc4oc5ccc(-n6c7ccccc7c7ccc8c9ccccc9sc8c76)cc5c34)nc(-c3cccc4sc5ccccc5c34)n2)cc1] | 1-656 |
| 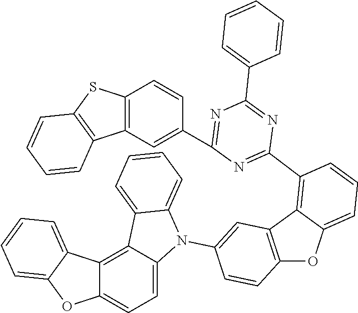 [SMILES: c1ccc(-c2nc(-c3ccc4sc5ccccc5c4c3)nc(-c3cccc4oc5ccc(-n6c7ccccc7c7c8c(ccc76)oc6ccccc68)cc5c34)n2)cc1] | 1-657 |
| 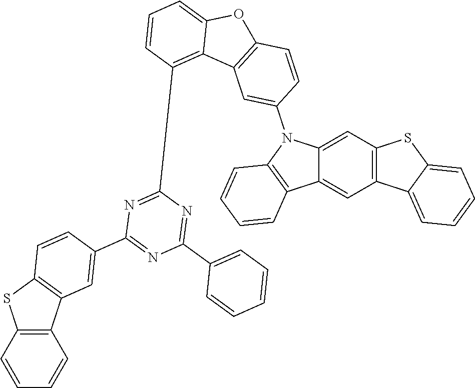 [SMILES: c1ccc(-c2nc(-c3ccc4sc5ccccc5c4c3)nc(-c3cccc4oc5ccc(-n6c7ccccc7c7cc8c(cc76)sc6ccccc68)cc5c34)n2)cc1] | 1-658 |
| 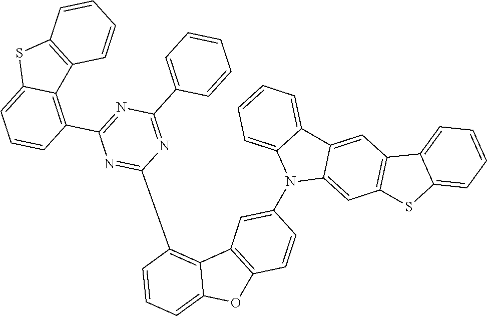 [SMILES: c1ccc(-c2nc(-c3cccc4oc5ccc(-n6c7ccccc7c7cc8c(cc76)sc6ccccc68)cc5c34)nc(-c3cccc4sc5ccccc5c34)n2)cc1] | 1-659 |
| 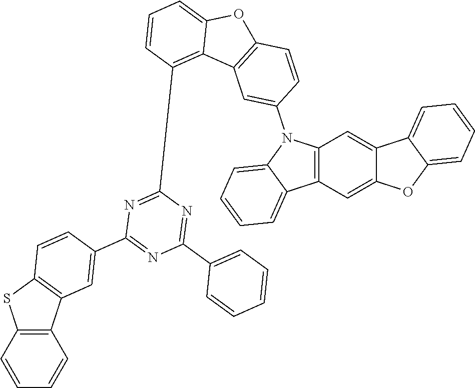 [SMILES: c1ccc(-c2nc(-c3ccc4sc5ccccc5c4c3)nc(-c3cccc4oc5ccc(-n6c7ccccc7c7cc8oc9ccccc9c8cc76)cc5c34)n2)cc1] | 1-660 |
| 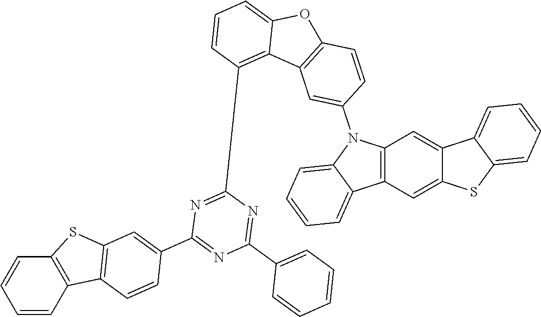 [SMILES: c1ccc(-c2nc(-c3ccc4c(c3)sc3ccccc34)nc(-c3cccc4oc5ccc(-n6c7ccccc7c7cc8sc9ccccc9c8cc76)cc5c34)n2)cc1] | 1-661 |
| 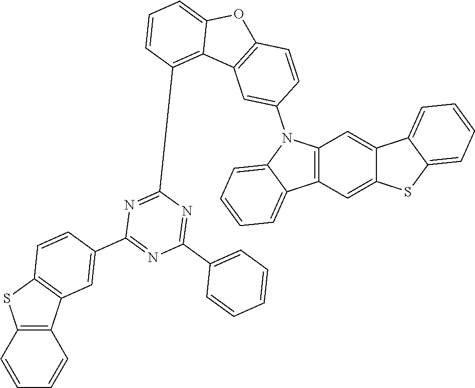 [SMILES: c1ccc(-c2nc(-c3ccc4sc5ccccc5c4c3)nc(-c3cccc4oc5ccc(-n6c7ccccc7c7cc8sc9ccccc9c8cc76)cc5c34)n2)cc1] | 1-662 |
| 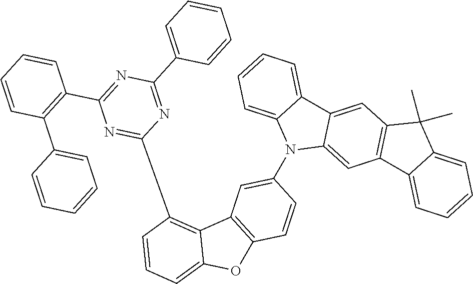 [SMILES: CC1(C)c2ccccc2-c2cc3c(cc21)c1ccccc1n3-c1ccc2oc3cccc(-c4nc(-c5ccccc5)nc(-c5ccccc5-c5ccccc5)n4)c3c2c1] | 1-663 |
| 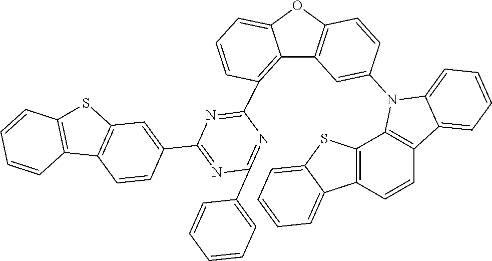 [SMILES: c1ccc(-c2nc(-c3ccc4c(c3)sc3ccccc34)nc(-c3cccc4oc5ccc(-n6c7ccccc7c7ccc8c9ccccc9sc8c76)cc5c34)n2)cc1] | 1-664 |
| 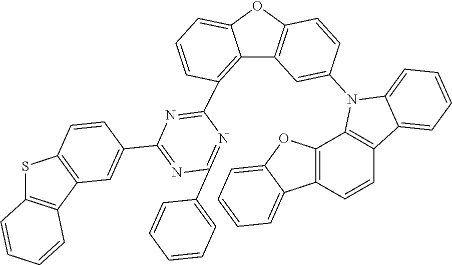 [SMILES: c1ccc(-c2nc(-c3ccc4sc5ccccc5c4c3)nc(-c3cccc4oc5ccc(-n6c7ccccc7c7ccc8c9ccccc9oc8c76)cc5c34)n2)cc1] | 1-665 |
| 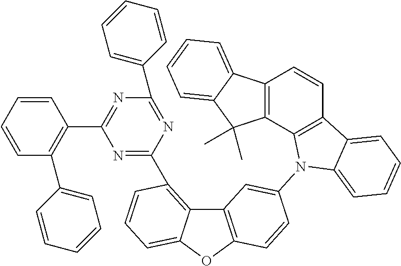 [SMILES: CC1(C)c2ccccc2-c2ccc3c4ccccc4n(-c4ccc5oc6cccc(-c7nc(-c8ccccc8)nc(-c8ccccc8-c8ccccc8)n7)c6c5c4)c3c21] | 1-666 |
| 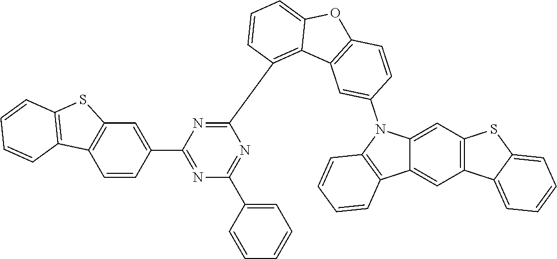 [SMILES: c1ccc(-c2nc(-c3ccc4c(c3)sc3ccccc34)nc(-c3cccc4oc5ccc(-n6c7ccccc7c7cc8c(cc76)sc6ccccc68)cc5c34)n2)cc1] | 1-667 |
| 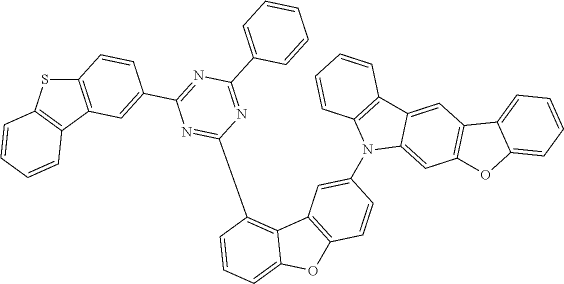 [SMILES: c1ccc(-c2nc(-c3ccc4sc5ccccc5c4c3)nc(-c3cccc4oc5ccc(-n6c7ccccc7c7cc8c(cc76)oc6ccccc68)cc5c34)n2)cc1] | 1-668 |
| 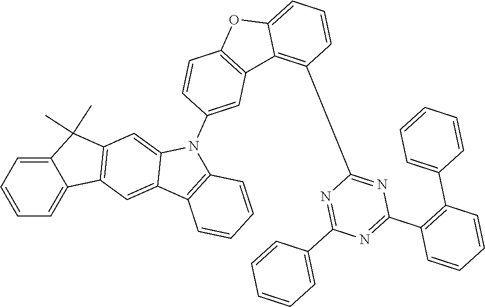 [SMILES: CC1(C)c2ccccc2-c2cc3c4ccccc4n(-c4ccc5oc6cccc(-c7nc(-c8ccccc8)nc(-c8ccccc8-c8ccccc8)n7)c6c5c4)c3cc21] | 1-669 |
| 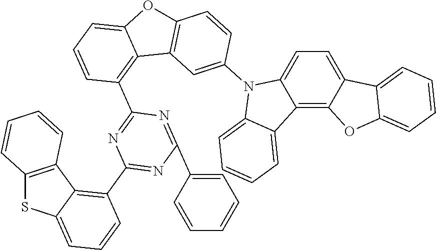 [SMILES: c1ccc(-c2nc(-c3cccc4oc5ccc(-n6c7ccccc7c7c8oc9ccccc9c8ccc76)cc5c34)nc(-c3cccc4sc5ccccc5c34)n2)cc1] | 1-670 |
| 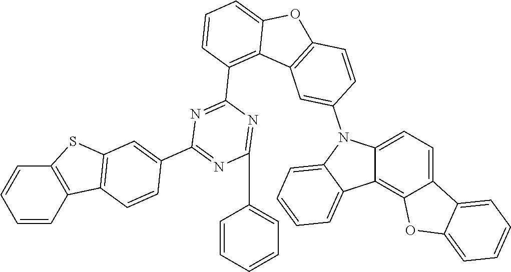 [SMILES: c1ccc(-c2nc(-c3ccc4c(c3)sc3ccccc34)nc(-c3cccc4oc5ccc(-n6c7ccccc7c7c8oc9ccccc9c8ccc76)cc5c34)n2)cc1] | 1-671 |
| 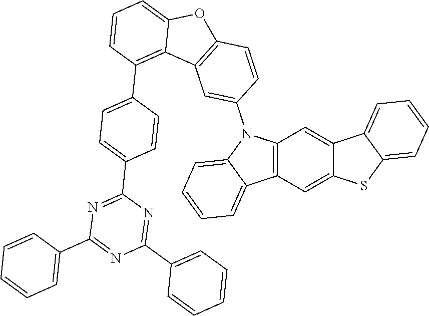 [SMILES: c1ccc(-c2nc(-c3ccccc3)nc(-c3ccc(-c4cccc5oc6ccc(-n7c8ccccc8c8cc9sc%10ccccc%10c9cc87)cc6c45)cc3)n2)cc1] | 1-672 |
| 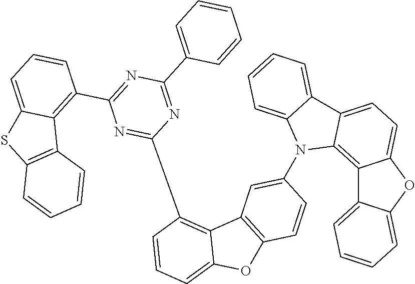 [SMILES: c1ccc(-c2nc(-c3cccc4oc5ccc(-n6c7ccccc7c7ccc8oc9ccccc9c8c76)cc5c34)nc(-c3cccc4sc5ccccc5c34)n2)cc1] | 1-673 |
| 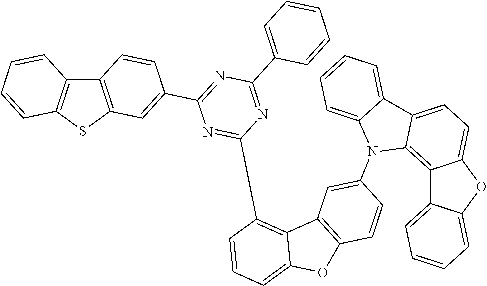 [SMILES: c1ccc(-c2nc(-c3ccc4c(c3)sc3ccccc34)nc(-c3cccc4oc5ccc(-n6c7ccccc7c7ccc8oc9ccccc9c8c76)cc5c34)n2)cc1] | 1-674 |
| 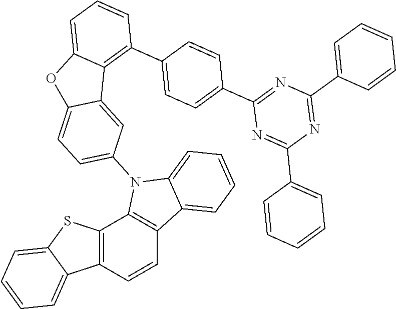 [SMILES: c1ccc(-c2nc(-c3ccccc3)nc(-c3ccc(-c4cccc5oc6ccc(-n7c8ccccc8c8ccc9c%10ccccc%10sc9c87)cc6c45)cc3)n2)cc1] | 1-675 |
| 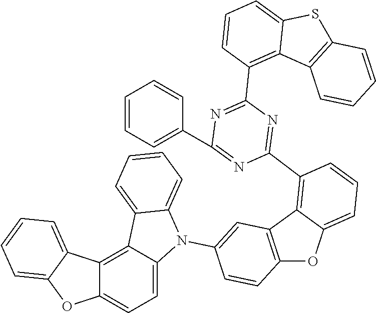 [SMILES: c1ccc(-c2nc(-c3cccc4oc5ccc(-n6c7ccccc7c7c8c(ccc76)oc6ccccc68)cc5c34)nc(-c3cccc4sc5ccccc5c34)n2)cc1] | 1-676 |
| 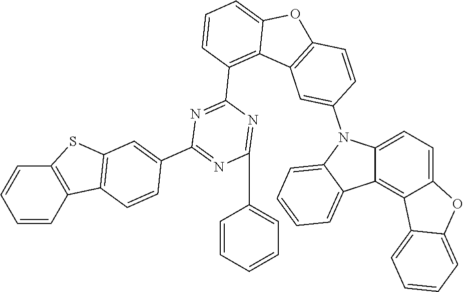 [SMILES: c1ccc(-c2nc(-c3ccc4c(c3)sc3ccccc34)nc(-c3cccc4oc5ccc(-n6c7ccccc7c7c8c(ccc76)oc6ccccc68)cc5c34)n2)cc1] | 1-677 |
| 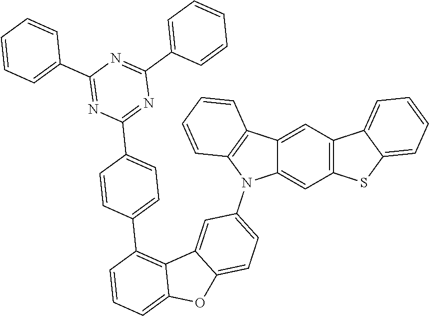 [SMILES: c1ccc(-c2nc(-c3ccccc3)nc(-c3ccc(-c4cccc5oc6ccc(-n7c8ccccc8c8cc9c(cc87)sc7ccccc79)cc6c45)cc3)n2)cc1] | 1-678 |
| 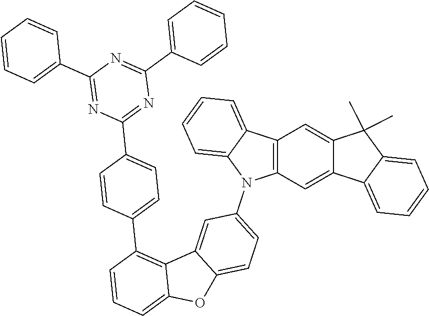 [SMILES: CC1(C)c2ccccc2-c2cc3c(cc21)c1ccccc1n3-c1ccc2oc3cccc(-c4ccc(-c5nc(-c6ccccc6)nc(-c6ccccc6)n5)cc4)c3c2c1] | 1-679 |
| 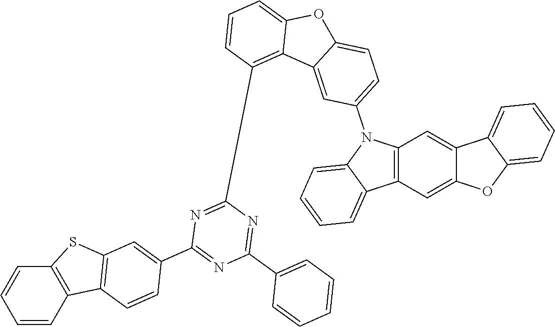 [SMILES: c1ccc(-c2nc(-c3ccc4c(c3)sc3ccccc34)nc(-c3cccc4oc5ccc(-n6c7ccccc7c7cc8oc9ccccc9c8cc76)cc5c34)n2)cc1] | 1-680 |
| 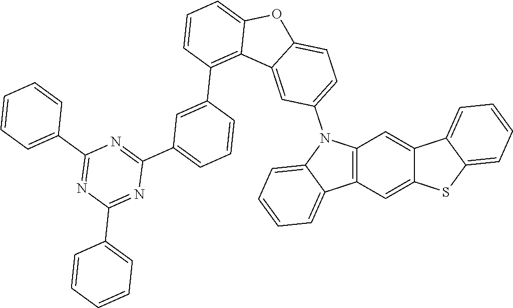 [SMILES: c1ccc(-c2nc(-c3ccccc3)nc(-c3cccc(-c4cccc5oc6ccc(-n7c8ccccc8c8cc9sc%10ccccc%10c9cc87)cc6c45)c3)n2)cc1] | 1-681 |
| 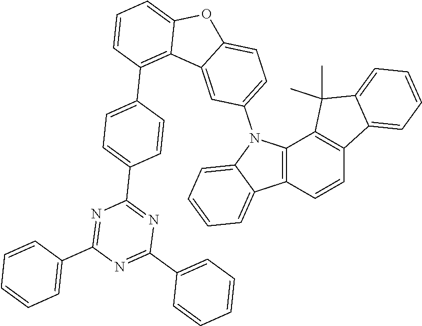 [SMILES: CC1(C)c2ccccc2-c2ccc3c4ccccc4n(-c4ccc5oc6cccc(-c7ccc(-c8nc(-c9ccccc9)nc(-c9ccccc9)n8)cc7)c6c5c4)c3c21] | 1-682 |
| 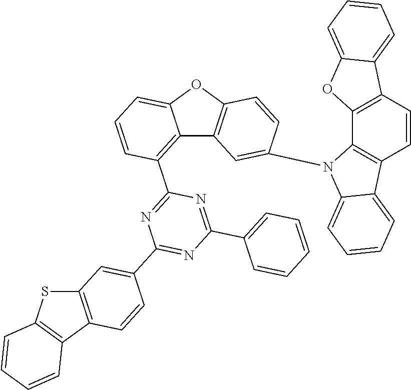 [SMILES: c1ccc(-c2nc(-c3ccc4c(c3)sc3ccccc34)nc(-c3cccc4oc5ccc(-n6c7ccccc7c7ccc8c9ccccc9oc8c76)cc5c34)n2)cc1] | 1-683 |
| 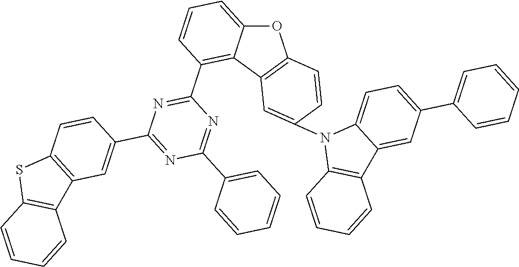 [SMILES: c1ccc(-c2ccc3c(c2)c2ccccc2n3-c2ccc3oc4cccc(-c5nc(-c6ccccc6)nc(-c6ccc7sc8ccccc8c7c6)n5)c4c3c2)cc1] | 1-684 |
| 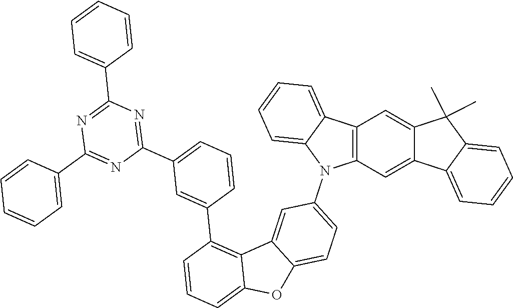 [SMILES: CC1(C)c2ccccc2-c2cc3c(cc21)c1ccccc1n3-c1ccc2oc3cccc(-c4cccc(-c5nc(-c6ccccc6)nc(-c6ccccc6)n5)c4)c3c2c1] | 1-685 |
| 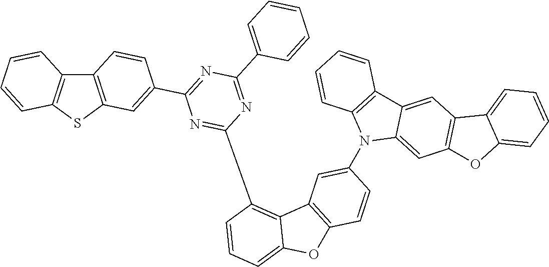 [SMILES: c1ccc(-c2nc(-c3ccc4c(c3)sc3ccccc34)nc(-c3cccc4oc5ccc(-n6c7ccccc7c7cc8c(cc76)oc6ccccc68)cc5c34)n2)cc1] | 1-686 |
| 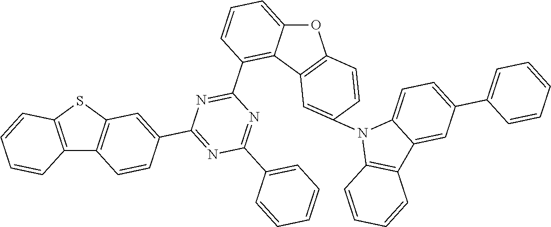 [SMILES: c1ccc(-c2ccc3c(c2)c2ccccc2n3-c2ccc3oc4cccc(-c5nc(-c6ccccc6)nc(-c6ccc7c(c6)sc6ccccc67)n5)c4c3c2)cc1] | 1-687 |
| 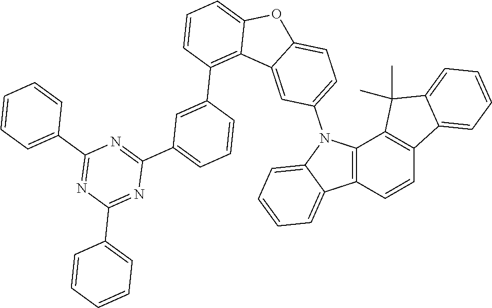 [SMILES: CC1(C)c2ccccc2-c2ccc3c4ccccc4n(-c4ccc5oc6cccc(-c7cccc(-c8nc(-c9ccccc9)nc(-c9ccccc9)n8)c7)c6c5c4)c3c21] | 1-688 |
| 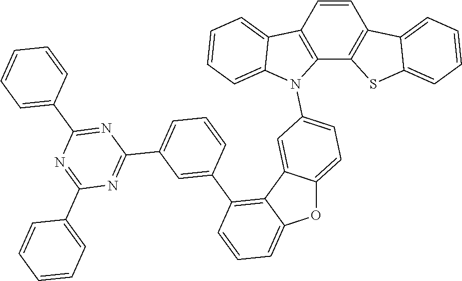 [SMILES: c1ccc(-c2nc(-c3ccccc3)nc(-c3cccc(-c4cccc5oc6ccc(-n7c8ccccc8c8ccc9c%10ccccc%10sc9c87)cc6c45)c3)n2)cc1] | 1-689 |
| 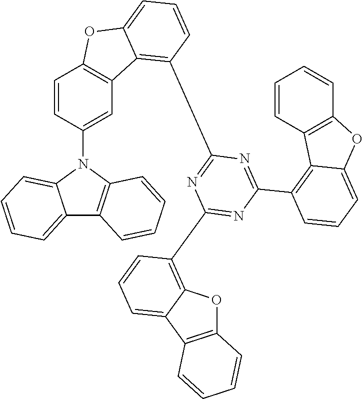 [SMILES: c1ccc2c(c1)oc1c(-c3nc(-c4cccc5oc6ccccc6c45)nc(-c4cccc5oc6ccc(-n7c8ccccc8c8ccccc87)cc6c45)n3)cccc12] | 1-690 |
| 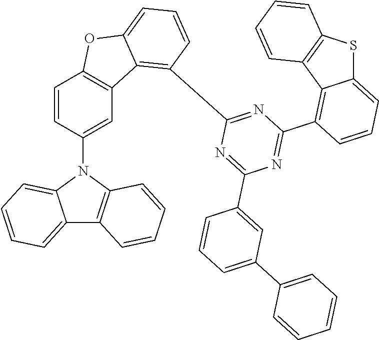 [SMILES: c1ccc(-c2cccc(-c3nc(-c4cccc5oc6ccc(-n7c8ccccc8c8ccccc87)cc6c45)nc(-c4cccc5sc6ccccc6c45)n3)c2)cc1] | 1-691 |
| 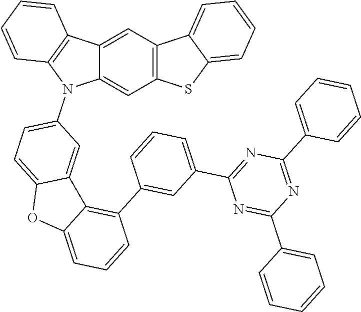 [SMILES: c1ccc(-c2nc(-c3ccccc3)nc(-c3cccc(-c4cccc5oc6ccc(-n7c8ccccc8c8cc9c(cc87)sc7ccccc79)cc6c45)c3)n2)cc1] | 1-692 |
| 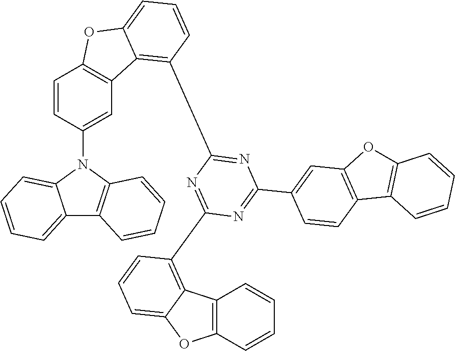 [SMILES: c1ccc2c(c1)oc1cc(-c3nc(-c4cccc5oc6ccccc6c45)nc(-c4cccc5oc6ccc(-n7c8ccccc8c8ccccc87)cc6c45)n3)ccc12] | 1-693 |
| 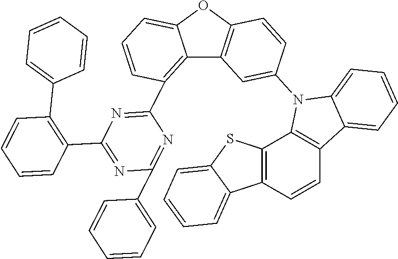 [SMILES: c1ccc(-c2nc(-c3ccccc3-c3ccccc3)nc(-c3cccc4oc5ccc(-n6c7ccccc7c7ccc8c9ccccc9sc8c76)cc5c34)n2)cc1] | 1-694 |
| 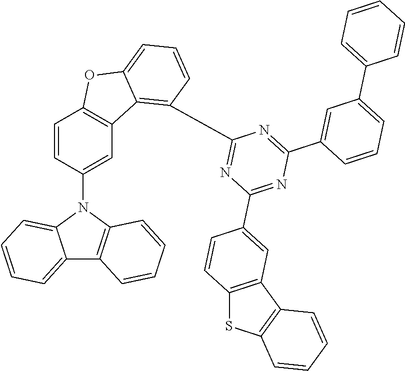 [SMILES: c1ccc(-c2cccc(-c3nc(-c4ccc5sc6ccccc6c5c4)nc(-c4cccc5oc6ccc(-n7c8ccccc8c8ccccc87)cc6c45)n3)c2)cc1] | 1-695 |
| 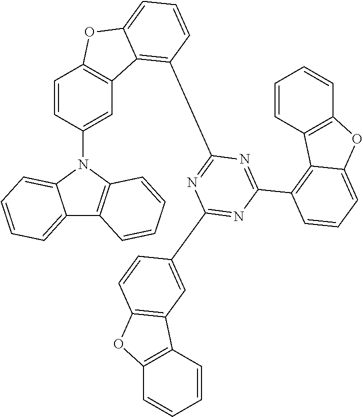 [SMILES: c1ccc2c(c1)oc1ccc(-c3nc(-c4cccc5oc6ccccc6c45)nc(-c4cccc5oc6ccc(-n7c8ccccc8c8ccccc87)cc6c45)n3)cc12] | 1-696 |
| 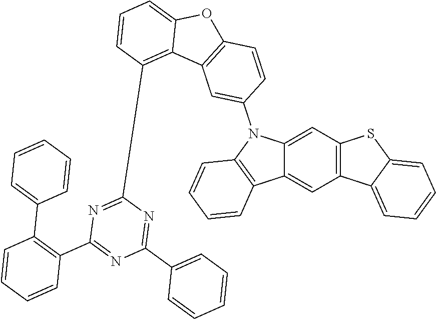 [SMILES: c1ccc(-c2nc(-c3ccccc3-c3ccccc3)nc(-c3cccc4oc5ccc(-n6c7ccccc7c7cc8c(cc76)sc6ccccc68)cc5c34)n2)cc1] | 1-697 |
| 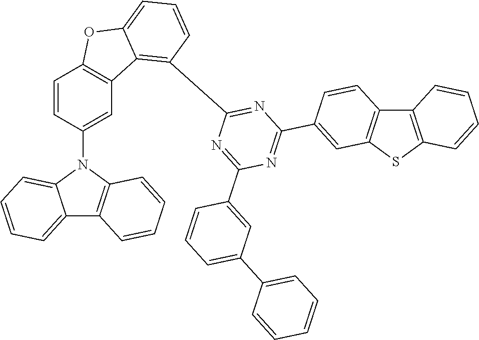 [SMILES: c1ccc(-c2cccc(-c3nc(-c4ccc5c(c4)sc4ccccc45)nc(-c4cccc5oc6ccc(-n7c8ccccc8c8ccccc87)cc6c45)n3)c2)cc1] | 1-698 |
| 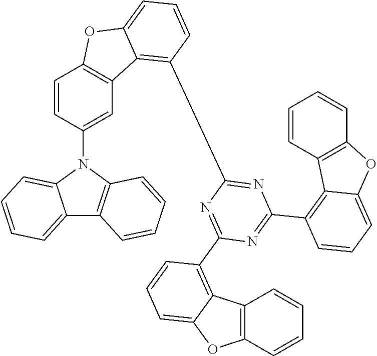 [SMILES: c1ccc2c(c1)oc1cccc(-c3nc(-c4cccc5oc6ccccc6c45)nc(-c4cccc5oc6ccc(-n7c8ccccc8c8ccccc87)cc6c45)n3)c12] | 1-699 |
| 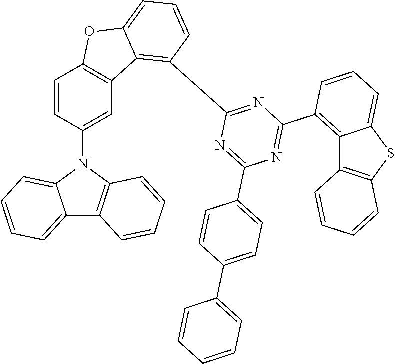 [SMILES: c1ccc(-c2ccc(-c3nc(-c4cccc5oc6ccc(-n7c8ccccc8c8ccccc87)cc6c45)nc(-c4cccc5sc6ccccc6c45)n3)cc2)cc1] | 1-700 |
| 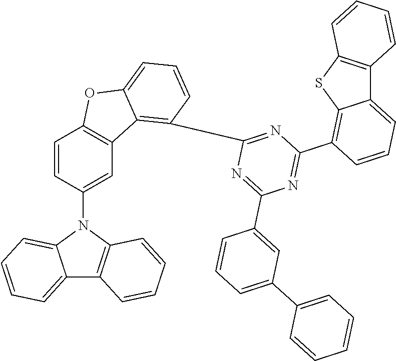 [SMILES: c1ccc(-c2cccc(-c3nc(-c4cccc5c4sc4ccccc45)nc(-c4cccc5oc6ccc(-n7c8ccccc8c8ccccc87)cc6c45)n3)c2)cc1] | 1-701 |
| 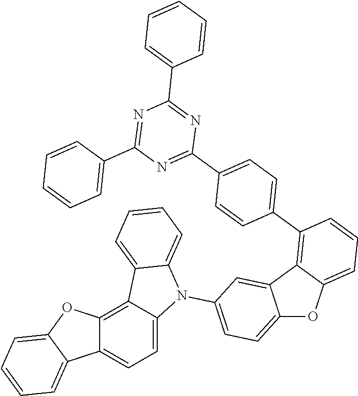 [SMILES: c1ccc(-c2nc(-c3ccccc3)nc(-c3ccc(-c4cccc5oc6ccc(-n7c8ccccc8c8c9oc%10ccccc%10c9ccc87)cc6c45)cc3)n2)cc1] | 1-702 |
| 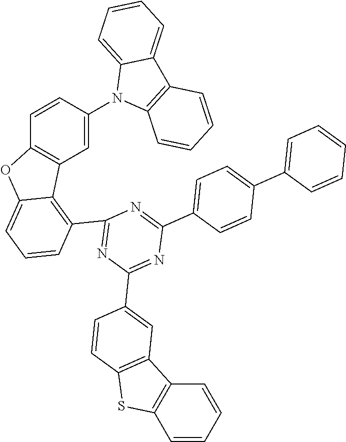 [SMILES: c1ccc(-c2ccc(-c3nc(-c4ccc5sc6ccccc6c5c4)nc(-c4cccc5oc6ccc(-n7c8ccccc8c8ccccc87)cc6c45)n3)cc2)cc1] | 1-703 |
| 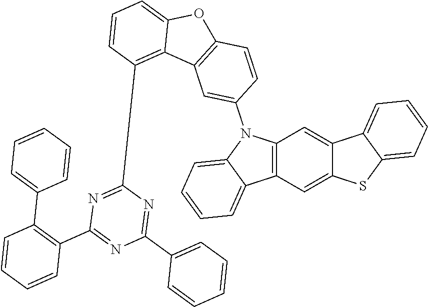 [SMILES: c1ccc(-c2nc(-c3ccccc3-c3ccccc3)nc(-c3cccc4oc5ccc(-n6c7ccccc7c7cc8sc9ccccc9c8cc76)cc5c34)n2)cc1] | 1-704 |
| 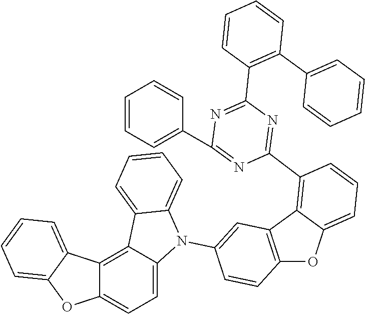 [SMILES: c1ccc(-c2nc(-c3ccccc3-c3ccccc3)nc(-c3cccc4oc5ccc(-n6c7ccccc7c7c8c(ccc76)oc6ccccc68)cc5c34)n2)cc1] | 1-705 |
| 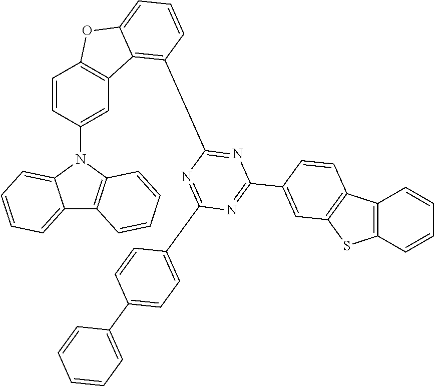 [SMILES: c1ccc(-c2ccc(-c3nc(-c4ccc5c(c4)sc4ccccc45)nc(-c4cccc5oc6ccc(-n7c8ccccc8c8ccccc87)cc6c45)n3)cc2)cc1] | 1-706 |
| 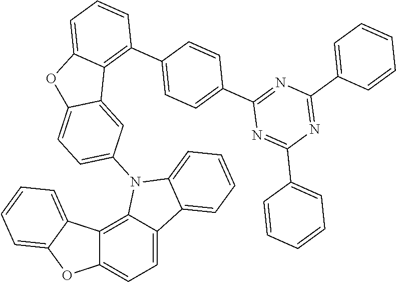 [SMILES: c1ccc(-c2nc(-c3ccccc3)nc(-c3ccc(-c4cccc5oc6ccc(-n7c8ccccc8c8ccc9oc%10ccccc%10c9c87)cc6c45)cc3)n2)cc1] | 1-707 |
| 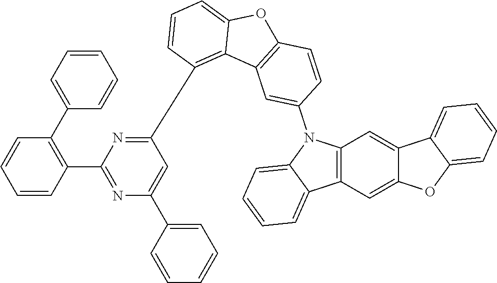 [SMILES: c1ccc(-c2cc(-c3cccc4oc5ccc(-n6c7ccccc7c7cc8oc9ccccc9c8cc76)cc5c34)nc(-c3ccccc3-c3ccccc3)n2)cc1] | 1-708 |
| 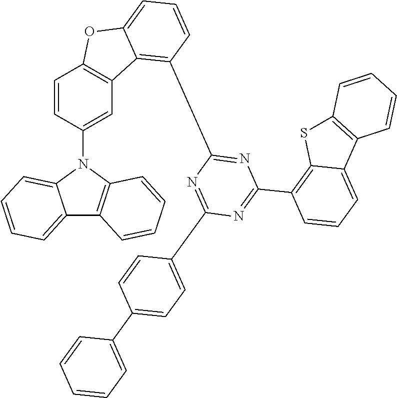 [SMILES: c1ccc(-c2ccc(-c3nc(-c4cccc5c4sc4ccccc45)nc(-c4cccc5oc6ccc(-n7c8ccccc8c8ccccc87)cc6c45)n3)cc2)cc1] | 1-709 |
| 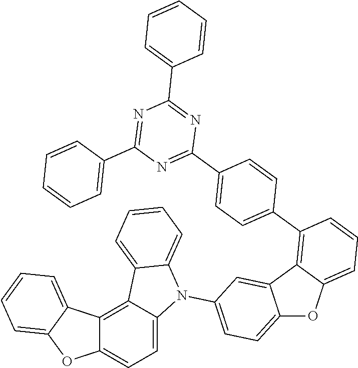 [SMILES: c1ccc(-c2nc(-c3ccccc3)nc(-c3ccc(-c4cccc5oc6ccc(-n7c8ccccc8c8c9c(ccc87)oc7ccccc79)cc6c45)cc3)n2)cc1] | 1-710 |
| 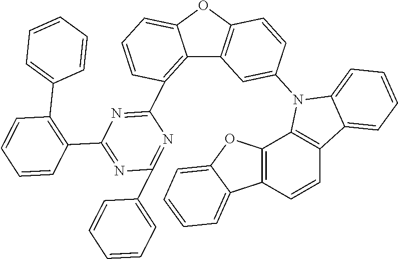 [SMILES: c1ccc(-c2nc(-c3ccccc3-c3ccccc3)nc(-c3cccc4oc5ccc(-n6c7ccccc7c7ccc8c9ccccc9oc8c76)cc5c34)n2)cc1] | 1-711 |
| 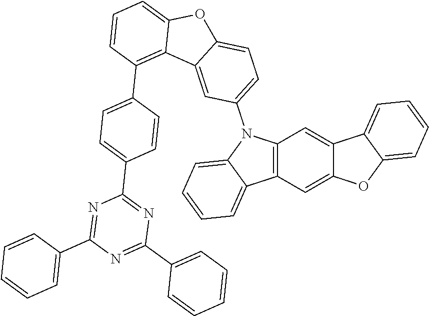 [SMILES: c1ccc(-c2nc(-c3ccccc3)nc(-c3ccc(-c4cccc5oc6ccc(-n7c8ccccc8c8cc9oc%10ccccc%10c9cc87)cc6c45)cc3)n2)cc1] | 1-712 |
| 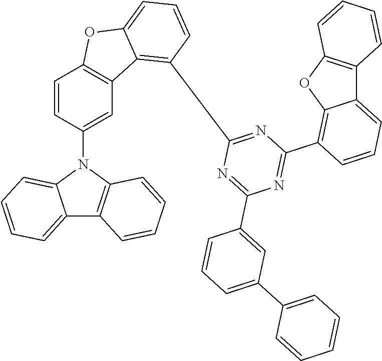 [SMILES: c1ccc(-c2cccc(-c3nc(-c4cccc5c4oc4ccccc45)nc(-c4cccc5oc6ccc(-n7c8ccccc8c8ccccc87)cc6c45)n3)c2)cc1] | 1-713 |
| 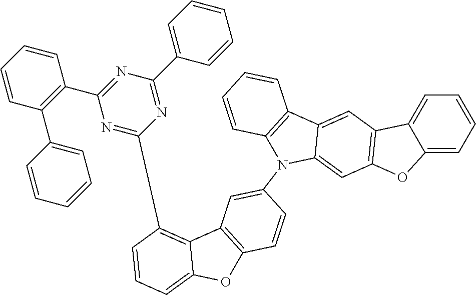 [SMILES: c1ccc(-c2nc(-c3ccccc3-c3ccccc3)nc(-c3cccc4oc5ccc(-n6c7ccccc7c7cc8c(cc76)oc6ccccc68)cc5c34)n2)cc1] | 1-714 |
| 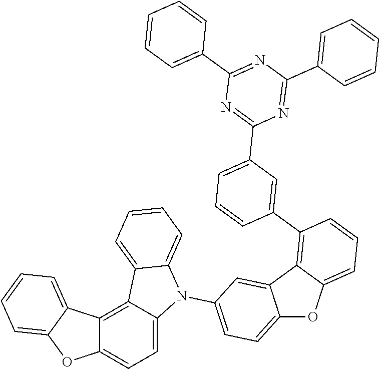 [SMILES: c1ccc(-c2nc(-c3ccccc3)nc(-c3cccc(-c4cccc5oc6ccc(-n7c8ccccc8c8c9c(ccc87)oc7ccccc79)cc6c45)c3)n2)cc1] | 1-715 |
| 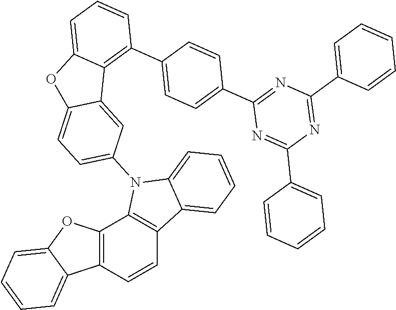 [SMILES: c1ccc(-c2nc(-c3ccccc3)nc(-c3ccc(-c4cccc5oc6ccc(-n7c8ccccc8c8ccc9c%10ccccc%10oc9c87)cc6c45)cc3)n2)cc1] | 1-716 |
| 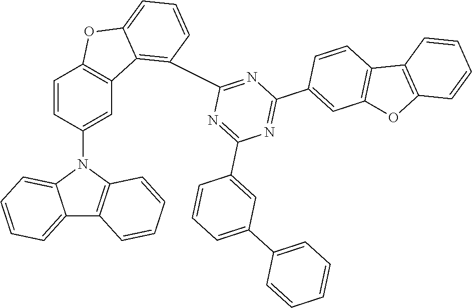 [SMILES: c1ccc(-c2cccc(-c3nc(-c4ccc5c(c4)oc4ccccc45)nc(-c4cccc5oc6ccc(-n7c8ccccc8c8ccccc87)cc6c45)n3)c2)cc1] | 1-717 |
| 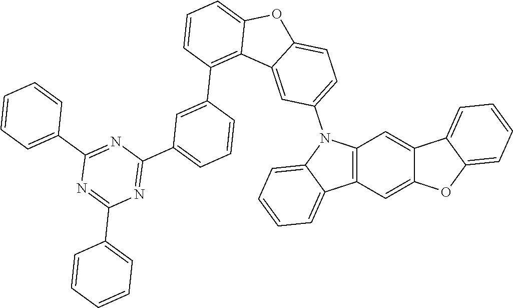 [SMILES: c1ccc(-c2nc(-c3ccccc3)nc(-c3cccc(-c4cccc5oc6ccc(-n7c8ccccc8c8cc9oc%10ccccc%10c9cc87)cc6c45)c3)n2)cc1] | 1-718 |
| 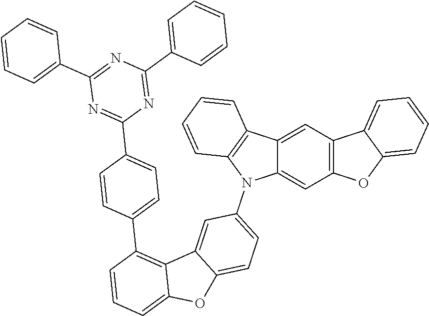 [SMILES: c1ccc(-c2nc(-c3ccccc3)nc(-c3ccc(-c4cccc5oc6ccc(-n7c8ccccc8c8cc9c(cc87)oc7ccccc79)cc6c45)cc3)n2)cc1] | 1-719 |
| 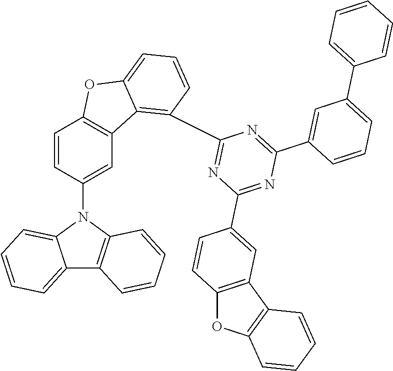 [SMILES: c1ccc(-c2cccc(-c3nc(-c4ccc5oc6ccccc6c5c4)nc(-c4cccc5oc6ccc(-n7c8ccccc8c8ccccc87)cc6c45)n3)c2)cc1] | 1-720 |
| 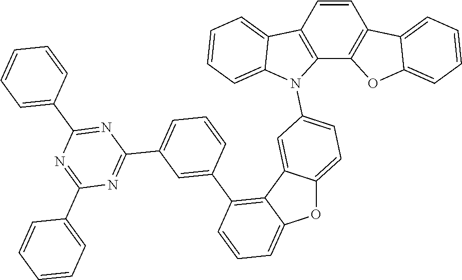 [SMILES: c1ccc(-c2nc(-c3ccccc3)nc(-c3cccc(-c4cccc5oc6ccc(-n7c8ccccc8c8ccc9c%10ccccc%10oc9c87)cc6c45)c3)n2)cc1] | 1-721 |
| 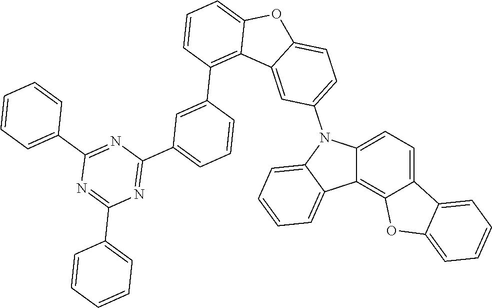 [SMILES: c1ccc(-c2nc(-c3ccccc3)nc(-c3cccc(-c4cccc5oc6ccc(-n7c8ccccc8c8c9oc%10ccccc%10c9ccc87)cc6c45)c3)n2)cc1] | 1-722 |
| 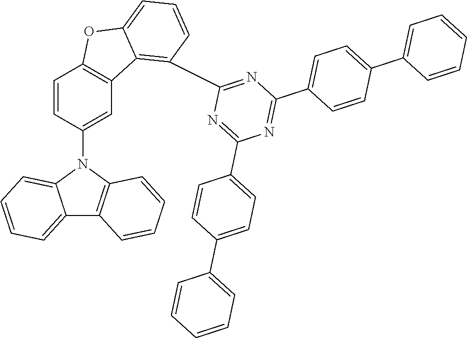 [SMILES: c1ccc(-c2ccc(-c3nc(-c4ccc(-c5ccccc5)cc4)nc(-c4cccc5oc6ccc(-n7c8ccccc8c8ccccc87)cc6c45)n3)cc2)cc1] | 1-723 |
| 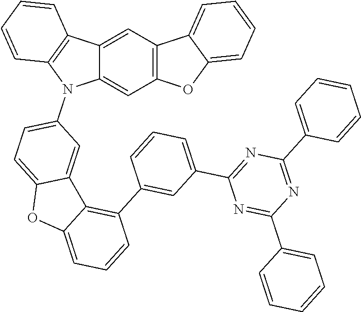 [SMILES: c1ccc(-c2nc(-c3ccccc3)nc(-c3cccc(-c4cccc5oc6ccc(-n7c8ccccc8c8cc9c(cc87)oc7ccccc79)cc6c45)c3)n2)cc1] | 1-724 |
| 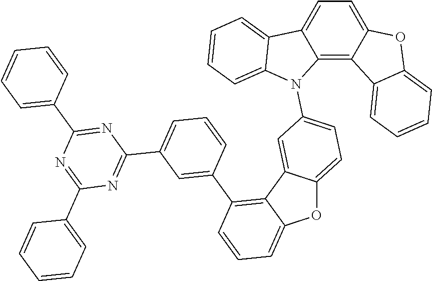 [SMILES: c1ccc(-c2nc(-c3ccccc3)nc(-c3cccc(-c4cccc5oc6ccc(-n7c8ccccc8c8ccc9oc%10ccccc%10c9c87)cc6c45)c3)n2)cc1] | 1-725 |
| 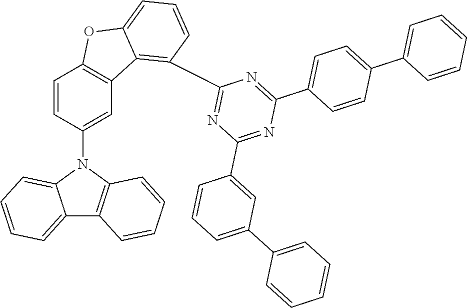 [SMILES: c1ccc(-c2ccc(-c3nc(-c4cccc(-c5ccccc5)c4)nc(-c4cccc5oc6ccc(-n7c8ccccc8c8ccccc87)cc6c45)n3)cc2)cc1] | 1-726 |
| 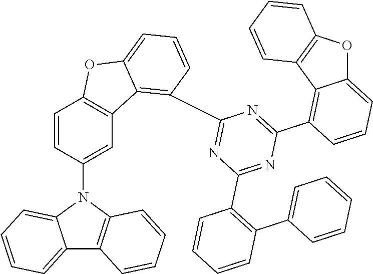 [SMILES: c1ccc(-c2ccccc2-c2nc(-c3cccc4oc5ccccc5c34)nc(-c3cccc4oc5ccc(-n6c7ccccc7c7ccccc76)cc5c34)n2)cc1] | 1-727 |
| 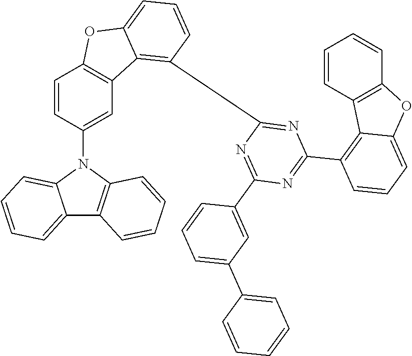 [SMILES: c1ccc(-c2cccc(-c3nc(-c4cccc5oc6ccccc6c45)nc(-c4cccc5oc6ccc(-n7c8ccccc8c8ccccc87)cc6c45)n3)c2)cc1] | 1-728 |
| 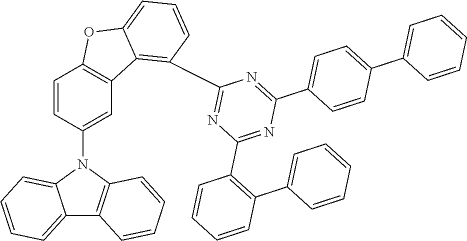 [SMILES: c1ccc(-c2ccc(-c3nc(-c4ccccc4-c4ccccc4)nc(-c4cccc5oc6ccc(-n7c8ccccc8c8ccccc87)cc6c45)n3)cc2)cc1] | 1-729 |
| 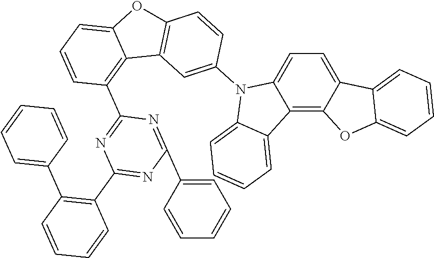 [SMILES: c1ccc(-c2nc(-c3ccccc3-c3ccccc3)nc(-c3cccc4oc5ccc(-n6c7ccccc7c7c8oc9ccccc9c8ccc76)cc5c34)n2)cc1] | 1-730 |
| 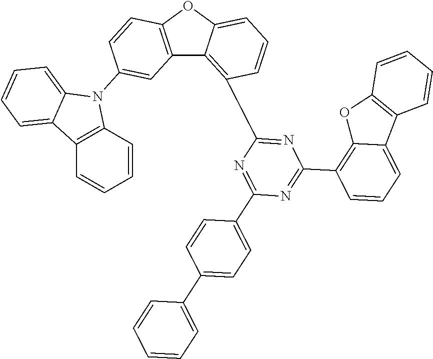 [SMILES: c1ccc(-c2ccc(-c3nc(-c4cccc5c4oc4ccccc45)nc(-c4cccc5oc6ccc(-n7c8ccccc8c8ccccc87)cc6c45)n3)cc2)cc1] | 1-731 |
| 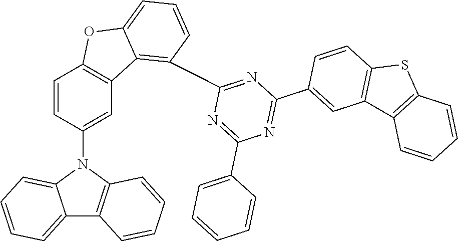 [SMILES: c1ccc(-c2nc(-c3ccc4sc5ccccc5c4c3)nc(-c3cccc4oc5ccc(-n6c7ccccc7c7ccccc76)cc5c34)n2)cc1] | 1-732 |
| 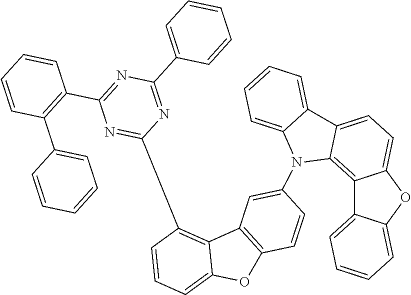 [SMILES: c1ccc(-c2nc(-c3ccccc3-c3ccccc3)nc(-c3cccc4oc5ccc(-n6c7ccccc7c7ccc8oc9ccccc9c8c76)cc5c34)n2)cc1] | 1-733 |
| 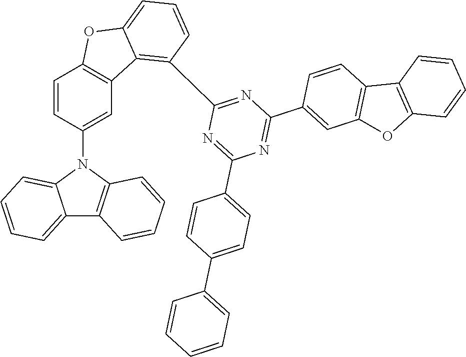 [SMILES: c1ccc(-c2ccc(-c3nc(-c4ccc5c(c4)oc4ccccc45)nc(-c4cccc5oc6ccc(-n7c8ccccc8c8ccccc87)cc6c45)n3)cc2)cc1] | 1-734 |
| 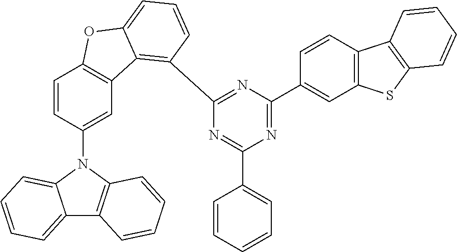 [SMILES: c1ccc(-c2nc(-c3ccc4c(c3)sc3ccccc34)nc(-c3cccc4oc5ccc(-n6c7ccccc7c7ccccc76)cc5c34)n2)cc1] | 1-735 |
| 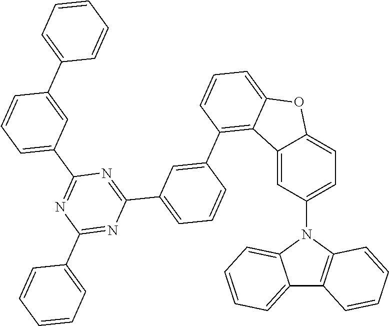 [SMILES: c1ccc(-c2cccc(-c3nc(-c4ccccc4)nc(-c4cccc(-c5cccc6oc7ccc(-n8c9ccccc9c9ccccc98)cc7c56)c4)n3)c2)cc1] | 1-736 |
| 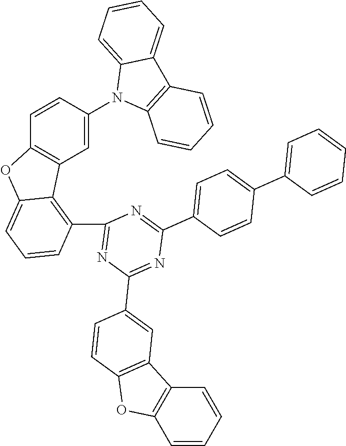 [SMILES: c1ccc(-c2ccc(-c3nc(-c4ccc5oc6ccccc6c5c4)nc(-c4cccc5oc6ccc(-n7c8ccccc8c8ccccc87)cc6c45)n3)cc2)cc1] | 1-737 |
| 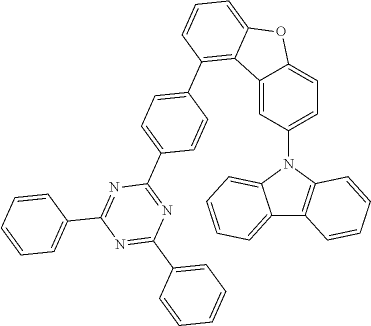 [SMILES: c1ccc(-c2nc(-c3ccccc3)nc(-c3ccc(-c4cccc5oc6ccc(-n7c8ccccc8c8ccccc87)cc6c45)cc3)n2)cc1] | 1-738 |
| 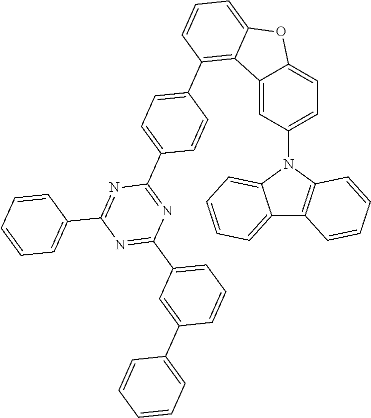 [SMILES: c1ccc(-c2cccc(-c3nc(-c4ccccc4)nc(-c4ccc(-c5cccc6oc7ccc(-n8c9ccccc9c9ccccc98)cc7c56)cc4)n3)c2)cc1] | 1-739 |
| 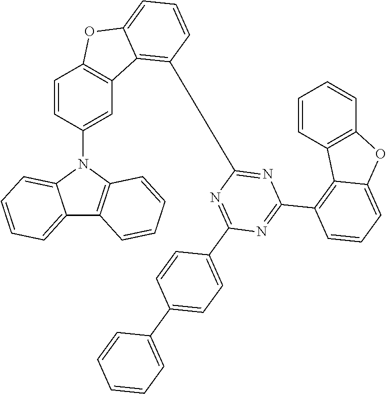 [SMILES: c1ccc(-c2ccc(-c3nc(-c4cccc5oc6ccccc6c45)nc(-c4cccc5oc6ccc(-n7c8ccccc8c8ccccc87)cc6c45)n3)cc2)cc1] | 1-740 |
| 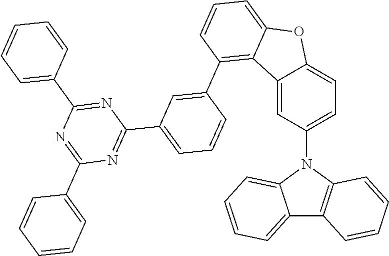 [SMILES: c1ccc(-c2nc(-c3ccccc3)nc(-c3cccc(-c4cccc5oc6ccc(-n7c8ccccc8c8ccccc87)cc6c45)c3)n2)cc1] | 1-741 |
| 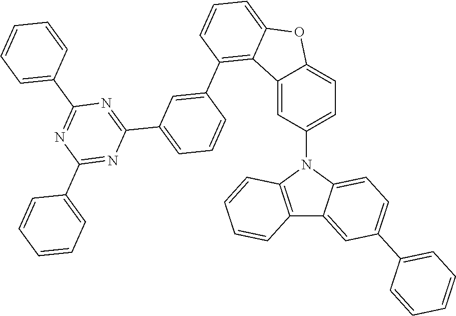 [SMILES: c1ccc(-c2ccc3c(c2)c2ccccc2n3-c2ccc3oc4cccc(-c5cccc(-c6nc(-c7ccccc7)nc(-c7ccccc7)n6)c5)c4c3c2)cc1] | 1-742 |
| 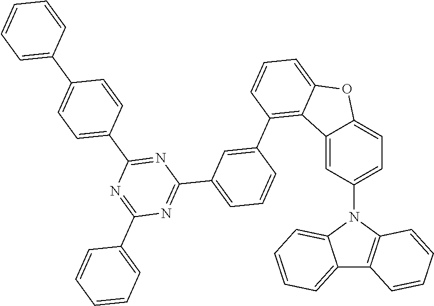 [SMILES: c1ccc(-c2ccc(-c3nc(-c4ccccc4)nc(-c4cccc(-c5cccc6oc7ccc(-n8c9ccccc9c9ccccc98)cc7c56)c4)n3)cc2)cc1] | 1-743 |
| 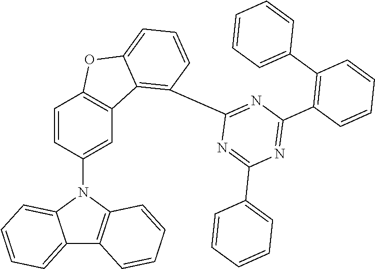 [SMILES: c1ccc(-c2nc(-c3ccccc3-c3ccccc3)nc(-c3cccc4oc5ccc(-n6c7ccccc7c7ccccc76)cc5c34)n2)cc1] | 1-744 |
| 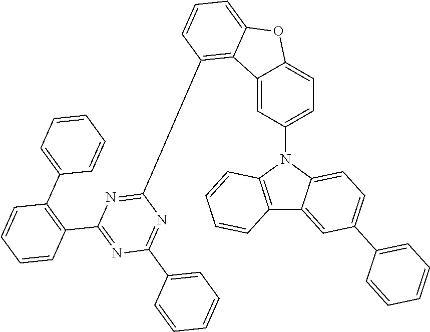 [SMILES: c1ccc(-c2ccc3c(c2)c2ccccc2n3-c2ccc3oc4cccc(-c5nc(-c6ccccc6)nc(-c6ccccc6-c6ccccc6)n5)c4c3c2)cc1] | 1-745 |
| 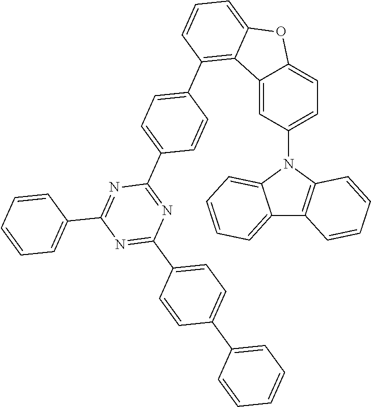 [SMILES: c1ccc(-c2ccc(-c3nc(-c4ccccc4)nc(-c4ccc(-c5cccc6oc7ccc(-n8c9ccccc9c9ccccc98)cc7c56)cc4)n3)cc2)cc1] | 1-746 |
| 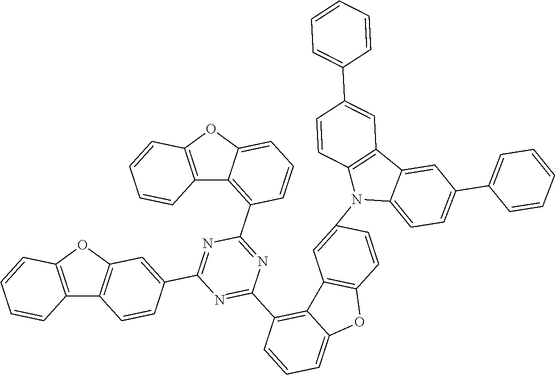 [SMILES: c1ccc(-c2ccc3c(c2)c2cc(-c4ccccc4)ccc2n3-c2ccc3oc4cccc(-c5nc(-c6ccc7c(c6)oc6ccccc67)nc(-c6cccc7oc8ccccc8c67)n5)c4c3c2)cc1] | 1-747 |
| 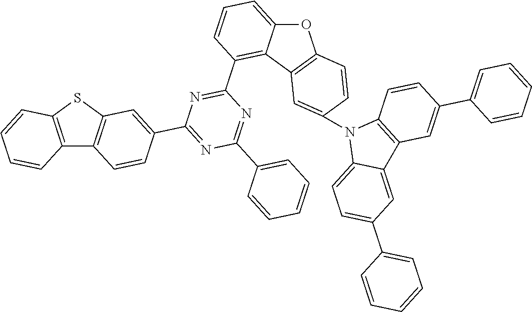 [SMILES: c1ccc(-c2ccc3c(c2)c2cc(-c4ccccc4)ccc2n3-c2ccc3oc4cccc(-c5nc(-c6ccccc6)nc(-c6ccc7c(c6)sc6ccccc67)n5)c4c3c2)cc1] | 1-748 |
| 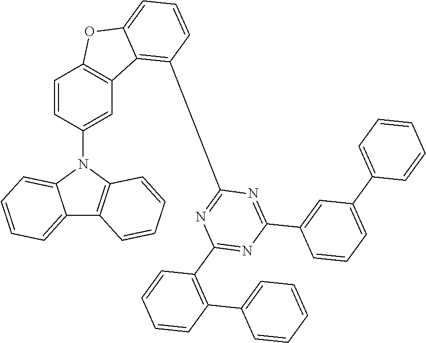 [SMILES: c1ccc(-c2cccc(-c3nc(-c4ccccc4-c4ccccc4)nc(-c4cccc5oc6ccc(-n7c8ccccc8c8ccccc87)cc6c45)n3)c2)cc1] | 1-749 |
| 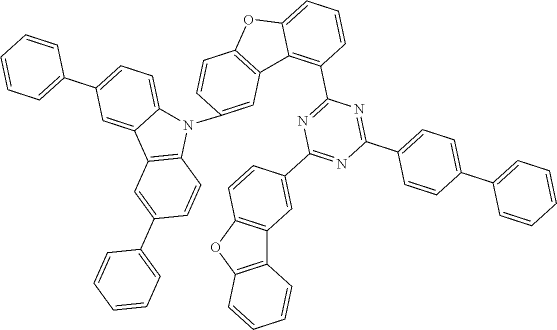 [SMILES: c1ccc(-c2ccc(-c3nc(-c4ccc5oc6ccccc6c5c4)nc(-c4cccc5oc6ccc(-n7c8ccc(-c9ccccc9)cc8c8cc(-c9ccccc9)ccc87)cc6c45)n3)cc2)cc1] | 1-750 |
| 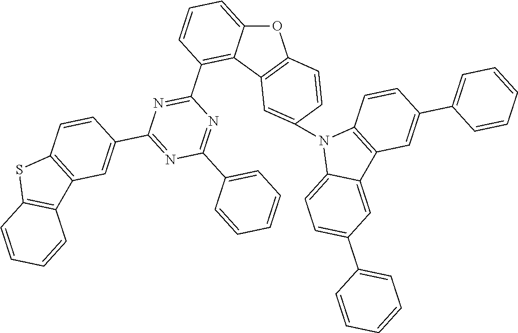 [SMILES: c1ccc(-c2ccc3c(c2)c2cc(-c4ccccc4)ccc2n3-c2ccc3oc4cccc(-c5nc(-c6ccccc6)nc(-c6ccc7sc8ccccc8c7c6)n5)c4c3c2)cc1] | 1-751 |
| 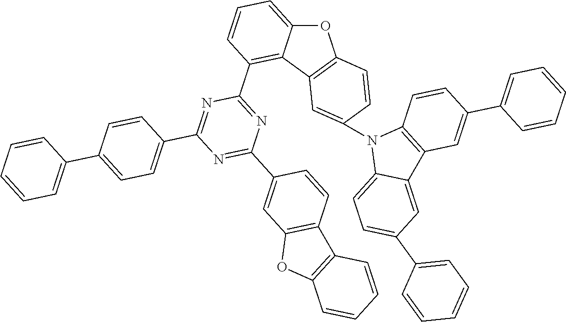 [SMILES: c1ccc(-c2ccc(-c3nc(-c4ccc5c(c4)oc4ccccc45)nc(-c4cccc5oc6ccc(-n7c8ccc(-c9ccccc9)cc8c8cc(-c9ccccc9)ccc87)cc6c45)n3)cc2)cc1] | 1-752 |
| 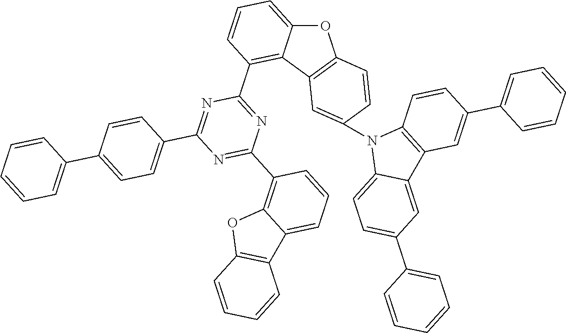 [SMILES: c1ccc(-c2ccc(-c3nc(-c4cccc5c4oc4ccccc45)nc(-c4cccc5oc6ccc(-n7c8ccc(-c9ccccc9)cc8c8cc(-c9ccccc9)ccc87)cc6c45)n3)cc2)cc1] | 1-753 |
| 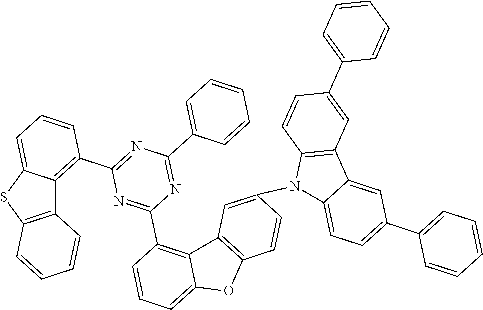 [SMILES: c1ccc(-c2ccc3c(c2)c2cc(-c4ccccc4)ccc2n3-c2ccc3oc4cccc(-c5nc(-c6ccccc6)nc(-c6cccc7sc8ccccc8c67)n5)c4c3c2)cc1] | 1-754 |
| 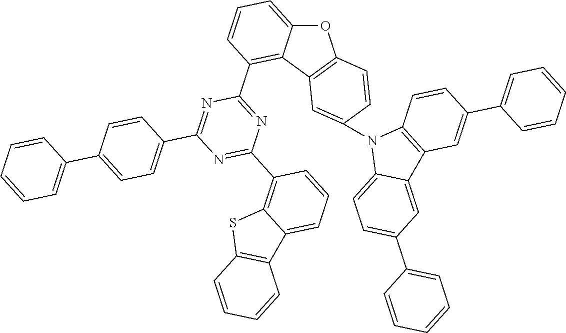 [SMILES: c1ccc(-c2ccc(-c3nc(-c4cccc5c4sc4ccccc45)nc(-c4cccc5oc6ccc(-n7c8ccc(-c9ccccc9)cc8c8cc(-c9ccccc9)ccc87)cc6c45)n3)cc2)cc1] | 1-755 |
| 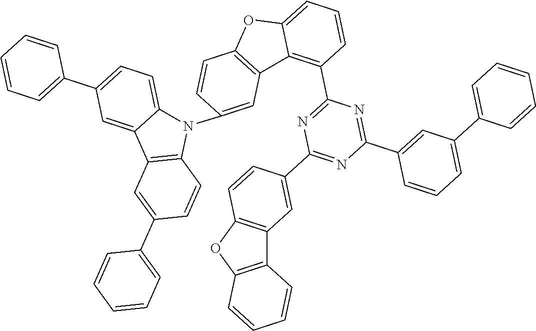 [SMILES: c1ccc(-c2cccc(-c3nc(-c4ccc5oc6ccccc6c5c4)nc(-c4cccc5oc6ccc(-n7c8ccc(-c9ccccc9)cc8c8cc(-c9ccccc9)ccc87)cc6c45)n3)c2)cc1] | 1-756 |
| 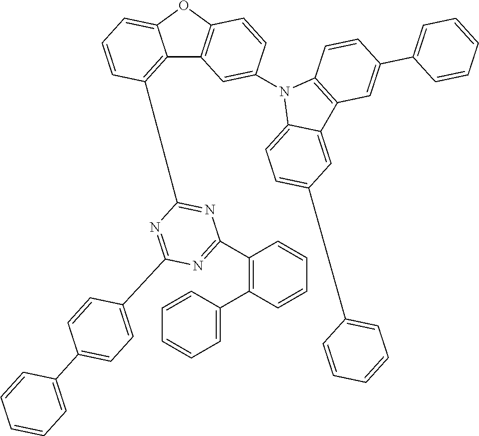 [SMILES: c1ccc(-c2ccc(-c3nc(-c4ccccc4-c4ccccc4)nc(-c4cccc5oc6ccc(-n7c8ccc(-c9ccccc9)cc8c8cc(-c9ccccc9)ccc87)cc6c45)n3)cc2)cc1] | 1-757 |
| 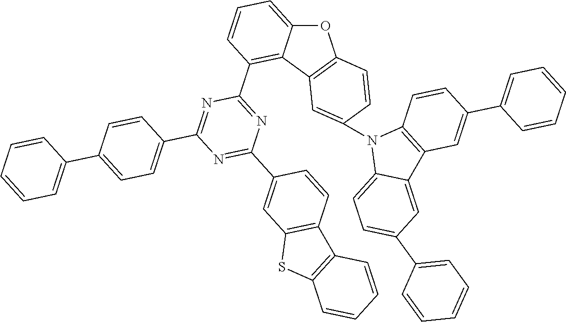 [SMILES: c1ccc(-c2ccc(-c3nc(-c4ccc5c(c4)sc4ccccc45)nc(-c4cccc5oc6ccc(-n7c8ccc(-c9ccccc9)cc8c8cc(-c9ccccc9)ccc87)cc6c45)n3)cc2)cc1] | 1-758 |
| 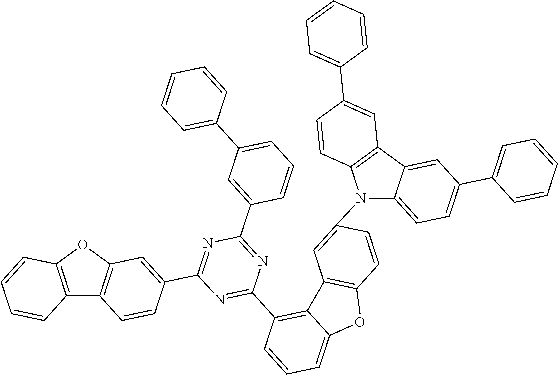 [SMILES: c1ccc(-c2cccc(-c3nc(-c4ccc5c(c4)oc4ccccc45)nc(-c4cccc5oc6ccc(-n7c8ccc(-c9ccccc9)cc8c8cc(-c9ccccc9)ccc87)cc6c45)n3)c2)cc1] | 1-759 |
| 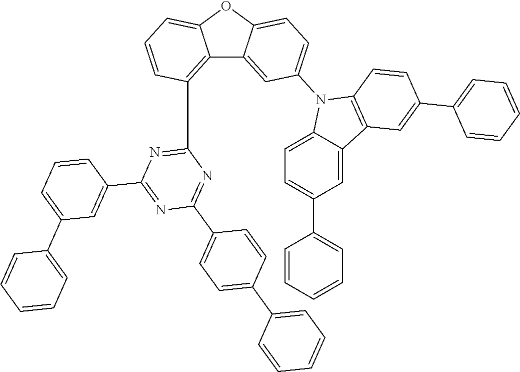 [SMILES: c1ccc(-c2ccc(-c3nc(-c4cccc(-c5ccccc5)c4)nc(-c4cccc5oc6ccc(-n7c8ccc(-c9ccccc9)cc8c8cc(-c9ccccc9)ccc87)cc6c45)n3)cc2)cc1] | 1-760 |
| 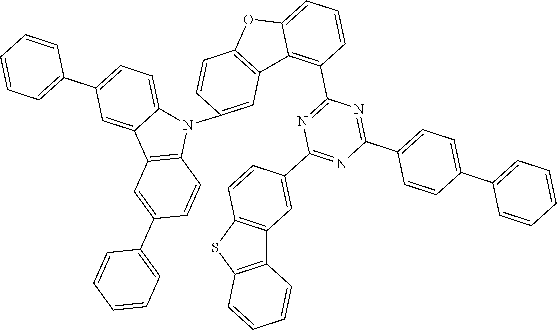 [SMILES: c1ccc(-c2ccc(-c3nc(-c4ccc5sc6ccccc6c5c4)nc(-c4cccc5oc6ccc(-n7c8ccc(-c9ccccc9)cc8c8cc(-c9ccccc9)ccc87)cc6c45)n3)cc2)cc1] | 1-761 |
| 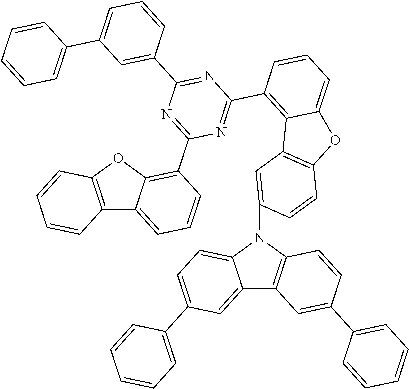 [SMILES: c1ccc(-c2cccc(-c3nc(-c4cccc5c4oc4ccccc45)nc(-c4cccc5oc6ccc(-n7c8ccc(-c9ccccc9)cc8c8cc(-c9ccccc9)ccc87)cc6c45)n3)c2)cc1] | 1-762 |
| 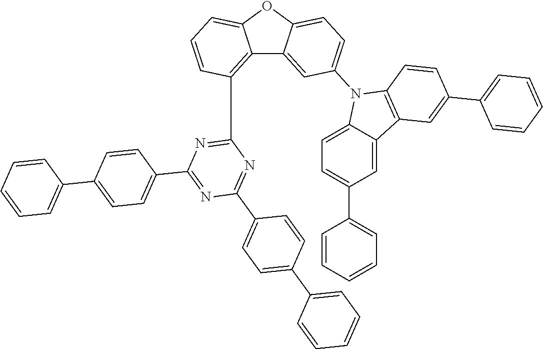 [SMILES: c1ccc(-c2ccc(-c3nc(-c4ccc(-c5ccccc5)cc4)nc(-c4cccc5oc6ccc(-n7c8ccc(-c9ccccc9)cc8c8cc(-c9ccccc9)ccc87)cc6c45)n3)cc2)cc1] | 1-763 |
| 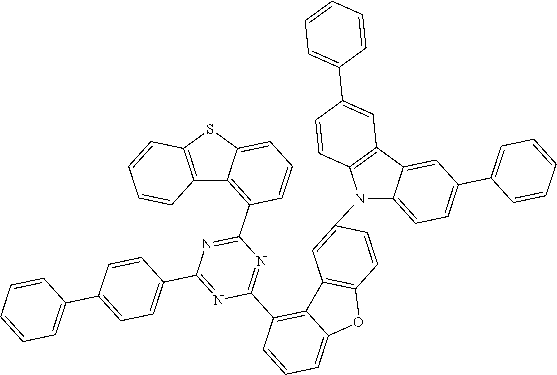 [SMILES: c1ccc(-c2ccc(-c3nc(-c4cccc5oc6ccc(-n7c8ccc(-c9ccccc9)cc8c8cc(-c9ccccc9)ccc87)cc6c45)nc(-c4cccc5sc6ccccc6c45)n3)cc2)cc1] | 1-764 |
| 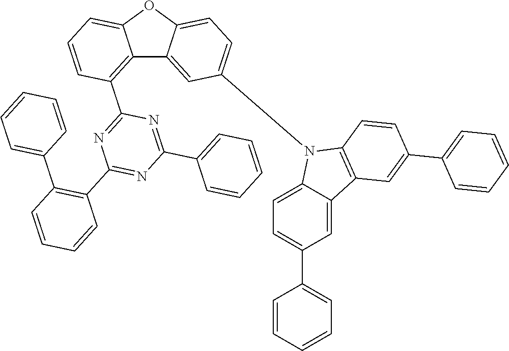 [SMILES: c1ccc(-c2ccc3c(c2)c2cc(-c4ccccc4)ccc2n3-c2ccc3oc4cccc(-c5nc(-c6ccccc6)nc(-c6ccccc6-c6ccccc6)n5)c4c3c2)cc1] | 1-765 |
| 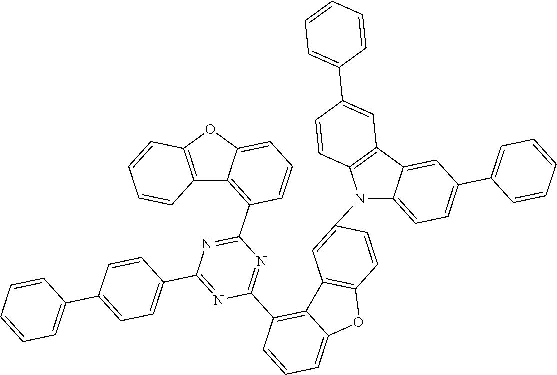 [SMILES: c1ccc(-c2ccc(-c3nc(-c4cccc5oc6ccccc6c45)nc(-c4cccc5oc6ccc(-n7c8ccc(-c9ccccc9)cc8c8cc(-c9ccccc9)ccc87)cc6c45)n3)cc2)cc1] | 1-766 |
| 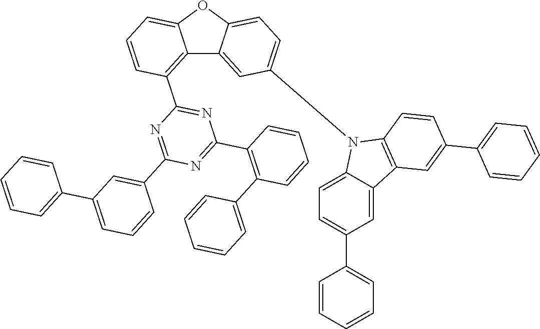 [SMILES: c1ccc(-c2cccc(-c3nc(-c4ccccc4-c4ccccc4)nc(-c4cccc5oc6ccc(-n7c8ccc(-c9ccccc9)cc8c8cc(-c9ccccc9)ccc87)cc6c45)n3)c2)cc1] | 1-767 |
| 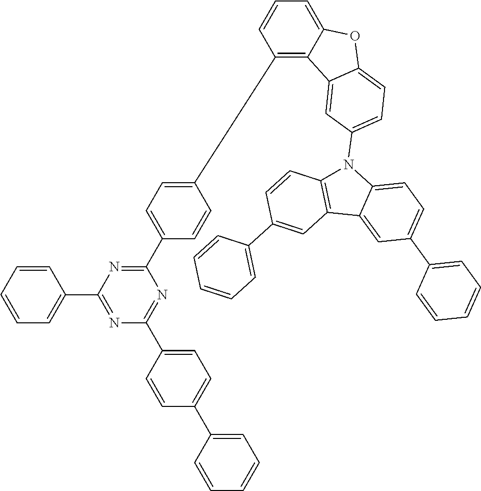 [SMILES: c1ccc(-c2ccc(-c3nc(-c4ccccc4)nc(-c4ccc(-c5cccc6oc7ccc(-n8c9ccc(-c%10ccccc%10)cc9c9cc(-c%10ccccc%10)ccc98)cc7c56)cc4)n3)cc2)cc1] | 1-768 |
| 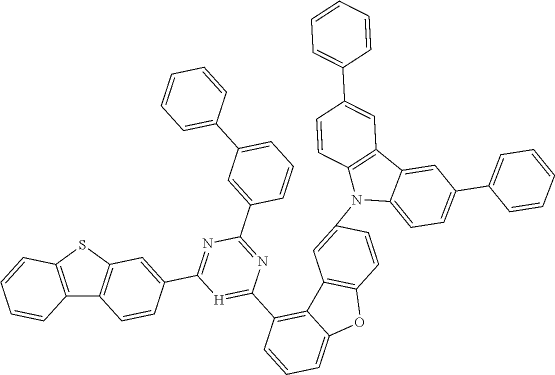 | 1-769 |
| 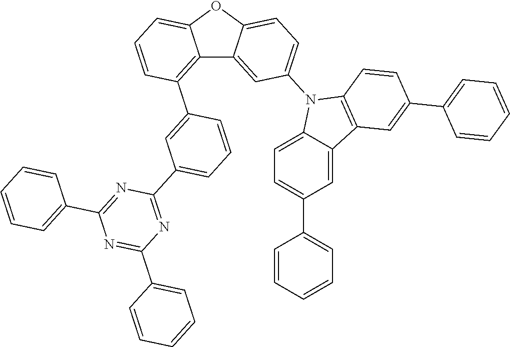 [SMILES: c1ccc(-c2ccc3c(c2)c2cc(-c4ccccc4)ccc2n3-c2ccc3oc4cccc(-c5cccc(-c6nc(-c7ccccc7)nc(-c7ccccc7)n6)c5)c4c3c2)cc1] | 1-770 |
| 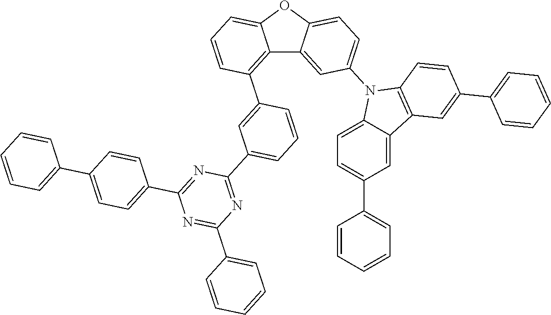 [SMILES: c1ccc(-c2ccc(-c3nc(-c4ccccc4)nc(-c4cccc(-c5cccc6oc7ccc(-n8c9ccc(-c%10ccccc%10)cc9c9cc(-c%10ccccc%10)ccc98)cc7c56)c4)n3)cc2)cc1] | 1-771 |
| 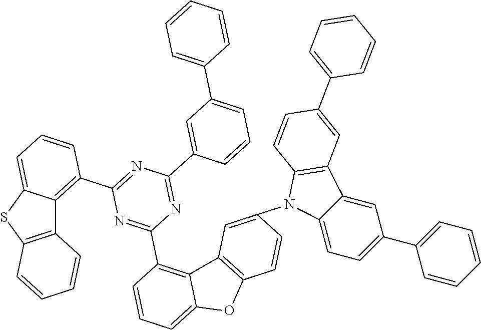 [SMILES: c1ccc(-c2cccc(-c3nc(-c4cccc5oc6ccc(-n7c8ccc(-c9ccccc9)cc8c8cc(-c9ccccc9)ccc87)cc6c45)nc(-c4cccc5sc6ccccc6c45)n3)c2)cc1] | 1-772 |
| 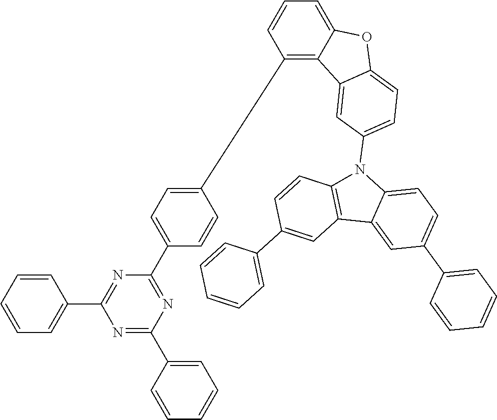 [SMILES: c1ccc(-c2ccc3c(c2)c2cc(-c4ccccc4)ccc2n3-c2ccc3oc4cccc(-c5ccc(-c6nc(-c7ccccc7)nc(-c7ccccc7)n6)cc5)c4c3c2)cc1] | 1-773 |
| 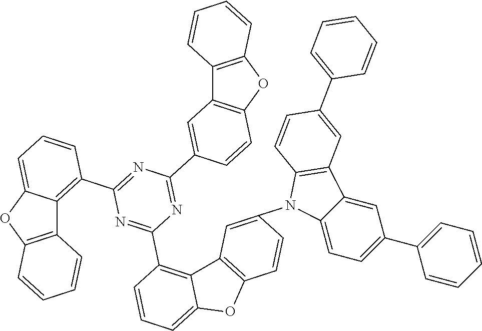 [SMILES: c1ccc(-c2ccc3c(c2)c2cc(-c4ccccc4)ccc2n3-c2ccc3oc4cccc(-c5nc(-c6ccc7oc8ccccc8c7c6)nc(-c6cccc7oc8ccccc8c67)n5)c4c3c2)cc1] | 1-774 |
| 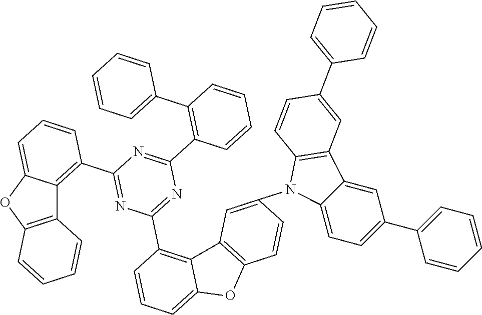 [SMILES: c1ccc(-c2ccc3c(c2)c2cc(-c4ccccc4)ccc2n3-c2ccc3oc4cccc(-c5nc(-c6ccccc6-c6ccccc6)nc(-c6cccc7oc8ccccc8c67)n5)c4c3c2)cc1] | 1-775 |
| 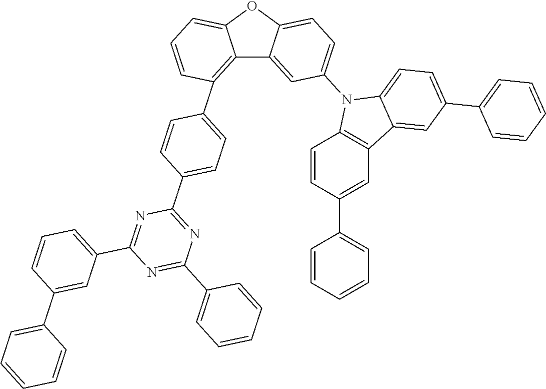 [SMILES: c1ccc(-c2cccc(-c3nc(-c4ccccc4)nc(-c4ccc(-c5cccc6oc7ccc(-n8c9ccc(-c%10ccccc%10)cc9c9cc(-c%10ccccc%10)ccc98)cc7c56)cc4)n3)c2)cc1] | 1-776 |
| 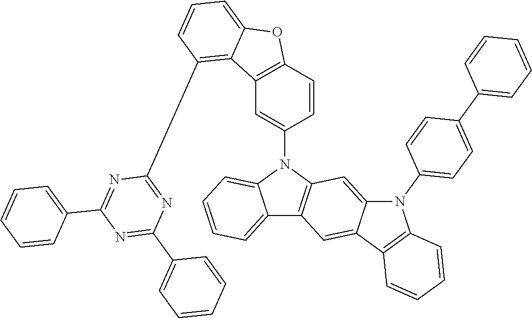 [SMILES: c1ccc(-c2ccc(-n3c4ccccc4c4cc5c6ccccc6n(-c6ccc7oc8cccc(-c9nc(-c%10ccccc%10)nc(-c%10ccccc%10)n9)c8c7c6)c5cc43)cc2)cc1] | 1-777 |
| 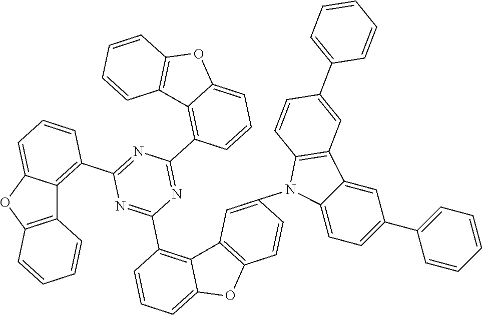 [SMILES: c1ccc(-c2ccc3c(c2)c2cc(-c4ccccc4)ccc2n3-c2ccc3oc4cccc(-c5nc(-c6cccc7oc8ccccc8c67)nc(-c6cccc7oc8ccccc8c67)n5)c4c3c2)cc1] | 1-778 |
| 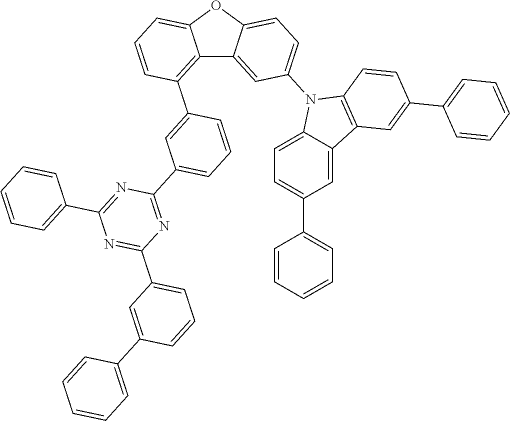 [SMILES: c1ccc(-c2cccc(-c3nc(-c4ccccc4)nc(-c4cccc(-c5cccc6oc7ccc(-n8c9ccc(-c%10ccccc%10)cc9c9cc(-c%10ccccc%10)ccc98)cc7c56)c4)n3)c2)cc1] | 1-779 |
| 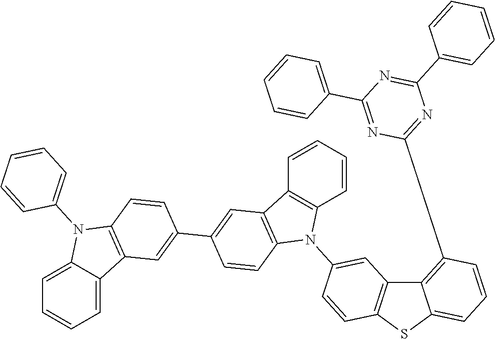 [SMILES: c1ccc(-c2nc(-c3ccccc3)nc(-c3cccc4sc5ccc(-n6c7ccccc7c7cc(-c8ccc9c(c8)c8ccccc8n9-c8ccccc8)ccc76)cc5c34)n2)cc1] | 1-780 |
| 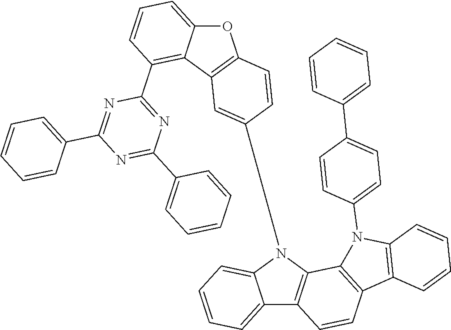 [SMILES: c1ccc(-c2ccc(-n3c4ccccc4c4ccc5c6ccccc6n(-c6ccc7oc8cccc(-c9nc(-c%10ccccc%10)nc(-c%10ccccc%10)n9)c8c7c6)c5c43)cc2)cc1] | 1-781 |
| 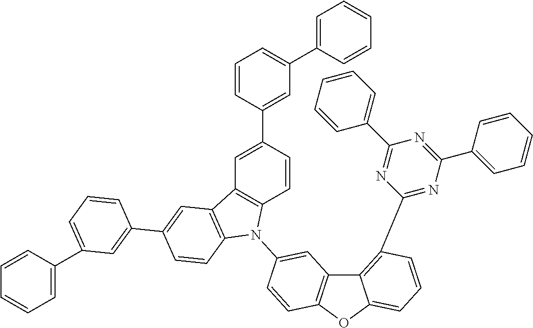 [SMILES: c1ccc(-c2cccc(-c3ccc4c(c3)c3cc(-c5cccc(-c6ccccc6)c5)ccc3n4-c3ccc4oc5cccc(-c6nc(-c7ccccc7)nc(-c7ccccc7)n6)c5c4c3)c2)cc1] | 1-782 |
| 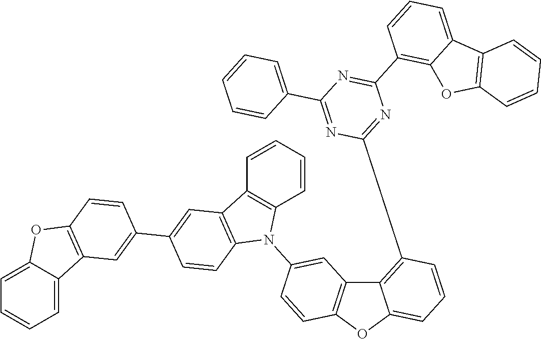 [SMILES: c1ccc(-c2nc(-c3cccc4c3oc3ccccc34)nc(-c3cccc4oc5ccc(-n6c7ccccc7c7cc(-c8ccc9oc%10ccccc%10c9c8)ccc76)cc5c34)n2)cc1] | 1-783 |
| 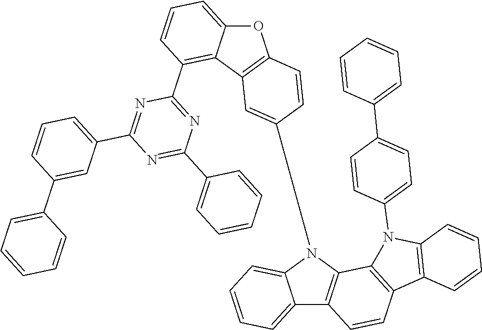 [SMILES: c1ccc(-c2ccc(-n3c4ccccc4c4ccc5c6ccccc6n(-c6ccc7oc8cccc(-c9nc(-c%10ccccc%10)nc(-c%10cccc(-c%11ccccc%11)c%10)n9)c8c7c6)c5c43)cc2)cc1] | 1-784 |
| 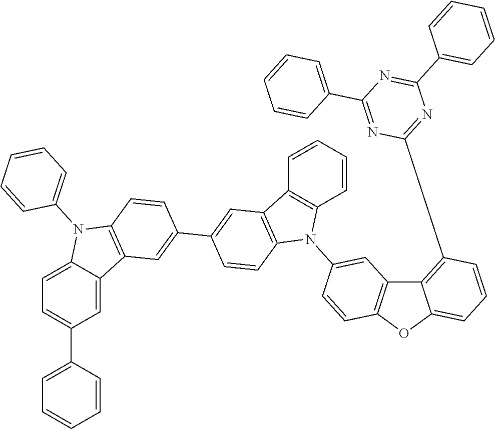 [SMILES: c1ccc(-c2ccc3c(c2)c2cc(-c4ccc5c(c4)c4ccccc4n5-c4ccc5oc6cccc(-c7nc(-c8ccccc8)nc(-c8ccccc8)n7)c6c5c4)ccc2n3-c2ccccc2)cc1] | 1-785 |
| 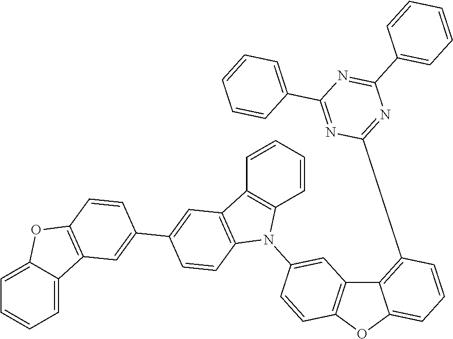 [SMILES: c1ccc(-c2nc(-c3ccccc3)nc(-c3cccc4oc5ccc(-n6c7ccccc7c7cc(-c8ccc9oc%10ccccc%10c9c8)ccc76)cc5c34)n2)cc1] | 1-786 |
| 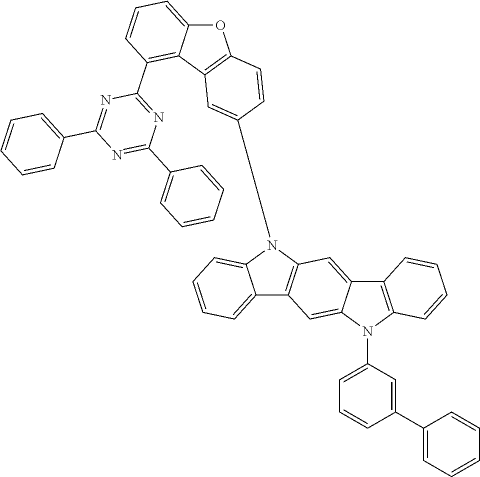 [SMILES: c1ccc(-c2cccc(-n3c4ccccc4c4cc5c(cc43)c3ccccc3n5-c3ccc4oc5cccc(-c6nc(-c7ccccc7)nc(-c7ccccc7)n6)c5c4c3)c2)cc1] | 1-787 |
| 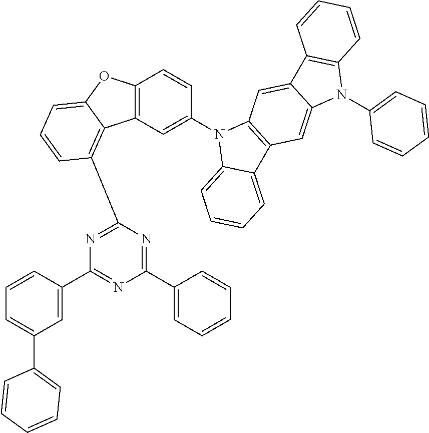 [SMILES: c1ccc(-c2cccc(-c3nc(-c4ccccc4)nc(-c4cccc5oc6ccc(-n7c8ccccc8c8cc9c(cc87)c7ccccc7n9-c7ccccc7)cc6c45)n3)c2)cc1] | 1-788 |
| 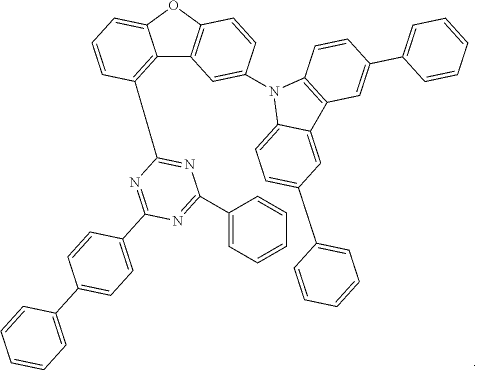 [SMILES: c1ccc(-c2ccc(-c3nc(-c4ccccc4)nc(-c4cccc5oc6ccc(-n7c8ccc(-c9ccccc9)cc8c8cc(-c9ccccc9)ccc87)cc6c45)n3)cc2)cc1] | 1-789 |

Particularly suitable compounds of the formulae (1), (1a), (1b), (1c), (1d), (1e), (1f), (1g) or (1h) that are selected in accordance with the invention are the compounds 1 to 36 and 67 to 81:

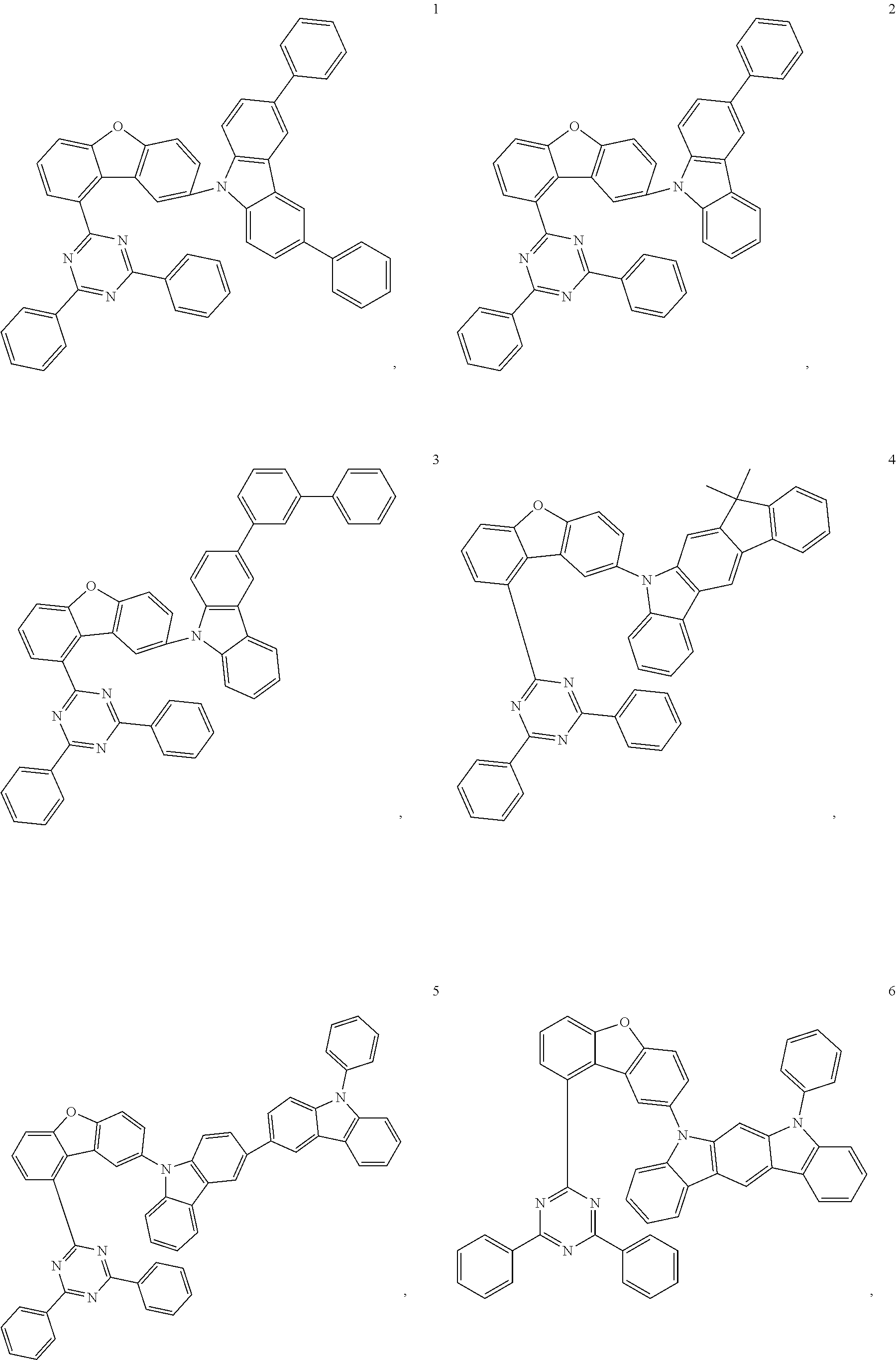

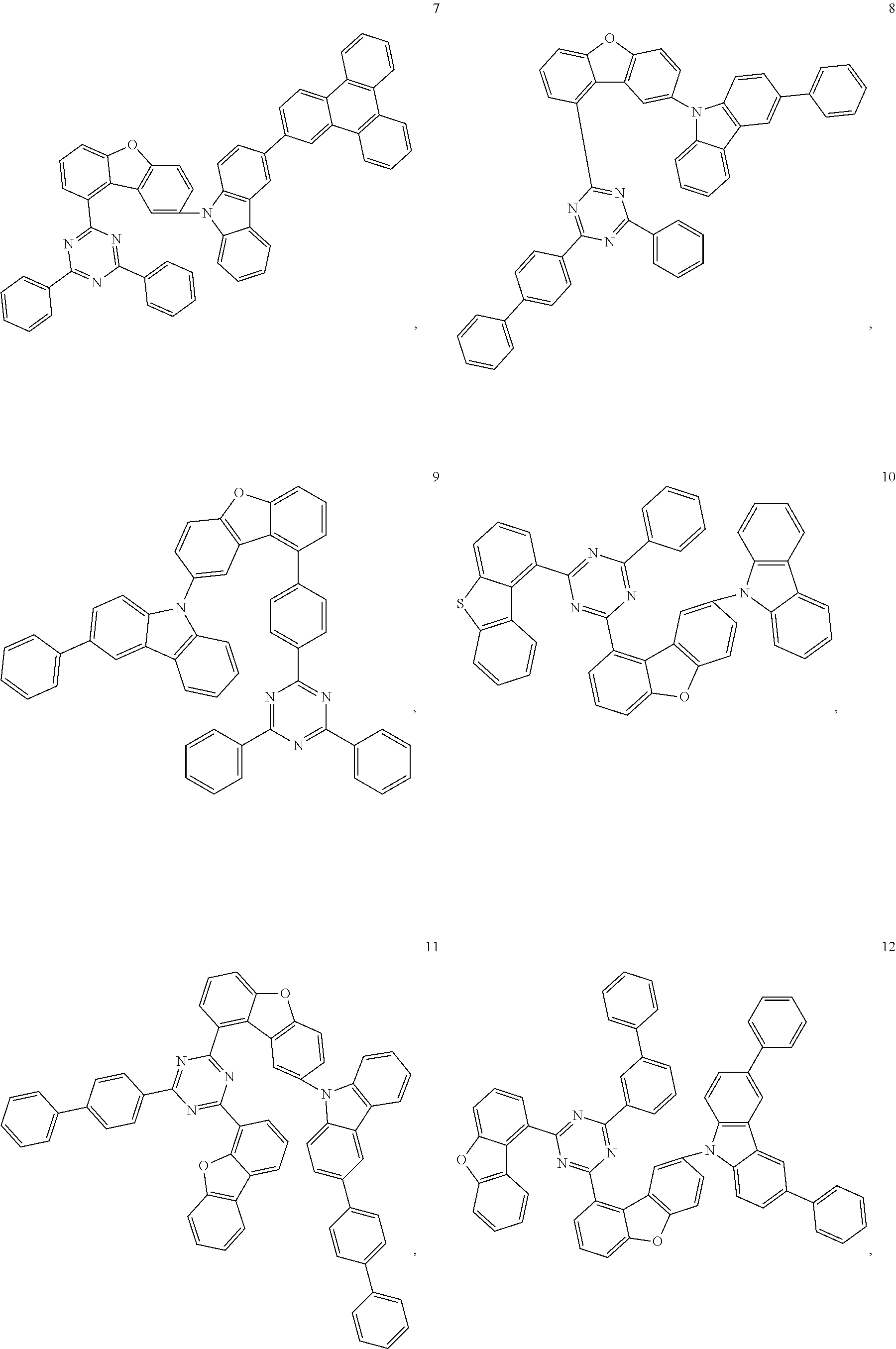

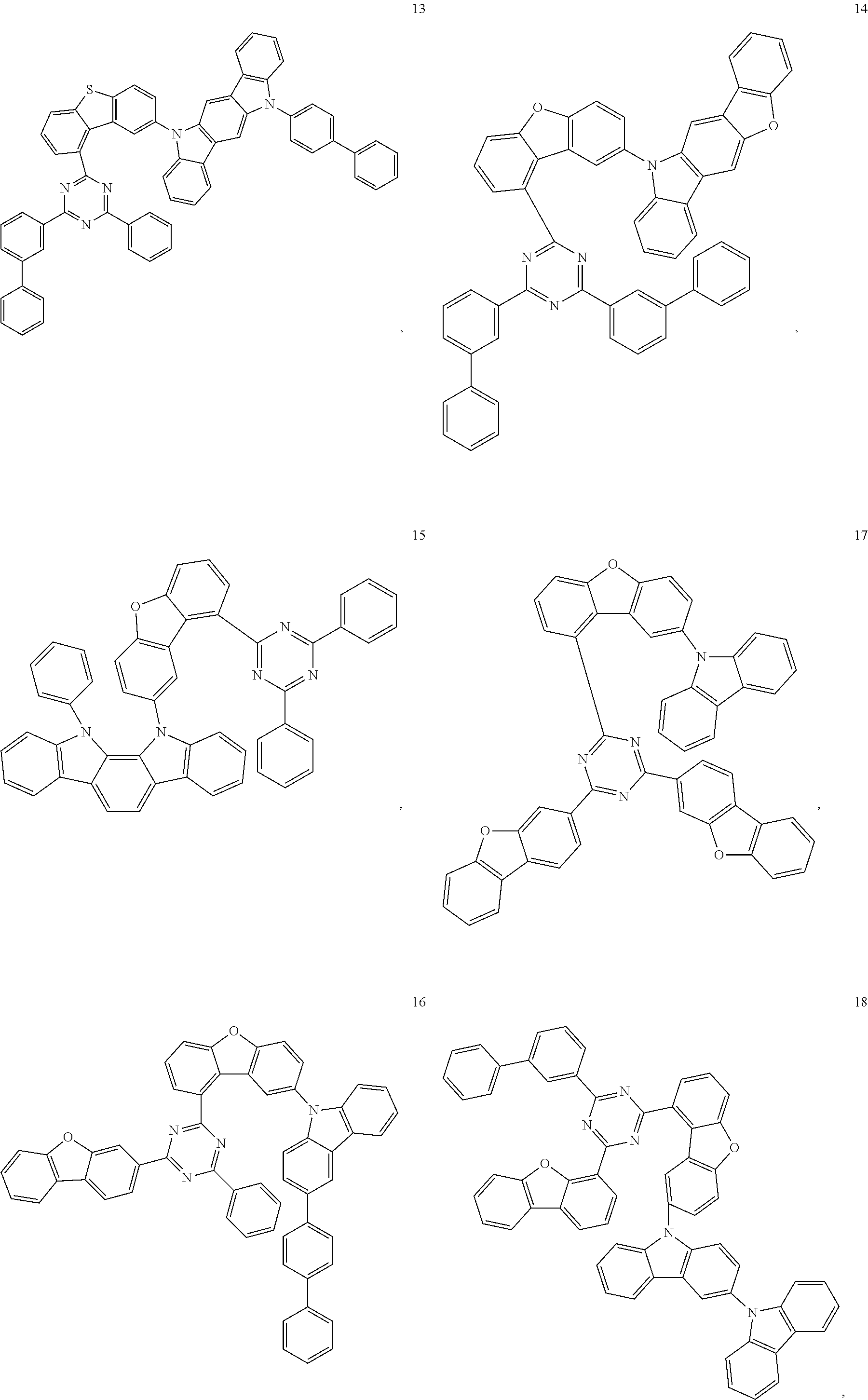

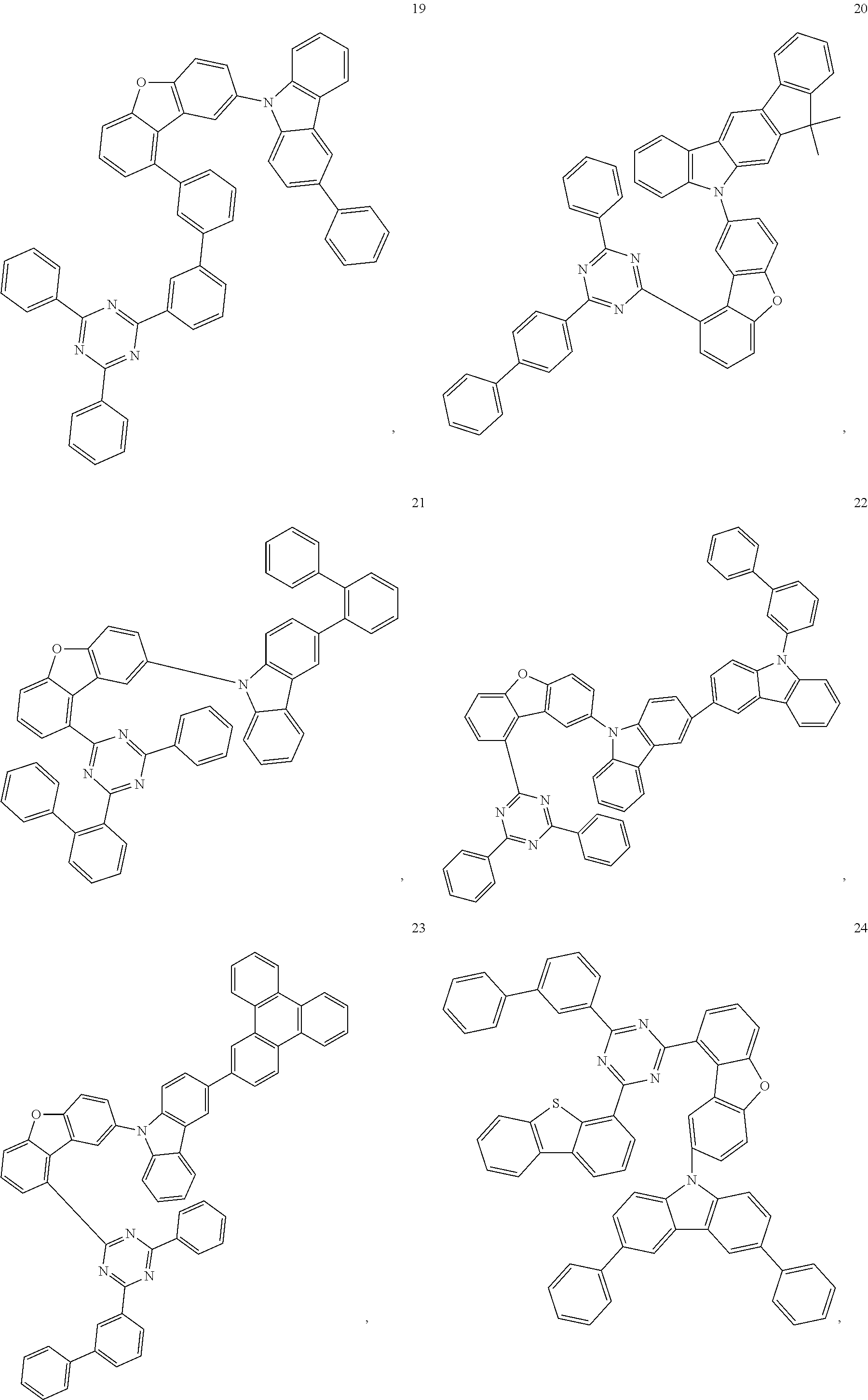

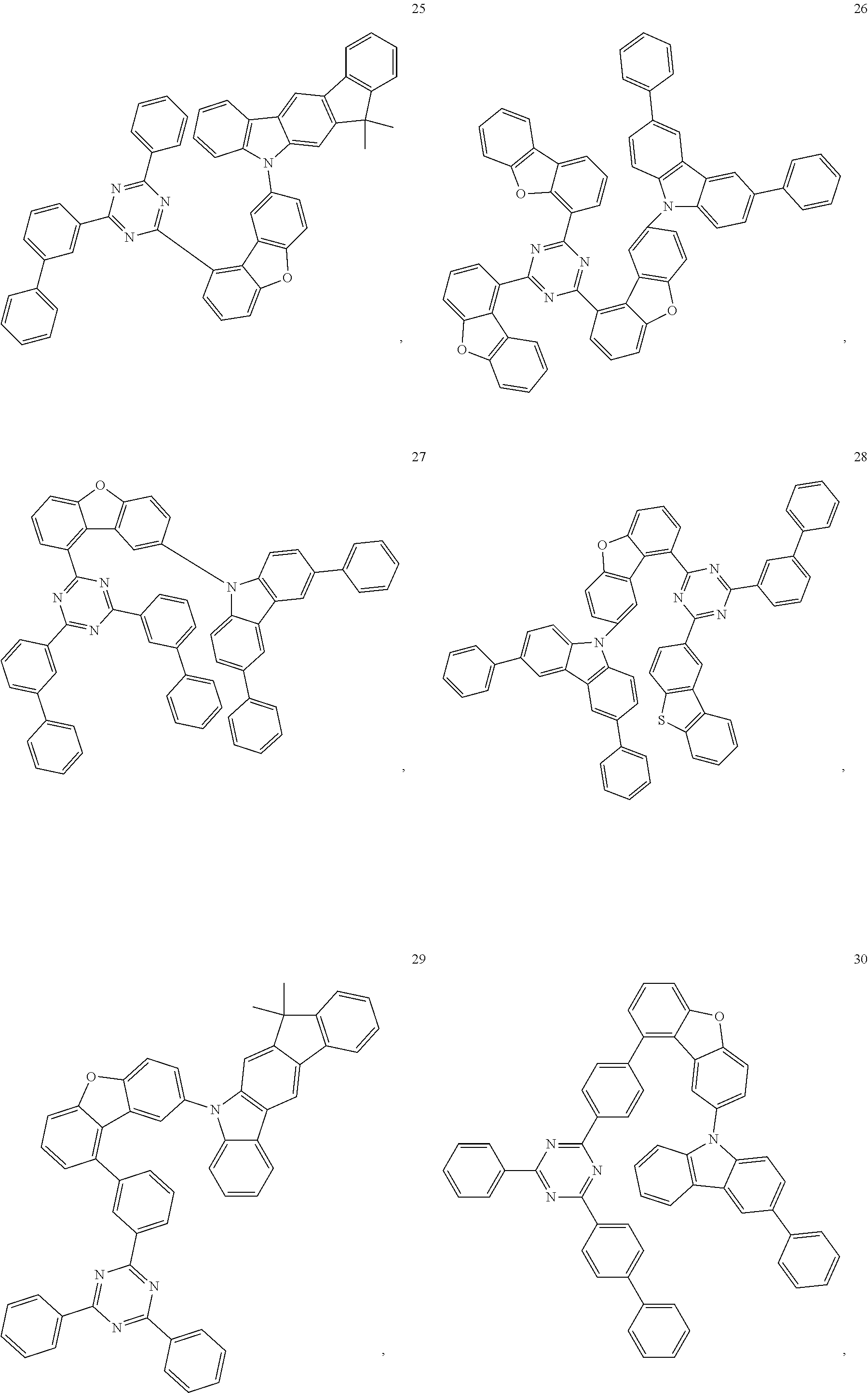

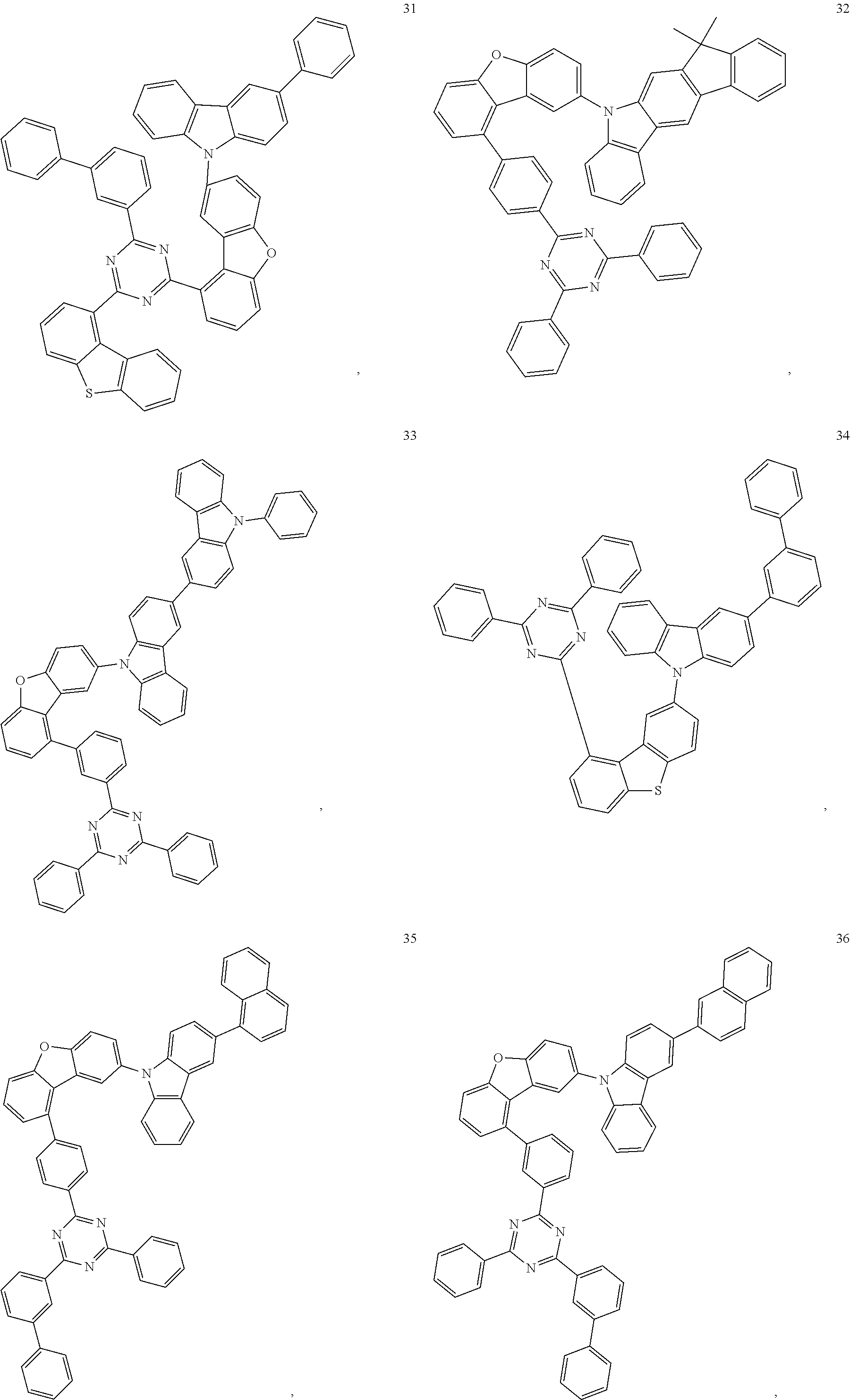

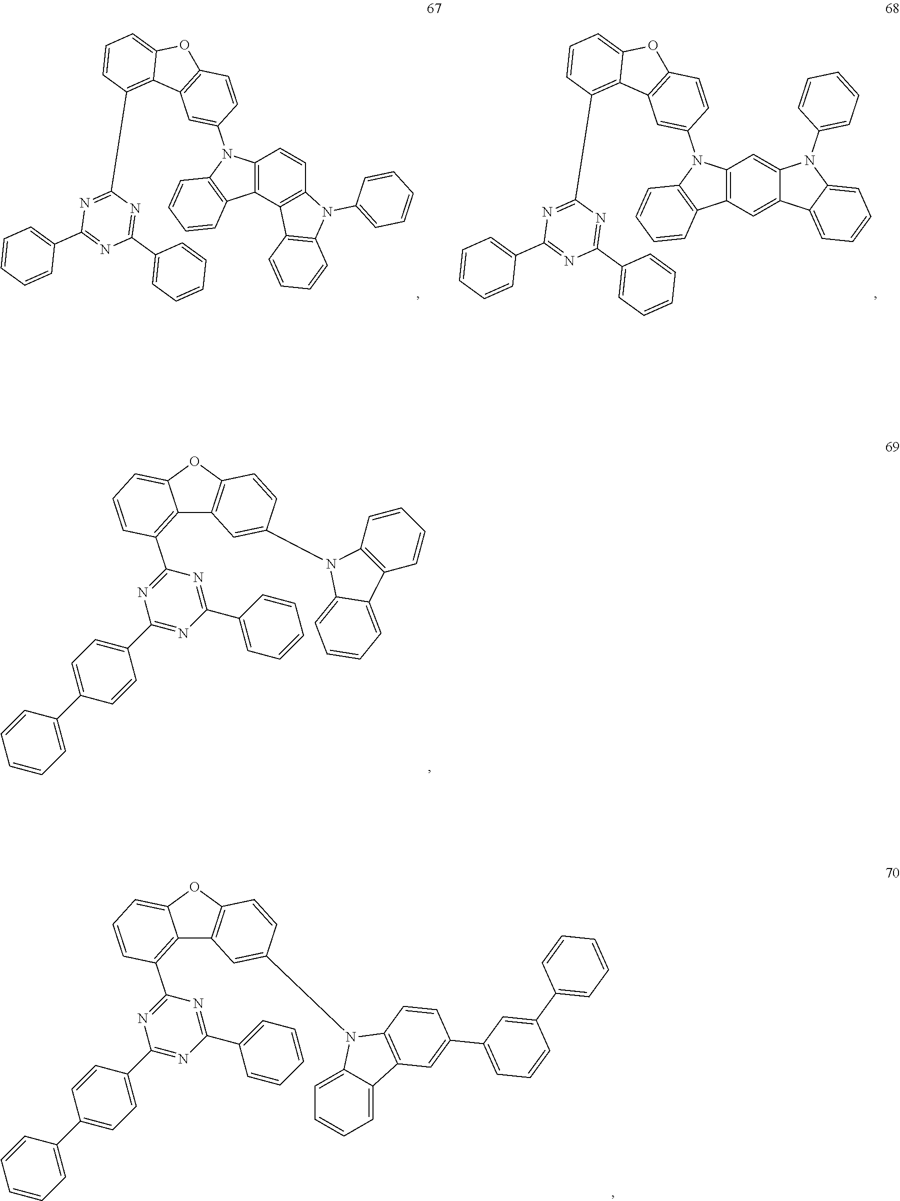 [SMILES: c1ccc(-c2nc(-c3ccccc3)nc(-c3cccc4oc5ccc(-n6c7ccccc7c7c8c9ccccc9n(-c9ccccc9)c8ccc76)cc5c34)n2)cc1 ; c1ccc(-c2nc(-c3ccccc3)nc(-c3cccc4oc5ccc(-n6c7ccccc7c7cc8c9ccccc9n(-c9ccccc9)c8cc76)cc5c34)n2)cc1 ; c1ccc(-c2ccc(-c3nc(-c4ccccc4)nc(-c4cccc5oc6ccc(-n7c8ccccc8c8ccccc87)cc6c45)n3)cc2)cc1 ; c1ccc(-c2ccc(-c3nc(-c4ccccc4)nc(-c4cccc5oc6ccc(-n7c8ccccc8c8cc(-c9cccc(-c%10ccccc%10)c9)ccc87)cc6c45)n3)cc2)cc1]

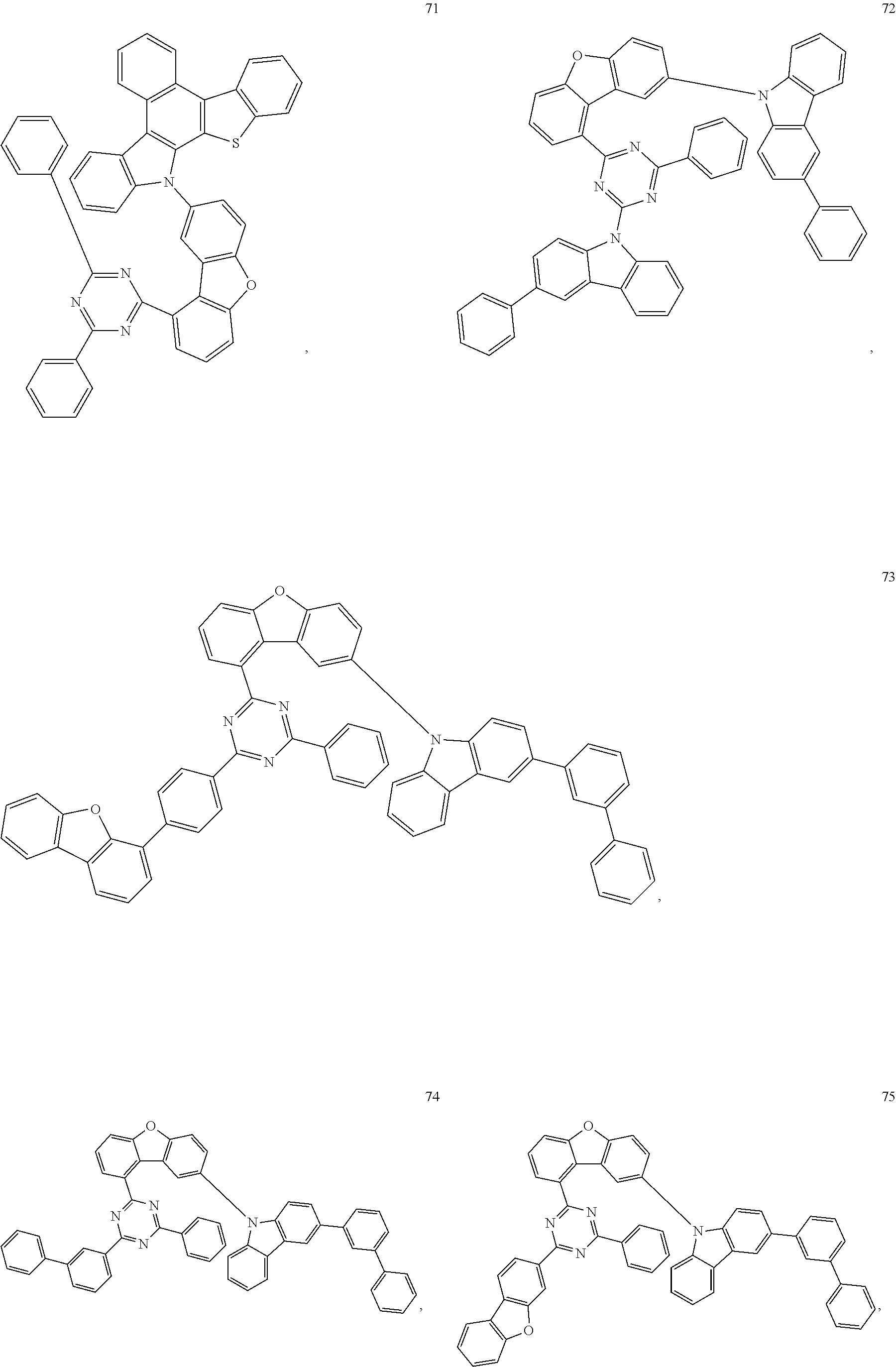

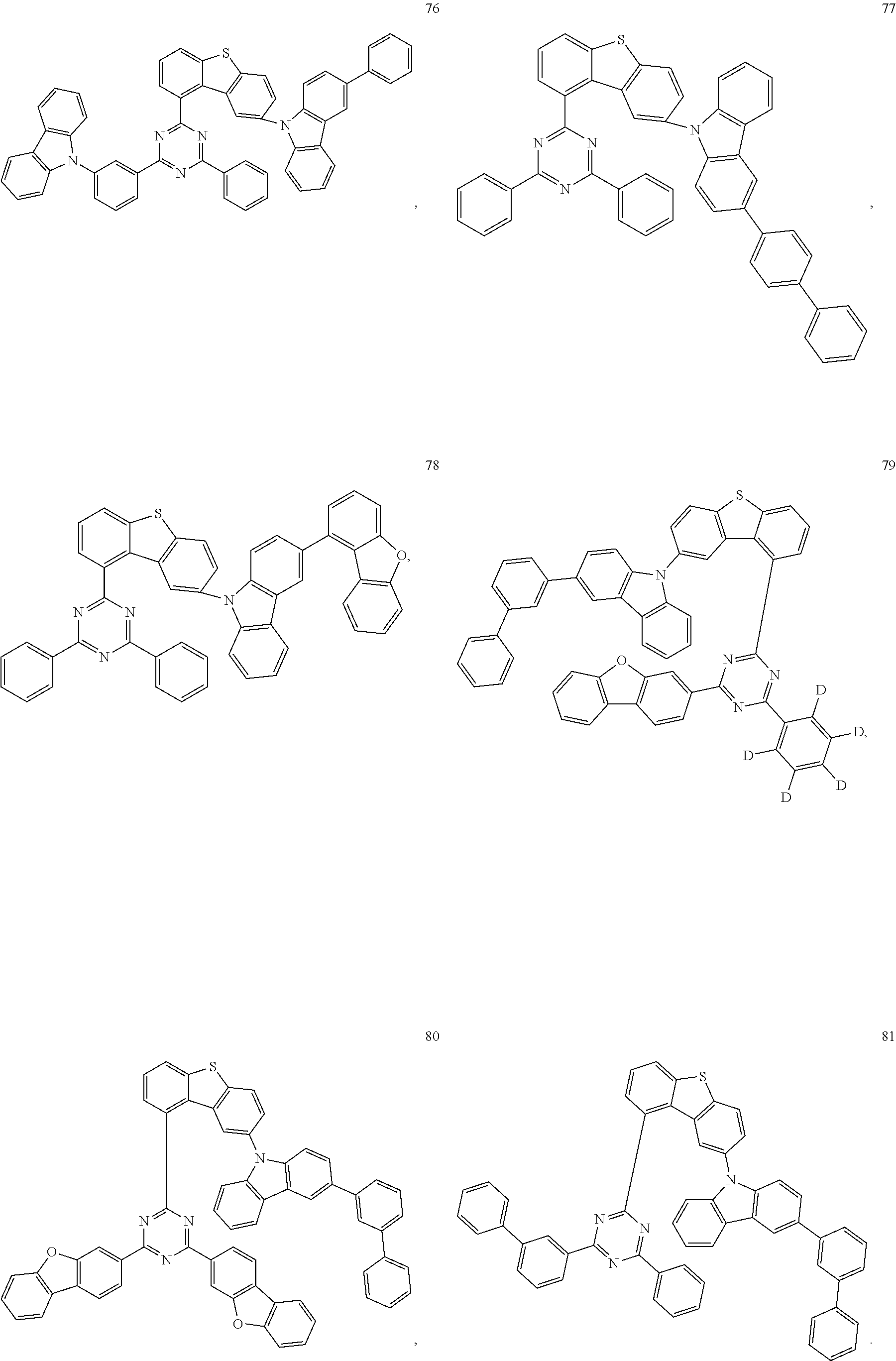

The preparation of the compounds of the formula (1) or of the preferred compounds of the formulae (1a) to (1h) and the compounds 1 to 36 and 67 to 81 is known to those skilled in the art. The compounds may be prepared by synthesis steps known to the person skilled in the art, for example halogenation, preferably bromination, and a subsequent organometallic coupling reaction, for example Suzuki coupling, Heck coupling or Hartwig-Buchwald coupling. The preparation of the compounds of the formula (1) or of the preferred compounds of the formulae (1a) to (1h) and of the compounds 1 to 36 and 67 to 81 can be inferred especially from WO 2016/015810, especially page 35 and the synthesis examples on pages 44 to 64.

The compounds of the formulae (1) to (1h) can be prepared according to Scheme 1 below, where L, X₁, Y, R, R¹, Ar₁, n, m, o, p has one of the definitions given above.

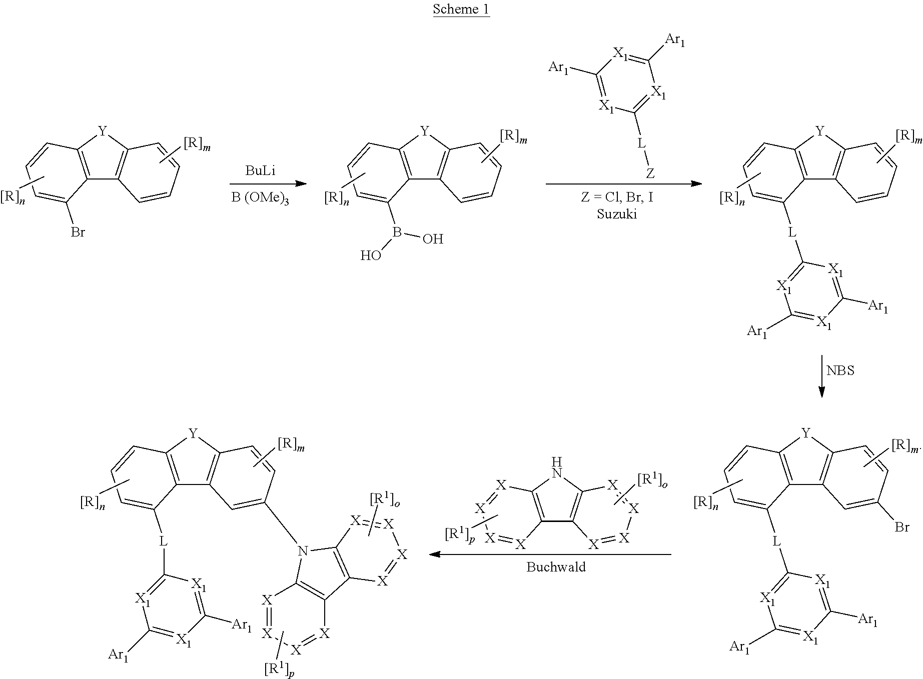

There follows a description of compounds of the formula (2) and preferred embodiments thereof that are present in the composition and/or apparatus according to the invention, for example as hole-transporting hosts.

The composition according to the invention contains at least one compound of the formula (2)

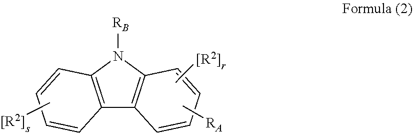

where the symbols and indices used are as follows:
R_{A} is H, -L₃-Ar₄ or -L₁-N(Ar)₂;
R_{B} is Ar₃ or -L₂-N(Ar)₂;
L₁, L₂ are the same or different at each instance and are a single bond or an aromatic or heteroaromatic ring system which has 5 to 30 aromatic ring atoms and may be substituted by one or more R³ radicals;
L₃ is a single bond or an aromatic or heteroaromatic ring system which has 5 to 30 aromatic ring atoms and may be substituted by one or more R³ radicals, where one substituent R³ may form a ring with a substituent R² on the carbazole;
Ar₃ is an aromatic ring system having 6 to 40 aromatic ring atoms or a heteroaromatic ring system having 10 to 40 aromatic ring atoms, which may be substituted by one or more R³ radicals;
Ar₄ is the same or different at each instance and is an unsubstituted or substituted 9-arylcarbazolyl or unsubstituted or substituted carbazol-9-yl, which may be substituted by one or more R⁴ radicals, and where one or more instances each of two R⁴ radicals or one R⁴ radical together with one R² radical may independently form a monocyclic or polycyclic, aliphatic, aromatic or heteroaromatic ring, where aryl is an aromatic or heteroaromatic ring system which has 5 to 30 aromatic ring atoms and may be substituted by R³;
R² is the same or different at each instance and is selected from the group consisting of H, D, F, Cl, Br, I, CN, NO₂, N(Ar)₂, N(R³)₂, C(═O)Ar, C(═O)R³, P(═O)(Ar)₂, P(Ar)₂, B(Ar)₂, Si(Ar)₃, Si(R³)₃, a straight-chain alkyl, alkoxy or thioalkyl group having 1 to 20 carbon atoms or a branched or cyclic alkyl, alkoxy or thioalkyl group having 3 to 20 carbon atoms or an alkenyl group having 2 to 20 carbon atoms, each of which may be substituted by one or more R³ radicals, where one or more nonadjacent CH₂ groups may be replaced by R³C═CR³, Si(R³)₂, C═O, C═S, C═NR³, P(═O)(R³), SO, SO₂, NR³, O, S or CONR³ and where one or more hydrogen atoms may be replaced by D, F, Cl, Br, I, CN or NO₂, an aromatic or heteroaromatic ring system which has 5 to 40 ring atoms and may be substituted in each case by one or more R³ radicals, an aryloxy or heteroaryloxy group which has 5 to 40 aromatic ring atoms and may be substituted by one or more R³ radicals, or an aralkyl or heteroaralkyl group which has 5 to 40 ring atoms and may be substituted by one or more R³ radicals; at the same time, it is optionally possible for two substituents R² bonded to the same carbon atom or to adjacent carbon atoms to form a monocyclic or polycyclic, aliphatic, aromatic or heteroaromatic ring system which may be substituted by one or more R³ radicals;
R³ is the same or different at each instance and is selected from the group consisting of H, D, F, CN, N(Ar)₂, an aliphatic hydrocarbyl radical having 1 to 20 carbon atoms, or an aromatic or heteroaromatic ring system having 5 to 30 aromatic ring atoms in which one or more hydrogen atoms may be replaced by D, F, Cl, Br, I or CN and which may be substituted by one or more alkyl groups each having 1 to 4 carbon atoms; at the same time, it is possible for two or more adjacent R³ substituents together to form a mono- or polycyclic, aliphatic ring system;
R⁴ is the same or different at each instance and is selected from the group consisting of H, D, F, CN, an aliphatic hydrocarbyl radical having 1 to 20 carbon atoms, or an aromatic or heteroaromatic ring system having 5 to 30 aromatic ring atoms in which one or more hydrogen atoms may be replaced by D, F, Cl, Br, I, a straight-chain or branched alkyl group having 1 to 4 carbon atoms or CN; at the same time, two or more adjacent R⁴ substituents together may form a mono- or polycyclic ring system;
Ar is the same or different at each instance and is an aromatic or heteroaromatic ring system which has 5 to 30 aromatic ring atoms and may be substituted by one or more nonaromatic R³ radicals; at the same time, two Ar radicals bonded to the same nitrogen atom, phosphorus atom or boron atom may also be bridged to one another by a single bond or a bridge selected from N(R³), C(R³)₂, O and S, and
r at each instance is independently 0, 1, 2 or 3;
s at each instance is independently 0, 1, 2, 3 or 4.

In one embodiment of the invention, compounds of the formula (2) as described above are selected, which are used in the composition together with compounds of the formulae (1), (1a), (1b), (1c), (1d), (1e), (1f), (1g) and (1h) as described above or described as preferred, or with the compounds in Table 1 or compounds 1 to 36 and 67 to 81.

Compounds of the formula (2) may be represented by the following formulae (2a), (2b), (2c) and (2d):

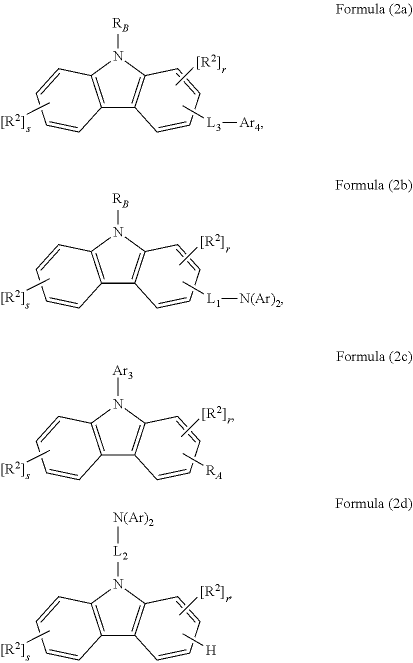

where L₁, L₂, L₃, Ar, Ar₃, Ar₄, R², r and s have a definition given above or definition given hereinafter.

Preferred compounds of the formula (2) or (2a) are compounds of the formulae (2e), (2f), (2g), (2h) and (2i)

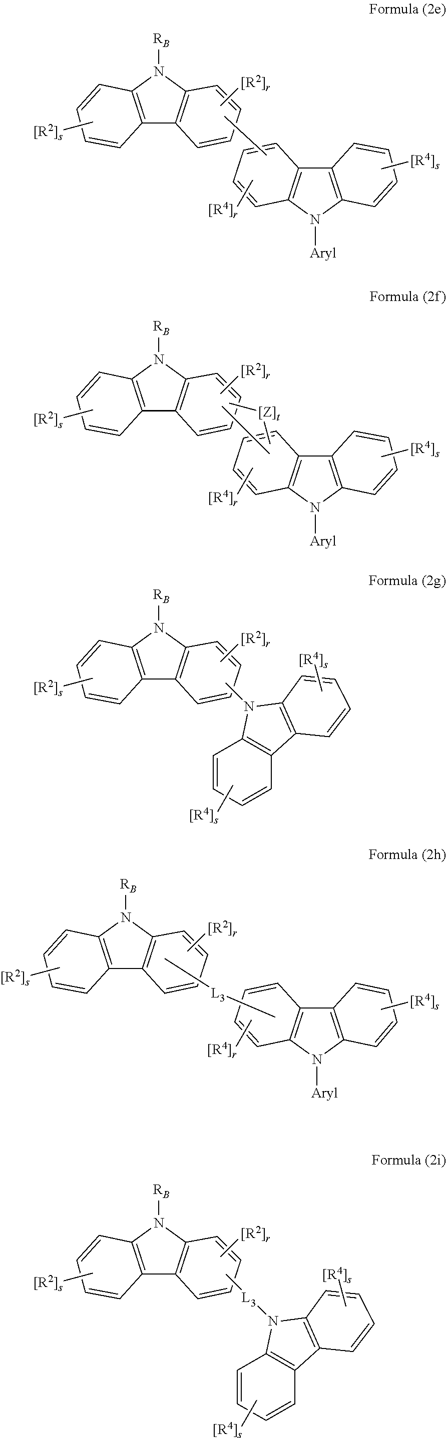

where R_{B}, Ar₃, aryl, R², R⁴, r and s have a definition given above or given hereinafter, L₃ in the formulae (2h) and (2i) is an aromatic or heteroaromatic ring system which has 5 to 30 aromatic ring atoms and may be substituted by one or more R³ radicals, where one substituent R² on the carbazole may form a ring with a substituent R³, Z is C(R³)₂, N—Ar, O or S and t is 0 or 1.

Preferred compounds of the formula (2) or (2c) in which at least r is 1 are compounds of the formulae (2j), (2k), (2l),

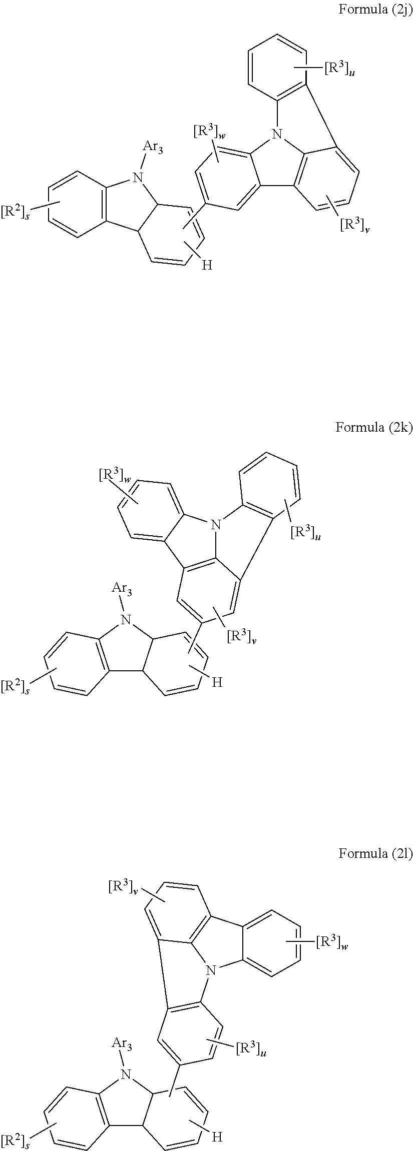

where Ar₃, R², R³ and s have a definition given above or definition given as preferred, and u, v and w independently at each instance are 0 or 1.

R³ in the compounds of the formulae (2j), (2k) and (2l) is preferably H or an aromatic or heteroaromatic ring system which has 5 to 40 ring atoms and may be substituted by R⁵. If u, v and/or w is 1, R³ in the compounds of the formulae (2j), (2k) and (2l) is preferably phenyl. In preferred compounds of the formulae (2j), (2k) and (2l), one index u, v or w is 1. More preferably, u, v and w are 0.

In compounds of the formulae (2a) to (2l), H is excluded from the definition of the substituents R² when r and/or s is/are greater than 1.

The invention accordingly further provides a composition as described above, wherein the compound of the formula (2) corresponds to one of the compounds of the formulae (2a), (2b), (2c), (2d), (2e), (2f), (2g), (2h), (2i), (2j), (2k) and (2l).

In the compounds of the formulae (2), (2a), (2b), (2c), (2d), (2e), (2f), (2g), (2h) and (2i), one substituent R² and one substituent R⁴ may form a ring, for example also defined by [Z]ₜ in formula (2f), preferably forming the following rings Z-1 to Z-7, and where the dotted lines in each case represent the bond to the carbazoles:

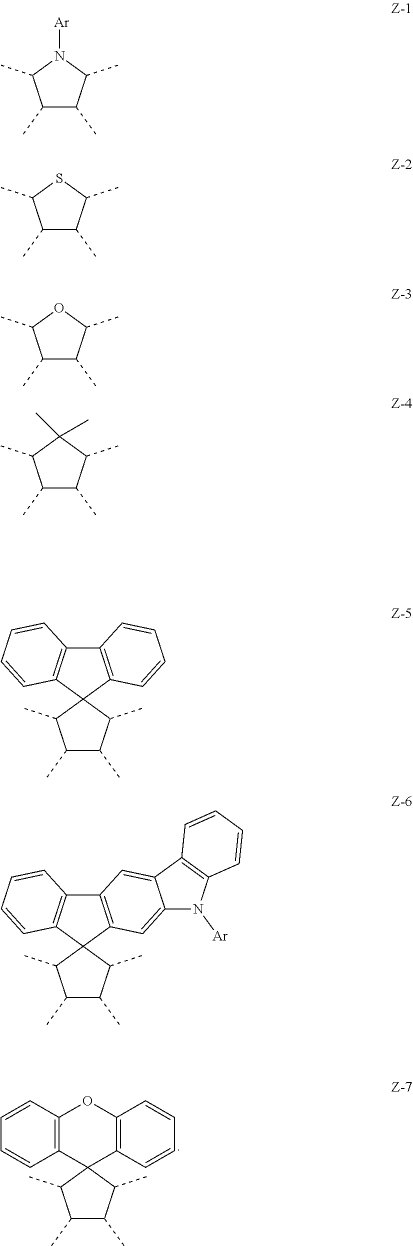

In the compounds of the formulae (2), (2a), (2b), (2c), (2d), (2e), (2f), (2g), (2h), (2i), (2j) and (2l), two substituents R² in one or more instances may together form a ring or two substituents R⁴, if present, in one or more instances may together form a ring, where this ring is in each case independently preferably selected from the following structures (S1) to (S9), where # and # represent the respective bonding site to the carbon atoms and the structures may each be substituted by one or more substituents R³:

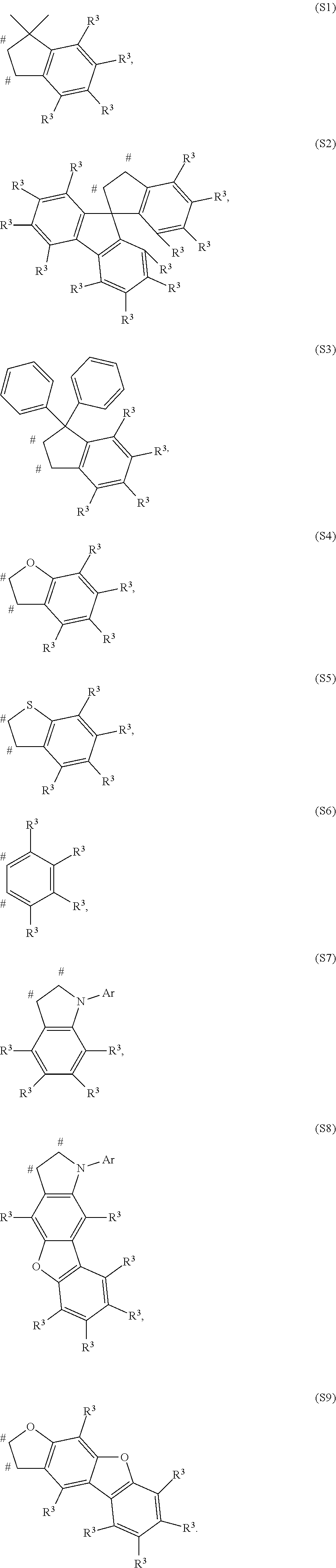

R³ in the substructures (S1) to (S9) is preferably H or an aromatic or heteroaromatic ring system which has 5 to 40 ring atoms and may be substituted by R⁵, preferably H or phenyl.

In the compounds of the formulae (2), (2a), (2b), (2c), (2d), (2e), (2f), (2g), (2h) and (2i), the linkers L₁, L₂ and L₃, if they are not a single bond, are each independently selected from the linkers L-2.1 to L-2.33:

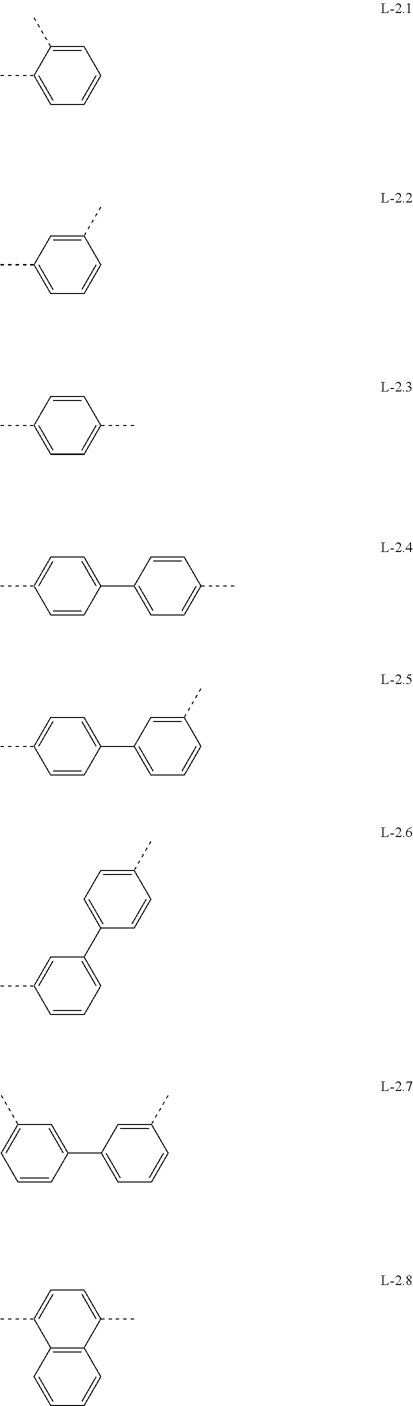

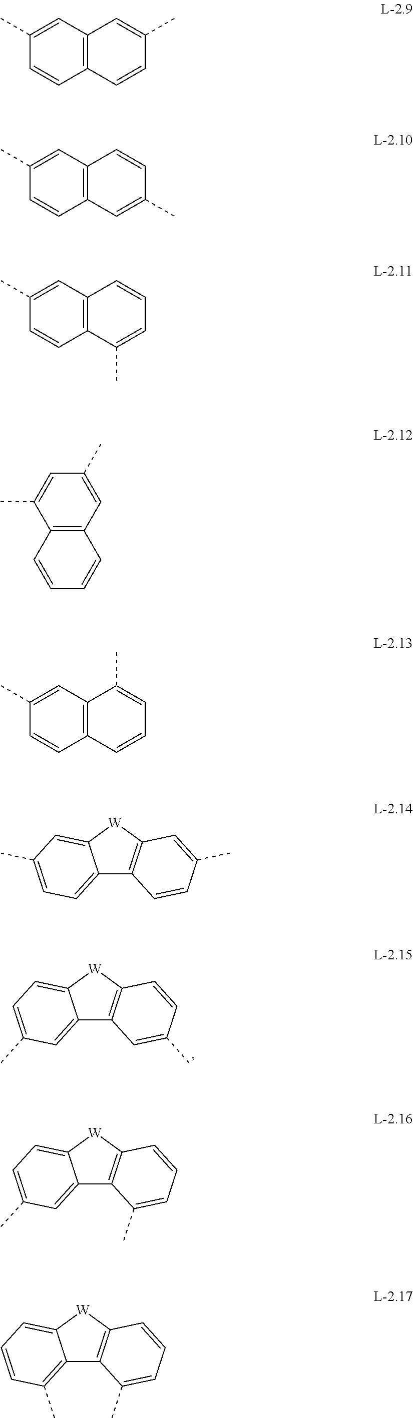

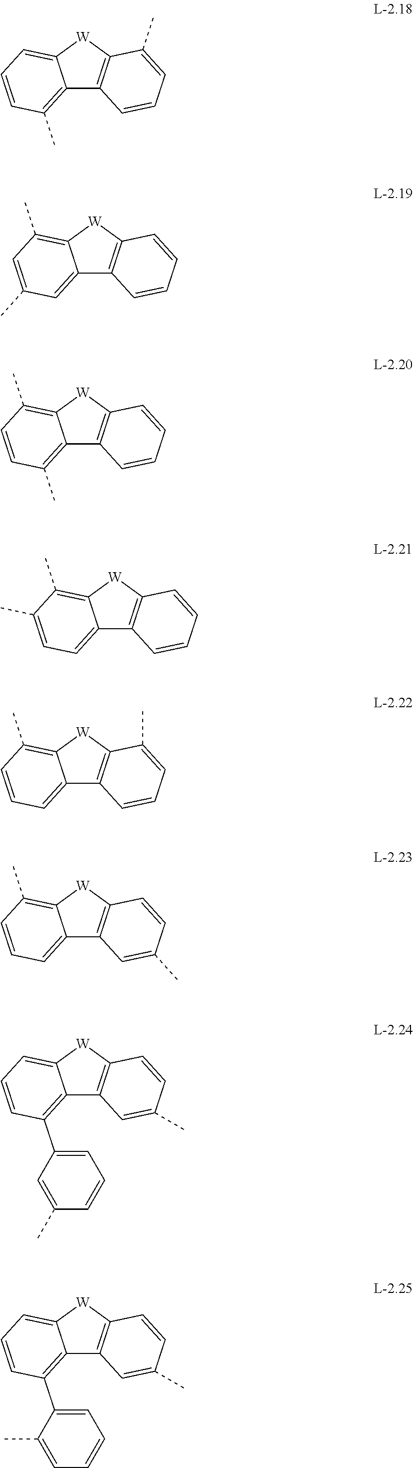

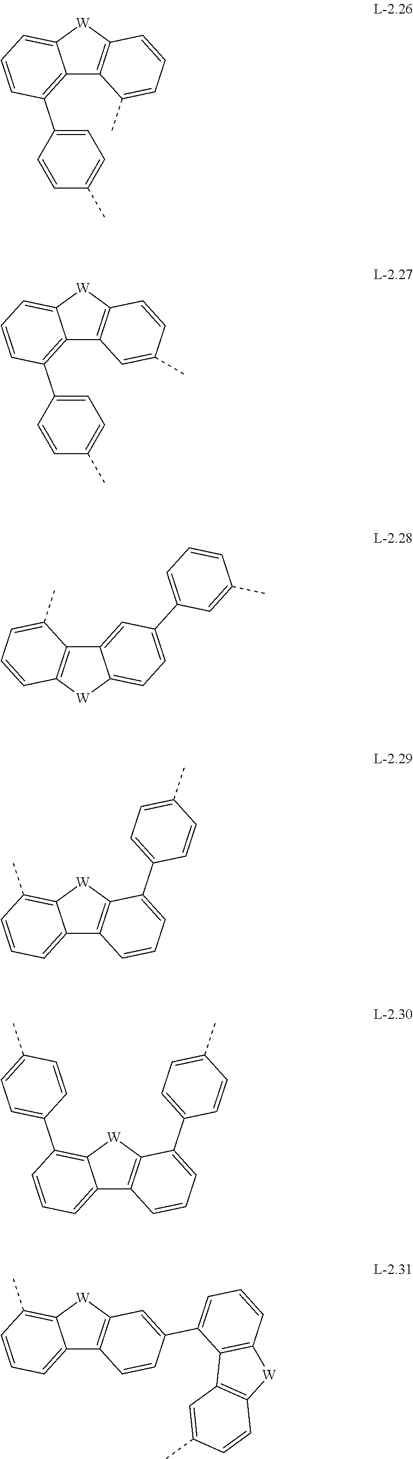

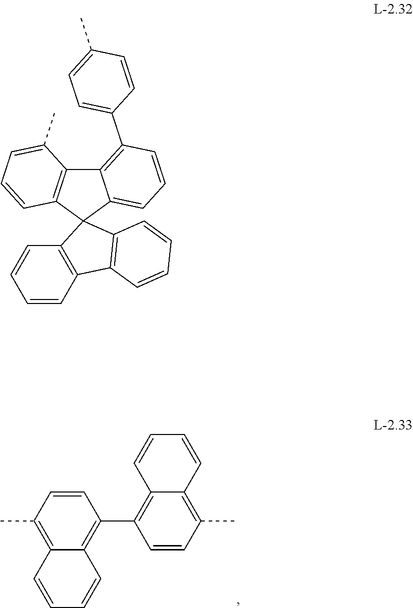

where W denotes N—Ar, O, S or C(CH₃)₂, Ar has a definition given above, the linkers L-2.1 to L-2.33 may be substituted by one or more R³ radicals and the dotted lines denote the attachment to the carbazoles. For the linker L₃, an R³ radical on one of the linkers L-2.1 to L-2.33 may form a ring with an R² radical of the carbazole.

Preferably, the linkers L-2.1 to L-2.33 are unsubstituted or substituted by a phenyl.

Preferred linkers for L₁ are selected from the structures L-2.1 to L-2.33 in which W is defined as S or O, more preferably defined as O.

Preferred linkers for L₃ are selected from the structures L-2.1 to L-2.33 in which W is defined as O, S or N—Ar, more preferably defined as O or N—Ar.

In a preferred embodiment of the compounds of the formulae (2), (2a), (2b), (2c), (2d), (2e), (2f), (2g), (2h) and (2i), the two carbazoles are joined to one another, each in the 3 position.

In compounds of the formulae (2), (2a), (2b), (2c), (2d), (2e), (2f), (2g), (2h) and (2i), r is preferably 0, 1 or 2, where R² has a definition given above or a definition given below. More preferably, r is 0 or 1. Most preferably, r is 0.

When, in compounds of the formulae (2), (2a), (2b), (2c), (2d), (2e), (2f), (2g), (2h) and (2i), r is greater than 0, the substituent R² is the same or different at each instance and is preferably selected from the group consisting of D, F, an alkyl group having 1 to 40 carbon atoms or an aromatic or heteroaromatic ring system which has 5 to 40 aromatic ring atoms and may be substituted by one or more R³ radicals. The aromatic or heteroaromatic ring system having 5 to 40 aromatic ring atoms in this R² is preferably derived from benzene, dibenzofuran, dibenzothiophene, 9-phenylcarbazole, indolo[3,2,1-jk]carbazole, biphenyl and terphenyl which may be substituted by one or more R³ radicals. The preferred position of the substituent(s) [R²]ᵣ is position 1, 2, 3 or 4 or the combinations of positions 1 and 4 and 1 and 3, more preferably 1 and 3, 2 or 3, most preferably 3, where R² has one of the preferred definitions given above and r is greater than 0. Particularly preferred substituents R² in [R²]ᵣ are carbazol-9-yl, biphenyl, terphenyl and dibenzofuranyl.

In compounds of the formulae (2), (2a), (2b), (2c), (2d), (2e), (2f), (2g), (2h), (2i), (2k) and (2l), s at each instance is independently preferably 0, 1 or 2, where R² and R⁴ have a definition given above or a definition given hereinafter. More preferably, s at each instance is independently 0 or 1; most preferably, s at each instance is 0.

When, in compounds of the formulae (2), (2a), (2b), (2c), (2d), (2e), (2f), (2g), (2h) and (2i), s is greater than 0, the substituent R⁴ is the same or different at each instance and is preferably selected from the group consisting of D, F, an alkyl group having 1 to 20 carbon atoms or an aromatic or heteroaromatic ring system having 5 to 30 aromatic ring atoms, in which one or more hydrogen atoms may be replaced by D, F, Cl, Br, I, a straight-chain or branched alkyl group having 1 to 4 carbon atoms or CN. It is possible here for two or more adjacent R⁴ substituents together to form a mono- or polycyclic ring system. The aromatic or heteroaromatic ring system having 5 to 40 aromatic ring atoms in this R⁴ is preferably derived from benzene, dibenzofuran, dibenzothiophene, 9-phenylcarbazole, biphenyl, terphenyl and triphenylene.

The preferred position of the substituent(s) [R⁴]s is position 1, 2 or 3, more preferably 3, where R⁴ has one of the preferred definitions given above and s is greater than 0.

Ar in N(Ar)₂ is preferably derived from benzene, dibenzofuran, fluorene, spirobifluorene, dibenzothiophene, 9-phenylcarbazole, biphenyl and terphenyl which may be substituted by one or more substituents R³. Ar here is preferably unsubstituted.

The substituent R² is the same or different at each instance and is preferably selected from the group consisting of D, F, Cl, Br, I, CN, NO₂, N(Ar)₂, NH₂, N(R³)₂, C(═O)Ar, C(═O)H, C(═O)R³, P(═O)(Ar)₂, a straight-chain alkyl, alkoxy or thioalkyl group having 1 to 40 carbon atoms or a branched or cyclic alkyl, alkoxy or thioalkyl group having 3 to 40 carbon atoms or an alkenyl or alkynyl group having 2 to 40 carbon atoms, each of which may be substituted by one or more R³ radicals, an aromatic or heteroaromatic ring system which has 5 to 60 aromatic ring atoms and may in each case be substituted by one or more R³ radicals, an aryloxy or heteroaryloxy group which has 5 to 60 aromatic ring atoms and may be substituted in each case by one or more R³ radicals. The substituent R² when it occurs is more preferably an aromatic or heteroaromatic ring system as described above, preferably selected and derived from the group of benzene, carbazole, 9-phenylcarbazole, dibenzofuran, dibenzothiophene, fluorene, terphenyl or spirobifluorene, most preferably derived from a dibenzofuran.

When, in compounds of the formulae (2j), (2k) and (2l), s is greater than 0, the substituent R² is the same or different at each instance and is preferably selected from the group consisting of D, F, an alkyl group having 1 to 40 carbon atoms or an aromatic or heteroaromatic ring system which has 5 to 40 aromatic ring atoms and may be substituted by one or more R³ radicals. The preferred position of the substituent(s) [R²]s is position 1, 3 and 4, more preferably 3, where R² has one of the definitions given above. Preferably, s is 0 or 1. When, in compounds of the formulae (2j), (2k) and (2l), s is 1, R² in [R²]s is preferably phenyl.

In the case of substitution of one of the substituents R² as described above by a substituent R³, the definitions of R³ as described above or described as preferred are applicable.

In compounds of the formulae (2), (2a), (2b), (2c), (2d), (2e), (2f), (2g), (2h), (2i), (2k) and (2i), as described above, Ar₃ is in each case independently an aromatic ring system having 6 to 40 aromatic ring atoms or a heteroaromatic ring system having 10 to 40 aromatic ring atoms which may be substituted by one or more R³ radicals.

In compounds of the formulae (2), (2a), (2b), (2c), (2d), (2e), (2f), (2g), (2h) and (2i), as described above, aryl is an aromatic or heteroaromatic ring system which has 5 to 30 aromatic ring atoms and may be substituted by R³.

Ar₃ and aryl are preferably derived from benzene, dibenzofuran, fluorene, spirobifluorene, dibenzothiophene, 9-phenylcarbazole, naphthalene, phenanthrene, triphenyl, biphenyl and terphenyl, which may be substituted by one or more substituents R³, where R³ has a definition given above.

In the case of the heteroaromatic ring systems which have 10 to 40 carbon atoms and may be substituted by one or more of the substituents R³, particular preference is given to electron-rich ring systems, where the optionally R³-substituted ring system preferably contains just one nitrogen atom in its entirety or the optionally R³-substituted ring system contains one or more oxygen and/or sulfur atoms in its entirety.

In compounds of the formulae (2), (2a), (2b), (2c), (2d), (2e), (2f), (2g), (2h), (2i), (2j), (2k) and (2l) or compounds of the formulae (2), (2a), (2b), (2c), (2d), (2e), (2f), (2g), (2h), (2i), (2j), (2k) and (2l) described with preference, aryl and Ar₃ at each instance is preferably independently selected from the aromatic or heteroaromatic ring systems Ar-1 to Ar-24

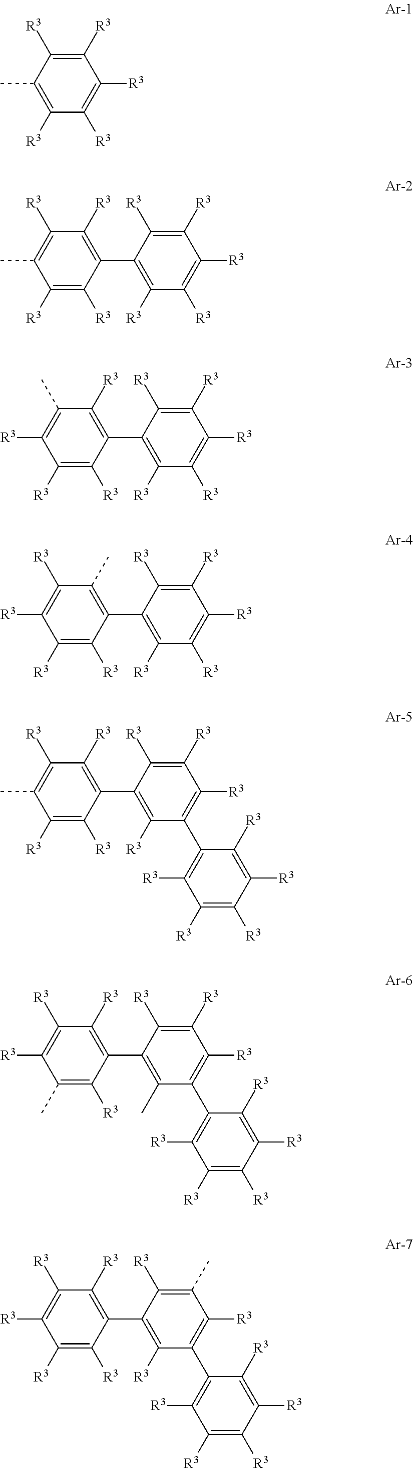

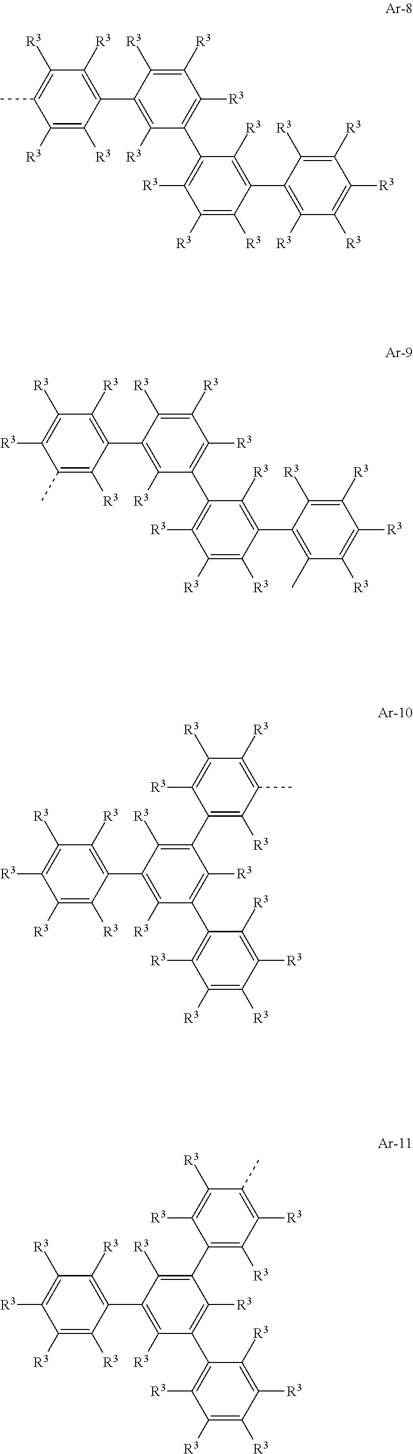

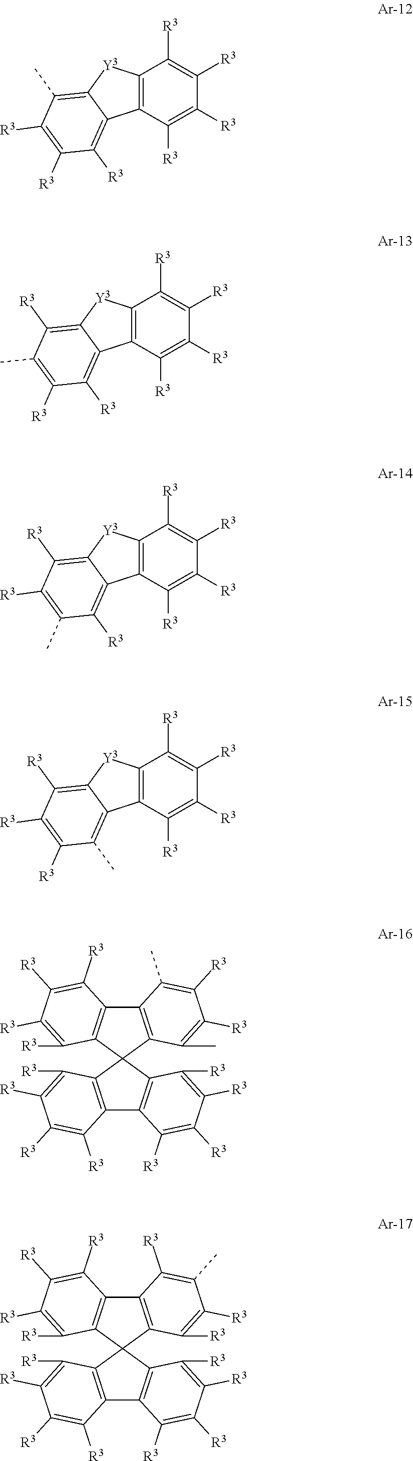

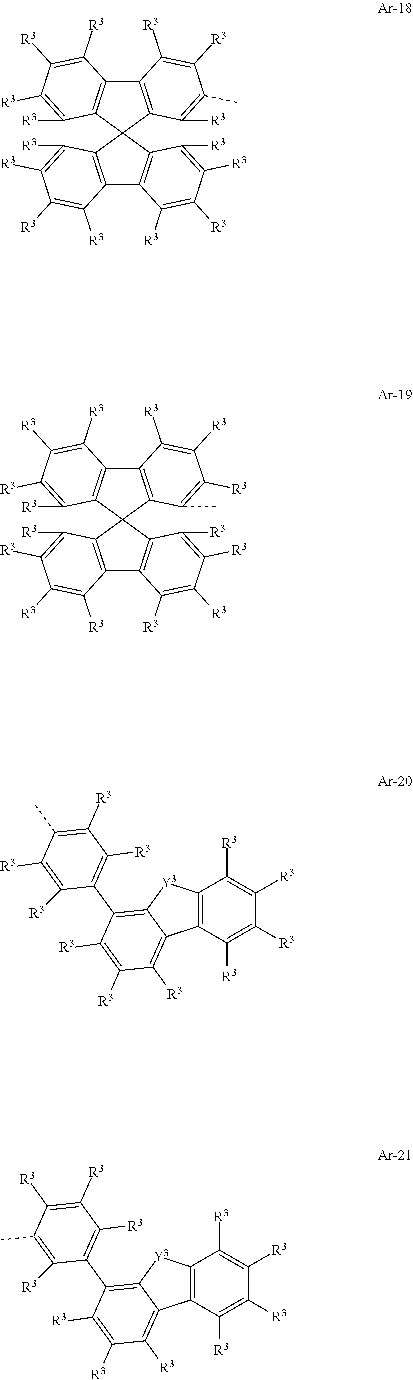

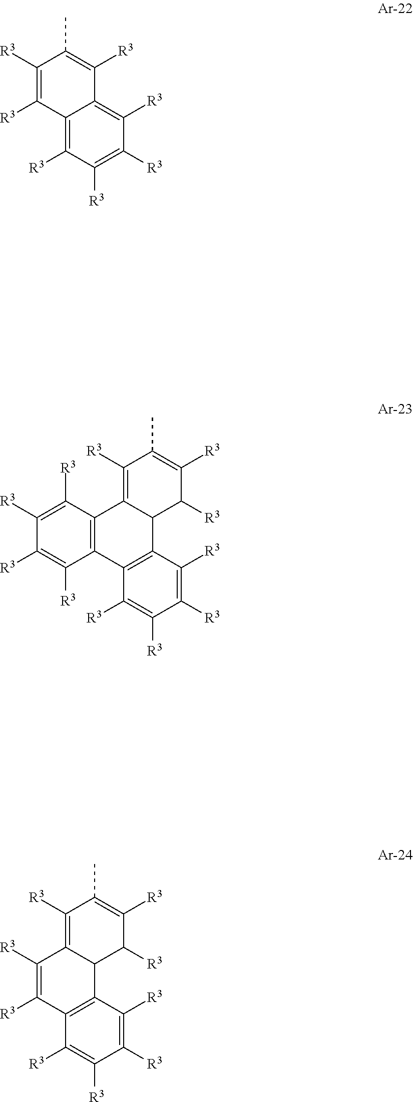

where Y³ at each instance is the same or different and is O, NR^{#}, S or C(R^{#})₂ where the R^{#} radical bonded to N is not H, and R³ has the aforementioned definition or a preferred definition below and the dotted bond represents the bond to the nitrogen atom.

The R^{#} radical is the same or different at each instance and is H, D, F, Cl, Br, I, CN, NO₂, N(Ar)₂, N(R³)₂, C(═O)Ar, C(═O)R³, P(═O)(Ar)₂, P(Ar)₂, B(Ar)₂, Si(Ar)₃, Si(R³)₃, a straight-chain alkyl, alkoxy or thioalkyl group having 1 to 20 carbon atoms or a branched or cyclic alkyl, alkoxy or thioalkyl group having 3 to 20 carbon atoms or an alkenyl group having 2 to 20 carbon atoms, each of which may be substituted by one or more R³ radicals, where one or more nonadjacent CH₂ groups may be replaced by R³C═CR³, Si(R³)₂, C═O, C═S, C═NR³, P(═O)(R³), SO, SO₂, NR³, O, S or CONR³ and where one or more hydrogen atoms may be replaced by D, F, Cl, Br, I, CN or NO₂, an aromatic or heteroaromatic ring system which has 5 to 40 aromatic ring atoms and may be substituted in each case by one or more R³ radicals, an aryloxy or heteroaryloxy group which has 5 to 40 aromatic ring atoms and may be substituted by one or more R³ radicals, or an aralkyl or heteroaralkyl group which has 5 to 40 aromatic ring atoms and may be substituted by one or more R³ radicals; at the same time, it is optionally possible for two substituents R^{#} bonded to the same carbon atom or to adjacent carbon atoms to form a monocyclic or polycyclic, aliphatic, aromatic or heteroaromatic ring system which may be substituted by one or more R³ radicals.

Y³ is preferably O, S or C(CH₃)₂. Y³ is most preferably O.

In the structures Ar-1 to Ar-24, the substituent R³ is the same or different at each instance and is selected from the group consisting of H, D, F, CN, an aliphatic hydrocarbyl radical having 1 to 20 carbon atoms, or an aromatic or heteroaromatic ring system having 5 to 30 aromatic ring atoms in which one or more hydrogen atoms may be replaced by D, F, C, Br, I or CN and which may be substituted by one or more alkyl groups each having 1 to 4 carbon atoms; at the same time, it is possible for two or more adjacent substituents R³ together to form a mono- or polycyclic, aliphatic ring system. In the structures Ar-1 to Ar-22, the substituent R³ is the same or different at each instance and is preferably selected from the group consisting of H, F, CN, an aliphatic hydrocarbyl radical having 1 to 10 carbon atoms or an aromatic or heteroaromatic ring system having 5 to 30 aromatic ring atoms. In the structures Ar-1 to Ar-24, the substituent R³ is the same or different at each instance and is preferably selected from the group consisting of H or an aromatic or heteroaromatic ring system having 5 to 30 aromatic ring atoms, as described above, but preferably dibenzofuran, dibenzothiophene, 9-phenylcarbazole or spirobifluorene. In the structures Ar-1 to Ar-24, the substituent R³ at each instance is more preferably H.

Examples of suitable compounds of the formulae (2), (2a), (2b), (2c), (2d), (2e), (2f), (2g), (2h), (2i), (2j), (2k) and (2l) that are selected in accordance with the invention are the following structures from Table 2 or the preferred compounds 37 to 66a:

TABLE 2

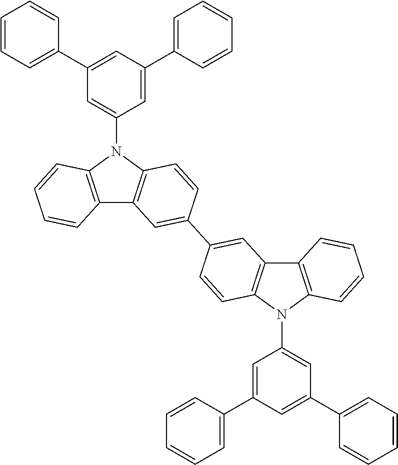 [SMILES: c1ccc(-c2cc(-c3ccccc3)cc(-n3c4ccccc4c4cc(-c5ccc6c(c5)c5ccccc5n6-c5cc(-c6ccccc6)cc(-c6ccccc6)c5)ccc43)c2)cc1]

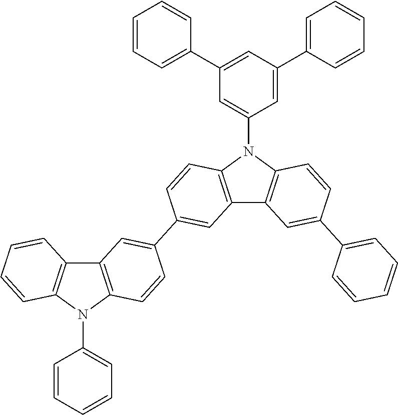 [SMILES: c1ccc(-c2cc(-c3ccccc3)cc(-n3c4ccc(-c5ccccc5)cc4c4cc(-c5ccc6c(c5)c5ccccc5n6-c5ccccc5)ccc43)c2)cc1]

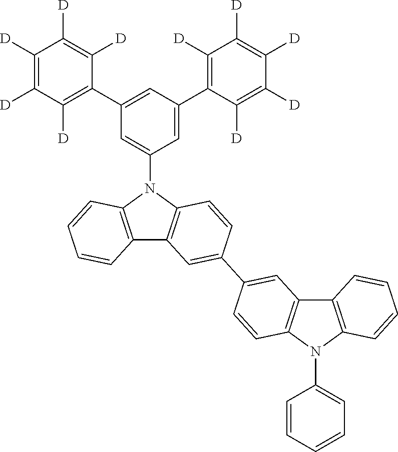 [SMILES: [2H]c1c([2H])c([2H])c(-c2cc(-c3c([2H])c([2H])c([2H])c([2H])c3[2H])cc(-n3c4ccccc4c4cc(-c5ccc6c(c5)c5ccccc5n6-c5ccccc5)ccc43)c2)c([2H])c1[2H]]

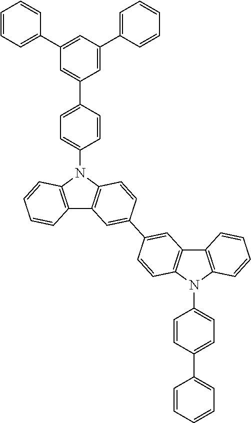 [SMILES: c1ccc(-c2ccc(-n3c4ccccc4c4cc(-c5ccc6c(c5)c5ccccc5n6-c5ccc(-c6cc(-c7ccccc7)cc(-c7ccccc7)c6)cc5)ccc43)cc2)cc1]

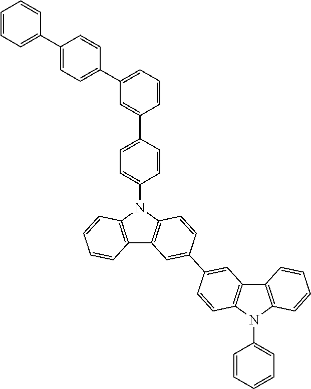 [SMILES: c1ccc(-c2ccc(-c3cccc(-c4ccc(-n5c6ccccc6c6cc(-c7ccc8c(c7)c7ccccc7n8-c7ccccc7)ccc65)cc4)c3)cc2)cc1]

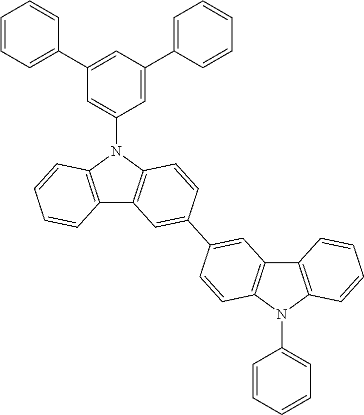 [SMILES: c1ccc(-c2cc(-c3ccccc3)cc(-n3c4ccccc4c4cc(-c5ccc6c(c5)c5ccccc5n6-c5ccccc5)ccc43)c2)cc1]

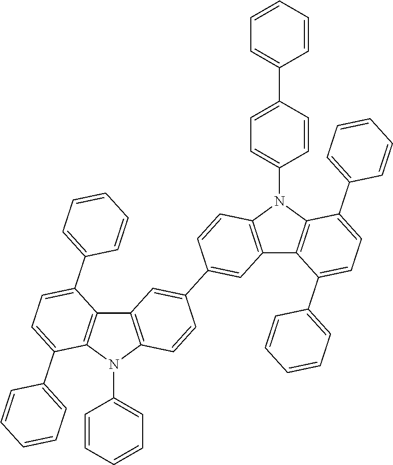 [SMILES: c1ccc(-c2ccc(-n3c4ccc(-c5ccc6c(c5)c5c(-c7ccccc7)ccc(-c7ccccc7)c5n6-c5ccccc5)cc4c4c(-c5ccccc5)ccc(-c5ccccc5)c43)cc2)cc1]

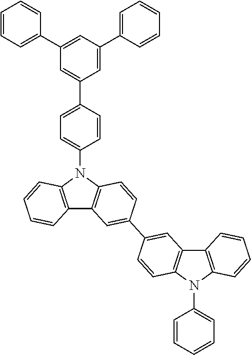 [SMILES: c1ccc(-c2cc(-c3ccccc3)cc(-c3ccc(-n4c5ccccc5c5cc(-c6ccc7c(c6)c6ccccc6n7-c6ccccc6)ccc54)cc3)c2)cc1]

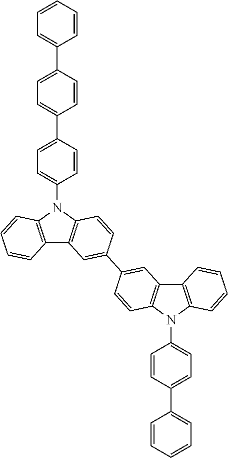 [SMILES: c1ccc(-c2ccc(-c3ccc(-n4c5ccccc5c5cc(-c6ccc7c(c6)c6ccccc6n7-c6ccc(-c7ccccc7)cc6)ccc54)cc3)cc2)cc1]

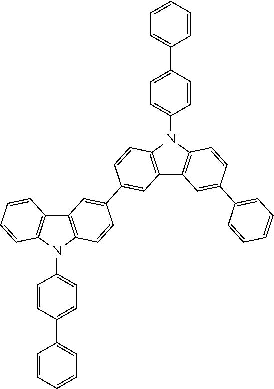 [SMILES: c1ccc(-c2ccc(-n3c4ccccc4c4cc(-c5ccc6c(c5)c5cc(-c7ccccc7)ccc5n6-c5ccc(-c6ccccc6)cc5)ccc43)cc2)cc1]

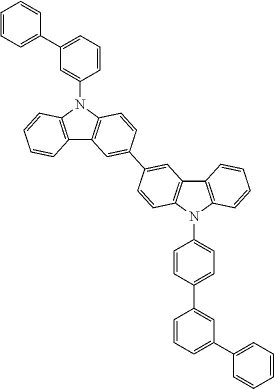 [SMILES: c1ccc(-c2cccc(-c3ccc(-n4c5ccccc5c5cc(-c6ccc7c(c6)c6ccccc6n7-c6cccc(-c7ccccc7)c6)ccc54)cc3)c2)cc1]

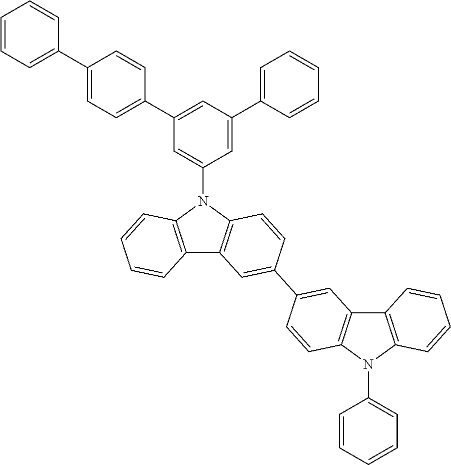 [SMILES: c1ccc(-c2ccc(-c3cc(-c4ccccc4)cc(-n4c5ccccc5c5cc(-c6ccc7c(c6)c6ccccc6n7-c6ccccc6)ccc54)c3)cc2)cc1]

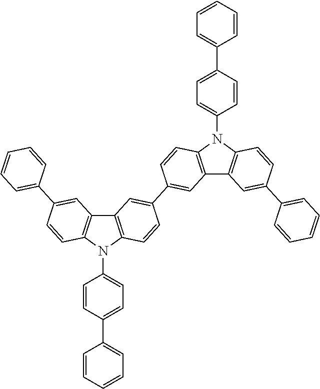 [SMILES: c1ccc(-c2ccc(-n3c4ccc(-c5ccccc5)cc4c4cc(-c5ccc6c(c5)c5cc(-c7ccccc7)ccc5n6-c5ccc(-c6ccccc6)cc5)ccc43)cc2)cc1]

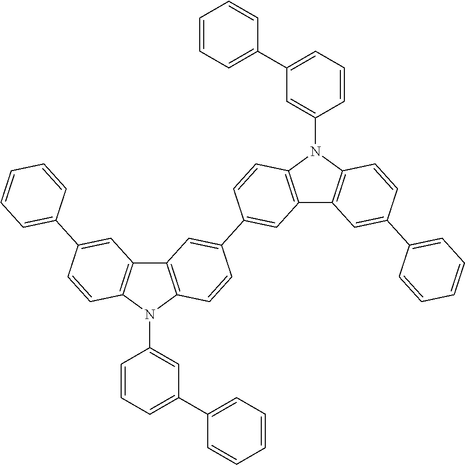 [SMILES: c1ccc(-c2cccc(-n3c4ccc(-c5ccccc5)cc4c4cc(-c5ccc6c(c5)c5cc(-c7ccccc7)ccc5n6-c5cccc(-c6ccccc6)c5)ccc43)c2)cc1]

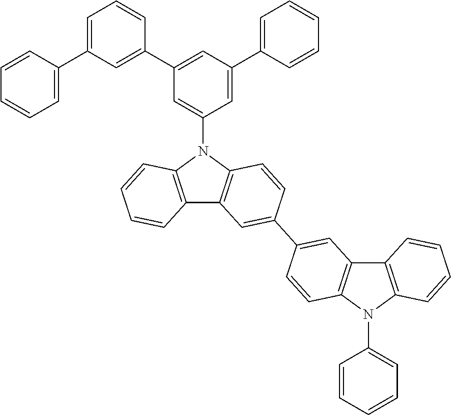 [SMILES: c1ccc(-c2cccc(-c3cc(-c4ccccc4)cc(-n4c5ccccc5c5cc(-c6ccc7c(c6)c6ccccc6n7-c6ccccc6)ccc54)c3)c2)cc1]

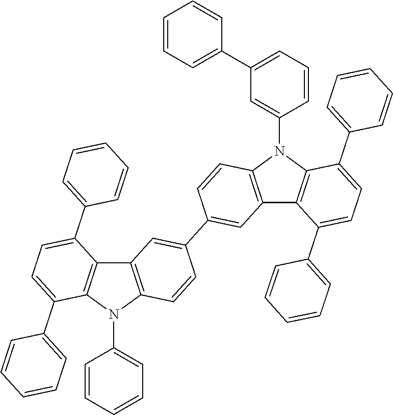 [SMILES: c1ccc(-c2cccc(-n3c4ccc(-c5ccc6c(c5)c5c(-c7ccccc7)ccc(-c7ccccc7)c5n6-c5ccccc5)cc4c4c(-c5ccccc5)ccc(-c5ccccc5)c43)c2)cc1]

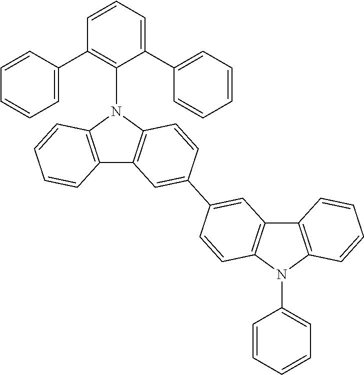 [SMILES: c1ccc(-c2cccc(-c3ccccc3)c2-n2c3ccccc3c3cc(-c4ccc5c(c4)c4ccccc4n5-c4ccccc4)ccc32)cc1]

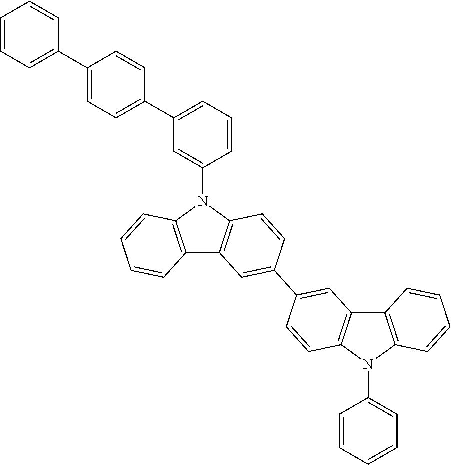 [SMILES: c1ccc(-c2ccc(-c3cccc(-n4c5ccccc5c5cc(-c6ccc7c(c6)c6ccccc6n7-c6ccccc6)ccc54)c3)cc2)cc1]

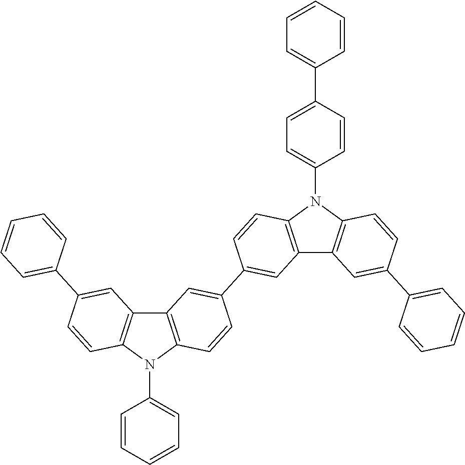 [SMILES: c1ccc(-c2ccc(-n3c4ccc(-c5ccccc5)cc4c4cc(-c5ccc6c(c5)c5cc(-c7ccccc7)ccc5n6-c5ccccc5)ccc43)cc2)cc1]

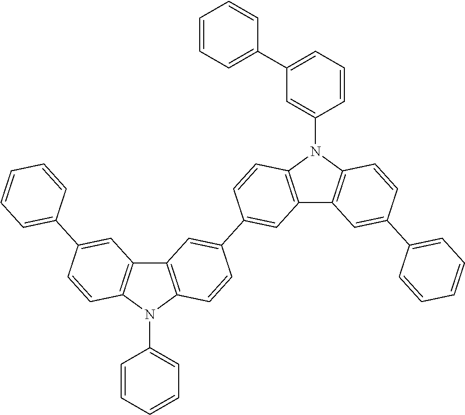 [SMILES: c1ccc(-c2cccc(-n3c4ccc(-c5ccccc5)cc4c4cc(-c5ccc6c(c5)c5cc(-c7ccccc7)ccc5n6-c5ccccc5)ccc43)c2)cc1]

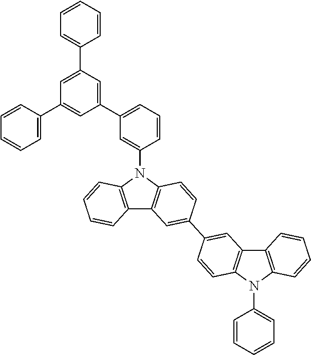 [SMILES: c1ccc(-c2cc(-c3ccccc3)cc(-c3cccc(-n4c5ccccc5c5cc(-c6ccc7c(c6)c6ccccc6n7-c6ccccc6)ccc54)c3)c2)cc1]

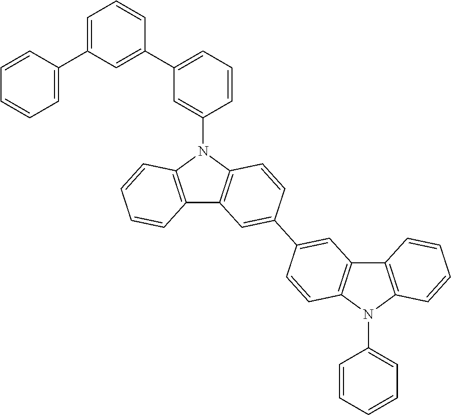 [SMILES: c1ccc(-c2cccc(-c3cccc(-n4c5ccccc5c5cc(-c6ccc7c(c6)c6ccccc6n7-c6ccccc6)ccc54)c3)c2)cc1]

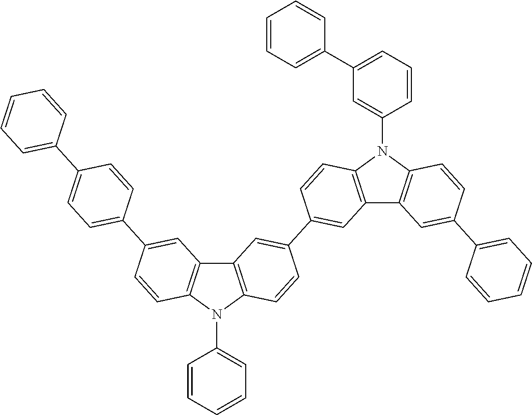 [SMILES: c1ccc(-c2ccc(-c3ccc4c(c3)c3cc(-c5ccc6c(c5)c5cc(-c7ccccc7)ccc5n6-c5cccc(-c6ccccc6)c5)ccc3n4-c3ccccc3)cc2)cc1]

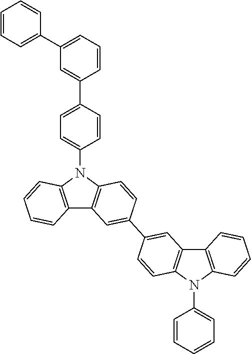 [SMILES: c1ccc(-c2cccc(-c3ccc(-n4c5ccccc5c5cc(-c6ccc7c(c6)c6ccccc6n7-c6ccccc6)ccc54)cc3)c2)cc1]

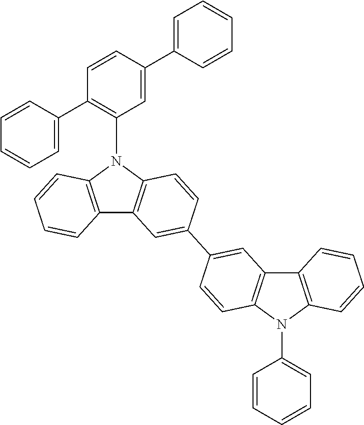 [SMILES: c1ccc(-c2ccc(-c3ccccc3)c(-n3c4ccccc4c4cc(-c5ccc6c(c5)c5ccccc5n6-c5ccccc5)ccc43)c2)cc1]

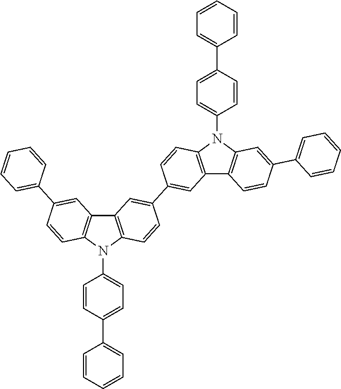 [SMILES: c1ccc(-c2ccc(-n3c4ccc(-c5ccccc5)cc4c4cc(-c5ccc6c(c5)c5ccc(-c7ccccc7)cc5n6-c5ccc(-c6ccccc6)cc5)ccc43)cc2)cc1]

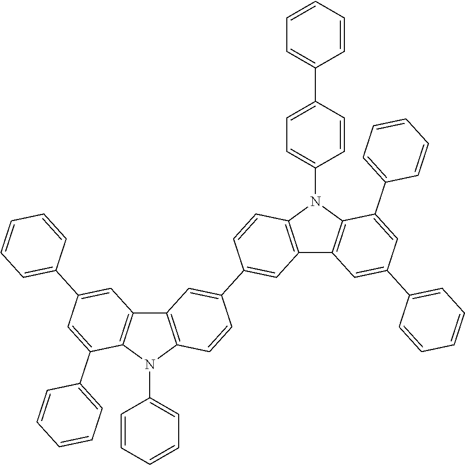 [SMILES: c1ccc(-c2ccc(-n3c4ccc(-c5ccc6c(c5)c5cc(-c7ccccc7)cc(-c7ccccc7)c5n6-c5ccccc5)cc4c4cc(-c5ccccc5)cc(-c5ccccc5)c43)cc2)cc1]

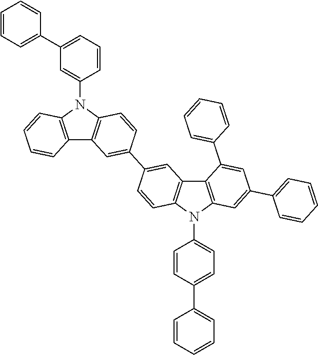 [SMILES: c1ccc(-c2ccc(-n3c4ccc(-c5ccc6c(c5)c5ccccc5n6-c5cccc(-c6ccccc6)c5)cc4c4c(-c5ccccc5)cc(-c5ccccc5)cc43)cc2)cc1]

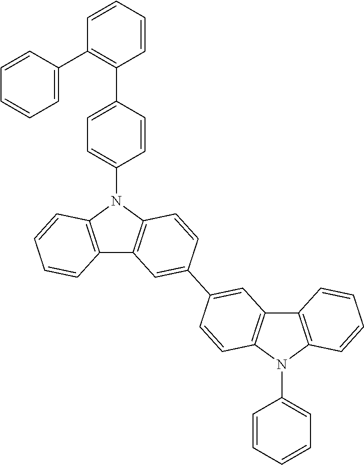 [SMILES: c1ccc(-c2ccccc2-c2ccc(-n3c4ccccc4c4cc(-c5ccc6c(c5)c5ccccc5n6-c5ccccc5)ccc43)cc2)cc1]

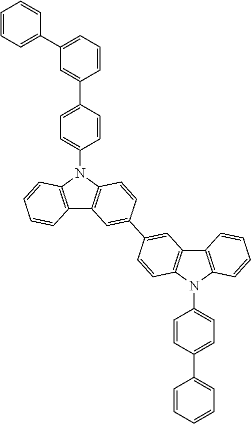 [SMILES: c1ccc(-c2ccc(-n3c4ccccc4c4cc(-c5ccc6c(c5)c5ccccc5n6-c5ccc(-c6cccc(-c7ccccc7)c6)cc5)ccc43)cc2)cc1]

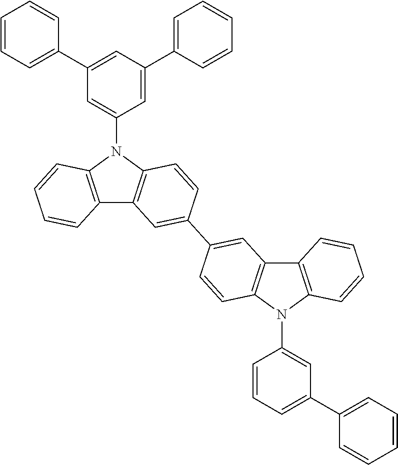 [SMILES: c1ccc(-c2cccc(-n3c4ccccc4c4cc(-c5ccc6c(c5)c5ccccc5n6-c5cc(-c6ccccc6)cc(-c6ccccc6)c5)ccc43)c2)cc1]

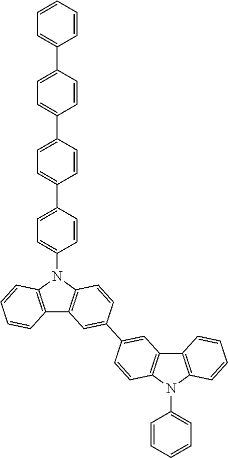 [SMILES: c1ccc(-c2ccc(-c3ccc(-c4ccc(-n5c6ccccc6c6cc(-c7ccc8c(c7)c7ccccc7n8-c7ccccc7)ccc65)cc4)cc3)cc2)cc1]

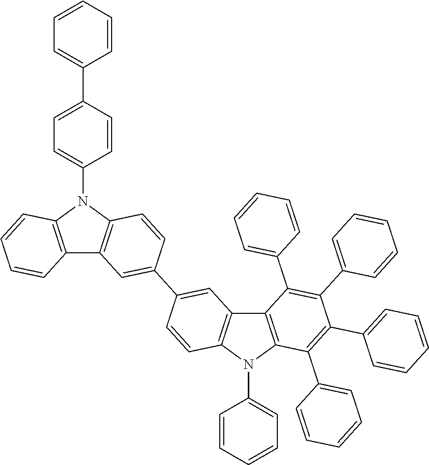 [SMILES: c1ccc(-c2ccc(-n3c4ccccc4c4cc(-c5ccc6c(c5)c5c(-c7ccccc7)c(-c7ccccc7)c(-c7ccccc7)c(-c7ccccc7)c5n6-c5ccccc5)ccc43)cc2)cc1]

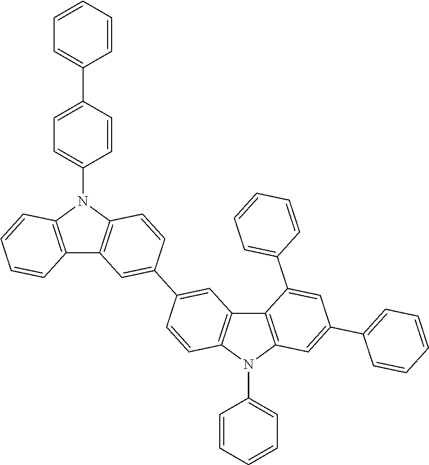 [SMILES: c1ccc(-c2ccc(-n3c4ccccc4c4cc(-c5ccc6c(c5)c5c(-c7ccccc7)cc(-c7ccccc7)cc5n6-c5ccccc5)ccc43)cc2)cc1]

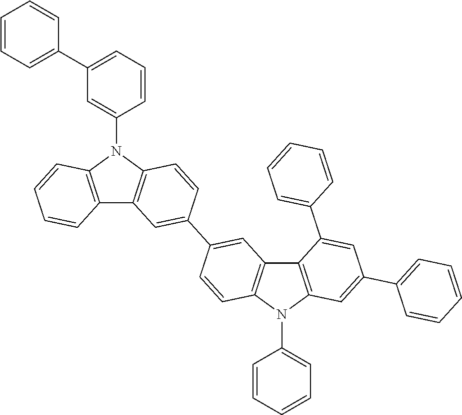 [SMILES: c1ccc(-c2cccc(-n3c4ccccc4c4cc(-c5ccc6c(c5)c5c(-c7ccccc7)cc(-c7ccccc7)cc5n6-c5ccccc5)ccc43)c2)cc1]

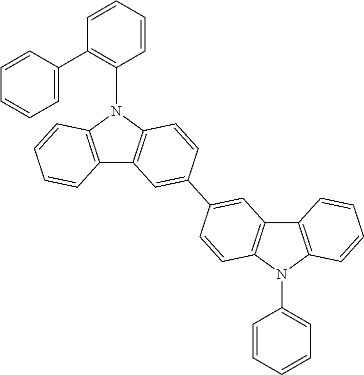 [SMILES: c1ccc(-c2ccccc2-n2c3ccccc3c3cc(-c4ccc5c(c4)c4ccccc4n5-c4ccccc4)ccc32)cc1]

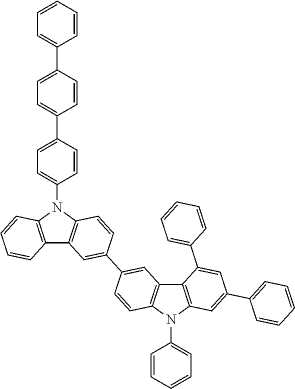 [SMILES: c1ccc(-c2ccc(-c3ccc(-n4c5ccccc5c5cc(-c6ccc7c(c6)c6c(-c8ccccc8)cc(-c8ccccc8)cc6n7-c6ccccc6)ccc54)cc3)cc2)cc1]

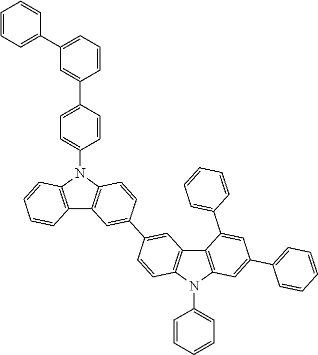 [SMILES: c1ccc(-c2cccc(-c3ccc(-n4c5ccccc5c5cc(-c6ccc7c(c6)c6c(-c8ccccc8)cc(-c8ccccc8)cc6n7-c6ccccc6)ccc54)cc3)c2)cc1]

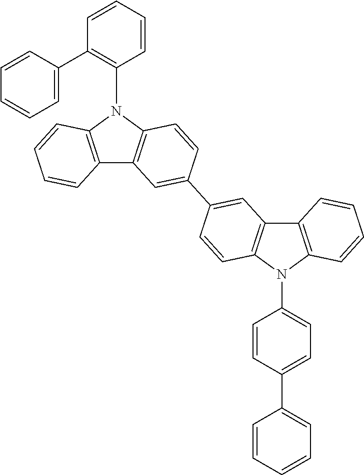 [SMILES: c1ccc(-c2ccc(-n3c4ccccc4c4cc(-c5ccc6c(c5)c5ccccc5n6-c5ccccc5-c5ccccc5)ccc43)cc2)cc1]

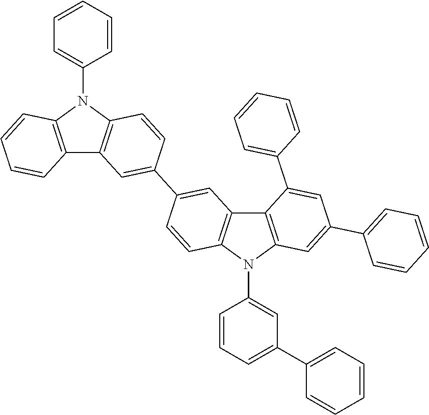 [SMILES: c1ccc(-c2cccc(-n3c4ccc(-c5ccc6c(c5)c5ccccc5n6-c5ccccc5)cc4c4c(-c5ccccc5)cc(-c5ccccc5)cc43)c2)cc1]

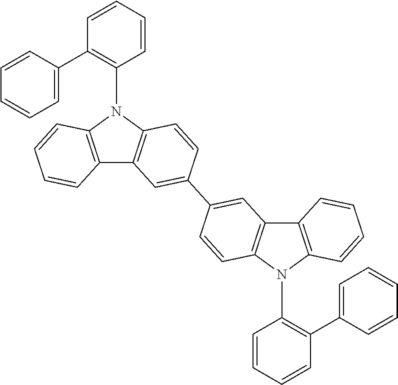 [SMILES: c1ccc(-c2ccccc2-n2c3ccccc3c3cc(-c4ccc5c(c4)c4ccccc4n5-c4ccccc4-c4ccccc4)ccc32)cc1]

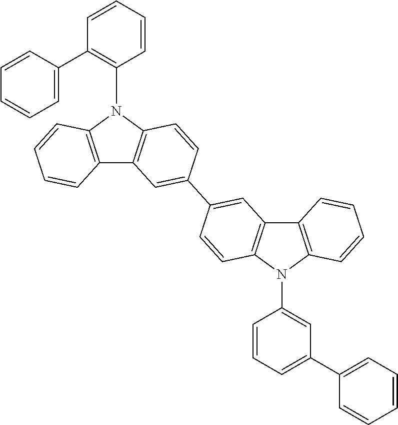 [SMILES: c1ccc(-c2cccc(-n3c4ccccc4c4cc(-c5ccc6c(c5)c5ccccc5n6-c5ccccc5-c5ccccc5)ccc43)c2)cc1]

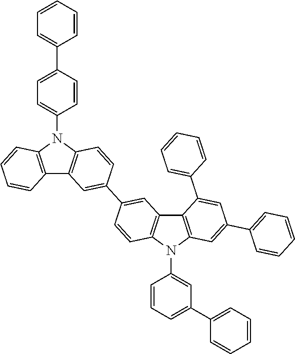 [SMILES: c1ccc(-c2ccc(-n3c4ccccc4c4cc(-c5ccc6c(c5)c5c(-c7ccccc7)cc(-c7ccccc7)cc5n6-c5cccc(-c6ccccc6)c5)ccc43)cc2)cc1]

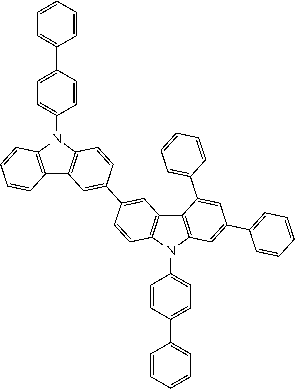 [SMILES: c1ccc(-c2ccc(-n3c4ccccc4c4cc(-c5ccc6c(c5)c5c(-c7ccccc7)cc(-c7ccccc7)cc5n6-c5ccc(-c6ccccc6)cc5)ccc43)cc2)cc1]

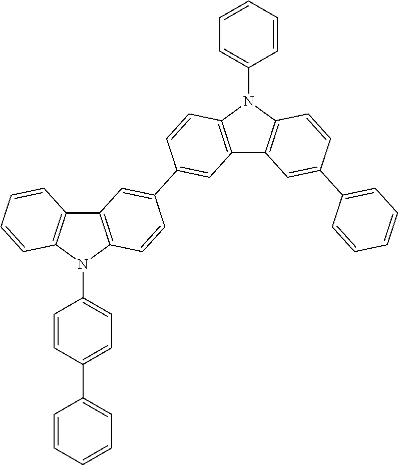 [SMILES: c1ccc(-c2ccc(-n3c4ccccc4c4cc(-c5ccc6c(c5)c5cc(-c7ccccc7)ccc5n6-c5ccccc5)ccc43)cc2)cc1]

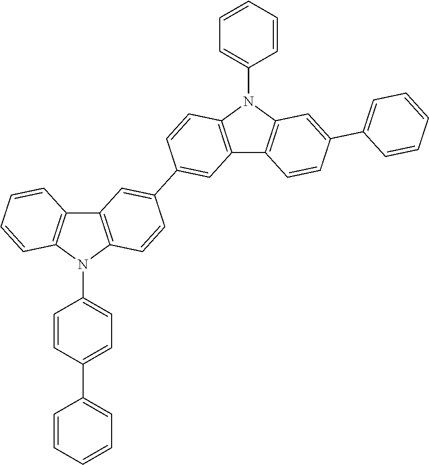 [SMILES: c1ccc(-c2ccc(-n3c4ccccc4c4cc(-c5ccc6c(c5)c5ccc(-c7ccccc7)cc5n6-c5ccccc5)ccc43)cc2)cc1]

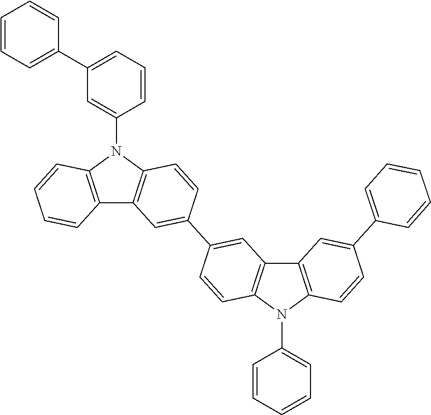 [SMILES: c1ccc(-c2cccc(-n3c4ccccc4c4cc(-c5ccc6c(c5)c5cc(-c7ccccc7)ccc5n6-c5ccccc5)ccc43)c2)cc1]

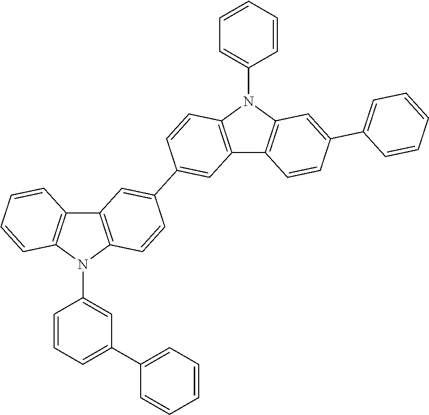 [SMILES: c1ccc(-c2cccc(-n3c4ccccc4c4cc(-c5ccc6c(c5)c5ccc(-c7ccccc7)cc5n6-c5ccccc5)ccc43)c2)cc1]

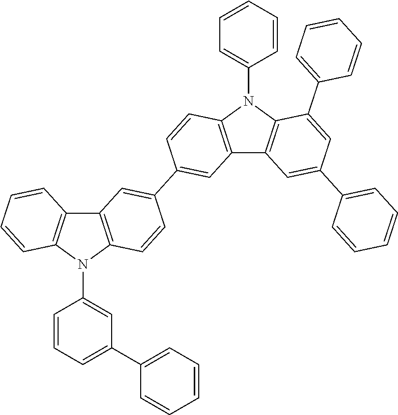 [SMILES: c1ccc(-c2cccc(-n3c4ccccc4c4cc(-c5ccc6c(c5)c5cc(-c7ccccc7)cc(-c7ccccc7)c5n6-c5ccccc5)ccc43)c2)cc1]

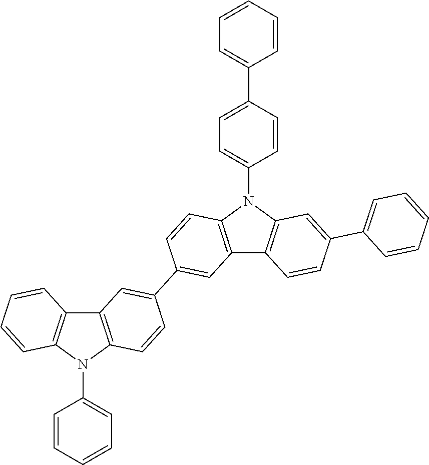 [SMILES: c1ccc(-c2ccc(-n3c4ccc(-c5ccc6c(c5)c5ccccc5n6-c5ccccc5)cc4c4ccc(-c5ccccc5)cc43)cc2)cc1]

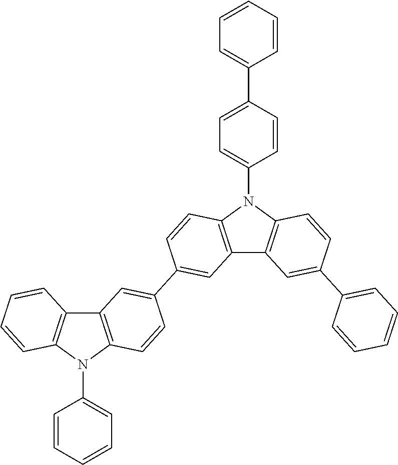 [SMILES: c1ccc(-c2ccc(-n3c4ccc(-c5ccccc5)cc4c4cc(-c5ccc6c(c5)c5ccccc5n6-c5ccccc5)ccc43)cc2)cc1]

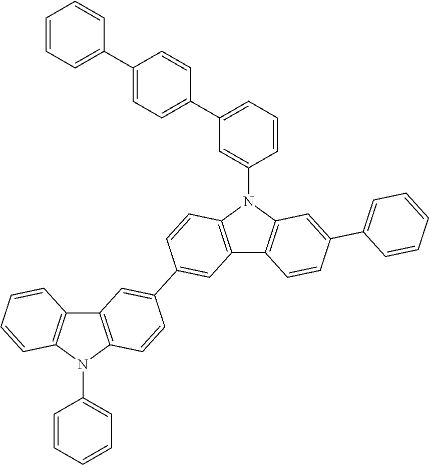 [SMILES: c1ccc(-c2ccc(-c3cccc(-n4c5ccc(-c6ccc7c(c6)c6ccccc6n7-c6ccccc6)cc5c5ccc(-c6ccccc6)cc54)c3)cc2)cc1]

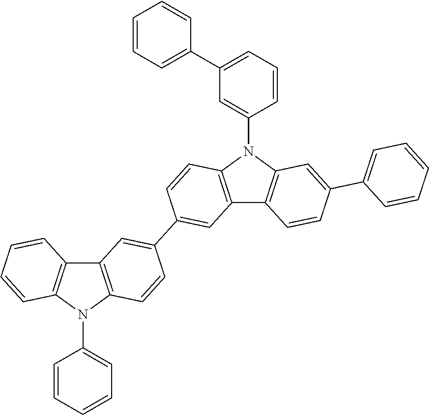 [SMILES: c1ccc(-c2cccc(-n3c4ccc(-c5ccc6c(c5)c5ccccc5n6-c5ccccc5)cc4c4ccc(-c5ccccc5)cc43)c2)cc1]

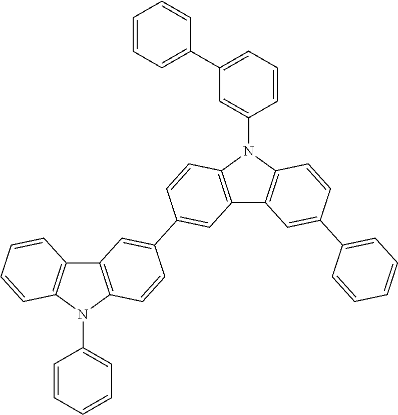 [SMILES: c1ccc(-c2cccc(-n3c4ccc(-c5ccccc5)cc4c4cc(-c5ccc6c(c5)c5ccccc5n6-c5ccccc5)ccc43)c2)cc1]

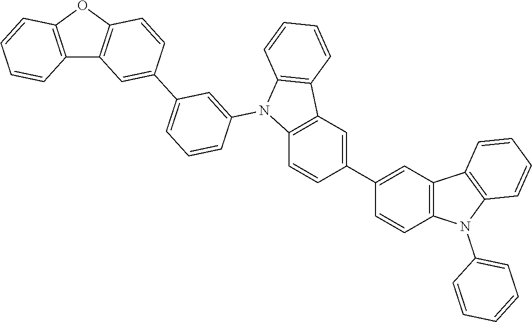 [SMILES: c1ccc(-n2c3ccccc3c3cc(-c4ccc5c(c4)c4ccccc4n5-c4cccc(-c5ccc6oc7ccccc7c6c5)c4)ccc32)cc1]

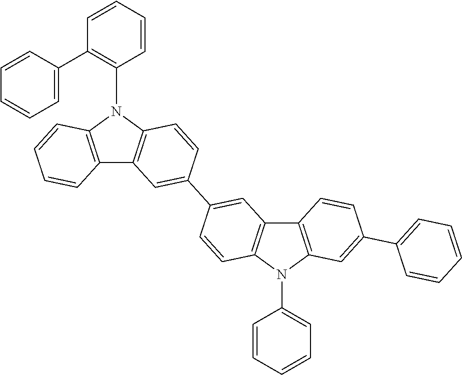 [SMILES: c1ccc(-c2ccc3c4cc(-c5ccc6c(c5)c5ccccc5n6-c5ccccc5-c5ccccc5)ccc4n(-c4ccccc4)c3c2)cc1]

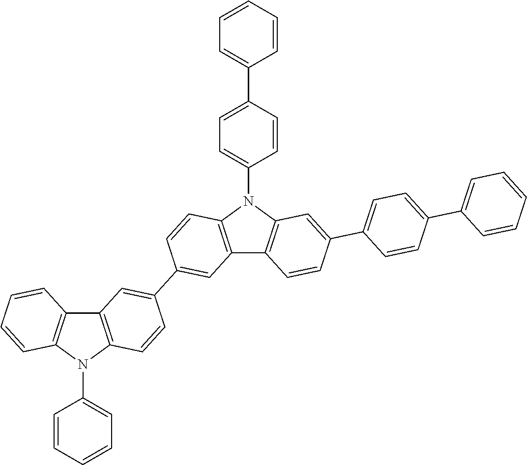 [SMILES: c1ccc(-c2ccc(-c3ccc4c5cc(-c6ccc7c(c6)c6ccccc6n7-c6ccccc6)ccc5n(-c5ccc(-c6ccccc6)cc5)c4c3)cc2)cc1]

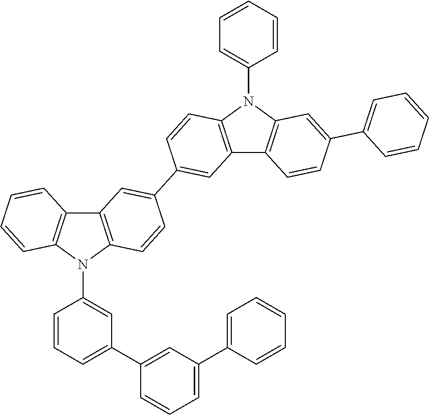 [SMILES: c1ccc(-c2cccc(-c3cccc(-n4c5ccccc5c5cc(-c6ccc7c(c6)c6ccc(-c8ccccc8)cc6n7-c6ccccc6)ccc54)c3)c2)cc1]

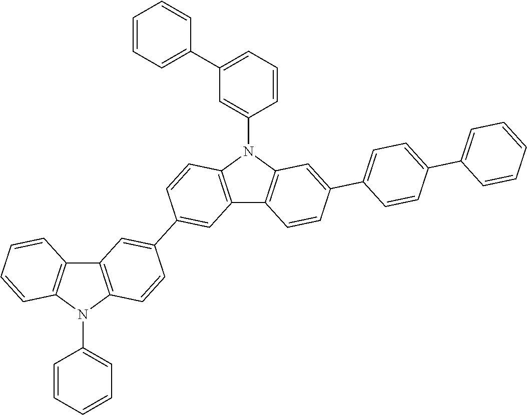 [SMILES: c1ccc(-c2ccc(-c3ccc4c5cc(-c6ccc7c(c6)c6ccccc6n7-c6ccccc6)ccc5n(-c5cccc(-c6ccccc6)c5)c4c3)cc2)cc1]

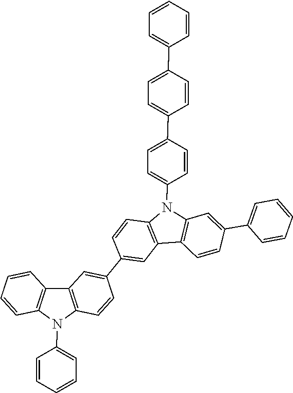 [SMILES: c1ccc(-c2ccc(-c3ccc(-n4c5ccc(-c6ccc7c(c6)c6ccccc6n7-c6ccccc6)cc5c5ccc(-c6ccccc6)cc54)cc3)cc2)cc1]

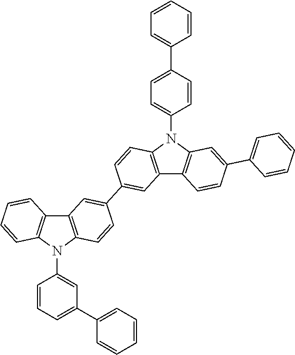 [SMILES: c1ccc(-c2ccc(-n3c4ccc(-c5ccc6c(c5)c5ccccc5n6-c5cccc(-c6ccccc6)c5)cc4c4ccc(-c5ccccc5)cc43)cc2)cc1]

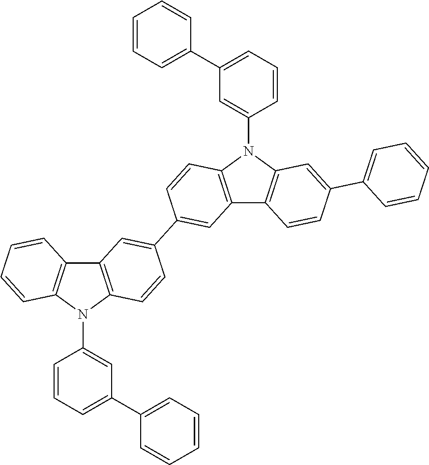 [SMILES: c1ccc(-c2cccc(-n3c4ccccc4c4cc(-c5ccc6c(c5)c5ccc(-c7ccccc7)cc5n6-c5cccc(-c6ccccc6)c5)ccc43)c2)cc1]

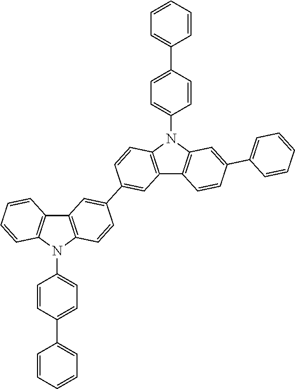 [SMILES: c1ccc(-c2ccc(-n3c4ccccc4c4cc(-c5ccc6c(c5)c5ccc(-c7ccccc7)cc5n6-c5ccc(-c6ccccc6)cc5)ccc43)cc2)cc1]

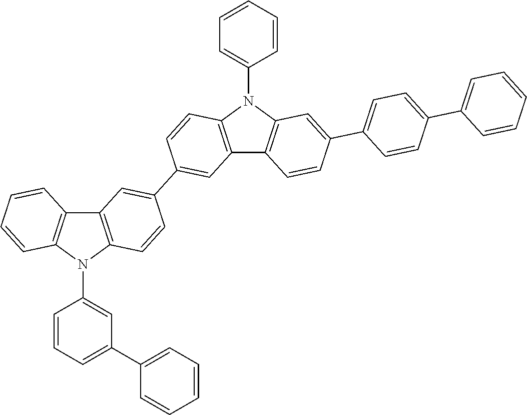 [SMILES: c1ccc(-c2ccc(-c3ccc4c5cc(-c6ccc7c(c6)c6ccccc6n7-c6cccc(-c7ccccc7)c6)ccc5n(-c5ccccc5)c4c3)cc2)cc1]

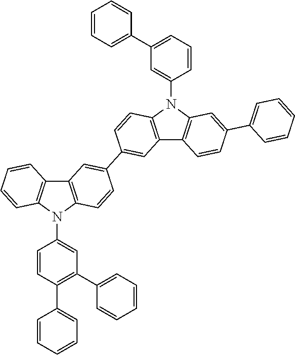 [SMILES: c1ccc(-c2cccc(-n3c4ccc(-c5ccc6c(c5)c5ccccc5n6-c5ccc(-c6ccccc6)c(-c6ccccc6)c5)cc4c4ccc(-c5ccccc5)cc43)c2)cc1]

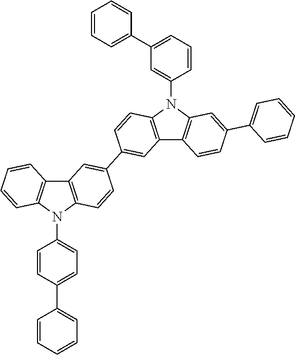 [SMILES: c1ccc(-c2ccc(-n3c4ccccc4c4cc(-c5ccc6c(c5)c5ccc(-c7ccccc7)cc5n6-c5cccc(-c6ccccc6)c5)ccc43)cc2)cc1]

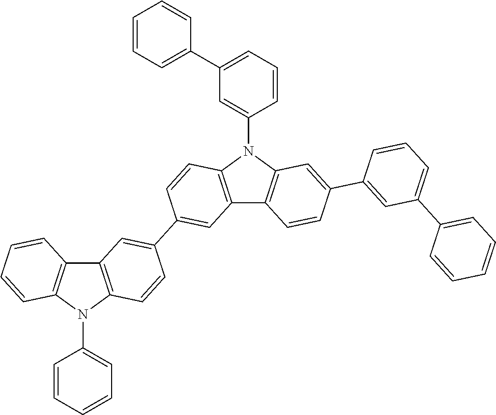 [SMILES: c1ccc(-c2cccc(-c3ccc4c5cc(-c6ccc7c(c6)c6ccccc6n7-c6ccccc6)ccc5n(-c5cccc(-c6ccccc6)c5)c4c3)c2)cc1]

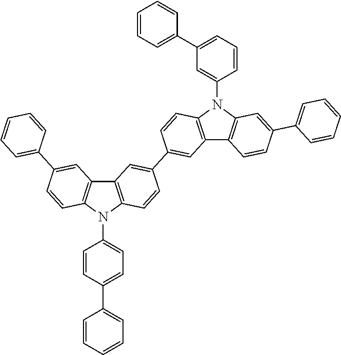 [SMILES: c1ccc(-c2ccc(-n3c4ccc(-c5ccccc5)cc4c4cc(-c5ccc6c(c5)c5ccc(-c7ccccc7)cc5n6-c5cccc(-c6ccccc6)c5)ccc43)cc2)cc1]

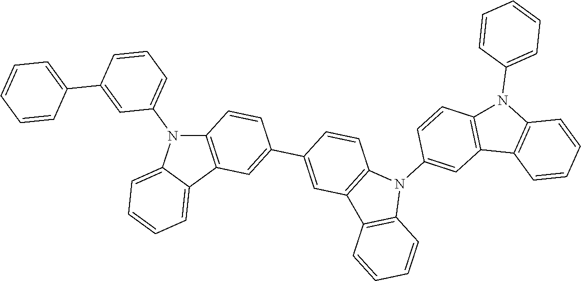 [SMILES: c1ccc(-c2cccc(-n3c4ccccc4c4cc(-c5ccc6c(c5)c5ccccc5n6-c5ccc6c(c5)c5ccccc5n6-c5ccccc5)ccc43)c2)cc1]

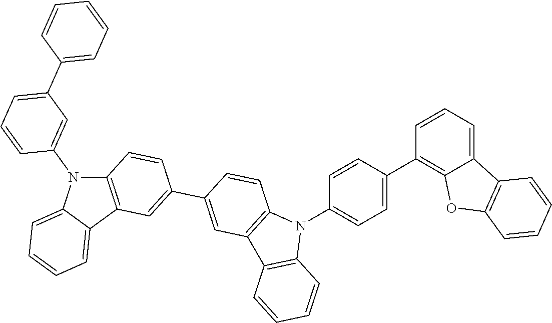 [SMILES: c1ccc(-c2cccc(-n3c4ccccc4c4cc(-c5ccc6c(c5)c5ccccc5n6-c5ccc(-c6cccc7c6oc6ccccc67)cc5)ccc43)c2)cc1]

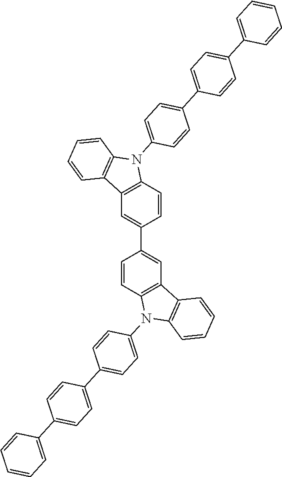 [SMILES: c1ccc(-c2ccc(-c3ccc(-n4c5ccccc5c5cc(-c6ccc7c(c6)c6ccccc6n7-c6ccc(-c7ccc(-c8ccccc8)cc7)cc6)ccc54)cc3)cc2)cc1]

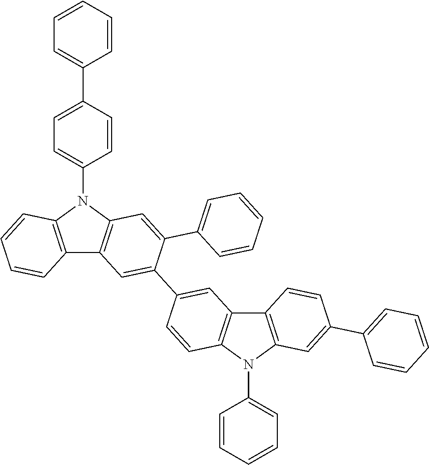 [SMILES: c1ccc(-c2ccc(-n3c4ccccc4c4cc(-c5ccc6c(c5)c5ccc(-c7ccccc7)cc5n6-c5ccccc5)c(-c5ccccc5)cc43)cc2)cc1]

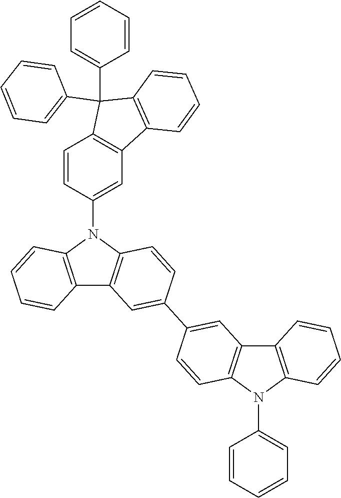 [SMILES: c1ccc(-n2c3ccccc3c3cc(-c4ccc5c(c4)c4ccccc4n5-c4ccc5c(c4)-c4ccccc4C5(c4ccccc4)c4ccccc4)ccc32)cc1]

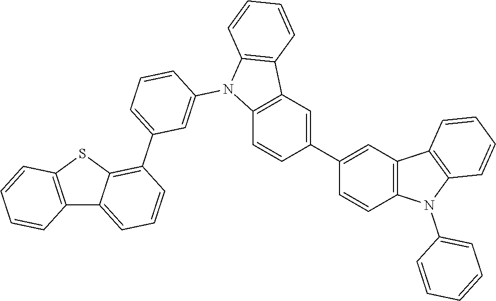 [SMILES: c1ccc(-n2c3ccccc3c3cc(-c4ccc5c(c4)c4ccccc4n5-c4cccc(-c5cccc6c5sc5ccccc56)c4)ccc32)cc1]

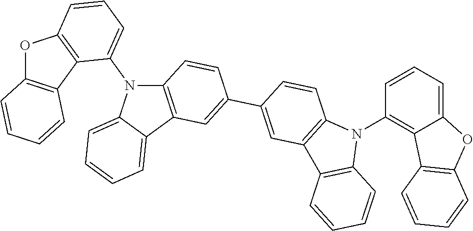 [SMILES: c1ccc2c(c1)oc1cccc(-n3c4ccccc4c4cc(-c5ccc6c(c5)c5ccccc5n6-c5cccc6oc7ccccc7c56)ccc43)c12]

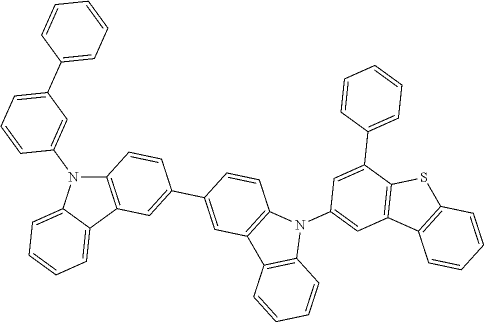 [SMILES: c1ccc(-c2cccc(-n3c4ccccc4c4cc(-c5ccc6c(c5)c5ccccc5n6-c5cc(-c6ccccc6)c6sc7ccccc7c6c5)ccc43)c2)cc1]

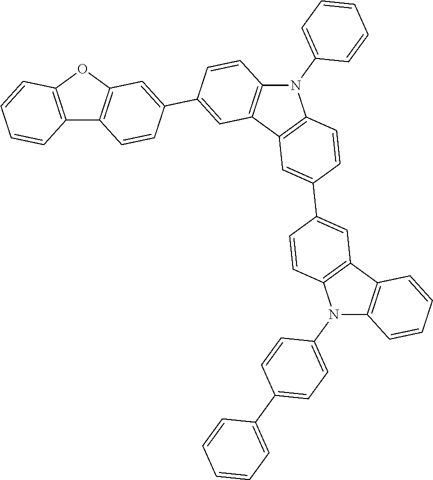 [SMILES: c1ccc(-c2ccc(-n3c4ccccc4c4cc(-c5ccc6c(c5)c5cc(-c7ccc8c(c7)oc7ccccc78)ccc5n6-c5ccccc5)ccc43)cc2)cc1]

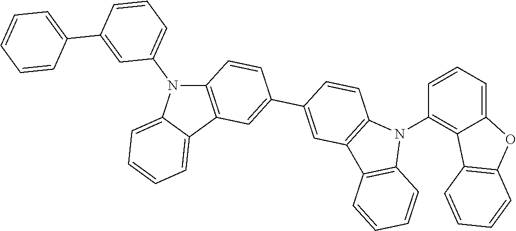 [SMILES: c1ccc(-c2cccc(-n3c4ccccc4c4cc(-c5ccc6c(c5)c5ccccc5n6-c5cccc6oc7ccccc7c56)ccc43)c2)cc1]

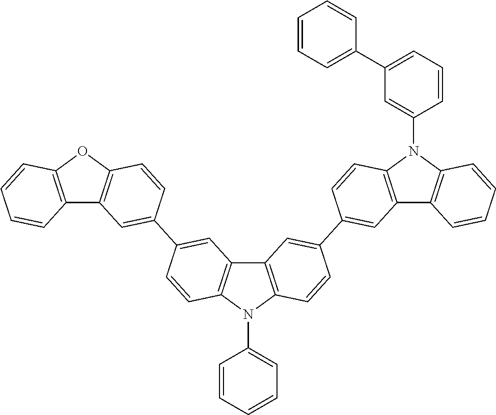 [SMILES: c1ccc(-c2cccc(-n3c4ccccc4c4cc(-c5ccc6c(c5)c5cc(-c7ccc8oc9ccccc9c8c7)ccc5n6-c5ccccc5)ccc43)c2)cc1]

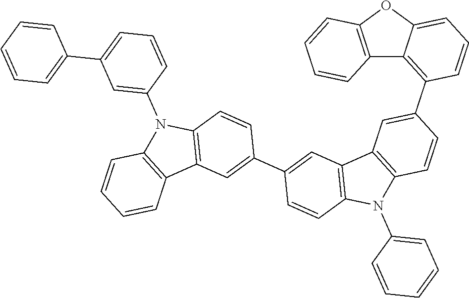 [SMILES: c1ccc(-c2cccc(-n3c4ccccc4c4cc(-c5ccc6c(c5)c5cc(-c7cccc8oc9ccccc9c78)ccc5n6-c5ccccc5)ccc43)c2)cc1]

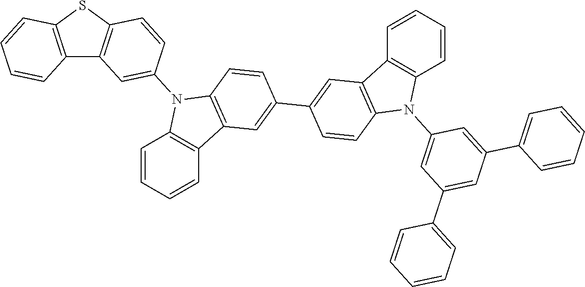 [SMILES: c1ccc(-c2cc(-c3ccccc3)cc(-n3c4ccccc4c4cc(-c5ccc6c(c5)c5ccccc5n6-c5ccc6sc7ccccc7c6c5)ccc43)c2)cc1]

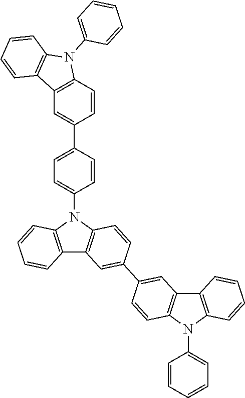 [SMILES: c1ccc(-n2c3ccccc3c3cc(-c4ccc(-n5c6ccccc6c6cc(-c7ccc8c(c7)c7ccccc7n8-c7ccccc7)ccc65)cc4)ccc32)cc1]

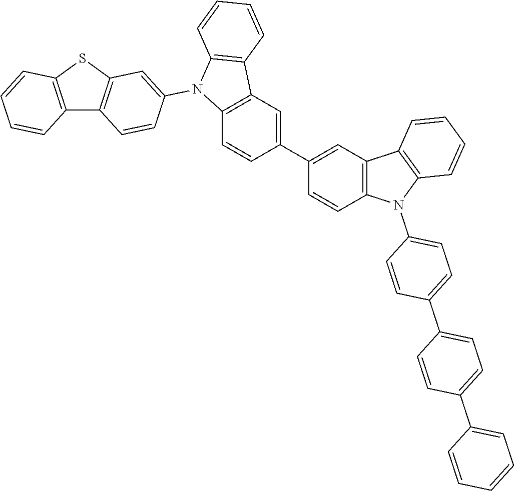 [SMILES: c1ccc(-c2ccc(-c3ccc(-n4c5ccccc5c5cc(-c6ccc7c(c6)c6ccccc6n7-c6ccc7c(c6)sc6ccccc67)ccc54)cc3)cc2)cc1]

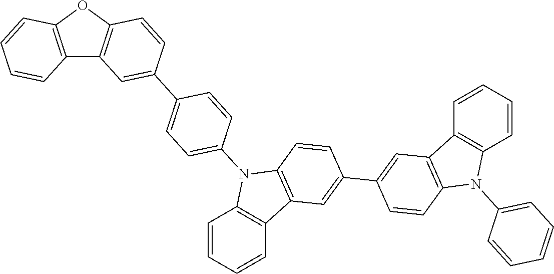 [SMILES: c1ccc(-n2c3ccccc3c3cc(-c4ccc5c(c4)c4ccccc4n5-c4ccc(-c5ccc6oc7ccccc7c6c5)cc4)ccc32)cc1]

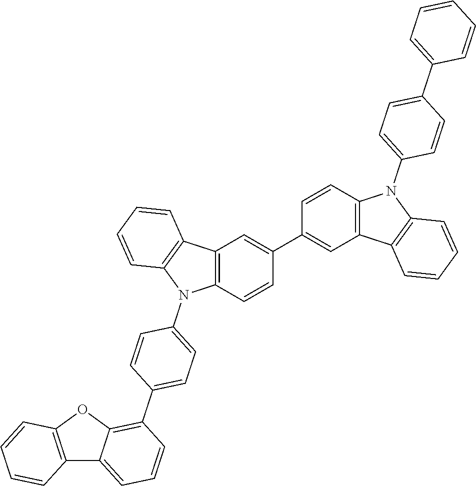 [SMILES: c1ccc(-c2ccc(-n3c4ccccc4c4cc(-c5ccc6c(c5)c5ccccc5n6-c5ccc(-c6cccc7c6oc6ccccc67)cc5)ccc43)cc2)cc1]

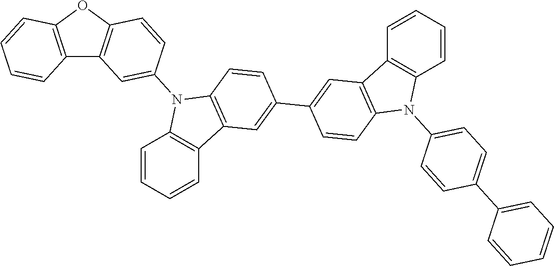 [SMILES: c1ccc(-c2ccc(-n3c4ccccc4c4cc(-c5ccc6c(c5)c5ccccc5n6-c5ccc6oc7ccccc7c6c5)ccc43)cc2)cc1]

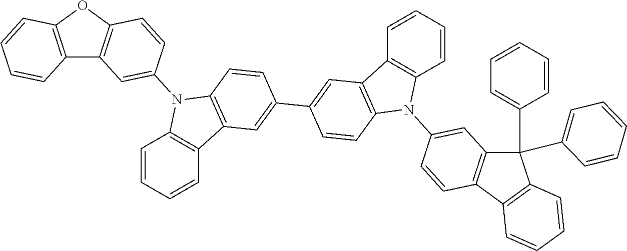 [SMILES: c1ccc(C2(c3ccccc3)c3ccccc3-c3ccc(-n4c5ccccc5c5cc(-c6ccc7c(c6)c6ccccc6n7-c6ccc7oc8ccccc8c7c6)ccc54)cc32)cc1]

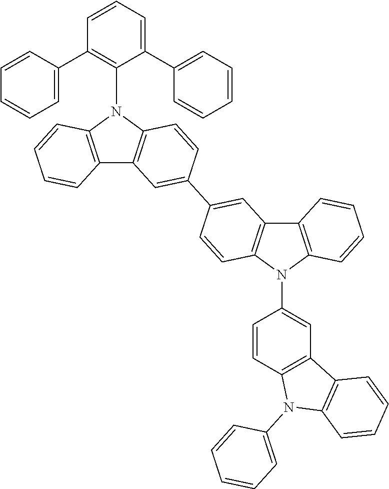 [SMILES: c1ccc(-c2cccc(-c3ccccc3)c2-n2c3ccccc3c3cc(-c4ccc5c(c4)c4ccccc4n5-c4ccc5c(c4)c4ccccc4n5-c4ccccc4)ccc32)cc1]

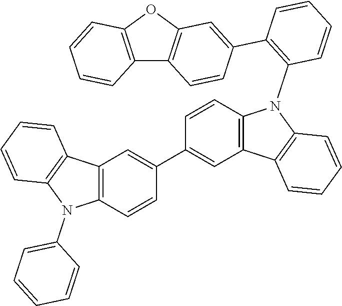 [SMILES: c1ccc(-n2c3ccccc3c3cc(-c4ccc5c(c4)c4ccccc4n5-c4ccccc4-c4ccc5c(c4)oc4ccccc45)ccc32)cc1]

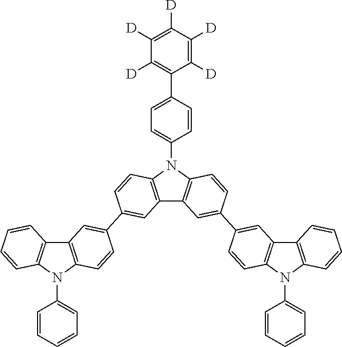 [SMILES: [2H]c1c([2H])c([2H])c(-c2ccc(-n3c4ccc(-c5ccc6c(c5)c5ccccc5n6-c5ccccc5)cc4c4cc(-c5ccc6c(c5)c5ccccc5n6-c5ccccc5)ccc43)cc2)c([2H])c1[2H]]

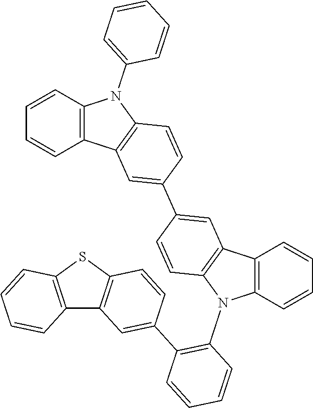 [SMILES: c1ccc(-n2c3ccccc3c3cc(-c4ccc5c(c4)c4ccccc4n5-c4ccccc4-c4ccc5sc6ccccc6c5c4)ccc32)cc1]

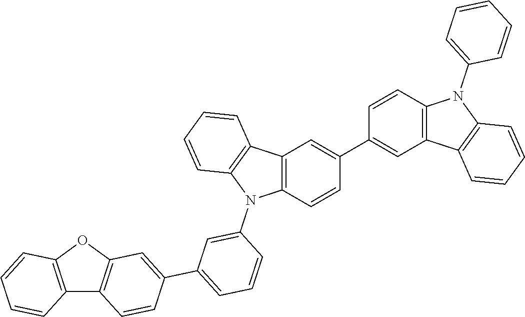 [SMILES: c1ccc(-n2c3ccccc3c3cc(-c4ccc5c(c4)c4ccccc4n5-c4cccc(-c5ccc6c(c5)oc5ccccc56)c4)ccc32)cc1]

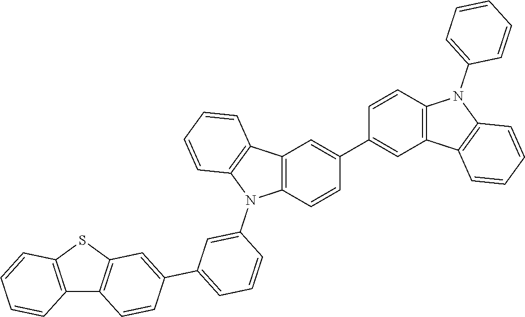 [SMILES: c1ccc(-n2c3ccccc3c3cc(-c4ccc5c(c4)c4ccccc4n5-c4cccc(-c5ccc6c(c5)sc5ccccc56)c4)ccc32)cc1]

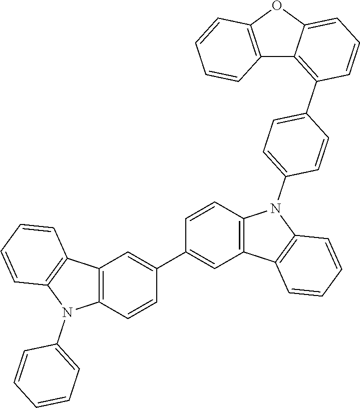 [SMILES: c1ccc(-n2c3ccccc3c3cc(-c4ccc5c(c4)c4ccccc4n5-c4ccc(-c5cccc6oc7ccccc7c56)cc4)ccc32)cc1]

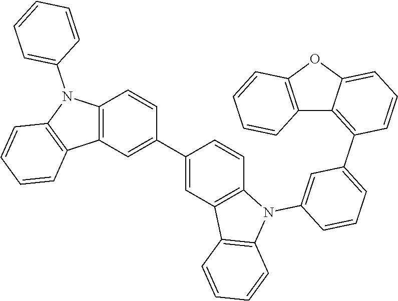 [SMILES: c1ccc(-n2c3ccccc3c3cc(-c4ccc5c(c4)c4ccccc4n5-c4cccc(-c5cccc6oc7ccccc7c56)c4)ccc32)cc1]

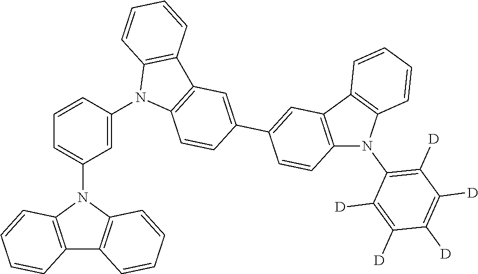 [SMILES: [2H]c1c([2H])c([2H])c(-n2c3ccccc3c3cc(-c4ccc5c(c4)c4ccccc4n5-c4cccc(-n5c6ccccc6c6ccccc65)c4)ccc32)c([2H])c1[2H]]

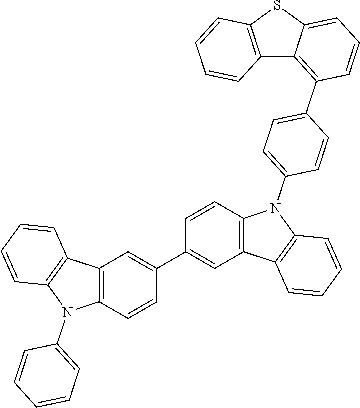 [SMILES: c1ccc(-n2c3ccccc3c3cc(-c4ccc5c(c4)c4ccccc4n5-c4ccc(-c5cccc6sc7ccccc7c56)cc4)ccc32)cc1]

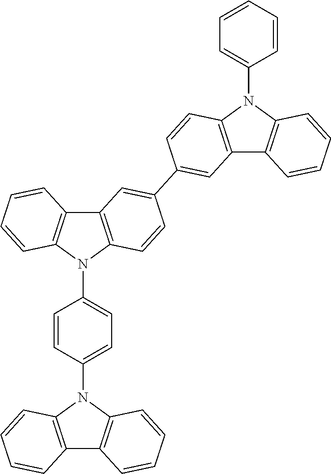 [SMILES: c1ccc(-n2c3ccccc3c3cc(-c4ccc5c(c4)c4ccccc4n5-c4ccc(-n5c6ccccc6c6ccccc65)cc4)ccc32)cc1]

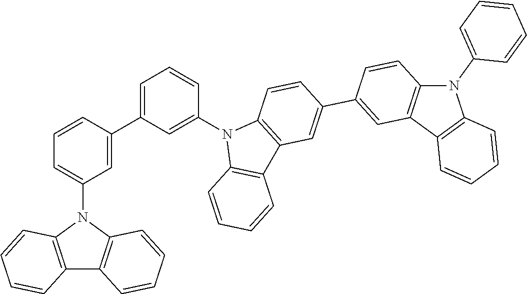 [SMILES: c1ccc(-n2c3ccccc3c3cc(-c4ccc5c(c4)c4ccccc4n5-c4cccc(-c5cccc(-n6c7ccccc7c7ccccc76)c5)c4)ccc32)cc1]

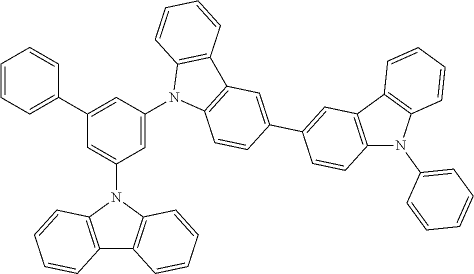 [SMILES: c1ccc(-c2cc(-n3c4ccccc4c4ccccc43)cc(-n3c4ccccc4c4cc(-c5ccc6c(c5)c5ccccc5n6-c5ccccc5)ccc43)c2)cc1]

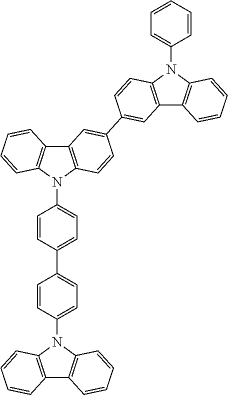 [SMILES: c1ccc(-n2c3ccccc3c3cc(-c4ccc5c(c4)c4ccccc4n5-c4ccc(-c5ccc(-n6c7ccccc7c7ccccc76)cc5)cc4)ccc32)cc1]

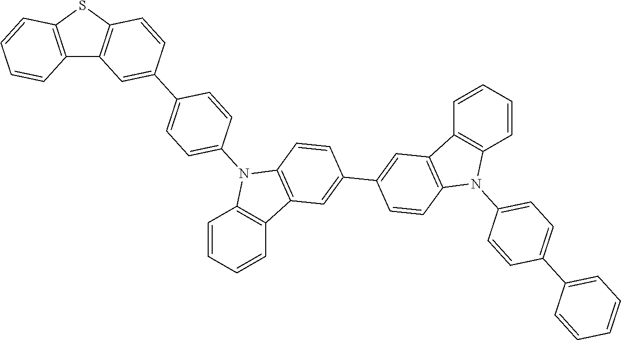 [SMILES: c1ccc(-c2ccc(-n3c4ccccc4c4cc(-c5ccc6c(c5)c5ccccc5n6-c5ccc(-c6ccc7sc8ccccc8c7c6)cc5)ccc43)cc2)cc1]

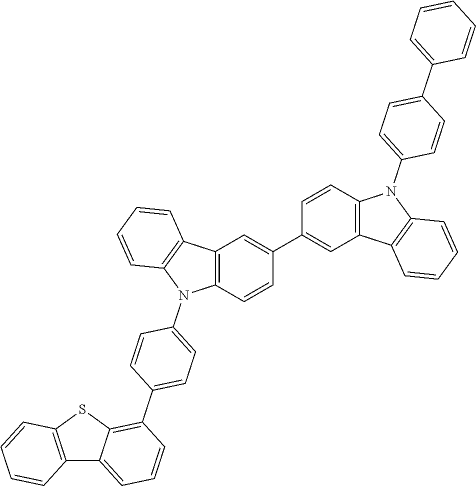 [SMILES: c1ccc(-c2ccc(-n3c4ccccc4c4cc(-c5ccc6c(c5)c5ccccc5n6-c5ccc(-c6cccc7c6sc6ccccc67)cc5)ccc43)cc2)cc1]

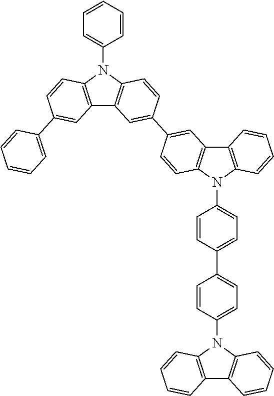 [SMILES: c1ccc(-c2ccc3c(c2)c2cc(-c4ccc5c(c4)c4ccccc4n5-c4ccc(-c5ccc(-n6c7ccccc7c7ccccc76)cc5)cc4)ccc2n3-c2ccccc2)cc1]

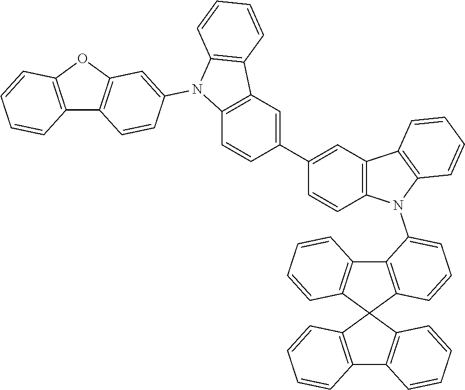 [SMILES: c1ccc2c(c1)-c1ccccc1C21c2ccccc2-c2c(-n3c4ccccc4c4cc(-c5ccc6c(c5)c5ccccc5n6-c5ccc6c(c5)oc5ccccc56)ccc43)cccc21]

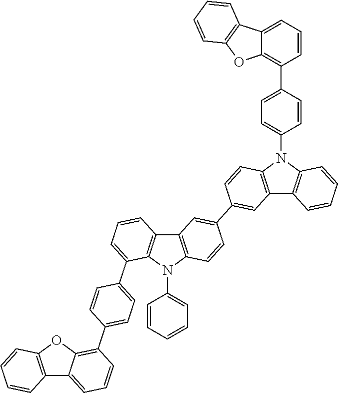 [SMILES: c1ccc(-n2c3ccc(-c4ccc5c(c4)c4ccccc4n5-c4ccc(-c5cccc6c5oc5ccccc56)cc4)cc3c3cccc(-c4ccc(-c5cccc6c5oc5ccccc56)cc4)c32)cc1]

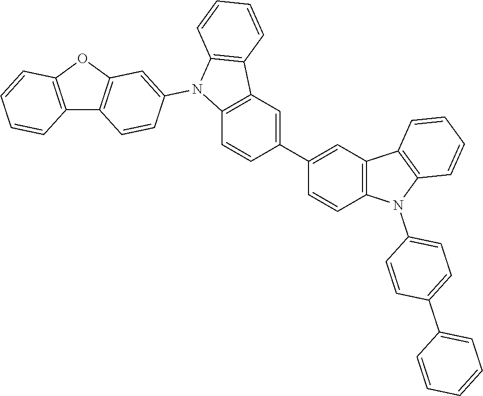 [SMILES: c1ccc(-c2ccc(-n3c4ccccc4c4cc(-c5ccc6c(c5)c5ccccc5n6-c5ccc6c(c5)oc5ccccc56)ccc43)cc2)cc1]

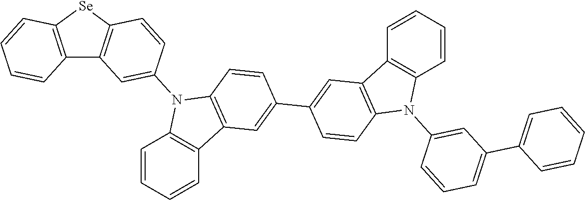 [SMILES: c1ccc(-c2cccc(-n3c4ccccc4c4cc(-c5ccc6c(c5)c5ccccc5n6-c5ccc6[se]c7ccccc7c6c5)ccc43)c2)cc1]

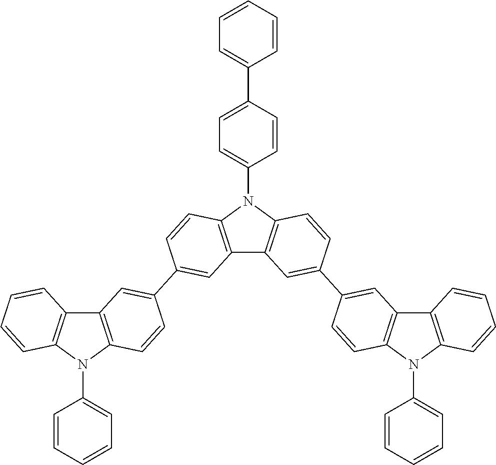 [SMILES: c1ccc(-c2ccc(-n3c4ccc(-c5ccc6c(c5)c5ccccc5n6-c5ccccc5)cc4c4cc(-c5ccc6c(c5)c5ccccc5n6-c5ccccc5)ccc43)cc2)cc1]

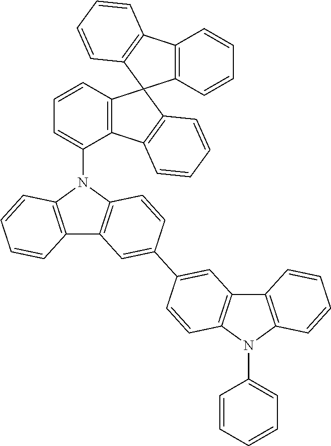 [SMILES: c1ccc(-n2c3ccccc3c3cc(-c4ccc5c(c4)c4ccccc4n5-c4cccc5c4-c4ccccc4C54c5ccccc5-c5ccccc54)ccc32)cc1]

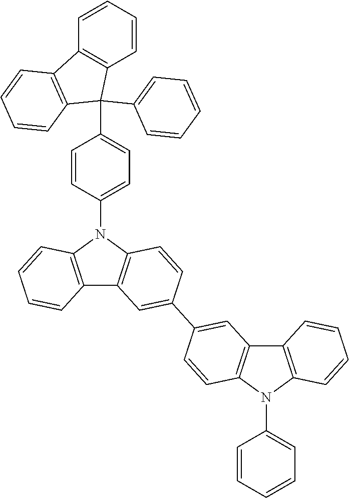 [SMILES: c1ccc(-n2c3ccccc3c3cc(-c4ccc5c(c4)c4ccccc4n5-c4ccc(C5(c6ccccc6)c6ccccc6-c6ccccc65)cc4)ccc32)cc1]

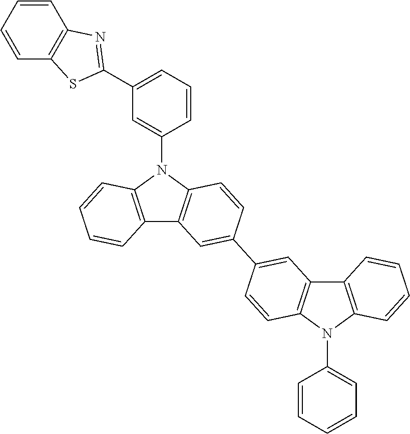 [SMILES: c1ccc(-n2c3ccccc3c3cc(-c4ccc5c(c4)c4ccccc4n5-c4cccc(-c5nc6ccccc6s5)c4)ccc32)cc1]

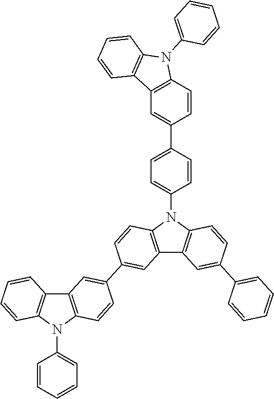 [SMILES: c1ccc(-c2ccc3c(c2)c2cc(-c4ccc5c(c4)c4ccccc4n5-c4ccccc4)ccc2n3-c2ccc(-c3ccc4c(c3)c3ccccc3n4-c3ccccc3)cc2)cc1]

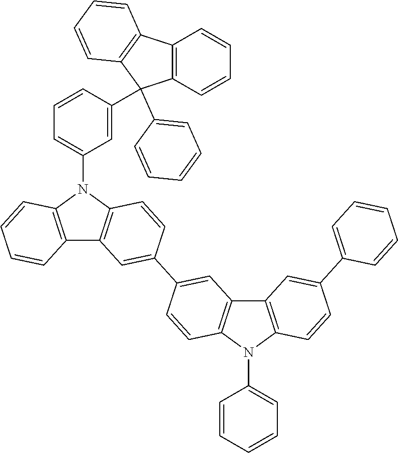 [SMILES: c1ccc(-c2ccc3c(c2)c2cc(-c4ccc5c(c4)c4ccccc4n5-c4cccc(C5(c6ccccc6)c6ccccc6-c6ccccc65)c4)ccc2n3-c2ccccc2)cc1]

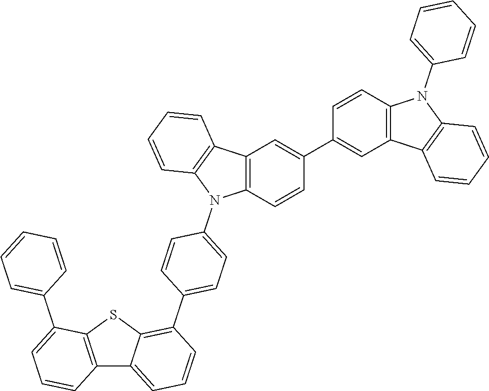 [SMILES: c1ccc(-c2cccc3c2sc2c(-c4ccc(-n5c6ccccc6c6cc(-c7ccc8c(c7)c7ccccc7n8-c7ccccc7)ccc65)cc4)cccc23)cc1]

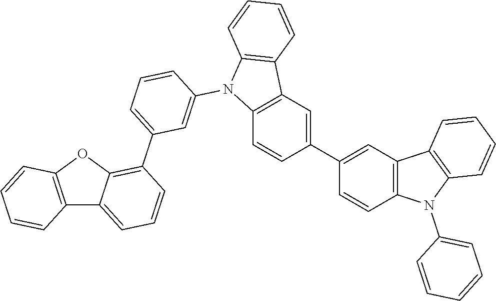 [SMILES: c1ccc(-n2c3ccccc3c3cc(-c4ccc5c(c4)c4ccccc4n5-c4cccc(-c5cccc6c5oc5ccccc56)c4)ccc32)cc1]

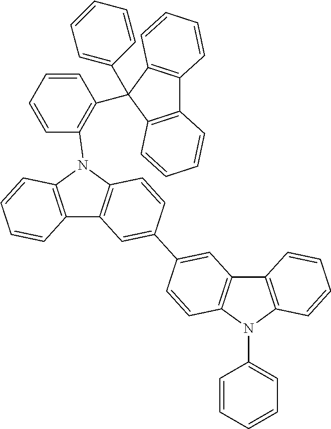 [SMILES: c1ccc(-n2c3ccccc3c3cc(-c4ccc5c(c4)c4ccccc4n5-c4ccccc4C4(c5ccccc5)c5ccccc5-c5ccccc54)ccc32)cc1]

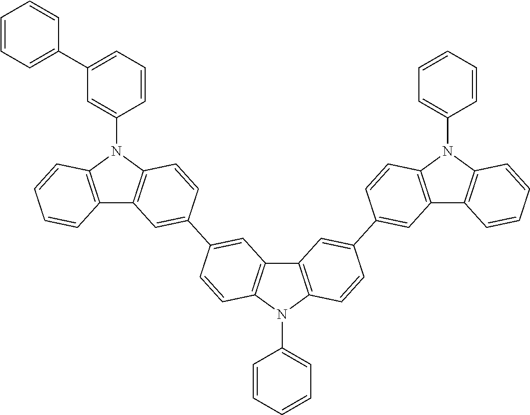 [SMILES: c1ccc(-c2cccc(-n3c4ccccc4c4cc(-c5ccc6c(c5)c5cc(-c7ccc8c(c7)c7ccccc7n8-c7ccccc7)ccc5n6-c5ccccc5)ccc43)c2)cc1]

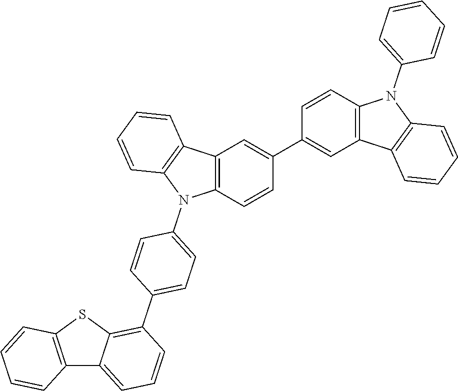 [SMILES: c1ccc(-n2c3ccccc3c3cc(-c4ccc5c(c4)c4ccccc4n5-c4ccc(-c5cccc6c5sc5ccccc56)cc4)ccc32)cc1]

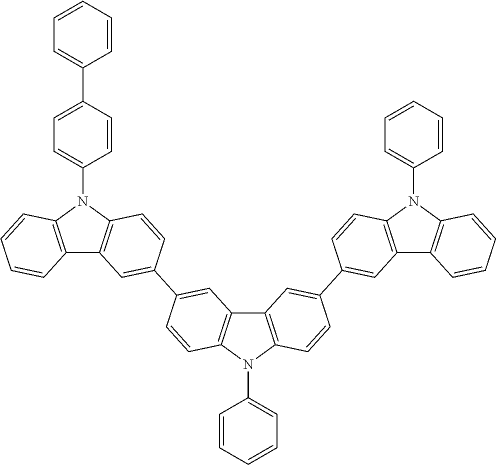 [SMILES: c1ccc(-c2ccc(-n3c4ccccc4c4cc(-c5ccc6c(c5)c5cc(-c7ccc8c(c7)c7ccccc7n8-c7ccccc7)ccc5n6-c5ccccc5)ccc43)cc2)cc1]

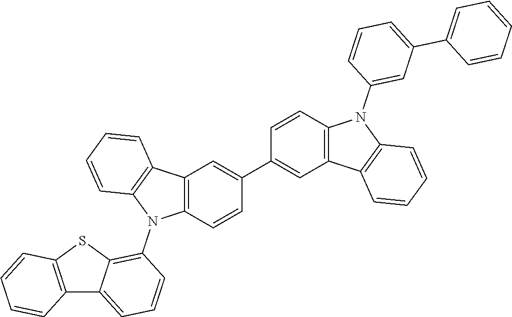 [SMILES: c1ccc(-c2cccc(-n3c4ccccc4c4cc(-c5ccc6c(c5)c5ccccc5n6-c5cccc6c5sc5ccccc56)ccc43)c2)cc1]

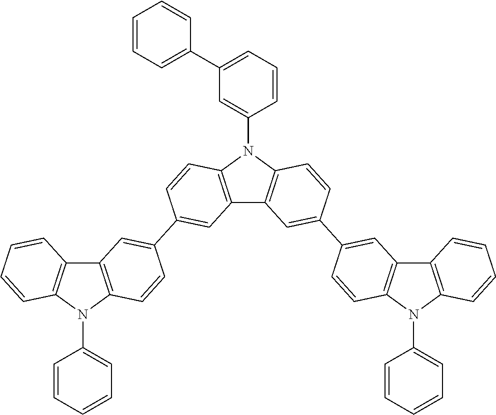 [SMILES: c1ccc(-c2cccc(-n3c4ccc(-c5ccc6c(c5)c5ccccc5n6-c5ccccc5)cc4c4cc(-c5ccc6c(c5)c5ccccc5n6-c5ccccc5)ccc43)c2)cc1]

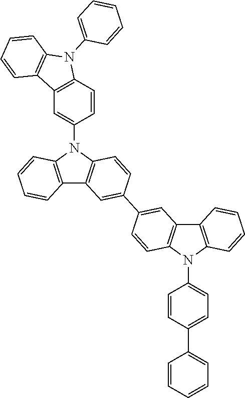 [SMILES: c1ccc(-c2ccc(-n3c4ccccc4c4cc(-c5ccc6c(c5)c5ccccc5n6-c5ccc6c(c5)c5ccccc5n6-c5ccccc5)ccc43)cc2)cc1]

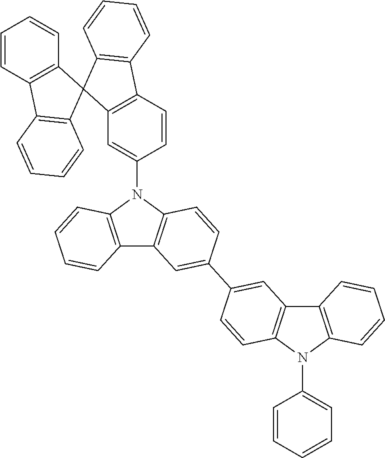 [SMILES: c1ccc(-n2c3ccccc3c3cc(-c4ccc5c(c4)c4ccccc4n5-c4ccc5c(c4)C4(c6ccccc6-c6ccccc64)c4ccccc4-5)ccc32)cc1]

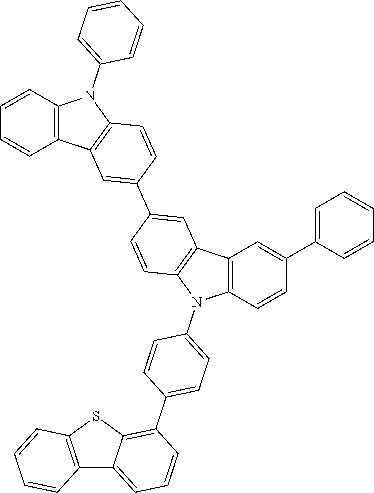 [SMILES: c1ccc(-c2ccc3c(c2)c2cc(-c4ccc5c(c4)c4ccccc4n5-c4ccccc4)ccc2n3-c2ccc(-c3cccc4c3sc3ccccc34)cc2)cc1]

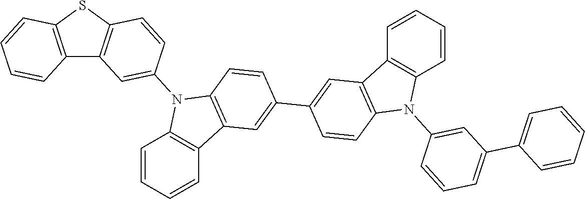 [SMILES: c1ccc(-c2cccc(-n3c4ccccc4c4cc(-c5ccc6c(c5)c5ccccc5n6-c5ccc6sc7ccccc7c6c5)ccc43)c2)cc1]

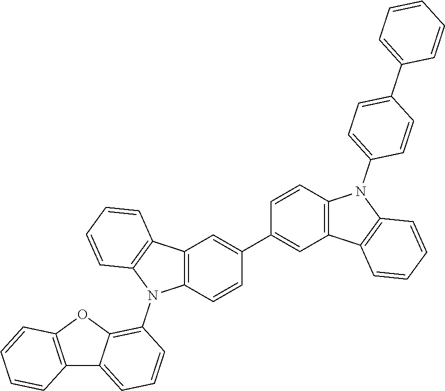 [SMILES: c1ccc(-c2ccc(-n3c4ccccc4c4cc(-c5ccc6c(c5)c5ccccc5n6-c5cccc6c5oc5ccccc56)ccc43)cc2)cc1]

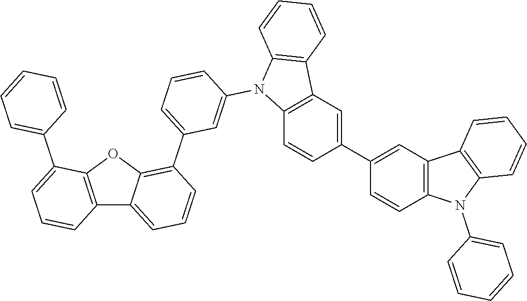 [SMILES: c1ccc(-c2cccc3c2oc2c(-c4cccc(-n5c6ccccc6c6cc(-c7ccc8c(c7)c7ccccc7n8-c7ccccc7)ccc65)c4)cccc23)cc1]

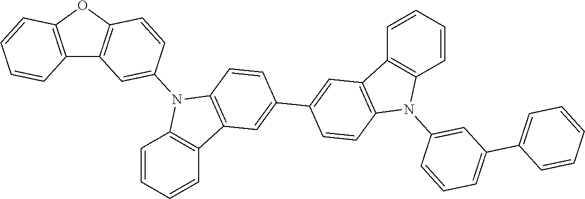 [SMILES: c1ccc(-c2cccc(-n3c4ccccc4c4cc(-c5ccc6c(c5)c5ccccc5n6-c5ccc6oc7ccccc7c6c5)ccc43)c2)cc1]

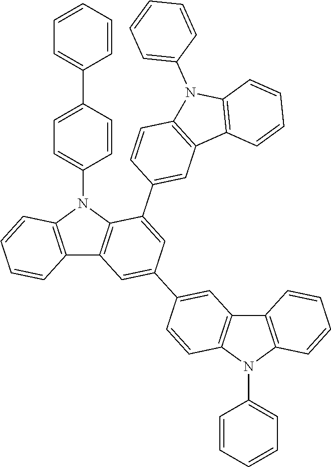 [SMILES: c1ccc(-c2ccc(-n3c4ccccc4c4cc(-c5ccc6c(c5)c5ccccc5n6-c5ccccc5)cc(-c5ccc6c(c5)c5ccccc5n6-c5ccccc5)c43)cc2)cc1]

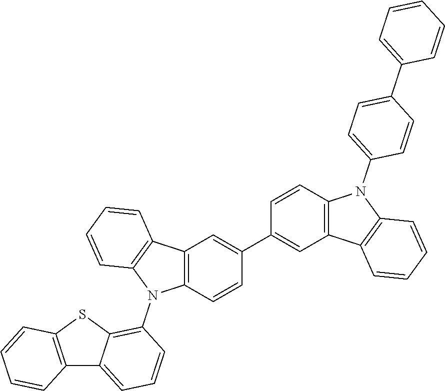 [SMILES: c1ccc(-c2ccc(-n3c4ccccc4c4cc(-c5ccc6c(c5)c5ccccc5n6-c5cccc6c5sc5ccccc56)ccc43)cc2)cc1]

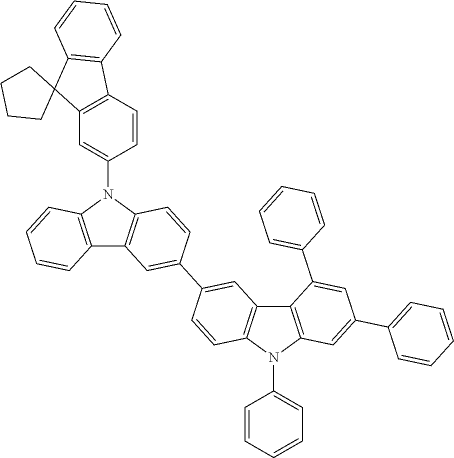 [SMILES: c1ccc(-c2cc(-c3ccccc3)c3c4cc(-c5ccc6c(c5)c5ccccc5n6-c5ccc6c(c5)C5(CCCC5)c5ccccc5-6)ccc4n(-c4ccccc4)c3c2)cc1]

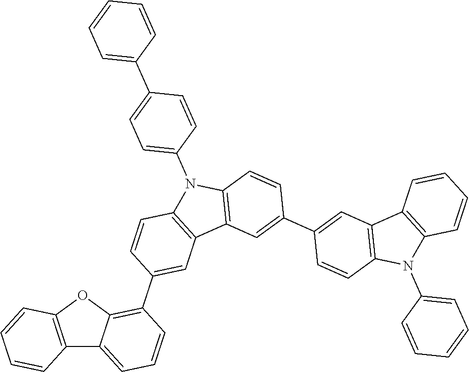 [SMILES: c1ccc(-c2ccc(-n3c4ccc(-c5ccc6c(c5)c5ccccc5n6-c5ccccc5)cc4c4cc(-c5cccc6c5oc5ccccc56)ccc43)cc2)cc1]

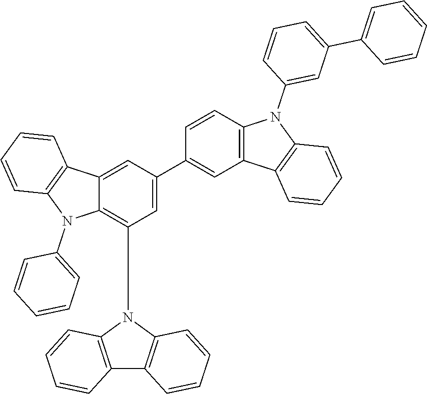 [SMILES: c1ccc(-c2cccc(-n3c4ccccc4c4cc(-c5cc(-n6c7ccccc7c7ccccc76)c6c(c5)c5ccccc5n6-c5ccccc5)ccc43)c2)cc1]

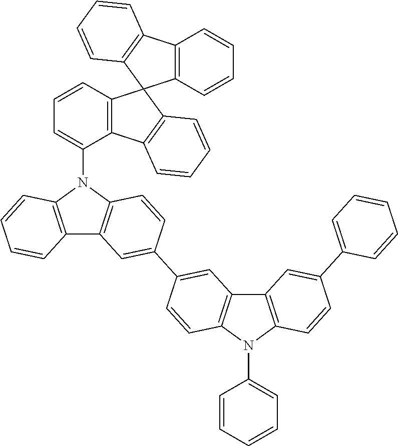 [SMILES: c1ccc(-c2ccc3c(c2)c2cc(-c4ccc5c(c4)c4ccccc4n5-c4cccc5c4-c4ccccc4C54c5ccccc5-c5ccccc54)ccc2n3-c2ccccc2)cc1]

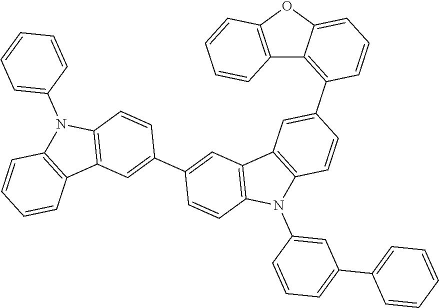 [SMILES: c1ccc(-c2cccc(-n3c4ccc(-c5ccc6c(c5)c5ccccc5n6-c5ccccc5)cc4c4cc(-c5cccc6oc7ccccc7c56)ccc43)c2)cc1]

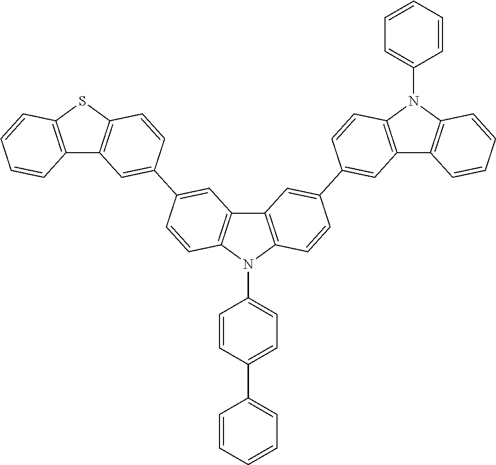 [SMILES: c1ccc(-c2ccc(-n3c4ccc(-c5ccc6sc7ccccc7c6c5)cc4c4cc(-c5ccc6c(c5)c5ccccc5n6-c5ccccc5)ccc43)cc2)cc1]

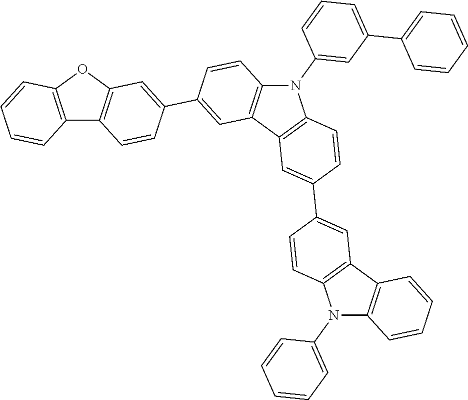 [SMILES: c1ccc(-c2cccc(-n3c4ccc(-c5ccc6c(c5)oc5ccccc56)cc4c4cc(-c5ccc6c(c5)c5ccccc5n6-c5ccccc5)ccc43)c2)cc1]

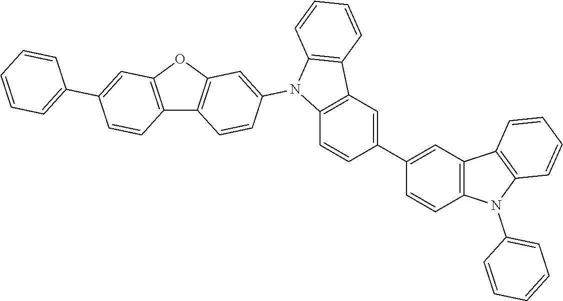 [SMILES: c1ccc(-c2ccc3c(c2)oc2cc(-n4c5ccccc5c5cc(-c6ccc7c(c6)c6ccccc6n7-c6ccccc6)ccc54)ccc23)cc1]

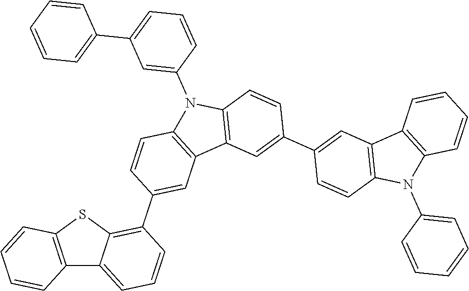 [SMILES: c1ccc(-c2cccc(-n3c4ccc(-c5ccc6c(c5)c5ccccc5n6-c5ccccc5)cc4c4cc(-c5cccc6c5sc5ccccc56)ccc43)c2)cc1]

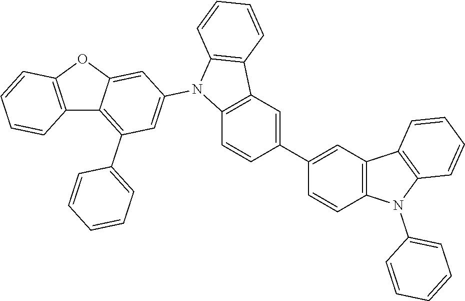 [SMILES: c1ccc(-c2cc(-n3c4ccccc4c4cc(-c5ccc6c(c5)c5ccccc5n6-c5ccccc5)ccc43)cc3oc4ccccc4c23)cc1]

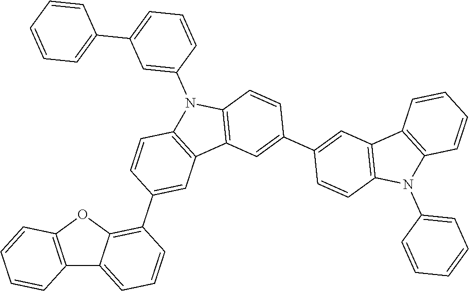 [SMILES: c1ccc(-c2cccc(-n3c4ccc(-c5ccc6c(c5)c5ccccc5n6-c5ccccc5)cc4c4cc(-c5cccc6c5oc5ccccc56)ccc43)c2)cc1]

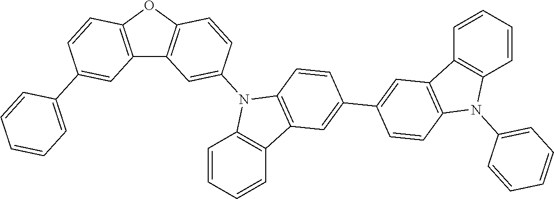 [SMILES: c1ccc(-c2ccc3oc4ccc(-n5c6ccccc6c6cc(-c7ccc8c(c7)c7ccccc7n8-c7ccccc7)ccc65)cc4c3c2)cc1]

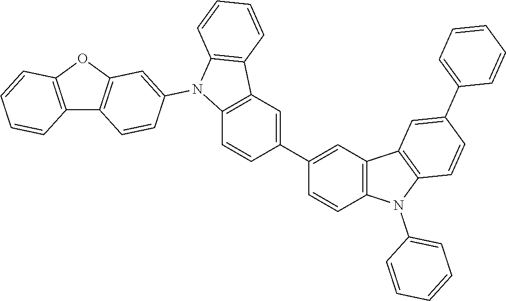 [SMILES: c1ccc(-c2ccc3c(c2)c2cc(-c4ccc5c(c4)c4ccccc4n5-c4ccc5c(c4)oc4ccccc45)ccc2n3-c2ccccc2)cc1]

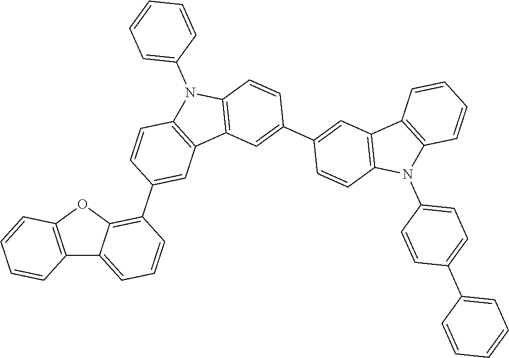 [SMILES: c1ccc(-c2ccc(-n3c4ccccc4c4cc(-c5ccc6c(c5)c5cc(-c7cccc8c7oc7ccccc78)ccc5n6-c5ccccc5)ccc43)cc2)cc1]

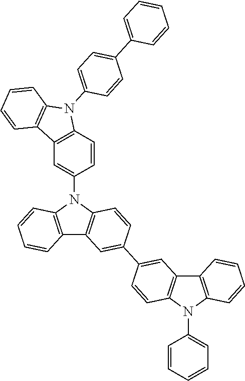 [SMILES: c1ccc(-c2ccc(-n3c4ccccc4c4cc(-n5c6ccccc6c6cc(-c7ccc8c(c7)c7ccccc7n8-c7ccccc7)ccc65)ccc43)cc2)cc1]

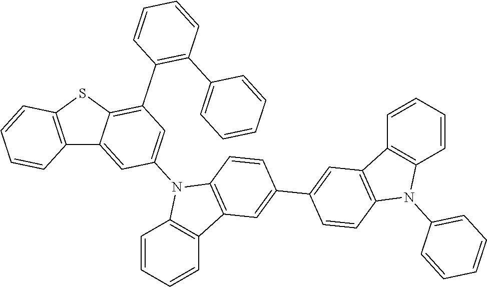 [SMILES: c1ccc(-c2ccccc2-c2cc(-n3c4ccccc4c4cc(-c5ccc6c(c5)c5ccccc5n6-c5ccccc5)ccc43)cc3c2sc2ccccc23)cc1]

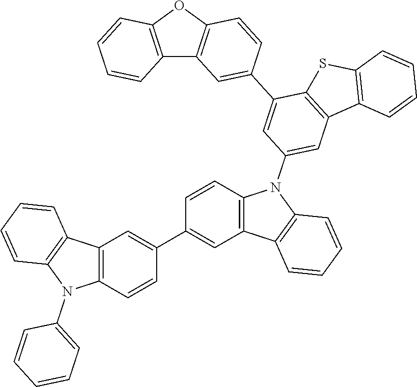 [SMILES: c1ccc(-n2c3ccccc3c3cc(-c4ccc5c(c4)c4ccccc4n5-c4cc(-c5ccc6oc7ccccc7c6c5)c5sc6ccccc6c5c4)ccc32)cc1]

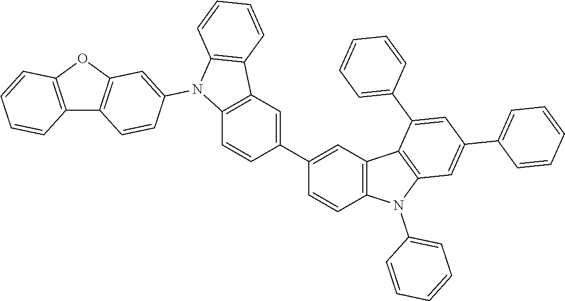 [SMILES: c1ccc(-c2cc(-c3ccccc3)c3c4cc(-c5ccc6c(c5)c5ccccc5n6-c5ccc6c(c5)oc5ccccc56)ccc4n(-c4ccccc4)c3c2)cc1]

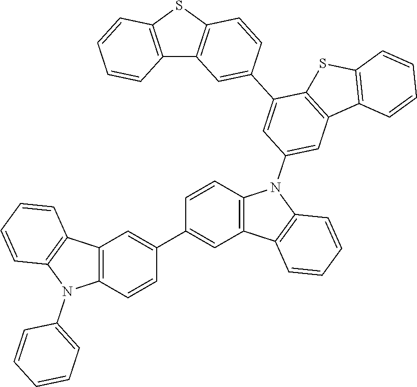 [SMILES: c1ccc(-n2c3ccccc3c3cc(-c4ccc5c(c4)c4ccccc4n5-c4cc(-c5ccc6sc7ccccc7c6c5)c5sc6ccccc6c5c4)ccc32)cc1]

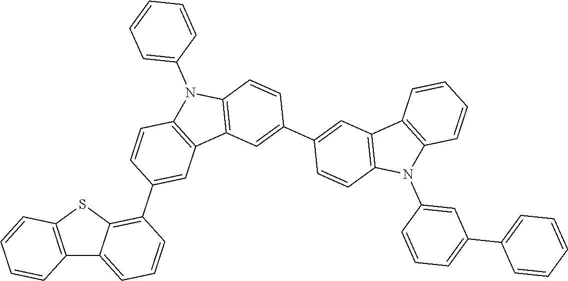 [SMILES: c1ccc(-c2cccc(-n3c4ccccc4c4cc(-c5ccc6c(c5)c5cc(-c7cccc8c7sc7ccccc78)ccc5n6-c5ccccc5)ccc43)c2)cc1]

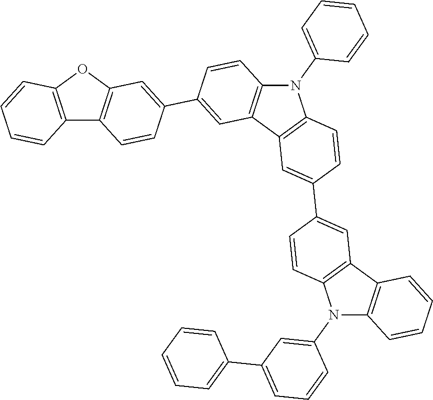 [SMILES: c1ccc(-c2cccc(-n3c4ccccc4c4cc(-c5ccc6c(c5)c5cc(-c7ccc8c(c7)oc7ccccc78)ccc5n6-c5ccccc5)ccc43)c2)cc1]

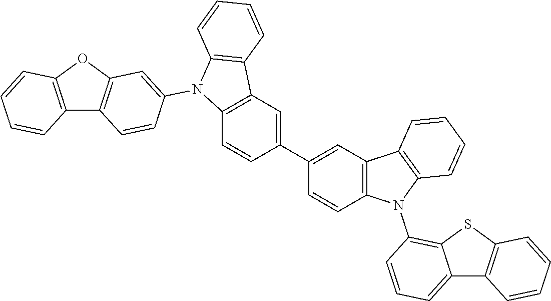 [SMILES: c1ccc2c(c1)oc1cc(-n3c4ccccc4c4cc(-c5ccc6c(c5)c5ccccc5n6-c5cccc6c5sc5ccccc56)ccc43)ccc12]

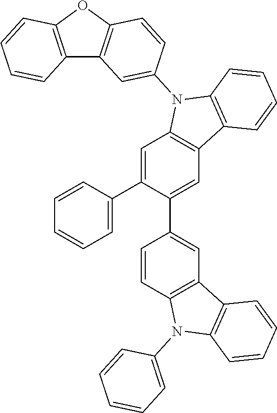 [SMILES: c1ccc(-c2cc3c(cc2-c2ccc4c(c2)c2ccccc2n4-c2ccccc2)c2ccccc2n3-c2ccc3oc4ccccc4c3c2)cc1]

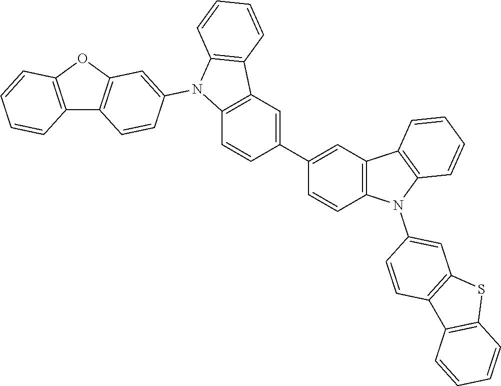 [SMILES: c1ccc2c(c1)oc1cc(-n3c4ccccc4c4cc(-c5ccc6c(c5)c5ccccc5n6-c5ccc6c(c5)sc5ccccc56)ccc43)ccc12]

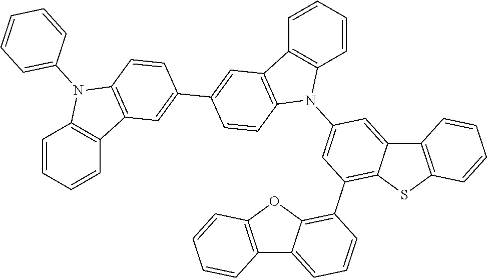 [SMILES: c1ccc(-n2c3ccccc3c3cc(-c4ccc5c(c4)c4ccccc4n5-c4cc(-c5cccc6c5oc5ccccc56)c5sc6ccccc6c5c4)ccc32)cc1]

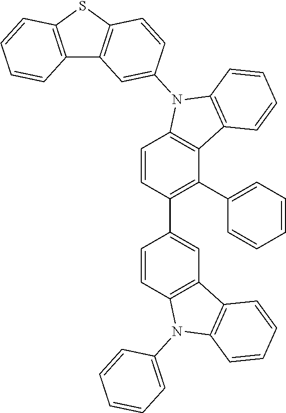 [SMILES: c1ccc(-c2c(-c3ccc4c(c3)c3ccccc3n4-c3ccccc3)ccc3c2c2ccccc2n3-c2ccc3sc4ccccc4c3c2)cc1]

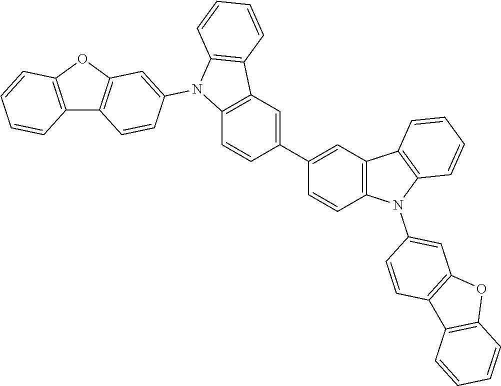 [SMILES: c1ccc2c(c1)oc1cc(-n3c4ccccc4c4cc(-c5ccc6c(c5)c5ccccc5n6-c5ccc6c(c5)oc5ccccc56)ccc43)ccc12]

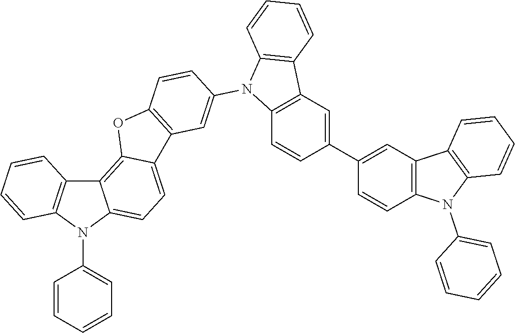 [SMILES: c1ccc(-n2c3ccccc3c3cc(-c4ccc5c(c4)c4ccccc4n5-c4ccc5oc6c(ccc7c6c6ccccc6n7-c6ccccc6)c5c4)ccc32)cc1]

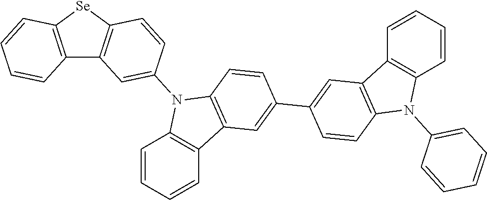 [SMILES: c1ccc(-n2c3ccccc3c3cc(-c4ccc5c(c4)c4ccccc4n5-c4ccc5[se]c6ccccc6c5c4)ccc32)cc1]

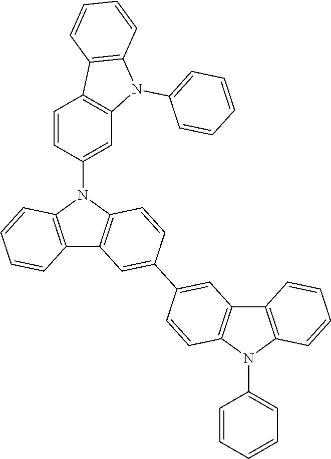 [SMILES: c1ccc(-n2c3ccccc3c3cc(-c4ccc5c(c4)c4ccccc4n5-c4ccc5c6ccccc6n(-c6ccccc6)c5c4)ccc32)cc1]

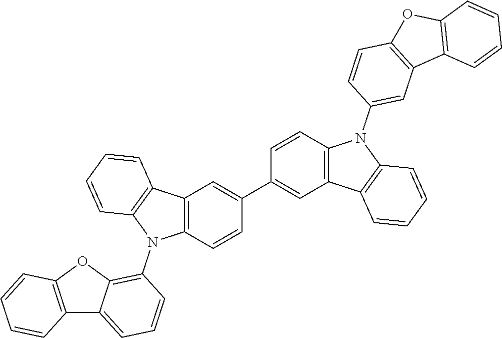 [SMILES: c1ccc2c(c1)oc1ccc(-n3c4ccccc4c4cc(-c5ccc6c(c5)c5ccccc5n6-c5cccc6c5oc5ccccc56)ccc43)cc12]

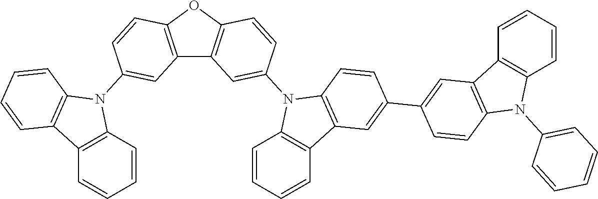 [SMILES: c1ccc(-n2c3ccccc3c3cc(-c4ccc5c(c4)c4ccccc4n5-c4ccc5oc6ccc(-n7c8ccccc8c8ccccc87)cc6c5c4)ccc32)cc1]

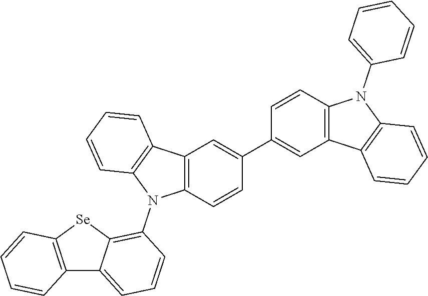 [SMILES: c1ccc(-n2c3ccccc3c3cc(-c4ccc5c(c4)c4ccccc4n5-c4cccc5c4[se]c4ccccc45)ccc32)cc1]

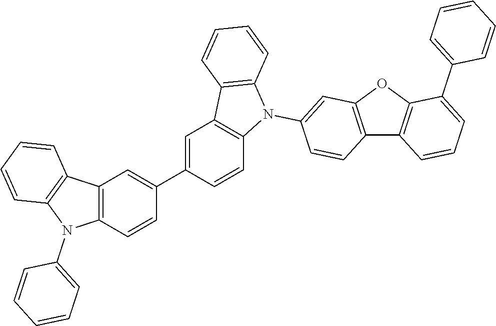 [SMILES: c1ccc(-c2cccc3c2oc2cc(-n4c5ccccc5c5cc(-c6ccc7c(c6)c6ccccc6n7-c6ccccc6)ccc54)ccc23)cc1]

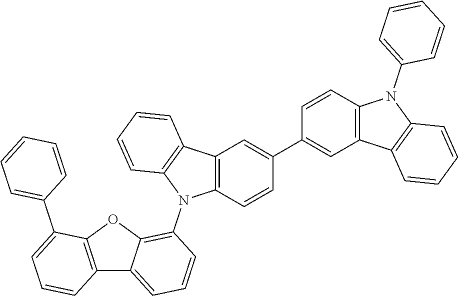 [SMILES: c1ccc(-c2cccc3c2oc2c(-n4c5ccccc5c5cc(-c6ccc7c(c6)c6ccccc6n7-c6ccccc6)ccc54)cccc23)cc1]

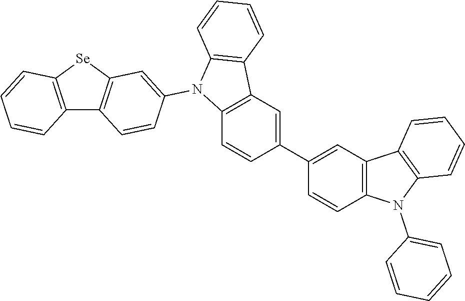 [SMILES: c1ccc(-n2c3ccccc3c3cc(-c4ccc5c(c4)c4ccccc4n5-c4ccc5c(c4)[se]c4ccccc45)ccc32)cc1]

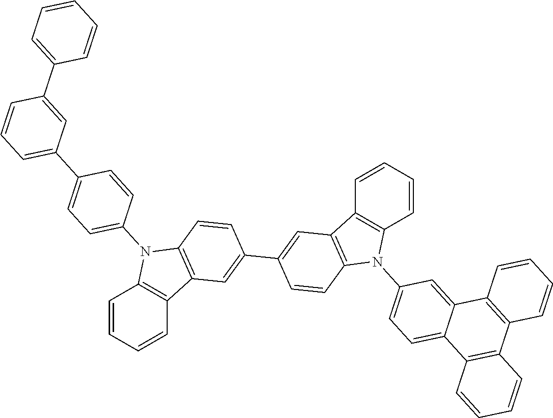 [SMILES: c1ccc(-c2cccc(-c3ccc(-n4c5ccccc5c5cc(-c6ccc7c(c6)c6ccccc6n7-c6ccc7c8ccccc8c8ccccc8c7c6)ccc54)cc3)c2)cc1]

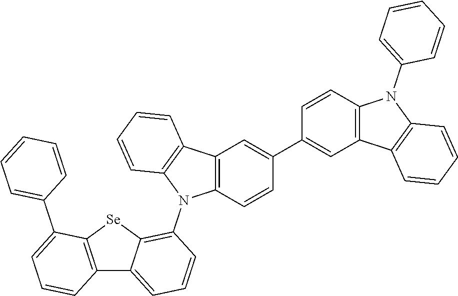 [SMILES: c1ccc(-c2cccc3c2[se]c2c(-n4c5ccccc5c5cc(-c6ccc7c(c6)c6ccccc6n7-c6ccccc6)ccc54)cccc23)cc1]

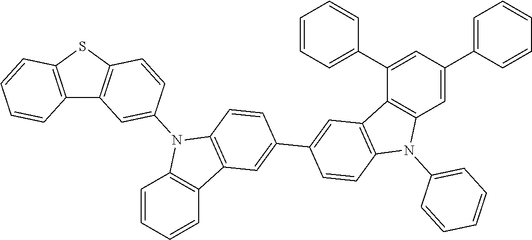 [SMILES: c1ccc(-c2cc(-c3ccccc3)c3c4cc(-c5ccc6c(c5)c5ccccc5n6-c5ccc6sc7ccccc7c6c5)ccc4n(-c4ccccc4)c3c2)cc1]

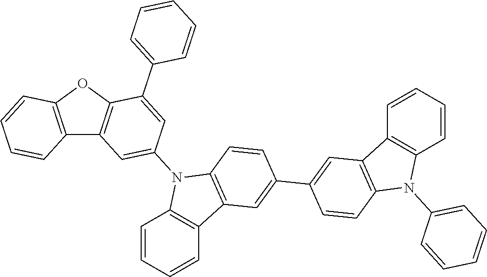 [SMILES: c1ccc(-c2cc(-n3c4ccccc4c4cc(-c5ccc6c(c5)c5ccccc5n6-c5ccccc5)ccc43)cc3c2oc2ccccc23)cc1]

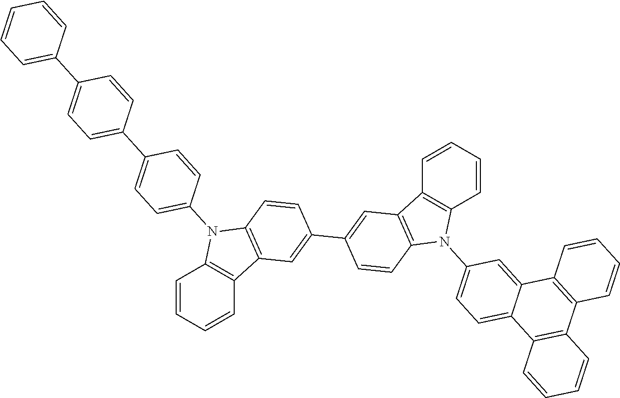 [SMILES: c1ccc(-c2ccc(-c3ccc(-n4c5ccccc5c5cc(-c6ccc7c(c6)c6ccccc6n7-c6ccc7c8ccccc8c8ccccc8c7c6)ccc54)cc3)cc2)cc1]

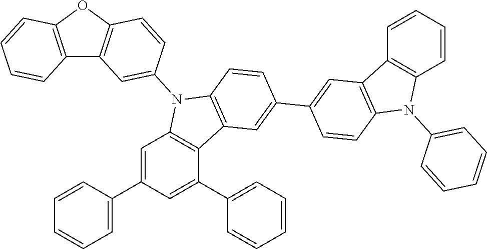 [SMILES: c1ccc(-c2cc(-c3ccccc3)c3c4cc(-c5ccc6c(c5)c5ccccc5n6-c5ccccc5)ccc4n(-c4ccc5oc6ccccc6c5c4)c3c2)cc1]

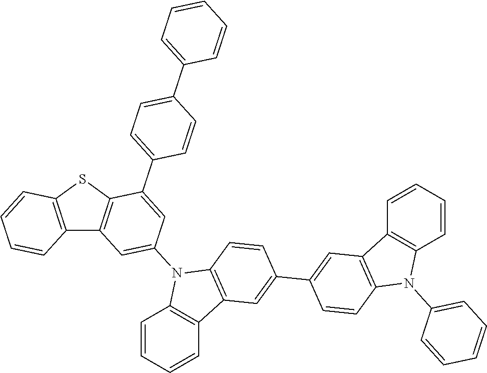 [SMILES: c1ccc(-c2ccc(-c3cc(-n4c5ccccc5c5cc(-c6ccc7c(c6)c6ccccc6n7-c6ccccc6)ccc54)cc4c3sc3ccccc34)cc2)cc1]

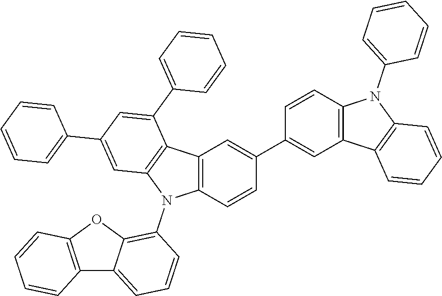 [SMILES: c1ccc(-c2cc(-c3ccccc3)c3c4cc(-c5ccc6c(c5)c5ccccc5n6-c5ccccc5)ccc4n(-c4cccc5c4oc4ccccc45)c3c2)cc1]

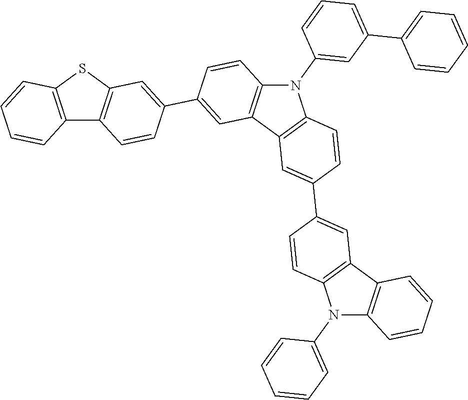 [SMILES: c1ccc(-c2cccc(-n3c4ccc(-c5ccc6c(c5)sc5ccccc56)cc4c4cc(-c5ccc6c(c5)c5ccccc5n6-c5ccccc5)ccc43)c2)cc1]

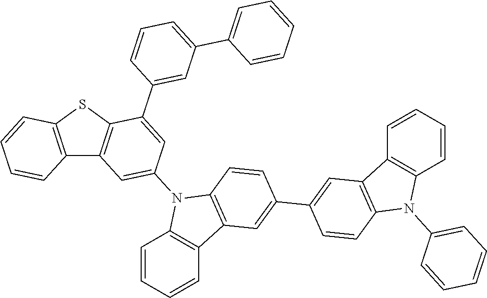 [SMILES: c1ccc(-c2cccc(-c3cc(-n4c5ccccc5c5cc(-c6ccc7c(c6)c6ccccc6n7-c6ccccc6)ccc54)cc4c3sc3ccccc34)c2)cc1]

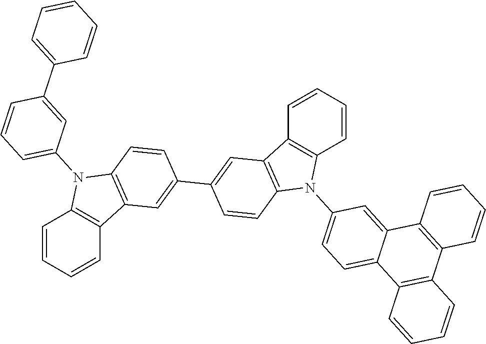 [SMILES: c1ccc(-c2cccc(-n3c4ccccc4c4cc(-c5ccc6c(c5)c5ccccc5n6-c5ccc6c7ccccc7c7ccccc7c6c5)ccc43)c2)cc1]

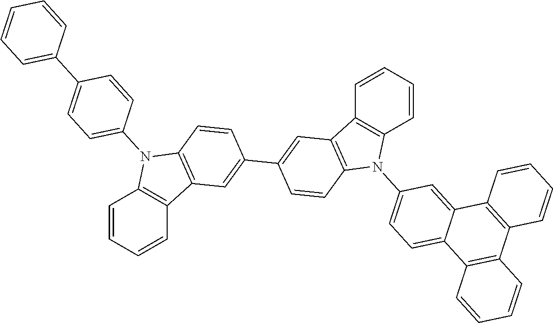 [SMILES: c1ccc(-c2ccc(-n3c4ccccc4c4cc(-c5ccc6c(c5)c5ccccc5n6-c5ccc6c7ccccc7c7ccccc7c6c5)ccc43)cc2)cc1]

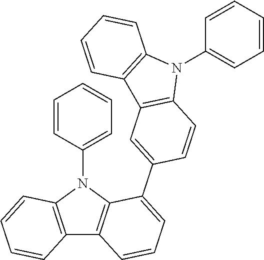 [SMILES: c1ccc(-n2c3ccccc3c3cc(-c4cccc5c6ccccc6n(-c6ccccc6)c45)ccc32)cc1]

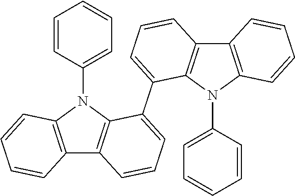 [SMILES: c1ccc(-n2c3ccccc3c3cccc(-c4cccc5c6ccccc6n(-c6ccccc6)c45)c32)cc1]

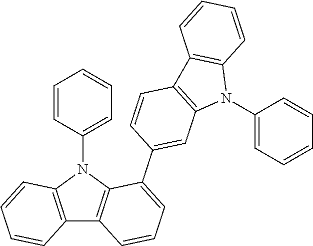 [SMILES: c1ccc(-n2c3ccccc3c3ccc(-c4cccc5c6ccccc6n(-c6ccccc6)c45)cc32)cc1]

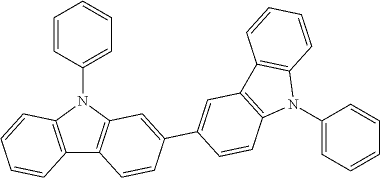 [SMILES: c1ccc(-n2c3ccccc3c3cc(-c4ccc5c6ccccc6n(-c6ccccc6)c5c4)ccc32)cc1]

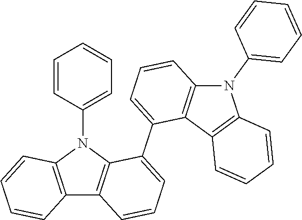 [SMILES: c1ccc(-n2c3ccccc3c3c(-c4cccc5c6ccccc6n(-c6ccccc6)c45)cccc32)cc1]

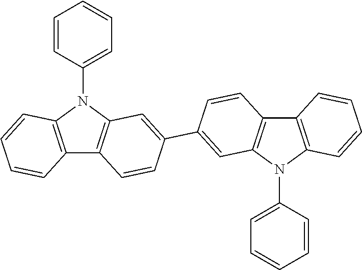 [SMILES: c1ccc(-n2c3ccccc3c3ccc(-c4ccc5c6ccccc6n(-c6ccccc6)c5c4)cc32)cc1]

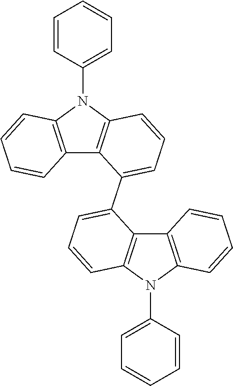 [SMILES: c1ccc(-n2c3ccccc3c3c(-c4cccc5c4c4ccccc4n5-c4ccccc4)cccc32)cc1]

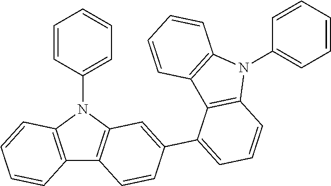 [SMILES: c1ccc(-n2c3ccccc3c3ccc(-c4cccc5c4c4ccccc4n5-c4ccccc4)cc32)cc1]

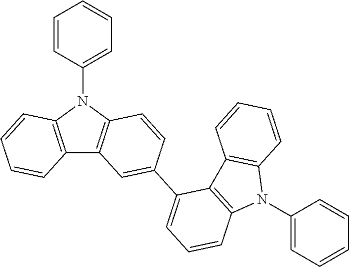 [SMILES: c1ccc(-n2c3ccccc3c3cc(-c4cccc5c4c4ccccc4n5-c4ccccc4)ccc32)cc1]

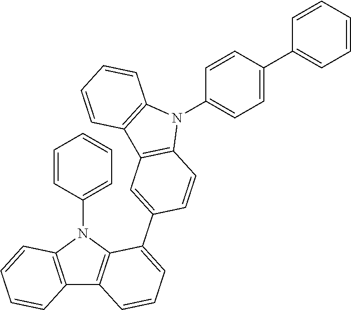 [SMILES: c1ccc(-c2ccc(-n3c4ccccc4c4cc(-c5cccc6c7ccccc7n(-c7ccccc7)c56)ccc43)cc2)cc1]

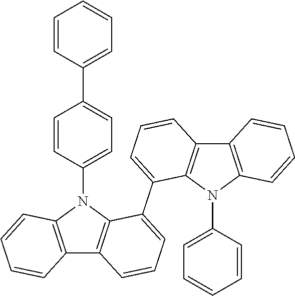 [SMILES: c1ccc(-c2ccc(-n3c4ccccc4c4cccc(-c5cccc6c7ccccc7n(-c7ccccc7)c56)c43)cc2)cc1]

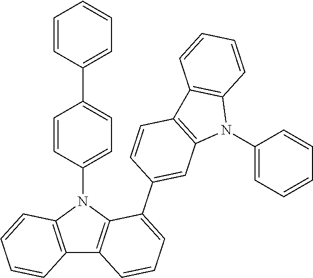 [SMILES: c1ccc(-c2ccc(-n3c4ccccc4c4cccc(-c5ccc6c7ccccc7n(-c7ccccc7)c6c5)c43)cc2)cc1]

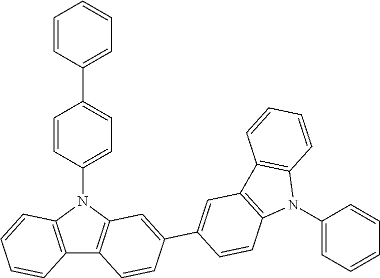 [SMILES: c1ccc(-c2ccc(-n3c4ccccc4c4ccc(-c5ccc6c(c5)c5ccccc5n6-c5ccccc5)cc43)cc2)cc1]

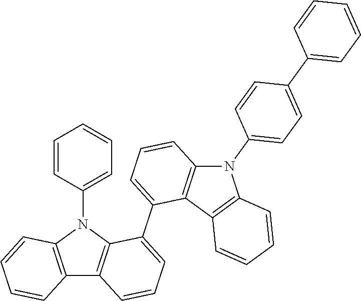 [SMILES: c1ccc(-c2ccc(-n3c4ccccc4c4c(-c5cccc6c7ccccc7n(-c7ccccc7)c56)cccc43)cc2)cc1]

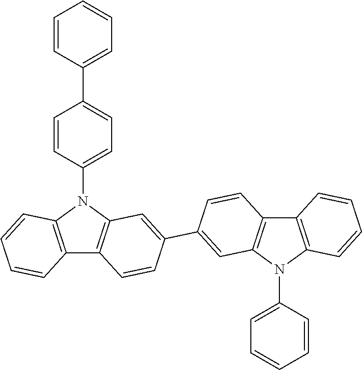 [SMILES: c1ccc(-c2ccc(-n3c4ccccc4c4ccc(-c5ccc6c7ccccc7n(-c7ccccc7)c6c5)cc43)cc2)cc1]

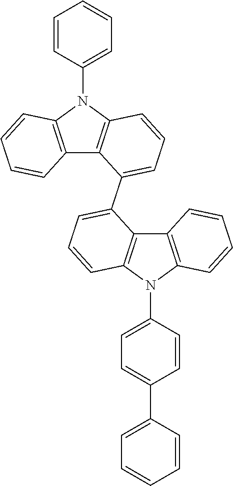 [SMILES: c1ccc(-c2ccc(-n3c4ccccc4c4c(-c5cccc6c5c5ccccc5n6-c5ccccc5)cccc43)cc2)cc1]

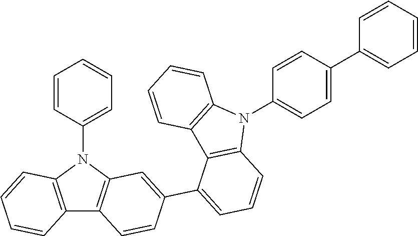 [SMILES: c1ccc(-c2ccc(-n3c4ccccc4c4c(-c5ccc6c7ccccc7n(-c7ccccc7)c6c5)cccc43)cc2)cc1]

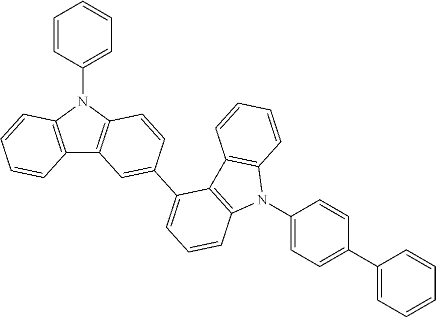 [SMILES: c1ccc(-c2ccc(-n3c4ccccc4c4c(-c5ccc6c(c5)c5ccccc5n6-c5ccccc5)cccc43)cc2)cc1]

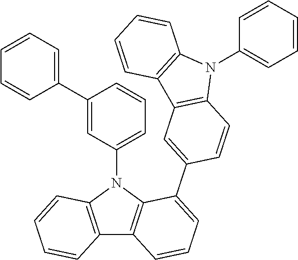 [SMILES: c1ccc(-c2cccc(-n3c4ccccc4c4cccc(-c5ccc6c(c5)c5ccccc5n6-c5ccccc5)c43)c2)cc1]

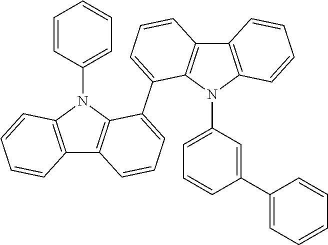 [SMILES: c1ccc(-c2cccc(-n3c4ccccc4c4cccc(-c5cccc6c7ccccc7n(-c7ccccc7)c56)c43)c2)cc1]

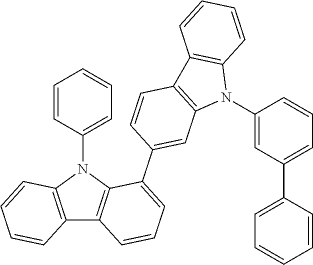 [SMILES: c1ccc(-c2cccc(-n3c4ccccc4c4ccc(-c5cccc6c7ccccc7n(-c7ccccc7)c56)cc43)c2)cc1]

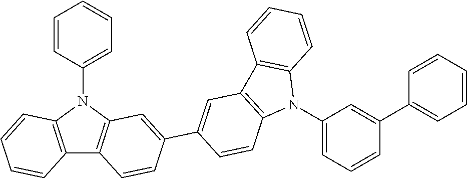 [SMILES: c1ccc(-c2cccc(-n3c4ccccc4c4cc(-c5ccc6c7ccccc7n(-c7ccccc7)c6c5)ccc43)c2)cc1]

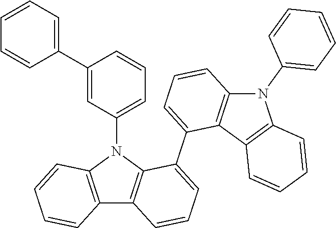 [SMILES: c1ccc(-c2cccc(-n3c4ccccc4c4cccc(-c5cccc6c5c5ccccc5n6-c5ccccc5)c43)c2)cc1]

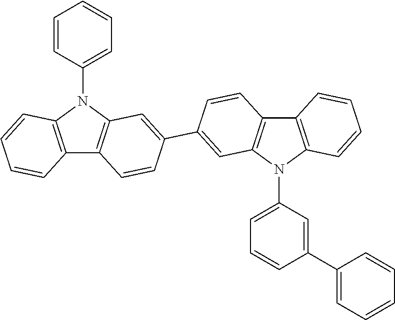 [SMILES: c1ccc(-c2cccc(-n3c4ccccc4c4ccc(-c5ccc6c7ccccc7n(-c7ccccc7)c6c5)cc43)c2)cc1]

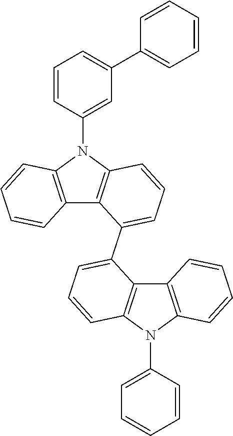 [SMILES: c1ccc(-c2cccc(-n3c4ccccc4c4c(-c5cccc6c5c5ccccc5n6-c5ccccc5)cccc43)c2)cc1]

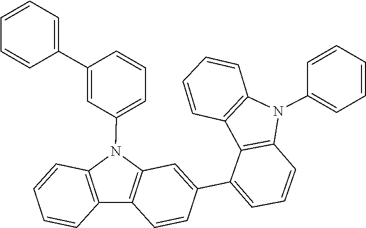 [SMILES: c1ccc(-c2cccc(-n3c4ccccc4c4ccc(-c5cccc6c5c5ccccc5n6-c5ccccc5)cc43)c2)cc1]

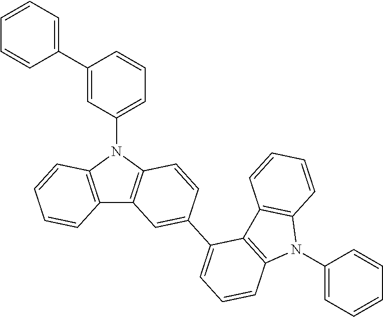 [SMILES: c1ccc(-c2cccc(-n3c4ccccc4c4cc(-c5cccc6c5c5ccccc5n6-c5ccccc5)ccc43)c2)cc1]

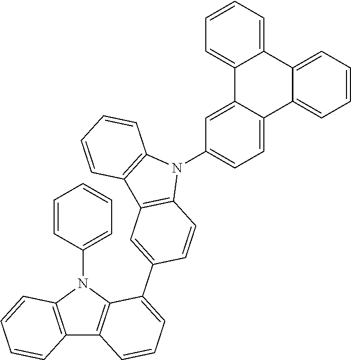 [SMILES: c1ccc(-n2c3ccccc3c3cccc(-c4ccc5c(c4)c4ccccc4n5-c4ccc5c6ccccc6c6ccccc6c5c4)c32)cc1]

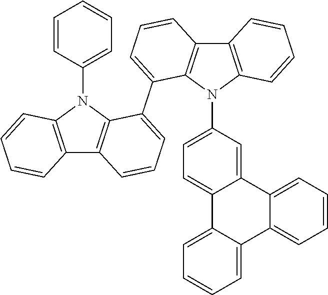 [SMILES: c1ccc(-n2c3ccccc3c3cccc(-c4cccc5c6ccccc6n(-c6ccc7c8ccccc8c8ccccc8c7c6)c45)c32)cc1]

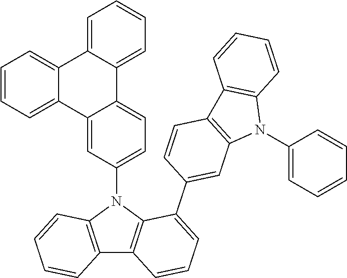 [SMILES: c1ccc(-n2c3ccccc3c3ccc(-c4cccc5c6ccccc6n(-c6ccc7c8ccccc8c8ccccc8c7c6)c45)cc32)cc1]

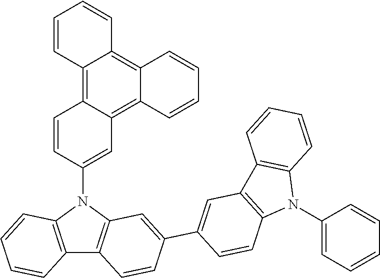 [SMILES: c1ccc(-n2c3ccccc3c3cc(-c4ccc5c6ccccc6n(-c6ccc7c8ccccc8c8ccccc8c7c6)c5c4)ccc32)cc1]

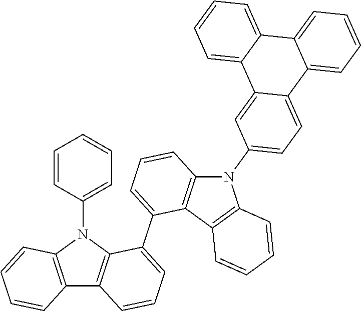 [SMILES: c1ccc(-n2c3ccccc3c3cccc(-c4cccc5c4c4ccccc4n5-c4ccc5c6ccccc6c6ccccc6c5c4)c32)cc1]

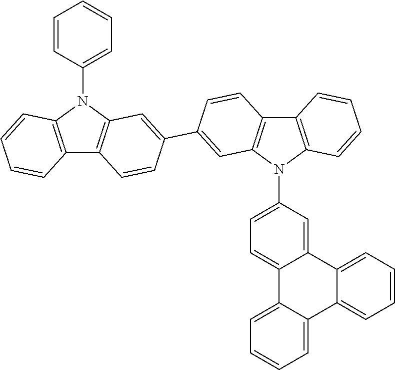 [SMILES: c1ccc(-n2c3ccccc3c3ccc(-c4ccc5c6ccccc6n(-c6ccc7c8ccccc8c8ccccc8c7c6)c5c4)cc32)cc1]

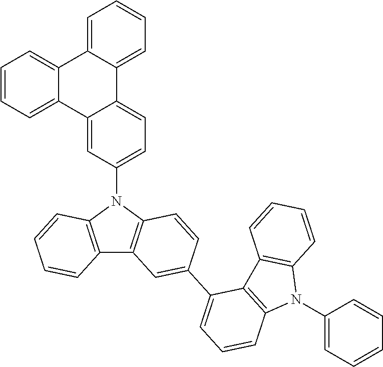 [SMILES: c1ccc(-n2c3ccccc3c3c(-c4ccc5c(c4)c4ccccc4n5-c4ccc5c6ccccc6c6ccccc6c5c4)cccc32)cc1]

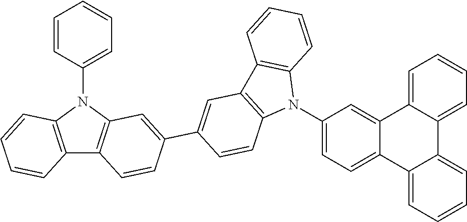 [SMILES: c1ccc(-n2c3ccccc3c3ccc(-c4ccc5c(c4)c4ccccc4n5-c4ccc5c6ccccc6c6ccccc6c5c4)cc32)cc1]

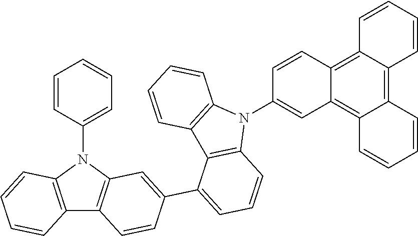 [SMILES: c1ccc(-n2c3ccccc3c3ccc(-c4cccc5c4c4ccccc4n5-c4ccc5c6ccccc6c6ccccc6c5c4)cc32)cc1]

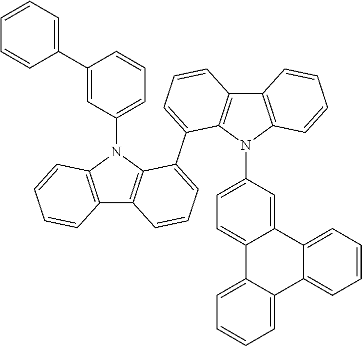 [SMILES: c1ccc(-c2cccc(-n3c4ccccc4c4cccc(-c5cccc6c7ccccc7n(-c7ccc8c9ccccc9c9ccccc9c8c7)c56)c43)c2)cc1]

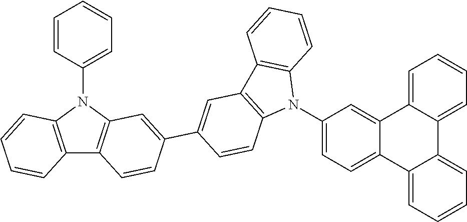 [SMILES: c1ccc(-n2c3ccccc3c3ccc(-c4ccc5c(c4)c4ccccc4n5-c4ccc5c6ccccc6c6ccccc6c5c4)cc32)cc1]

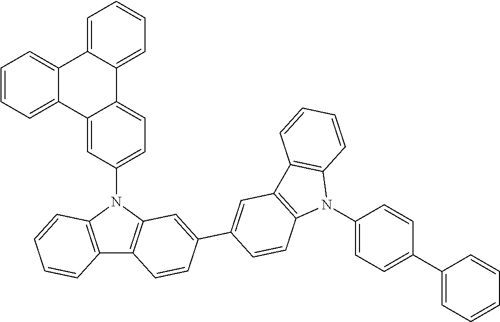 [SMILES: c1ccc(-c2ccc(-n3c4ccccc4c4cc(-c5ccc6c7ccccc7n(-c7ccc8c9ccccc9c9ccccc9c8c7)c6c5)ccc43)cc2)cc1]

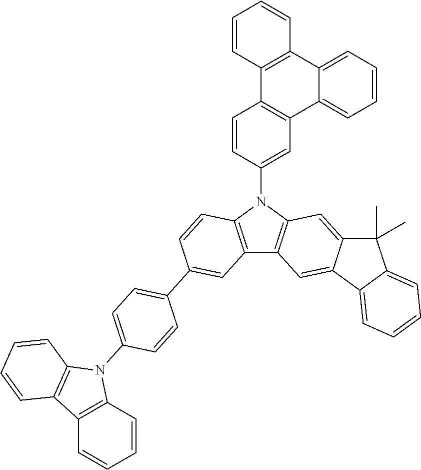 [SMILES: CC1(C)c2ccccc2-c2cc3c4cc(-c5ccc(-n6c7ccccc7c7ccccc76)cc5)ccc4n(-c4ccc5c6ccccc6c6ccccc6c5c4)c3cc21]

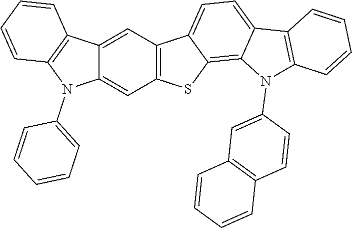 [SMILES: c1ccc(-n2c3ccccc3c3cc4c(cc32)sc2c4ccc3c4ccccc4n(-c4ccc5ccccc5c4)c32)cc1]

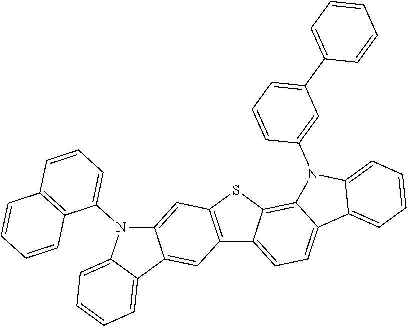 [SMILES: c1ccc(-c2cccc(-n3c4ccccc4c4ccc5c6cc7c8ccccc8n(-c8cccc9ccccc89)c7cc6sc5c43)c2)cc1]

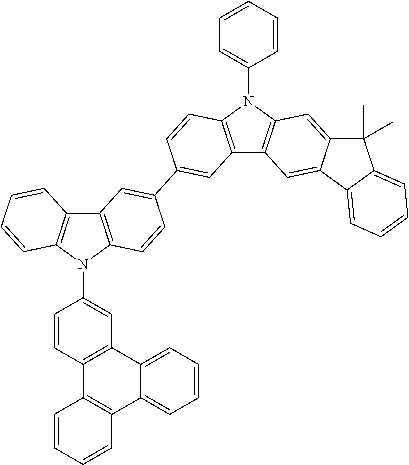 [SMILES: CC1(C)c2ccccc2-c2cc3c4cc(-c5ccc6c(c5)c5ccccc5n6-c5ccc6c7ccccc7c7ccccc7c6c5)ccc4n(-c4ccccc4)c3cc21]

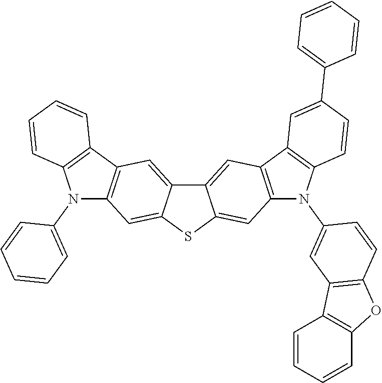 [SMILES: c1ccc(-c2ccc3c(c2)c2cc4c(cc2n3-c2ccc3oc5ccccc5c3c2)sc2cc3c(cc24)c2ccccc2n3-c2ccccc2)cc1]

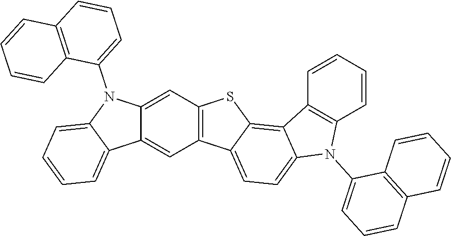 [SMILES: c1ccc2c(-n3c4ccccc4c4cc5c(cc43)sc3c5ccc4c3c3ccccc3n4-c3cccc4ccccc34)cccc2c1]

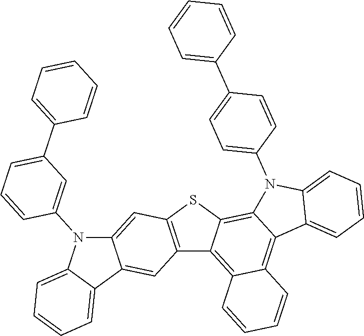 [SMILES: c1ccc(-c2ccc(-n3c4ccccc4c4c5ccccc5c5c6cc7c8ccccc8n(-c8cccc(-c9ccccc9)c8)c7cc6sc5c43)cc2)cc1]

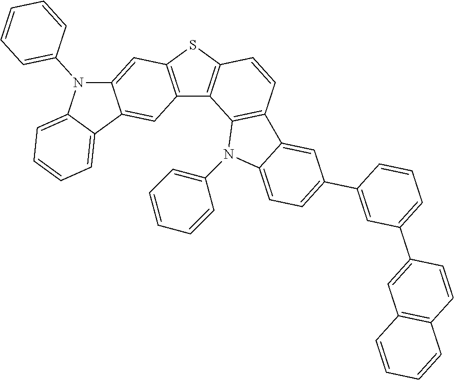 [SMILES: c1ccc(-n2c3ccccc3c3cc4c(cc32)sc2ccc3c5cc(-c6cccc(-c7ccc8ccccc8c7)c6)ccc5n(-c5ccccc5)c3c24)cc1]

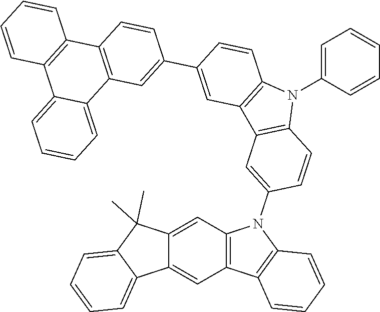 [SMILES: CC1(C)c2ccccc2-c2cc3c4ccccc4n(-c4ccc5c(c4)c4cc(-c6ccc7c8ccccc8c8ccccc8c7c6)ccc4n5-c4ccccc4)c3cc21]

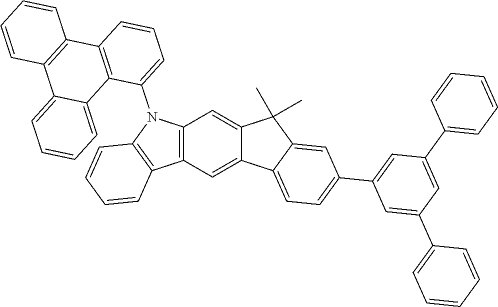 [SMILES: CC1(C)c2cc(-c3cc(-c4ccccc4)cc(-c4ccccc4)c3)ccc2-c2cc3c4ccccc4n(-c4cccc5c6ccccc6c6ccccc6c45)c3cc21]

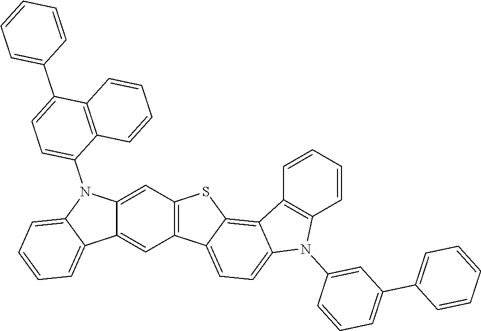 [SMILES: c1ccc(-c2cccc(-n3c4ccccc4c4c5sc6cc7c(cc6c5ccc43)c3ccccc3n7-c3ccc(-c4ccccc4)c4ccccc34)c2)cc1]

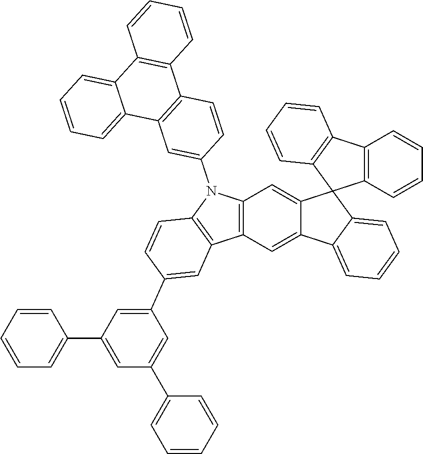 [SMILES: c1ccc(-c2cc(-c3ccccc3)cc(-c3ccc4c(c3)c3cc5c(cc3n4-c3ccc4c6ccccc6c6ccccc6c4c3)C3(c4ccccc4-c4ccccc43)c3ccccc3-5)c2)cc1]

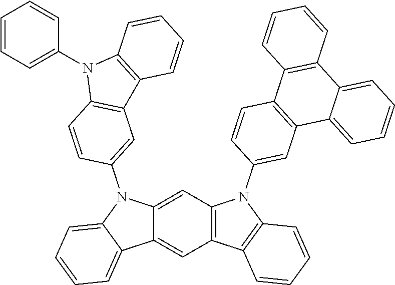 [SMILES: c1ccc(-n2c3ccccc3c3cc(-n4c5ccccc5c5cc6c7ccccc7n(-c7ccc8c9ccccc9c9ccccc9c8c7)c6cc54)ccc32)cc1]

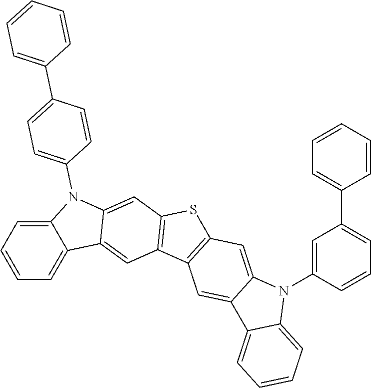 [SMILES: c1ccc(-c2ccc(-n3c4ccccc4c4cc5c(cc43)sc3cc4c(cc35)c3ccccc3n4-c3cccc(-c4ccccc4)c3)cc2)cc1]

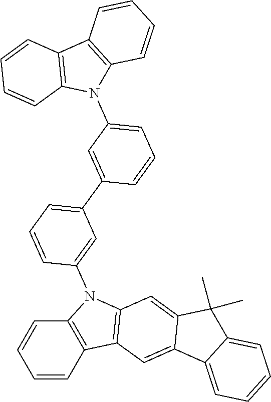 [SMILES: CC1(C)c2ccccc2-c2cc3c4ccccc4n(-c4cccc(-c5cccc(-n6c7ccccc7c7ccccc76)c5)c4)c3cc21]

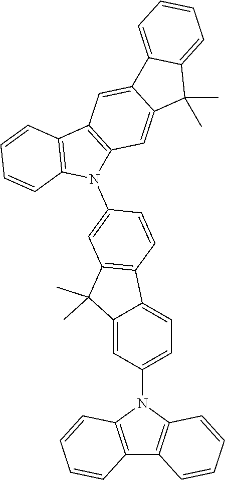 [SMILES: CC1(C)c2cc(-n3c4ccccc4c4ccccc43)ccc2-c2ccc(-n3c4ccccc4c4cc5c(cc43)C(C)(C)c3ccccc3-5)cc21]

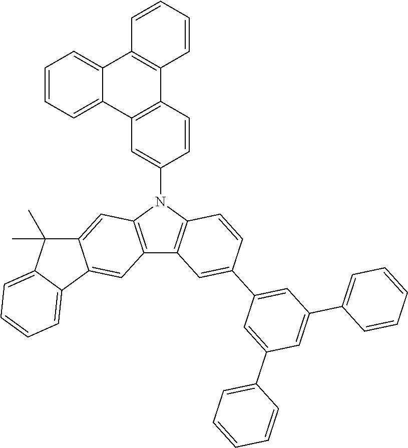 [SMILES: CC1(C)c2ccccc2-c2cc3c4cc(-c5cc(-c6ccccc6)cc(-c6ccccc6)c5)ccc4n(-c4ccc5c6ccccc6c6ccccc6c5c4)c3cc21]

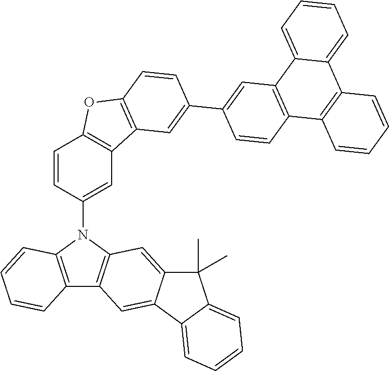 [SMILES: CC1(C)c2ccccc2-c2cc3c4ccccc4n(-c4ccc5oc6ccc(-c7ccc8c9ccccc9c9ccccc9c8c7)cc6c5c4)c3cc21]

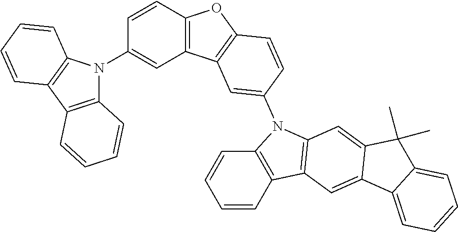 [SMILES: CC1(C)c2ccccc2-c2cc3c4ccccc4n(-c4ccc5oc6ccc(-n7c8ccccc8c8ccccc87)cc6c5c4)c3cc21]

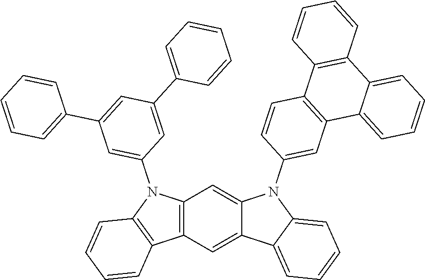 [SMILES: c1ccc(-c2cc(-c3ccccc3)cc(-n3c4ccccc4c4cc5c6ccccc6n(-c6ccc7c8ccccc8c8ccccc8c7c6)c5cc43)c2)cc1]

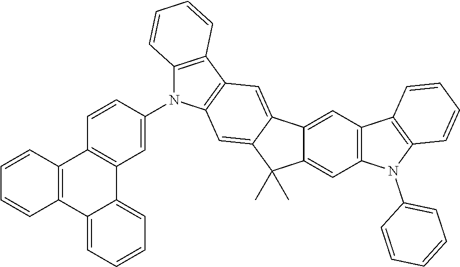 [SMILES: CC1(C)c2cc3c(cc2-c2cc4c5ccccc5n(-c5ccc6c7ccccc7c7ccccc7c6c5)c4cc21)c1ccccc1n3-c1ccccc1]

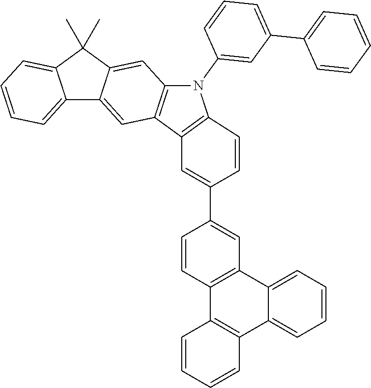 [SMILES: CC1(C)c2ccccc2-c2cc3c4cc(-c5ccc6c7ccccc7c7ccccc7c6c5)ccc4n(-c4cccc(-c5ccccc5)c4)c3cc21]

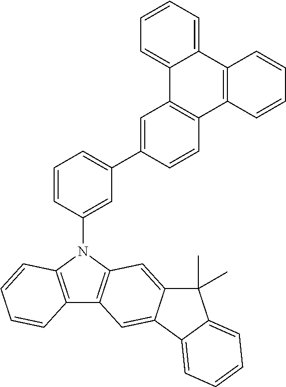 [SMILES: CC1(C)c2ccccc2-c2cc3c4ccccc4n(-c4cccc(-c5ccc6c7ccccc7c7ccccc7c6c5)c4)c3cc21]

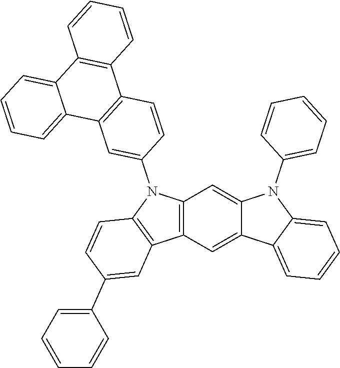 [SMILES: c1ccc(-c2ccc3c(c2)c2cc4c5ccccc5n(-c5ccccc5)c4cc2n3-c2ccc3c4ccccc4c4ccccc4c3c2)cc1]

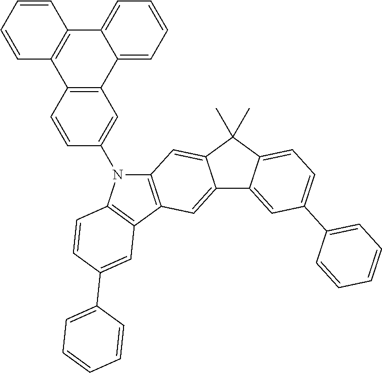 [SMILES: CC1(C)c2ccc(-c3ccccc3)cc2-c2cc3c4cc(-c5ccccc5)ccc4n(-c4ccc5c6ccccc6c6ccccc6c5c4)c3cc21]

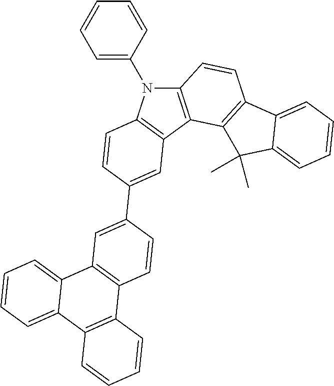 [SMILES: CC1(C)c2ccccc2-c2ccc3c(c21)c1cc(-c2ccc4c5ccccc5c5ccccc5c4c2)ccc1n3-c1ccccc1]

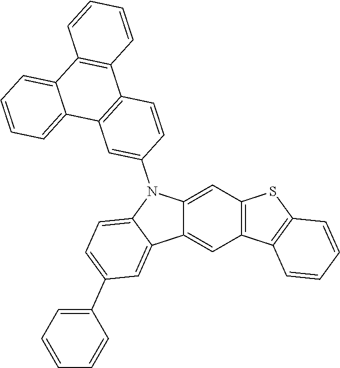 [SMILES: c1ccc(-c2ccc3c(c2)c2cc4c(cc2n3-c2ccc3c5ccccc5c5ccccc5c3c2)sc2ccccc24)cc1]

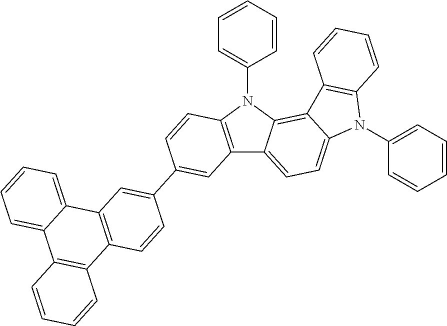 [SMILES: c1ccc(-n2c3ccccc3c3c2ccc2c4cc(-c5ccc6c7ccccc7c7ccccc7c6c5)ccc4n(-c4ccccc4)c23)cc1]

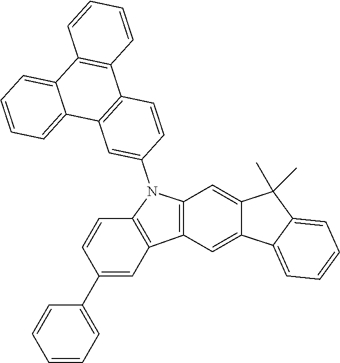 [SMILES: CC1(C)c2ccccc2-c2cc3c4cc(-c5ccccc5)ccc4n(-c4ccc5c6ccccc6c6ccccc6c5c4)c3cc21]

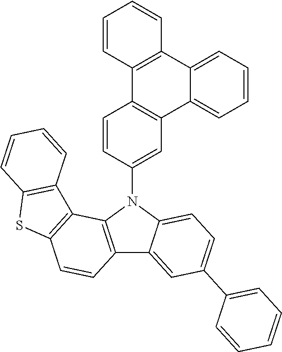 [SMILES: c1ccc(-c2ccc3c(c2)c2ccc4sc5ccccc5c4c2n3-c2ccc3c4ccccc4c4ccccc4c3c2)cc1]

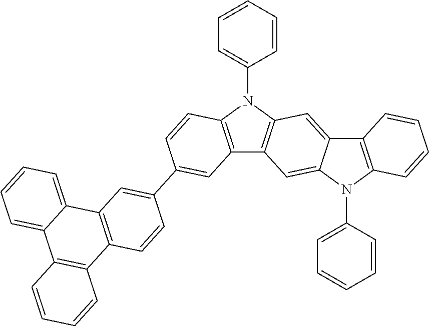 [SMILES: c1ccc(-n2c3ccccc3c3cc4c(cc32)c2cc(-c3ccc5c6ccccc6c6ccccc6c5c3)ccc2n4-c2ccccc2)cc1]

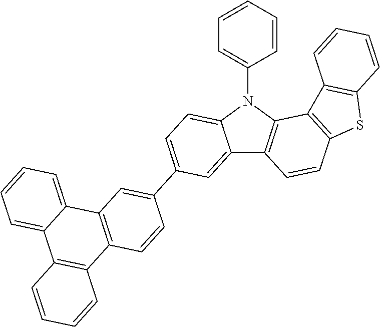 [SMILES: c1ccc(-n2c3ccc(-c4ccc5c6ccccc6c6ccccc6c5c4)cc3c3ccc4sc5ccccc5c4c32)cc1]

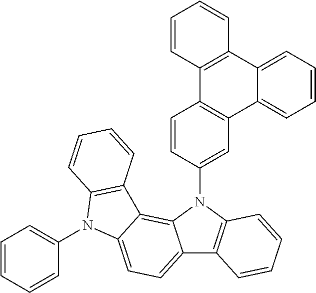 [SMILES: c1ccc(-n2c3ccccc3c3c2ccc2c4ccccc4n(-c4ccc5c6ccccc6c6ccccc6c5c4)c23)cc1]

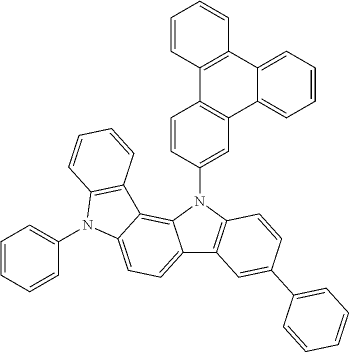 [SMILES: c1ccc(-c2ccc3c(c2)c2ccc4c(c5ccccc5n4-c4ccccc4)c2n3-c2ccc3c4ccccc4c4ccccc4c3c2)cc1]

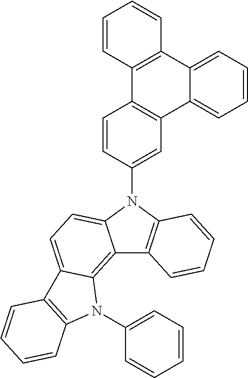 [SMILES: c1ccc(-n2c3ccccc3c3ccc4c(c5ccccc5n4-c4ccc5c6ccccc6c6ccccc6c5c4)c32)cc1]

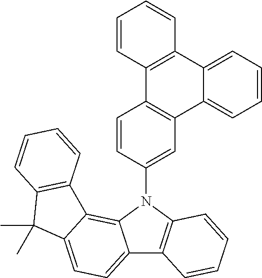 [SMILES: CC1(C)c2ccccc2-c2c1ccc1c3ccccc3n(-c3ccc4c5ccccc5c5ccccc5c4c3)c21]

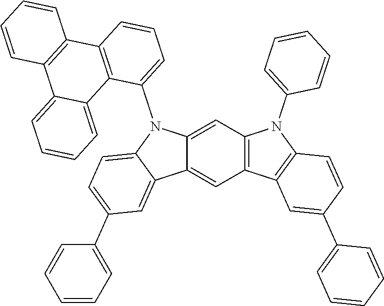 [SMILES: c1ccc(-c2ccc3c(c2)c2cc4c5cc(-c6ccccc6)ccc5n(-c5cccc6c7ccccc7c7ccccc7c56)c4cc2n3-c2ccccc2)cc1]

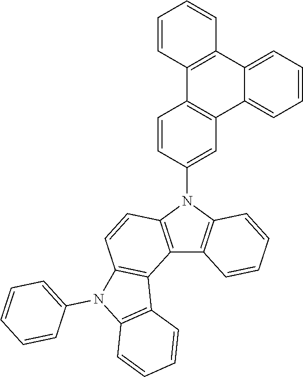 [SMILES: c1ccc(-n2c3ccccc3c3c4c5ccccc5n(-c5ccc6c7ccccc7c7ccccc7c6c5)c4ccc32)cc1]

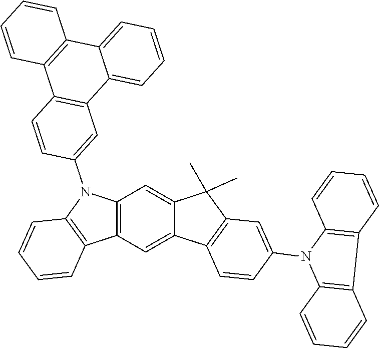 [SMILES: CC1(C)c2cc(-n3c4ccccc4c4ccccc43)ccc2-c2cc3c4ccccc4n(-c4ccc5c6ccccc6c6ccccc6c5c4)c3cc21]

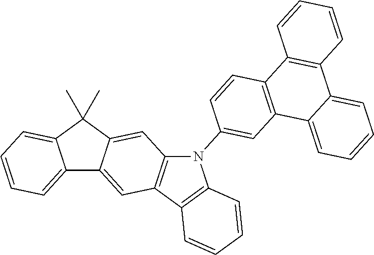 [SMILES: CC1(C)c2ccccc2-c2cc3c4ccccc4n(-c4ccc5c6ccccc6c6ccccc6c5c4)c3cc21]

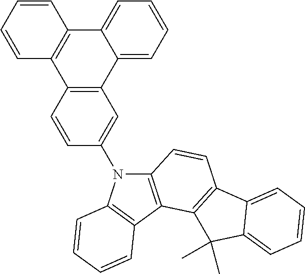 [SMILES: CC1(C)c2ccccc2-c2ccc3c(c21)c1ccccc1n3-c1ccc2c3ccccc3c3ccccc3c2c1]

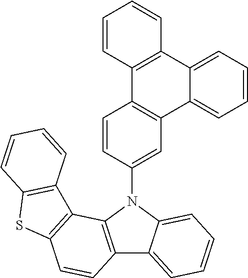 [SMILES: c1ccc2c(c1)sc1ccc3c4ccccc4n(-c4ccc5c6ccccc6c6ccccc6c5c4)c3c12]

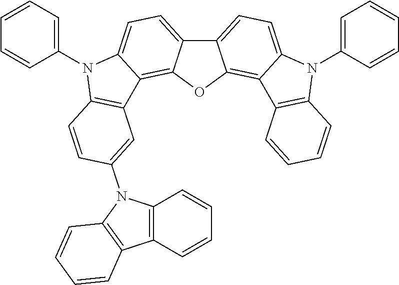 [SMILES: c1ccc(-n2c3ccccc3c3c4oc5c(ccc6c5c5cc(-n7c8ccccc8c8ccccc87)ccc5n6-c5ccccc5)c4ccc32)cc1]

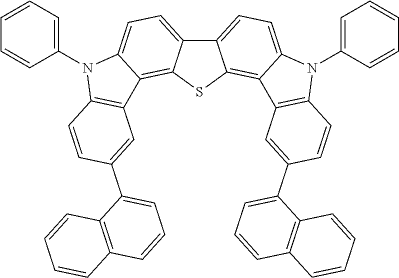 [SMILES: c1ccc(-n2c3ccc(-c4cccc5ccccc45)cc3c3c4sc5c(ccc6c5c5cc(-c7cccc8ccccc78)ccc5n6-c5ccccc5)c4ccc32)cc1]

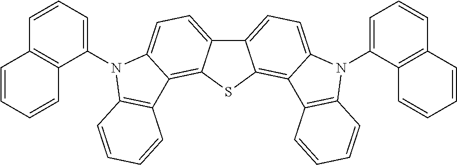 [SMILES: c1ccc2c(-n3c4ccccc4c4c5sc6c(ccc7c6c6ccccc6n7-c6cccc7ccccc67)c5ccc43)cccc2c1]

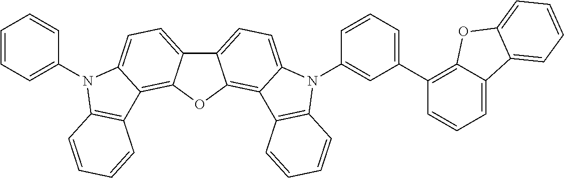 [SMILES: c1ccc(-n2c3ccccc3c3c4oc5c(ccc6c5c5ccccc5n6-c5cccc(-c6cccc7c6oc6ccccc67)c5)c4ccc32)cc1]

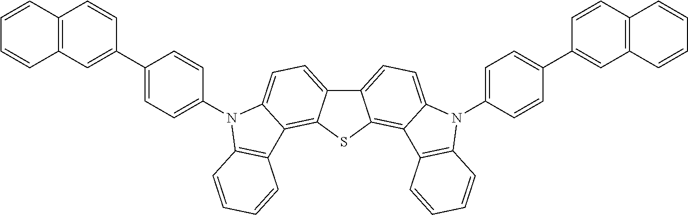 [SMILES: c1ccc2cc(-c3ccc(-n4c5ccccc5c5c6sc7c(ccc8c7c7ccccc7n8-c7ccc(-c8ccc9ccccc9c8)cc7)c6ccc54)cc3)ccc2c1]

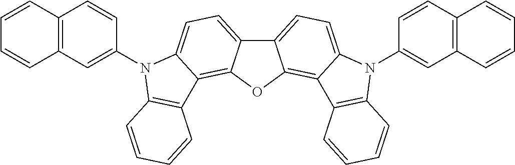 [SMILES: c1ccc2cc(-n3c4ccccc4c4c5oc6c(ccc7c6c6ccccc6n7-c6ccc7ccccc7c6)c5ccc43)ccc2c1]

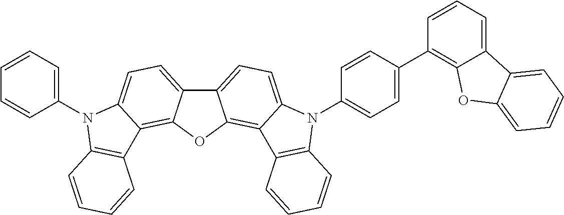 [SMILES: c1ccc(-n2c3ccccc3c3c4oc5c(ccc6c5c5ccccc5n6-c5ccc(-c6cccc7c6oc6ccccc67)cc5)c4ccc32)cc1]

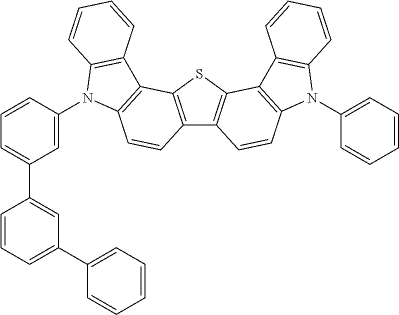 [SMILES: c1ccc(-c2cccc(-c3cccc(-n4c5ccccc5c5c6sc7c(ccc8c7c7ccccc7n8-c7ccccc7)c6ccc54)c3)c2)cc1]

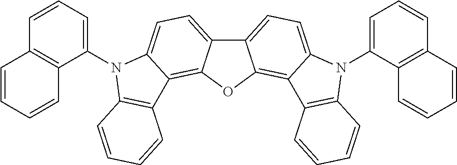 [SMILES: c1ccc2c(-n3c4ccccc4c4c5oc6c(ccc7c6c6ccccc6n7-c6cccc7ccccc67)c5ccc43)cccc2c1]

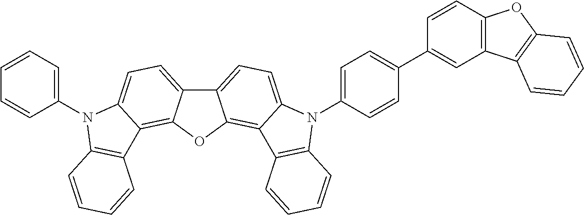 [SMILES: c1ccc(-n2c3ccccc3c3c4oc5c(ccc6c5c5ccccc5n6-c5ccc(-c6ccc7oc8ccccc8c7c6)cc5)c4ccc32)cc1]

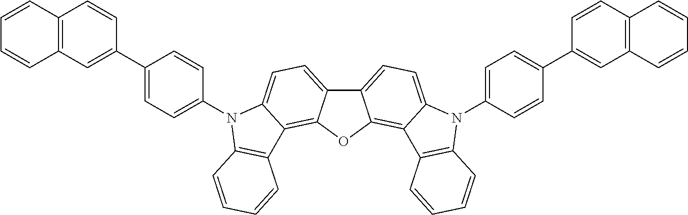 [SMILES: c1ccc2cc(-c3ccc(-n4c5ccccc5c5c6oc7c(ccc8c7c7ccccc7n8-c7ccc(-c8ccc9ccccc9c8)cc7)c6ccc54)cc3)ccc2c1]

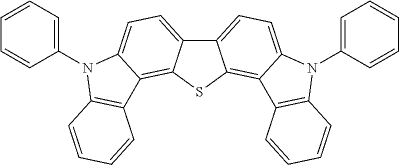 [SMILES: c1ccc(-n2c3ccccc3c3c4sc5c(ccc6c5c5ccccc5n6-c5ccccc5)c4ccc32)cc1]

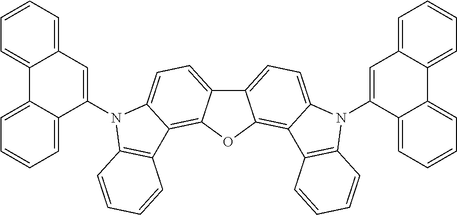 [SMILES: c1ccc2c(c1)cc(-n1c3ccccc3c3c4oc5c(ccc6c5c5ccccc5n6-c5cc6ccccc6c6ccccc56)c4ccc31)c1ccccc12]

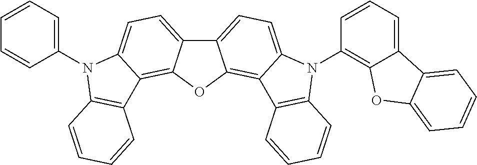 [SMILES: c1ccc(-n2c3ccccc3c3c4oc5c(ccc6c5c5ccccc5n6-c5cccc6c5oc5ccccc56)c4ccc32)cc1]

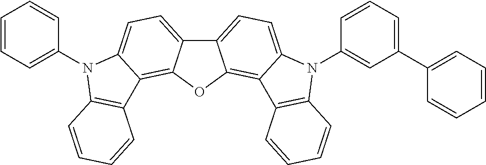 [SMILES: c1ccc(-c2cccc(-n3c4ccccc4c4c5oc6c(ccc7c6c6ccccc6n7-c6ccccc6)c5ccc43)c2)cc1]

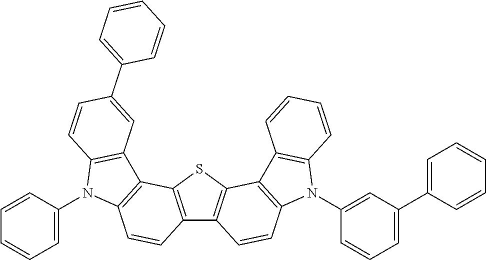 [SMILES: c1ccc(-c2cccc(-n3c4ccccc4c4c5sc6c(ccc7c6c6cc(-c8ccccc8)ccc6n7-c6ccccc6)c5ccc43)c2)cc1]

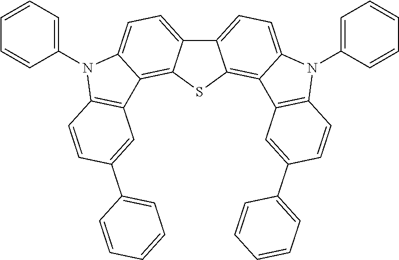 [SMILES: c1ccc(-c2ccc3c(c2)c2c4sc5c(ccc6c5c5cc(-c7ccccc7)ccc5n6-c5ccccc5)c4ccc2n3-c2ccccc2)cc1]

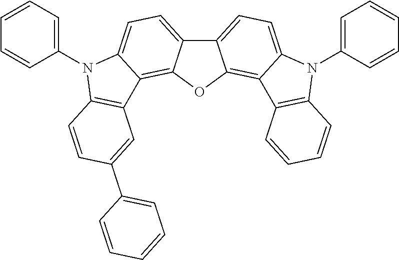 [SMILES: c1ccc(-c2ccc3c(c2)c2c4oc5c(ccc6c5c5ccccc5n6-c5ccccc5)c4ccc2n3-c2ccccc2)cc1]

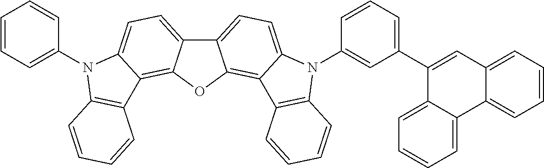 [SMILES: c1ccc(-n2c3ccccc3c3c4oc5c(ccc6c5c5ccccc5n6-c5cccc(-c6cc7ccccc7c7ccccc67)c5)c4ccc32)cc1]

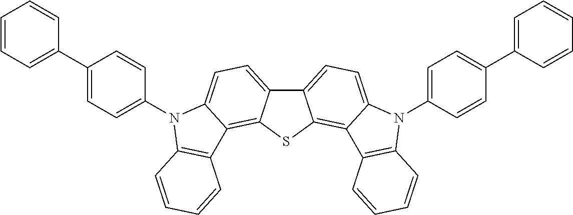 [SMILES: c1ccc(-c2ccc(-n3c4ccccc4c4c5sc6c(ccc7c6c6ccccc6n7-c6ccc(-c7ccccc7)cc6)c5ccc43)cc2)cc1]

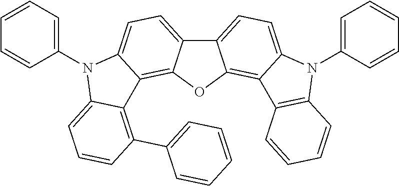 [SMILES: c1ccc(-c2cccc3c2c2c4oc5c(ccc6c5c5ccccc5n6-c5ccccc5)c4ccc2n3-c2ccccc2)cc1]

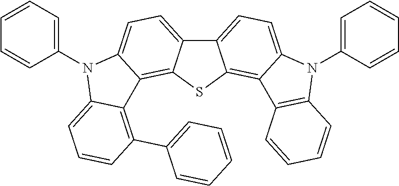 [SMILES: c1ccc(-c2cccc3c2c2c4sc5c(ccc6c5c5ccccc5n6-c5ccccc5)c4ccc2n3-c2ccccc2)cc1]

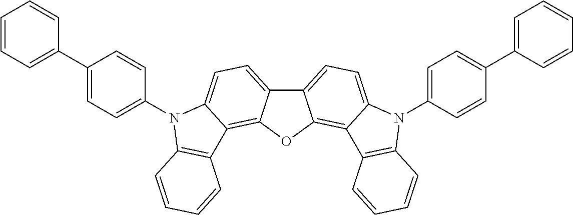 [SMILES: c1ccc(-c2ccc(-n3c4ccccc4c4c5oc6c(ccc7c6c6ccccc6n7-c6ccc(-c7ccccc7)cc6)c5ccc43)cc2)cc1]

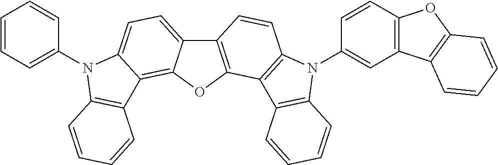 [SMILES: c1ccc(-n2c3ccccc3c3c4oc5c(ccc6c5c5ccccc5n6-c5ccc6oc7ccccc7c6c5)c4ccc32)cc1]

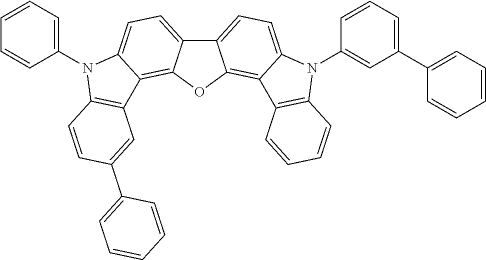 [SMILES: c1ccc(-c2cccc(-n3c4ccccc4c4c5oc6c(ccc7c6c6cc(-c8ccccc8)ccc6n7-c6ccccc6)c5ccc43)c2)cc1]

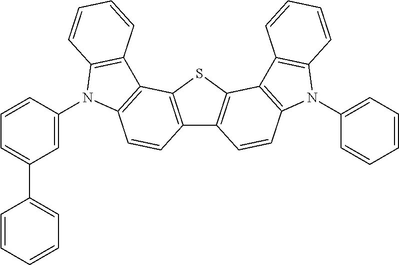 [SMILES: c1ccc(-c2cccc(-n3c4ccccc4c4c5sc6c(ccc7c6c6ccccc6n7-c6ccccc6)c5ccc43)c2)cc1]

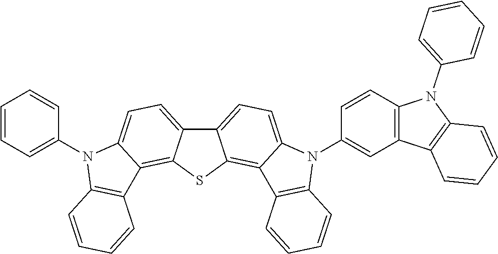 [SMILES: c1ccc(-n2c3ccccc3c3cc(-n4c5ccccc5c5c6sc7c(ccc8c7c7ccccc7n8-c7ccccc7)c6ccc54)ccc32)cc1]

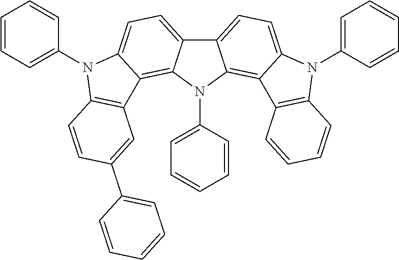 [SMILES: c1ccc(-c2ccc3c(c2)c2c(ccc4c5ccc6c(c7ccccc7n6-c6ccccc6)c5n(-c5ccccc5)c42)n3-c2ccccc2)cc1]

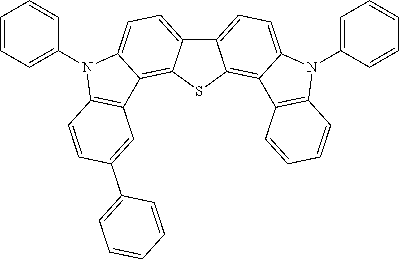 [SMILES: c1ccc(-c2ccc3c(c2)c2c4sc5c(ccc6c5c5ccccc5n6-c5ccccc5)c4ccc2n3-c2ccccc2)cc1]

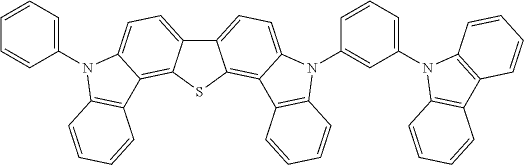 [SMILES: c1ccc(-n2c3ccccc3c3c4sc5c(ccc6c5c5ccccc5n6-c5cccc(-n6c7ccccc7c7ccccc76)c5)c4ccc32)cc1]

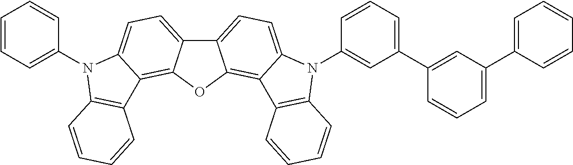 [SMILES: c1ccc(-c2cccc(-c3cccc(-n4c5ccccc5c5c6oc7c(ccc8c7c7ccccc7n8-c7ccccc7)c6ccc54)c3)c2)cc1]

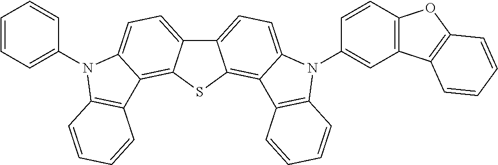 [SMILES: c1ccc(-n2c3ccccc3c3c4sc5c(ccc6c5c5ccccc5n6-c5ccc6oc7ccccc7c6c5)c4ccc32)cc1]

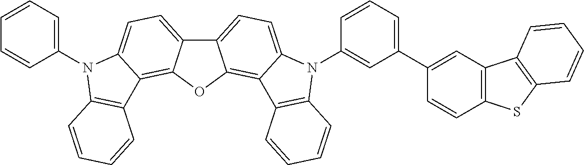 [SMILES: c1ccc(-n2c3ccccc3c3c4oc5c(ccc6c5c5ccccc5n6-c5cccc(-c6ccc7sc8ccccc8c7c6)c5)c4ccc32)cc1]

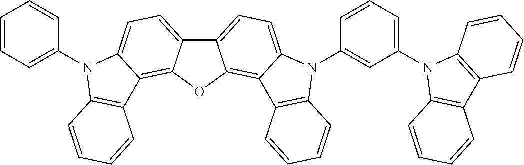 [SMILES: c1ccc(-n2c3ccccc3c3c4oc5c(ccc6c5c5ccccc5n6-c5cccc(-n6c7ccccc7c7ccccc76)c5)c4ccc32)cc1]

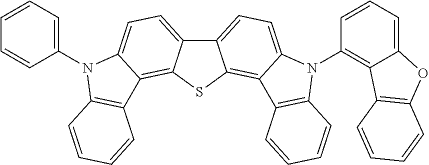 [SMILES: c1ccc(-n2c3ccccc3c3c4sc5c(ccc6c5c5ccccc5n6-c5cccc6oc7ccccc7c56)c4ccc32)cc1]

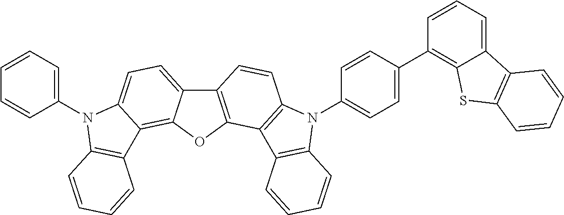 [SMILES: c1ccc(-n2c3ccccc3c3c4oc5c(ccc6c5c5ccccc5n6-c5ccc(-c6cccc7c6sc6ccccc67)cc5)c4ccc32)cc1]

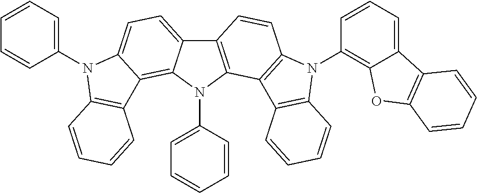 [SMILES: c1ccc(-n2c3ccccc3c3c2ccc2c4ccc5c(c6ccccc6n5-c5cccc6c5oc5ccccc56)c4n(-c4ccccc4)c23)cc1]

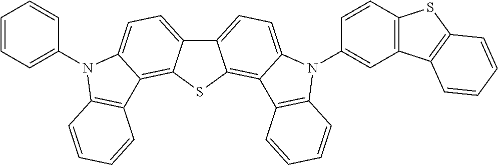 [SMILES: c1ccc(-n2c3ccccc3c3c4sc5c(ccc6c5c5ccccc5n6-c5ccc6sc7ccccc7c6c5)c4ccc32)cc1]

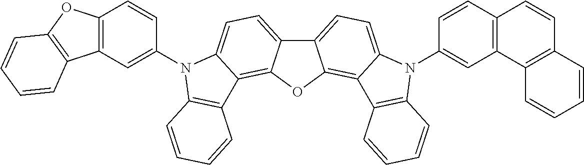 [SMILES: c1ccc2c(c1)ccc1ccc(-n3c4ccccc4c4c5oc6c(ccc7c6c6ccccc6n7-c6ccc7oc8ccccc8c7c6)c5ccc43)cc12]

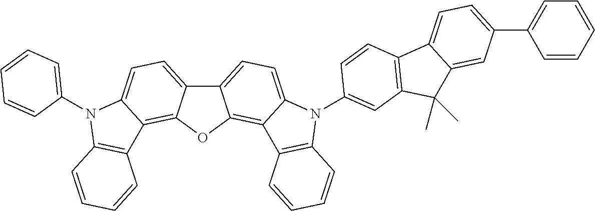 [SMILES: CC1(C)c2cc(-c3ccccc3)ccc2-c2ccc(-n3c4ccccc4c4c5oc6c(ccc7c6c6ccccc6n7-c6ccccc6)c5ccc43)cc21]

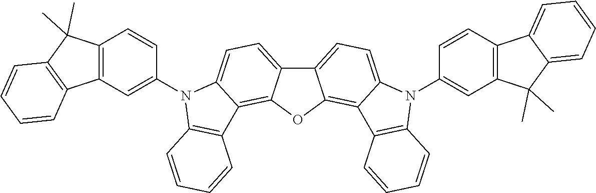 [SMILES: CC1(C)c2ccccc2-c2cc(-n3c4ccccc4c4c5oc6c(ccc7c6c6ccccc6n7-c6ccc7c(c6)C(C)(C)c6ccccc6-7)c5ccc43)ccc21]

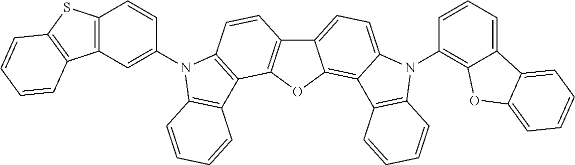 [SMILES: c1ccc2c(c1)oc1c(-n3c4ccccc4c4c5oc6c(ccc7c6c6ccccc6n7-c6ccc7sc8ccccc8c7c6)c5ccc43)cccc12]

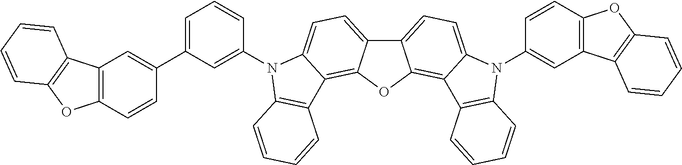 [SMILES: c1cc(-c2ccc3oc4ccccc4c3c2)cc(-n2c3ccccc3c3c4oc5c(ccc6c5c5ccccc5n6-c5ccc6oc7ccccc7c6c5)c4ccc32)c1]

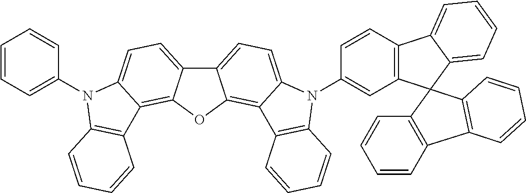 [SMILES: c1ccc(-n2c3ccccc3c3c4oc5c(ccc6c5c5ccccc5n6-c5ccc6c(c5)C5(c7ccccc7-c7ccccc75)c5ccccc5-6)c4ccc32)cc1]

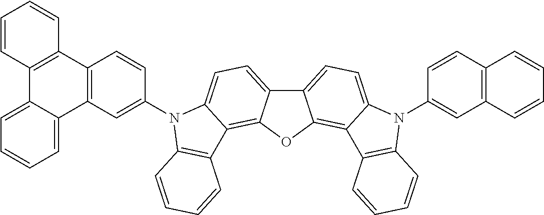 [SMILES: c1ccc2cc(-n3c4ccccc4c4c5oc6c(ccc7c6c6ccccc6n7-c6ccc7c8ccccc8c8ccccc8c7c6)c5ccc43)ccc2c1]

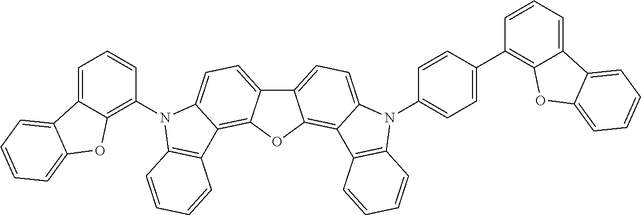 [SMILES: c1ccc2c(c1)oc1c(-c3ccc(-n4c5ccccc5c5c6oc7c(ccc8c7c7ccccc7n8-c7cccc8c7oc7ccccc78)c6ccc54)cc3)cccc12]

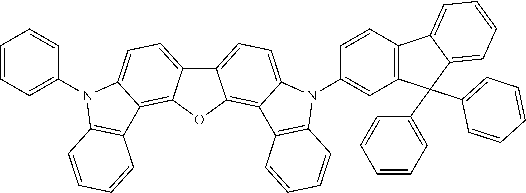 [SMILES: c1ccc(-n2c3ccccc3c3c4oc5c(ccc6c5c5ccccc5n6-c5ccc6c(c5)C(c5ccccc5)(c5ccccc5)c5ccccc5-6)c4ccc32)cc1]

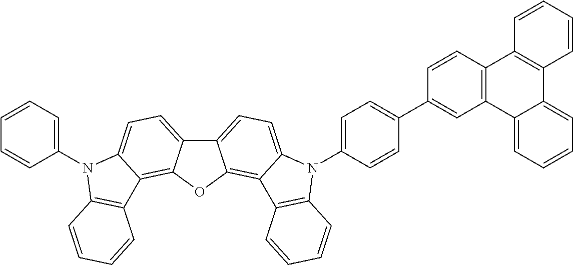 [SMILES: c1ccc(-n2c3ccccc3c3c4oc5c(ccc6c5c5ccccc5n6-c5ccc(-c6ccc7c8ccccc8c8ccccc8c7c6)cc5)c4ccc32)cc1]

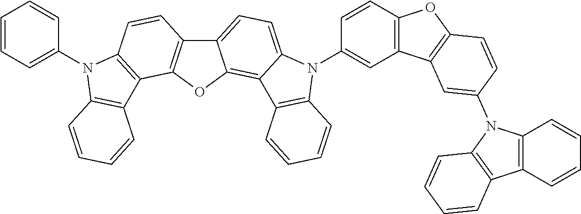 [SMILES: c1ccc(-n2c3ccccc3c3c4oc5c(ccc6c5c5ccccc5n6-c5ccc6oc7ccc(-n8c9ccccc9c9ccccc98)cc7c6c5)c4ccc32)cc1]

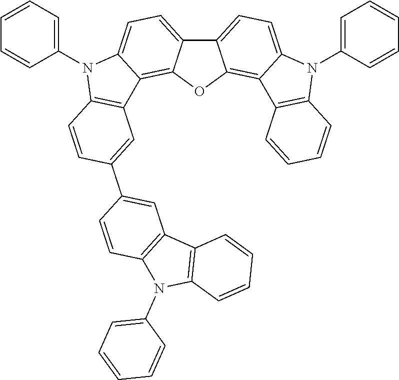 [SMILES: c1ccc(-n2c3ccccc3c3cc(-c4ccc5c(c4)c4c6oc7c(ccc8c7c7ccccc7n8-c7ccccc7)c6ccc4n5-c4ccccc4)ccc32)cc1]

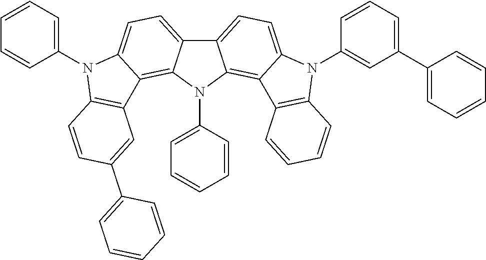 [SMILES: c1ccc(-c2cccc(-n3c4ccccc4c4c3ccc3c5ccc6c(c7cc(-c8ccccc8)ccc7n6-c6ccccc6)c5n(-c5ccccc5)c34)c2)cc1]

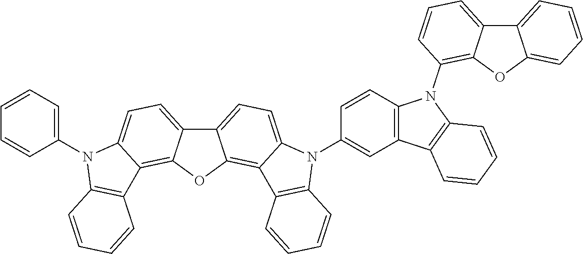 [SMILES: c1ccc(-n2c3ccccc3c3c4oc5c(ccc6c5c5ccccc5n6-c5ccc6c(c5)c5ccccc5n6-c5cccc6c5oc5ccccc56)c4ccc32)cc1]

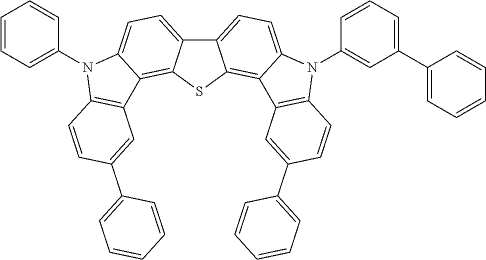 [SMILES: c1ccc(-c2cccc(-n3c4ccc(-c5ccccc5)cc4c4c5sc6c(ccc7c6c6cc(-c8ccccc8)ccc6n7-c6ccccc6)c5ccc43)c2)cc1]

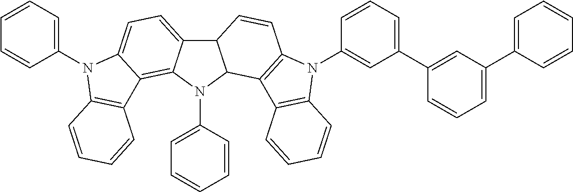 [SMILES: C1=CC2c3ccc4c(c3N(c3ccccc3)C2c2c1n(-c1cccc(-c3cccc(-c5ccccc5)c3)c1)c1ccccc21)c1ccccc1n4-c1ccccc1]

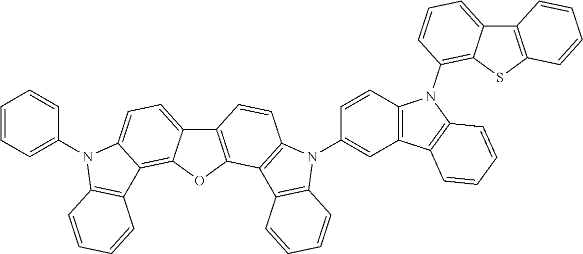 [SMILES: c1ccc(-n2c3ccccc3c3c4oc5c(ccc6c5c5ccccc5n6-c5ccc6c(c5)c5ccccc5n6-c5cccc6c5sc5ccccc56)c4ccc32)cc1]

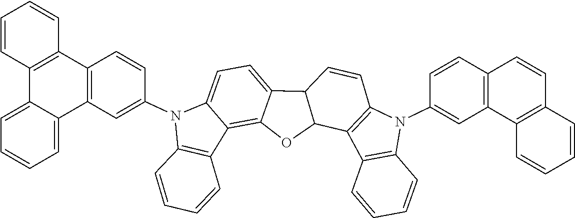 [SMILES: C1=CC2c3ccc4c(c3OC2c2c1n(-c1ccc3ccc5ccccc5c3c1)c1ccccc21)c1ccccc1n4-c1ccc2c3ccccc3c3ccccc3c2c1]

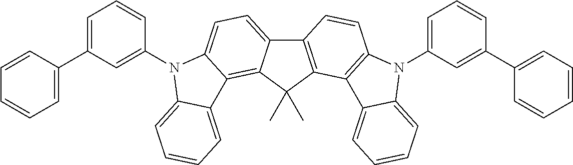 [SMILES: CC1(C)c2c(ccc3c2c2ccccc2n3-c2cccc(-c3ccccc3)c2)-c2ccc3c(c21)c1ccccc1n3-c1cccc(-c2ccccc2)c1]

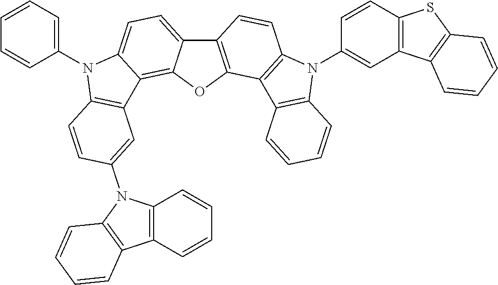 [SMILES: c1ccc(-n2c3ccc(-n4c5ccccc5c5ccccc54)cc3c3c4oc5c(ccc6c5c5ccccc5n6-c5ccc6sc7ccccc7c6c5)c4ccc32)cc1]

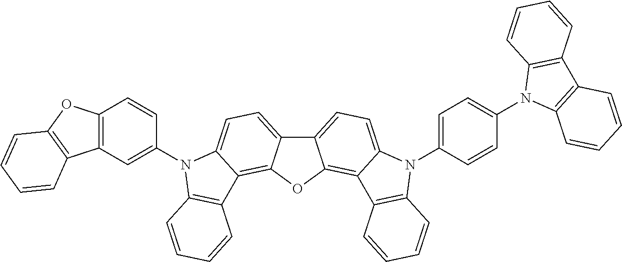 [SMILES: c1ccc2c(c1)oc1ccc(-n3c4ccccc4c4c5oc6c(ccc7c6c6ccccc6n7-c6ccc(-n7c8ccccc8c8ccccc87)cc6)c5ccc43)cc12]

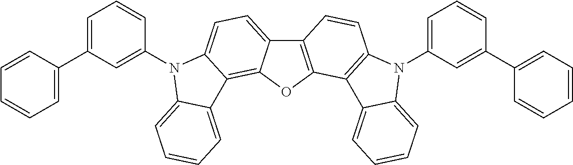 [SMILES: c1ccc(-c2cccc(-n3c4ccccc4c4c5oc6c(ccc7c6c6ccccc6n7-c6cccc(-c7ccccc7)c6)c5ccc43)c2)cc1]

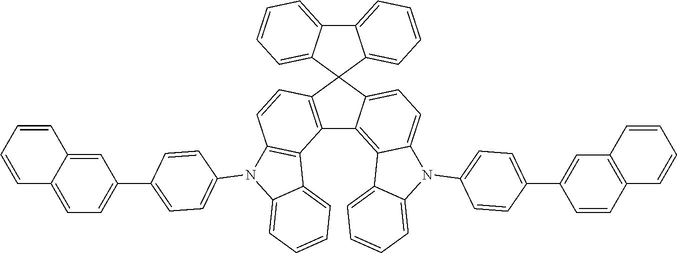 [SMILES: c1ccc2c(c1)-c1ccccc1C21c2ccc3c(c2-c2c1ccc1c2c2ccccc2n1-c1ccc(-c2ccc4ccccc4c2)cc1)c1ccccc1n3-c1ccc(-c2ccc3ccccc3c2)cc1]

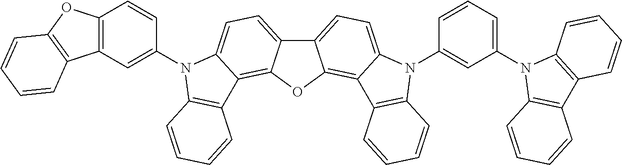 [SMILES: c1cc(-n2c3ccccc3c3ccccc32)cc(-n2c3ccccc3c3c4oc5c(ccc6c5c5ccccc5n6-c5ccc6oc7ccccc7c6c5)c4ccc32)c1]

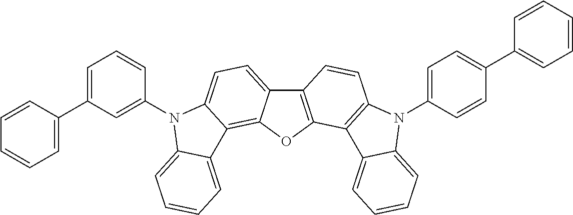 [SMILES: c1ccc(-c2ccc(-n3c4ccccc4c4c5oc6c(ccc7c6c6ccccc6n7-c6cccc(-c7ccccc7)c6)c5ccc43)cc2)cc1]

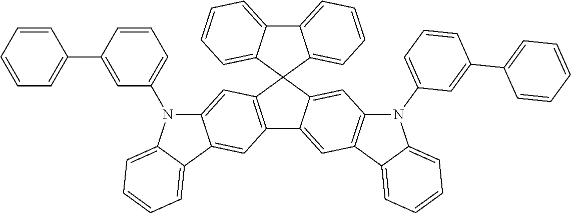 [SMILES: c1ccc(-c2cccc(-n3c4ccccc4c4cc5c(cc43)C3(c4ccccc4-c4ccccc43)c3cc4c(cc3-5)c3ccccc3n4-c3cccc(-c4ccccc4)c3)c2)cc1]

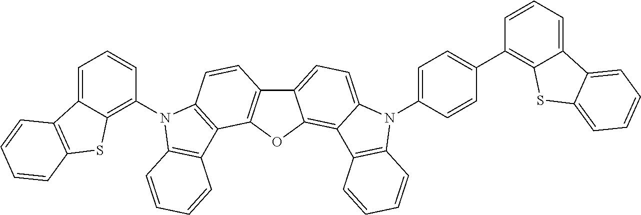 [SMILES: c1ccc2c(c1)sc1c(-c3ccc(-n4c5ccccc5c5c6oc7c(ccc8c7c7ccccc7n8-c7cccc8c7sc7ccccc78)c6ccc54)cc3)cccc12]

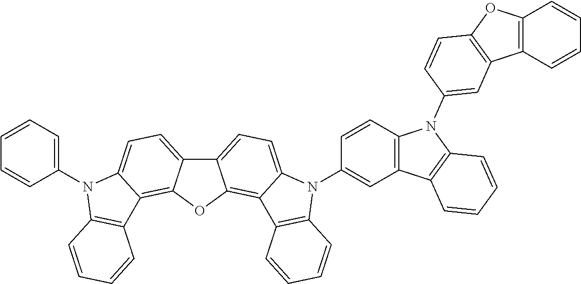 [SMILES: c1ccc(-n2c3ccccc3c3c4oc5c(ccc6c5c5ccccc5n6-c5ccc6c(c5)c5ccccc5n6-c5ccc6oc7ccccc7c6c5)c4ccc32)cc1]

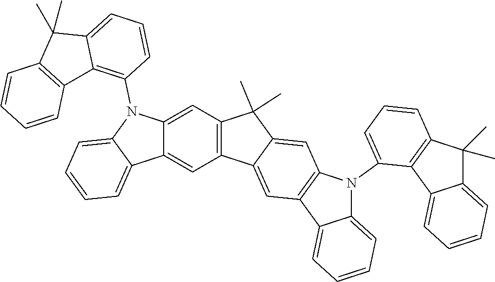 [SMILES: CC1(C)c2cc3c(cc2-c2cc4c5ccccc5n(-c5cccc6c5-c5ccccc5C6(C)C)c4cc21)c1ccccc1n3-c1cccc2c1-c1ccccc1C2(C)C]

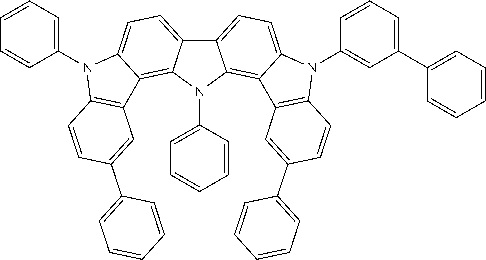 [SMILES: c1ccc(-c2cccc(-n3c4ccc(-c5ccccc5)cc4c4c3ccc3c5ccc6c(c7cc(-c8ccccc8)ccc7n6-c6ccccc6)c5n(-c5ccccc5)c34)c2)cc1]

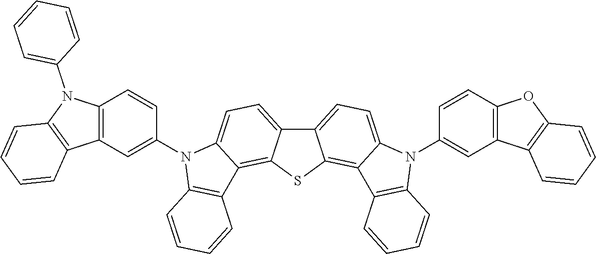 [SMILES: c1ccc(-n2c3ccccc3c3cc(-n4c5ccccc5c5c6sc7c(ccc8c7c7ccccc7n8-c7ccc8oc9ccccc9c8c7)c6ccc54)ccc32)cc1]

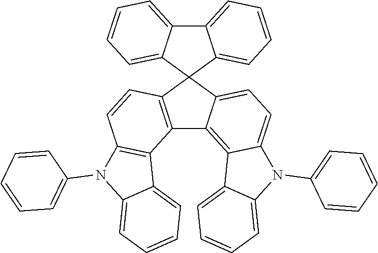 [SMILES: c1ccc(-n2c3ccccc3c3c4c(ccc32)C2(c3ccccc3-c3ccccc32)c2ccc3c(c2-4)c2ccccc2n3-c2ccccc2)cc1]

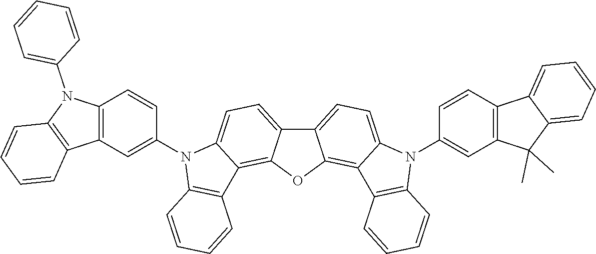 [SMILES: CC1(C)c2ccccc2-c2ccc(-n3c4ccccc4c4c5oc6c(ccc7c6c6ccccc6n7-c6ccc7c(c6)c6ccccc6n7-c6ccccc6)c5ccc43)cc21]

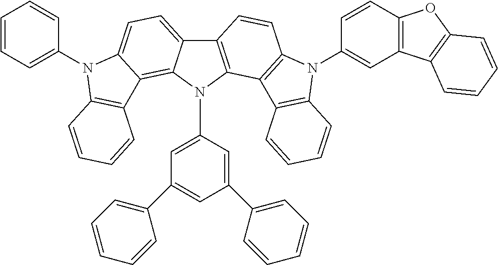 [SMILES: c1ccc(-c2cc(-c3ccccc3)cc(-n3c4c(ccc5c4c4ccccc4n5-c4ccccc4)c4ccc5c(c6ccccc6n5-c5ccc6oc7ccccc7c6c5)c43)c2)cc1]

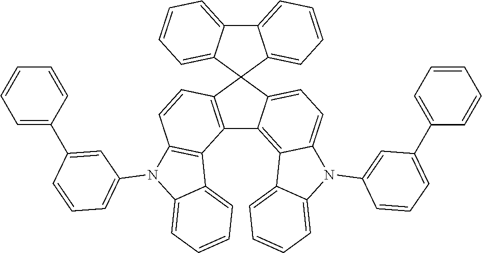 [SMILES: c1ccc(-c2cccc(-n3c4ccccc4c4c5c(ccc43)C3(c4ccccc4-c4ccccc43)c3ccc4c(c3-5)c3ccccc3n4-c3cccc(-c4ccccc4)c3)c2)cc1]

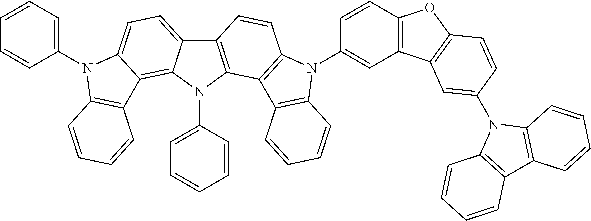 [SMILES: c1ccc(-n2c3ccccc3c3c2ccc2c4ccc5c(c6ccccc6n5-c5ccc6oc7ccc(-n8c9ccccc9c9ccccc98)cc7c6c5)c4n(-c4ccccc4)c23)cc1]

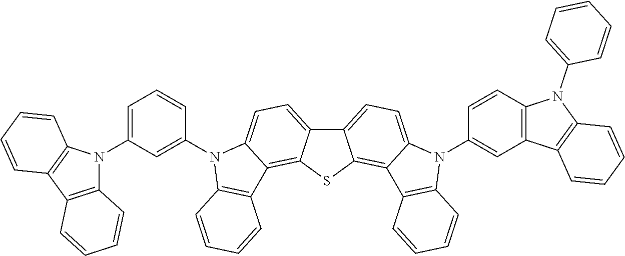 [SMILES: c1ccc(-n2c3ccccc3c3cc(-n4c5ccccc5c5c6sc7c(ccc8c7c7ccccc7n8-c7cccc(-n8c9ccccc9c9ccccc98)c7)c6ccc54)ccc32)cc1]

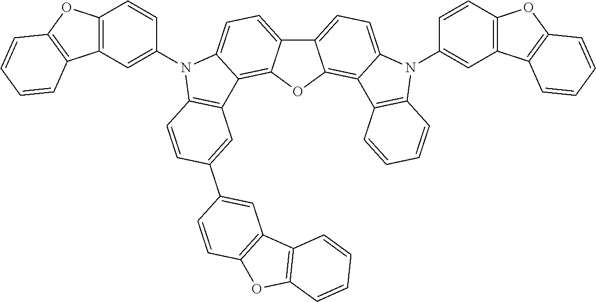 [SMILES: c1ccc2c(c1)oc1ccc(-c3ccc4c(c3)c3c5oc6c(ccc7c6c6ccccc6n7-c6ccc7oc8ccccc8c7c6)c5ccc3n4-c3ccc4oc5ccccc5c4c3)cc12]

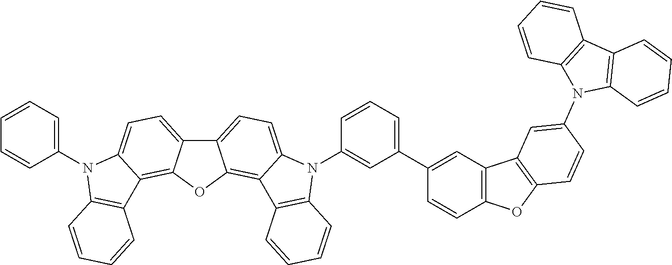 [SMILES: c1ccc(-n2c3ccccc3c3c4oc5c(ccc6c5c5ccccc5n6-c5cccc(-c6ccc7oc8ccc(-n9c%10ccccc%10c%10ccccc%109)cc8c7c6)c5)c4ccc32)cc1]

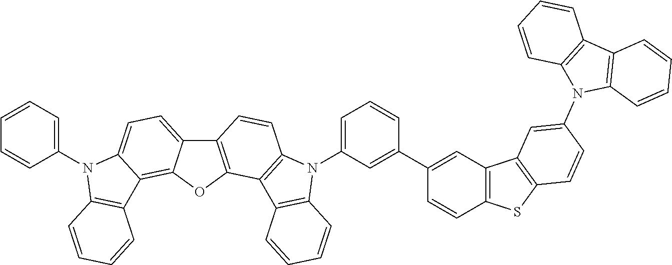 [SMILES: c1ccc(-n2c3ccccc3c3c4oc5c(ccc6c5c5ccccc5n6-c5cccc(-c6ccc7sc8ccc(-n9c%10ccccc%10c%10ccccc%109)cc8c7c6)c5)c4ccc32)cc1]

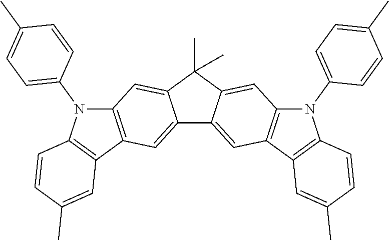

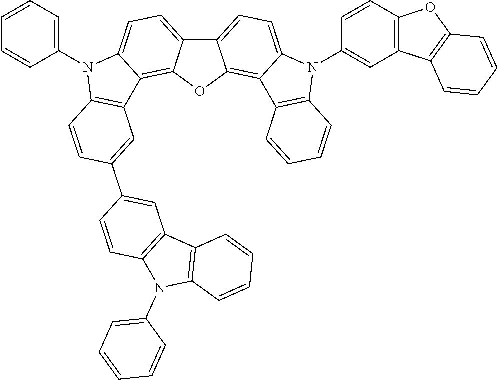 [SMILES: c1ccc(-n2c3ccccc3c3cc(-c4ccc5c(c4)c4c6oc7c(ccc8c7c7ccccc7n8-c7ccc8oc9ccccc9c8c7)c6ccc4n5-c4ccccc4)ccc32)cc1]

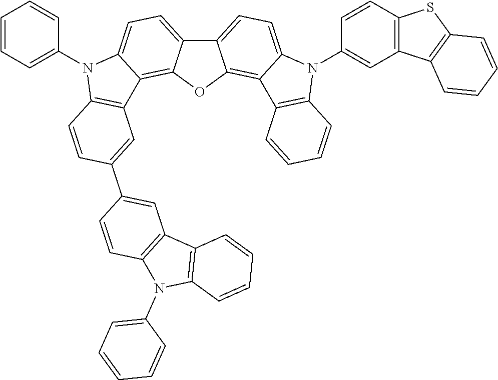 [SMILES: c1ccc(-n2c3ccccc3c3cc(-c4ccc5c(c4)c4c6oc7c(ccc8c7c7ccccc7n8-c7ccc8sc9ccccc9c8c7)c6ccc4n5-c4ccccc4)ccc32)cc1]

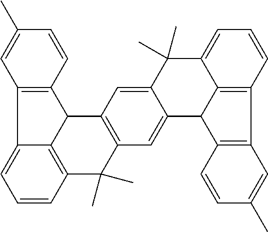 [SMILES: Cc1ccc2c(c1)-c1cccc3c1C2c1cc2c(cc1C3(C)C)C1c3ccc(C)cc3-c3cccc(c31)C2(C)C]

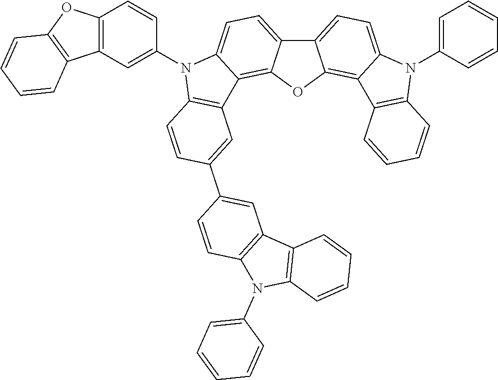 [SMILES: c1ccc(-n2c3ccccc3c3cc(-c4ccc5c(c4)c4c6oc7c(ccc8c7c7ccccc7n8-c7ccccc7)c6ccc4n5-c4ccc5oc6ccccc6c5c4)ccc32)cc1]

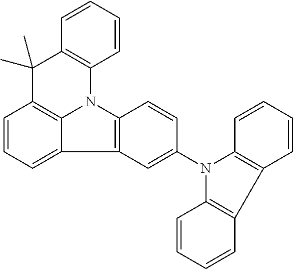 [SMILES: CC1(C)c2ccccc2-n2c3ccc(-n4c5ccccc5c5ccccc54)cc3c3cccc1c32]

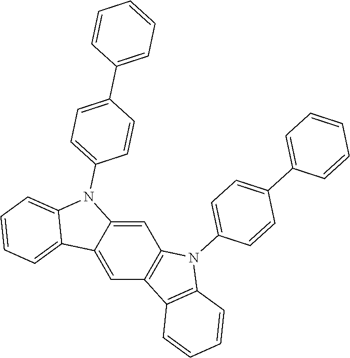 [SMILES: c1ccc(-c2ccc(-n3c4ccccc4c4cc5c6ccccc6n(-c6ccc(-c7ccccc7)cc6)c5cc43)cc2)cc1]

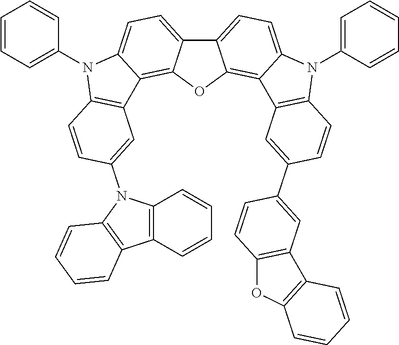 [SMILES: c1ccc(-n2c3ccc(-c4ccc5oc6ccccc6c5c4)cc3c3c4oc5c(ccc6c5c5cc(-n7c8ccccc8c8ccccc87)ccc5n6-c5ccccc5)c4ccc32)cc1]

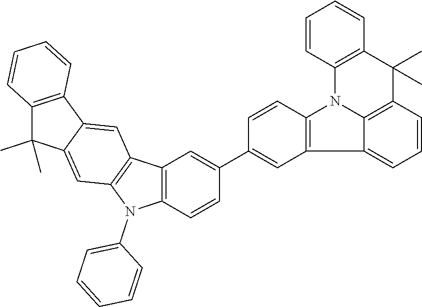

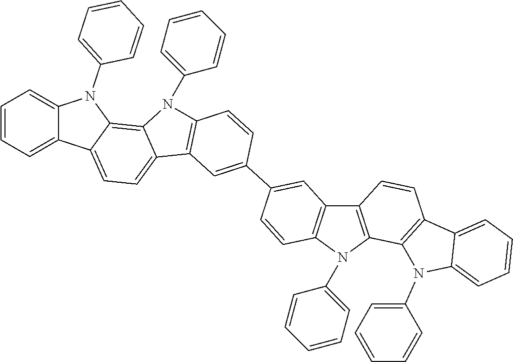 [SMILES: c1ccc(-n2c3ccccc3c3ccc4c5cc(-c6ccc7c(c6)c6ccc8c9ccccc9n(-c9ccccc9)c8c6n7-c6ccccc6)ccc5n(-c5ccccc5)c4c32)cc1]

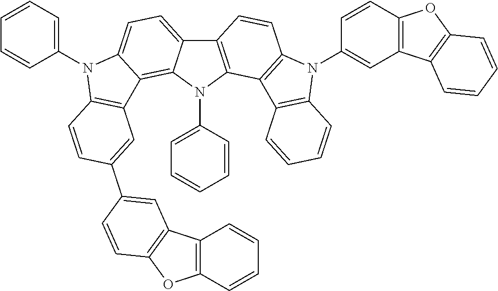 [SMILES: c1ccc(-n2c3ccc(-c4ccc5oc6ccccc6c5c4)cc3c3c2ccc2c4ccc5c(c6ccccc6n5-c5ccc6oc7ccccc7c6c5)c4n(-c4ccccc4)c23)cc1]

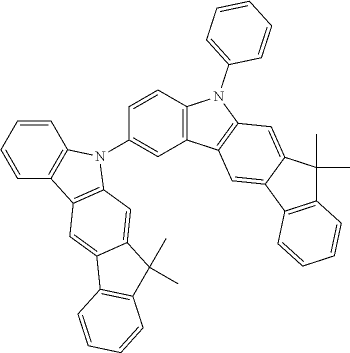 [SMILES: CC1(C)c2ccccc2-c2cc3c4ccccc4n(-c4ccc5c(c4)c4cc6c(cc4n5-c4ccccc4)C(C)(C)c4ccccc4-6)c3cc21]

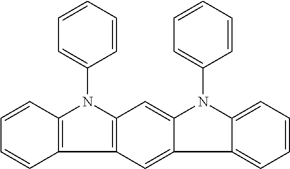 [SMILES: c1ccc(-n2c3ccccc3c3cc4c5ccccc5n(-c5ccccc5)c4cc32)cc1]

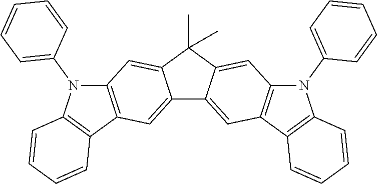 [SMILES: CC1(C)c2cc3c(cc2-c2cc4c5ccccc5n(-c5ccccc5)c4cc21)c1ccccc1n3-c1ccccc1]

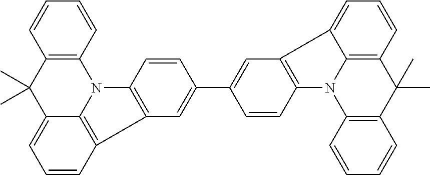

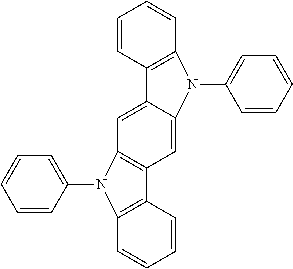 [SMILES: c1ccc(-n2c3ccccc3c3cc4c(cc32)c2ccccc2n4-c2ccccc2)cc1]

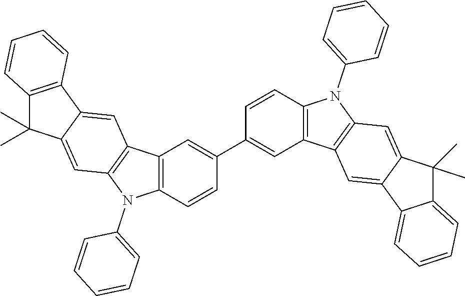

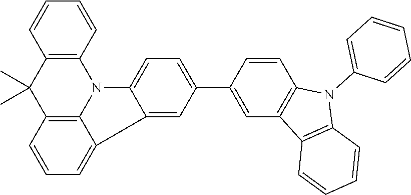 [SMILES: CC1(C)c2ccccc2-n2c3ccc(-c4ccc5c(c4)c4ccccc4n5-c4ccccc4)cc3c3cccc1c32]

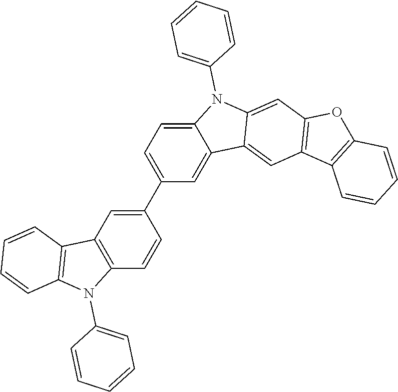 [SMILES: c1ccc(-n2c3ccccc3c3cc(-c4ccc5c(c4)c4cc6c(cc4n5-c4ccccc4)oc4ccccc46)ccc32)cc1]

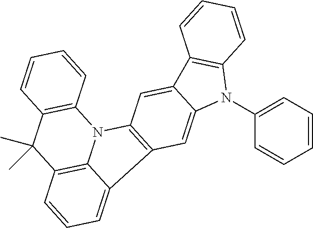 [SMILES: CC1(C)c2ccccc2-n2c3cc4c5ccccc5n(-c5ccccc5)c4cc3c3cccc1c32]

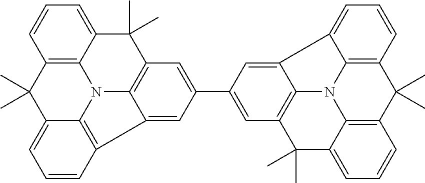

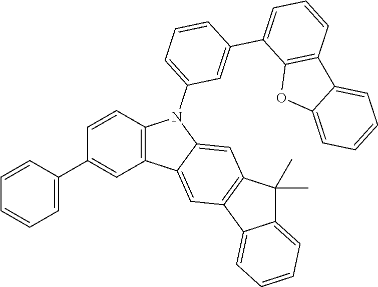 [SMILES: CC1(C)c2ccccc2-c2cc3c4cc(-c5ccccc5)ccc4n(-c4cccc(-c5cccc6c5oc5ccccc56)c4)c3cc21]

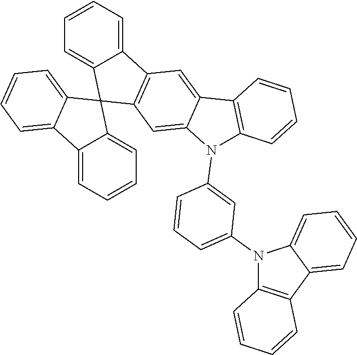 [SMILES: c1cc(-n2c3ccccc3c3ccccc32)cc(-n2c3ccccc3c3cc4c(cc32)C2(c3ccccc3-c3ccccc32)c2ccccc2-4)c1]

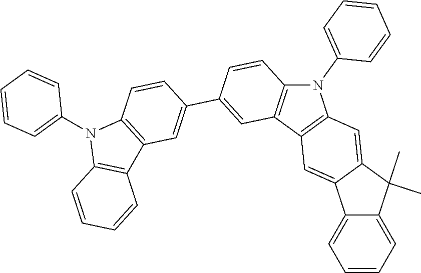 [SMILES: CC1(C)c2ccccc2-c2cc3c4cc(-c5ccc6c(c5)c5ccccc5n6-c5ccccc5)ccc4n(-c4ccccc4)c3cc21]

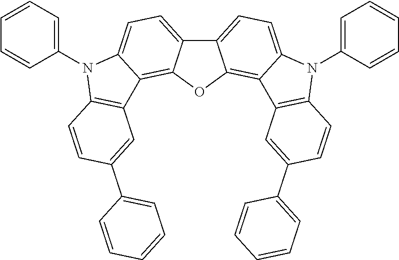 [SMILES: c1ccc(-c2ccc3c(c2)c2c4oc5c(ccc6c5c5cc(-c7ccccc7)ccc5n6-c5ccccc5)c4ccc2n3-c2ccccc2)cc1]

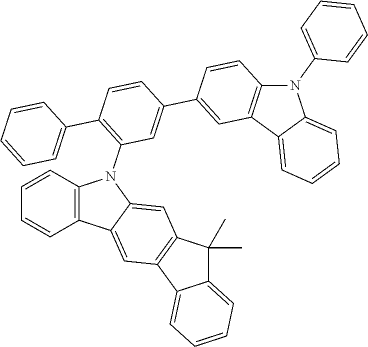 [SMILES: CC1(C)c2ccccc2-c2cc3c4ccccc4n(-c4cc(-c5ccc6c(c5)c5ccccc5n6-c5ccccc5)ccc4-c4ccccc4)c3cc21]

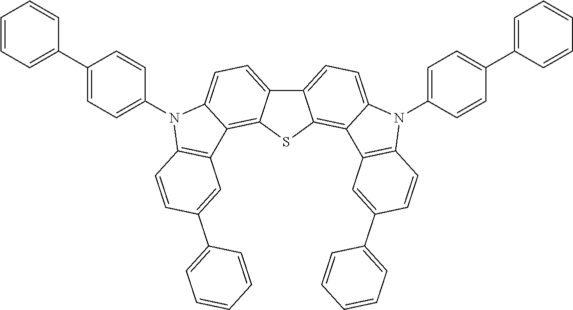 [SMILES: c1ccc(-c2ccc(-n3c4ccc(-c5ccccc5)cc4c4c5sc6c(ccc7c6c6cc(-c8ccccc8)ccc6n7-c6ccc(-c7ccccc7)cc6)c5ccc43)cc2)cc1]

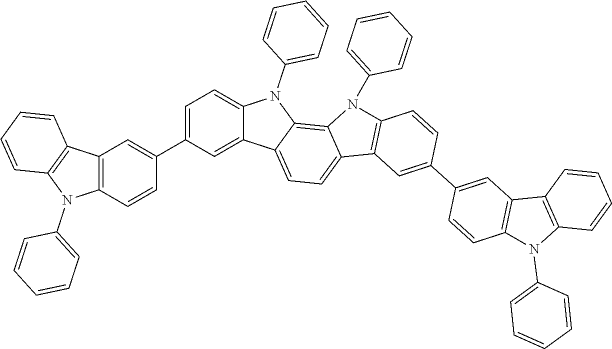 [SMILES: c1ccc(-n2c3ccccc3c3cc(-c4ccc5c(c4)c4ccc6c7cc(-c8ccc9c(c8)c8ccccc8n9-c8ccccc8)ccc7n(-c7ccccc7)c6c4n5-c4ccccc4)ccc32)cc1]

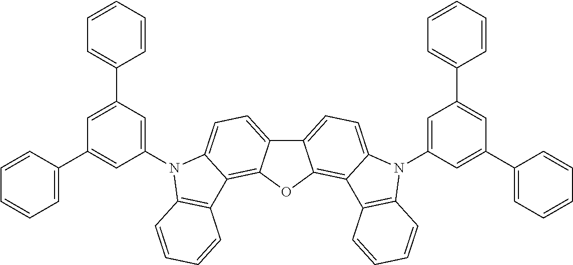 [SMILES: c1ccc(-c2cc(-c3ccccc3)cc(-n3c4ccccc4c4c5oc6c(ccc7c6c6ccccc6n7-c6cc(-c7ccccc7)cc(-c7ccccc7)c6)c5ccc43)c2)cc1]

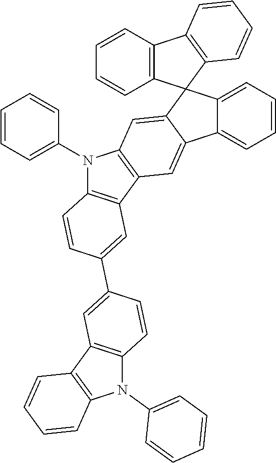 [SMILES: c1ccc(-n2c3ccccc3c3cc(-c4ccc5c(c4)c4cc6c(cc4n5-c4ccccc4)C4(c5ccccc5-c5ccccc54)c4ccccc4-6)ccc32)cc1]

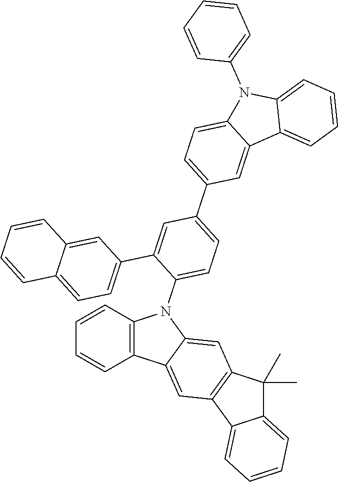 [SMILES: CC1(C)c2ccccc2-c2cc3c4ccccc4n(-c4ccc(-c5ccc6c(c5)c5ccccc5n6-c5ccccc5)cc4-c4ccc5ccccc5c4)c3cc21]

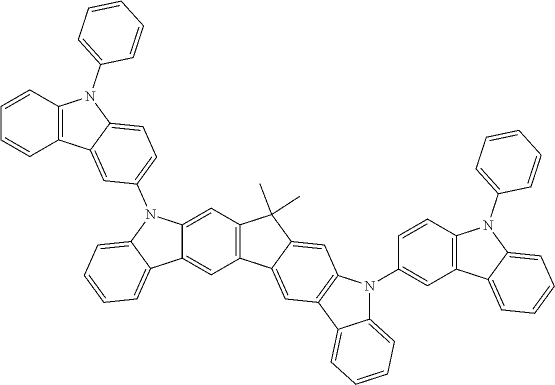 [SMILES: CC1(C)c2cc3c(cc2-c2cc4c5ccccc5n(-c5ccc6c(c5)c5ccccc5n6-c5ccccc5)c4cc21)c1ccccc1n3-c1ccc2c(c1)c1ccccc1n2-c1ccccc1]

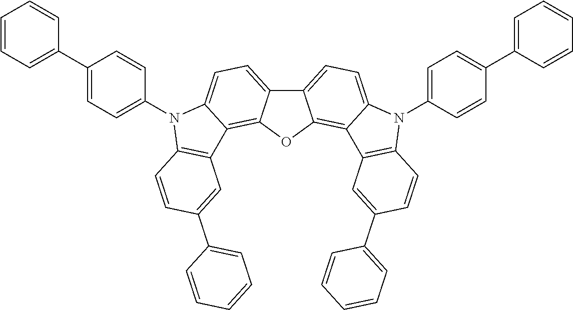 [SMILES: c1ccc(-c2ccc(-n3c4ccc(-c5ccccc5)cc4c4c5oc6c(ccc7c6c6cc(-c8ccccc8)ccc6n7-c6ccc(-c7ccccc7)cc6)c5ccc43)cc2)cc1]

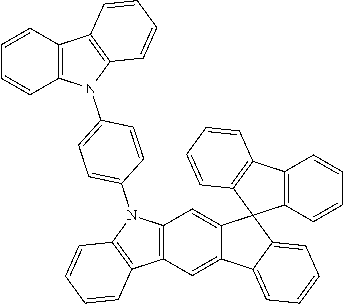 [SMILES: c1ccc2c(c1)-c1ccccc1C21c2ccccc2-c2cc3c4ccccc4n(-c4ccc(-n5c6ccccc6c6ccccc65)cc4)c3cc21]

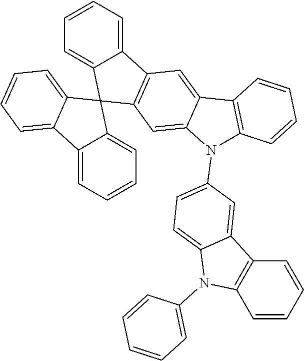 [SMILES: c1ccc(-n2c3ccccc3c3cc(-n4c5ccccc5c5cc6c(cc54)C4(c5ccccc5-c5ccccc54)c4ccccc4-6)ccc32)cc1]

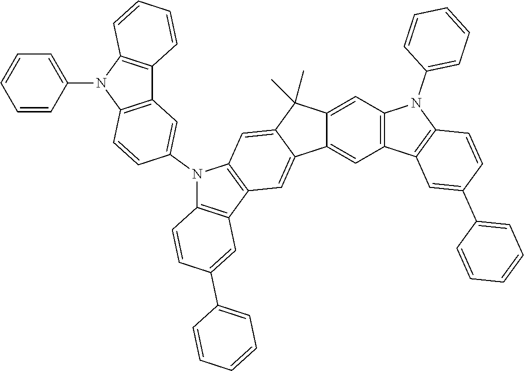 [SMILES: CC1(C)c2cc3c(cc2-c2cc4c5cc(-c6ccccc6)ccc5n(-c5ccc6c(c5)c5ccccc5n6-c5ccccc5)c4cc21)c1cc(-c2ccccc2)ccc1n3-c1ccccc1]

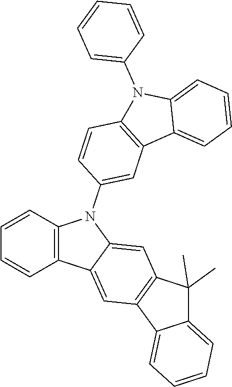 [SMILES: CC1(C)c2ccccc2-c2cc3c4ccccc4n(-c4ccc5c(c4)c4ccccc4n5-c4ccccc4)c3cc21]

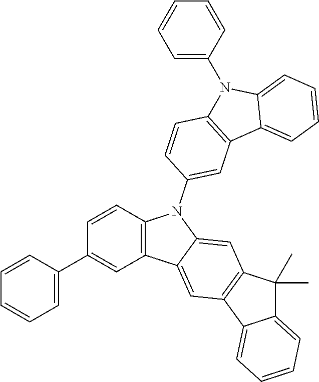 [SMILES: CC1(C)c2ccccc2-c2cc3c4cc(-c5ccccc5)ccc4n(-c4ccc5c(c4)c4ccccc4n5-c4ccccc4)c3cc21]

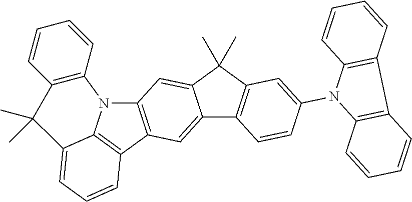 [SMILES: CC1(C)c2cc(-n3c4ccccc4c4ccccc43)ccc2-c2cc3c4cccc5c4n(c3cc21)-c1ccccc1C5(C)C]

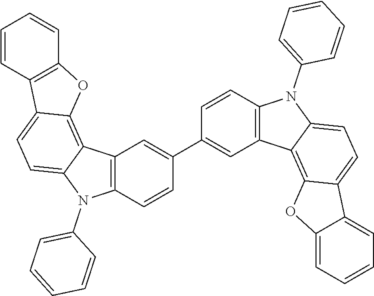 [SMILES: c1ccc(-n2c3ccc(-c4ccc5c(c4)c4c6oc7ccccc7c6ccc4n5-c4ccccc4)cc3c3c4oc5ccccc5c4ccc32)cc1]

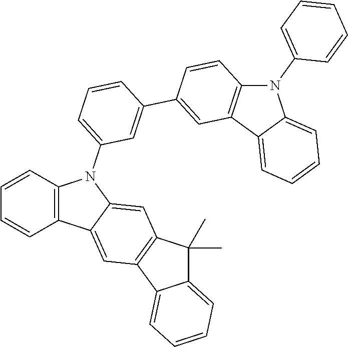 [SMILES: CC1(C)c2ccccc2-c2cc3c4ccccc4n(-c4cccc(-c5ccc6c(c5)c5ccccc5n6-c5ccccc5)c4)c3cc21]

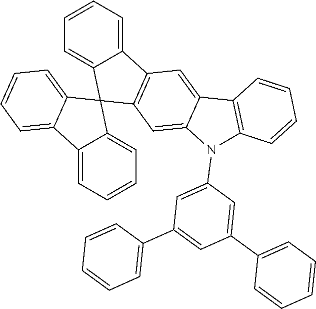 [SMILES: c1ccc(-c2cc(-c3ccccc3)cc(-n3c4ccccc4c4cc5c(cc43)C3(c4ccccc4-c4ccccc43)c3ccccc3-5)c2)cc1]

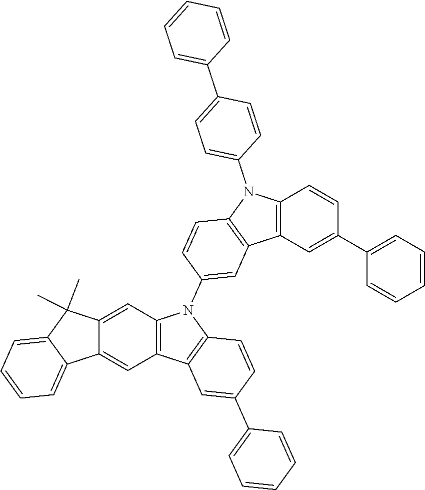 [SMILES: CC1(C)c2ccccc2-c2cc3c4cc(-c5ccccc5)ccc4n(-c4ccc5c(c4)c4cc(-c6ccccc6)ccc4n5-c4ccc(-c5ccccc5)cc4)c3cc21]

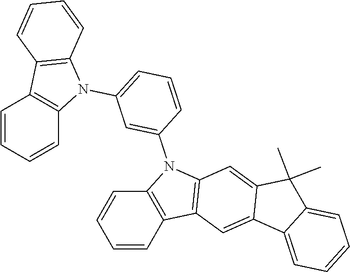 [SMILES: CC1(C)c2ccccc2-c2cc3c4ccccc4n(-c4cccc(-n5c6ccccc6c6ccccc65)c4)c3cc21]

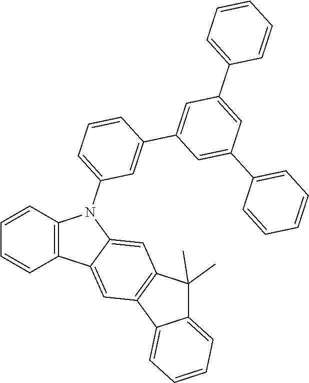 [SMILES: CC1(C)c2ccccc2-c2cc3c4ccccc4n(-c4cccc(-c5cc(-c6ccccc6)cc(-c6ccccc6)c5)c4)c3cc21]

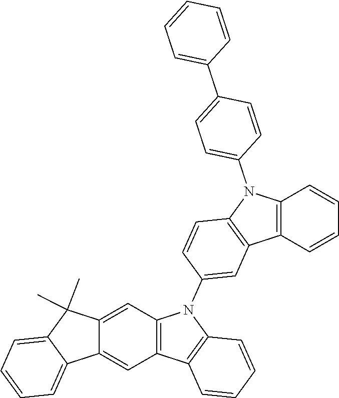 [SMILES: CC1(C)c2ccccc2-c2cc3c4ccccc4n(-c4ccc5c(c4)c4ccccc4n5-c4ccc(-c5ccccc5)cc4)c3cc21]

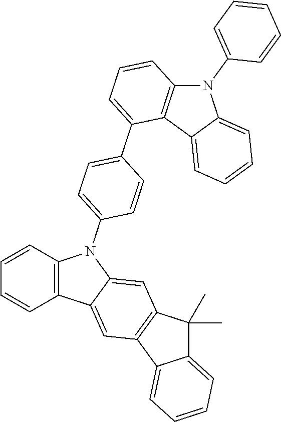 [SMILES: CC1(C)c2ccccc2-c2cc3c4ccccc4n(-c4ccc(-c5cccc6c5c5ccccc5n6-c5ccccc5)cc4)c3cc21]

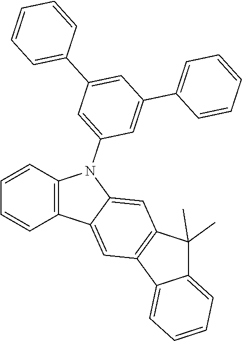 [SMILES: CC1(C)c2ccccc2-c2cc3c4ccccc4n(-c4cc(-c5ccccc5)cc(-c5ccccc5)c4)c3cc21]

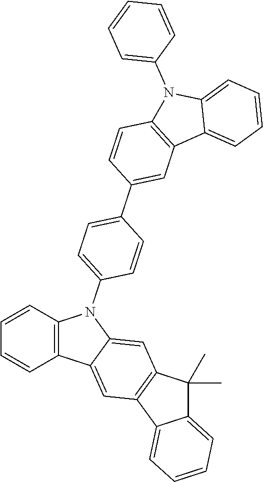 [SMILES: CC1(C)c2ccccc2-c2cc3c4ccccc4n(-c4ccc(-c5ccc6c(c5)c5ccccc5n6-c5ccccc5)cc4)c3cc21]

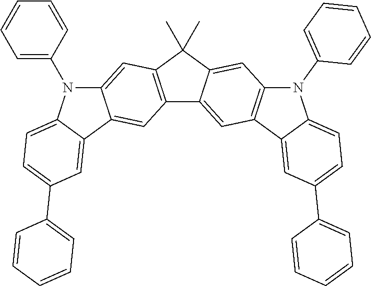 [SMILES: CC1(C)c2cc3c(cc2-c2cc4c5cc(-c6ccccc6)ccc5n(-c5ccccc5)c4cc21)c1cc(-c2ccccc2)ccc1n3-c1ccccc1]

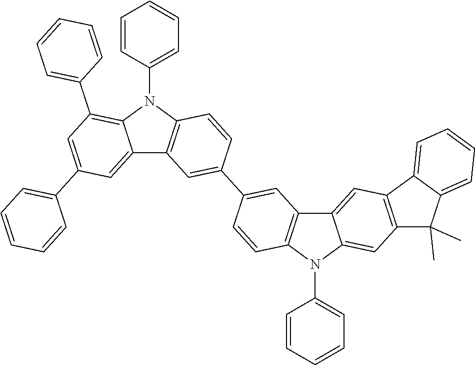 [SMILES: CC1(C)c2ccccc2-c2cc3c4cc(-c5ccc6c(c5)c5cc(-c7ccccc7)cc(-c7ccccc7)c5n6-c5ccccc5)ccc4n(-c4ccccc4)c3cc21]

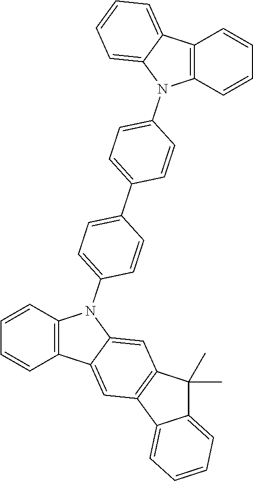 [SMILES: CC1(C)c2ccccc2-c2cc3c4ccccc4n(-c4ccc(-c5ccc(-n6c7ccccc7c7ccccc76)cc5)cc4)c3cc21]

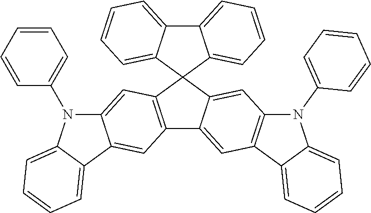 [SMILES: c1ccc(-n2c3ccccc3c3cc4c(cc32)C2(c3ccccc3-c3ccccc32)c2cc3c(cc2-4)c2ccccc2n3-c2ccccc2)cc1]

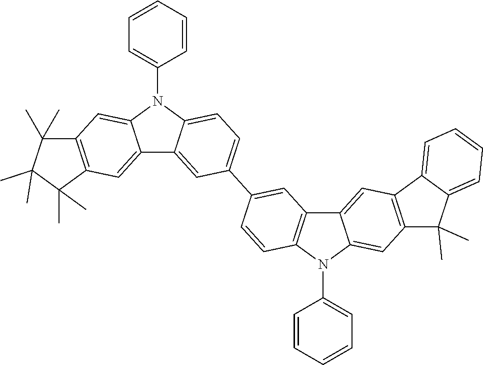 [SMILES: CC1(C)c2ccccc2-c2cc3c4cc(-c5ccc6c(c5)c5cc7c(cc5n6-c5ccccc5)C(C)(C)C(C)(C)C7(C)C)ccc4n(-c4ccccc4)c3cc21]

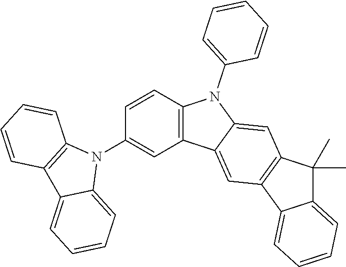 [SMILES: CC1(C)c2ccccc2-c2cc3c4cc(-n5c6ccccc6c6ccccc65)ccc4n(-c4ccccc4)c3cc21]

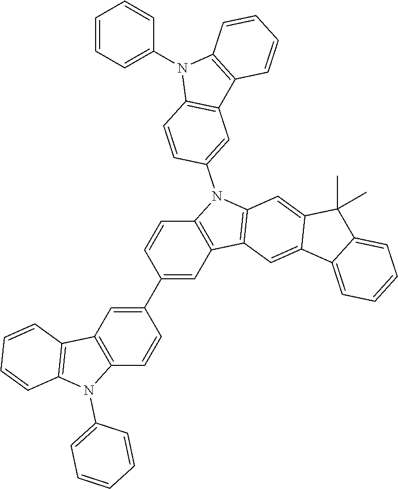 [SMILES: CC1(C)c2ccccc2-c2cc3c4cc(-c5ccc6c(c5)c5ccccc5n6-c5ccccc5)ccc4n(-c4ccc5c(c4)c4ccccc4n5-c4ccccc4)c3cc21]

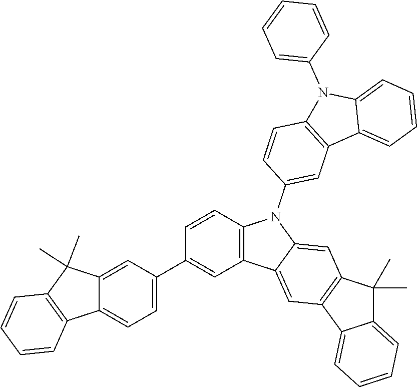 [SMILES: CC1(C)c2ccccc2-c2ccc(-c3ccc4c(c3)c3cc5c(cc3n4-c3ccc4c(c3)c3ccccc3n4-c3ccccc3)C(C)(C)c3ccccc3-5)cc21]

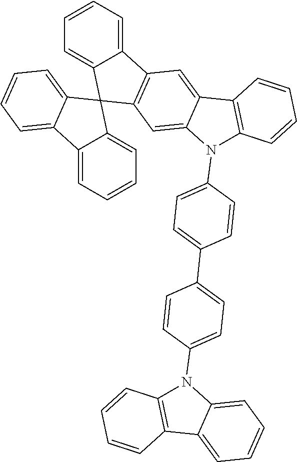 [SMILES: c1ccc2c(c1)-c1ccccc1C21c2ccccc2-c2cc3c4ccccc4n(-c4ccc(-c5ccc(-n6c7ccccc7c7ccccc76)cc5)cc4)c3cc21]

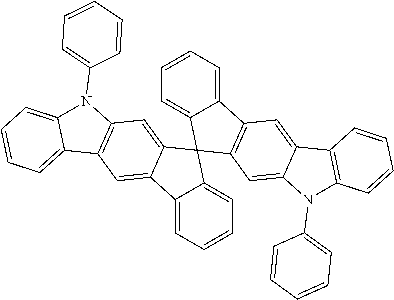 [SMILES: c1ccc(-n2c3ccccc3c3cc4c(cc32)C2(c3ccccc3-4)c3ccccc3-c3cc4c5ccccc5n(-c5ccccc5)c4cc32)cc1]

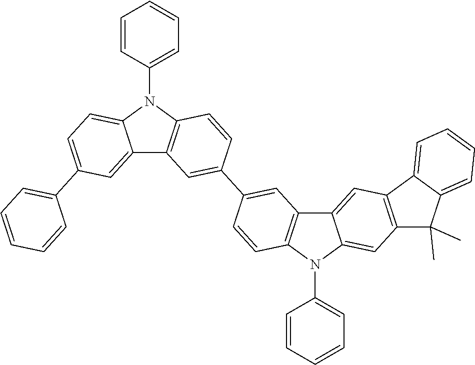 [SMILES: CC1(C)c2ccccc2-c2cc3c4cc(-c5ccc6c(c5)c5cc(-c7ccccc7)ccc5n6-c5ccccc5)ccc4n(-c4ccccc4)c3cc21]

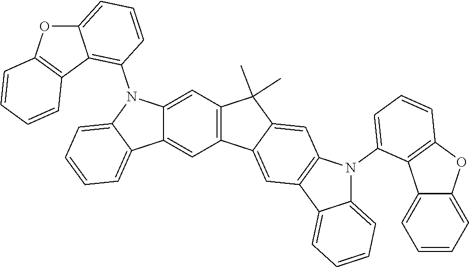 [SMILES: CC1(C)c2cc3c(cc2-c2cc4c5ccccc5n(-c5cccc6oc7ccccc7c56)c4cc21)c1ccccc1n3-c1cccc2oc3ccccc3c12]

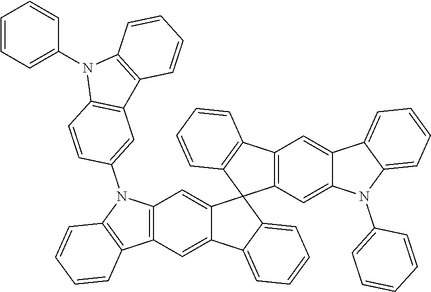 [SMILES: c1ccc(-n2c3ccccc3c3cc(-n4c5ccccc5c5cc6c(cc54)C4(c5ccccc5-c5cc7c8ccccc8n(-c8ccccc8)c7cc54)c4ccccc4-6)ccc32)cc1]

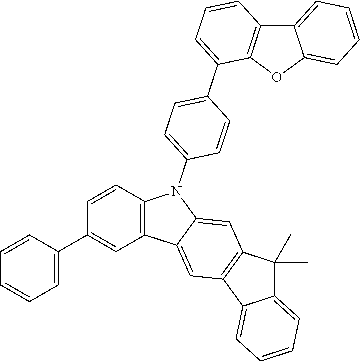 [SMILES: CC1(C)c2ccccc2-c2cc3c4cc(-c5ccccc5)ccc4n(-c4ccc(-c5cccc6c5oc5ccccc56)cc4)c3cc21]

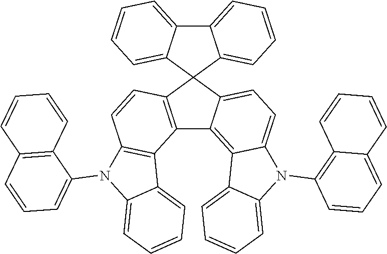 [SMILES: c1ccc2c(c1)-c1ccccc1C21c2ccc3c(c2-c2c1ccc1c2c2ccccc2n1-c1cccc2ccccc12)c1ccccc1n3-c1cccc2ccccc12]

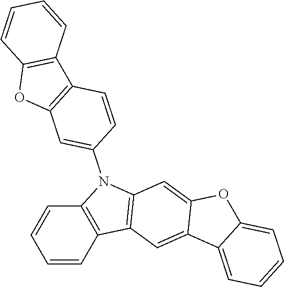 [SMILES: c1ccc2c(c1)oc1cc(-n3c4ccccc4c4cc5c(cc43)oc3ccccc35)ccc12]

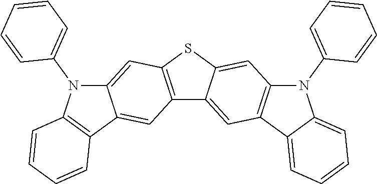 [SMILES: c1ccc(-n2c3ccccc3c3cc4c(cc32)sc2cc3c(cc24)c2ccccc2n3-c2ccccc2)cc1]

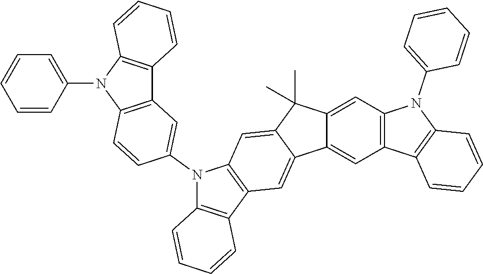 [SMILES: CC1(C)c2cc3c(cc2-c2cc4c5ccccc5n(-c5ccc6c(c5)c5ccccc5n6-c5ccccc5)c4cc21)c1ccccc1n3-c1ccccc1]

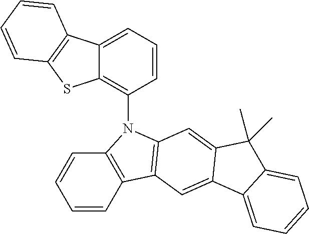 [SMILES: CC1(C)c2ccccc2-c2cc3c4ccccc4n(-c4cccc5c4sc4ccccc45)c3cc21]

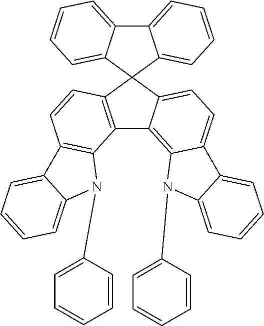 [SMILES: c1ccc(-n2c3ccccc3c3ccc4c(c32)-c2c(ccc3c5ccccc5n(-c5ccccc5)c23)C42c3ccccc3-c3ccccc32)cc1]

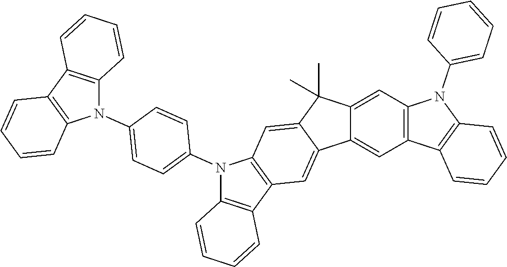 [SMILES: CC1(C)c2cc3c(cc2-c2cc4c5ccccc5n(-c5ccc(-n6c7ccccc7c7ccccc76)cc5)c4cc21)c1ccccc1n3-c1ccccc1]

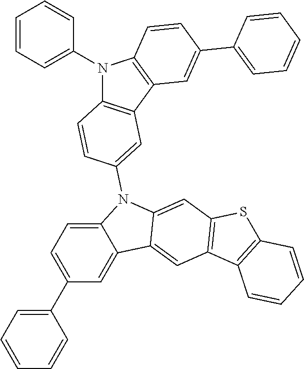 [SMILES: c1ccc(-c2ccc3c(c2)c2cc(-n4c5ccc(-c6ccccc6)cc5c5cc6c(cc54)sc4ccccc46)ccc2n3-c2ccccc2)cc1]

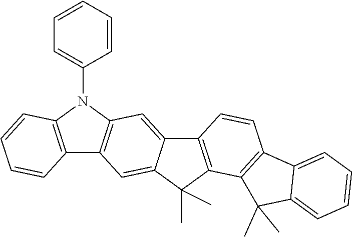 [SMILES: CC1(C)c2ccccc2-c2ccc3c(c21)C(C)(C)c1cc2c4ccccc4n(-c4ccccc4)c2cc1-3]

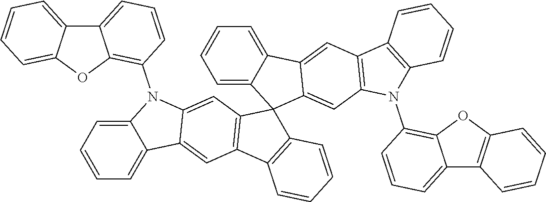 [SMILES: c1ccc2c(c1)-c1cc3c4ccccc4n(-c4cccc5c4oc4ccccc45)c3cc1C21c2ccccc2-c2cc3c4ccccc4n(-c4cccc5c4oc4ccccc45)c3cc21]

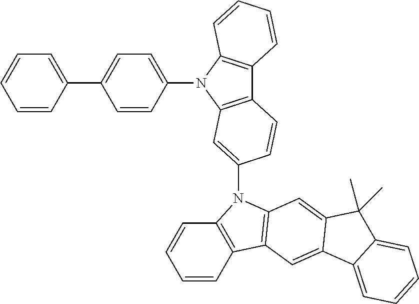 [SMILES: CC1(C)c2ccccc2-c2cc3c4ccccc4n(-c4ccc5c6ccccc6n(-c6ccc(-c7ccccc7)cc6)c5c4)c3cc21]

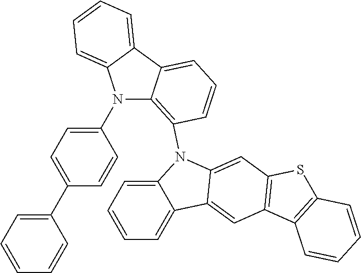 [SMILES: c1ccc(-c2ccc(-n3c4ccccc4c4cccc(-n5c6ccccc6c6cc7c(cc65)sc5ccccc57)c43)cc2)cc1]

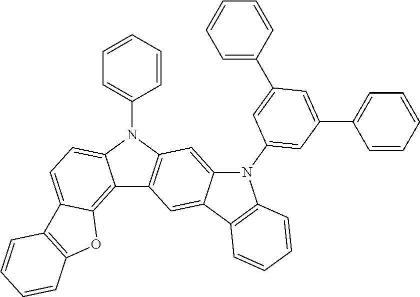 [SMILES: c1ccc(-c2cc(-c3ccccc3)cc(-n3c4ccccc4c4cc5c6c7oc8ccccc8c7ccc6n(-c6ccccc6)c5cc43)c2)cc1]

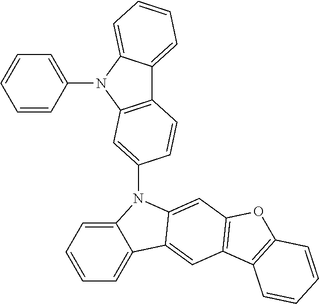 [SMILES: c1ccc(-n2c3ccccc3c3ccc(-n4c5ccccc5c5cc6c(cc54)oc4ccccc46)cc32)cc1]

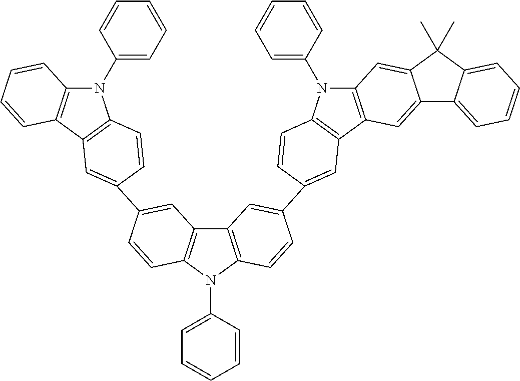 [SMILES: CC1(C)c2ccccc2-c2cc3c4cc(-c5ccc6c(c5)c5cc(-c7ccc8c(c7)c7ccccc7n8-c7ccccc7)ccc5n6-c5ccccc5)ccc4n(-c4ccccc4)c3cc21]

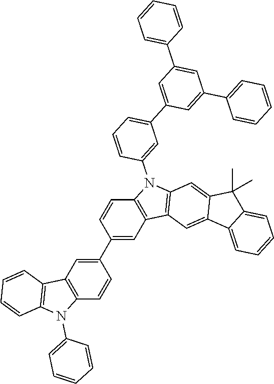 [SMILES: CC1(C)c2ccccc2-c2cc3c4cc(-c5ccc6c(c5)c5ccccc5n6-c5ccccc5)ccc4n(-c4cccc(-c5cc(-c6ccccc6)cc(-c6ccccc6)c5)c4)c3cc21]

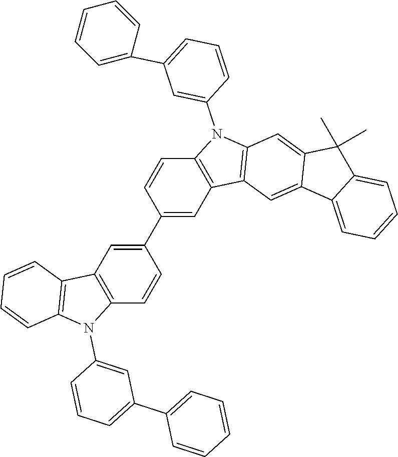 [SMILES: CC1(C)c2ccccc2-c2cc3c4cc(-c5ccc6c(c5)c5ccccc5n6-c5cccc(-c6ccccc6)c5)ccc4n(-c4cccc(-c5ccccc5)c4)c3cc21]

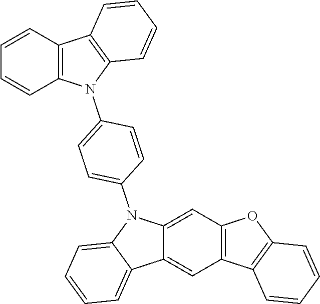 [SMILES: c1ccc2c(c1)oc1cc3c(cc12)c1ccccc1n3-c1ccc(-n2c3ccccc3c3ccccc32)cc1]

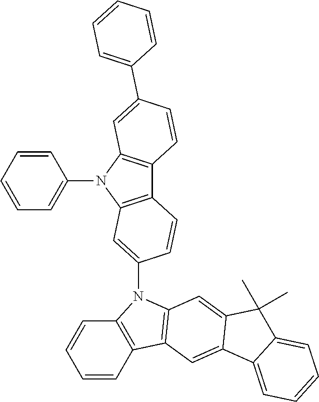 [SMILES: CC1(C)c2ccccc2-c2cc3c4ccccc4n(-c4ccc5c6ccc(-c7ccccc7)cc6n(-c6ccccc6)c5c4)c3cc21]

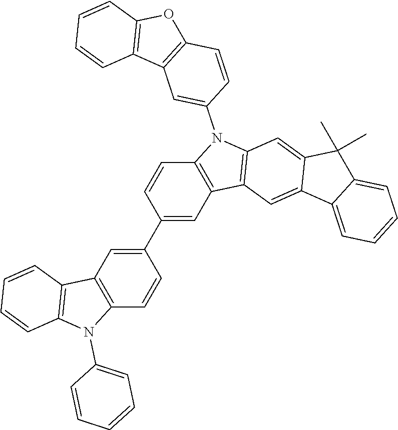 [SMILES: CC1(C)c2ccccc2-c2cc3c4cc(-c5ccc6c(c5)c5ccccc5n6-c5ccccc5)ccc4n(-c4ccc5oc6ccccc6c5c4)c3cc21]

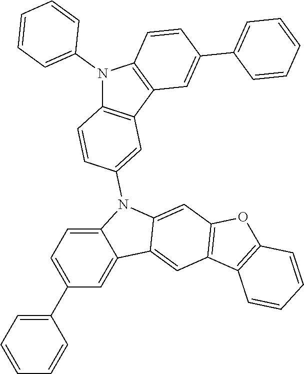 [SMILES: c1ccc(-c2ccc3c(c2)c2cc(-n4c5ccc(-c6ccccc6)cc5c5cc6c(cc54)oc4ccccc46)ccc2n3-c2ccccc2)cc1]

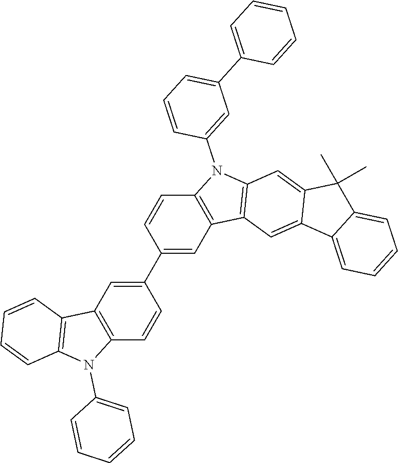 [SMILES: CC1(C)c2ccccc2-c2cc3c4cc(-c5ccc6c(c5)c5ccccc5n6-c5ccccc5)ccc4n(-c4cccc(-c5ccccc5)c4)c3cc21]

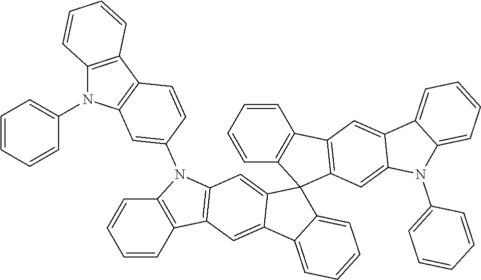 [SMILES: c1ccc(-n2c3ccccc3c3ccc(-n4c5ccccc5c5cc6c(cc54)C4(c5ccccc5-c5cc7c8ccccc8n(-c8ccccc8)c7cc54)c4ccccc4-6)cc32)cc1]

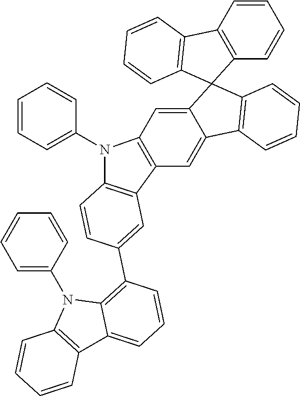 [SMILES: c1ccc(-n2c3ccc(-c4cccc5c6ccccc6n(-c6ccccc6)c45)cc3c3cc4c(cc32)C2(c3ccccc3-c3ccccc32)c2ccccc2-4)cc1]

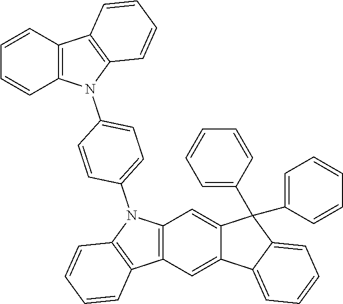 [SMILES: c1ccc(C2(c3ccccc3)c3ccccc3-c3cc4c5ccccc5n(-c5ccc(-n6c7ccccc7c7ccccc76)cc5)c4cc32)cc1]

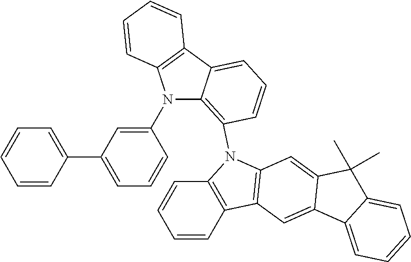 [SMILES: CC1(C)c2ccccc2-c2cc3c4ccccc4n(-c4cccc5c6ccccc6n(-c6cccc(-c7ccccc7)c6)c45)c3cc21]

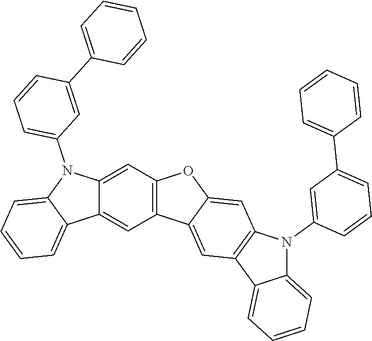 [SMILES: c1ccc(-c2cccc(-n3c4ccccc4c4cc5c(cc43)oc3cc4c(cc35)c3ccccc3n4-c3cccc(-c4ccccc4)c3)c2)cc1]

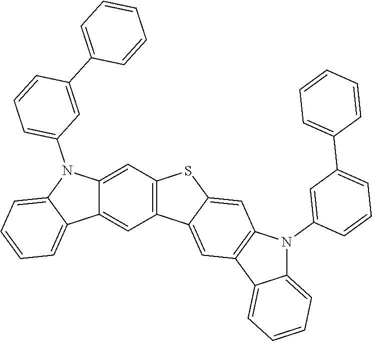 [SMILES: c1ccc(-c2cccc(-n3c4ccccc4c4cc5c(cc43)sc3cc4c(cc35)c3ccccc3n4-c3cccc(-c4ccccc4)c3)c2)cc1]

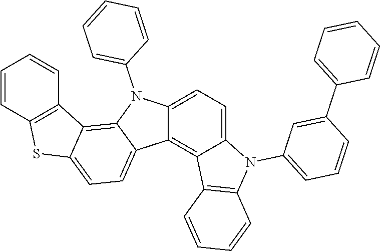 [SMILES: c1ccc(-c2cccc(-n3c4ccccc4c4c5c6ccc7sc8ccccc8c7c6n(-c6ccccc6)c5ccc43)c2)cc1]

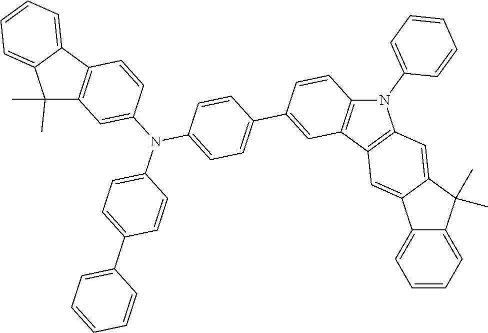 [SMILES: CC1(C)c2ccccc2-c2ccc(N(c3ccc(-c4ccccc4)cc3)c3ccc(-c4ccc5c(c4)c4cc6c(cc4n5-c4ccccc4)C(C)(C)c4ccccc4-6)cc3)cc21]

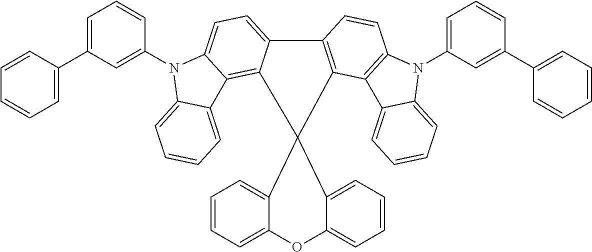 [SMILES: c1ccc(-c2cccc(-n3c4ccccc4c4c5c(ccc43)-c3ccc4c(c3C53c5ccccc5Oc5ccccc53)c3ccccc3n4-c3cccc(-c4ccccc4)c3)c2)cc1]

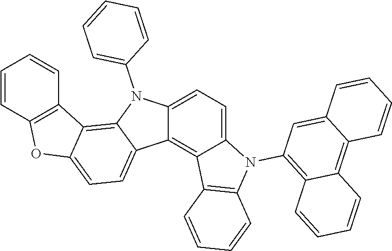 [SMILES: c1ccc(-n2c3ccc4c(c5ccccc5n4-c4cc5ccccc5c5ccccc45)c3c3ccc4oc5ccccc5c4c32)cc1]

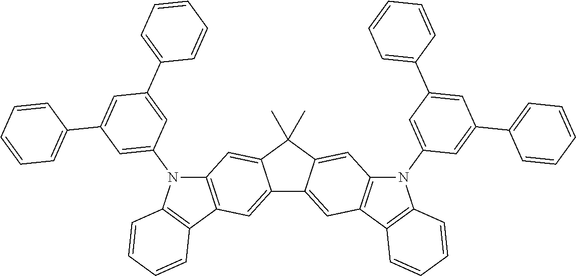 [SMILES: CC1(C)c2cc3c(cc2-c2cc4c5ccccc5n(-c5cc(-c6ccccc6)cc(-c6ccccc6)c5)c4cc21)c1ccccc1n3-c1cc(-c2ccccc2)cc(-c2ccccc2)c1]

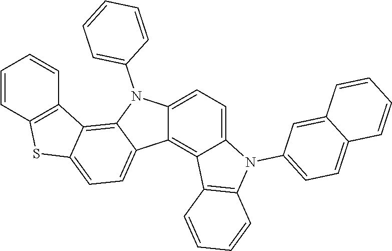 [SMILES: c1ccc(-n2c3ccc4c(c5ccccc5n4-c4ccc5ccccc5c4)c3c3ccc4sc5ccccc5c4c32)cc1]

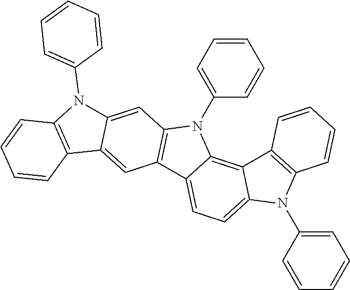 [SMILES: c1ccc(-n2c3ccccc3c3cc4c5ccc6c(c7ccccc7n6-c6ccccc6)c5n(-c5ccccc5)c4cc32)cc1]

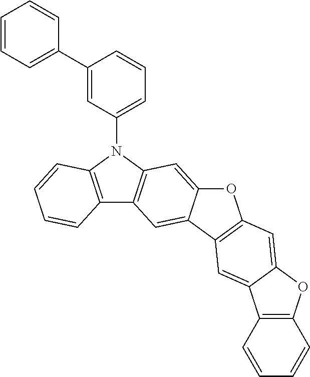 [SMILES: c1ccc(-c2cccc(-n3c4ccccc4c4cc5c(cc43)oc3cc4oc6ccccc6c4cc35)c2)cc1]

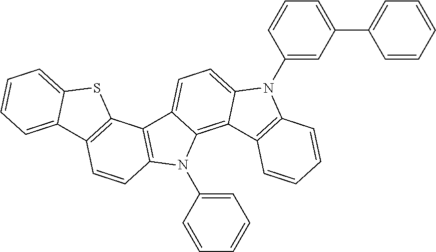 [SMILES: c1ccc(-c2cccc(-n3c4ccccc4c4c3ccc3c5c6sc7ccccc7c6ccc5n(-c5ccccc5)c34)c2)cc1]

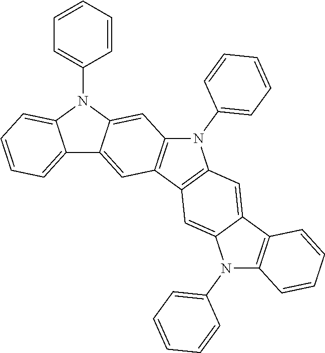 [SMILES: c1ccc(-n2c3ccccc3c3cc4c(cc32)c2cc3c5ccccc5n(-c5ccccc5)c3cc2n4-c2ccccc2)cc1]

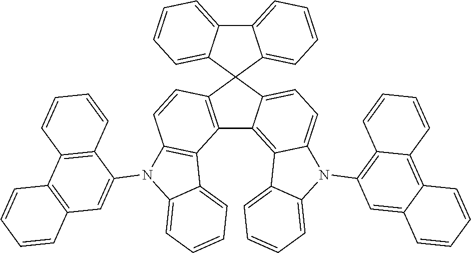 [SMILES: c1ccc2c(c1)-c1ccccc1C21c2ccc3c(c2-c2c1ccc1c2c2ccccc2n1-c1cc2ccccc2c2ccccc12)c1ccccc1n3-c1cc2ccccc2c2ccccc12]

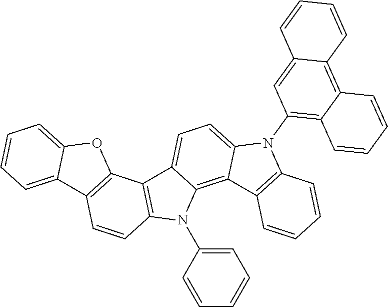 [SMILES: c1ccc(-n2c3ccc4c5ccccc5oc4c3c3ccc4c(c5ccccc5n4-c4cc5ccccc5c5ccccc45)c32)cc1]

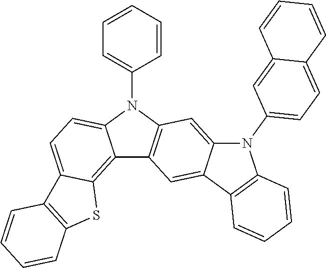 [SMILES: c1ccc(-n2c3cc4c(cc3c3c5sc6ccccc6c5ccc32)c2ccccc2n4-c2ccc3ccccc3c2)cc1]

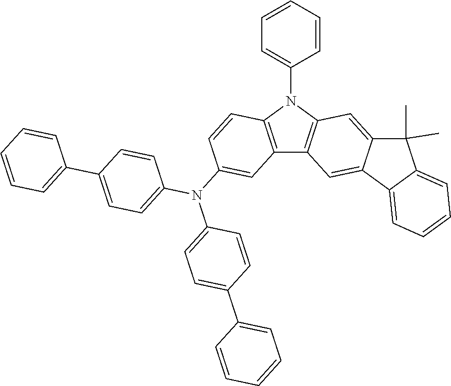 [SMILES: CC1(C)c2ccccc2-c2cc3c4cc(N(c5ccc(-c6ccccc6)cc5)c5ccc(-c6ccccc6)cc5)ccc4n(-c4ccccc4)c3cc21]

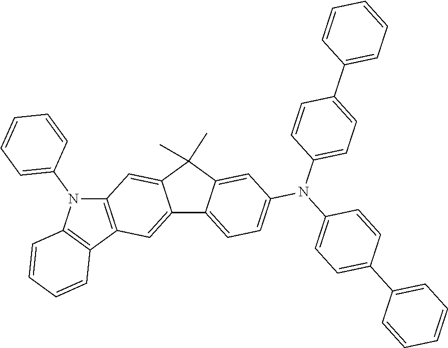 [SMILES: CC1(C)c2cc(N(c3ccc(-c4ccccc4)cc3)c3ccc(-c4ccccc4)cc3)ccc2-c2cc3c4ccccc4n(-c4ccccc4)c3cc21]

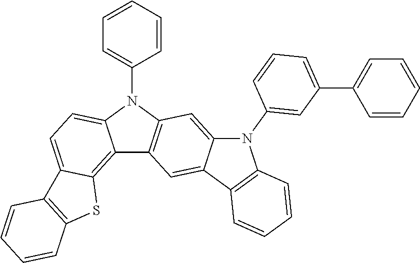 [SMILES: c1ccc(-c2cccc(-n3c4ccccc4c4cc5c6c7sc8ccccc8c7ccc6n(-c6ccccc6)c5cc43)c2)cc1]

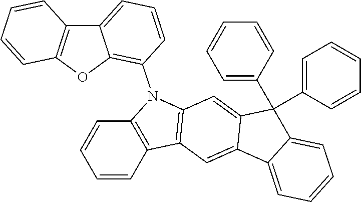 [SMILES: c1ccc(C2(c3ccccc3)c3ccccc3-c3cc4c5ccccc5n(-c5cccc6c5oc5ccccc56)c4cc32)cc1]

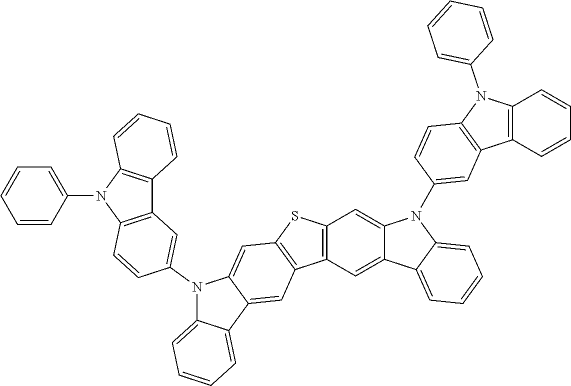 [SMILES: c1ccc(-n2c3ccccc3c3cc(-n4c5ccccc5c5cc6c(cc54)sc4cc5c(cc46)c4ccccc4n5-c4ccc5c(c4)c4ccccc4n5-c4ccccc4)ccc32)cc1]

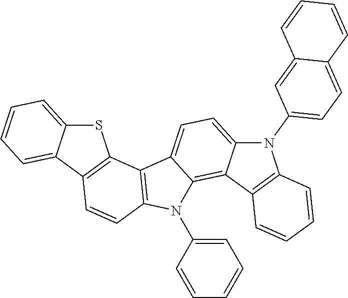 [SMILES: c1ccc(-n2c3ccc4c5ccccc5sc4c3c3ccc4c(c5ccccc5n4-c4ccc5ccccc5c4)c32)cc1]

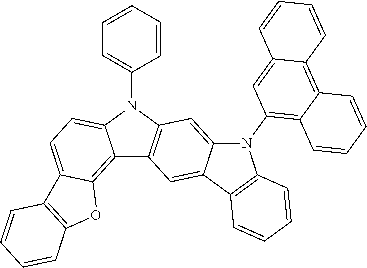 [SMILES: c1ccc(-n2c3cc4c(cc3c3c5oc6ccccc6c5ccc32)c2ccccc2n4-c2cc3ccccc3c3ccccc23)cc1]

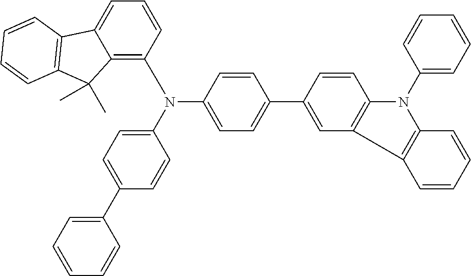 [SMILES: CC1(C)c2ccccc2-c2cccc(N(c3ccc(-c4ccccc4)cc3)c3ccc(-c4ccc5c(c4)c4ccccc4n5-c4ccccc4)cc3)c21]

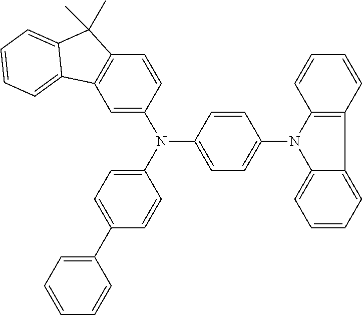 [SMILES: CC1(C)c2ccccc2-c2cc(N(c3ccc(-c4ccccc4)cc3)c3ccc(-n4c5ccccc5c5ccccc54)cc3)ccc21]

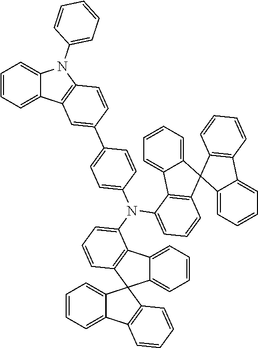 [SMILES: c1ccc(-n2c3ccccc3c3cc(-c4ccc(N(c5cccc6c5-c5ccccc5C65c6ccccc6-c6ccccc65)c5cccc6c5-c5ccccc5C65c6ccccc6-c6ccccc65)cc4)ccc32)cc1]

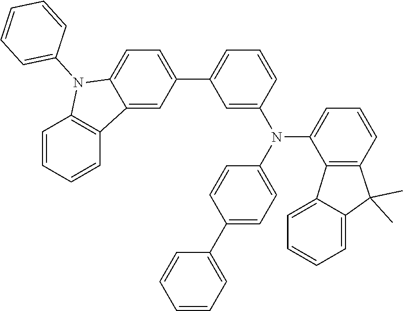 [SMILES: CC1(C)c2ccccc2-c2c(N(c3ccc(-c4ccccc4)cc3)c3cccc(-c4ccc5c(c4)c4ccccc4n5-c4ccccc4)c3)cccc21]

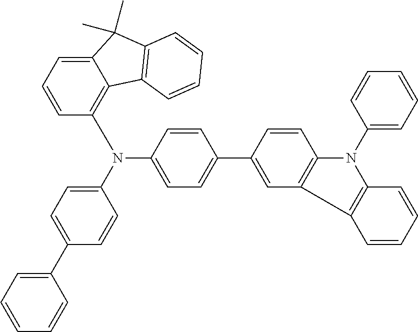 [SMILES: CC1(C)c2ccccc2-c2c(N(c3ccc(-c4ccccc4)cc3)c3ccc(-c4ccc5c(c4)c4ccccc4n5-c4ccccc4)cc3)cccc21]

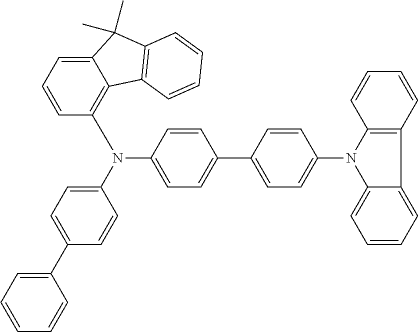 [SMILES: CC1(C)c2ccccc2-c2c(N(c3ccc(-c4ccccc4)cc3)c3ccc(-c4ccc(-n5c6ccccc6c6ccccc65)cc4)cc3)cccc21]

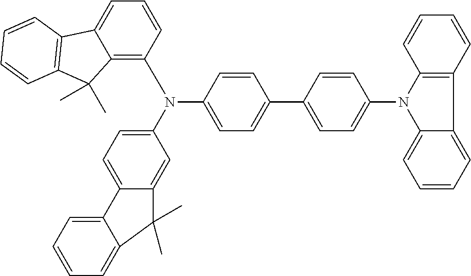 [SMILES: CC1(C)c2ccccc2-c2ccc(N(c3ccc(-c4ccc(-n5c6ccccc6c6ccccc65)cc4)cc3)c3cccc4c3C(C)(C)c3ccccc3-4)cc21]

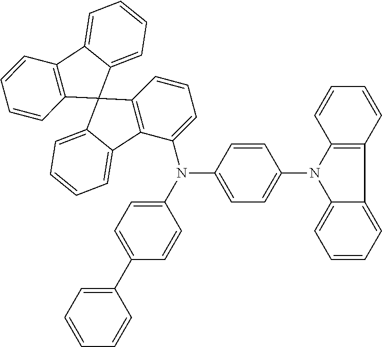 [SMILES: c1ccc(-c2ccc(N(c3ccc(-n4c5ccccc5c5ccccc54)cc3)c3cccc4c3-c3ccccc3C43c4ccccc4-c4ccccc43)cc2)cc1]

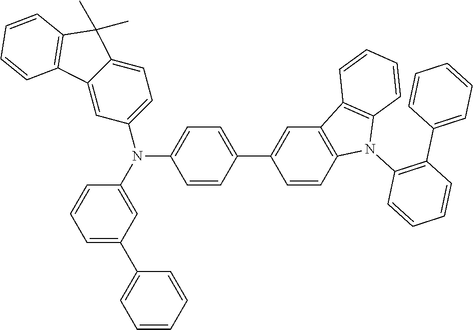 [SMILES: CC1(C)c2ccccc2-c2cc(N(c3ccc(-c4ccc5c(c4)c4ccccc4n5-c4ccccc4-c4ccccc4)cc3)c3cccc(-c4ccccc4)c3)ccc21]

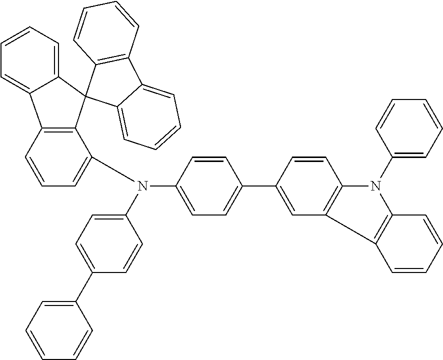 [SMILES: c1ccc(-c2ccc(N(c3ccc(-c4ccc5c(c4)c4ccccc4n5-c4ccccc4)cc3)c3cccc4c3C3(c5ccccc5-c5ccccc53)c3ccccc3-4)cc2)cc1]

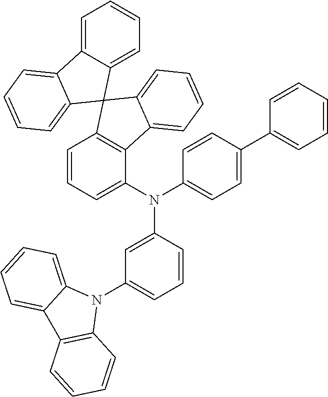 [SMILES: c1ccc(-c2ccc(N(c3cccc(-n4c5ccccc5c5ccccc54)c3)c3cccc4c3-c3ccccc3C43c4ccccc4-c4ccccc43)cc2)cc1]

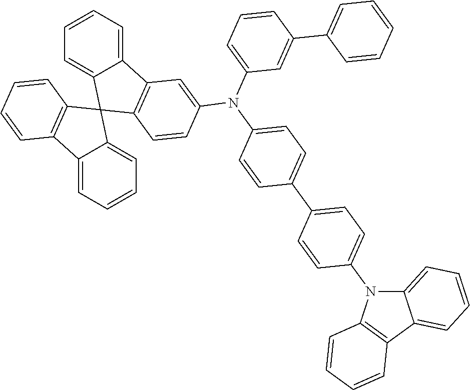 [SMILES: c1ccc(-c2cccc(N(c3ccc(-c4ccc(-n5c6ccccc6c6ccccc65)cc4)cc3)c3ccc4c(c3)-c3ccccc3C43c4ccccc4-c4ccccc43)c2)cc1]

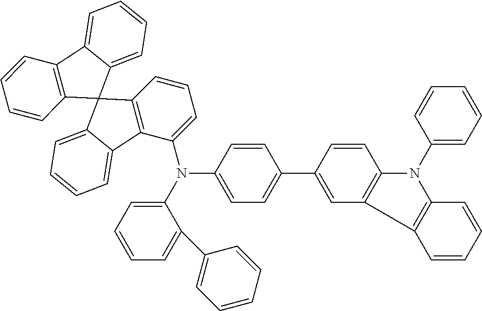 [SMILES: c1ccc(-c2ccccc2N(c2ccc(-c3ccc4c(c3)c3ccccc3n4-c3ccccc3)cc2)c2cccc3c2-c2ccccc2C32c3ccccc3-c3ccccc32)cc1]

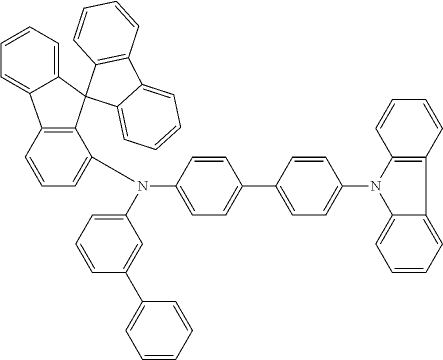 [SMILES: c1ccc(-c2cccc(N(c3ccc(-c4ccc(-n5c6ccccc6c6ccccc65)cc4)cc3)c3cccc4c3C3(c5ccccc5-c5ccccc53)c3ccccc3-4)c2)cc1]

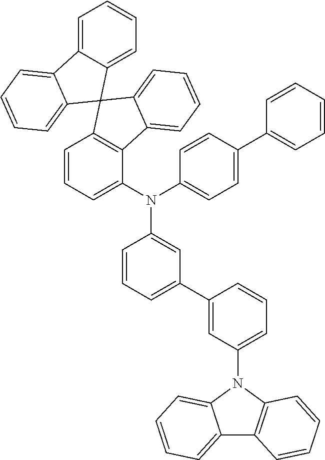 [SMILES: c1ccc(-c2ccc(N(c3cccc(-c4cccc(-n5c6ccccc6c6ccccc65)c4)c3)c3cccc4c3-c3ccccc3C43c4ccccc4-c4ccccc43)cc2)cc1]

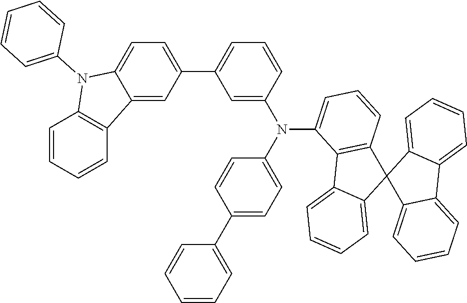 [SMILES: c1ccc(-c2ccc(N(c3cccc(-c4ccc5c(c4)c4ccccc4n5-c4ccccc4)c3)c3cccc4c3-c3ccccc3C43c4ccccc4-c4ccccc43)cc2)cc1]

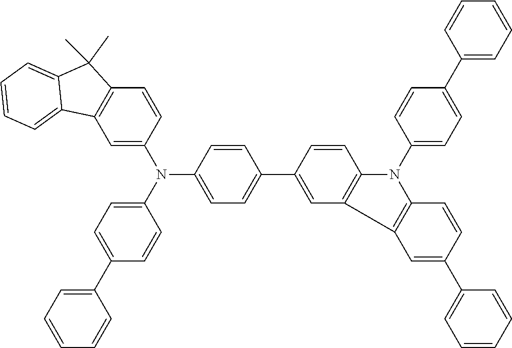 [SMILES: CC1(C)c2ccccc2-c2cc(N(c3ccc(-c4ccccc4)cc3)c3ccc(-c4ccc5c(c4)c4cc(-c6ccccc6)ccc4n5-c4ccc(-c5ccccc5)cc4)cc3)ccc21]

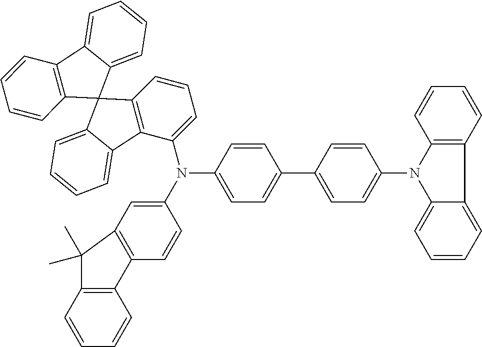 [SMILES: CC1(C)c2ccccc2-c2ccc(N(c3ccc(-c4ccc(-n5c6ccccc6c6ccccc65)cc4)cc3)c3cccc4c3-c3ccccc3C43c4ccccc4-c4ccccc43)cc21]

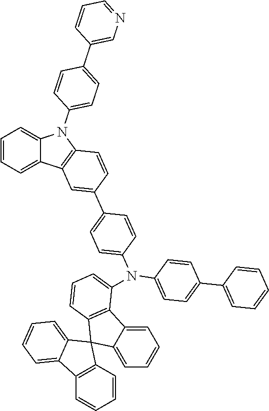 [SMILES: c1ccc(-c2ccc(N(c3ccc(-c4ccc5c(c4)c4ccccc4n5-c4ccc(-c5cccnc5)cc4)cc3)c3cccc4c3-c3ccccc3C43c4ccccc4-c4ccccc43)cc2)cc1]

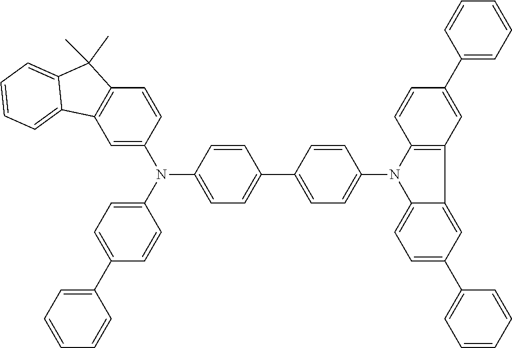 [SMILES: CC1(C)c2ccccc2-c2cc(N(c3ccc(-c4ccccc4)cc3)c3ccc(-c4ccc(-n5c6ccc(-c7ccccc7)cc6c6cc(-c7ccccc7)ccc65)cc4)cc3)ccc21]

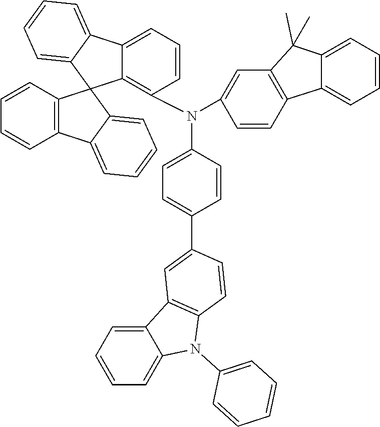 [SMILES: CC1(C)c2ccccc2-c2ccc(N(c3ccc(-c4ccc5c(c4)c4ccccc4n5-c4ccccc4)cc3)c3cccc4c3C3(c5ccccc5-c5ccccc53)c3ccccc3-4)cc21]

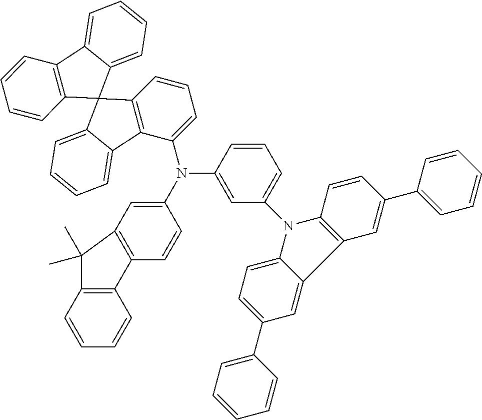 [SMILES: CC1(C)c2ccccc2-c2ccc(N(c3cccc(-n4c5ccc(-c6ccccc6)cc5c5cc(-c6ccccc6)ccc54)c3)c3cccc4c3-c3ccccc3C43c4ccccc4-c4ccccc43)cc21]

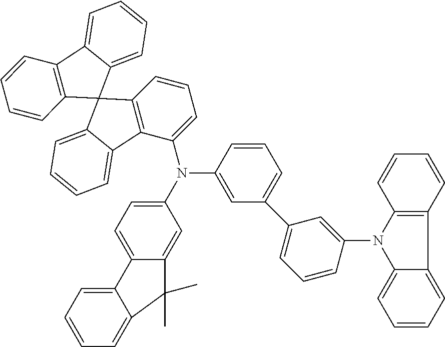 [SMILES: CC1(C)c2ccccc2-c2ccc(N(c3cccc(-c4cccc(-n5c6ccccc6c6ccccc65)c4)c3)c3cccc4c3-c3ccccc3C43c4ccccc4-c4ccccc43)cc21]

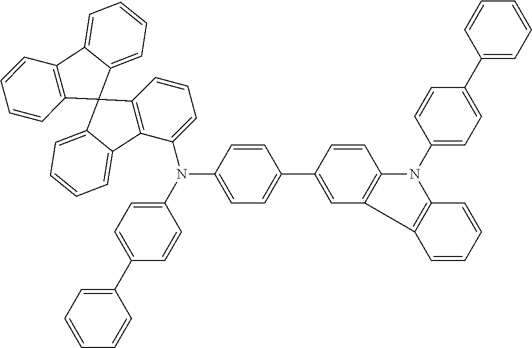 [SMILES: c1ccc(-c2ccc(N(c3ccc(-c4ccc5c(c4)c4ccccc4n5-c4ccc(-c5ccccc5)cc4)cc3)c3cccc4c3-c3ccccc3C43c4ccccc4-c4ccccc43)cc2)cc1]

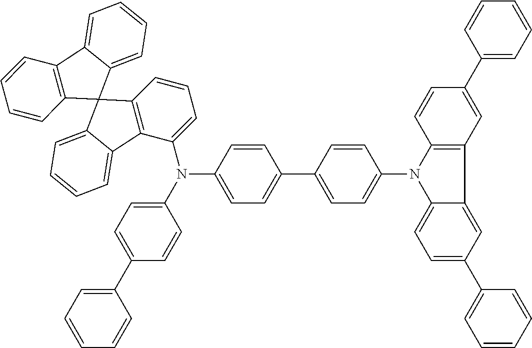 [SMILES: c1ccc(-c2ccc(N(c3ccc(-c4ccc(-n5c6ccc(-c7ccccc7)cc6c6cc(-c7ccccc7)ccc65)cc4)cc3)c3cccc4c3-c3ccccc3C43c4ccccc4-c4ccccc43)cc2)cc1]

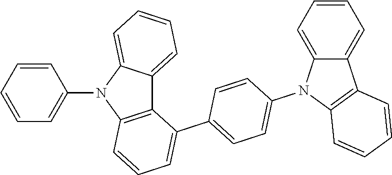 [SMILES: c1ccc(-n2c3ccccc3c3c(-c4ccc(-n5c6ccccc6c6ccccc65)cc4)cccc32)cc1]

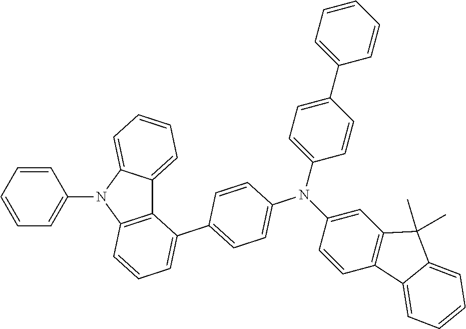 [SMILES: CC1(C)c2ccccc2-c2ccc(N(c3ccc(-c4ccccc4)cc3)c3ccc(-c4cccc5c4c4ccccc4n5-c4ccccc4)cc3)cc21]

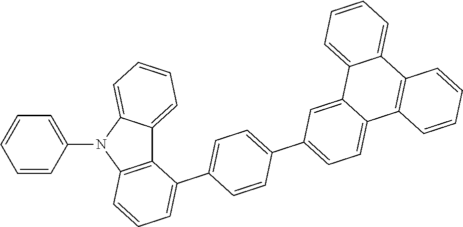 [SMILES: c1ccc(-n2c3ccccc3c3c(-c4ccc(-c5ccc6c7ccccc7c7ccccc7c6c5)cc4)cccc32)cc1]

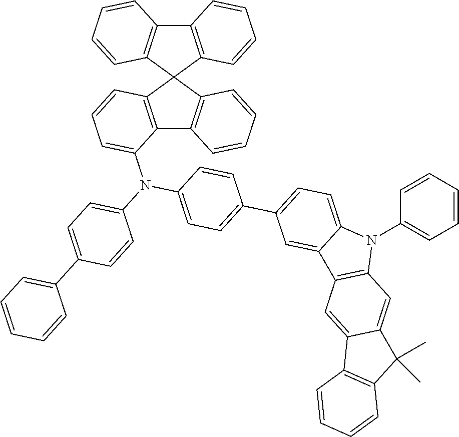 [SMILES: CC1(C)c2ccccc2-c2cc3c4cc(-c5ccc(N(c6ccc(-c7ccccc7)cc6)c6cccc7c6-c6ccccc6C76c7ccccc7-c7ccccc76)cc5)ccc4n(-c4ccccc4)c3cc21]

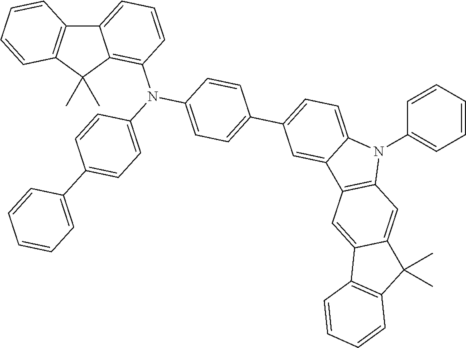 [SMILES: CC1(C)c2ccccc2-c2cc3c4cc(-c5ccc(N(c6ccc(-c7ccccc7)cc6)c6cccc7c6C(C)(C)c6ccccc6-7)cc5)ccc4n(-c4ccccc4)c3cc21]

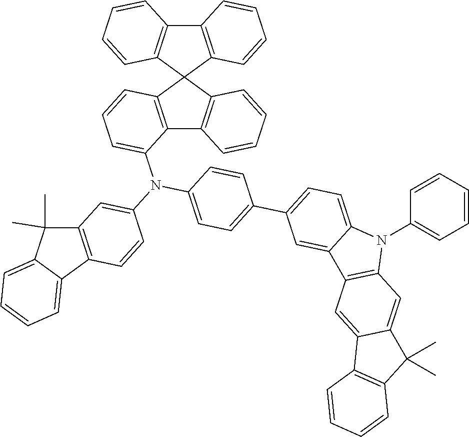 [SMILES: CC1(C)c2ccccc2-c2ccc(N(c3ccc(-c4ccc5c(c4)c4cc6c(cc4n5-c4ccccc4)C(C)(C)c4ccccc4-6)cc3)c3cccc4c3-c3ccccc3C43c4ccccc4-c4ccccc43)cc21]

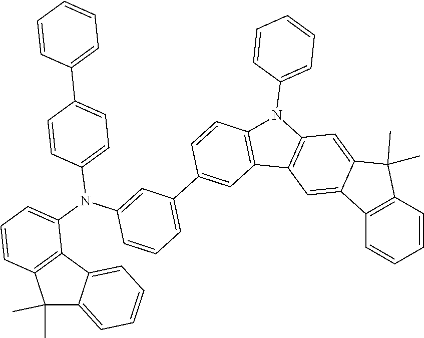 [SMILES: CC1(C)c2ccccc2-c2cc3c4cc(-c5cccc(N(c6ccc(-c7ccccc7)cc6)c6cccc7c6-c6ccccc6C7(C)C)c5)ccc4n(-c4ccccc4)c3cc21]

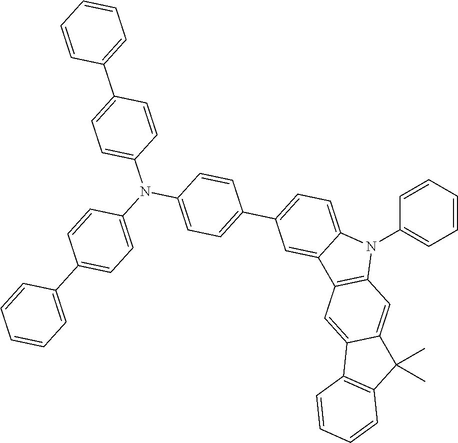 [SMILES: CC1(C)c2ccccc2-c2cc3c4cc(-c5ccc(N(c6ccc(-c7ccccc7)cc6)c6ccc(-c7ccccc7)cc6)cc5)ccc4n(-c4ccccc4)c3cc21]

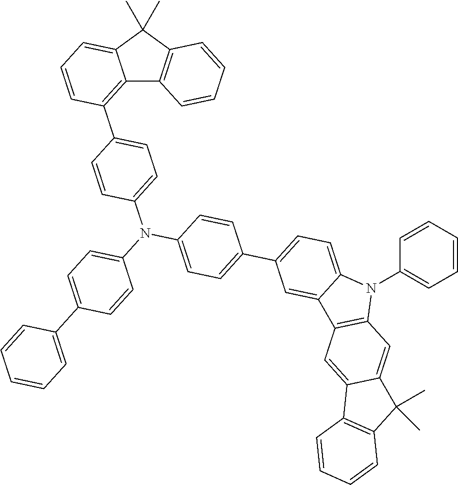 [SMILES: CC1(C)c2ccccc2-c2cc3c4cc(-c5ccc(N(c6ccc(-c7ccccc7)cc6)c6ccc(-c7cccc8c7-c7ccccc7C8(C)C)cc6)cc5)ccc4n(-c4ccccc4)c3cc21]

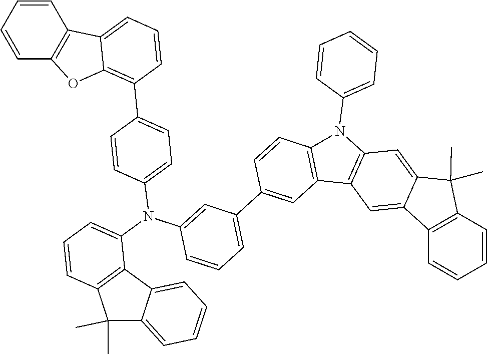 [SMILES: CC1(C)c2ccccc2-c2cc3c4cc(-c5cccc(N(c6ccc(-c7cccc8c7oc7ccccc78)cc6)c6cccc7c6-c6ccccc6C7(C)C)c5)ccc4n(-c4ccccc4)c3cc21]

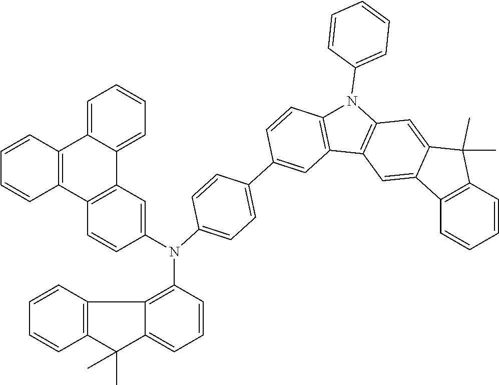 [SMILES: CC1(C)c2ccccc2-c2cc3c4cc(-c5ccc(N(c6ccc7c8ccccc8c8ccccc8c7c6)c6cccc7c6-c6ccccc6C7(C)C)cc5)ccc4n(-c4ccccc4)c3cc21]

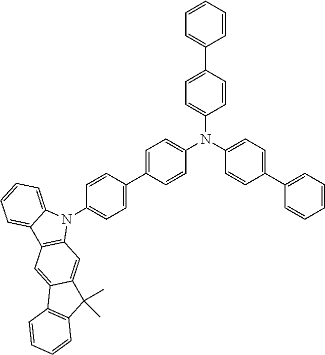 [SMILES: CC1(C)c2ccccc2-c2cc3c4ccccc4n(-c4ccc(-c5ccc(N(c6ccc(-c7ccccc7)cc6)c6ccc(-c7ccccc7)cc6)cc5)cc4)c3cc21]

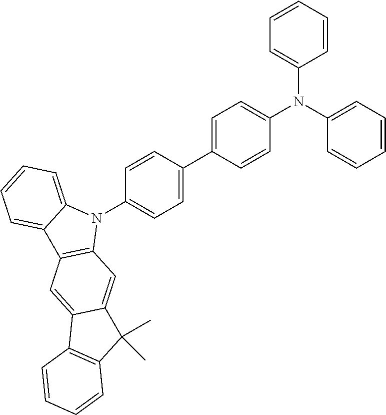 [SMILES: CC1(C)c2ccccc2-c2cc3c4ccccc4n(-c4ccc(-c5ccc(N(c6ccccc6)c6ccccc6)cc5)cc4)c3cc21]

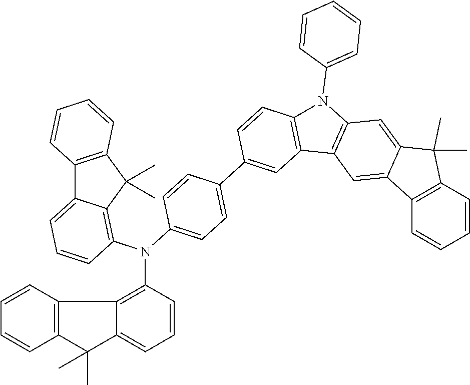 [SMILES: CC1(C)c2ccccc2-c2cc3c4cc(-c5ccc(N(c6cccc7c6-c6ccccc6C7(C)C)c6cccc7c6C(C)(C)c6ccccc6-7)cc5)ccc4n(-c4ccccc4)c3cc21]

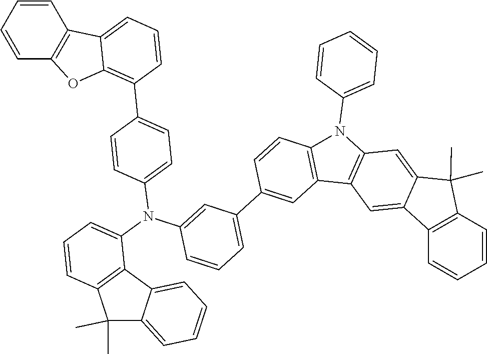 [SMILES: CC1(C)c2ccccc2-c2cc3c4cc(-c5cccc(N(c6ccc(-c7cccc8c7oc7ccccc78)cc6)c6cccc7c6-c6ccccc6C7(C)C)c5)ccc4n(-c4ccccc4)c3cc21]

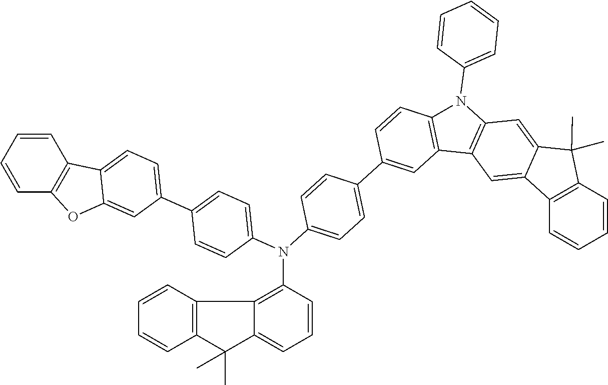 [SMILES: CC1(C)c2ccccc2-c2cc3c4cc(-c5ccc(N(c6ccc(-c7ccc8c(c7)oc7ccccc78)cc6)c6cccc7c6-c6ccccc6C7(C)C)cc5)ccc4n(-c4ccccc4)c3cc21]

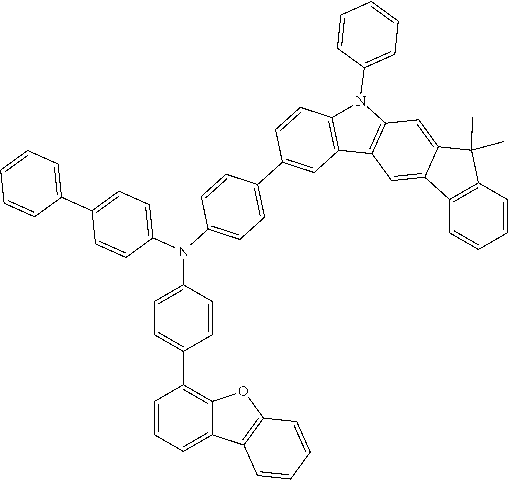 [SMILES: CC1(C)c2ccccc2-c2cc3c4cc(-c5ccc(N(c6ccc(-c7ccccc7)cc6)c6ccc(-c7cccc8c7oc7ccccc78)cc6)cc5)ccc4n(-c4ccccc4)c3cc21]

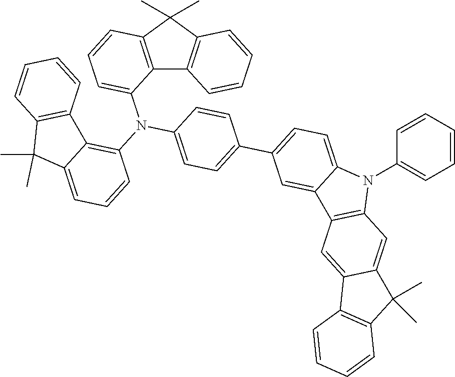 [SMILES: CC1(C)c2ccccc2-c2cc3c4cc(-c5ccc(N(c6cccc7c6-c6ccccc6C7(C)C)c6cccc7c6-c6ccccc6C7(C)C)cc5)ccc4n(-c4ccccc4)c3cc21]

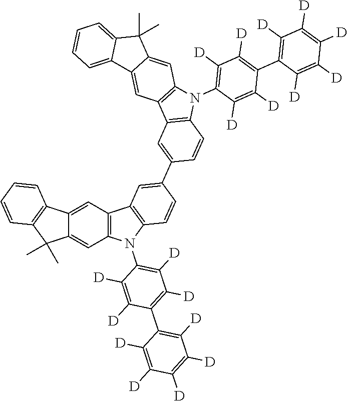 [SMILES: [2H]c1c([2H])c([2H])c(-c2c([2H])c([2H])c(-n3c4ccc(-c5ccc6c(c5)c5cc7c(cc5n6-c5c([2H])c([2H])c(-c6c([2H])c([2H])c([2H])c([2H])c6[2H])c([2H])c5[2H])C(C)(C)c5ccccc5-7)cc4c4cc5c(cc43)C(C)(C)c3ccccc3-5)c([2H])c2[2H])c([2H])c1[2H]]

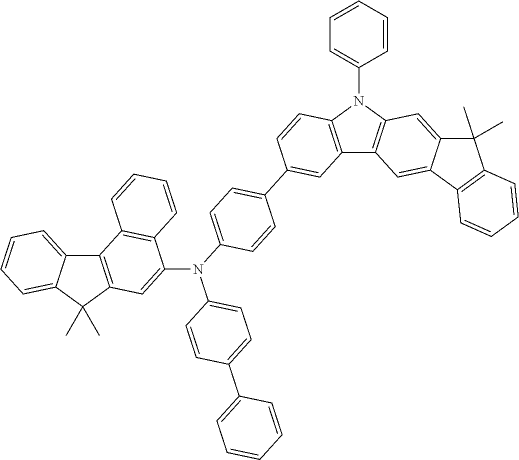 [SMILES: CC1(C)c2ccccc2-c2cc3c4cc(-c5ccc(N(c6ccc(-c7ccccc7)cc6)c6cc7c(c8ccccc68)-c6ccccc6C7(C)C)cc5)ccc4n(-c4ccccc4)c3cc21]

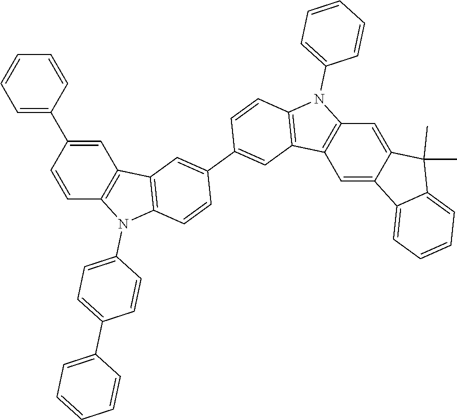 [SMILES: CC1(C)c2ccccc2-c2cc3c4cc(-c5ccc6c(c5)c5cc(-c7ccccc7)ccc5n6-c5ccc(-c6ccccc6)cc5)ccc4n(-c4ccccc4)c3cc21]

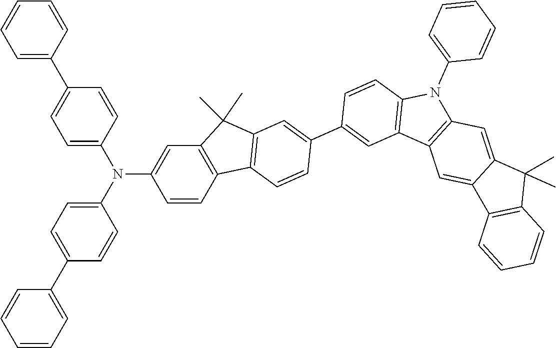 [SMILES: CC1(C)c2cc(-c3ccc4c(c3)c3cc5c(cc3n4-c3ccccc3)C(C)(C)c3ccccc3-5)ccc2-c2ccc(N(c3ccc(-c4ccccc4)cc3)c3ccc(-c4ccccc4)cc3)cc21]

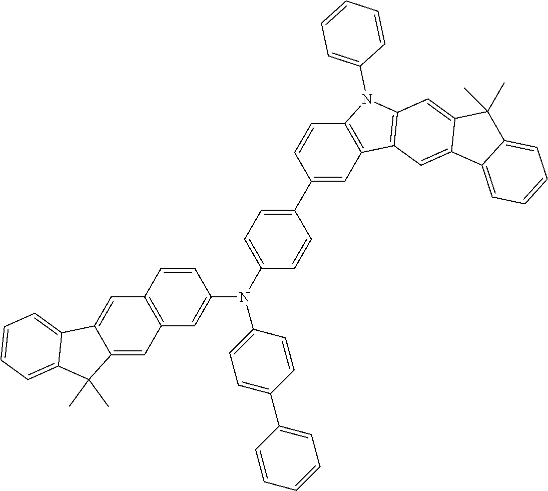 [SMILES: CC1(C)c2ccccc2-c2cc3ccc(N(c4ccc(-c5ccccc5)cc4)c4ccc(-c5ccc6c(c5)c5cc7c(cc5n6-c5ccccc5)C(C)(C)c5ccccc5-7)cc4)cc3cc21]

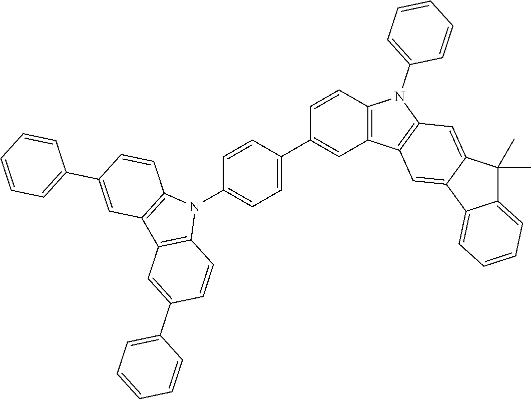 [SMILES: CC1(C)c2ccccc2-c2cc3c4cc(-c5ccc(-n6c7ccc(-c8ccccc8)cc7c7cc(-c8ccccc8)ccc76)cc5)ccc4n(-c4ccccc4)c3cc21]

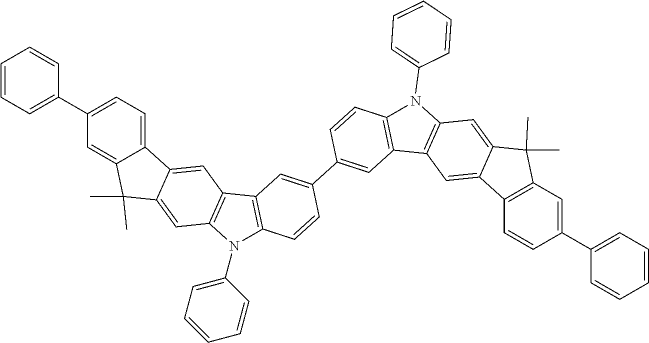 [SMILES: CC1(C)c2cc(-c3ccccc3)ccc2-c2cc3c4cc(-c5ccc6c(c5)c5cc7c(cc5n6-c5ccccc5)C(C)(C)c5cc(-c6ccccc6)ccc5-7)ccc4n(-c4ccccc4)c3cc21]

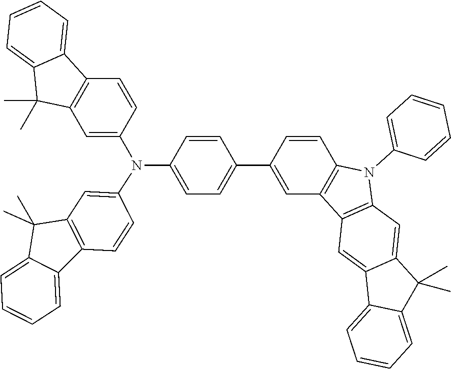 [SMILES: CC1(C)c2ccccc2-c2ccc(N(c3ccc(-c4ccc5c(c4)c4cc6c(cc4n5-c4ccccc4)C(C)(C)c4ccccc4-6)cc3)c3ccc4c(c3)C(C)(C)c3ccccc3-4)cc21]

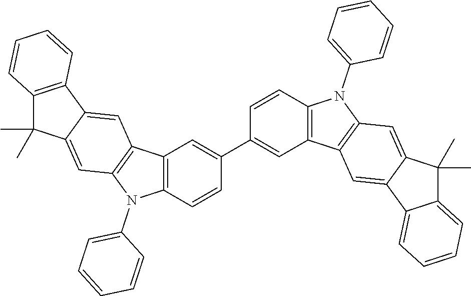

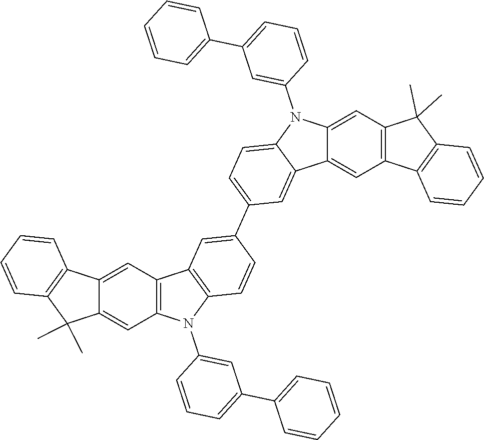 [SMILES: CC1(C)c2ccccc2-c2cc3c4cc(-c5ccc6c(c5)c5cc7c(cc5n6-c5cccc(-c6ccccc6)c5)C(C)(C)c5ccccc5-7)ccc4n(-c4cccc(-c5ccccc5)c4)c3cc21]

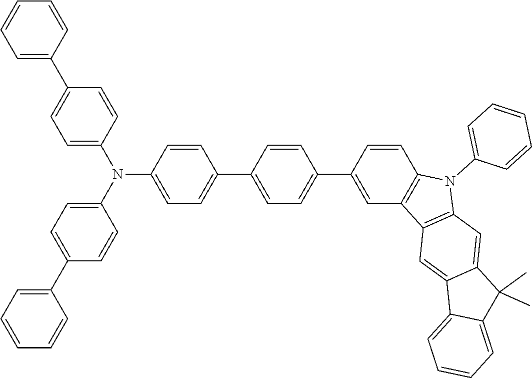 [SMILES: CC1(C)c2ccccc2-c2cc3c4cc(-c5ccc(-c6ccc(N(c7ccc(-c8ccccc8)cc7)c7ccc(-c8ccccc8)cc7)cc6)cc5)ccc4n(-c4ccccc4)c3cc21]

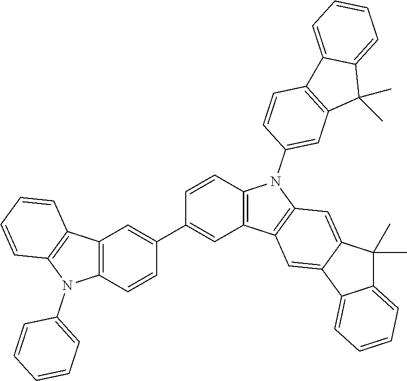 [SMILES: CC1(C)c2ccccc2-c2ccc(-n3c4ccc(-c5ccc6c(c5)c5ccccc5n6-c5ccccc5)cc4c4cc5c(cc43)C(C)(C)c3ccccc3-5)cc21]

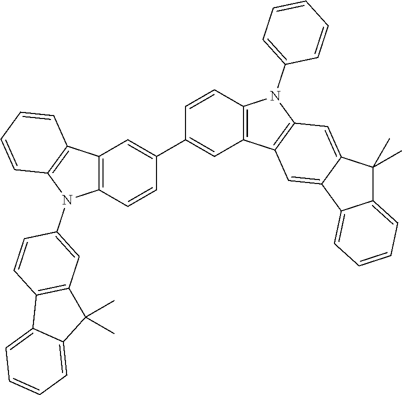 [SMILES: CC1(C)c2ccccc2-c2ccc(-n3c4ccccc4c4cc(-c5ccc6c(c5)c5cc7c(cc5n6-c5ccccc5)C(C)(C)c5ccccc5-7)ccc43)cc21]

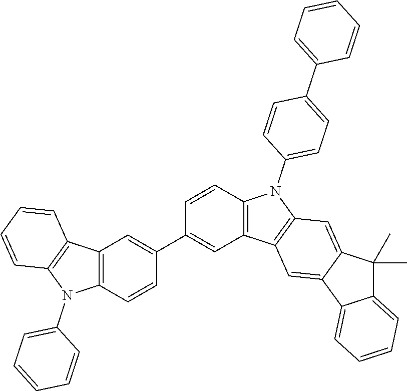 [SMILES: CC1(C)c2ccccc2-c2cc3c4cc(-c5ccc6c(c5)c5ccccc5n6-c5ccccc5)ccc4n(-c4ccc(-c5ccccc5)cc4)c3cc21]

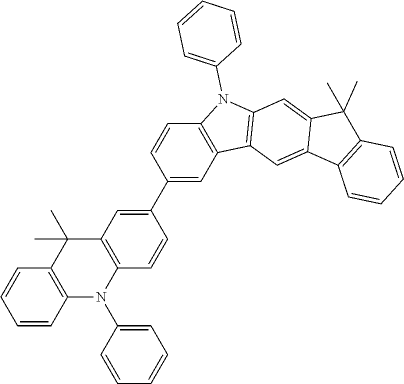 [SMILES: CC1(C)c2ccccc2-c2cc3c4cc(-c5ccc6c(c5)C(C)(C)c5ccccc5N6c5ccccc5)ccc4n(-c4ccccc4)c3cc21]

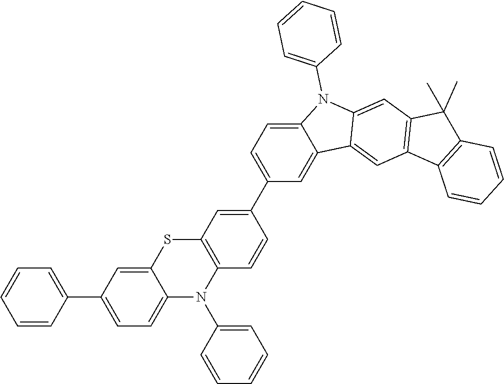 [SMILES: CC1(C)c2ccccc2-c2cc3c4cc(-c5ccc6c(c5)Sc5cc(-c7ccccc7)ccc5N6c5ccccc5)ccc4n(-c4ccccc4)c3cc21]

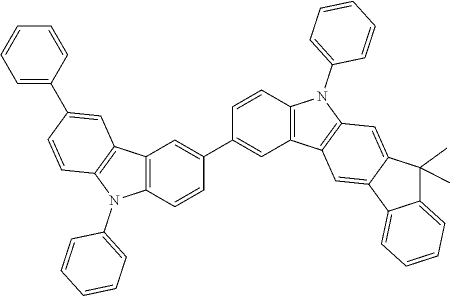 [SMILES: CC1(C)c2ccccc2-c2cc3c4cc(-c5ccc6c(c5)c5cc(-c7ccccc7)ccc5n6-c5ccccc5)ccc4n(-c4ccccc4)c3cc21]

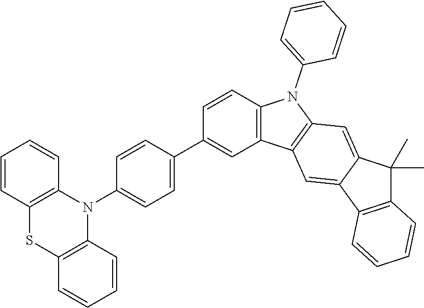 [SMILES: CC1(C)c2ccccc2-c2cc3c4cc(-c5ccc(N6c7ccccc7Sc7ccccc76)cc5)ccc4n(-c4ccccc4)c3cc21]

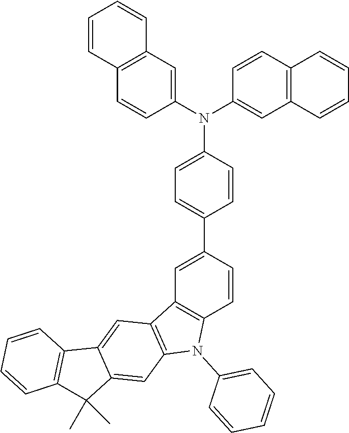 [SMILES: CC1(C)c2ccccc2-c2cc3c4cc(-c5ccc(N(c6ccc7ccccc7c6)c6ccc7ccccc7c6)cc5)ccc4n(-c4ccccc4)c3cc21]

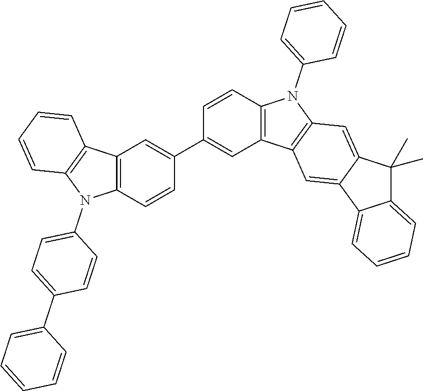 [SMILES: CC1(C)c2ccccc2-c2cc3c4cc(-c5ccc6c(c5)c5ccccc5n6-c5ccc(-c6ccccc6)cc5)ccc4n(-c4ccccc4)c3cc21]

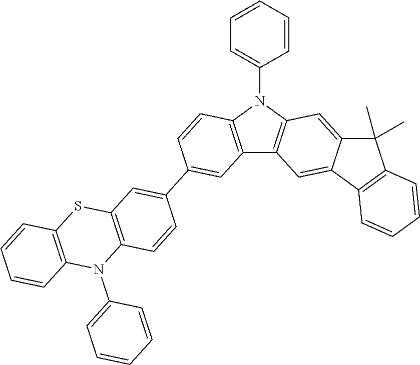 [SMILES: CC1(C)c2ccccc2-c2cc3c4cc(-c5ccc6c(c5)Sc5ccccc5N6c5ccccc5)ccc4n(-c4ccccc4)c3cc21]

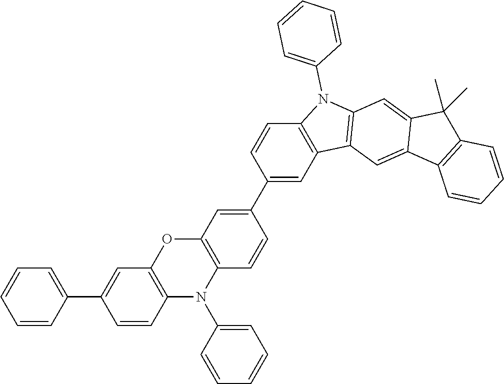 [SMILES: CC1(C)c2ccccc2-c2cc3c4cc(-c5ccc6c(c5)Oc5cc(-c7ccccc7)ccc5N6c5ccccc5)ccc4n(-c4ccccc4)c3cc21]

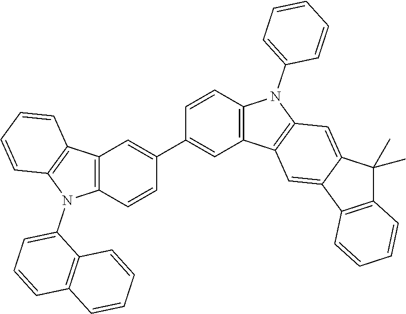 [SMILES: CC1(C)c2ccccc2-c2cc3c4cc(-c5ccc6c(c5)c5ccccc5n6-c5cccc6ccccc56)ccc4n(-c4ccccc4)c3cc21]

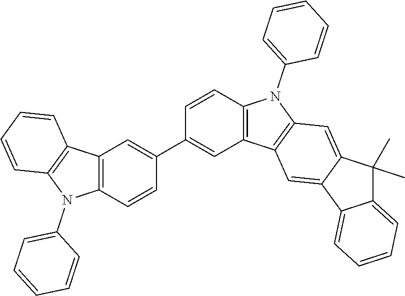 [SMILES: CC1(C)c2ccccc2-c2cc3c4cc(-c5ccc6c(c5)c5ccccc5n6-c5ccccc5)ccc4n(-c4ccccc4)c3cc21]

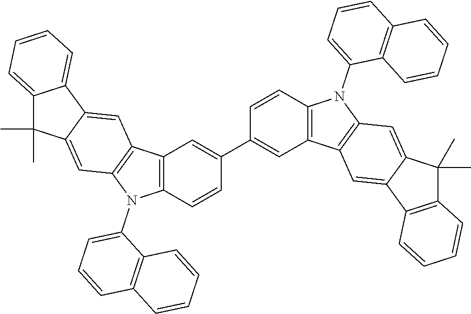

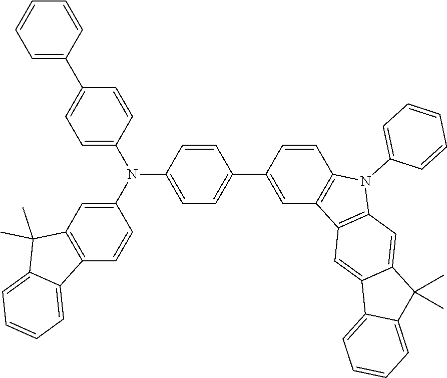 [SMILES: CC1(C)c2ccccc2-c2ccc(N(c3ccc(-c4ccccc4)cc3)c3ccc(-c4ccc5c(c4)c4cc6c(cc4n5-c4ccccc4)C(C)(C)c4ccccc4-6)cc3)cc21]

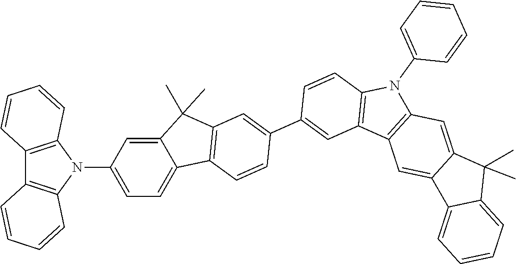 [SMILES: CC1(C)c2cc(-c3ccc4c(c3)c3cc5c(cc3n4-c3ccccc3)C(C)(C)c3ccccc3-5)ccc2-c2ccc(-n3c4ccccc4c4ccccc43)cc21]

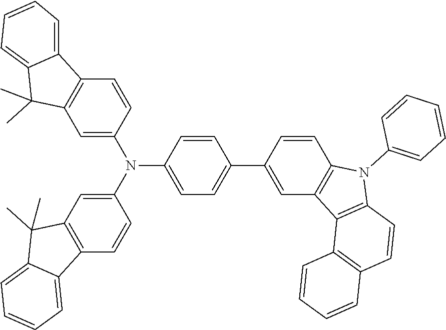 [SMILES: CC1(C)c2ccccc2-c2ccc(N(c3ccc(-c4ccc5c(c4)c4c6ccccc6ccc4n5-c4ccccc4)cc3)c3ccc4c(c3)C(C)(C)c3ccccc3-4)cc21]

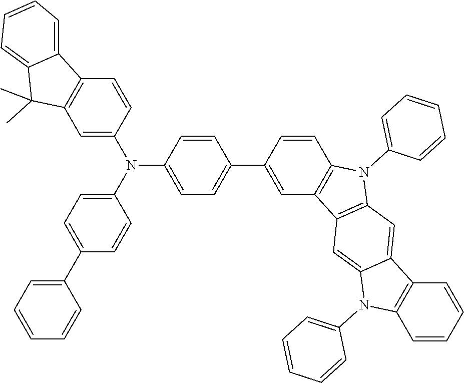 [SMILES: CC1(C)c2ccccc2-c2ccc(N(c3ccc(-c4ccccc4)cc3)c3ccc(-c4ccc5c(c4)c4cc6c(cc4n5-c4ccccc4)c4ccccc4n6-c4ccccc4)cc3)cc21]

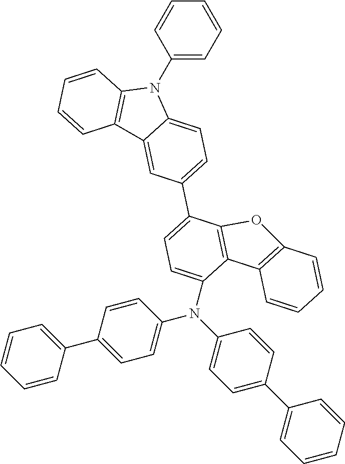 [SMILES: c1ccc(-c2ccc(N(c3ccc(-c4ccccc4)cc3)c3ccc(-c4ccc5c(c4)c4ccccc4n5-c4ccccc4)c4oc5ccccc5c34)cc2)cc1]

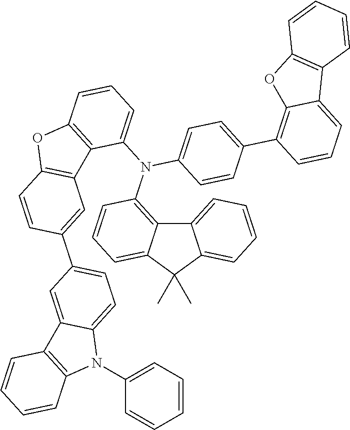 [SMILES: CC1(C)c2ccccc2-c2c(N(c3ccc(-c4cccc5c4oc4ccccc45)cc3)c3cccc4oc5ccc(-c6ccc7c(c6)c6ccccc6n7-c6ccccc6)cc5c34)cccc21]

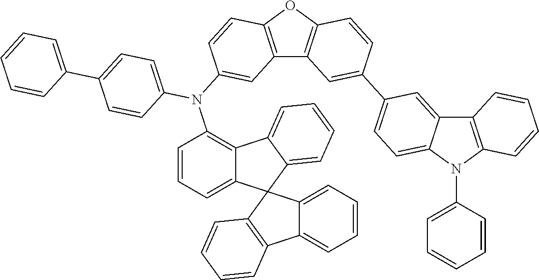 [SMILES: c1ccc(-c2ccc(N(c3ccc4oc5ccc(-c6ccc7c(c6)c6ccccc6n7-c6ccccc6)cc5c4c3)c3cccc4c3-c3ccccc3C43c4ccccc4-c4ccccc43)cc2)cc1]

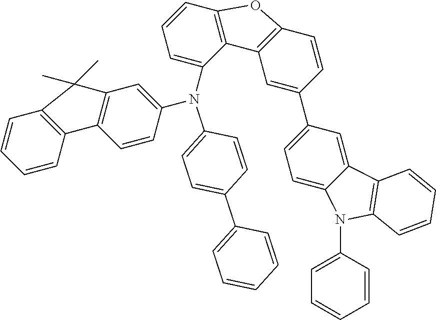 [SMILES: CC1(C)c2ccccc2-c2ccc(N(c3ccc(-c4ccccc4)cc3)c3cccc4oc5ccc(-c6ccc7c(c6)c6ccccc6n7-c6ccccc6)cc5c34)cc21]

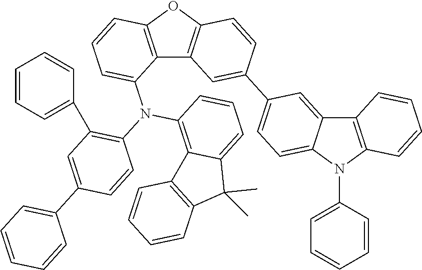 [SMILES: CC1(C)c2ccccc2-c2c(N(c3ccc(-c4ccccc4)cc3-c3ccccc3)c3cccc4oc5ccc(-c6ccc7c(c6)c6ccccc6n7-c6ccccc6)cc5c34)cccc21]

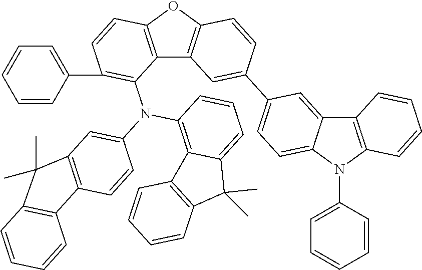 [SMILES: CC1(C)c2ccccc2-c2ccc(N(c3cccc4c3-c3ccccc3C4(C)C)c3c(-c4ccccc4)ccc4oc5ccc(-c6ccc7c(c6)c6ccccc6n7-c6ccccc6)cc5c34)cc21]

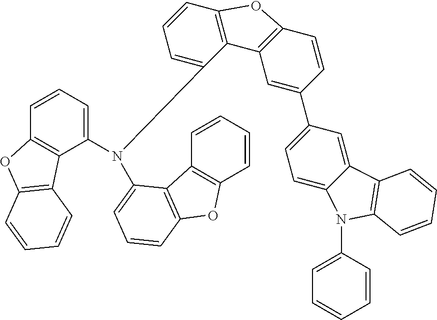 [SMILES: c1ccc(-n2c3ccccc3c3cc(-c4ccc5oc6cccc(N(c7cccc8oc9ccccc9c78)c7cccc8oc9ccccc9c78)c6c5c4)ccc32)cc1]

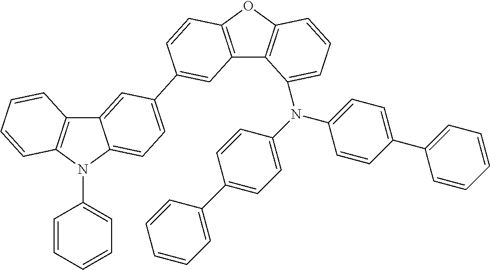 [SMILES: c1ccc(-c2ccc(N(c3ccc(-c4ccccc4)cc3)c3cccc4oc5ccc(-c6ccc7c(c6)c6ccccc6n7-c6ccccc6)cc5c34)cc2)cc1]

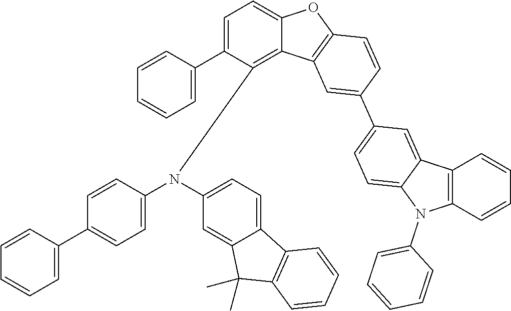 [SMILES: CC1(C)c2ccccc2-c2ccc(N(c3ccc(-c4ccccc4)cc3)c3c(-c4ccccc4)ccc4oc5ccc(-c6ccc7c(c6)c6ccccc6n7-c6ccccc6)cc5c34)cc21]

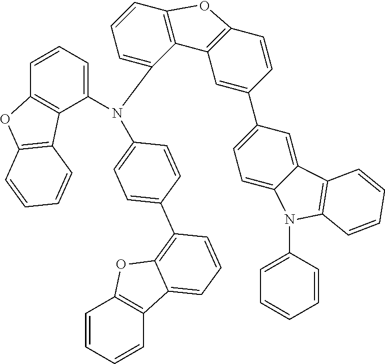 [SMILES: c1ccc(-n2c3ccccc3c3cc(-c4ccc5oc6cccc(N(c7ccc(-c8cccc9c8oc8ccccc89)cc7)c7cccc8oc9ccccc9c78)c6c5c4)ccc32)cc1]

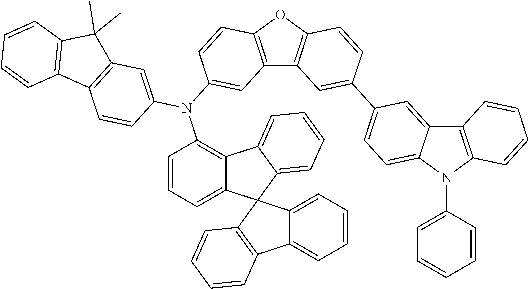 [SMILES: CC1(C)c2ccccc2-c2ccc(N(c3ccc4oc5ccc(-c6ccc7c(c6)c6ccccc6n7-c6ccccc6)cc5c4c3)c3cccc4c3-c3ccccc3C43c4ccccc4-c4ccccc43)cc21]

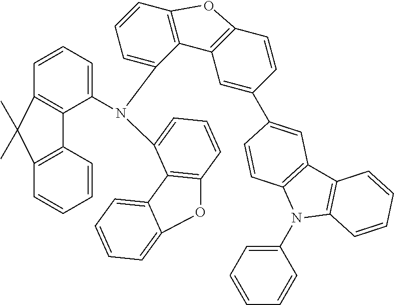 [SMILES: CC1(C)c2ccccc2-c2c(N(c3cccc4oc5ccccc5c34)c3cccc4oc5ccc(-c6ccc7c(c6)c6ccccc6n7-c6ccccc6)cc5c34)cccc21]

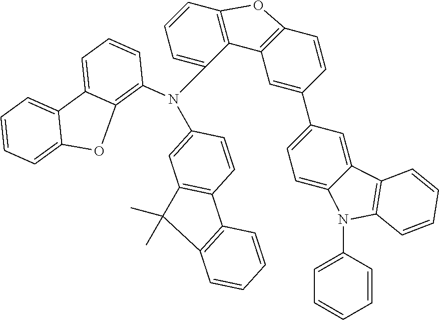 [SMILES: CC1(C)c2ccccc2-c2ccc(N(c3cccc4c3oc3ccccc34)c3cccc4oc5ccc(-c6ccc7c(c6)c6ccccc6n7-c6ccccc6)cc5c34)cc21]

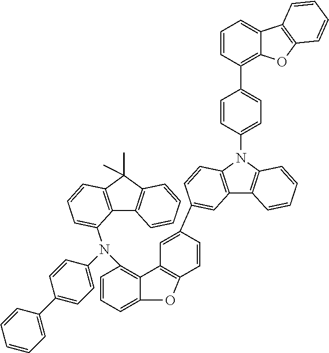 [SMILES: CC1(C)c2ccccc2-c2c(N(c3ccc(-c4ccccc4)cc3)c3cccc4oc5ccc(-c6ccc7c(c6)c6ccccc6n7-c6ccc(-c7cccc8c7oc7ccccc78)cc6)cc5c34)cccc21]

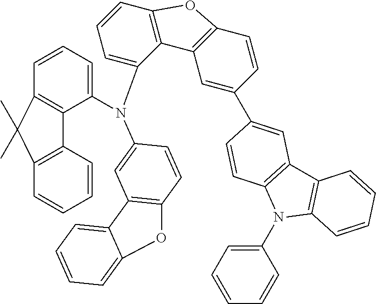 [SMILES: CC1(C)c2ccccc2-c2c(N(c3ccc4oc5ccccc5c4c3)c3cccc4oc5ccc(-c6ccc7c(c6)c6ccccc6n7-c6ccccc6)cc5c34)cccc21]

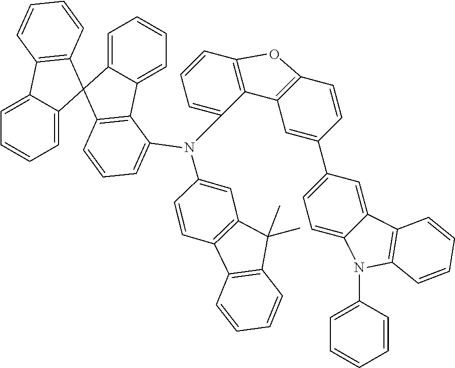 [SMILES: CC1(C)c2ccccc2-c2ccc(N(c3cccc4c3-c3ccccc3C43c4ccccc4-c4ccccc43)c3cccc4oc5ccc(-c6ccc7c(c6)c6ccccc6n7-c6ccccc6)cc5c34)cc21]

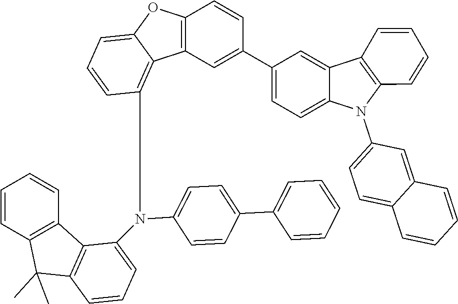 [SMILES: CC1(C)c2ccccc2-c2c(N(c3ccc(-c4ccccc4)cc3)c3cccc4oc5ccc(-c6ccc7c(c6)c6ccccc6n7-c6ccc7ccccc7c6)cc5c34)cccc21]

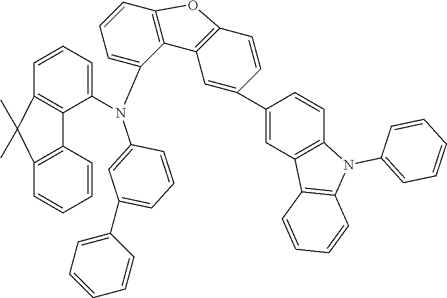 [SMILES: CC1(C)c2ccccc2-c2c(N(c3cccc(-c4ccccc4)c3)c3cccc4oc5ccc(-c6ccc7c(c6)c6ccccc6n7-c6ccccc6)cc5c34)cccc21]

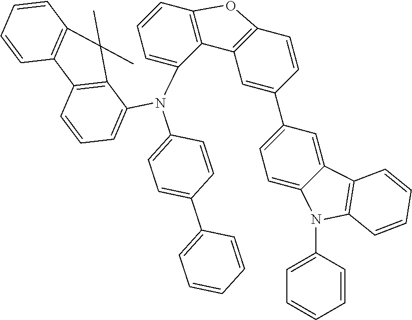 [SMILES: CC1(C)c2ccccc2-c2cccc(N(c3ccc(-c4ccccc4)cc3)c3cccc4oc5ccc(-c6ccc7c(c6)c6ccccc6n7-c6ccccc6)cc5c34)c21]

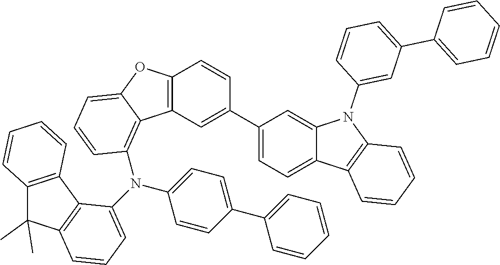 [SMILES: CC1(C)c2ccccc2-c2c(N(c3ccc(-c4ccccc4)cc3)c3cccc4oc5ccc(-c6ccc7c8ccccc8n(-c8cccc(-c9ccccc9)c8)c7c6)cc5c34)cccc21]

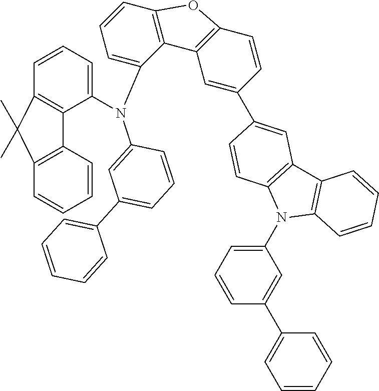 [SMILES: CC1(C)c2ccccc2-c2c(N(c3cccc(-c4ccccc4)c3)c3cccc4oc5ccc(-c6ccc7c(c6)c6ccccc6n7-c6cccc(-c7ccccc7)c6)cc5c34)cccc21]

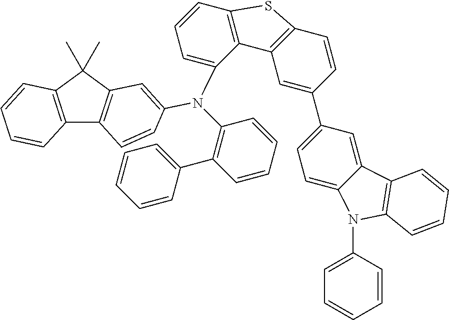 [SMILES: CC1(C)c2ccccc2-c2ccc(N(c3ccccc3-c3ccccc3)c3cccc4sc5ccc(-c6ccc7c(c6)c6ccccc6n7-c6ccccc6)cc5c34)cc21]

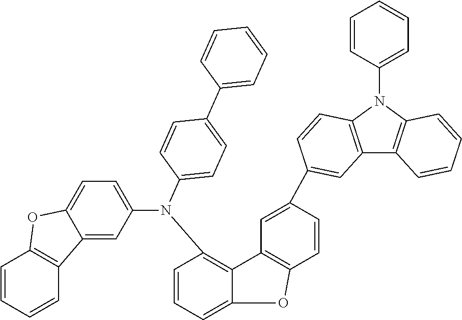 [SMILES: c1ccc(-c2ccc(N(c3ccc4oc5ccccc5c4c3)c3cccc4oc5ccc(-c6ccc7c(c6)c6ccccc6n7-c6ccccc6)cc5c34)cc2)cc1]

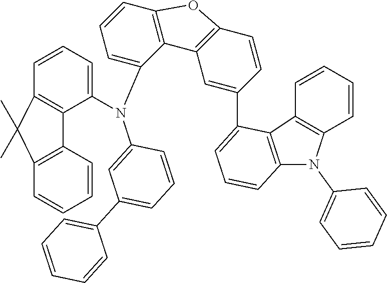 [SMILES: CC1(C)c2ccccc2-c2c(N(c3cccc(-c4ccccc4)c3)c3cccc4oc5ccc(-c6cccc7c6c6ccccc6n7-c6ccccc6)cc5c34)cccc21]

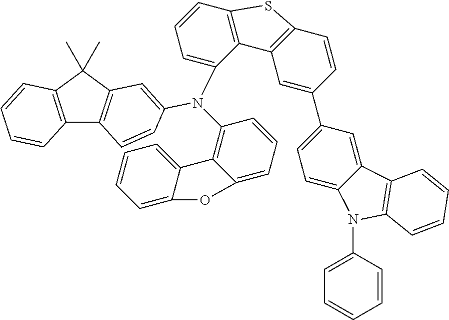 [SMILES: CC1(C)c2ccccc2-c2ccc(N(c3cccc4oc5ccccc5c34)c3cccc4sc5ccc(-c6ccc7c(c6)c6ccccc6n7-c6ccccc6)cc5c34)cc21]

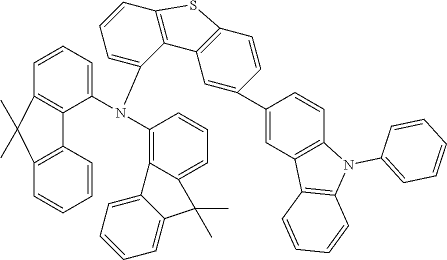 [SMILES: CC1(C)c2ccccc2-c2c(N(c3cccc4c3-c3ccccc3C4(C)C)c3cccc4sc5ccc(-c6ccc7c(c6)c6ccccc6n7-c6ccccc6)cc5c34)cccc21]

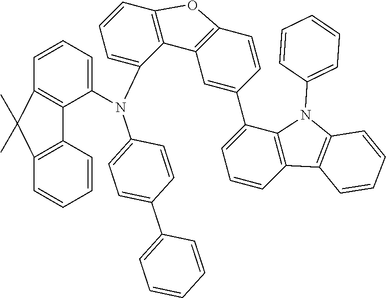 [SMILES: CC1(C)c2ccccc2-c2c(N(c3ccc(-c4ccccc4)cc3)c3cccc4oc5ccc(-c6cccc7c8ccccc8n(-c8ccccc8)c67)cc5c34)cccc21]

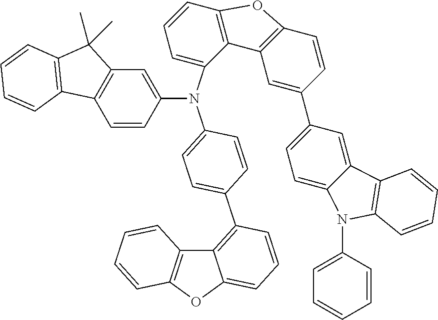 [SMILES: CC1(C)c2ccccc2-c2ccc(N(c3ccc(-c4cccc5oc6ccccc6c45)cc3)c3cccc4oc5ccc(-c6ccc7c(c6)c6ccccc6n7-c6ccccc6)cc5c34)cc21]

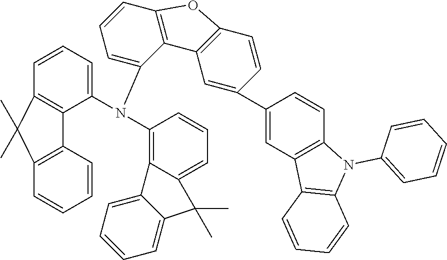 [SMILES: CC1(C)c2ccccc2-c2c(N(c3cccc4c3-c3ccccc3C4(C)C)c3cccc4oc5ccc(-c6ccc7c(c6)c6ccccc6n7-c6ccccc6)cc5c34)cccc21]

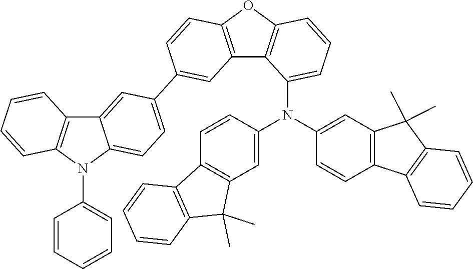 [SMILES: CC1(C)c2ccccc2-c2ccc(N(c3ccc4c(c3)C(C)(C)c3ccccc3-4)c3cccc4oc5ccc(-c6ccc7c(c6)c6ccccc6n7-c6ccccc6)cc5c34)cc21]

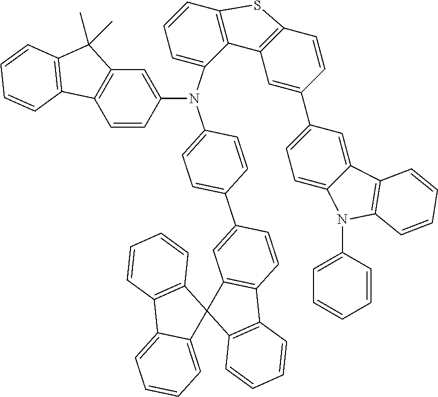 [SMILES: CC1(C)c2ccccc2-c2ccc(N(c3ccc(-c4ccc5c(c4)C4(c6ccccc6-c6ccccc64)c4ccccc4-5)cc3)c3cccc4sc5ccc(-c6ccc7c(c6)c6ccccc6n7-c6ccccc6)cc5c34)cc21]

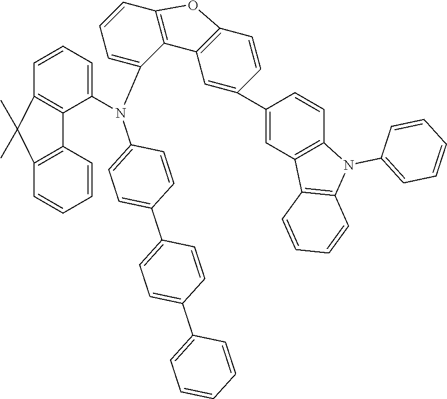 [SMILES: CC1(C)c2ccccc2-c2c(N(c3ccc(-c4ccc(-c5ccccc5)cc4)cc3)c3cccc4oc5ccc(-c6ccc7c(c6)c6ccccc6n7-c6ccccc6)cc5c34)cccc21]

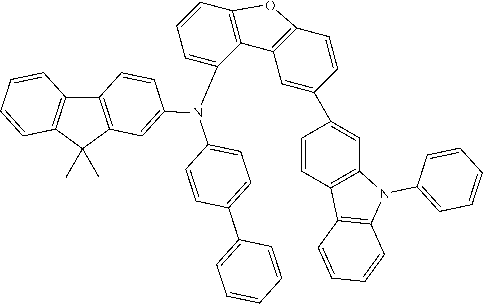 [SMILES: CC1(C)c2ccccc2-c2ccc(N(c3ccc(-c4ccccc4)cc3)c3cccc4oc5ccc(-c6ccc7c8ccccc8n(-c8ccccc8)c7c6)cc5c34)cc21]

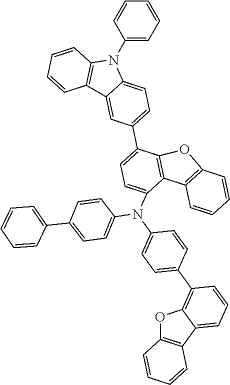 [SMILES: c1ccc(-c2ccc(N(c3ccc(-c4cccc5c4oc4ccccc45)cc3)c3ccc(-c4ccc5c(c4)c4ccccc4n5-c4ccccc4)c4oc5ccccc5c34)cc2)cc1]

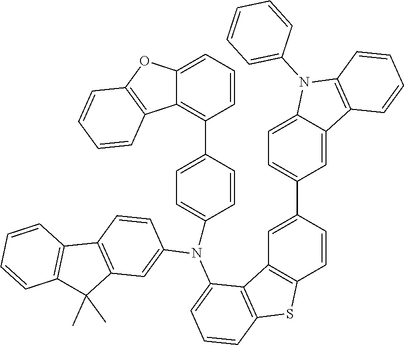 [SMILES: CC1(C)c2ccccc2-c2ccc(N(c3ccc(-c4cccc5oc6ccccc6c45)cc3)c3cccc4sc5ccc(-c6ccc7c(c6)c6ccccc6n7-c6ccccc6)cc5c34)cc21]

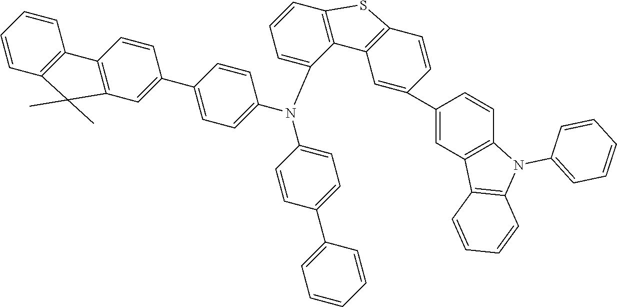 [SMILES: CC1(C)c2ccccc2-c2ccc(-c3ccc(N(c4ccc(-c5ccccc5)cc4)c4cccc5sc6ccc(-c7ccc8c(c7)c7ccccc7n8-c7ccccc7)cc6c45)cc3)cc21]

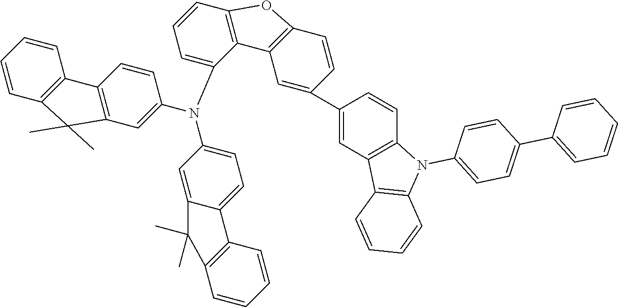 [SMILES: CC1(C)c2ccccc2-c2ccc(N(c3ccc4c(c3)C(C)(C)c3ccccc3-4)c3cccc4oc5ccc(-c6ccc7c(c6)c6ccccc6n7-c6ccc(-c7ccccc7)cc6)cc5c34)cc21]

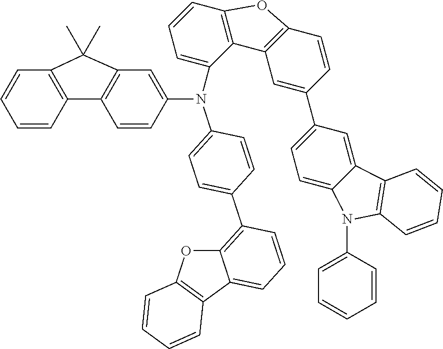 [SMILES: CC1(C)c2ccccc2-c2ccc(N(c3ccc(-c4cccc5c4oc4ccccc45)cc3)c3cccc4oc5ccc(-c6ccc7c(c6)c6ccccc6n7-c6ccccc6)cc5c34)cc21]

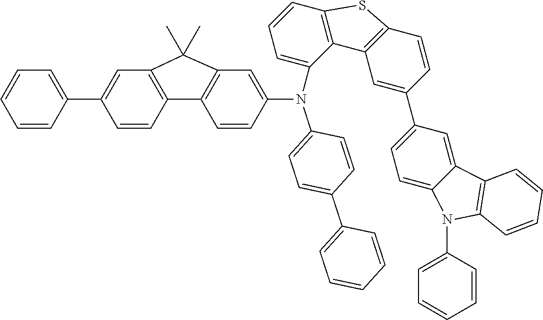 [SMILES: CC1(C)c2cc(-c3ccccc3)ccc2-c2ccc(N(c3ccc(-c4ccccc4)cc3)c3cccc4sc5ccc(-c6ccc7c(c6)c6ccccc6n7-c6ccccc6)cc5c34)cc21]

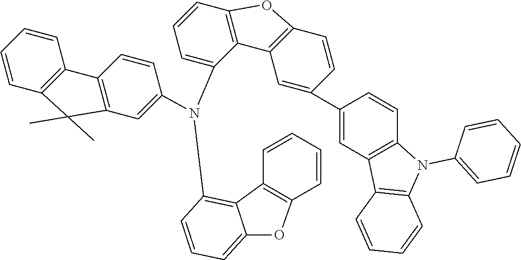 [SMILES: CC1(C)c2ccccc2-c2ccc(N(c3cccc4oc5ccccc5c34)c3cccc4oc5ccc(-c6ccc7c(c6)c6ccccc6n7-c6ccccc6)cc5c34)cc21]

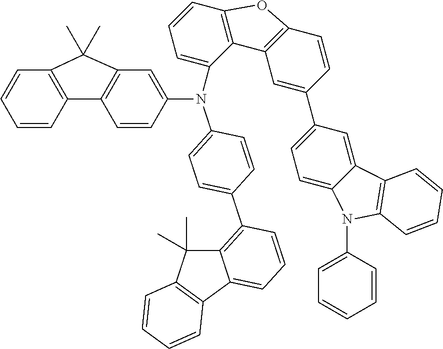 [SMILES: CC1(C)c2ccccc2-c2ccc(N(c3ccc(-c4cccc5c4C(C)(C)c4ccccc4-5)cc3)c3cccc4oc5ccc(-c6ccc7c(c6)c6ccccc6n7-c6ccccc6)cc5c34)cc21]

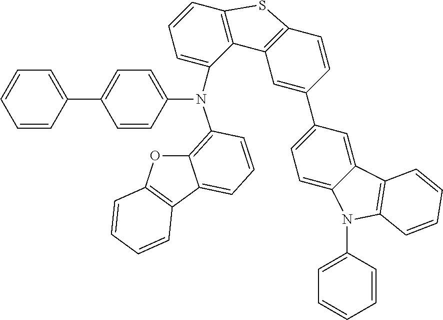 [SMILES: c1ccc(-c2ccc(N(c3cccc4c3oc3ccccc34)c3cccc4sc5ccc(-c6ccc7c(c6)c6ccccc6n7-c6ccccc6)cc5c34)cc2)cc1]

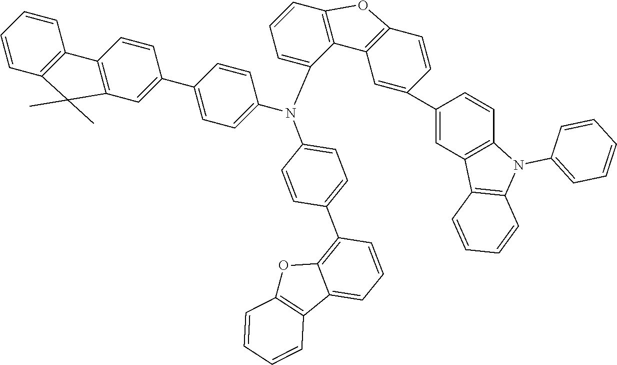 [SMILES: CC1(C)c2ccccc2-c2ccc(-c3ccc(N(c4ccc(-c5cccc6c5oc5ccccc56)cc4)c4cccc5oc6ccc(-c7ccc8c(c7)c7ccccc7n8-c7ccccc7)cc6c45)cc3)cc21]

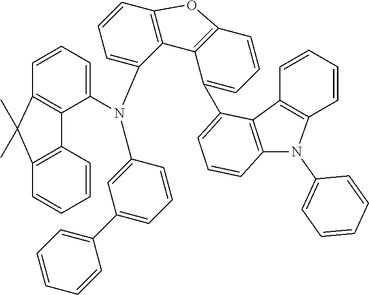 [SMILES: CC1(C)c2ccccc2-c2c(N(c3cccc(-c4ccccc4)c3)c3cccc4oc5cccc(-c6cccc7c6c6ccccc6n7-c6ccccc6)c5c34)cccc21]

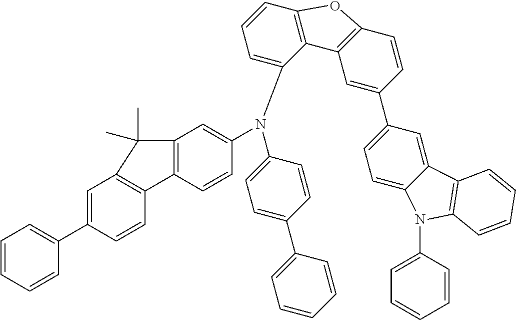 [SMILES: CC1(C)c2cc(-c3ccccc3)ccc2-c2ccc(N(c3ccc(-c4ccccc4)cc3)c3cccc4oc5ccc(-c6ccc7c(c6)c6ccccc6n7-c6ccccc6)cc5c34)cc21]

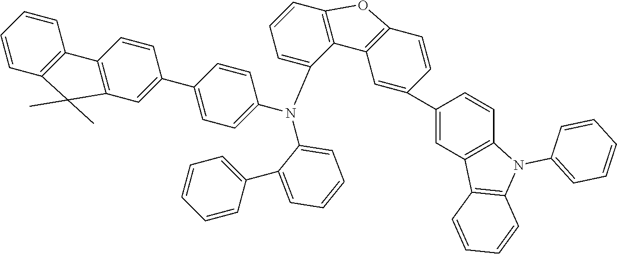 [SMILES: CC1(C)c2ccccc2-c2ccc(-c3ccc(N(c4ccccc4-c4ccccc4)c4cccc5oc6ccc(-c7ccc8c(c7)c7ccccc7n8-c7ccccc7)cc6c45)cc3)cc21]

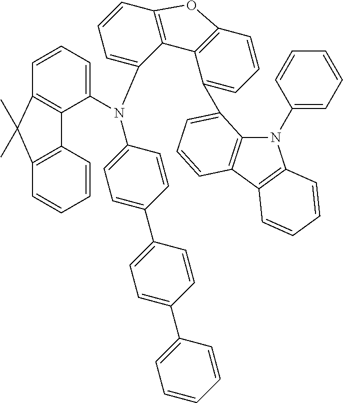 [SMILES: CC1(C)c2ccccc2-c2c(N(c3ccc(-c4ccc(-c5ccccc5)cc4)cc3)c3cccc4oc5cccc(-c6cccc7c8ccccc8n(-c8ccccc8)c67)c5c34)cccc21]

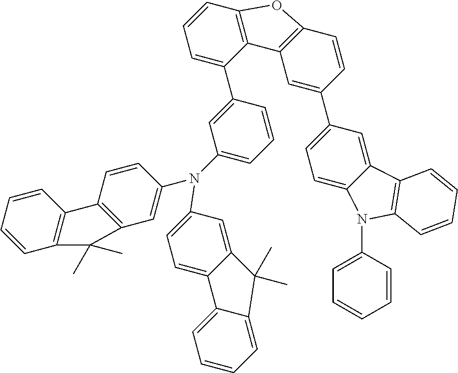 [SMILES: CC1(C)c2ccccc2-c2ccc(N(c3cccc(-c4cccc5oc6ccc(-c7ccc8c(c7)c7ccccc7n8-c7ccccc7)cc6c45)c3)c3ccc4c(c3)C(C)(C)c3ccccc3-4)cc21]

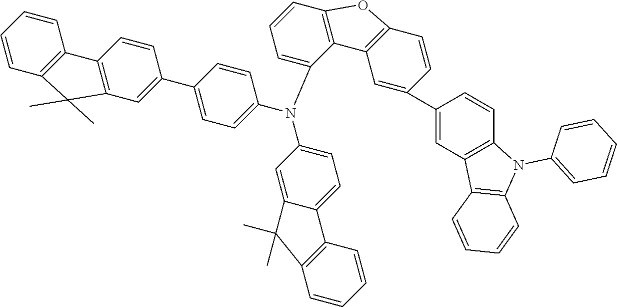 [SMILES: CC1(C)c2ccccc2-c2ccc(-c3ccc(N(c4ccc5c(c4)C(C)(C)c4ccccc4-5)c4cccc5oc6ccc(-c7ccc8c(c7)c7ccccc7n8-c7ccccc7)cc6c45)cc3)cc21]

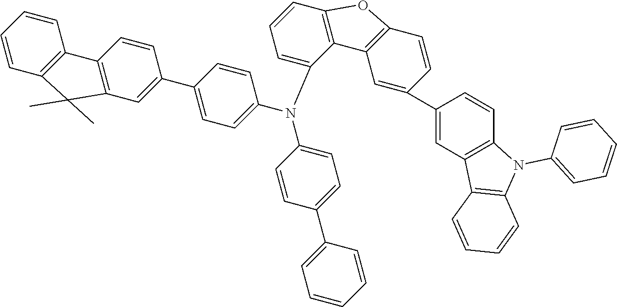 [SMILES: CC1(C)c2ccccc2-c2ccc(-c3ccc(N(c4ccc(-c5ccccc5)cc4)c4cccc5oc6ccc(-c7ccc8c(c7)c7ccccc7n8-c7ccccc7)cc6c45)cc3)cc21]

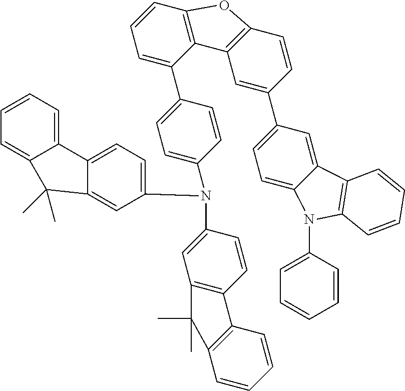 [SMILES: CC1(C)c2ccccc2-c2ccc(N(c3ccc(-c4cccc5oc6ccc(-c7ccc8c(c7)c7ccccc7n8-c7ccccc7)cc6c45)cc3)c3ccc4c(c3)C(C)(C)c3ccccc3-4)cc21]

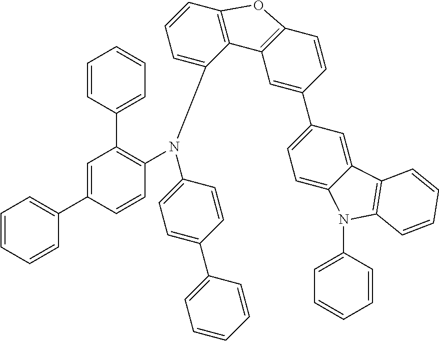 [SMILES: c1ccc(-c2ccc(N(c3ccc(-c4ccccc4)cc3-c3ccccc3)c3cccc4oc5ccc(-c6ccc7c(c6)c6ccccc6n7-c6ccccc6)cc5c34)cc2)cc1]

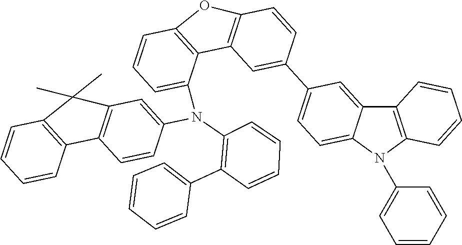 [SMILES: CC1(C)c2ccccc2-c2ccc(N(c3ccccc3-c3ccccc3)c3cccc4oc5ccc(-c6ccc7c(c6)c6ccccc6n7-c6ccccc6)cc5c34)cc21]

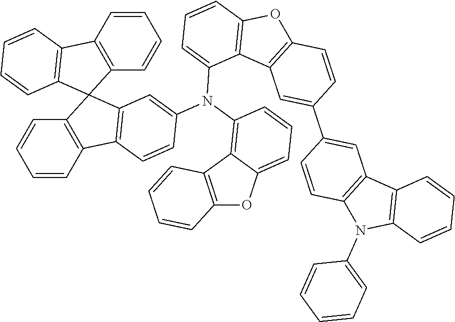 [SMILES: c1ccc(-n2c3ccccc3c3cc(-c4ccc5oc6cccc(N(c7ccc8c(c7)C7(c9ccccc9-c9ccccc97)c7ccccc7-8)c7cccc8oc9ccccc9c78)c6c5c4)ccc32)cc1]

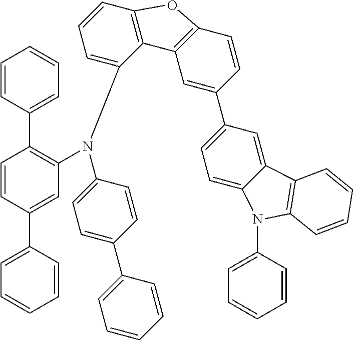 [SMILES: c1ccc(-c2ccc(N(c3cc(-c4ccccc4)ccc3-c3ccccc3)c3cccc4oc5ccc(-c6ccc7c(c6)c6ccccc6n7-c6ccccc6)cc5c34)cc2)cc1]

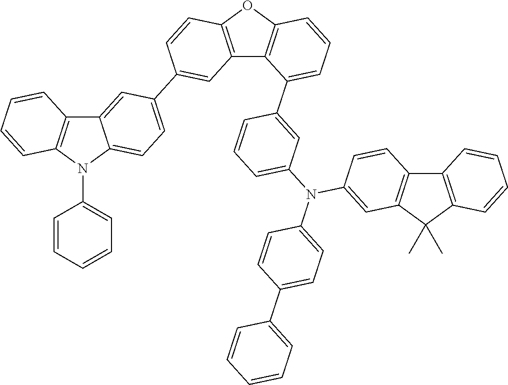 [SMILES: CC1(C)c2ccccc2-c2ccc(N(c3ccc(-c4ccccc4)cc3)c3cccc(-c4cccc5oc6ccc(-c7ccc8c(c7)c7ccccc7n8-c7ccccc7)cc6c45)c3)cc21]

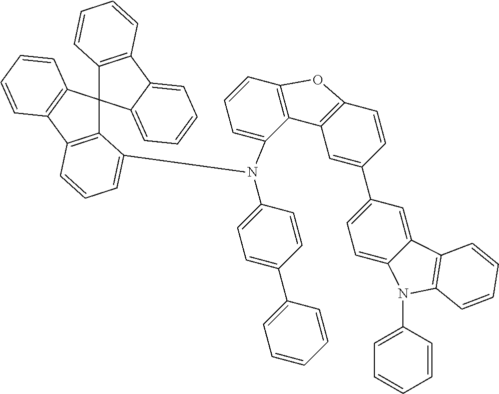 [SMILES: c1ccc(-c2ccc(N(c3cccc4c3C3(c5ccccc5-c5ccccc53)c3ccccc3-4)c3cccc4oc5ccc(-c6ccc7c(c6)c6ccccc6n7-c6ccccc6)cc5c34)cc2)cc1]

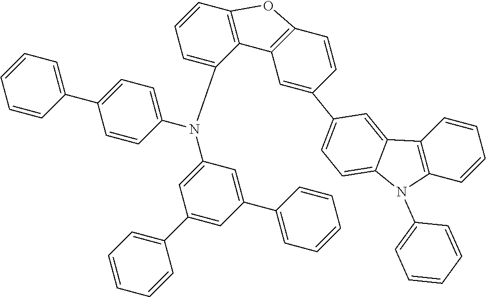 [SMILES: c1ccc(-c2ccc(N(c3cc(-c4ccccc4)cc(-c4ccccc4)c3)c3cccc4oc5ccc(-c6ccc7c(c6)c6ccccc6n7-c6ccccc6)cc5c34)cc2)cc1]

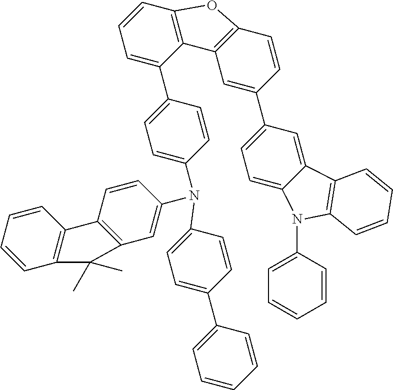 [SMILES: CC1(C)c2ccccc2-c2ccc(N(c3ccc(-c4ccccc4)cc3)c3ccc(-c4cccc5oc6ccc(-c7ccc8c(c7)c7ccccc7n8-c7ccccc7)cc6c45)cc3)cc21]

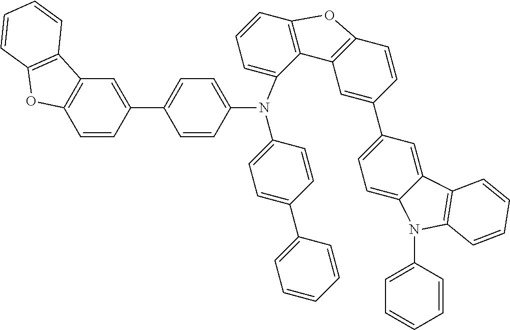 [SMILES: c1ccc(-c2ccc(N(c3ccc(-c4ccc5oc6ccccc6c5c4)cc3)c3cccc4oc5ccc(-c6ccc7c(c6)c6ccccc6n7-c6ccccc6)cc5c34)cc2)cc1]

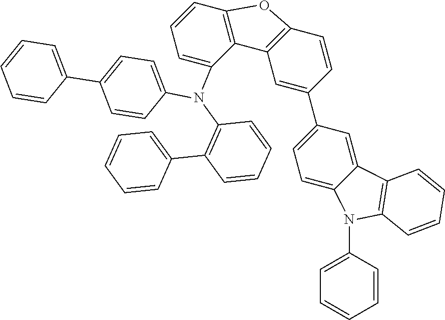 [SMILES: c1ccc(-c2ccc(N(c3ccccc3-c3ccccc3)c3cccc4oc5ccc(-c6ccc7c(c6)c6ccccc6n7-c6ccccc6)cc5c34)cc2)cc1]

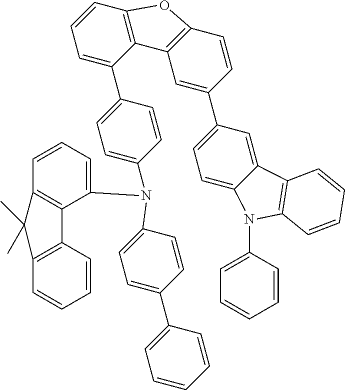 [SMILES: CC1(C)c2ccccc2-c2c(N(c3ccc(-c4ccccc4)cc3)c3ccc(-c4cccc5oc6ccc(-c7ccc8c(c7)c7ccccc7n8-c7ccccc7)cc6c45)cc3)cccc21]

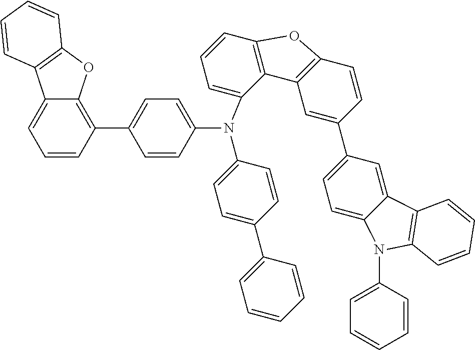 [SMILES: c1ccc(-c2ccc(N(c3ccc(-c4cccc5c4oc4ccccc45)cc3)c3cccc4oc5ccc(-c6ccc7c(c6)c6ccccc6n7-c6ccccc6)cc5c34)cc2)cc1]

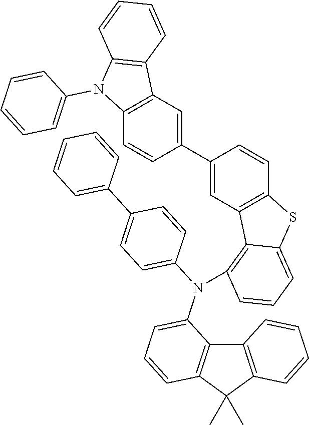 [SMILES: CC1(C)c2ccccc2-c2c(N(c3ccc(-c4ccccc4)cc3)c3cccc4sc5ccc(-c6ccc7c(c6)c6ccccc6n7-c6ccccc6)cc5c34)cccc21]

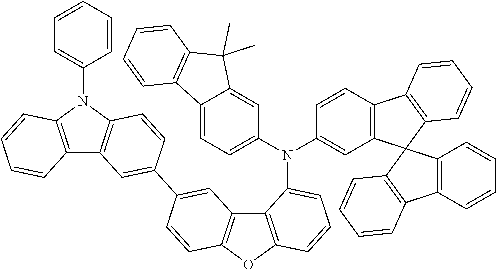 [SMILES: CC1(C)c2ccccc2-c2ccc(N(c3ccc4c(c3)C3(c5ccccc5-c5ccccc53)c3ccccc3-4)c3cccc4oc5ccc(-c6ccc7c(c6)c6ccccc6n7-c6ccccc6)cc5c34)cc21]

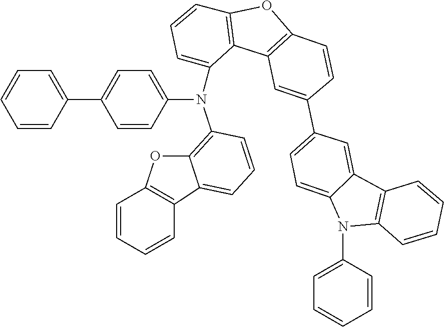 [SMILES: c1ccc(-c2ccc(N(c3cccc4c3oc3ccccc34)c3cccc4oc5ccc(-c6ccc7c(c6)c6ccccc6n7-c6ccccc6)cc5c34)cc2)cc1]

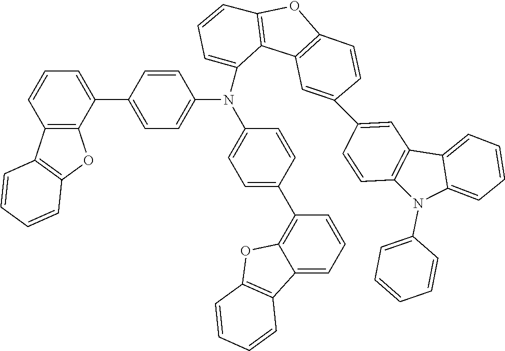 [SMILES: c1ccc(-n2c3ccccc3c3cc(-c4ccc5oc6cccc(N(c7ccc(-c8cccc9c8oc8ccccc89)cc7)c7ccc(-c8cccc9c8oc8ccccc89)cc7)c6c5c4)ccc32)cc1]

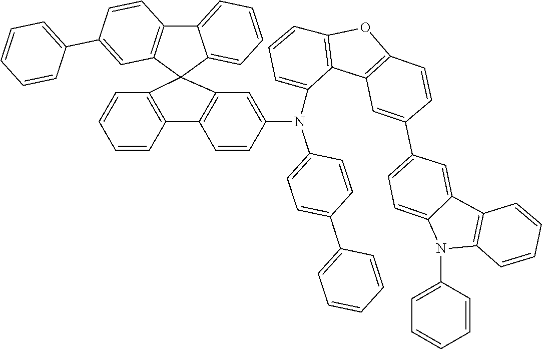 [SMILES: c1ccc(-c2ccc(N(c3ccc4c(c3)C3(c5ccccc5-c5ccc(-c6ccccc6)cc53)c3ccccc3-4)c3cccc4oc5ccc(-c6ccc7c(c6)c6ccccc6n7-c6ccccc6)cc5c34)cc2)cc1]

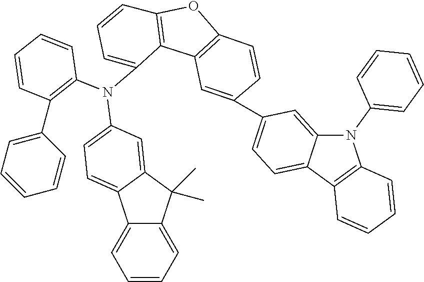 [SMILES: CC1(C)c2ccccc2-c2ccc(N(c3ccccc3-c3ccccc3)c3cccc4oc5ccc(-c6ccc7c8ccccc8n(-c8ccccc8)c7c6)cc5c34)cc21]

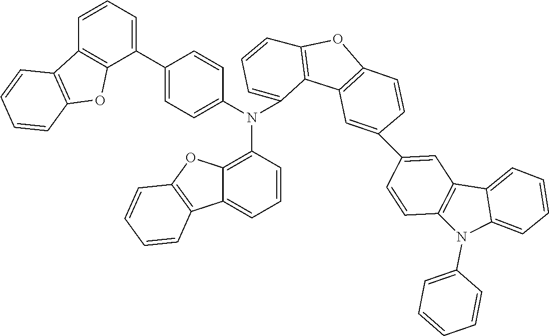 [SMILES: c1ccc(-n2c3ccccc3c3cc(-c4ccc5oc6cccc(N(c7ccc(-c8cccc9c8oc8ccccc89)cc7)c7cccc8c7oc7ccccc78)c6c5c4)ccc32)cc1]

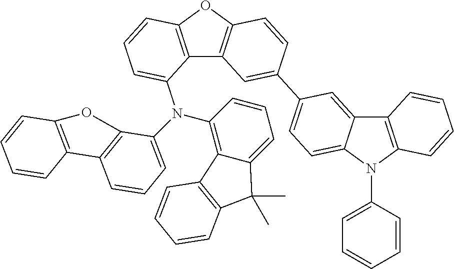 [SMILES: CC1(C)c2ccccc2-c2c(N(c3cccc4c3oc3ccccc34)c3cccc4oc5ccc(-c6ccc7c(c6)c6ccccc6n7-c6ccccc6)cc5c34)cccc21]

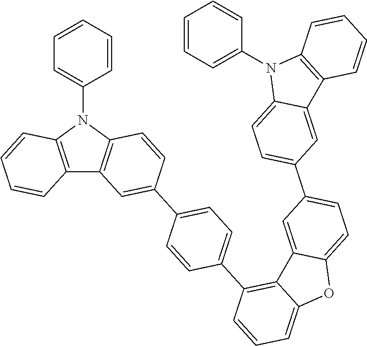 [SMILES: c1ccc(-n2c3ccccc3c3cc(-c4ccc(-c5cccc6oc7ccc(-c8ccc9c(c8)c8ccccc8n9-c8ccccc8)cc7c56)cc4)ccc32)cc1]

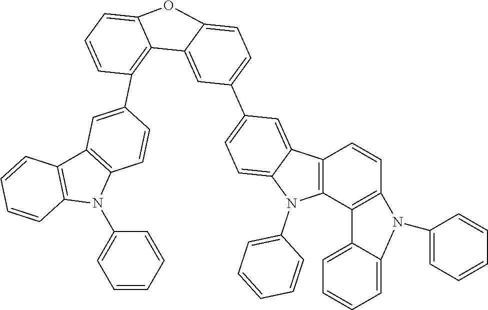 [SMILES: c1ccc(-n2c3ccccc3c3cc(-c4cccc5oc6ccc(-c7ccc8c(c7)c7ccc9c(c%10ccccc%10n9-c9ccccc9)c7n8-c7ccccc7)cc6c45)ccc32)cc1]

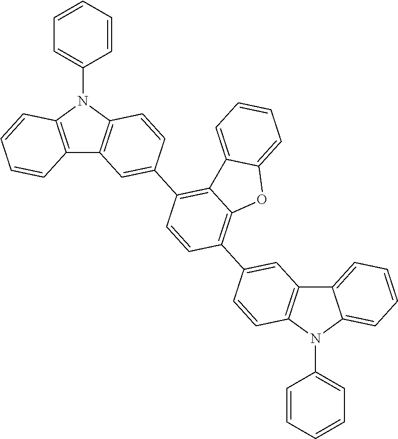 [SMILES: c1ccc(-n2c3ccccc3c3cc(-c4ccc(-c5ccc6c(c5)c5ccccc5n6-c5ccccc5)c5c4oc4ccccc45)ccc32)cc1]

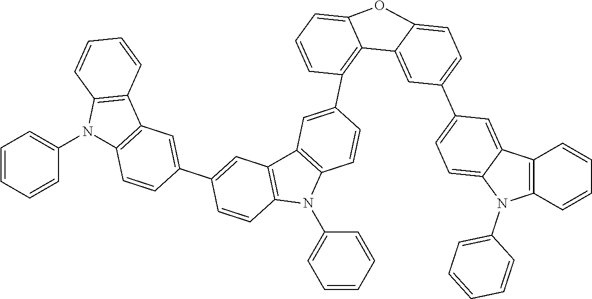 [SMILES: c1ccc(-n2c3ccccc3c3cc(-c4ccc5oc6cccc(-c7ccc8c(c7)c7cc(-c9ccc%10c(c9)c9ccccc9n%10-c9ccccc9)ccc7n8-c7ccccc7)c6c5c4)ccc32)cc1]

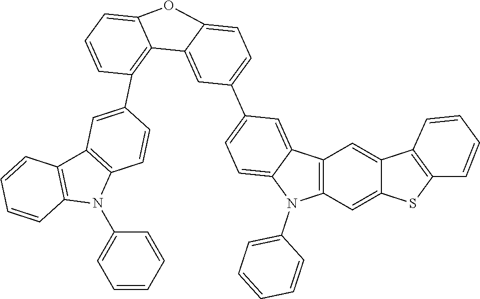 [SMILES: c1ccc(-n2c3ccccc3c3cc(-c4cccc5oc6ccc(-c7ccc8c(c7)c7cc9c(cc7n8-c7ccccc7)sc7ccccc79)cc6c45)ccc32)cc1]

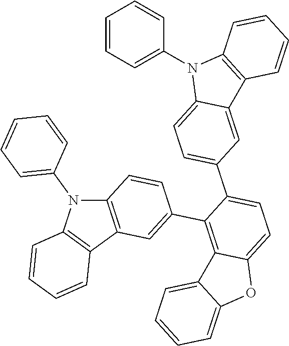 [SMILES: c1ccc(-n2c3ccccc3c3cc(-c4ccc5oc6ccccc6c5c4-c4ccc5c(c4)c4ccccc4n5-c4ccccc4)ccc32)cc1]

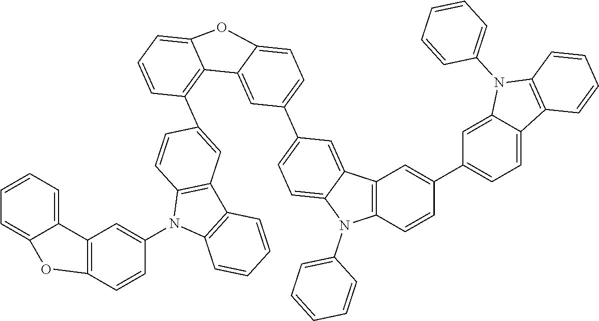 [SMILES: c1ccc(-n2c3ccc(-c4ccc5oc6cccc(-c7ccc8c(c7)c7ccccc7n8-c7ccc8oc9ccccc9c8c7)c6c5c4)cc3c3cc(-c4ccc5c6ccccc6n(-c6ccccc6)c5c4)ccc32)cc1]

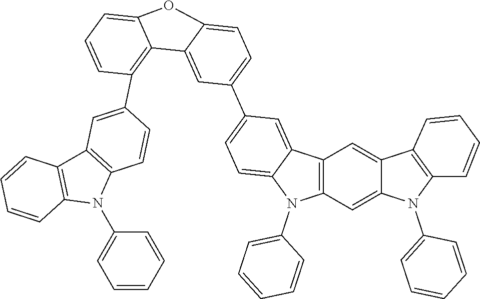 [SMILES: c1ccc(-n2c3ccccc3c3cc(-c4cccc5oc6ccc(-c7ccc8c(c7)c7cc9c%10ccccc%10n(-c%10ccccc%10)c9cc7n8-c7ccccc7)cc6c45)ccc32)cc1]

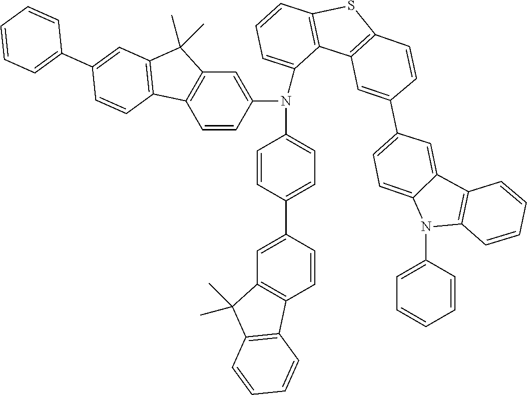 [SMILES: CC1(C)c2ccccc2-c2ccc(-c3ccc(N(c4ccc5c(c4)C(C)(C)c4cc(-c6ccccc6)ccc4-5)c4cccc5sc6ccc(-c7ccc8c(c7)c7ccccc7n8-c7ccccc7)cc6c45)cc3)cc21]

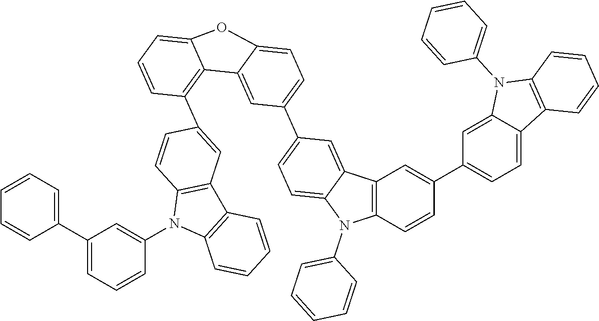 [SMILES: c1ccc(-c2cccc(-n3c4ccccc4c4cc(-c5cccc6oc7ccc(-c8ccc9c(c8)c8cc(-c%10ccc%11c%12ccccc%12n(-c%12ccccc%12)c%11c%10)ccc8n9-c8ccccc8)cc7c56)ccc43)c2)cc1]

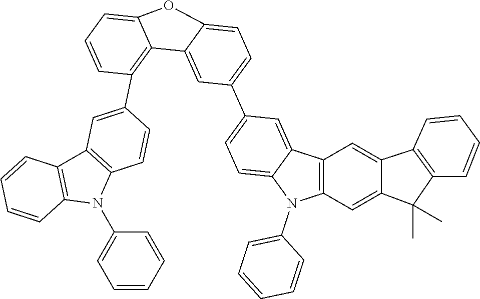 [SMILES: CC1(C)c2ccccc2-c2cc3c4cc(-c5ccc6oc7cccc(-c8ccc9c(c8)c8ccccc8n9-c8ccccc8)c7c6c5)ccc4n(-c4ccccc4)c3cc21]

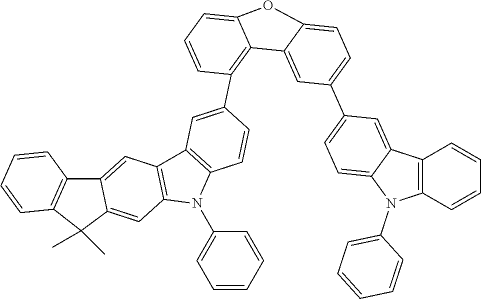 [SMILES: CC1(C)c2ccccc2-c2cc3c4cc(-c5cccc6oc7ccc(-c8ccc9c(c8)c8ccccc8n9-c8ccccc8)cc7c56)ccc4n(-c4ccccc4)c3cc21]

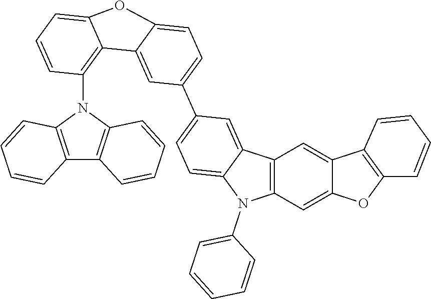 [SMILES: c1ccc(-n2c3ccc(-c4ccc5oc6cccc(-n7c8ccccc8c8ccccc87)c6c5c4)cc3c3cc4c(cc32)oc2ccccc24)cc1]

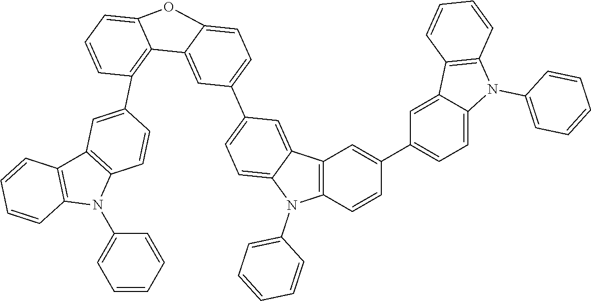 [SMILES: c1ccc(-n2c3ccccc3c3cc(-c4ccc5c(c4)c4cc(-c6ccc7oc8cccc(-c9ccc%10c(c9)c9ccccc9n%10-c9ccccc9)c8c7c6)ccc4n5-c4ccccc4)ccc32)cc1]

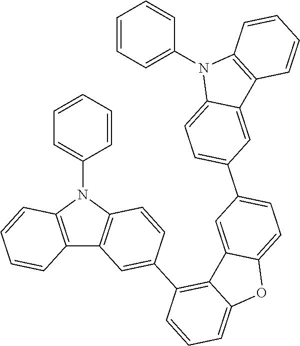 [SMILES: c1ccc(-n2c3ccccc3c3cc(-c4ccc5oc6cccc(-c7ccc8c(c7)c7ccccc7n8-c7ccccc7)c6c5c4)ccc32)cc1]

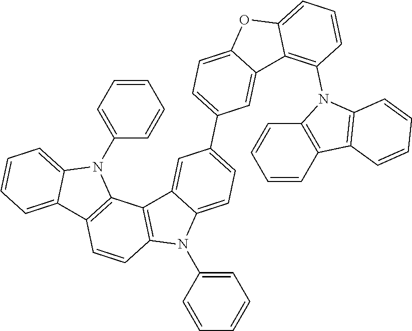 [SMILES: c1ccc(-n2c3ccc(-c4ccc5oc6cccc(-n7c8ccccc8c8ccccc87)c6c5c4)cc3c3c2ccc2c4ccccc4n(-c4ccccc4)c23)cc1]

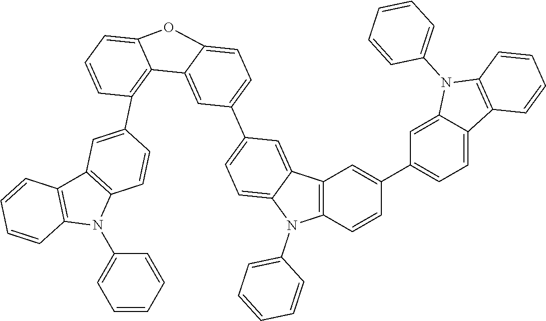 [SMILES: c1ccc(-n2c3ccc(-c4ccc5oc6cccc(-c7ccc8c(c7)c7ccccc7n8-c7ccccc7)c6c5c4)cc3c3cc(-c4ccc5c6ccccc6n(-c6ccccc6)c5c4)ccc32)cc1]

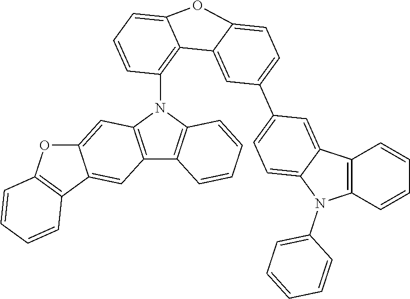 [SMILES: c1ccc(-n2c3ccccc3c3cc(-c4ccc5oc6cccc(-n7c8ccccc8c8cc9c(cc87)oc7ccccc79)c6c5c4)ccc32)cc1]

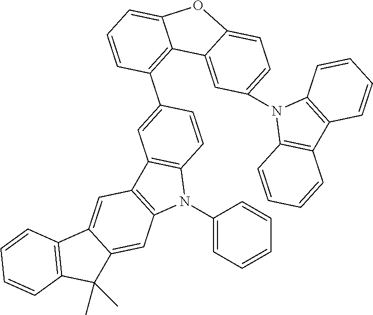 [SMILES: CC1(C)c2ccccc2-c2cc3c4cc(-c5cccc6oc7ccc(-n8c9ccccc9c9ccccc98)cc7c56)ccc4n(-c4ccccc4)c3cc21]

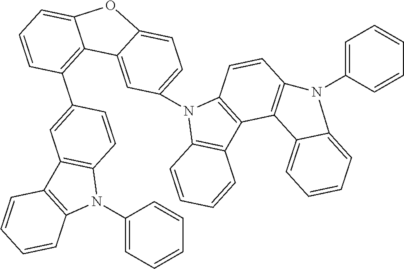 [SMILES: c1ccc(-n2c3ccccc3c3cc(-c4cccc5oc6ccc(-n7c8ccccc8c8c9c%10ccccc%10n(-c%10ccccc%10)c9ccc87)cc6c45)ccc32)cc1]

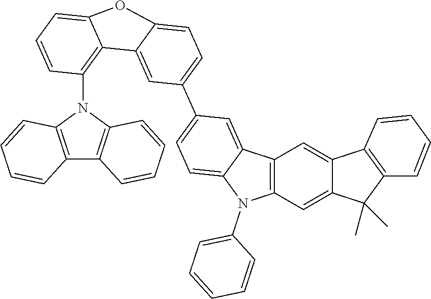 [SMILES: CC1(C)c2ccccc2-c2cc3c4cc(-c5ccc6oc7cccc(-n8c9ccccc9c9ccccc98)c7c6c5)ccc4n(-c4ccccc4)c3cc21]

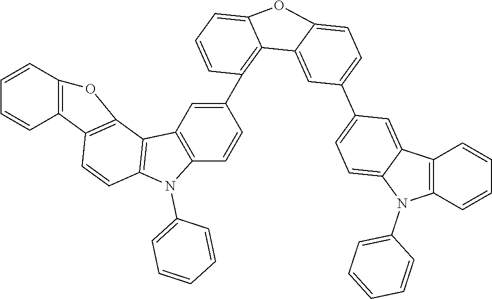 [SMILES: c1ccc(-n2c3ccccc3c3cc(-c4ccc5oc6cccc(-c7ccc8c(c7)c7c9oc%10ccccc%10c9ccc7n8-c7ccccc7)c6c5c4)ccc32)cc1]

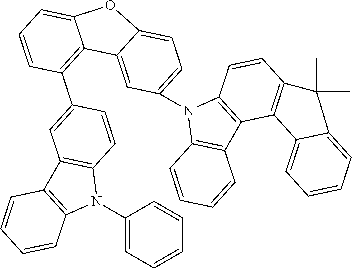 [SMILES: CC1(C)c2ccccc2-c2c1ccc1c2c2ccccc2n1-c1ccc2oc3cccc(-c4ccc5c(c4)c4ccccc4n5-c4ccccc4)c3c2c1]

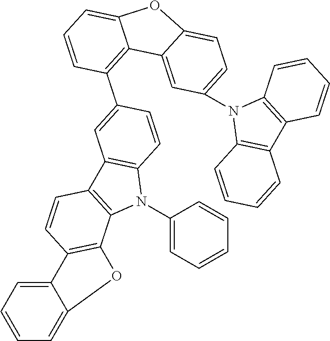 [SMILES: c1ccc(-n2c3ccc(-c4cccc5oc6ccc(-n7c8ccccc8c8ccccc87)cc6c45)cc3c3ccc4c5ccccc5oc4c32)cc1]

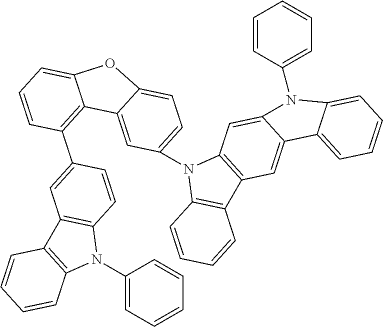 [SMILES: c1ccc(-n2c3ccccc3c3cc(-c4cccc5oc6ccc(-n7c8ccccc8c8cc9c%10ccccc%10n(-c%10ccccc%10)c9cc87)cc6c45)ccc32)cc1]

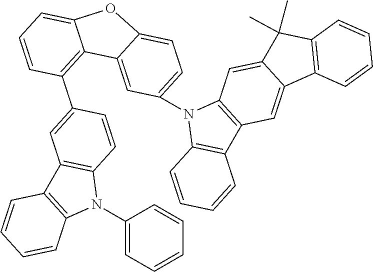 [SMILES: CC1(C)c2ccccc2-c2cc3c4ccccc4n(-c4ccc5oc6cccc(-c7ccc8c(c7)c7ccccc7n8-c7ccccc7)c6c5c4)c3cc21]

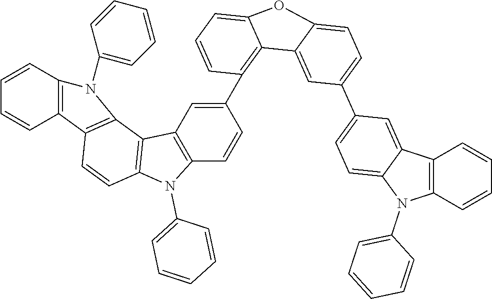 [SMILES: c1ccc(-n2c3ccccc3c3cc(-c4ccc5oc6cccc(-c7ccc8c(c7)c7c(ccc9c%10ccccc%10n(-c%10ccccc%10)c97)n8-c7ccccc7)c6c5c4)ccc32)cc1]

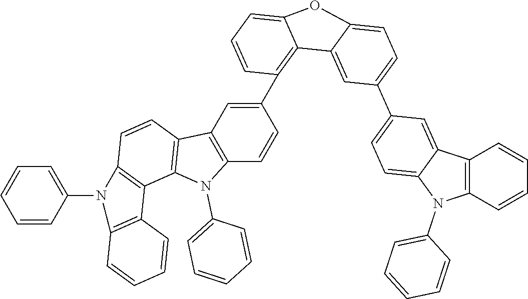 [SMILES: c1ccc(-n2c3ccccc3c3cc(-c4ccc5oc6cccc(-c7ccc8c(c7)c7ccc9c(c%10ccccc%10n9-c9ccccc9)c7n8-c7ccccc7)c6c5c4)ccc32)cc1]

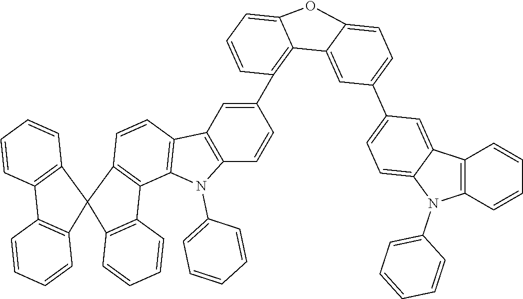 [SMILES: c1ccc(-n2c3ccccc3c3cc(-c4ccc5oc6cccc(-c7ccc8c(c7)c7ccc9c(c7n8-c7ccccc7)-c7ccccc7C97c8ccccc8-c8ccccc87)c6c5c4)ccc32)cc1]

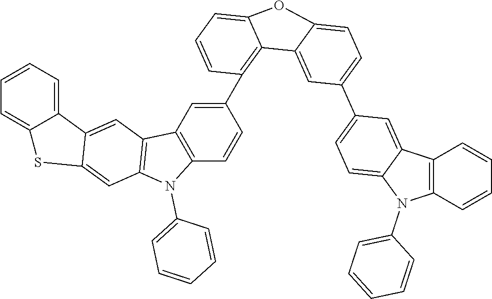 [SMILES: c1ccc(-n2c3ccccc3c3cc(-c4ccc5oc6cccc(-c7ccc8c(c7)c7cc9c(cc7n8-c7ccccc7)sc7ccccc79)c6c5c4)ccc32)cc1]

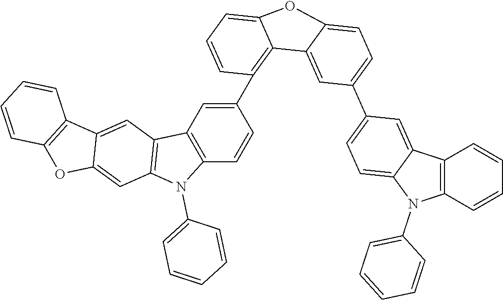 [SMILES: c1ccc(-n2c3ccccc3c3cc(-c4ccc5oc6cccc(-c7ccc8c(c7)c7cc9c(cc7n8-c7ccccc7)oc7ccccc79)c6c5c4)ccc32)cc1]

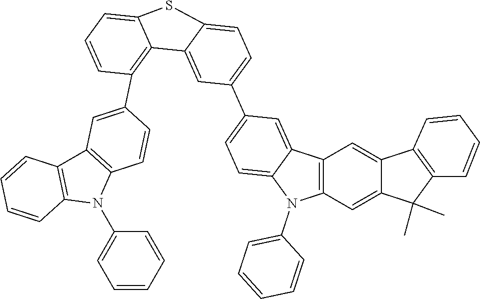 [SMILES: CC1(C)c2ccccc2-c2cc3c4cc(-c5ccc6sc7cccc(-c8ccc9c(c8)c8ccccc8n9-c8ccccc8)c7c6c5)ccc4n(-c4ccccc4)c3cc21]

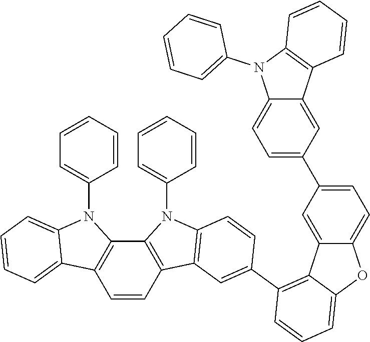 [SMILES: c1ccc(-n2c3ccccc3c3cc(-c4ccc5oc6cccc(-c7ccc8c(c7)c7ccc9c%10ccccc%10n(-c%10ccccc%10)c9c7n8-c7ccccc7)c6c5c4)ccc32)cc1]

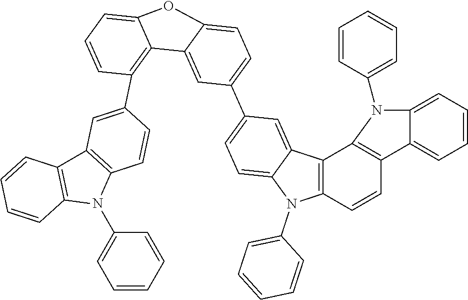 [SMILES: c1ccc(-n2c3ccccc3c3cc(-c4cccc5oc6ccc(-c7ccc8c(c7)c7c(ccc9c%10ccccc%10n(-c%10ccccc%10)c97)n8-c7ccccc7)cc6c45)ccc32)cc1]

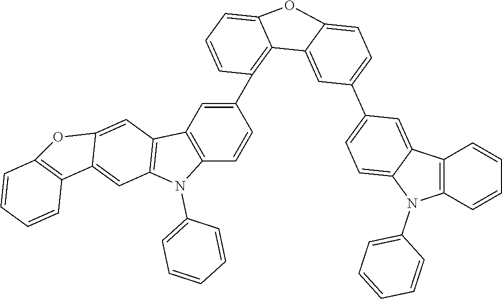 [SMILES: c1ccc(-n2c3ccccc3c3cc(-c4ccc5oc6cccc(-c7ccc8c(c7)c7cc9oc%10ccccc%10c9cc7n8-c7ccccc7)c6c5c4)ccc32)cc1]

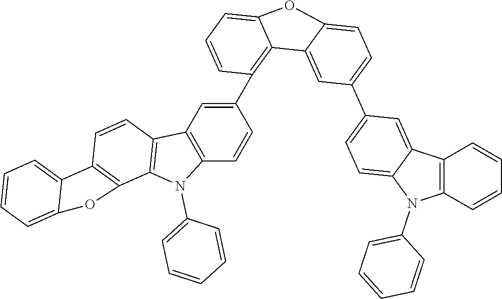 [SMILES: c1ccc(-n2c3ccccc3c3cc(-c4ccc5oc6cccc(-c7ccc8c(c7)c7ccc9c%10ccccc%10oc9c7n8-c7ccccc7)c6c5c4)ccc32)cc1]

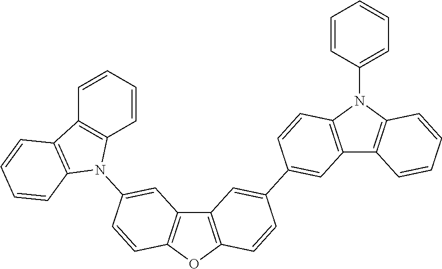 [SMILES: c1ccc(-n2c3ccccc3c3cc(-c4ccc5oc6ccc(-n7c8ccccc8c8ccccc87)cc6c5c4)ccc32)cc1]

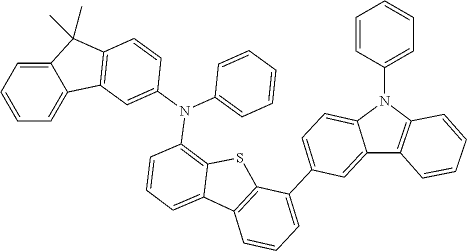 [SMILES: CC1(C)c2ccccc2-c2cc(N(c3ccccc3)c3cccc4c3sc3c(-c5ccc6c(c5)c5ccccc5n6-c5ccccc5)cccc34)ccc21]

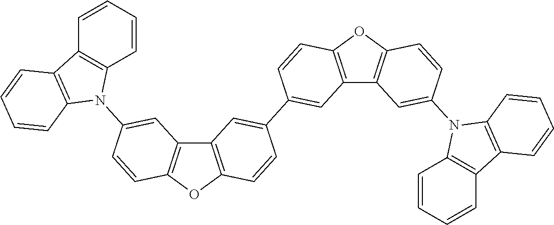 [SMILES: c1ccc2c(c1)c1ccccc1n2-c1ccc2oc3ccc(-c4ccc5oc6ccc(-n7c8ccccc8c8ccccc87)cc6c5c4)cc3c2c1]

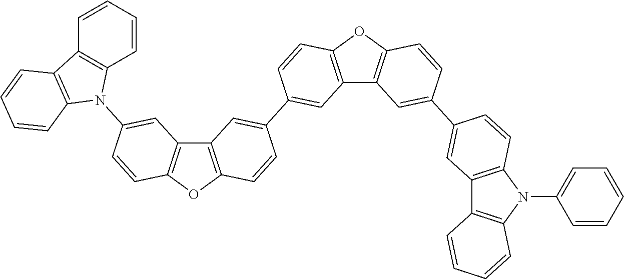 [SMILES: c1ccc(-n2c3ccccc3c3cc(-c4ccc5oc6ccc(-c7ccc8oc9ccc(-n%10c%11ccccc%11c%11ccccc%11%10)cc9c8c7)cc6c5c4)ccc32)cc1]

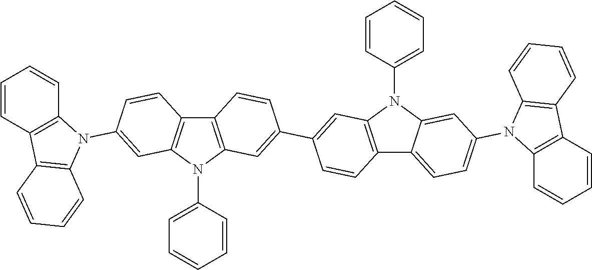 [SMILES: c1ccc(-n2c3cc(-c4ccc5c6ccc(-n7c8ccccc8c8ccccc87)cc6n(-c6ccccc6)c5c4)ccc3c3ccc(-n4c5ccccc5c5ccccc54)cc32)cc1]

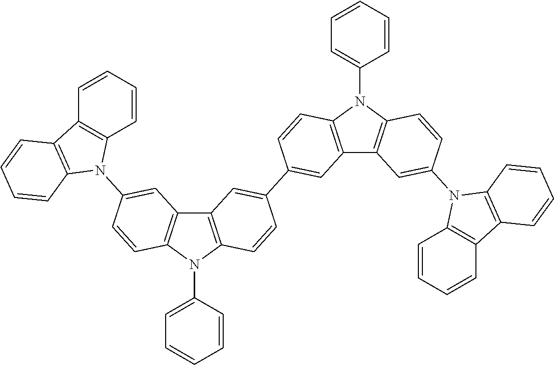 [SMILES: c1ccc(-n2c3ccc(-c4ccc5c(c4)c4cc(-n6c7ccccc7c7ccccc76)ccc4n5-c4ccccc4)cc3c3cc(-n4c5ccccc5c5ccccc54)ccc32)cc1]

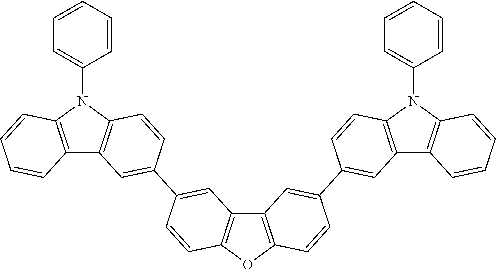 [SMILES: c1ccc(-n2c3ccccc3c3cc(-c4ccc5oc6ccc(-c7ccc8c(c7)c7ccccc7n8-c7ccccc7)cc6c5c4)ccc32)cc1]

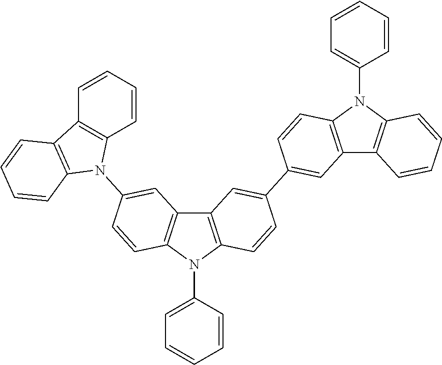 [SMILES: c1ccc(-n2c3ccccc3c3cc(-c4ccc5c(c4)c4cc(-n6c7ccccc7c7ccccc76)ccc4n5-c4ccccc4)ccc32)cc1]

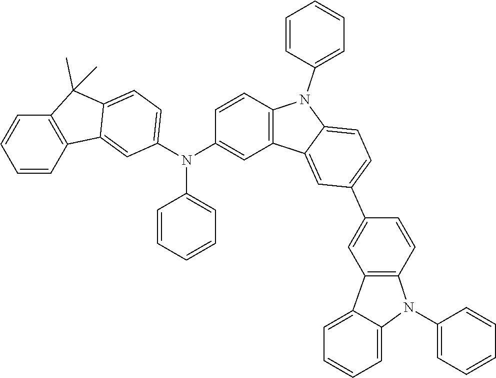 [SMILES: CC1(C)c2ccccc2-c2cc(N(c3ccccc3)c3ccc4c(c3)c3cc(-c5ccc6c(c5)c5ccccc5n6-c5ccccc5)ccc3n4-c3ccccc3)ccc21]

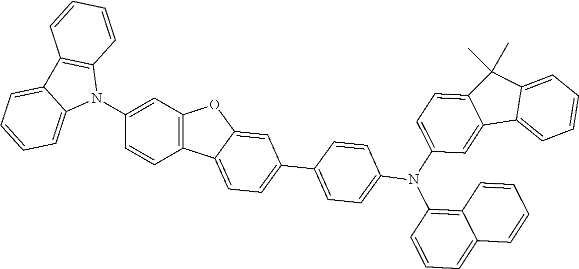 [SMILES: CC1(C)c2ccccc2-c2cc(N(c3ccc(-c4ccc5c(c4)oc4cc(-n6c7ccccc7c7ccccc76)ccc45)cc3)c3cccc4ccccc34)ccc21]

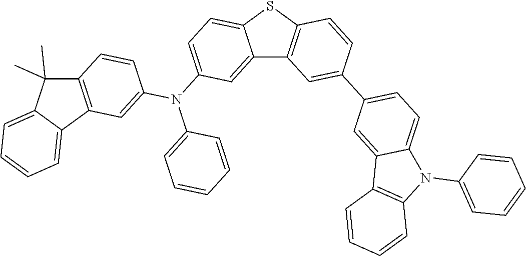 [SMILES: CC1(C)c2ccccc2-c2cc(N(c3ccccc3)c3ccc4sc5ccc(-c6ccc7c(c6)c6ccccc6n7-c6ccccc6)cc5c4c3)ccc21]

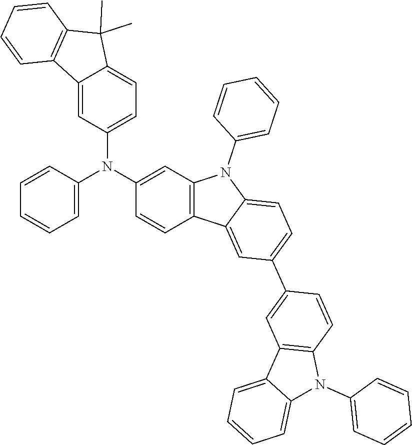 [SMILES: CC1(C)c2ccccc2-c2cc(N(c3ccccc3)c3ccc4c5cc(-c6ccc7c(c6)c6ccccc6n7-c6ccccc6)ccc5n(-c5ccccc5)c4c3)ccc21]

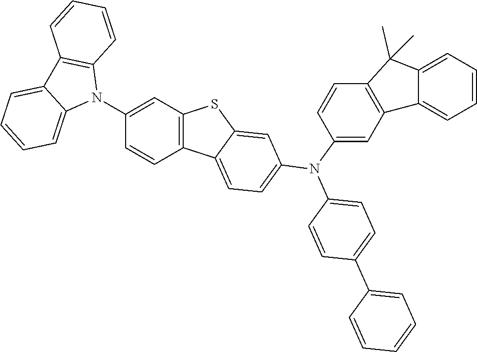 [SMILES: CC1(C)c2ccccc2-c2cc(N(c3ccc(-c4ccccc4)cc3)c3ccc4c(c3)sc3cc(-n5c6ccccc6c6ccccc65)ccc34)ccc21]

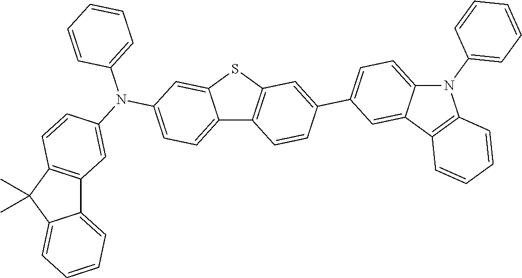 [SMILES: CC1(C)c2ccccc2-c2cc(N(c3ccccc3)c3ccc4c(c3)sc3cc(-c5ccc6c(c5)c5ccccc5n6-c5ccccc5)ccc34)ccc21]

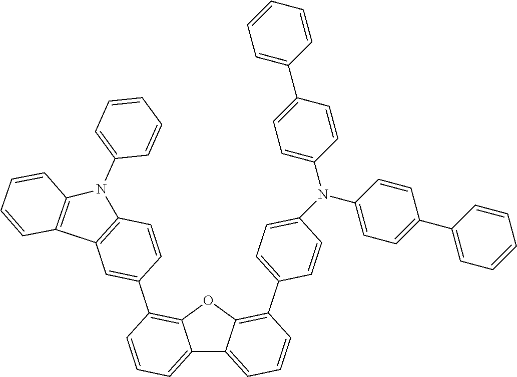 [SMILES: c1ccc(-c2ccc(N(c3ccc(-c4ccccc4)cc3)c3ccc(-c4cccc5c4oc4c(-c6ccc7c(c6)c6ccccc6n7-c6ccccc6)cccc45)cc3)cc2)cc1]

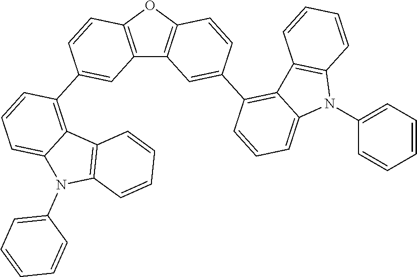 [SMILES: c1ccc(-n2c3ccccc3c3c(-c4ccc5oc6ccc(-c7cccc8c7c7ccccc7n8-c7ccccc7)cc6c5c4)cccc32)cc1]

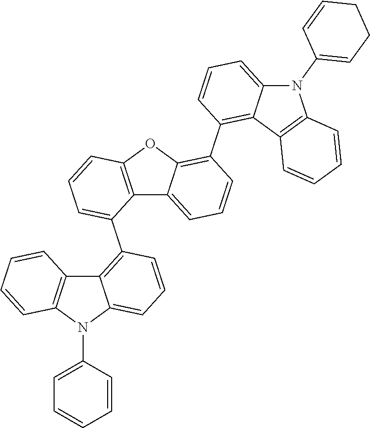 [SMILES: C1=CC(n2c3ccccc3c3c(-c4cccc5c4oc4cccc(-c6cccc7c6c6ccccc6n7-c6ccccc6)c45)cccc32)=CCC1]

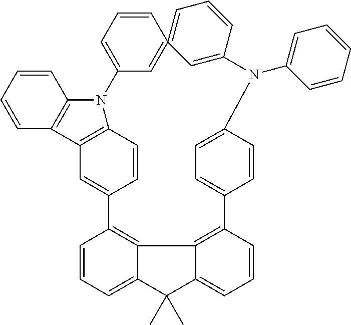

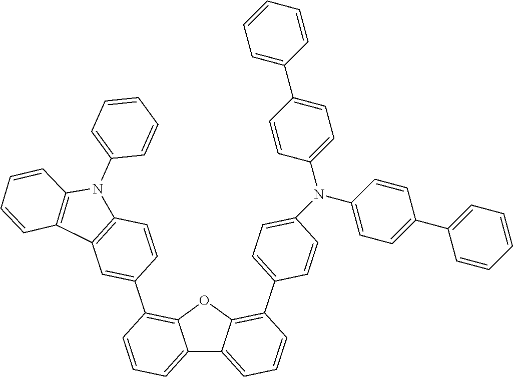 [SMILES: c1ccc(-c2ccc(N(c3ccc(-c4ccccc4)cc3)c3ccc(-c4cccc5c4oc4c(-c6ccc7c(c6)c6ccccc6n7-c6ccccc6)cccc45)cc3)cc2)cc1]

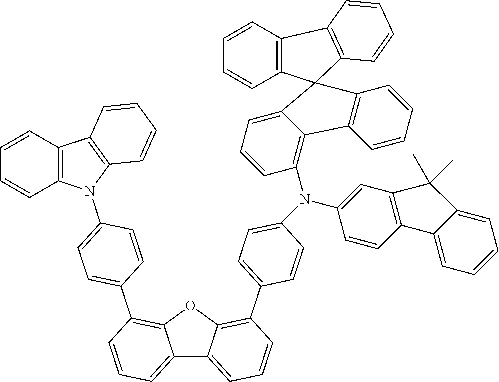 [SMILES: CC1(C)c2ccccc2-c2ccc(N(c3ccc(-c4cccc5c4oc4c(-c6ccc(-n7c8ccccc8c8ccccc87)cc6)cccc45)cc3)c3cccc4c3-c3ccccc3C43c4ccccc4-c4ccccc43)cc21]

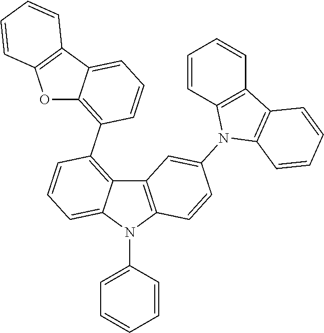 [SMILES: c1ccc(-n2c3ccc(-n4c5ccccc5c5ccccc54)cc3c3c(-c4cccc5c4oc4ccccc45)cccc32)cc1]

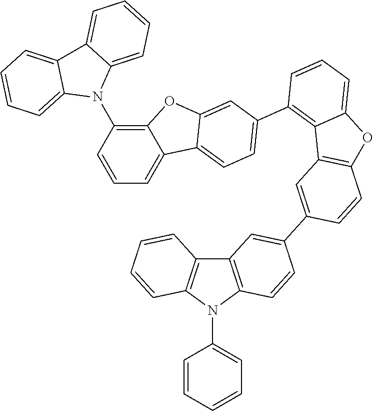 [SMILES: c1ccc(-n2c3ccccc3c3cc(-c4ccc5oc6cccc(-c7ccc8c(c7)oc7c(-n9c%10ccccc%10c%10ccccc%109)cccc78)c6c5c4)ccc32)cc1]

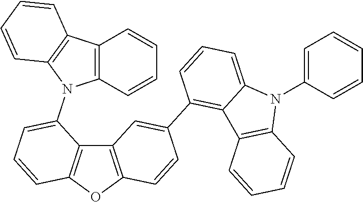 [SMILES: c1ccc(-n2c3ccccc3c3c(-c4ccc5oc6cccc(-n7c8ccccc8c8ccccc87)c6c5c4)cccc32)cc1]

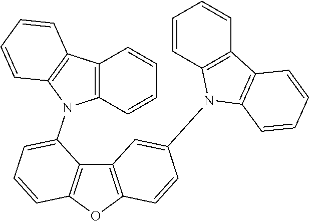 [SMILES: c1cc(-n2c3ccccc3c3ccccc32)c2c(c1)oc1ccc(-n3c4ccccc4c4ccccc43)cc12]

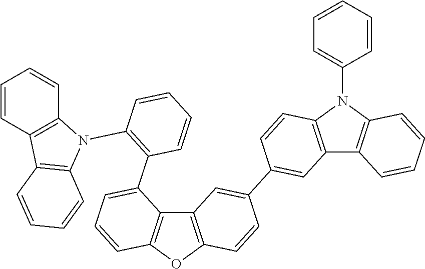 [SMILES: c1ccc(-n2c3ccccc3c3cc(-c4ccc5oc6cccc(-c7ccccc7-n7c8ccccc8c8ccccc87)c6c5c4)ccc32)cc1]

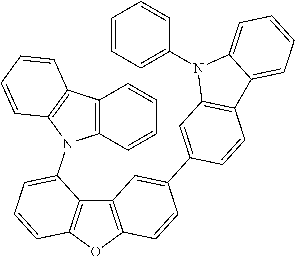 [SMILES: c1ccc(-n2c3ccccc3c3ccc(-c4ccc5oc6cccc(-n7c8ccccc8c8ccccc87)c6c5c4)cc32)cc1]

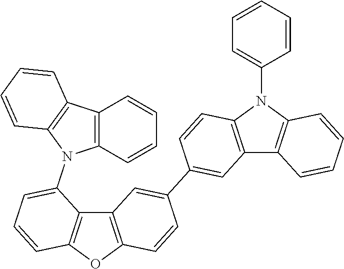 [SMILES: c1ccc(-n2c3ccccc3c3cc(-c4ccc5oc6cccc(-n7c8ccccc8c8ccccc87)c6c5c4)ccc32)cc1]

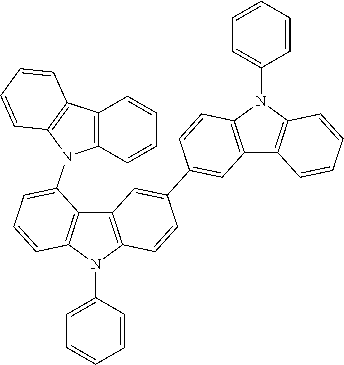 [SMILES: c1ccc(-n2c3ccccc3c3cc(-c4ccc5c(c4)c4c(-n6c7ccccc7c7ccccc76)cccc4n5-c4ccccc4)ccc32)cc1]

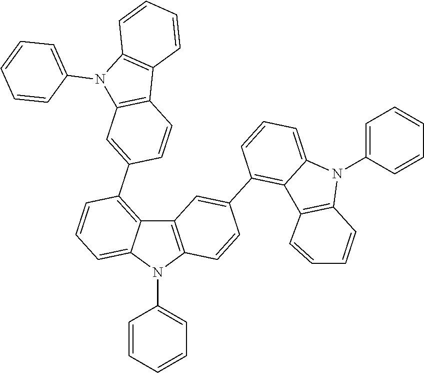 [SMILES: c1ccc(-n2c3ccccc3c3ccc(-c4cccc5c4c4cc(-c6cccc7c6c6ccccc6n7-c6ccccc6)ccc4n5-c4ccccc4)cc32)cc1]

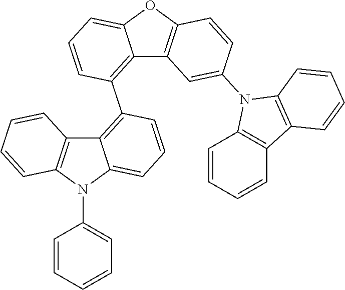 [SMILES: c1ccc(-n2c3ccccc3c3c(-c4cccc5oc6ccc(-n7c8ccccc8c8ccccc87)cc6c45)cccc32)cc1]

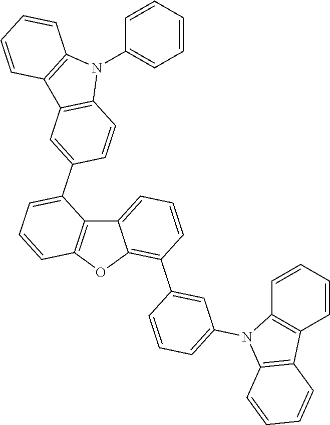 [SMILES: c1ccc(-n2c3ccccc3c3cc(-c4cccc5oc6c(-c7cccc(-n8c9ccccc9c9ccccc98)c7)cccc6c45)ccc32)cc1]

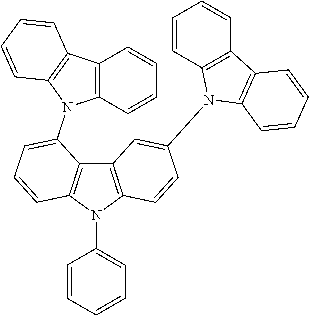 [SMILES: c1ccc(-n2c3ccc(-n4c5ccccc5c5ccccc54)cc3c3c(-n4c5ccccc5c5ccccc54)cccc32)cc1]

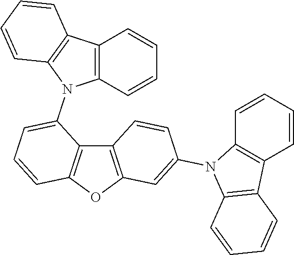 [SMILES: c1cc(-n2c3ccccc3c3ccccc32)c2c(c1)oc1cc(-n3c4ccccc4c4ccccc43)ccc12]

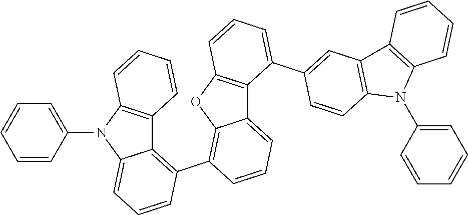 [SMILES: c1ccc(-n2c3ccccc3c3cc(-c4cccc5oc6c(-c7cccc8c7c7ccccc7n8-c7ccccc7)cccc6c45)ccc32)cc1]

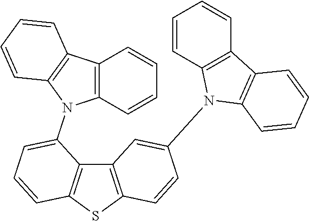 [SMILES: c1cc(-n2c3ccccc3c3ccccc32)c2c(c1)sc1ccc(-n3c4ccccc4c4ccccc43)cc12]

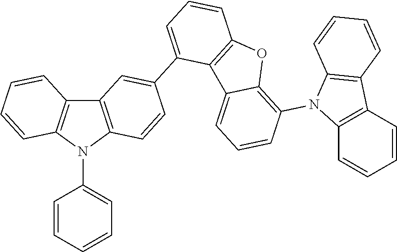 [SMILES: c1ccc(-n2c3ccccc3c3cc(-c4cccc5oc6c(-n7c8ccccc8c8ccccc87)cccc6c45)ccc32)cc1]

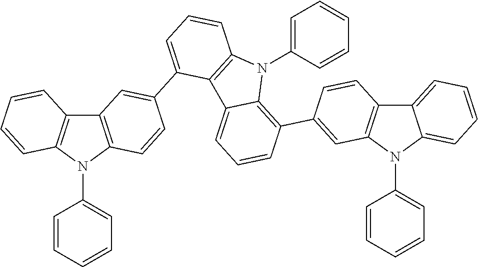 [SMILES: c1ccc(-n2c3ccccc3c3cc(-c4cccc5c4c4cccc(-c6ccc7c8ccccc8n(-c8ccccc8)c7c6)c4n5-c4ccccc4)ccc32)cc1]

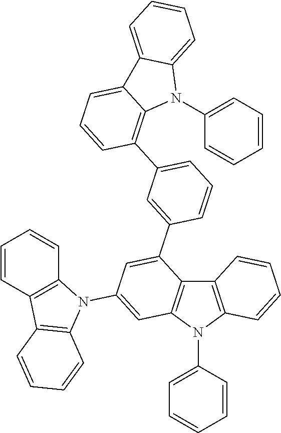 [SMILES: c1ccc(-n2c3ccccc3c3c(-c4cccc(-c5cccc6c7ccccc7n(-c7ccccc7)c56)c4)cc(-n4c5ccccc5c5ccccc54)cc32)cc1]

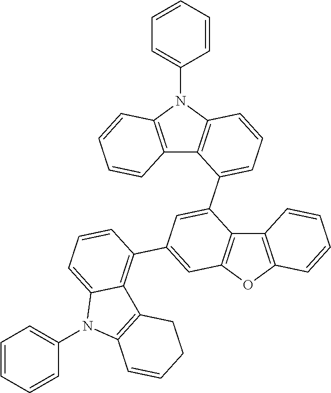 [SMILES: C1=Cc2c(c3c(-c4cc(-c5cccc6c5c5ccccc5n6-c5ccccc5)c5c(c4)oc4ccccc45)cccc3n2-c2ccccc2)CC1]

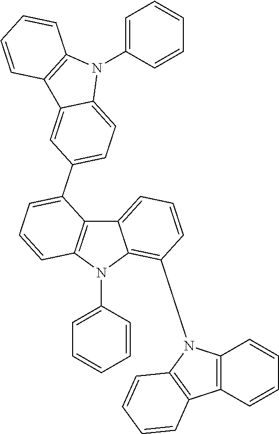 [SMILES: c1ccc(-n2c3ccccc3c3cc(-c4cccc5c4c4cccc(-n6c7ccccc7c7ccccc76)c4n5-c4ccccc4)ccc32)cc1]

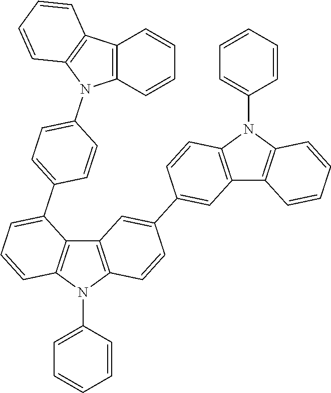 [SMILES: c1ccc(-n2c3ccccc3c3cc(-c4ccc5c(c4)c4c(-c6ccc(-n7c8ccccc8c8ccccc87)cc6)cccc4n5-c4ccccc4)ccc32)cc1]

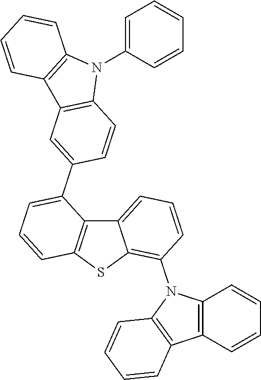 [SMILES: c1ccc(-n2c3ccccc3c3cc(-c4cccc5sc6c(-n7c8ccccc8c8ccccc87)cccc6c45)ccc32)cc1]

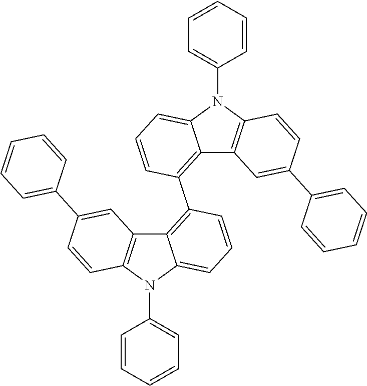 [SMILES: c1ccc(-c2ccc3c(c2)c2c(-c4cccc5c4c4cc(-c6ccccc6)ccc4n5-c4ccccc4)cccc2n3-c2ccccc2)cc1]

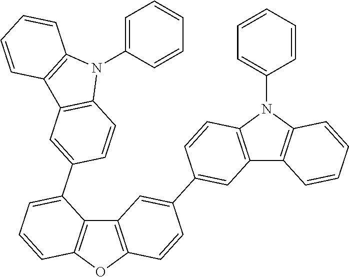 [SMILES: c1ccc(-n2c3ccccc3c3cc(-c4ccc5oc6cccc(-c7ccc8c(c7)c7ccccc7n8-c7ccccc7)c6c5c4)ccc32)cc1]

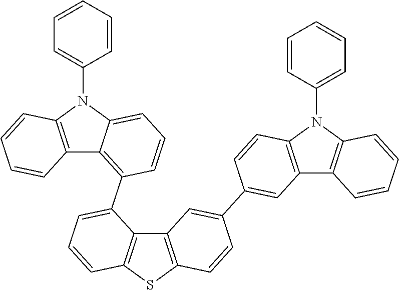 [SMILES: c1ccc(-n2c3ccccc3c3cc(-c4ccc5sc6cccc(-c7cccc8c7c7ccccc7n8-c7ccccc7)c6c5c4)ccc32)cc1]

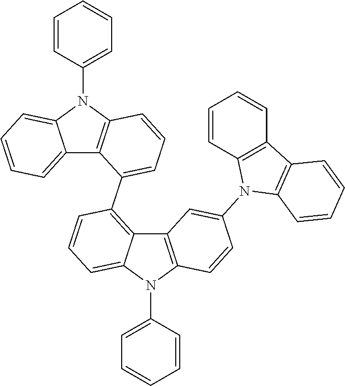 [SMILES: c1ccc(-n2c3ccccc3c3c(-c4cccc5c4c4cc(-n6c7ccccc7c7ccccc76)ccc4n5-c4ccccc4)cccc32)cc1]

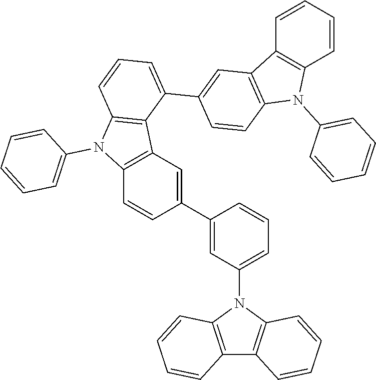 [SMILES: c1ccc(-n2c3ccccc3c3cc(-c4cccc5c4c4cc(-c6cccc(-n7c8ccccc8c8ccccc87)c6)ccc4n5-c4ccccc4)ccc32)cc1]

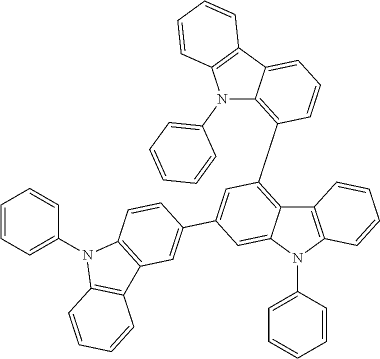 [SMILES: c1ccc(-n2c3ccccc3c3cc(-c4cc(-c5cccc6c7ccccc7n(-c7ccccc7)c56)c5c6ccccc6n(-c6ccccc6)c5c4)ccc32)cc1]

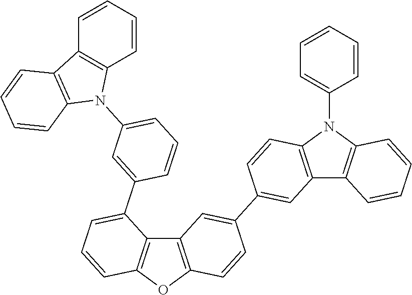 [SMILES: c1ccc(-n2c3ccccc3c3cc(-c4ccc5oc6cccc(-c7cccc(-n8c9ccccc9c9ccccc98)c7)c6c5c4)ccc32)cc1]

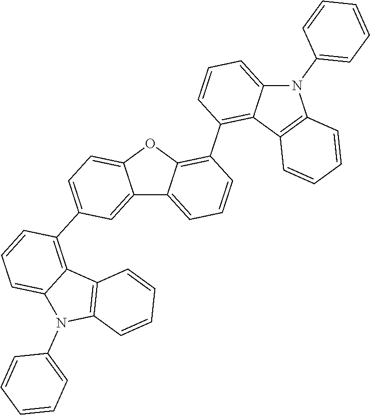 [SMILES: c1ccc(-n2c3ccccc3c3c(-c4ccc5oc6c(-c7cccc8c7c7ccccc7n8-c7ccccc7)cccc6c5c4)cccc32)cc1]

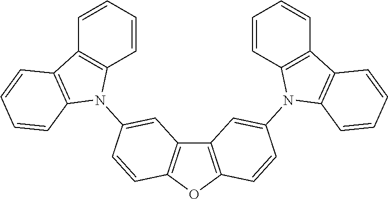 [SMILES: c1ccc2c(c1)c1ccccc1n2-c1ccc2oc3ccc(-n4c5ccccc5c5ccccc54)cc3c2c1]

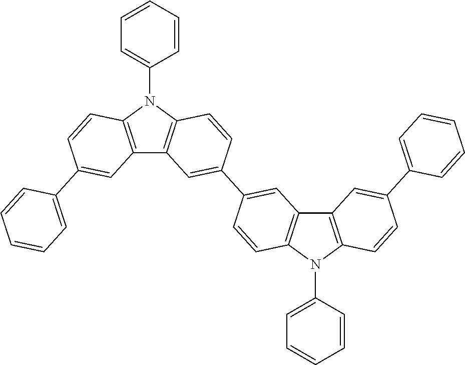 [SMILES: c1ccc(-c2ccc3c(c2)c2cc(-c4ccc5c(c4)c4cc(-c6ccccc6)ccc4n5-c4ccccc4)ccc2n3-c2ccccc2)cc1]

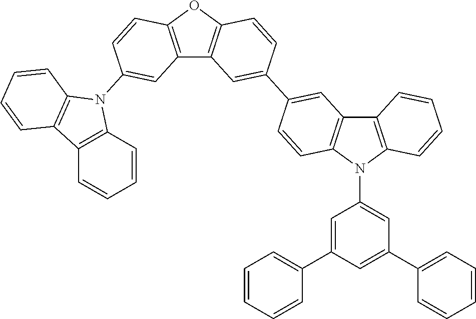 [SMILES: c1ccc(-c2cc(-c3ccccc3)cc(-n3c4ccccc4c4cc(-c5ccc6oc7ccc(-n8c9ccccc9c9ccccc98)cc7c6c5)ccc43)c2)cc1]

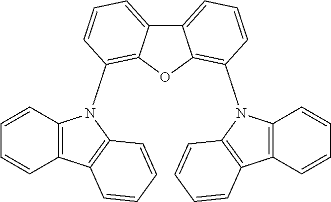 [SMILES: c1cc(-n2c3ccccc3c3ccccc32)c2oc3c(-n4c5ccccc5c5ccccc54)cccc3c2c1]

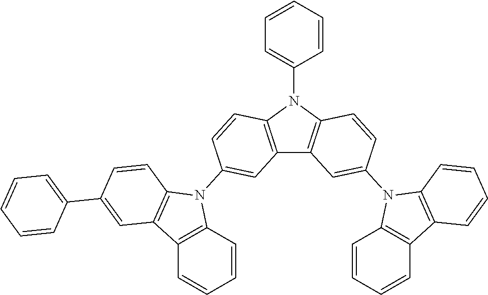 [SMILES: c1ccc(-c2ccc3c(c2)c2ccccc2n3-c2ccc3c(c2)c2cc(-n4c5ccccc5c5ccccc54)ccc2n3-c2ccccc2)cc1]

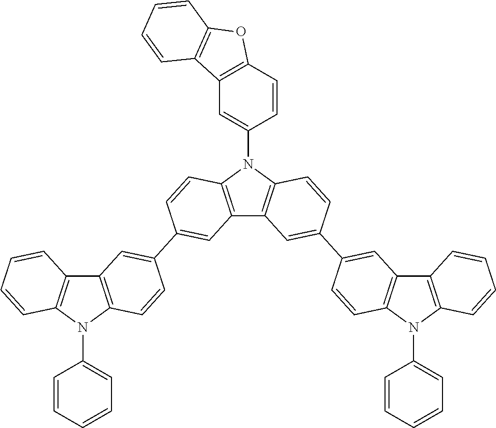 [SMILES: c1ccc(-n2c3ccccc3c3cc(-c4ccc5c(c4)c4cc(-c6ccc7c(c6)c6ccccc6n7-c6ccccc6)ccc4n5-c4ccc5oc6ccccc6c5c4)ccc32)cc1]

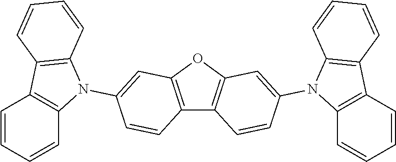 [SMILES: c1ccc2c(c1)c1ccccc1n2-c1ccc2c(c1)oc1cc(-n3c4ccccc4c4ccccc43)ccc12]

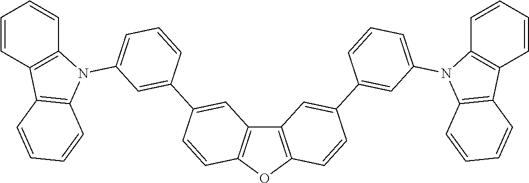 [SMILES: c1cc(-c2ccc3oc4ccc(-c5cccc(-n6c7ccccc7c7ccccc76)c5)cc4c3c2)cc(-n2c3ccccc3c3ccccc32)c1]

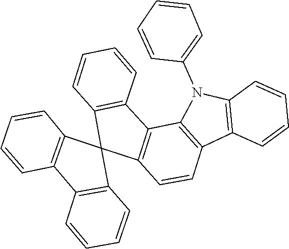 [SMILES: c1ccc(-n2c3ccccc3c3ccc4c(c32)-c2ccccc2C42c3ccccc3-c3ccccc32)cc1]

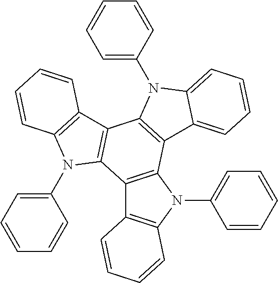 [SMILES: c1ccc(-n2c3ccccc3c3c2c2c4ccccc4n(-c4ccccc4)c2c2c4ccccc4n(-c4ccccc4)c32)cc1]

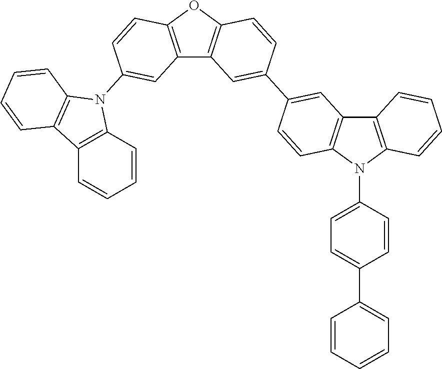 [SMILES: c1ccc(-c2ccc(-n3c4ccccc4c4cc(-c5ccc6oc7ccc(-n8c9ccccc9c9ccccc98)cc7c6c5)ccc43)cc2)cc1]

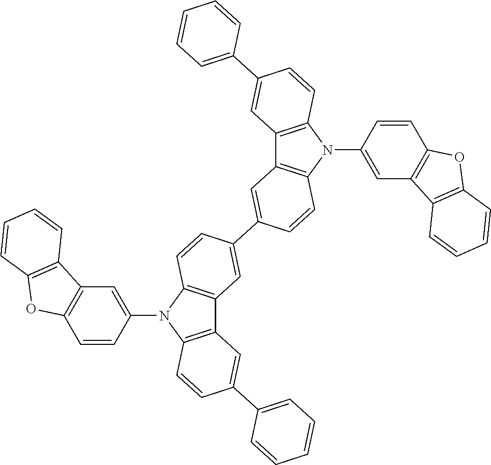 [SMILES: c1ccc(-c2ccc3c(c2)c2cc(-c4ccc5c(c4)c4cc(-c6ccccc6)ccc4n5-c4ccc5oc6ccccc6c5c4)ccc2n3-c2ccc3oc4ccccc4c3c2)cc1]

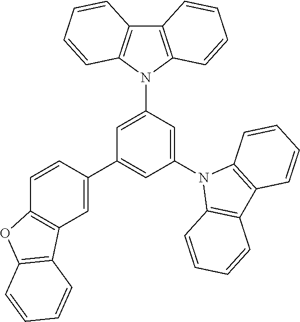 [SMILES: c1ccc2c(c1)oc1ccc(-c3cc(-n4c5ccccc5c5ccccc54)cc(-n4c5ccccc5c5ccccc54)c3)cc12]

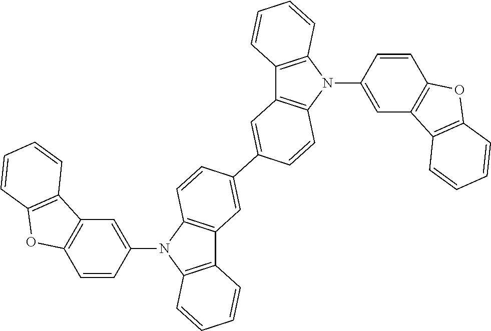 [SMILES: c1ccc2c(c1)oc1ccc(-n3c4ccccc4c4cc(-c5ccc6c(c5)c5ccccc5n6-c5ccc6oc7ccccc7c6c5)ccc43)cc12]

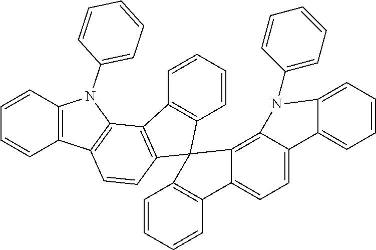 [SMILES: c1ccc(-n2c3ccccc3c3ccc4c(c32)-c2ccccc2C42c3ccccc3-c3ccc4c5ccccc5n(-c5ccccc5)c4c32)cc1]

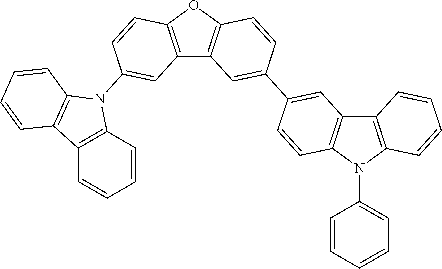 [SMILES: c1ccc(-n2c3ccccc3c3cc(-c4ccc5oc6ccc(-n7c8ccccc8c8ccccc87)cc6c5c4)ccc32)cc1]

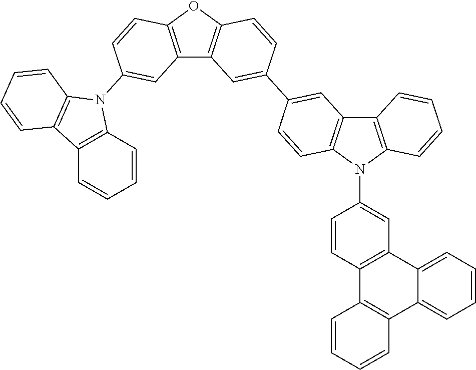 [SMILES: c1ccc2c(c1)c1ccccc1c1cc(-n3c4ccccc4c4cc(-c5ccc6oc7ccc(-n8c9ccccc9c9ccccc98)cc7c6c5)ccc43)ccc21]

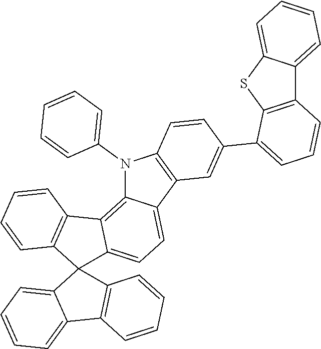 [SMILES: c1ccc(-n2c3ccc(-c4cccc5c4sc4ccccc45)cc3c3ccc4c(c32)-c2ccccc2C42c3ccccc3-c3ccccc32)cc1]

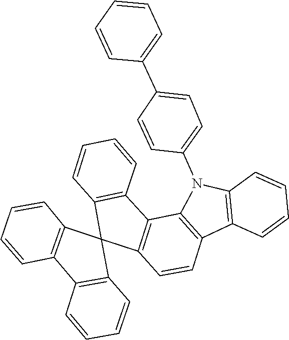 [SMILES: c1ccc(-c2ccc(-n3c4ccccc4c4ccc5c(c43)-c3ccccc3C53c4ccccc4-c4ccccc43)cc2)cc1]

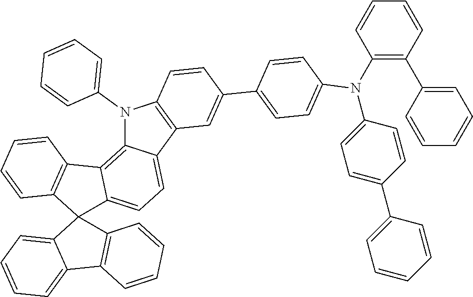 [SMILES: c1ccc(-c2ccc(N(c3ccc(-c4ccc5c(c4)c4ccc6c(c4n5-c4ccccc4)-c4ccccc4C64c5ccccc5-c5ccccc54)cc3)c3ccccc3-c3ccccc3)cc2)cc1]

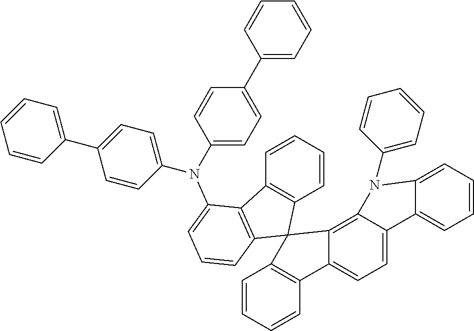 [SMILES: c1ccc(-c2ccc(N(c3ccc(-c4ccccc4)cc3)c3cccc4c3-c3ccccc3C43c4ccccc4-c4ccc5c6ccccc6n(-c6ccccc6)c5c43)cc2)cc1]

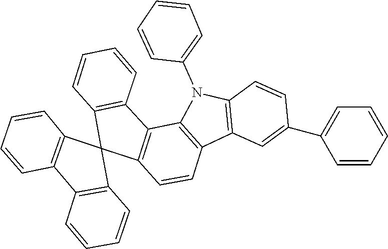 [SMILES: c1ccc(-c2ccc3c(c2)c2ccc4c(c2n3-c2ccccc2)-c2ccccc2C42c3ccccc3-c3ccccc32)cc1]

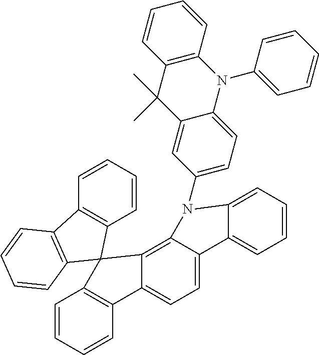 [SMILES: CC1(C)c2ccccc2N(c2ccccc2)c2ccc(-n3c4ccccc4c4ccc5c(c43)C3(c4ccccc4-c4ccccc43)c3ccccc3-5)cc21]

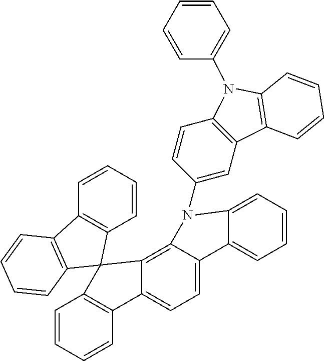 [SMILES: c1ccc(-n2c3ccccc3c3cc(-n4c5ccccc5c5ccc6c(c54)C4(c5ccccc5-c5ccccc54)c4ccccc4-6)ccc32)cc1]

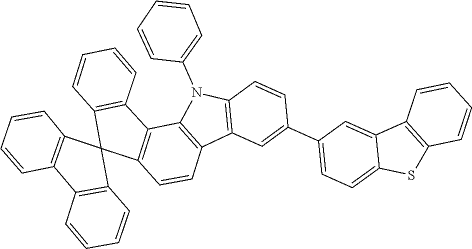 [SMILES: c1ccc(-n2c3ccc(-c4ccc5sc6ccccc6c5c4)cc3c3ccc4c(c32)-c2ccccc2C42c3ccccc3-c3ccccc32)cc1]

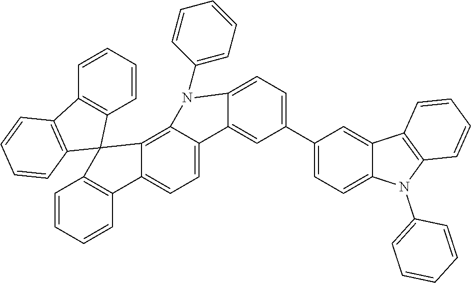 [SMILES: c1ccc(-n2c3ccccc3c3cc(-c4ccc5c(c4)c4ccc6c(c4n5-c4ccccc4)C4(c5ccccc5-c5ccccc54)c4ccccc4-6)ccc32)cc1]

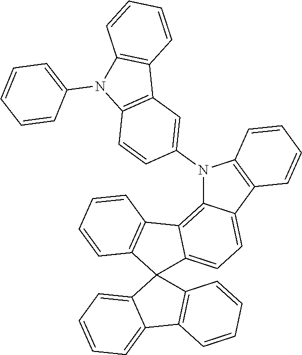 [SMILES: c1ccc(-n2c3ccccc3c3cc(-n4c5ccccc5c5ccc6c(c54)-c4ccccc4C64c5ccccc5-c5ccccc54)ccc32)cc1]

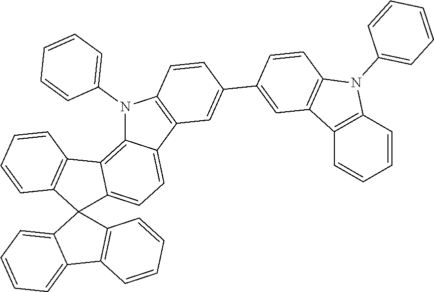 [SMILES: c1ccc(-n2c3ccccc3c3cc(-c4ccc5c(c4)c4ccc6c(c4n5-c4ccccc4)-c4ccccc4C64c5ccccc5-c5ccccc54)ccc32)cc1]

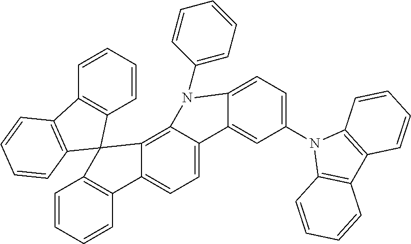 [SMILES: c1ccc(-n2c3ccc(-n4c5ccccc5c5ccccc54)cc3c3ccc4c(c32)C2(c3ccccc3-c3ccccc32)c2ccccc2-4)cc1]

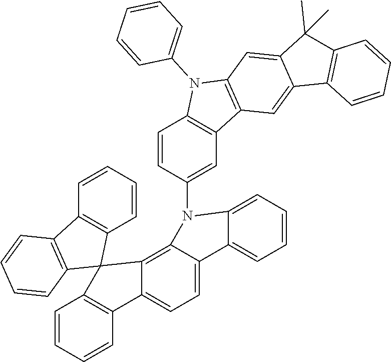 [SMILES: CC1(C)c2ccccc2-c2cc3c4cc(-n5c6ccccc6c6ccc7c(c65)C5(c6ccccc6-c6ccccc65)c5ccccc5-7)ccc4n(-c4ccccc4)c3cc21]

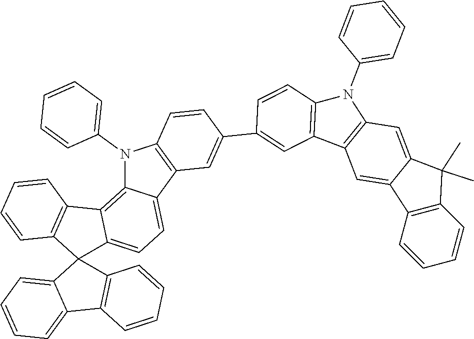 [SMILES: CC1(C)c2ccccc2-c2cc3c4cc(-c5ccc6c(c5)c5ccc7c(c5n6-c5ccccc5)-c5ccccc5C75c6ccccc6-c6ccccc65)ccc4n(-c4ccccc4)c3cc21]

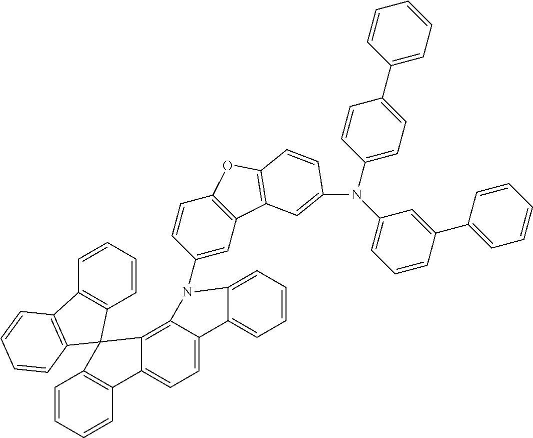 [SMILES: c1ccc(-c2ccc(N(c3cccc(-c4ccccc4)c3)c3ccc4oc5ccc(-n6c7ccccc7c7ccc8c(c76)C6(c7ccccc7-c7ccccc76)c6ccccc6-8)cc5c4c3)cc2)cc1]

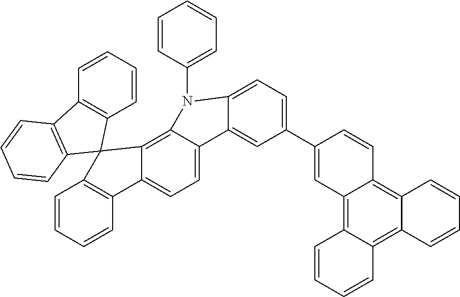 [SMILES: c1ccc(-n2c3ccc(-c4ccc5c6ccccc6c6ccccc6c5c4)cc3c3ccc4c(c32)C2(c3ccccc3-c3ccccc32)c2ccccc2-4)cc1]

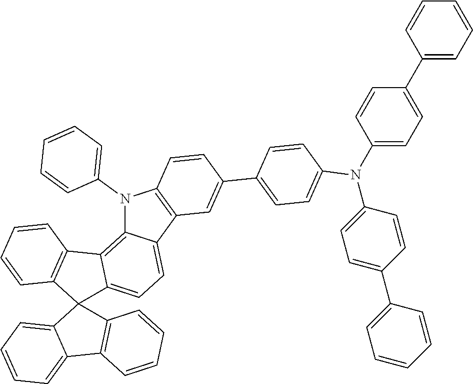 [SMILES: c1ccc(-c2ccc(N(c3ccc(-c4ccccc4)cc3)c3ccc(-c4ccc5c(c4)c4ccc6c(c4n5-c4ccccc4)-c4ccccc4C64c5ccccc5-c5ccccc54)cc3)cc2)cc1]

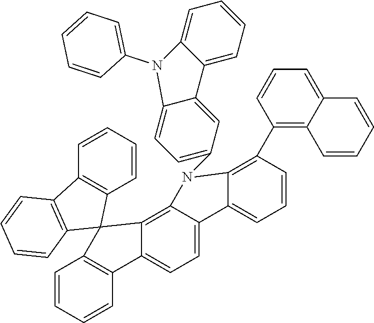 [SMILES: c1ccc(-n2c3ccccc3c3cc(-n4c5c(-c6cccc7ccccc67)cccc5c5ccc6c(c54)C4(c5ccccc5-c5ccccc54)c4ccccc4-6)ccc32)cc1]

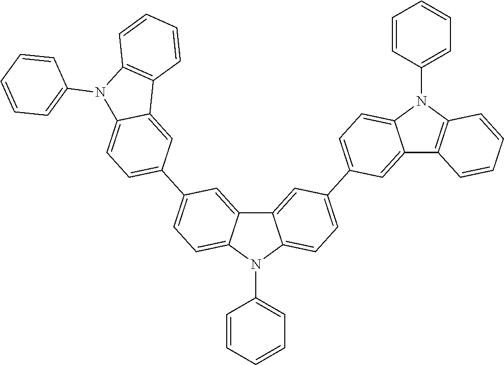 [SMILES: c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1]

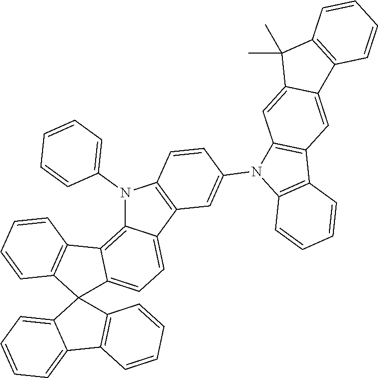 [SMILES: CC1(C)c2ccccc2-c2cc3c4ccccc4n(-c4ccc5c(c4)c4ccc6c(c4n5-c4ccccc4)-c4ccccc4C64c5ccccc5-c5ccccc54)c3cc21]

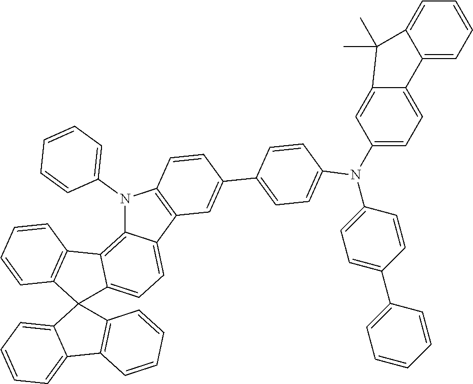 [SMILES: CC1(C)c2ccccc2-c2ccc(N(c3ccc(-c4ccccc4)cc3)c3ccc(-c4ccc5c(c4)c4ccc6c(c4n5-c4ccccc4)-c4ccccc4C64c5ccccc5-c5ccccc54)cc3)cc21]

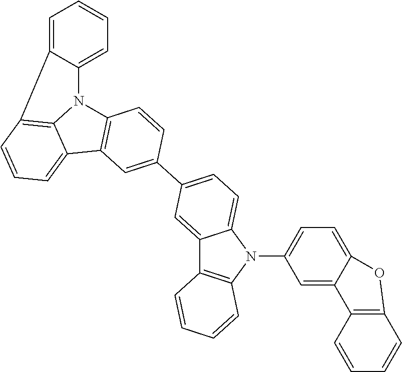 [SMILES: c1ccc2c(c1)oc1ccc(-n3c4ccccc4c4cc(-c5ccc6c(c5)c5cccc7c8ccccc8n6c75)ccc43)cc12]

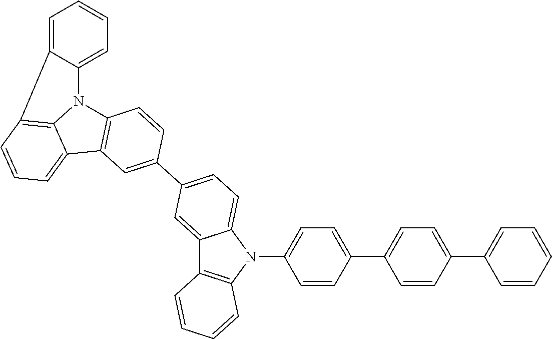 [SMILES: c1ccc(-c2ccc(-c3ccc(-n4c5ccccc5c5cc(-c6ccc7c(c6)c6cccc8c9ccccc9n7c86)ccc54)cc3)cc2)cc1]

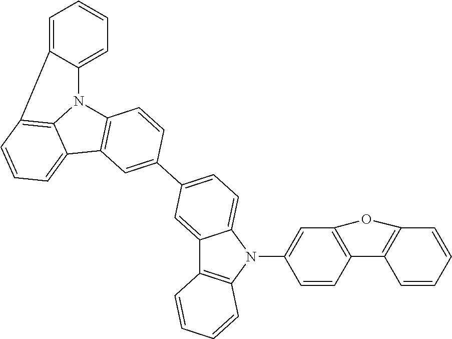 [SMILES: c1ccc2c(c1)oc1cc(-n3c4ccccc4c4cc(-c5ccc6c(c5)c5cccc7c8ccccc8n6c75)ccc43)ccc12]

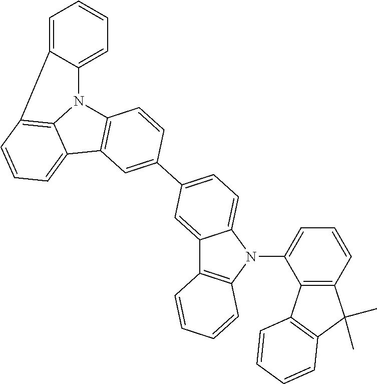 [SMILES: CC1(C)c2ccccc2-c2c(-n3c4ccccc4c4cc(-c5ccc6c(c5)c5cccc7c8ccccc8n6c75)ccc43)cccc21]

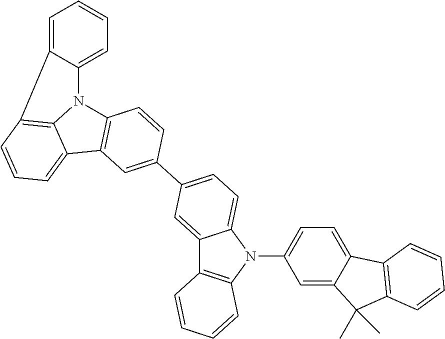 [SMILES: CC1(C)c2ccccc2-c2ccc(-n3c4ccccc4c4cc(-c5ccc6c(c5)c5cccc7c8ccccc8n6c75)ccc43)cc21]

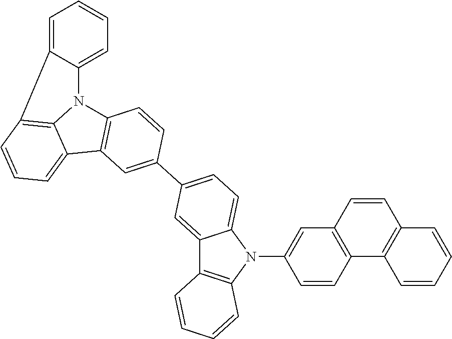 [SMILES: c1ccc2c(c1)ccc1cc(-n3c4ccccc4c4cc(-c5ccc6c(c5)c5cccc7c8ccccc8n6c75)ccc43)ccc12]

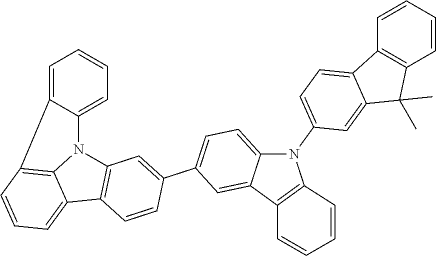 [SMILES: CC1(C)c2ccccc2-c2ccc(-n3c4ccccc4c4cc(-c5ccc6c7cccc8c9ccccc9n(c6c5)c87)ccc43)cc21]

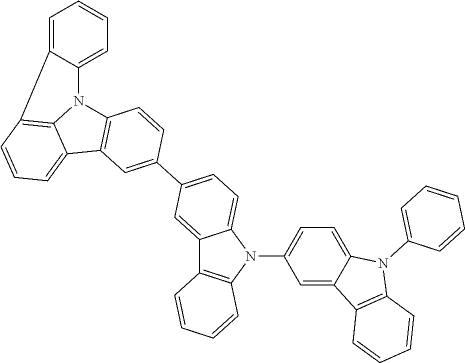 [SMILES: c1ccc(-n2c3ccccc3c3cc(-n4c5ccccc5c5cc(-c6ccc7c(c6)c6cccc8c9ccccc9n7c86)ccc54)ccc32)cc1]

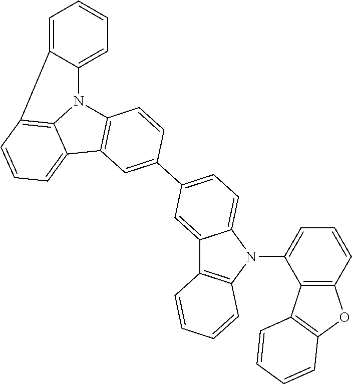 [SMILES: c1ccc2c(c1)oc1cccc(-n3c4ccccc4c4cc(-c5ccc6c(c5)c5cccc7c8ccccc8n6c75)ccc43)c12]

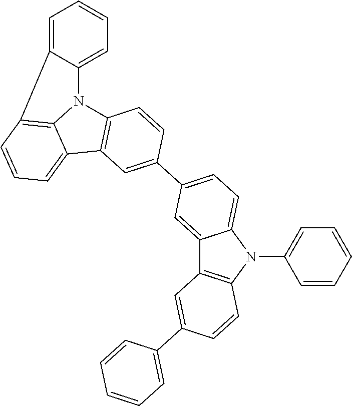 [SMILES: c1ccc(-c2ccc3c(c2)c2cc(-c4ccc5c(c4)c4cccc6c7ccccc7n5c64)ccc2n3-c2ccccc2)cc1]

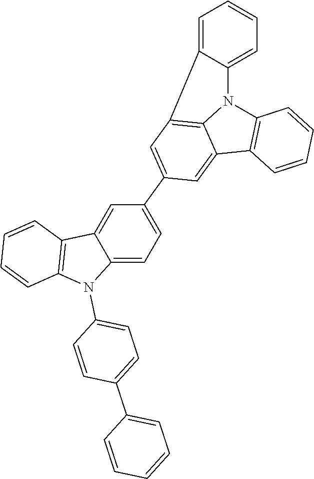 [SMILES: c1ccc(-c2ccc(-n3c4ccccc4c4cc(-c5cc6c7ccccc7n7c8ccccc8c(c5)c67)ccc43)cc2)cc1]

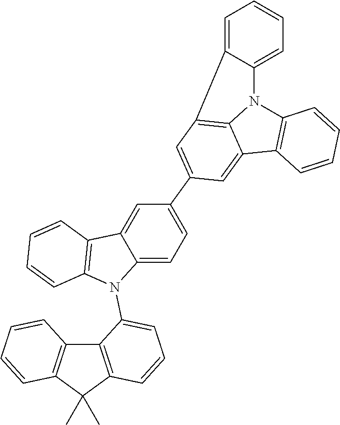 [SMILES: CC1(C)c2ccccc2-c2c(-n3c4ccccc4c4cc(-c5cc6c7ccccc7n7c8ccccc8c(c5)c67)ccc43)cccc21]

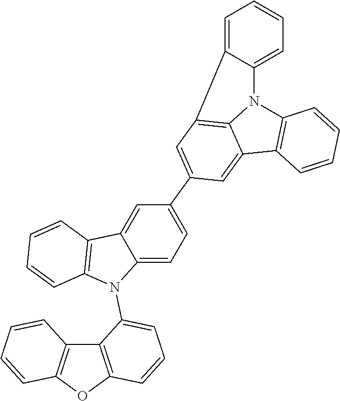 [SMILES: c1ccc2c(c1)oc1cccc(-n3c4ccccc4c4cc(-c5cc6c7ccccc7n7c8ccccc8c(c5)c67)ccc43)c12]

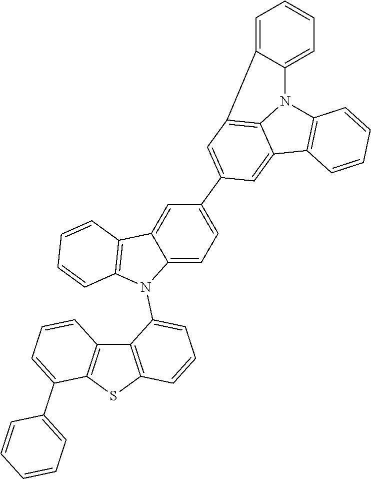 [SMILES: c1ccc(-c2cccc3c2sc2cccc(-n4c5ccccc5c5cc(-c6cc7c8ccccc8n8c9ccccc9c(c6)c78)ccc54)c23)cc1]

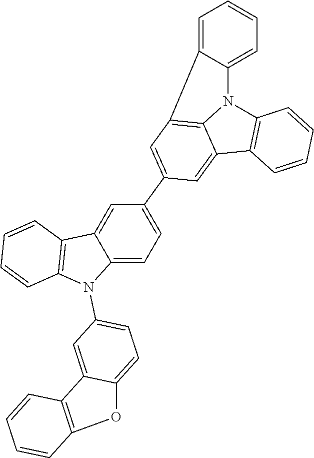 [SMILES: c1ccc2c(c1)oc1ccc(-n3c4ccccc4c4cc(-c5cc6c7ccccc7n7c8ccccc8c(c5)c67)ccc43)cc12]

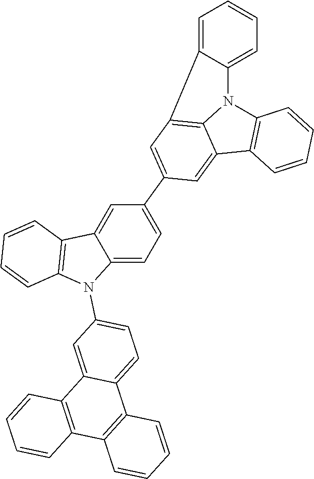 [SMILES: c1ccc2c(c1)c1ccccc1c1cc(-n3c4ccccc4c4cc(-c5cc6c7ccccc7n7c8ccccc8c(c5)c67)ccc43)ccc21]

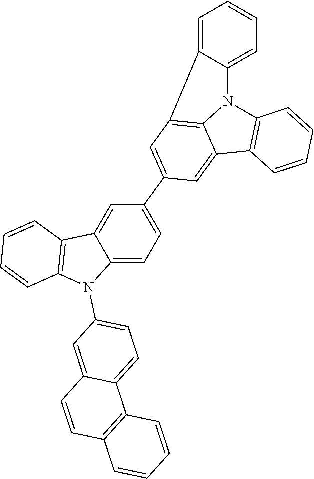 [SMILES: c1ccc2c(c1)ccc1cc(-n3c4ccccc4c4cc(-c5cc6c7ccccc7n7c8ccccc8c(c5)c67)ccc43)ccc12]

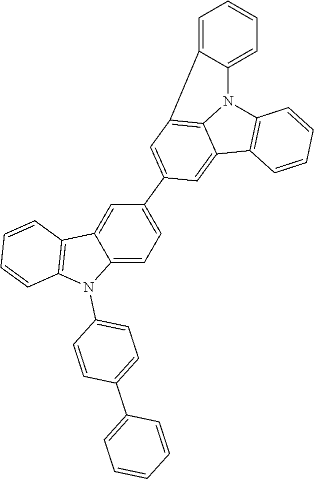 [SMILES: c1ccc(-c2ccc(-n3c4ccccc4c4cc(-c5cc6c7ccccc7n7c8ccccc8c(c5)c67)ccc43)cc2)cc1]

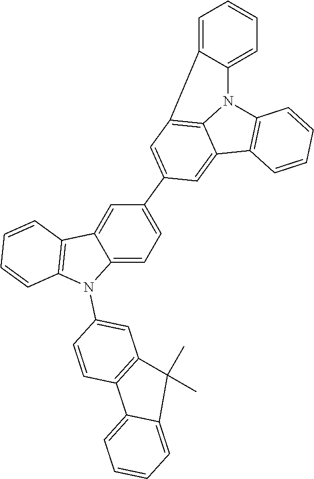 [SMILES: CC1(C)c2ccccc2-c2ccc(-n3c4ccccc4c4cc(-c5cc6c7ccccc7n7c8ccccc8c(c5)c67)ccc43)cc21]

Particularly suitable examples of compounds of the formula (2), (2a), (2b), (2c), (2d), (2e), (2f), (2g), (2h) and (2i) that are selected in accordance with the invention are the compounds 37 to 66a:

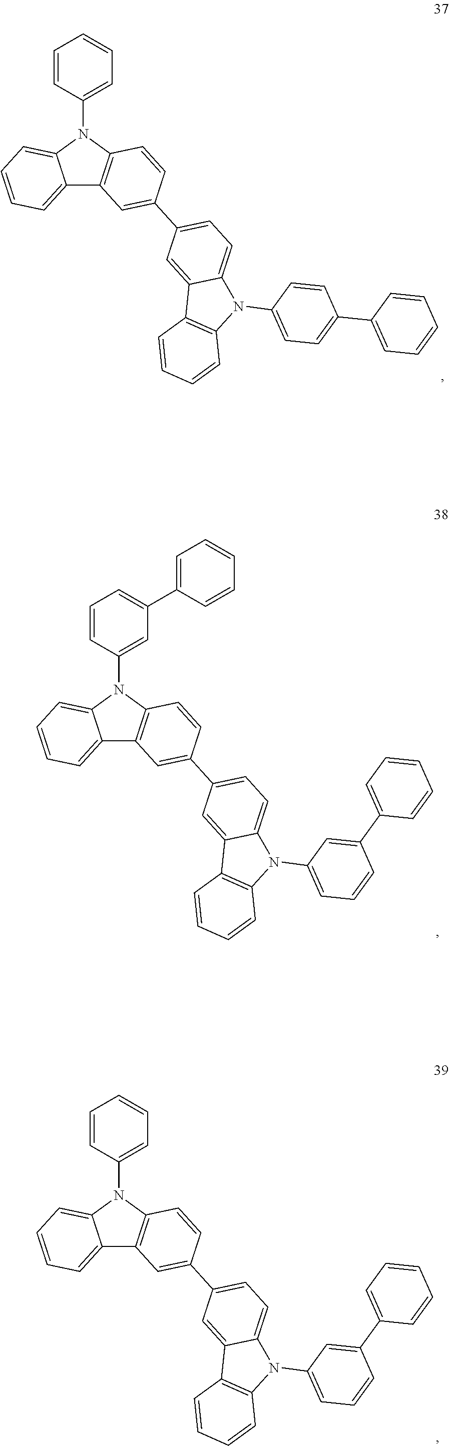 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-c5ccc6c(c5)c5ccccc5n6-c5ccccc5)ccc43)c2)cc1]

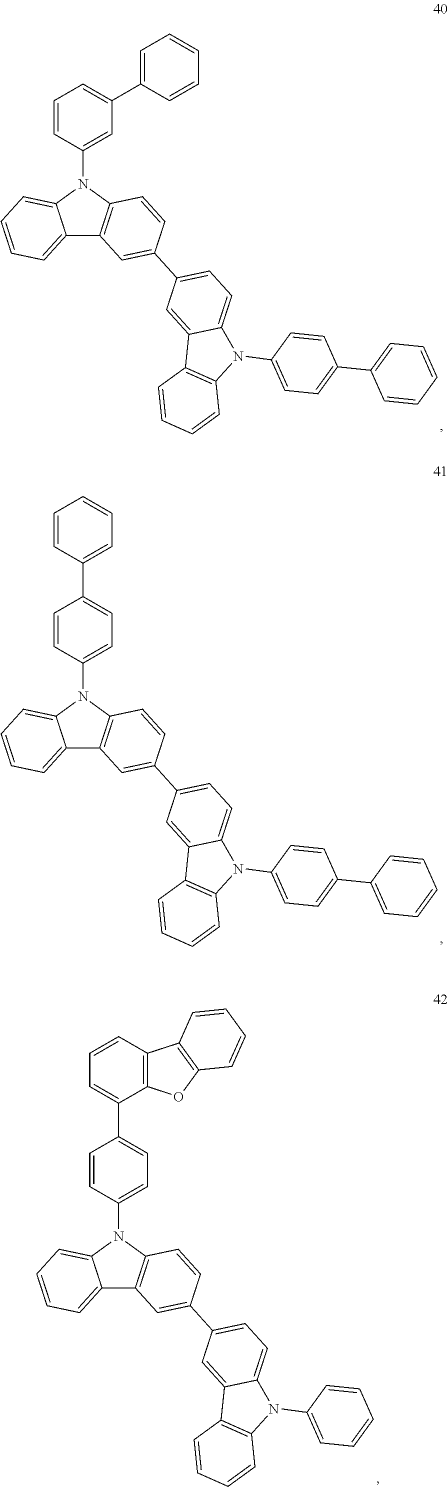 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-n2c3ccccc3c3cc(-c4ccc5c(c4)c4ccccc4n5-c4ccc(-c5cccc6c5oc5ccccc56)cc4)ccc32)cc1]

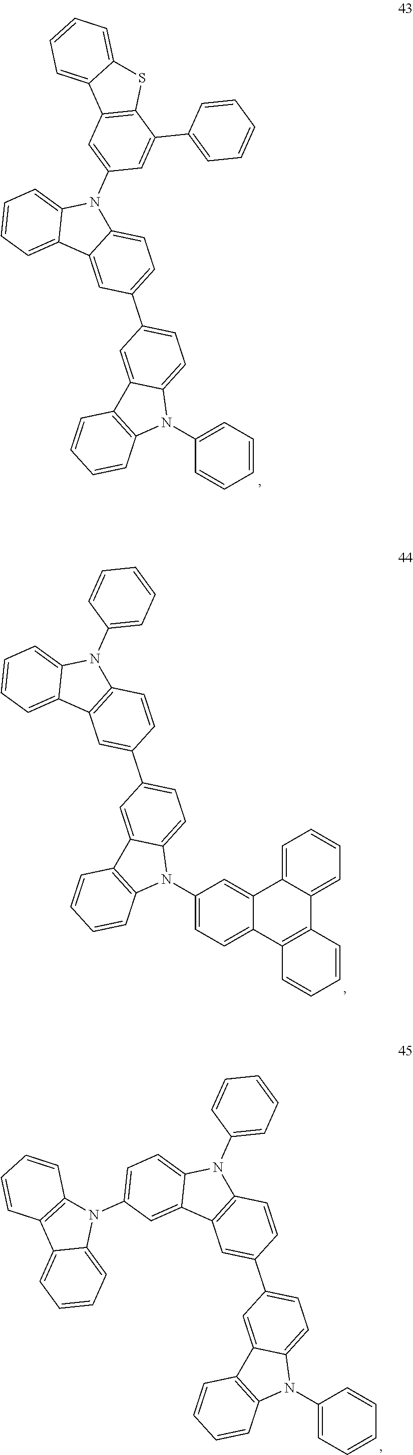 [SMILES: c1ccc(-c2cc(-n3c4ccccc4c4cc(-c5ccc6c(c5)c5ccccc5n6-c5ccccc5)ccc43)cc3c2sc2ccccc23)cc1 ; c1ccc(-n2c3ccccc3c3cc(-c4ccc5c(c4)c4ccccc4n5-c4ccc5c6ccccc6c6ccccc6c5c4)ccc32)cc1 ; c1ccc(-n2c3ccccc3c3cc(-c4ccc5c(c4)c4cc(-n6c7ccccc7c7ccccc76)ccc4n5-c4ccccc4)ccc32)cc1]

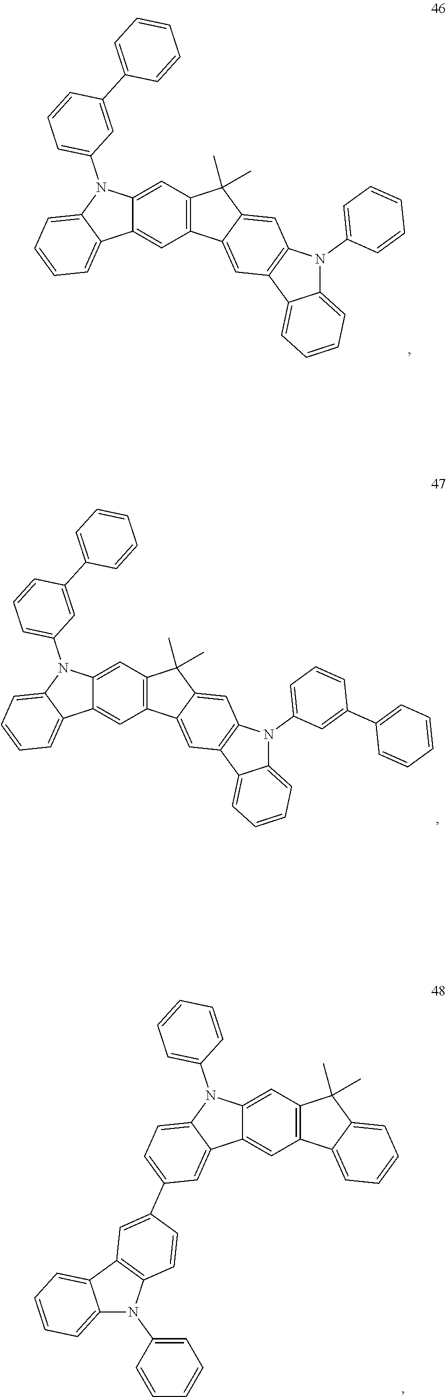 [SMILES: CC1(C)c2cc3c(cc2-c2cc4c5ccccc5n(-c5cccc(-c6ccccc6)c5)c4cc21)c1ccccc1n3-c1ccccc1 ; CC1(C)c2cc3c(cc2-c2cc4c5ccccc5n(-c5cccc(-c6ccccc6)c5)c4cc21)c1ccccc1n3-c1cccc(-c2ccccc2)c1 ; CC1(C)c2ccccc2-c2cc3c4cc(-c5ccc6c(c5)c5ccccc5n6-c5ccccc5)ccc4n(-c4ccccc4)c3cc21]

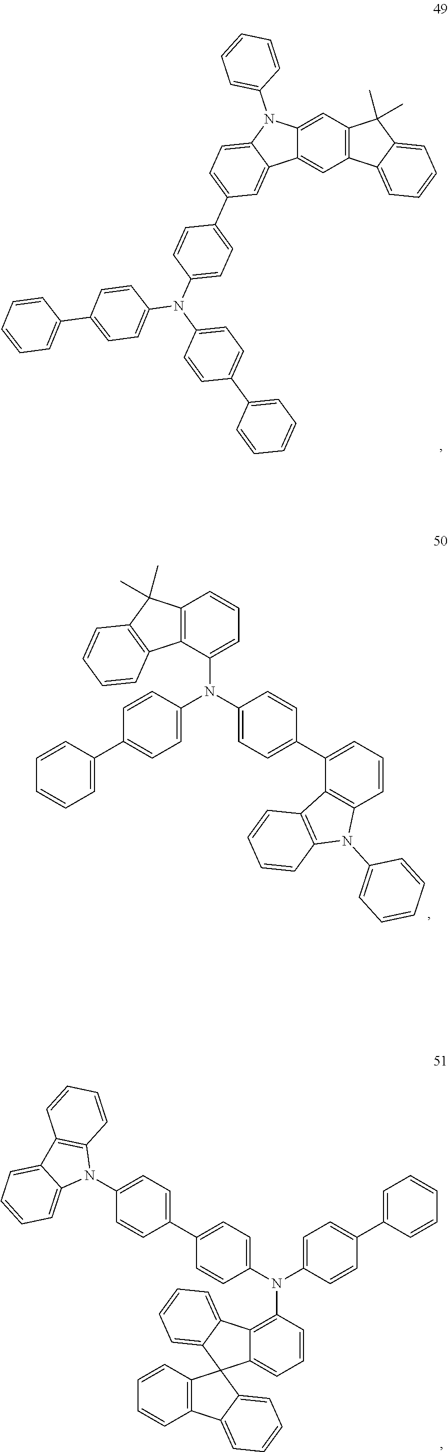 [SMILES: CC1(C)c2ccccc2-c2cc3c4cc(-c5ccc(N(c6ccc(-c7ccccc7)cc6)c6ccc(-c7ccccc7)cc6)cc5)ccc4n(-c4ccccc4)c3cc21 ; CC1(C)c2ccccc2-c2c(N(c3ccc(-c4ccccc4)cc3)c3ccc(-c4cccc5c4c4ccccc4n5-c4ccccc4)cc3)cccc21 ; c1ccc(-c2ccc(N(c3ccc(-c4ccc(-n5c6ccccc6c6ccccc65)cc4)cc3)c3cccc4c3-c3ccccc3C43c4ccccc4-c4ccccc43)cc2)cc1]

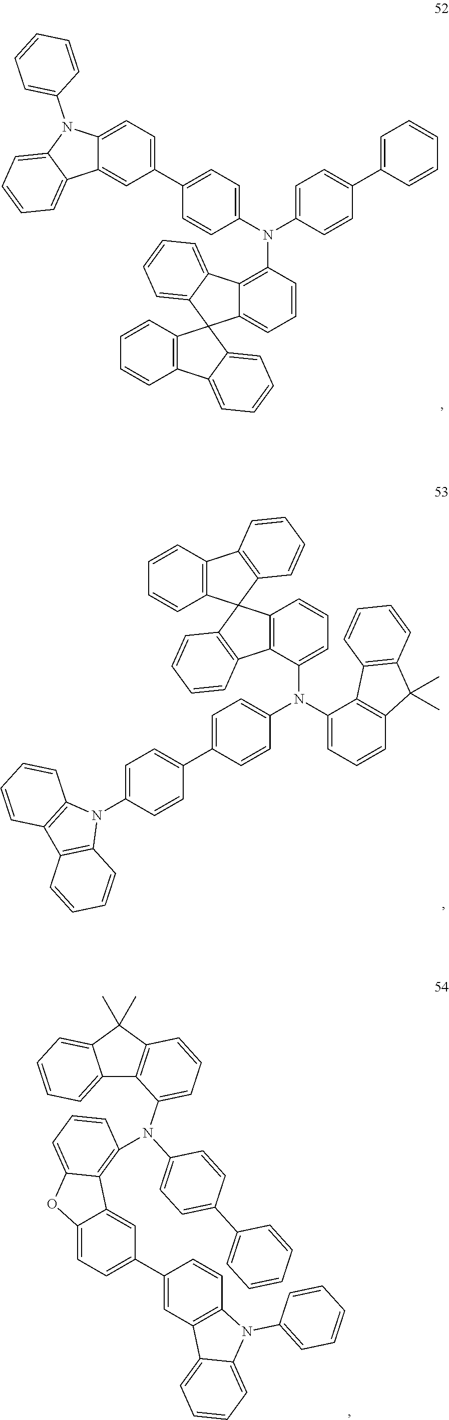 [SMILES: c1ccc(-c2ccc(N(c3ccc(-c4ccc5c(c4)c4ccccc4n5-c4ccccc4)cc3)c3cccc4c3-c3ccccc3C43c4ccccc4-c4ccccc43)cc2)cc1 ; CC1(C)c2ccccc2-c2c(N(c3ccc(-c4ccc(-n5c6ccccc6c6ccccc65)cc4)cc3)c3cccc4c3-c3ccccc3C43c4ccccc4-c4ccccc43)cccc21 ; CC1(C)c2ccccc2-c2c(N(c3ccc(-c4ccccc4)cc3)c3cccc4oc5ccc(-c6ccc7c(c6)c6ccccc6n7-c6ccccc6)cc5c34)cccc21]

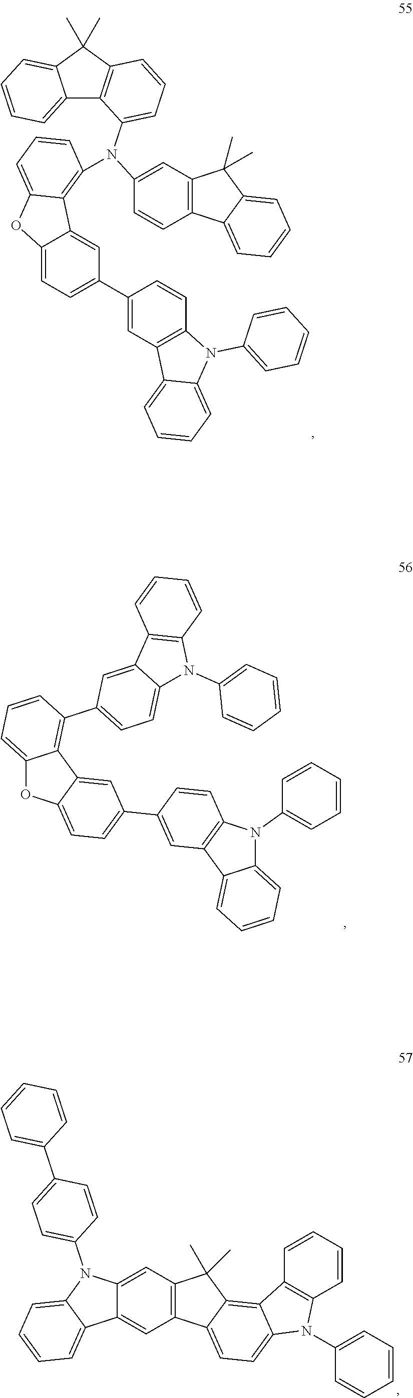 [SMILES: CC1(C)c2ccccc2-c2ccc(N(c3cccc4c3-c3ccccc3C4(C)C)c3cccc4oc5ccc(-c6ccc7c(c6)c6ccccc6n7-c6ccccc6)cc5c34)cc21 ; c1ccc(-n2c3ccccc3c3cc(-c4ccc5oc6cccc(-c7ccc8c(c7)c7ccccc7n8-c7ccccc7)c6c5c4)ccc32)cc1 ; CC1(C)c2cc3c(cc2-c2ccc4c(c21)c1ccccc1n4-c1ccccc1)c1ccccc1n3-c1ccc(-c2ccccc2)cc1]

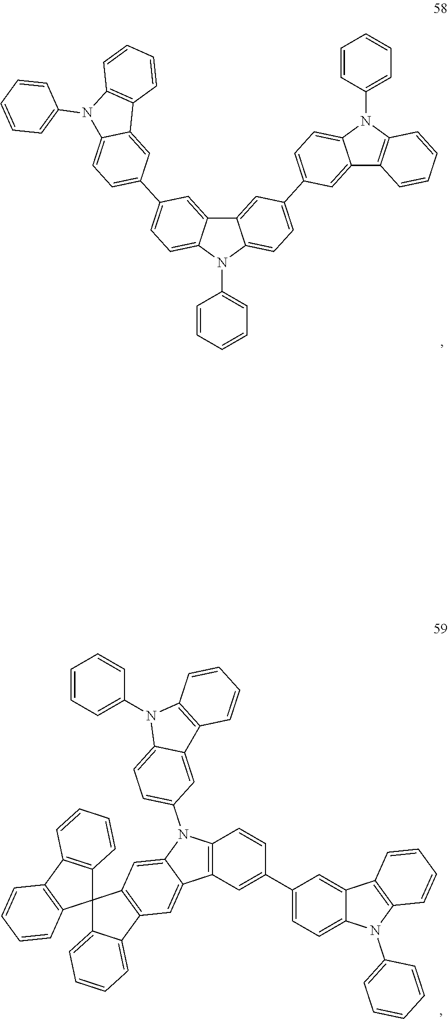 [SMILES: c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1 ; c1ccc(-n2c3ccccc3c3cc(-c4ccc5c(c4)c4cc6c(cc4n5-c4ccc5c(c4)c4ccccc4n5-c4ccccc4)C4(c5ccccc5-c5ccccc54)c4ccccc4-6)ccc32)cc1]

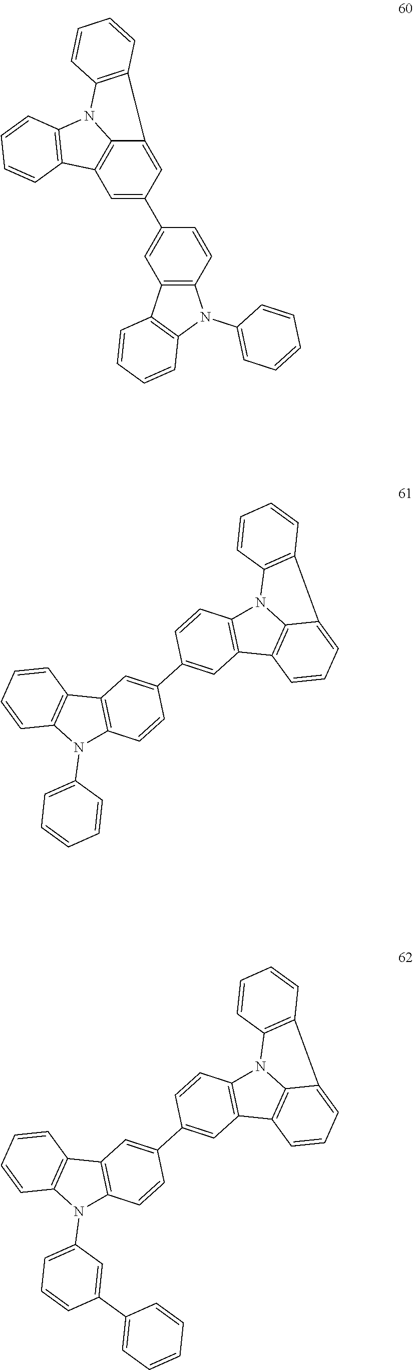 [SMILES: c1ccc(-n2c3ccccc3c3cc(-c4cc5c6ccccc6n6c7ccccc7c(c4)c56)ccc32)cc1 ; c1ccc(-n2c3ccccc3c3cc(-c4ccc5c(c4)c4cccc6c7ccccc7n5c64)ccc32)cc1 ; c1ccc(-c2cccc(-n3c4ccccc4c4cc(-c5ccc6c(c5)c5cccc7c8ccccc8n6c75)ccc43)c2)cc1]

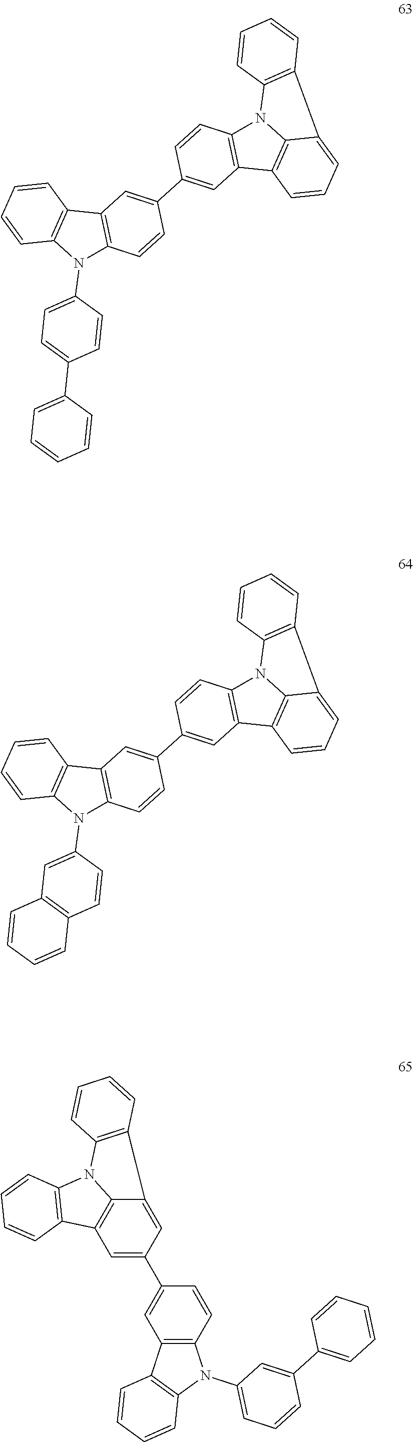 [SMILES: c1ccc(-c2ccc(-n3c4ccccc4c4cc(-c5ccc6c(c5)c5cccc7c8ccccc8n6c75)ccc43)cc2)cc1 ; c1ccc2cc(-n3c4ccccc4c4cc(-c5ccc6c(c5)c5cccc7c8ccccc8n6c75)ccc43)ccc2c1 ; c1ccc(-c2cccc(-n3c4ccccc4c4cc(-c5cc6c7ccccc7n7c8ccccc8c(c5)c67)ccc43)c2)cc1]

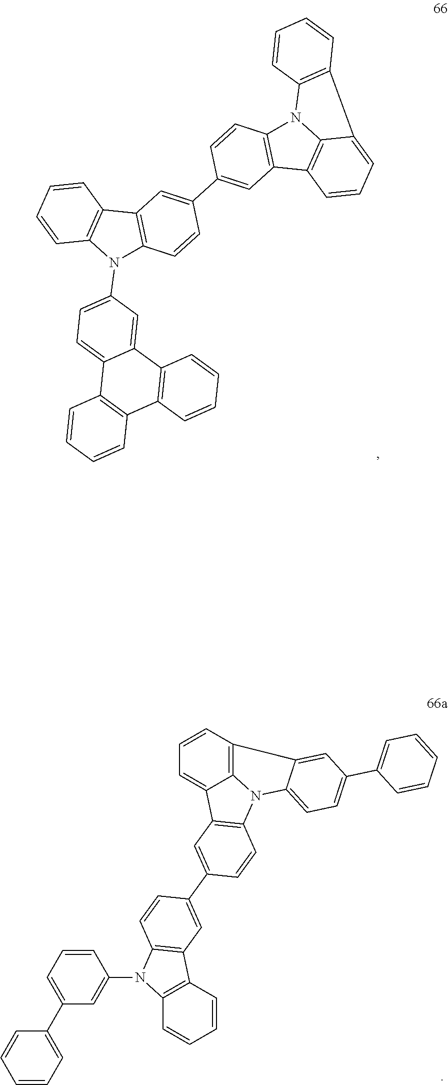 [SMILES: c1ccc2c(c1)c1ccccc1c1cc(-n3c4ccccc4c4cc(-c5ccc6c(c5)c5cccc7c8ccccc8n6c75)ccc43)ccc21 ; c1ccc(-c2cccc(-n3c4ccccc4c4cc(-c5ccc6c(c5)c5cccc7c8cc(-c9ccccc9)ccc8n6c75)ccc43)c2)cc1]

The preparation of the compounds of the formula (2) or preferred compounds of the formulae (2), (2a), (2b), (2c), (2d), (2e), (2f), (2g), (2h), (2i), (2j), (2k) and (2l) and of the compounds from Table 2 and 37 to 66a is known to the person skilled in the art. The compounds may be prepared by synthesis steps known to the person skilled in the art, for example halogenation, preferably bromination, and a subsequent organometallic coupling reaction, for example Suzuki coupling, Heck coupling or Hartwig-Buchwald coupling. Some of the compounds of the formula (2) are commercially available.

The aforementioned host materials of the formulae (1), (1a), (1b), (1c), (1d), (1e), (1f), (1g) or (1h) and the embodiments thereof described as preferred or the compounds from Table 1 and the compounds 1 to 36 and 67 to 81 can be combined in accordance with the invention as desired with the above host materials of the formulae (2), (2a), (2b), (2c), (2d), (2e), (2f), (2g), (2h), (2i), (2j), (2k) and (2l) and the embodiments thereof described as preferred or the compounds from Table 2 or the compounds 37 to 66a.

Particularly preferred mixtures of the host materials of the formula (1) with the host materials of the formula (2) for the composition of the invention or organic electronic device of the invention are obtained by combination of the compounds 1 to 36 and 67 to 81 with the compounds from Table 2.

Very particularly preferred mixtures of the host materials of the formula (1) with the host materials of the formula (2) for the composition of the invention or for the organic electronic device of the invention are obtained by combination of the compounds 1 to 36 and 67 to 81 with the compounds 37 to 66a, as shown below in Table 3.

TABLE 3

| | | | | | | | | |
|---|---|---|---|---|---|---|---|---|
| M1 | 1 | 37 | M2 | 1 | 38 | M3 | 1 | 39 |
| M4 | 1 | 40 | M5 | 1 | 41 | M6 | 1 | 42 |
| M7 | 1 | 43 | M8 | 1 | 44 | M9 | 1 | 45 |
| M10 | 1 | 46 | M11 | 1 | 47 | M12 | 1 | 48 |
| M13 | 1 | 49 | M14 | 1 | 50 | M15 | 1 | 51 |
| M16 | 1 | 52 | M17 | 1 | 53 | M18 | 1 | 54 |
| M19 | 1 | 55 | M20 | 1 | 56 | M21 | 1 | 57 |
| M22 | 1 | 58 | M23 | 1 | 59 | | | |
| M24 | 2 | 37 | M25 | 2 | 38 | M26 | 2 | 39 |
| M27 | 2 | 40 | M28 | 2 | 41 | M29 | 2 | 42 |
| M30 | 2 | 43 | M31 | 2 | 44 | M32 | 2 | 45 |
| M33 | 2 | 46 | M34 | 2 | 47 | M35 | 2 | 48 |
| M36 | 2 | 49 | M37 | 2 | 50 | M38 | 2 | 51 |
| M39 | 2 | 52 | M40 | 2 | 53 | M41 | 2 | 54 |
| M42 | 2 | 55 | M43 | 2 | 56 | M44 | 2 | 57 |
| M45 | 2 | 58 | M46 | 2 | 59 | | | |
| M47 | 3 | 37 | M48 | 3 | 38 | M49 | 3 | 39 |
| M50 | 3 | 40 | M51 | 3 | 41 | M52 | 3 | 42 |
| M53 | 3 | 43 | M54 | 3 | 44 | M55 | 3 | 45 |
| M56 | 3 | 46 | M57 | 3 | 47 | M58 | 3 | 48 |
| M59 | 3 | 49 | M60 | 3 | 50 | M61 | 3 | 51 |
| M62 | 3 | 52 | M63 | 3 | 53 | M64 | 3 | 54 |
| M65 | 3 | 55 | M66 | 3 | 56 | M67 | 3 | 57 |
| M68 | 3 | 58 | M69 | 3 | 59 | | | |
| M70 | 4 | 37 | M71 | 4 | 38 | M72 | 4 | 39 |
| M73 | 4 | 40 | M74 | 4 | 41 | M75 | 4 | 42 |
| M76 | 4 | 43 | M77 | 4 | 44 | M78 | 4 | 45 |
| M79 | 4 | 46 | M80 | 4 | 47 | M81 | 4 | 48 |
| M82 | 4 | 49 | M83 | 4 | 50 | M84 | 4 | 51 |
| M85 | 4 | 52 | M86 | 4 | 53 | M87 | 4 | 54 |
| M88 | 4 | 55 | M89 | 4 | 56 | M90 | 4 | 57 |
| M91 | 4 | 58 | M92 | 4 | 59 | | | |
| M93 | 5 | 37 | M94 | 5 | 38 | M95 | 5 | 39 |
| M96 | 5 | 40 | M97 | 5 | 41 | M98 | 5 | 42 |
| M99 | 5 | 43 | M100 | 5 | 44 | M101 | 5 | 45 |
| M102 | 5 | 46 | M103 | 5 | 47 | M104 | 5 | 48 |
| M105 | 5 | 49 | M106 | 5 | 50 | M107 | 5 | 51 |
| M108 | 5 | 52 | M109 | 5 | 53 | M110 | 5 | 54 |
| M111 | 5 | 55 | M112 | 5 | 56 | M113 | 5 | 57 |
| M114 | 5 | 58 | M115 | 5 | 59 | | | |
| M116 | 6 | 37 | M117 | 6 | 38 | M118 | 6 | 39 |
| M119 | 6 | 40 | M120 | 6 | 41 | M121 | 6 | 42 |
| M122 | 6 | 43 | M123 | 6 | 44 | M124 | 6 | 45 |
| M125 | 6 | 46 | M126 | 6 | 47 | M127 | 6 | 48 |
| M128 | 6 | 49 | M129 | 6 | 50 | M130 | 6 | 51 |
| M131 | 6 | 52 | M132 | 6 | 53 | M133 | 6 | 54 |
| M134 | 6 | 55 | M135 | 6 | 56 | M136 | 6 | 57 |
| M137 | 6 | 58 | M138 | 6 | 59 | | | |
| M139 | 7 | 37 | M140 | 7 | 38 | M141 | 7 | 39 |
| M142 | 7 | 40 | M143 | 7 | 41 | M144 | 7 | 42 |
| M145 | 7 | 43 | M146 | 7 | 44 | M147 | 7 | 45 |
| M148 | 7 | 46 | M149 | 7 | 47 | M150 | 7 | 48 |
| M151 | 7 | 49 | M152 | 7 | 50 | M153 | 7 | 51 |
| M154 | 7 | 52 | M155 | 7 | 53 | M156 | 7 | 54 |
| M157 | 7 | 55 | M158 | 7 | 56 | M159 | 7 | 57 |
| M160 | 7 | 58 | M161 | 7 | 59 | | | |
| M162 | 8 | 37 | M163 | 8 | 38 | M164 | 8 | 39 |
| M165 | 8 | 40 | M166 | 8 | 41 | M167 | 8 | 42 |
| M168 | 8 | 43 | M169 | 8 | 44 | M170 | 8 | 45 |
| M171 | 8 | 46 | M172 | 8 | 47 | M173 | 8 | 48 |
| M174 | 8 | 49 | M175 | 8 | 50 | M176 | 8 | 51 |
| M177 | 8 | 52 | M178 | 8 | 53 | M179 | 8 | 54 |
| M180 | 8 | 55 | M181 | 8 | 56 | M182 | 8 | 57 |
| M183 | 8 | 58 | M184 | 8 | 59 | | | |
| M185 | 9 | 37 | M186 | 9 | 38 | M187 | 9 | 39 |
| M188 | 9 | 40 | M189 | 9 | 41 | M190 | 9 | 42 |
| M191 | 9 | 43 | M192 | 9 | 44 | M193 | 9 | 45 |
| M194 | 9 | 46 | M195 | 9 | 47 | M196 | 9 | 48 |
| M197 | 9 | 49 | M198 | 9 | 50 | M199 | 9 | 51 |
| M200 | 9 | 52 | M201 | 9 | 53 | M202 | 9 | 54 |
| M203 | 9 | 55 | M204 | 9 | 56 | M205 | 9 | 57 |
| M206 | 9 | 58 | M207 | 9 | 59 | | | |
| M208 | 10 | 37 | M209 | 10 | 38 | M210 | 10 | 39 |
| M211 | 10 | 40 | M212 | 10 | 41 | M213 | 10 | 42 |
| M214 | 10 | 43 | M215 | 10 | 44 | M216 | 10 | 45 |
| M217 | 10 | 46 | M218 | 10 | 47 | M219 | 10 | 48 |
| M220 | 10 | 49 | M221 | 10 | 50 | M222 | 10 | 51 |
| M223 | 10 | 52 | M224 | 10 | 53 | M225 | 10 | 54 |
| M226 | 10 | 55 | M227 | 10 | 56 | M228 | 10 | 57 |
| M229 | 10 | 58 | M230 | 10 | 59 | | | |
| M231 | 11 | 37 | M232 | 11 | 38 | M233 | 11 | 39 |
| M234 | 11 | 40 | M235 | 11 | 41 | M236 | 11 | 42 |
| M237 | 11 | 43 | M238 | 11 | 44 | M239 | 11 | 45 |
| M240 | 11 | 46 | M241 | 11 | 47 | M242 | 11 | 48 |
| M243 | 11 | 49 | M244 | 11 | 50 | M245 | 11 | 51 |
| M246 | 11 | 52 | M247 | 11 | 53 | M248 | 11 | 54 |
| M249 | 11 | 55 | M250 | 11 | 56 | M251 | 11 | 57 |
| M252 | 11 | 58 | M253 | 11 | 59 | | | |
| M254 | 11 | 61 | M255 | 11 | 62 | M256 | 11 | 63 |
| M257 | 12 | 37 | M258 | 12 | 38 | M259 | 12 | 39 |
| M260 | 12 | 40 | M261 | 12 | 41 | M262 | 12 | 42 |
| M263 | 12 | 43 | M264 | 12 | 44 | M265 | 12 | 45 |
| M266 | 12 | 46 | M267 | 12 | 47 | M268 | 12 | 48 |
| M269 | 12 | 49 | M270 | 12 | 50 | M271 | 12 | 51 |
| M272 | 12 | 52 | M273 | 12 | 53 | M274 | 12 | 54 |
| M275 | 12 | 55 | M276 | 12 | 56 | M277 | 12 | 57 |
| M278 | 12 | 58 | M279 | 12 | 59 | | | |
| M280 | 13 | 37 | M281 | 13 | 38 | M282 | 13 | 39 |
| M283 | 13 | 40 | M284 | 13 | 41 | M285 | 13 | 42 |
| M286 | 13 | 43 | M287 | 13 | 44 | M288 | 13 | 45 |
| M289 | 13 | 46 | M290 | 13 | 47 | M291 | 13 | 48 |
| M292 | 13 | 49 | M293 | 13 | 50 | M294 | 13 | 51 |
| M295 | 13 | 52 | M296 | 13 | 53 | M297 | 13 | 54 |
| M298 | 13 | 55 | M299 | 13 | 56 | M300 | 13 | 57 |
| M301 | 13 | 58 | M302 | 13 | 59 | | | |
| M303 | 14 | 37 | M304 | 14 | 38 | M305 | 14 | 39 |
| M306 | 14 | 40 | M307 | 14 | 41 | M308 | 14 | 42 |
| M309 | 14 | 43 | M310 | 14 | 44 | M311 | 14 | 45 |
| M312 | 14 | 46 | M313 | 14 | 47 | M314 | 14 | 48 |
| M315 | 14 | 49 | M316 | 14 | 50 | M317 | 14 | 51 |
| M318 | 14 | 52 | M319 | 14 | 53 | M320 | 14 | 54 |
| M321 | 14 | 55 | M322 | 14 | 56 | M323 | 14 | 57 |
| M324 | 14 | 58 | M325 | 14 | 59 | | | |
| M326 | 14 | 61 | M327 | 14 | 62 | M328 | 14 | 63 |
| M329 | 15 | 37 | M330 | 15 | 38 | M331 | 15 | 39 |
| M332 | 15 | 40 | M333 | 15 | 41 | M334 | 15 | 42 |
| M335 | 15 | 43 | M336 | 15 | 44 | M337 | 15 | 45 |
| M338 | 15 | 46 | M339 | 15 | 47 | M340 | 15 | 48 |
| M341 | 15 | 49 | M342 | 15 | 50 | M343 | 15 | 51 |
| M344 | 15 | 52 | M345 | 15 | 53 | M346 | 15 | 54 |
| M347 | 15 | 55 | M348 | 15 | 56 | M349 | 15 | 57 |
| M350 | 15 | 58 | M351 | 15 | 59 | | | |
| M352 | 16 | 37 | M353 | 16 | 38 | M354 | 16 | 39 |
| M355 | 16 | 40 | M356 | 16 | 41 | M357 | 16 | 42 |
| M358 | 16 | 43 | M359 | 16 | 44 | M360 | 16 | 45 |
| M361 | 16 | 46 | M362 | 16 | 47 | M363 | 16 | 48 |
| M364 | 16 | 49 | M365 | 16 | 50 | M366 | 16 | 51 |
| M367 | 16 | 52 | M368 | 16 | 53 | M369 | 16 | 54 |
| M370 | 16 | 55 | M371 | 16 | 56 | M372 | 16 | 57 |
| M373 | 16 | 58 | M374 | 16 | 59 | | | |
| M375 | 17 | 37 | M376 | 17 | 38 | M377 | 17 | 39 |
| M378 | 17 | 40 | M379 | 17 | 41 | M380 | 17 | 42 |
| M381 | 17 | 43 | M382 | 17 | 44 | M383 | 17 | 45 |
| M384 | 17 | 46 | M385 | 17 | 47 | M386 | 17 | 48 |
| M387 | 17 | 49 | M388 | 17 | 50 | M389 | 17 | 51 |
| M390 | 17 | 52 | M391 | 17 | 53 | M392 | 17 | 54 |
| M393 | 17 | 55 | M394 | 17 | 56 | M395 | 17 | 57 |
| M396 | 17 | 58 | M397 | 17 | 59 | | | |
| M398 | 18 | 37 | M399 | 18 | 38 | M400 | 18 | 39 |
| M401 | 18 | 40 | M402 | 18 | 41 | M403 | 18 | 42 |
| M404 | 18 | 43 | M405 | 18 | 44 | M406 | 18 | 45 |
| M407 | 18 | 46 | M408 | 18 | 47 | M409 | 18 | 48 |
| M410 | 18 | 49 | M411 | 18 | 50 | M412 | 18 | 51 |
| M413 | 18 | 52 | M414 | 18 | 53 | M415 | 18 | 54 |
| M416 | 18 | 55 | M417 | 18 | 56 | M418 | 18 | 57 |
| M419 | 18 | 58 | M420 | 18 | 59 | | | |
| M421 | 19 | 37 | M422 | 19 | 38 | M423 | 19 | 39 |
| M424 | 19 | 40 | M425 | 19 | 41 | M426 | 19 | 42 |
| M427 | 19 | 43 | M428 | 19 | 44 | M429 | 19 | 45 |
| M430 | 19 | 46 | M431 | 19 | 47 | M432 | 19 | 48 |
| M433 | 19 | 49 | M434 | 19 | 50 | M435 | 19 | 51 |
| M436 | 19 | 52 | M437 | 19 | 53 | M438 | 19 | 54 |
| M439 | 19 | 55 | M440 | 19 | 56 | M441 | 19 | 57 |
| M442 | 19 | 58 | M443 | 19 | 59 | | | |
| M444 | 20 | 37 | M445 | 20 | 38 | M446 | 20 | 39 |
| M447 | 20 | 40 | M448 | 20 | 41 | M449 | 20 | 42 |
| M450 | 20 | 43 | M451 | 20 | 44 | M452 | 20 | 45 |
| M453 | 20 | 46 | M454 | 20 | 47 | M455 | 20 | 48 |
| M456 | 20 | 49 | M457 | 20 | 50 | M458 | 20 | 51 |
| M459 | 20 | 52 | M460 | 20 | 53 | M461 | 20 | 54 |
| M462 | 20 | 55 | M463 | 20 | 56 | M464 | 20 | 57 |
| M465 | 20 | 58 | M466 | 20 | 59 | | | |
| M467 | 21 | 37 | M468 | 21 | 38 | M469 | 21 | 39 |
| M470 | 21 | 40 | M471 | 21 | 41 | M472 | 21 | 42 |
| M473 | 21 | 43 | M474 | 21 | 44 | M475 | 21 | 45 |
| M476 | 21 | 46 | M477 | 21 | 47 | M478 | 21 | 48 |
| M479 | 21 | 49 | M480 | 21 | 50 | M481 | 21 | 51 |
| M482 | 21 | 52 | M483 | 21 | 53 | M484 | 21 | 54 |
| M485 | 21 | 55 | M486 | 21 | 56 | M487 | 21 | 57 |
| M488 | 21 | 58 | M489 | 21 | 59 | | | |
| M490 | 22 | 37 | M491 | 22 | 38 | M492 | 22 | 39 |
| M493 | 22 | 40 | M494 | 22 | 41 | M495 | 22 | 42 |
| M496 | 22 | 43 | M497 | 22 | 44 | M498 | 22 | 45 |
| M499 | 22 | 46 | M500 | 22 | 47 | M501 | 22 | 48 |
| M502 | 22 | 49 | M503 | 22 | 50 | M504 | 22 | 51 |
| M505 | 22 | 52 | M506 | 22 | 53 | M507 | 22 | 54 |
| M508 | 22 | 55 | M509 | 22 | 56 | M510 | 22 | 57 |
| M511 | 22 | 58 | M512 | 22 | 59 | | | |
| M513 | 23 | 37 | M514 | 23 | 38 | M515 | 23 | 39 |
| M516 | 23 | 40 | M517 | 23 | 41 | M518 | 23 | 42 |
| M519 | 23 | 43 | M520 | 23 | 44 | M521 | 23 | 45 |
| M522 | 23 | 46 | M523 | 23 | 47 | M524 | 23 | 48 |
| M525 | 23 | 49 | M526 | 23 | 50 | M527 | 23 | 51 |
| M528 | 23 | 52 | M529 | 23 | 53 | M530 | 23 | 54 |
| M531 | 23 | 55 | M532 | 23 | 56 | M533 | 23 | 57 |
| M534 | 23 | 58 | M535 | 23 | 59 | | | |
| M536 | 24 | 37 | M537 | 24 | 38 | M538 | 24 | 39 |
| M539 | 24 | 40 | M540 | 24 | 41 | M541 | 24 | 42 |
| M542 | 24 | 43 | M543 | 24 | 44 | M544 | 24 | 45 |
| M545 | 24 | 46 | M546 | 24 | 47 | M547 | 24 | 48 |
| M548 | 24 | 49 | M549 | 24 | 50 | M550 | 24 | 51 |
| M551 | 24 | 52 | M552 | 24 | 53 | M553 | 24 | 54 |
| M554 | 24 | 55 | M555 | 24 | 56 | M556 | 24 | 57 |
| M557 | 24 | 58 | M558 | 24 | 59 | | | |
| M559 | 25 | 37 | M560 | 25 | 38 | M561 | 25 | 39 |
| M562 | 25 | 40 | M563 | 25 | 41 | M564 | 25 | 42 |
| M565 | 25 | 43 | M566 | 25 | 44 | M567 | 25 | 45 |
| M568 | 25 | 46 | M569 | 25 | 47 | M570 | 25 | 48 |
| M571 | 25 | 49 | M572 | 25 | 50 | M573 | 25 | 51 |
| M574 | 25 | 52 | M575 | 25 | 53 | M576 | 25 | 54 |
| M577 | 25 | 55 | M578 | 25 | 56 | M579 | 25 | 57 |
| M580 | 25 | 58 | M581 | 25 | 59 | | | |
| M582 | 26 | 37 | M583 | 26 | 38 | M584 | 26 | 39 |
| M588 | 26 | 40 | M589 | 26 | 41 | M590 | 26 | 42 |
| M591 | 26 | 43 | M592 | 26 | 44 | M593 | 26 | 45 |
| M594 | 26 | 46 | M595 | 26 | 47 | M596 | 26 | 48 |
| M597 | 26 | 49 | M598 | 26 | 50 | M599 | 26 | 51 |
| M600 | 26 | 52 | M601 | 26 | 53 | M602 | 26 | 54 |
| M603 | 26 | 55 | M604 | 26 | 56 | M605 | 26 | 57 |
| M606 | 26 | 58 | M607 | 26 | 59 | | | |
| M608 | 27 | 37 | M609 | 27 | 38 | M610 | 27 | 39 |
| M611 | 27 | 40 | M612 | 27 | 41 | M613 | 27 | 42 |
| M614 | 27 | 43 | M615 | 27 | 44 | M616 | 27 | 45 |
| M617 | 27 | 46 | M618 | 27 | 47 | M619 | 27 | 48 |
| M620 | 27 | 49 | M621 | 27 | 50 | M622 | 27 | 51 |
| M623 | 27 | 52 | M624 | 27 | 53 | M625 | 27 | 54 |
| M626 | 27 | 55 | M627 | 27 | 56 | M628 | 27 | 57 |
| M629 | 27 | 58 | M630 | 27 | 59 | | | |
| M631 | 28 | 37 | M632 | 28 | 38 | M633 | 28 | 39 |
| M634 | 28 | 40 | M635 | 28 | 41 | M636 | 28 | 42 |
| M637 | 28 | 43 | M638 | 28 | 44 | M639 | 28 | 45 |
| M640 | 28 | 46 | M641 | 28 | 47 | M642 | 28 | 48 |
| M643 | 28 | 49 | M644 | 28 | 50 | M645 | 28 | 51 |
| M646 | 28 | 52 | M647 | 28 | 53 | M648 | 28 | 54 |
| M649 | 28 | 55 | M650 | 28 | 56 | M651 | 28 | 57 |
| M652 | 28 | 58 | M653 | 28 | 59 | | | |
| M654 | 29 | 37 | M655 | 29 | 38 | M656 | 29 | 39 |
| M657 | 29 | 40 | M658 | 29 | 41 | M659 | 29 | 42 |
| M660 | 29 | 43 | M661 | 29 | 44 | M662 | 29 | 45 |
| M663 | 29 | 46 | M664 | 29 | 47 | M665 | 29 | 48 |
| M666 | 29 | 49 | M667 | 29 | 50 | M668 | 29 | 51 |
| M669 | 29 | 52 | M670 | 29 | 53 | M671 | 29 | 54 |
| M672 | 29 | 55 | M673 | 29 | 56 | M674 | 29 | 57 |
| M675 | 29 | 58 | M676 | 29 | 59 | | | |
| M677 | 30 | 37 | M678 | 30 | 38 | M679 | 30 | 39 |
| M680 | 30 | 40 | M681 | 30 | 41 | M682 | 30 | 42 |
| M683 | 30 | 43 | M684 | 30 | 44 | M685 | 30 | 45 |
| M686 | 30 | 46 | M687 | 30 | 47 | M688 | 30 | 48 |
| M689 | 30 | 49 | M690 | 30 | 50 | M691 | 30 | 51 |
| M692 | 30 | 52 | M693 | 30 | 53 | M694 | 30 | 54 |
| M695 | 30 | 55 | M696 | 30 | 56 | M697 | 30 | 57 |
| M698 | 30 | 58 | M699 | 30 | 59 | | | |
| M700 | 31 | 37 | M701 | 31 | 38 | M702 | 31 | 39 |
| M703 | 31 | 40 | M704 | 31 | 41 | M705 | 31 | 42 |
| M706 | 31 | 43 | M707 | 31 | 44 | M708 | 31 | 45 |
| M709 | 31 | 46 | M710 | 31 | 47 | M711 | 31 | 48 |
| M712 | 31 | 49 | M713 | 31 | 50 | M714 | 31 | 51 |
| M715 | 31 | 52 | M716 | 31 | 53 | M717 | 31 | 54 |
| M718 | 31 | 55 | M719 | 31 | 56 | M720 | 31 | 57 |
| M721 | 31 | 58 | M722 | 31 | 59 | | | |
| M723 | 32 | 37 | M724 | 32 | 38 | M725 | 32 | 39 |
| M726 | 32 | 40 | M727 | 32 | 41 | M728 | 32 | 42 |
| M729 | 32 | 43 | M730 | 32 | 44 | M731 | 32 | 45 |
| M732 | 32 | 46 | M733 | 32 | 47 | M734 | 32 | 48 |
| M735 | 32 | 49 | M736 | 32 | 50 | M737 | 32 | 51 |
| M738 | 32 | 52 | M739 | 32 | 53 | M740 | 32 | 54 |
| M741 | 32 | 55 | M742 | 32 | 56 | M743 | 32 | 57 |
| M744 | 32 | 58 | M745 | 32 | 59 | | | |
| M746 | 33 | 37 | M747 | 33 | 38 | M748 | 33 | 39 |
| M749 | 33 | 40 | M750 | 33 | 41 | M751 | 33 | 42 |
| M752 | 33 | 43 | M753 | 33 | 44 | M754 | 33 | 45 |
| M755 | 33 | 46 | M756 | 33 | 47 | M757 | 33 | 48 |
| M758 | 33 | 49 | M759 | 33 | 50 | M760 | 33 | 51 |
| M761 | 33 | 52 | M762 | 33 | 53 | M763 | 33 | 54 |
| M764 | 33 | 55 | M765 | 33 | 56 | M766 | 33 | 57 |
| M767 | 33 | 58 | M768 | 33 | 59 | | | |
| M769 | 34 | 37 | M770 | 34 | 38 | M771 | 34 | 39 |
| M772 | 34 | 40 | M773 | 34 | 41 | M774 | 34 | 42 |
| M775 | 34 | 43 | M776 | 34 | 44 | M777 | 34 | 45 |
| M778 | 34 | 46 | M779 | 34 | 47 | M780 | 34 | 48 |
| M781 | 34 | 49 | M782 | 34 | 50 | M783 | 34 | 51 |
| M784 | 34 | 52 | M785 | 34 | 53 | M786 | 34 | 54 |
| M787 | 34 | 55 | M788 | 34 | 56 | M789 | 34 | 57 |
| M790 | 34 | 58 | M791 | 34 | 59 | | | |
| M792 | 35 | 37 | M793 | 35 | 38 | M794 | 35 | 39 |
| M795 | 35 | 40 | M796 | 35 | 41 | M797 | 35 | 42 |
| M798 | 35 | 43 | M799 | 35 | 44 | M800 | 35 | 45 |
| M801 | 35 | 46 | M802 | 35 | 47 | M803 | 35 | 48 |
| M804 | 35 | 49 | M805 | 35 | 50 | M806 | 35 | 51 |
| M807 | 35 | 52 | M808 | 35 | 53 | M809 | 35 | 54 |
| M810 | 35 | 55 | M811 | 35 | 56 | M812 | 35 | 57 |
| M813 | 35 | 58 | M814 | 35 | 59 | | | |
| M815 | 36 | 37 | M816 | 36 | 38 | M817 | 36 | 39 |
| M818 | 36 | 40 | M819 | 36 | 41 | M820 | 36 | 42 |
| M821 | 36 | 43 | M822 | 36 | 44 | M823 | 36 | 45 |
| M824 | 36 | 46 | M825 | 36 | 47 | M826 | 36 | 48 |
| M827 | 36 | 49 | M828 | 36 | 50 | M829 | 36 | 51 |
| M830 | 36 | 52 | M831 | 36 | 53 | M832 | 36 | 54 |
| M833 | 36 | 55 | M834 | 36 | 56 | M835 | 36 | 57 |
| M836 | 36 | 58 | M837 | 36 | 59 | | | |
| M838 | 1 | 62 | M839 | 1 | 63 | M840 | 1 | 64 |
| M841 | 1 | 65 | M842 | 1 | 66 | | | |
| M843 | 2 | 60 | M844 | 2 | 61 | M845 | 2 | 62 |
| M846 | 2 | 63 | M847 | 2 | 64 | M848 | 2 | 65 |
| M849 | 2 | 66 | | | | | | |
| M850 | 3 | 60 | M851 | 3 | 61 | M852 | 3 | 62 |
| M853 | 3 | 63 | M854 | 3 | 64 | M855 | 3 | 65 |
| M856 | 3 | 66 | | | | | | |
| M857 | 4 | 60 | M858 | 4 | 61 | M859 | 4 | 62 |
| M860 | 4 | 63 | M861 | 4 | 64 | M862 | 4 | 65 |
| M863 | 4 | 66 | | | | | | |
| M864 | 5 | 60 | M865 | 5 | 61 | M866 | 5 | 62 |
| M867 | 5 | 63 | M868 | 5 | 64 | M869 | 5 | 65 |
| M870 | 5 | 66 | | | | | | |
| M871 | 6 | 60 | M872 | 6 | 61 | M873 | 6 | 62 |
| M874 | 6 | 63 | M875 | 6 | 64 | M876 | 6 | 65 |
| M877 | 6 | 66 | | | | | | |
| M878 | 7 | 60 | M865 | 7 | 61 | M866 | 7 | 62 |
| M881 | 7 | 63 | M868 | 7 | 64 | M869 | 7 | 65 |
| M884 | 7 | 66 | | | | | | |
| M885 | 8 | 60 | M886 | 8 | 61 | M887 | 8 | 62 |
| M888 | 8 | 63 | M889 | 8 | 64 | M890 | 8 | 65 |
| M891 | 8 | 66 | | | | | | |
| M892 | 9 | 60 | M893 | 9 | 61 | M894 | 9 | 62 |
| M895 | 9 | 63 | M896 | 9 | 64 | M897 | 9 | 65 |
| M898 | 9 | 66 | | | | | | |
| M899 | 10 | 60 | M900 | 10 | 61 | M901 | 10 | 62 |
| M902 | 10 | 63 | M903 | 10 | 64 | M904 | 10 | 65 |
| M905 | 10 | 66 | | | | | | |
| M906 | 11 | 60 | M907 | 11 | 61 | M908 | 11 | 62 |
| M909 | 11 | 63 | M910 | 11 | 64 | M911 | 11 | 65 |
| M912 | 11 | 66 | | | | | | |
| M913 | 12 | 60 | M914 | 12 | 61 | M915 | 12 | 62 |
| M916 | 12 | 63 | M917 | 12 | 64 | M918 | 12 | 65 |
| M919 | 12 | 66 | | | | | | |
| M920 | 13 | 60 | M921 | 13 | 61 | M922 | 13 | 62 |
| M923 | 13 | 63 | M924 | 13 | 64 | M925 | 13 | 65 |
| M926 | 13 | 66 | | | | | | |
| M927 | 14 | 60 | M928 | 14 | 61 | M929 | 14 | 62 |
| M930 | 14 | 63 | M931 | 14 | 64 | M932 | 14 | 65 |
| M933 | 14 | 66 | | | | | | |
| M934 | 15 | 60 | M935 | 15 | 61 | M936 | 15 | 62 |
| M937 | 15 | 63 | M938 | 15 | 64 | M939 | 15 | 65 |
| M940 | 15 | 66 | | | | | | |
| M941 | 16 | 60 | M942 | 16 | 61 | M943 | 16 | 62 |
| M944 | 16 | 63 | M945 | 16 | 64 | M946 | 16 | 65 |
| M947 | 16 | 66 | | | | | | |
| M948 | 17 | 60 | M949 | 17 | 61 | M950 | 17 | 62 |
| M951 | 17 | 63 | M952 | 17 | 64 | M953 | 17 | 65 |
| M954 | 17 | 66 | | | | | | |
| M955 | 18 | 60 | M956 | 18 | 61 | M957 | 18 | 62 |
| M958 | 18 | 63 | M959 | 18 | 64 | M960 | 18 | 65 |
| M961 | 18 | 66 | | | | | | |
| M962 | 19 | 60 | M963 | 19 | 61 | M964 | 19 | 62 |
| M965 | 19 | 63 | M966 | 19 | 64 | M967 | 19 | 65 |
| M968 | 19 | 66 | | | | | | |
| M969 | 20 | 60 | M0970 | 20 | 61 | M971 | 20 | 62 |
| M972 | 20 | 63 | M973 | 20 | 64 | M974 | 20 | 65 |
| M975 | 20 | 66 | | | | | | |
| M976 | 21 | 60 | M977 | 21 | 61 | M978 | 21 | 62 |
| M979 | 21 | 63 | M980 | 21 | 64 | M981 | 21 | 65 |
| M982 | 21 | 66 | | | | | | |
| M983 | 22 | 60 | M984 | 22 | 61 | M985 | 22 | 62 |
| M986 | 22 | 63 | M987 | 22 | 64 | M988 | 22 | 65 |
| M989 | 22 | 66 | | | | | | |
| M990 | 22 | 60 | M991 | 22 | 61 | M992 | 22 | 62 |
| M993 | 22 | 63 | M994 | 22 | 64 | M995 | 22 | 65 |
| M996 | 22 | 66 | | | | | | |
| M997 | 23 | 60 | M998 | 23 | 61 | M999 | 23 | 62 |
| M1000 | 23 | 63 | M1001 | 23 | 64 | M1002 | 23 | 65 |
| M1003 | 23 | 66 | | | | | | |
| M1004 | 24 | 60 | M1005 | 24 | 61 | M1006 | 24 | 62 |
| M1007 | 24 | 63 | M1008 | 24 | 64 | M1009 | 24 | 65 |
| M1010 | 24 | 66 | | | | | | |
| M1011 | 25 | 60 | M1012 | 25 | 61 | M1013 | 25 | 62 |
| M1014 | 25 | 63 | M1015 | 25 | 64 | M1016 | 25 | 65 |
| M1017 | 25 | 66 | | | | | | |
| M1018 | 26 | 60 | M1019 | 26 | 61 | M1020 | 26 | 62 |
| M1021 | 26 | 63 | M1022 | 26 | 64 | M1023 | 26 | 65 |
| M1024 | 26 | 66 | | | | | | |
| M1025 | 27 | 60 | M1026 | 27 | 61 | M1027 | 27 | 62 |
| M1028 | 27 | 63 | M1029 | 27 | 64 | M1030 | 27 | 65 |
| M1031 | 27 | 66 | | | | | | |
| M1032 | 28 | 60 | M1033 | 28 | 61 | M1034 | 28 | 62 |
| M1035 | 28 | 63 | M1036 | 28 | 64 | M1037 | 28 | 65 |
| M1038 | 28 | 66 | | | | | | |
| M1039 | 29 | 60 | M1040 | 29 | 61 | M1041 | 29 | 62 |
| M1042 | 29 | 63 | M1043 | 29 | 64 | M1044 | 29 | 65 |
| M1045 | 29 | 66 | | | | | | |
| M1046 | 30 | 60 | M1047 | 30 | 61 | M1048 | 30 | 62 |
| M1049 | 30 | 63 | M1050 | 30 | 64 | M1051 | 30 | 65 |
| M1052 | 30 | 66 | | | | | | |
| M1053 | 31 | 60 | M1054 | 31 | 61 | M1055 | 31 | 62 |
| M1056 | 31 | 63 | M1057 | 31 | 64 | M1058 | 31 | 65 |
| M1059 | 31 | 66 | | | | | | |
| M1060 | 32 | 60 | M1061 | 32 | 61 | M1062 | 32 | 62 |
| M1063 | 32 | 63 | M1064 | 32 | 64 | M1065 | 32 | 65 |
| M1066 | 32 | 66 | | | | | | |
| M1067 | 33 | 60 | M1068 | 33 | 61 | M1069 | 33 | 62 |
| M1070 | 33 | 63 | M1071 | 33 | 64 | M1072 | 33 | 65 |
| M1073 | 33 | 66 | | | | | | |
| M1074 | 34 | 60 | M1075 | 34 | 61 | M1076 | 34 | 62 |
| M1077 | 34 | 63 | M1078 | 34 | 64 | M1079 | 34 | 65 |
| M1080 | 34 | 66 | | | | | | |
| M1081 | 35 | 60 | M1082 | 35 | 61 | M1083 | 35 | 62 |
| M1084 | 35 | 63 | M1085 | 35 | 64 | M1086 | 35 | 65 |
| M1087 | 35 | 66 | | | | | | |
| M1088 | 36 | 60 | M1089 | 36 | 61 | M1090 | 36 | 62 |
| M1091 | 36 | 63 | M1092 | 36 | 64 | M1093 | 36 | 65 |
| M1094 | 36 | 66 | M1095 | 1 | 60 | M1096 | 1 | 61 |
| M1097 | 67 | 37 | M1098 | 67 | 38 | M1099 | 67 | 39 |
| M1100 | 67 | 40 | M1101 | 67 | 41 | M1102 | 67 | 42 |
| M1103 | 67 | 43 | M1104 | 67 | 44 | M1105 | 67 | 45 |
| M1106 | 67 | 46 | M1107 | 67 | 47 | M1108 | 67 | 48 |
| M1109 | 67 | 49 | M1110 | 67 | 50 | M1111 | 67 | 51 |
| M1112 | 67 | 52 | M1113 | 67 | 53 | M1114 | 67 | 54 |
| M1115 | 67 | 55 | M1116 | 67 | 56 | M1117 | 67 | 57 |
| M1118 | 67 | 58 | M1119 | 67 | 59 | M1120 | 67 | 60 |
| M1121 | 67 | 61 | M1122 | 67 | 62 | M1123 | 67 | 63 |
| M1124 | 67 | 64 | M1125 | 67 | 65 | M1126 | 67 | 66 |
| M1127 | 68 | 37 | M1128 | 68 | 38 | M1129 | 68 | 39 |
| M1130 | 68 | 40 | M1131 | 68 | 41 | M1132 | 68 | 42 |
| M1133 | 68 | 43 | M1134 | 68 | 44 | M1135 | 68 | 45 |
| M1136 | 68 | 46 | M1137 | 68 | 47 | M1138 | 68 | 48 |
| M1139 | 68 | 49 | M1140 | 68 | 50 | M1141 | 68 | 51 |
| M1142 | 68 | 52 | M1143 | 68 | 53 | M1144 | 68 | 54 |
| M1145 | 68 | 55 | M1146 | 68 | 56 | M1147 | 68 | 57 |
| M1148 | 68 | 58 | M1149 | 68 | 59 | M1150 | 68 | 60 |
| M1151 | 68 | 61 | M1152 | 68 | 62 | M1153 | 68 | 63 |
| M1154 | 68 | 64 | M1155 | 68 | 65 | M1156 | 68 | 66 |
| M1157 | 69 | 37 | M1158 | 69 | 38 | M1159 | 69 | 39 |
| M1160 | 69 | 40 | M1161 | 69 | 41 | M1162 | 69 | 42 |
| M1163 | 69 | 43 | M1164 | 69 | 44 | M1165 | 69 | 45 |
| M1166 | 69 | 46 | M1167 | 69 | 47 | M1168 | 69 | 48 |
| M1169 | 69 | 49 | M1170 | 69 | 50 | M1171 | 69 | 51 |
| M1172 | 69 | 52 | M1173 | 69 | 53 | M1174 | 69 | 54 |
| M1175 | 69 | 55 | M1176 | 69 | 56 | M1177 | 69 | 57 |
| M1178 | 69 | 58 | M1179 | 69 | 59 | M1180 | 69 | 60 |
| M1181 | 69 | 61 | M1182 | 69 | 62 | M1183 | 69 | 63 |
| M1184 | 69 | 64 | M1185 | 69 | 65 | M1186 | 69 | 66 |
| M1187 | 70 | 37 | M1188 | 70 | 38 | M1189 | 70 | 39 |
| M1190 | 70 | 40 | M1191 | 70 | 41 | M1192 | 70 | 42 |
| M1193 | 70 | 43 | M1194 | 70 | 44 | M1195 | 70 | 45 |
| M1196 | 70 | 46 | M1197 | 70 | 47 | M1198 | 70 | 48 |
| M1199 | 70 | 49 | M1200 | 70 | 50 | M1201 | 70 | 51 |
| M1202 | 70 | 52 | M1203 | 70 | 53 | M1204 | 70 | 54 |
| M1205 | 70 | 55 | M1206 | 70 | 56 | M1207 | 70 | 57 |
| M1208 | 70 | 58 | M1209 | 70 | 59 | M1210 | 70 | 60 |
| M1211 | 70 | 61 | M1212 | 70 | 62 | M1213 | 70 | 63 |
| M1214 | 70 | 64 | M1215 | 70 | 65 | M1216 | 70 | 66 |
| M1217 | 71 | 37 | M1218 | 71 | 38 | M1219 | 71 | 39 |
| M1220 | 71 | 40 | M1221 | 71 | 41 | M1222 | 71 | 42 |
| M1223 | 71 | 43 | M1224 | 71 | 44 | M1225 | 71 | 45 |
| M1226 | 71 | 46 | M1227 | 71 | 47 | M1228 | 71 | 48 |
| M1229 | 71 | 49 | M1230 | 71 | 50 | M1231 | 71 | 51 |
| M1232 | 71 | 52 | M1233 | 71 | 53 | M1234 | 71 | 54 |
| M1235 | 71 | 55 | M1236 | 71 | 56 | M1237 | 71 | 57 |
| M1238 | 71 | 58 | M1239 | 71 | 59 | M1240 | 71 | 60 |
| M1241 | 71 | 61 | M1242 | 71 | 62 | M1243 | 71 | 63 |
| M1244 | 71 | 64 | M1245 | 71 | 65 | M1246 | 71 | 66 |
| M1247 | 72 | 37 | M1248 | 72 | 38 | M1249 | 72 | 39 |
| M1250 | 72 | 40 | M1251 | 72 | 41 | M1252 | 72 | 42 |
| M1253 | 72 | 43 | M1254 | 72 | 44 | M1255 | 72 | 45 |
| M1256 | 72 | 46 | M1257 | 72 | 47 | M1258 | 72 | 48 |
| M1259 | 72 | 49 | M1260 | 72 | 50 | M1261 | 72 | 51 |
| M1262 | 72 | 52 | M1263 | 72 | 53 | M1264 | 72 | 54 |
| M1265 | 72 | 55 | M1266 | 72 | 56 | M1267 | 72 | 57 |
| M1268 | 72 | 58 | M1269 | 72 | 59 | M1270 | 72 | 60 |
| M1271 | 72 | 61 | M1272 | 72 | 62 | M1273 | 72 | 63 |
| M1274 | 72 | 64 | M1275 | 72 | 65 | M1276 | 72 | 66 |
| M1277 | 73 | 37 | M1278 | 73 | 38 | M1279 | 73 | 39 |
| M1280 | 73 | 40 | M1281 | 73 | 41 | M1282 | 73 | 42 |
| M1283 | 73 | 43 | M1284 | 73 | 44 | M1285 | 73 | 45 |
| M1286 | 73 | 46 | M1287 | 73 | 47 | M1288 | 73 | 48 |
| M1289 | 73 | 49 | M1290 | 73 | 50 | M1291 | 73 | 51 |
| M1292 | 73 | 52 | M1293 | 73 | 53 | M1294 | 73 | 54 |
| M1295 | 73 | 55 | M1296 | 73 | 56 | M1297 | 73 | 57 |
| M1298 | 73 | 58 | M1299 | 73 | 59 | M1300 | 73 | 60 |
| M1301 | 73 | 61 | M1302 | 73 | 62 | M1303 | 73 | 63 |
| M1304 | 73 | 64 | M1305 | 73 | 65 | M1306 | 73 | 66 |
| M1307 | 74 | 37 | M1308 | 74 | 38 | M1309 | 74 | 39 |
| M1310 | 74 | 40 | M1311 | 74 | 41 | M1312 | 74 | 42 |
| M1313 | 74 | 43 | M1314 | 74 | 44 | M1315 | 74 | 45 |
| M1316 | 74 | 46 | M1317 | 74 | 47 | M1318 | 74 | 48 |
| M1319 | 74 | 49 | M1320 | 74 | 50 | M1321 | 74 | 51 |
| M1322 | 74 | 52 | M1323 | 74 | 53 | M1324 | 74 | 54 |
| M1325 | 74 | 55 | M1326 | 74 | 56 | M1327 | 74 | 57 |
| M1328 | 74 | 58 | M1329 | 74 | 59 | M1330 | 74 | 60 |
| M1331 | 74 | 61 | M1332 | 74 | 62 | M1333 | 74 | 63 |
| M1334 | 74 | 64 | M1335 | 74 | 65 | M1336 | 74 | 66 |
| M1337 | 75 | 37 | M1338 | 75 | 38 | M1339 | 75 | 39 |
| M1340 | 75 | 40 | M1341 | 75 | 41 | M1342 | 75 | 42 |
| M1343 | 75 | 43 | M1344 | 75 | 44 | M1345 | 75 | 45 |
| M1346 | 75 | 46 | M1347 | 75 | 47 | M1348 | 75 | 48 |
| M1349 | 75 | 49 | M1350 | 75 | 50 | M1351 | 75 | 51 |
| M1352 | 75 | 52 | M1353 | 75 | 53 | M1354 | 75 | 54 |
| M1355 | 75 | 55 | M1356 | 75 | 56 | M1357 | 75 | 57 |
| M1358 | 75 | 58 | M1359 | 75 | 59 | M1360 | 75 | 60 |
| M1361 | 75 | 61 | M1362 | 75 | 62 | M1363 | 75 | 63 |
| M1364 | 75 | 64 | M1365 | 75 | 65 | M1366 | 75 | 66 |
| M1367 | 76 | 37 | M1368 | 76 | 38 | M1369 | 76 | 39 |
| M1370 | 76 | 40 | M1371 | 76 | 41 | M1372 | 76 | 42 |
| M1373 | 76 | 43 | M1374 | 76 | 44 | M1375 | 76 | 45 |
| M1376 | 76 | 46 | M1377 | 76 | 47 | M1378 | 76 | 48 |
| M1379 | 76 | 49 | M1380 | 76 | 50 | M1381 | 76 | 51 |
| M1382 | 76 | 52 | M1383 | 76 | 53 | M1384 | 76 | 54 |
| M1385 | 76 | 55 | M1386 | 76 | 56 | M1387 | 76 | 57 |
| M1388 | 76 | 58 | M1389 | 76 | 59 | M1390 | 76 | 60 |
| M1391 | 76 | 61 | M1392 | 76 | 62 | M1393 | 76 | 63 |
| M1394 | 76 | 64 | M1395 | 76 | 65 | M1396 | 76 | 66 |
| M1397 | 77 | 37 | M1398 | 77 | 38 | M1399 | 77 | 39 |
| M1400 | 77 | 40 | M1401 | 77 | 41 | M1402 | 77 | 42 |
| M1403 | 77 | 43 | M1404 | 77 | 44 | M1405 | 77 | 45 |
| M1406 | 77 | 46 | M1407 | 77 | 47 | M1408 | 77 | 48 |
| M1409 | 77 | 49 | M1410 | 77 | 50 | M1411 | 77 | 51 |
| M1412 | 77 | 52 | M1413 | 77 | 53 | M1414 | 77 | 54 |
| M1415 | 77 | 55 | M1416 | 77 | 56 | M1417 | 77 | 57 |
| M1418 | 77 | 58 | M1419 | 77 | 59 | M1420 | 77 | 60 |
| M1421 | 77 | 61 | M1422 | 77 | 62 | M1423 | 77 | 63 |
| M1424 | 77 | 64 | M1425 | 77 | 65 | M1426 | 77 | 66 |
| M1427 | 78 | 37 | M1428 | 78 | 38 | M1429 | 78 | 39 |
| M1430 | 78 | 40 | M1431 | 78 | 41 | M1432 | 78 | 42 |
| M1433 | 78 | 43 | M1434 | 78 | 44 | M1435 | 78 | 45 |
| M1436 | 78 | 46 | M1437 | 78 | 47 | M1438 | 78 | 48 |
| M1439 | 78 | 49 | M1440 | 78 | 50 | M1441 | 78 | 51 |
| M1442 | 78 | 52 | M1443 | 78 | 53 | M1444 | 78 | 54 |
| M1445 | 78 | 55 | M1446 | 78 | 56 | M1447 | 78 | 57 |
| M1448 | 78 | 58 | M1449 | 78 | 59 | M1450 | 78 | 60 |
| M1451 | 78 | 61 | M1452 | 78 | 62 | M1453 | 78 | 63 |
| M1454 | 78 | 64 | M1455 | 78 | 65 | M1456 | 78 | 66 |
| M1457 | 79 | 37 | M1458 | 79 | 38 | M1459 | 79 | 39 |
| M1460 | 79 | 40 | M1461 | 79 | 41 | M1462 | 79 | 42 |
| M1463 | 79 | 43 | M1464 | 79 | 44 | M1465 | 79 | 45 |
| M1466 | 79 | 46 | M1467 | 79 | 47 | M1468 | 79 | 48 |
| M1469 | 79 | 49 | M1470 | 79 | 50 | M1471 | 79 | 51 |
| M1472 | 79 | 52 | M1473 | 79 | 53 | M1474 | 79 | 54 |
| M1475 | 79 | 55 | M1476 | 79 | 56 | M1477 | 79 | 57 |
| M1478 | 79 | 58 | M1479 | 79 | 59 | M1480 | 79 | 60 |
| M1481 | 79 | 61 | M1482 | 79 | 62 | M1483 | 79 | 63 |
| M1484 | 79 | 64 | M1485 | 79 | 65 | M1486 | 79 | 66 |
| M1487 | 80 | 37 | M1488 | 80 | 38 | M1489 | 80 | 39 |
| M1490 | 80 | 40 | M1491 | 80 | 41 | M1492 | 80 | 42 |
| M1493 | 80 | 43 | M1494 | 80 | 44 | M1495 | 80 | 45 |
| M1496 | 80 | 46 | M1497 | 80 | 47 | M1498 | 80 | 48 |
| M1499 | 80 | 49 | M1500 | 80 | 50 | M1501 | 80 | 51 |
| M1502 | 80 | 52 | M1503 | 80 | 53 | M1504 | 80 | 54 |
| M1505 | 80 | 55 | M1506 | 80 | 56 | M1507 | 80 | 57 |
| M1508 | 80 | 58 | M1509 | 80 | 59 | M1510 | 80 | 60 |
| M1511 | 80 | 61 | M1512 | 80 | 62 | M1513 | 80 | 63 |
| M1514 | 80 | 64 | M1515 | 80 | 65 | M1516 | 80 | 66 |
| M1517 | 81 | 37 | M1518 | 81 | 38 | M1519 | 81 | 39 |
| M1520 | 81 | 40 | M1521 | 81 | 41 | M1522 | 81 | 42 |
| M1523 | 81 | 43 | M1524 | 81 | 44 | M1525 | 81 | 45 |
| M1526 | 81 | 46 | M1527 | 81 | 47 | M1528 | 81 | 48 |
| M1529 | 81 | 49 | M1530 | 81 | 50 | M1531 | 81 | 51 |
| M1532 | 81 | 52 | M1533 | 81 | 53 | M1534 | 81 | 54 |
| M1535 | 81 | 55 | M1536 | 81 | 56 | M1537 | 81 | 57 |
| M1538 | 81 | 58 | M1539 | 81 | 59 | M1540 | 81 | 60 |
| M1541 | 81 | 61 | M1542 | 81 | 62 | M1543 | 81 | 63 |
| M1544 | 81 | 64 | M1545 | 81 | 65 | M1546 | 81 | 66 |
| M1547 | 1 | 66a | M1548 | 2 | 66a | M1549 | 3 | 66a |
| M1550 | 4 | 66a | M1551 | 5 | 66a | M1552 | 6 | 66a |
| M1553 | 7 | 66a | M1554 | 8 | 66a | M1555 | 9 | 66a |
| M1556 | 10 | 66a | M1557 | 11 | 66a | M1558 | 12 | 66a |
| M1559 | 13 | 66a | M1560 | 14 | 66a | M1561 | 15 | 66a |
| M1562 | 16 | 66a | M1563 | 17 | 66a | M1564 | 18 | 66a |
| M1565 | 19 | 66a | M1566 | 20 | 66a | M1567 | 21 | 66a |
| M1568 | 22 | 66a | M1569 | 23 | 66a | M1570 | 24 | 66a |
| M1571 | 25 | 66a | M1572 | 26 | 66a | M1573 | 27 | 66a |
| M1574 | 28 | 66a | M1575 | 29 | 66a | M1576 | 30 | 66a |
| M1577 | 31 | 66a | M1578 | 32 | 66a | M1579 | 33 | 66a |
| M1580 | 34 | 66a | M1581 | 35 | 66a | M1582 | 36 | 66a |
| M1583 | 67 | 66a | M1584 | 68 | 66a | M1585 | 69 | 66a |
| M1586 | 70 | 66a | M1587 | 71 | 66a | M1588 | 72 | 66a |
| M1589 | 73 | 66a | M1590 | 74 | 66a | M1591 | 75 | 66a |
| M1592 | 76 | 66a | M1593 | 77 | 66a | M1594 | 78 | 66a |
| M1595 | 79 | 66a | M1596 | 80 | 66a | M1597 | 81 | 66a. |

The concentration of the electron-transporting host material of the formula (1) as described above or described as preferred in the composition or mixture of the invention or in the light-emitting layer of the device of the invention is in the range from 5% by weight to 90% by weight, preferably in the range from 10% by weight to 85% by weight, more preferably in the range from 20% by weight to 85% by weight, even more preferably in the range from 30% by weight to 80% by weight, very especially preferably in the range from 20% by weight to 60% by weight and most preferably in the range from 30% by weight to 50% by weight, based on the overall composition/mixture or based on the overall composition of the light-emitting layer.

The concentration of the hole-transporting host material of the formula (2) as described above or described as preferred in the composition or mixture or in the light-emitting layer of the device of the invention is in the range from 10% by weight to 95% by weight, preferably in the range from 15% by weight to 90% by weight, more preferably in the range from 15% by weight to 80% by weight, even more preferably in the range from 20% by weight to 70% by weight, very especially preferably in the range from 40% by weight to 80% by weight and most preferably in the range from 50% by weight to 70% by weight, based on the overall composition/mixture or based on the overall composition of the light-emitting layer.

In a further preferred embodiment, the composition of the invention may comprise, as well as at least one compound of the formula (1) as described above or described as preferred, and at least one compound of the formula (2) as described above or described as preferred, further compounds as well, especially organic functional materials. The composition according to the invention is a physical mixture of the at least one compound of the formula (1), the at least one compound of the formula (2) and optionally further organic functional materials as a constituent of an organic layer in an electronic device, as described hereinafter.

The present invention therefore also relates to a composition which, as well as the aforementioned materials, also comprises at least one further compound selected from the group consisting of hole injection materials, hole transport materials, hole blocker materials, wide band gap materials, fluorescent emitters, phosphorescent emitters, host materials, electron blocker materials, electron transport materials and electron injection materials, n-dopants and p-dopants. It does not present any difficulties at all to the person skilled in the art to select these from a multitude of materials that are known to such a person.

n-Dopants are understood herein to mean reducing agents, i.e. electron donors.

p-Dopants are understood herein to mean oxidizing agents, i.e. electron acceptors.

A wide band gap material is understood herein to mean a material within the scope of the disclosure of U.S. Pat. No. 7,294,849 which is characterized by a band gap of at least 3.5 eV, the band gap being understood to mean the gap between the HOMO and LUMO energy of a material.

It is preferable when the composition of the invention comprising at least one hole-transporting host of the formula (2) and at least one electron-transporting host of the formula (1), as described above or described with preference, additionally comprises at least one light-emitting compound or an emitter, particular preference being given to phosphorescent emitters.

The present invention also relates to a composition/mixture which, as well as the aforementioned host materials 1 and 2, as described above or described with preference, especially mixtures M1 to M1597, also contains at least one phosphorescent emitter.

The present invention also relates to an organic electroluminescent device as described above or hereinafter or described with preference, wherein the light-emitting layer, as well as the aforementioned host materials 1 and 2, as described above or described with preference, especially material combinations M1 to M1597, also comprises at least one phosphorescent emitter.

The term “phosphorescent emitters” typically encompasses compounds where the light is emitted through a spin-forbidden transition from an excited state having higher spin multiplicity, i.e. a spin state >1, for example through a transition from a triplet state or a state having an even higher spin quantum number, for example a quintet state. This is preferably understood to mean a transition from a triplet state.

Suitable phosphorescent emitters (=triplet emitters) are especially compounds which, when suitably excited, emit light, preferably in the visible region, and also contain at least one atom of atomic number greater than 20, preferably greater than 38 and less than 84, more preferably greater than 56 and less than 80, especially a metal having this atomic number. Preferred phosphorescence emitters used are compounds containing copper, molybdenum, tungsten, rhenium, ruthenium, osmium, rhodium, iridium, palladium, platinum, silver, gold or europium, especially compounds containing iridium or platinum. In the context of the present invention, all luminescent compounds containing the abovementioned metals are regarded as phosphorescent emitters.

In general, all phosphorescent complexes as used for phosphorescent OLEDs according to the prior art and as known to those skilled in the art in the field of organic electroluminescent devices are suitable.

Examples of the above-described emitters can be found in applications WO 2016/015815, WO 00/70655, WO 2001/41512, WO 2002/02714, WO 2002/15645, EP 1191613, EP 1191612, EP 1191614, WO 05/033244, WO 05/019373, US 2005/0258742, WO 2009/146770, WO 2010/015307, WO 2010/031485, WO 2010/054731, WO 2010/054728, WO 2010/086089, WO 2010/099852, WO 2010/102709, WO 2011/032626, WO 2011/066898, WO 2011/157339, WO 2012/007086, WO 2014/008982, WO 2014/023377, WO 2014/094961, WO 2014/094960, WO 2015/036074, WO 2015/104045, WO 2015/117718, WO 2016/015815, WO 2016/124304, WO 2017/032439, WO 2015/036074, WO 2015/117718 and WO 2016/015815.

Preferred phosphorescent emitters contain a dibenzofuran or an azadibenzofuran structure in at least one ligand.

Preferred phosphorescent emitters conform to the formula (3)

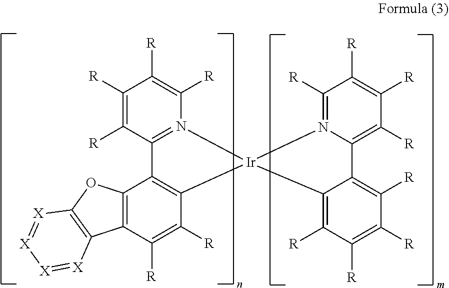

where the symbols and indices for this formula (3) are defined as follows:

n+m is 3, n is 1 or 2, m is 2 or 1,

X is N or CR,

R is H, D, a branched or linear alkyl group having 1 to 10 carbon atoms or a partly or fully deuterated branched or linear alkyl group having 1 to 10 carbon atoms or a cycloalkyl group which has 4 to 7 carbon atoms and may be partly or fully substituted by deuterium.

In emitters of the formula (3), n is preferably 1 and m is preferably 2.

In emitters of the formula (3), preferably, one X is selected from N and the other X are CR.

In emitters of the formula (3), at least one R is preferably different from H.

In emitters of the formula (3), preferably two, three or four R are different from H and have one of the other definitions given above for the emitters of the formula (3).

Preferred examples of phosphorescent emitters are listed in Table 4 below.

TABLE 4

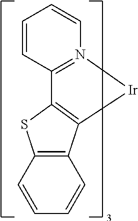

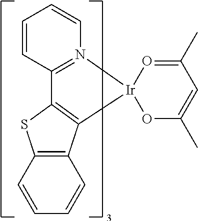

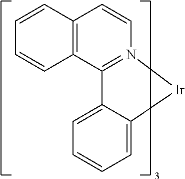

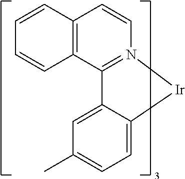

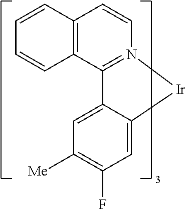

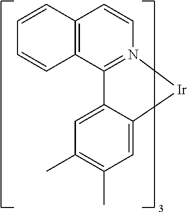

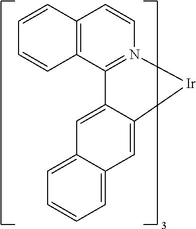

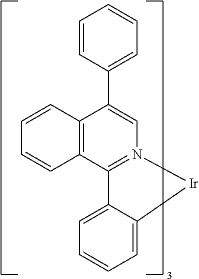

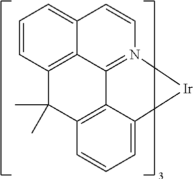

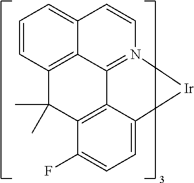

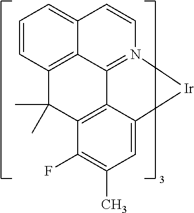

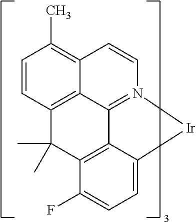

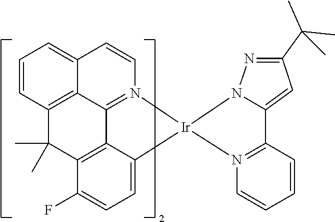

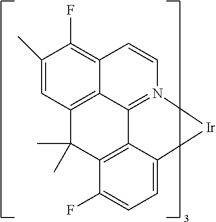

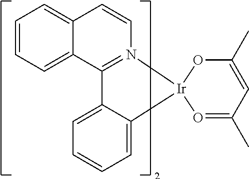

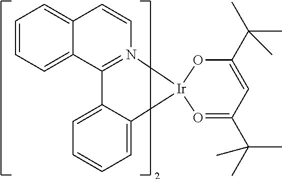

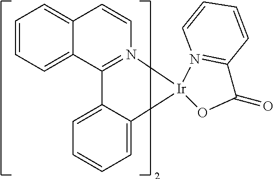

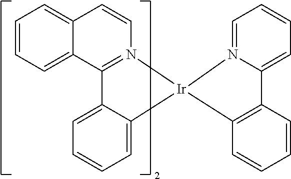

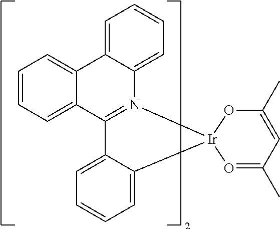

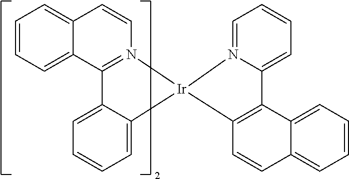

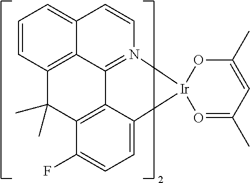

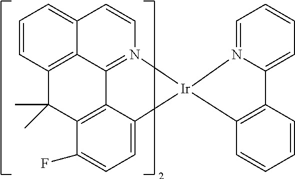

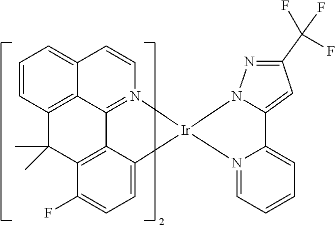

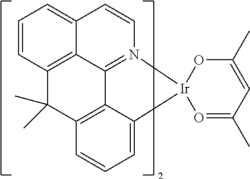

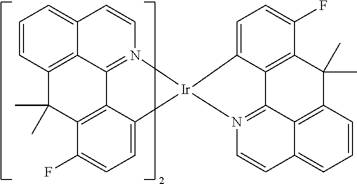

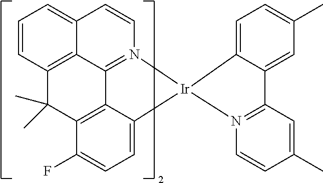

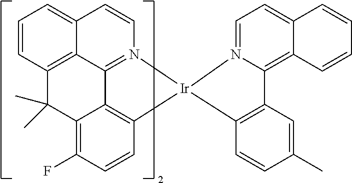

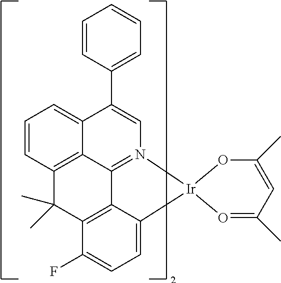

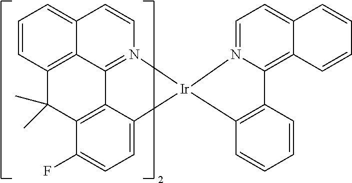

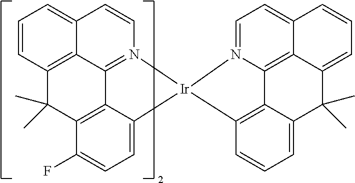

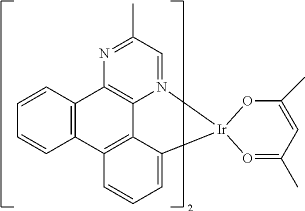

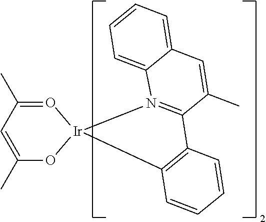

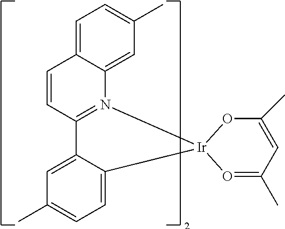

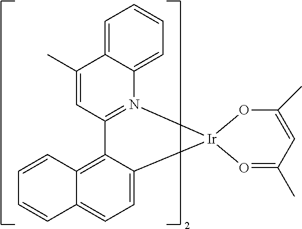

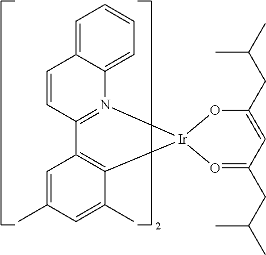

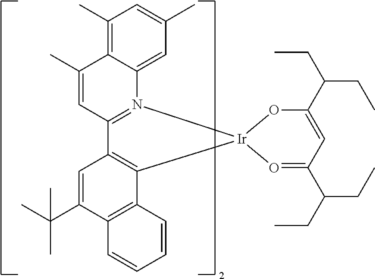

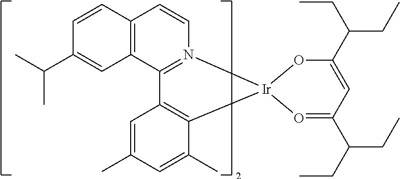

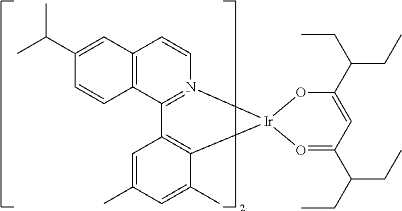

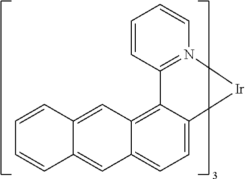

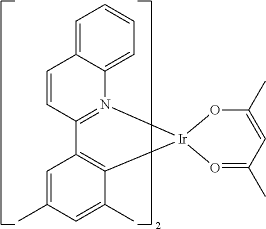

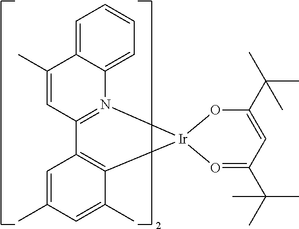

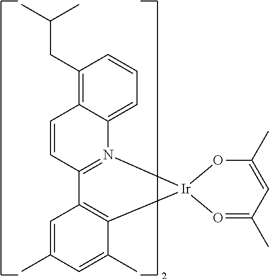

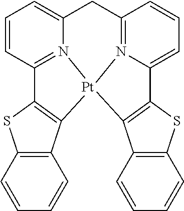

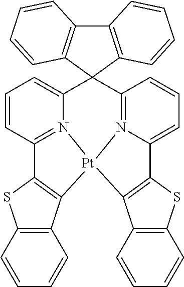

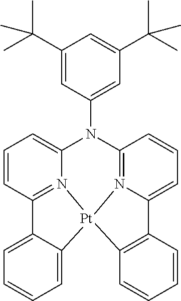

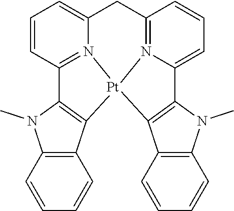

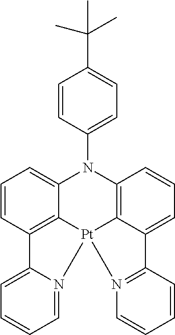

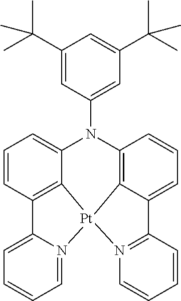

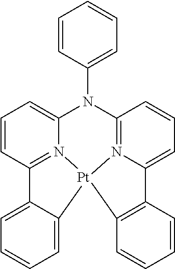

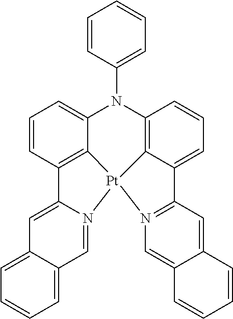

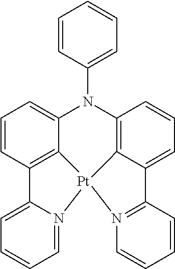

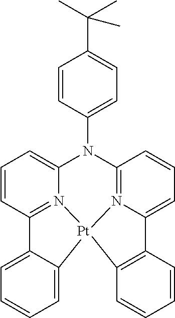

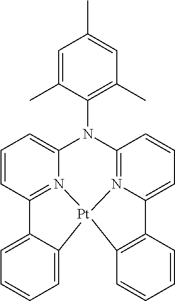

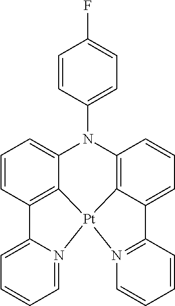

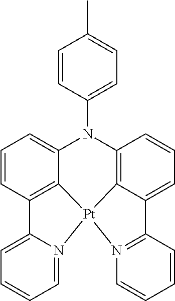

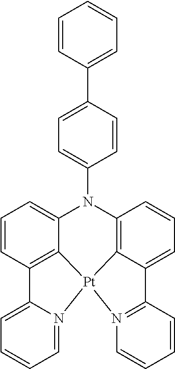

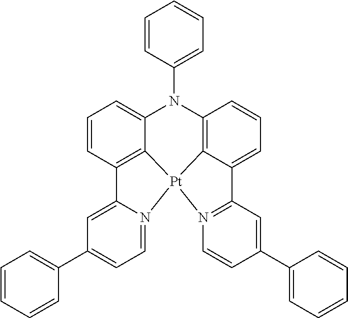

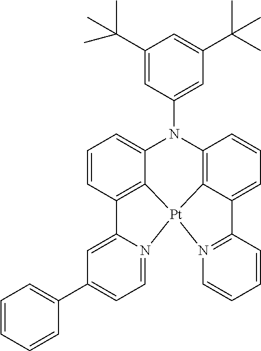

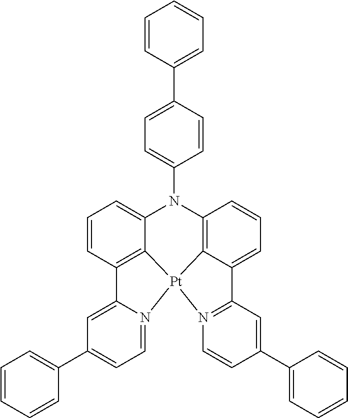

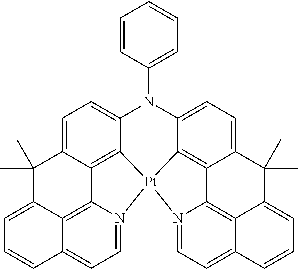

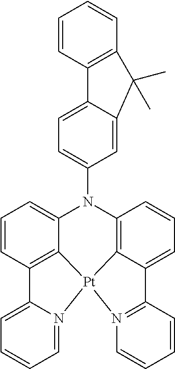

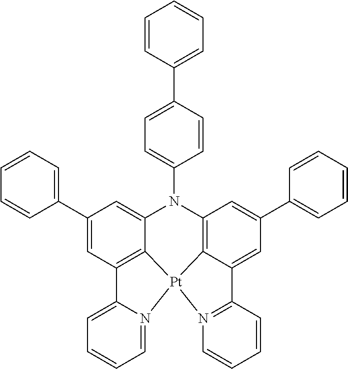

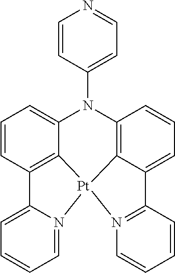

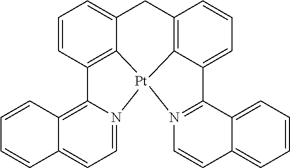

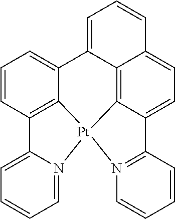

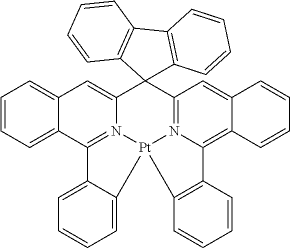

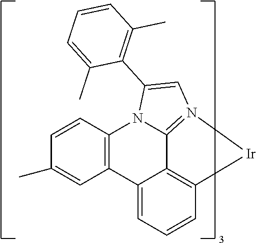

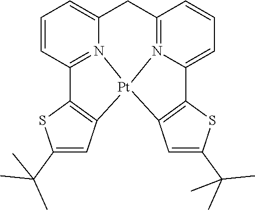

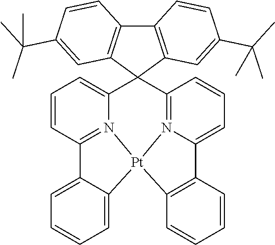

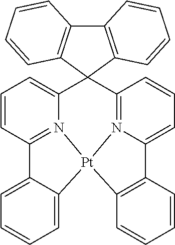

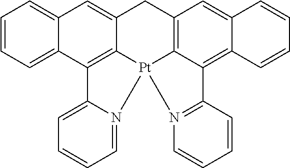

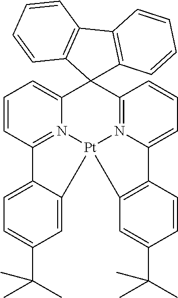

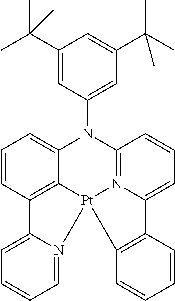

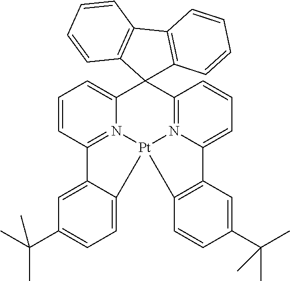

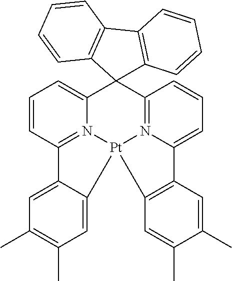

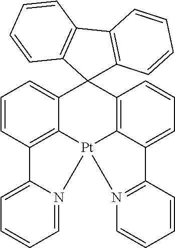

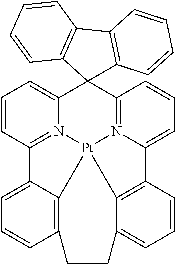

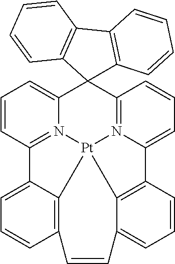

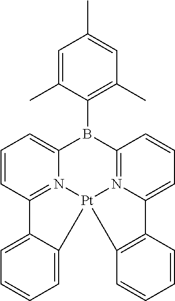

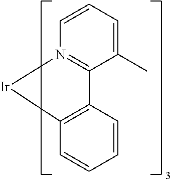

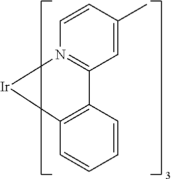

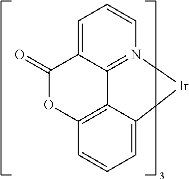

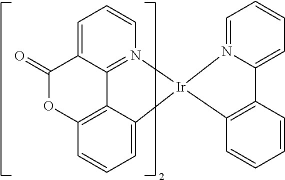

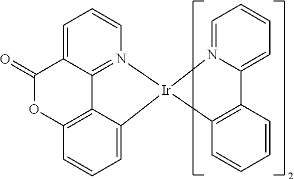

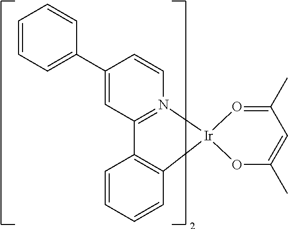

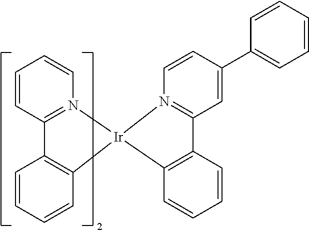

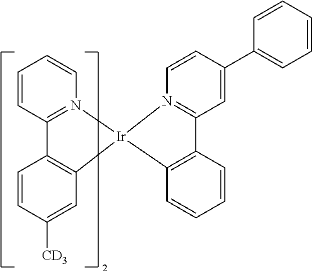

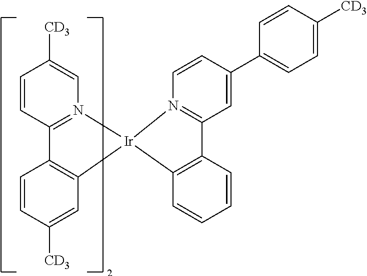

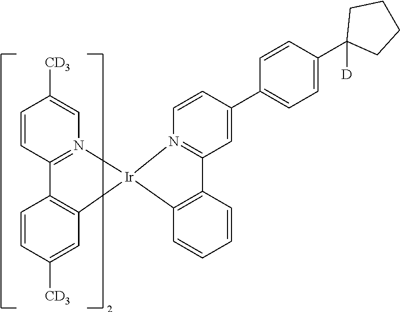

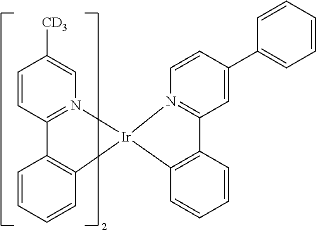

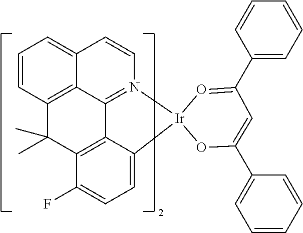

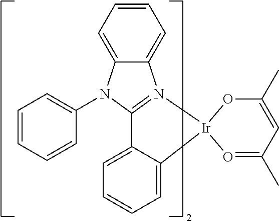

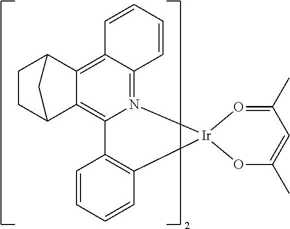

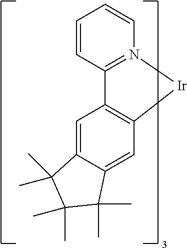

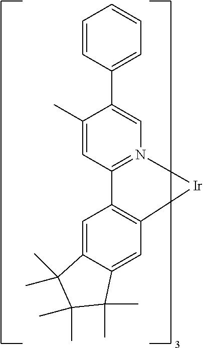

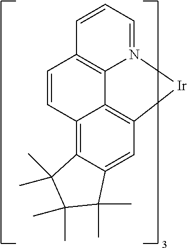

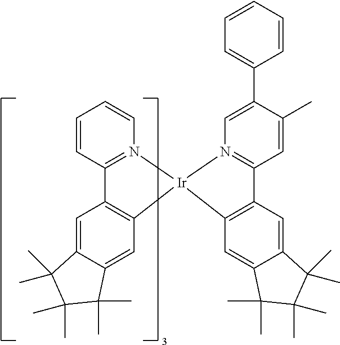

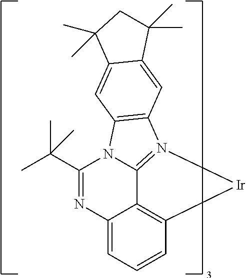

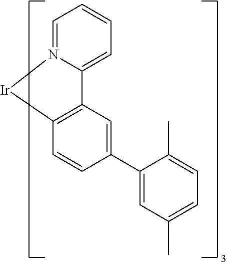

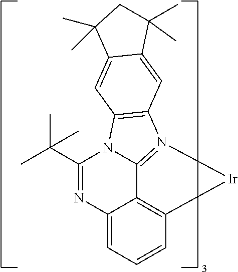

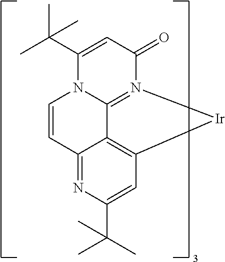

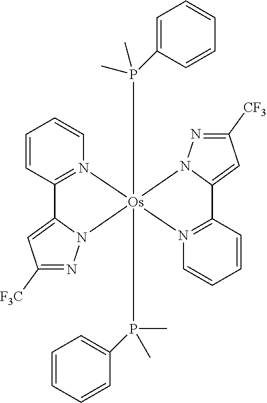

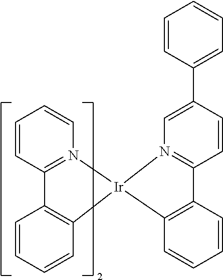

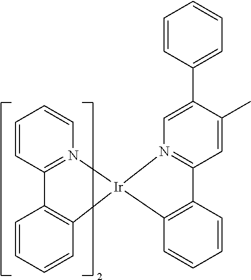

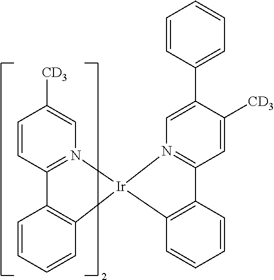

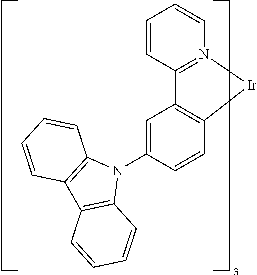

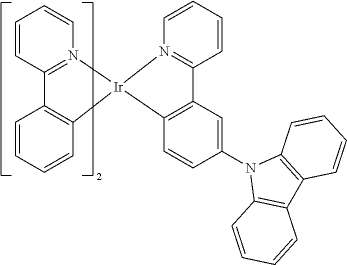

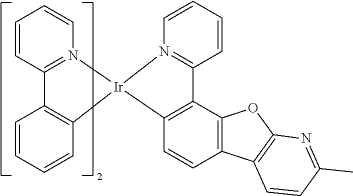

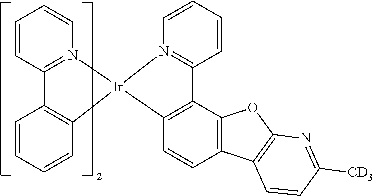

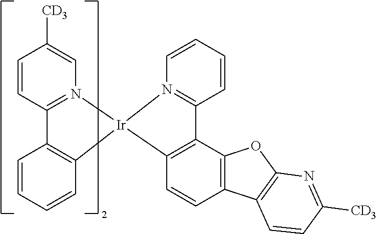

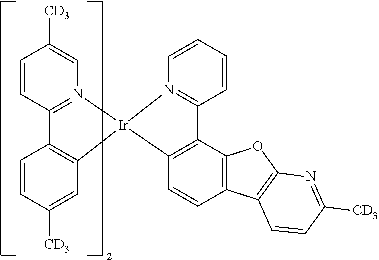

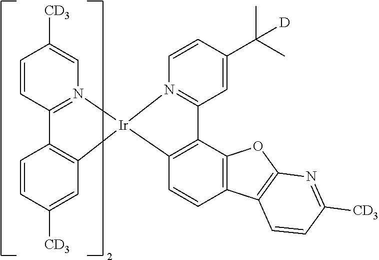

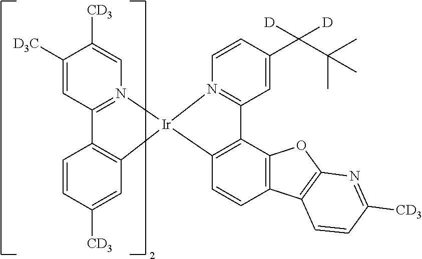

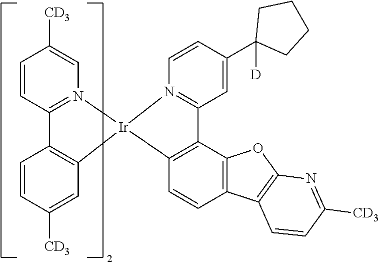

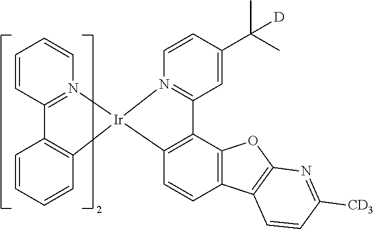

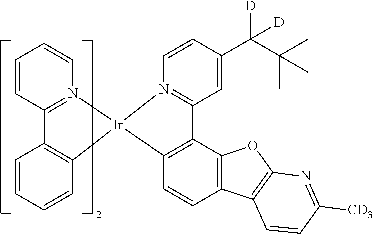

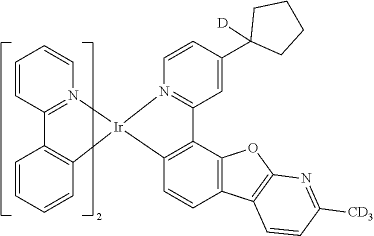

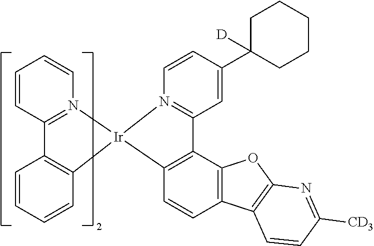

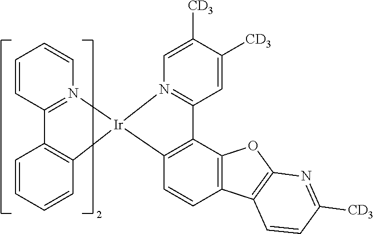

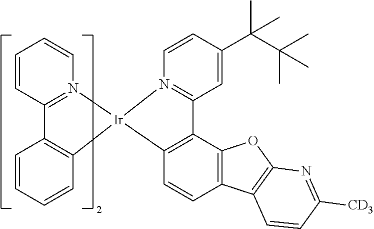

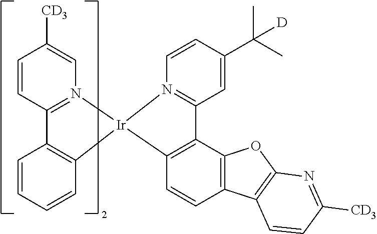

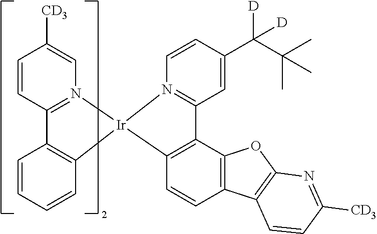

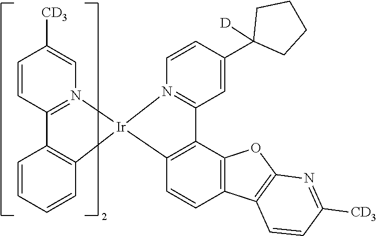

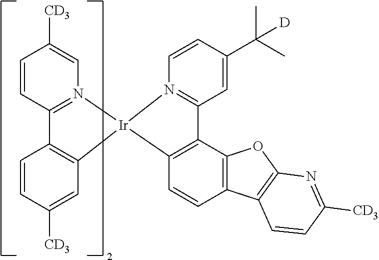

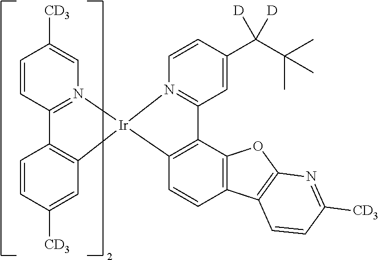

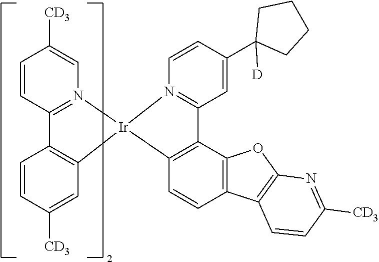

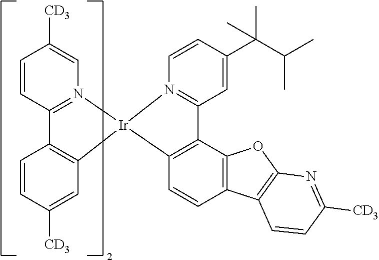

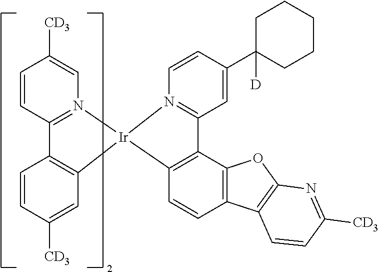

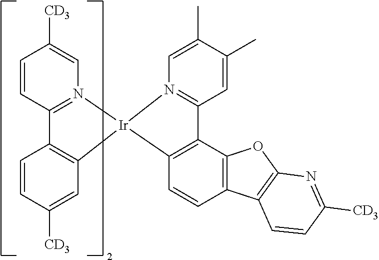

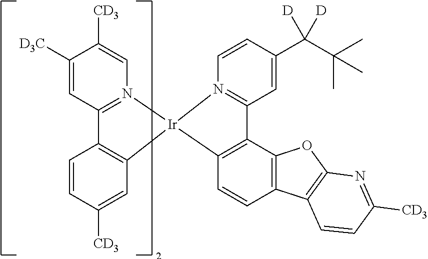

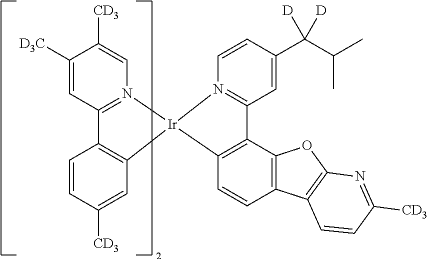

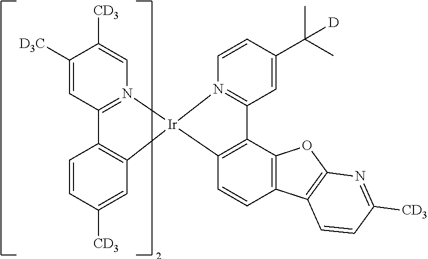

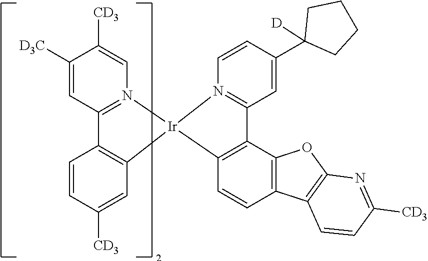

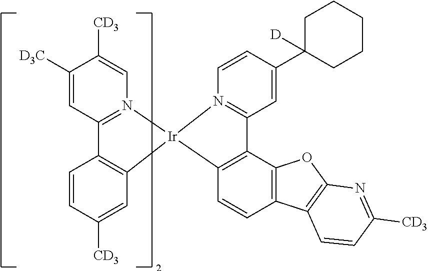

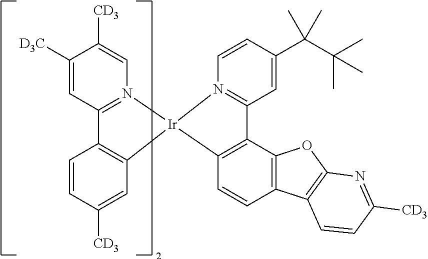

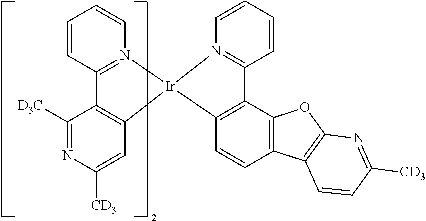

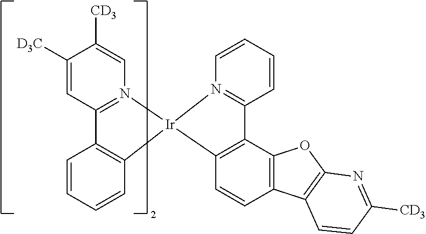

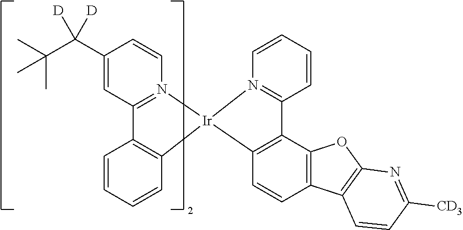

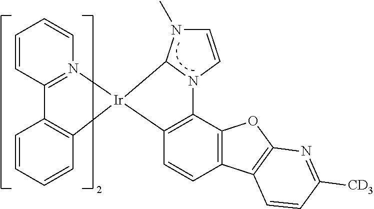

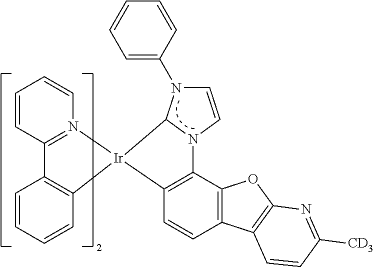

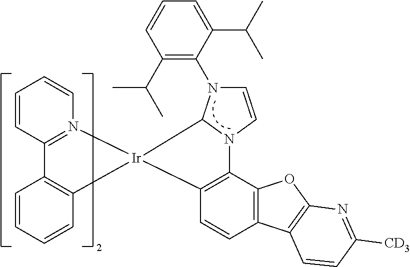

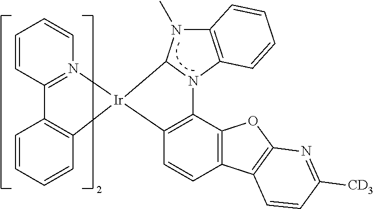

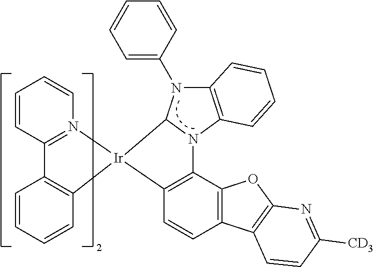

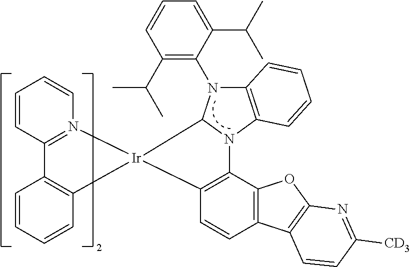

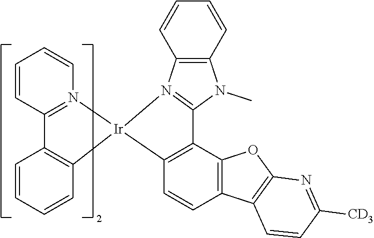

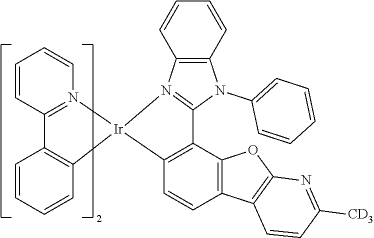

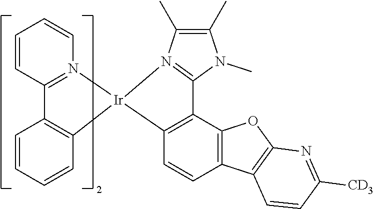

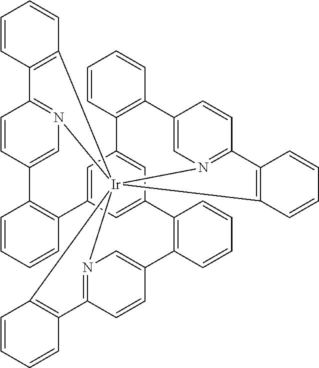

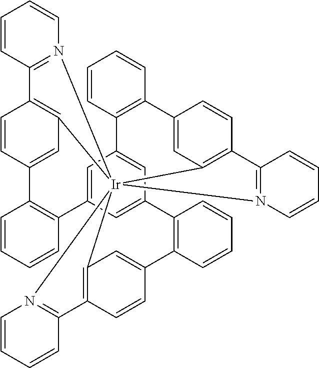

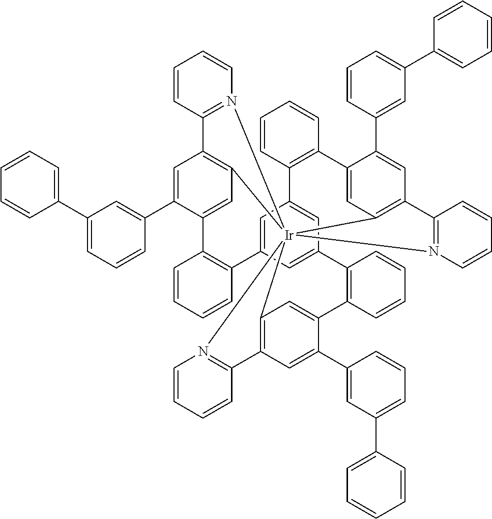

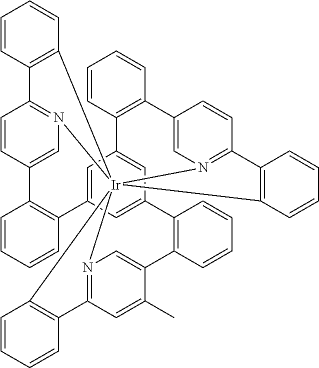

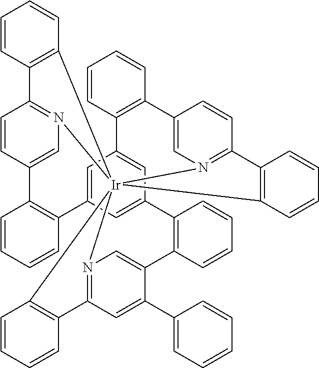

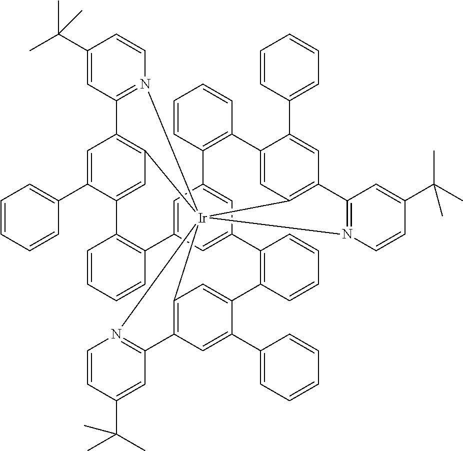

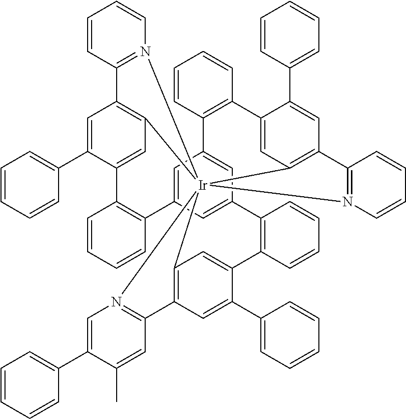

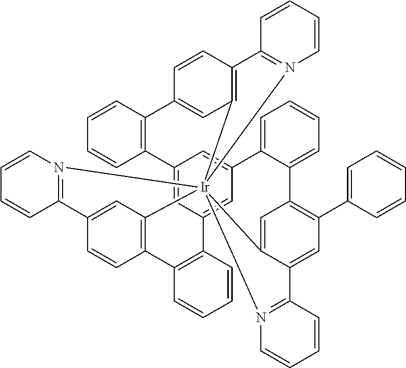

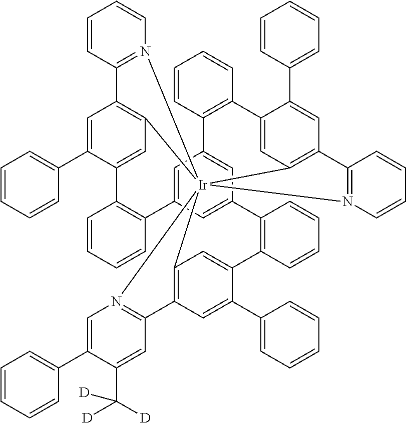

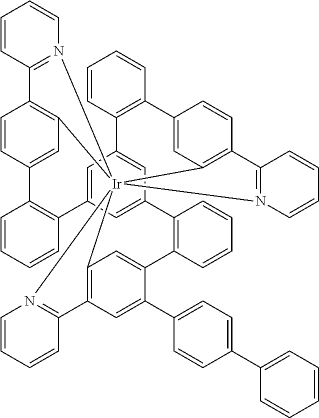

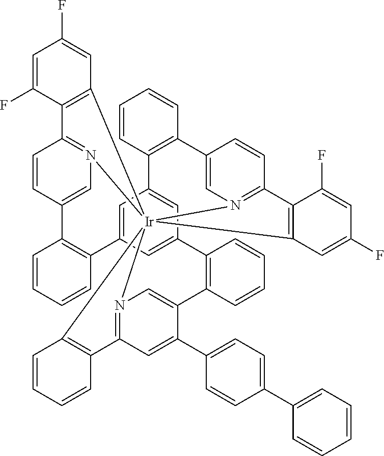

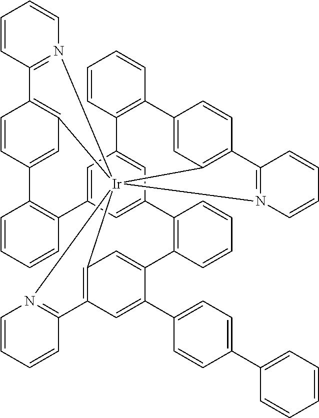

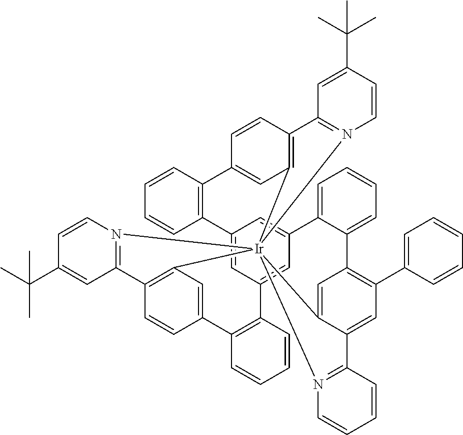

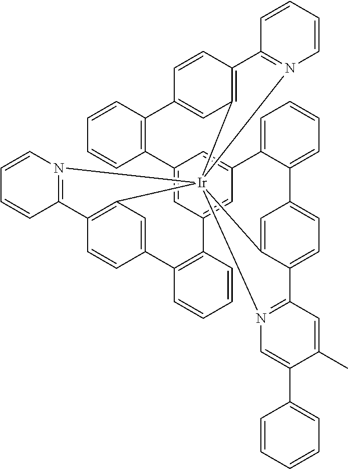

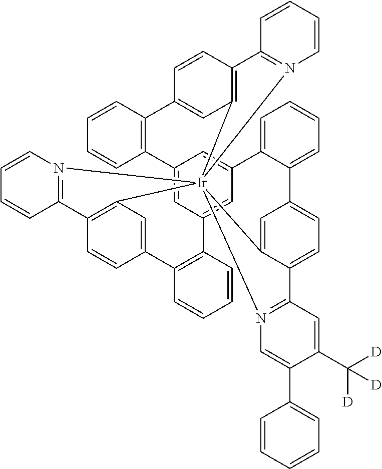

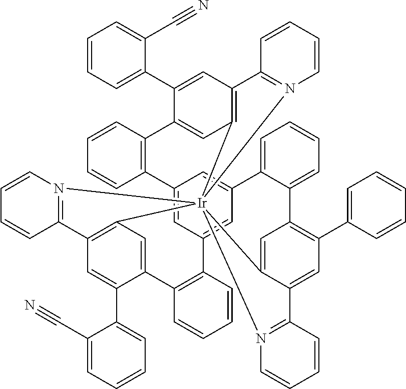

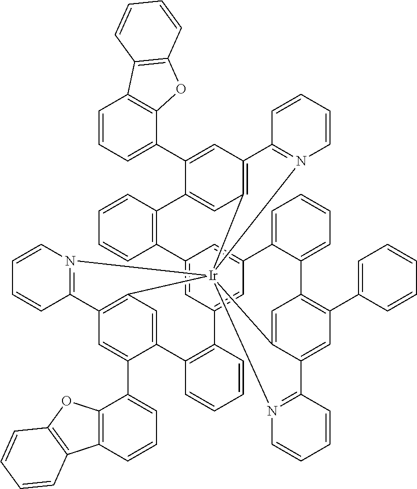

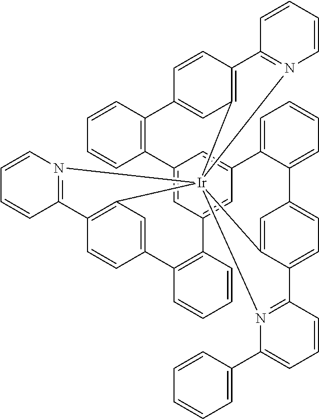

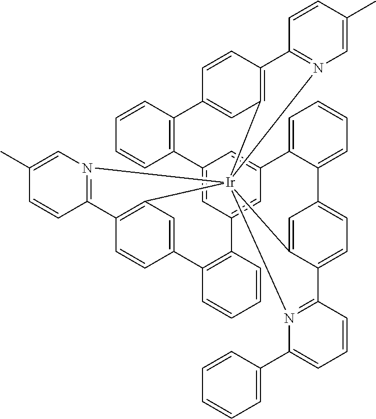

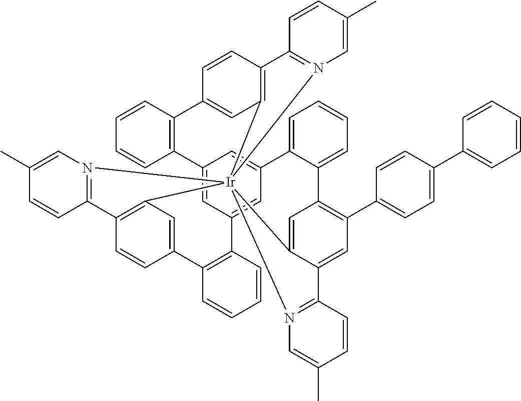

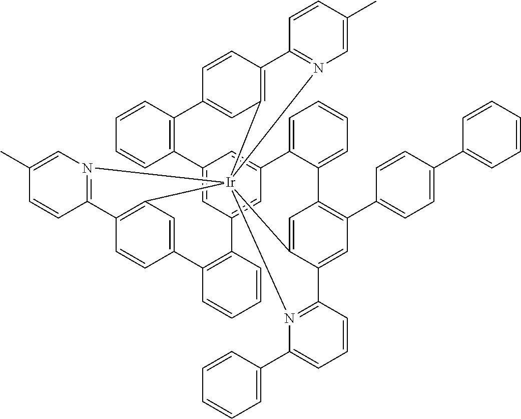

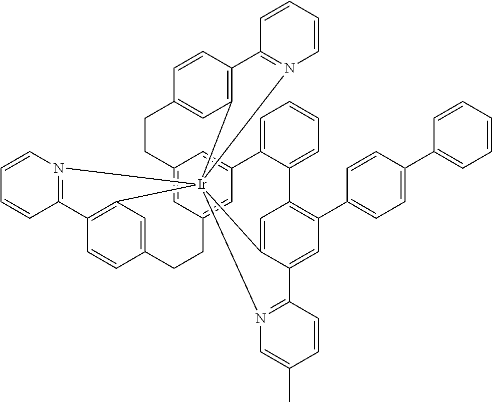

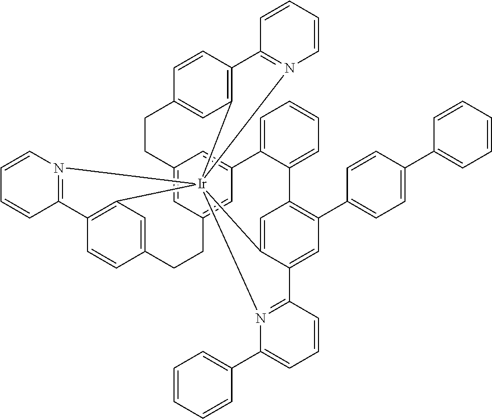

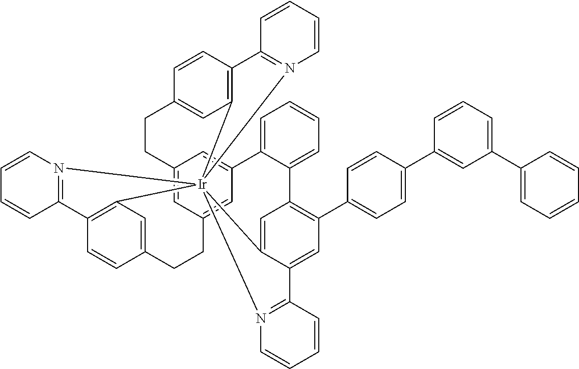

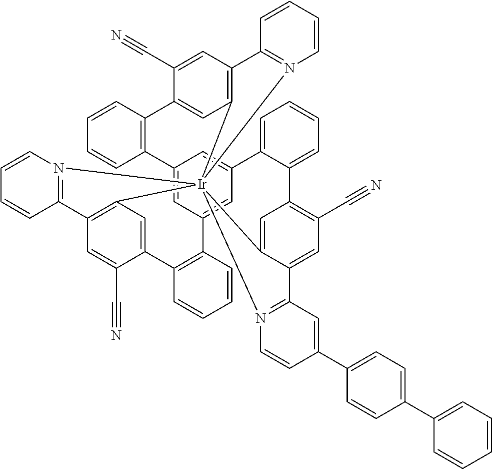

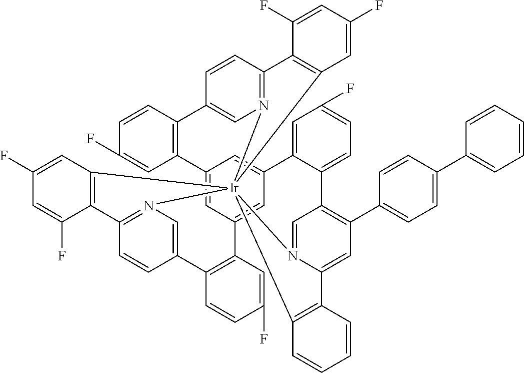

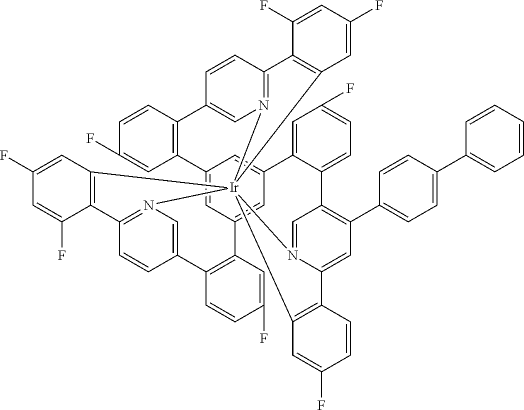

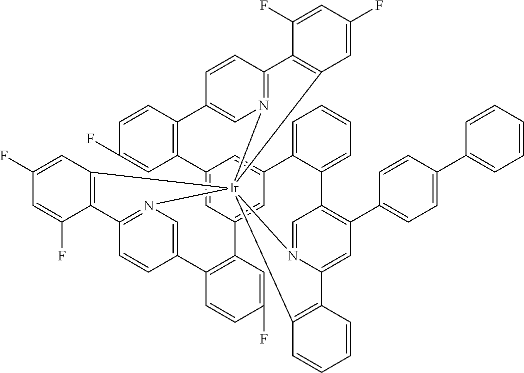

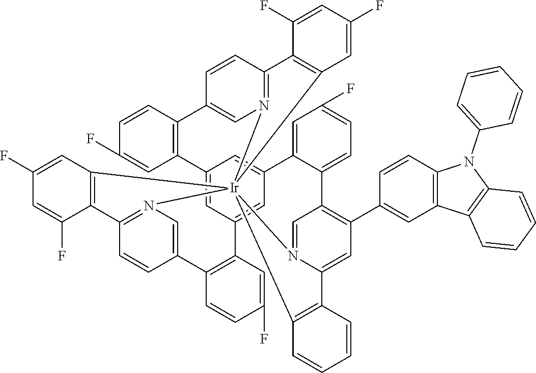

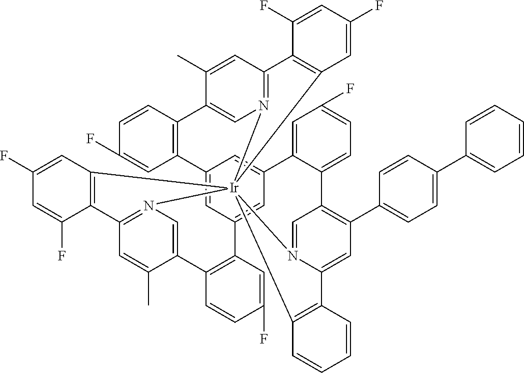

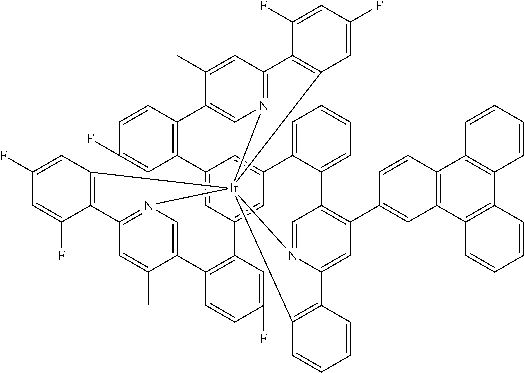

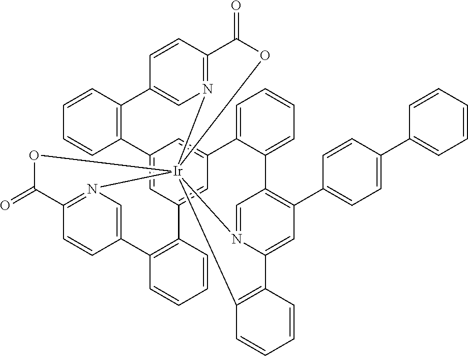

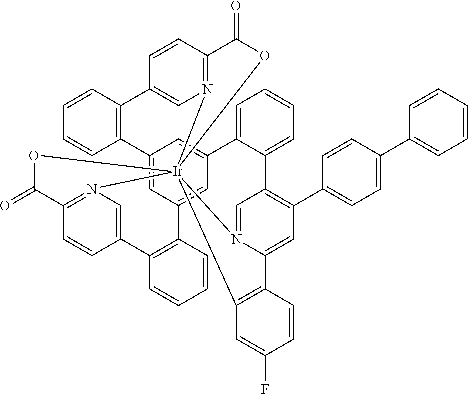

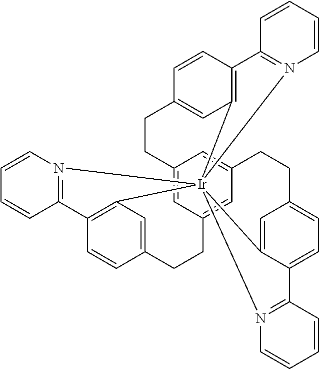

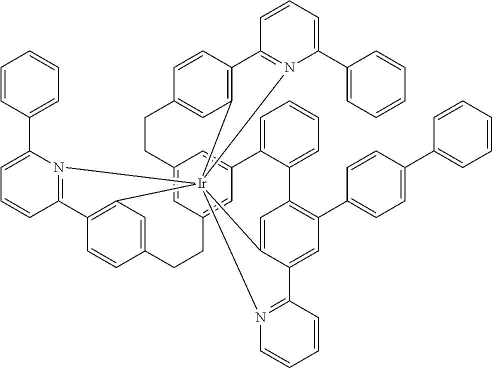

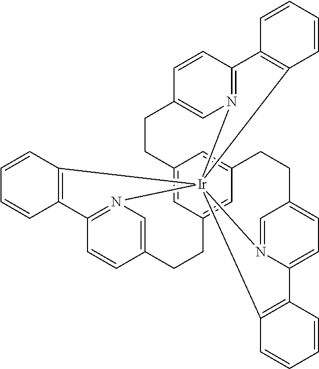

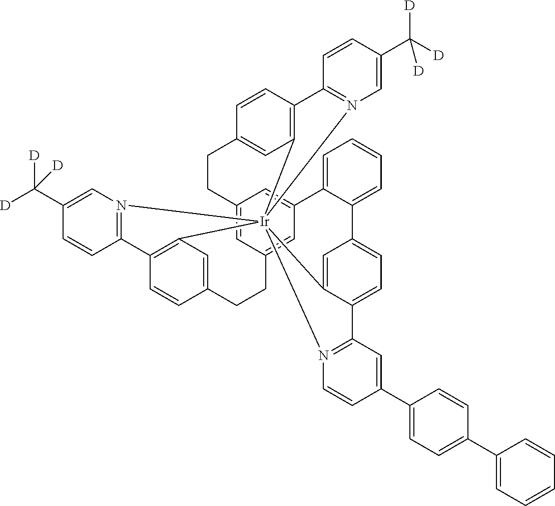

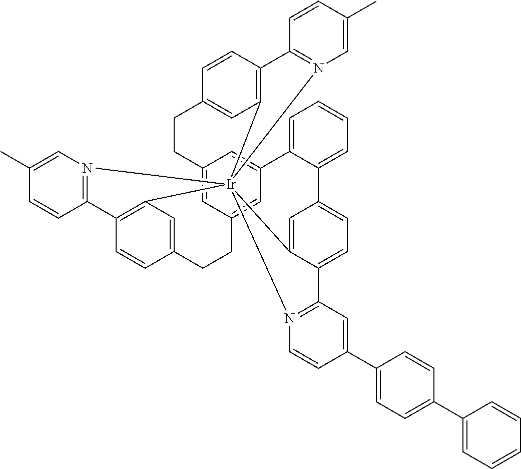

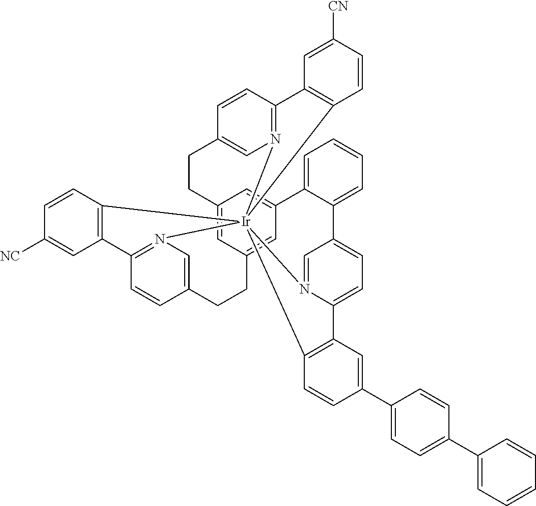

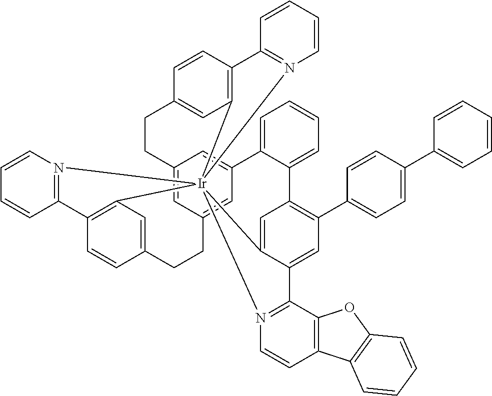

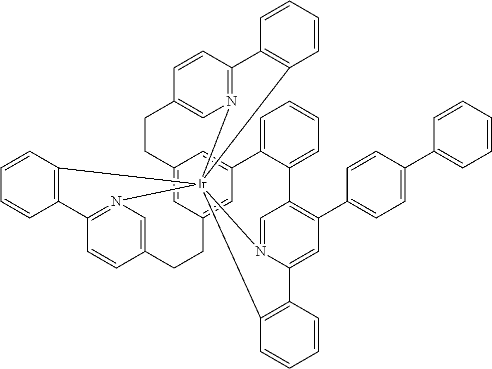

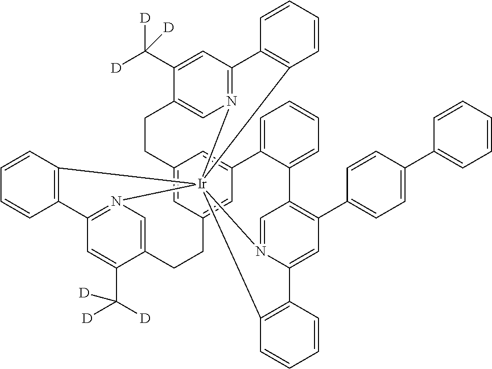

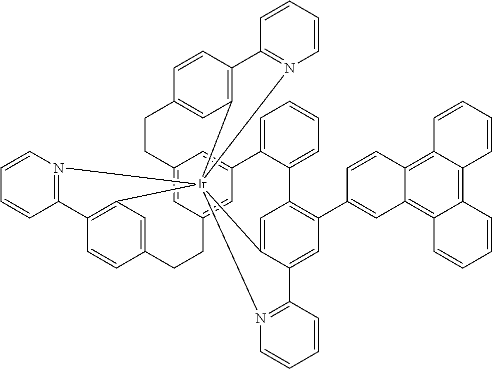

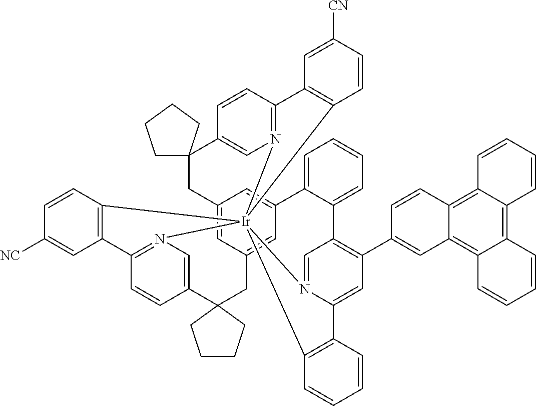

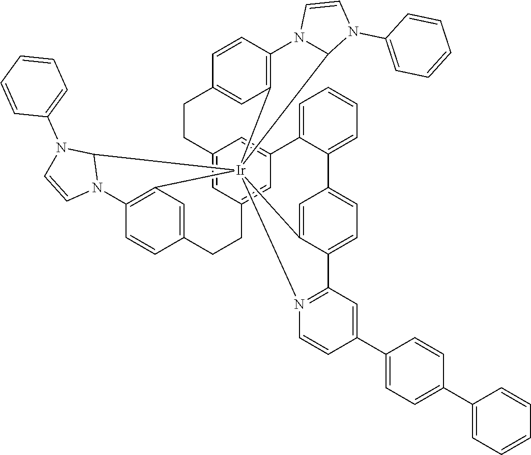

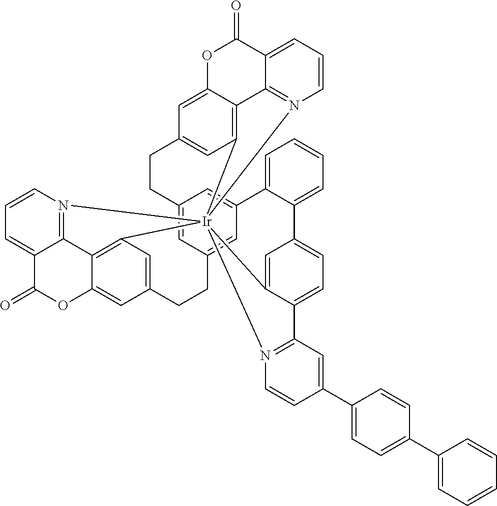

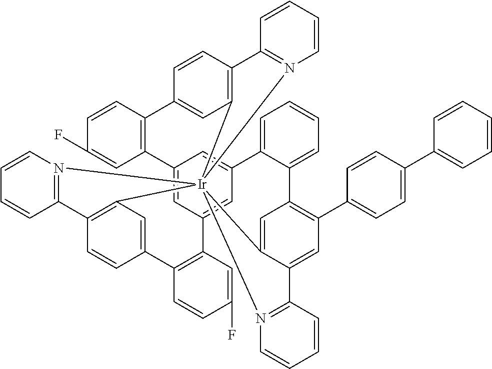

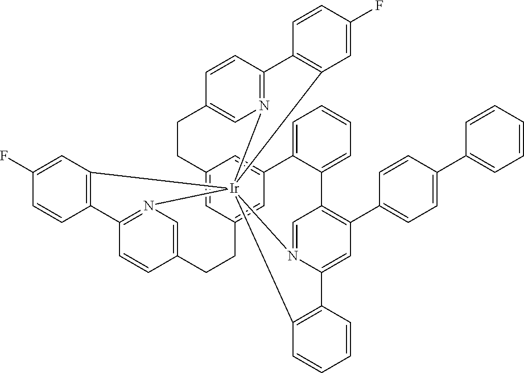

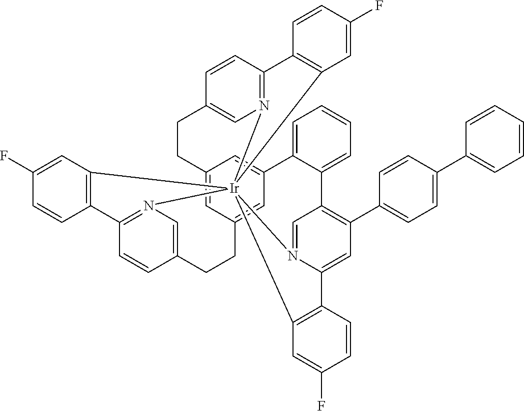

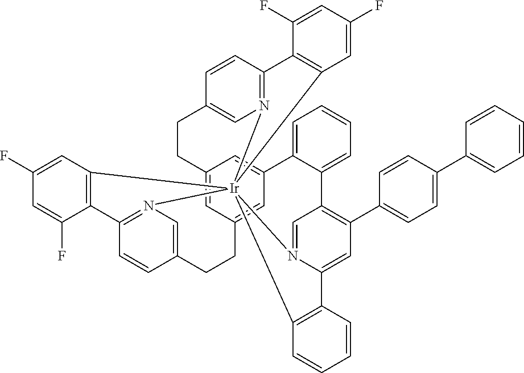

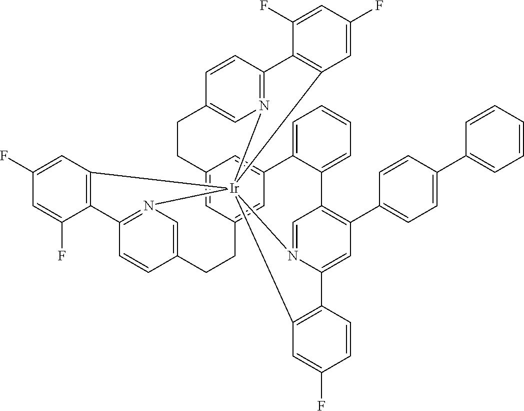

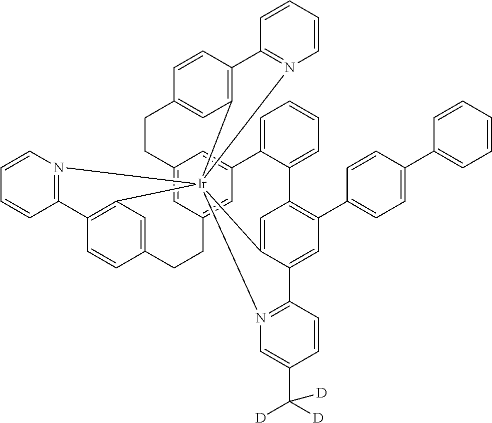

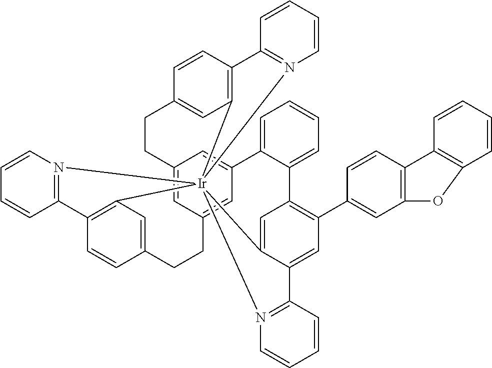

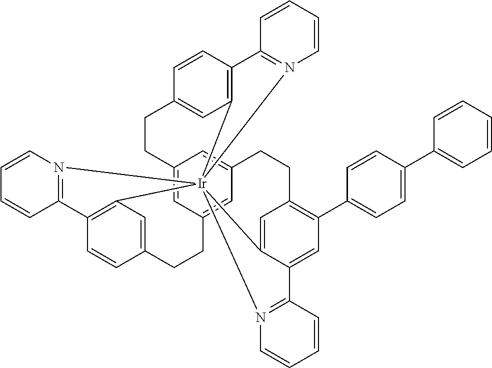

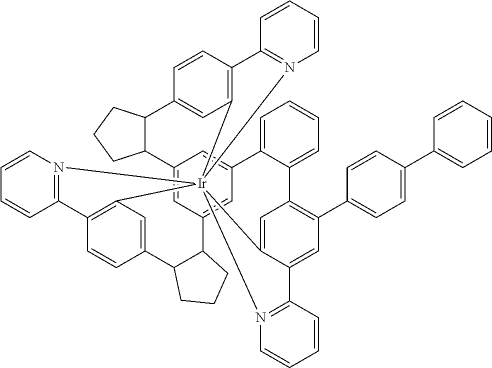

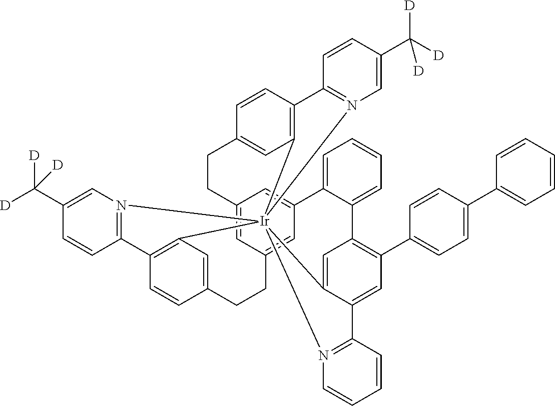

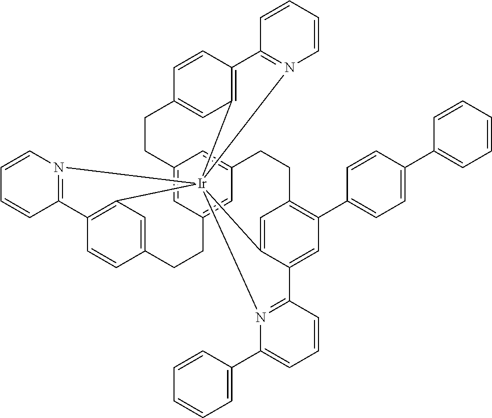

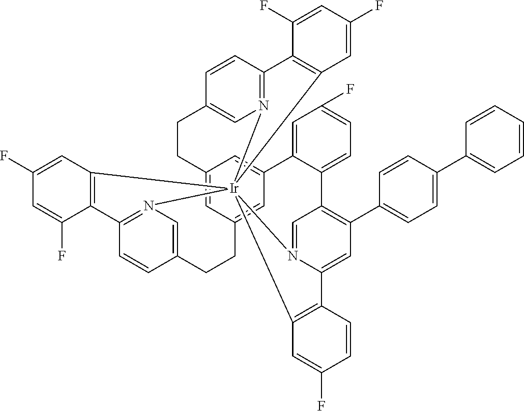

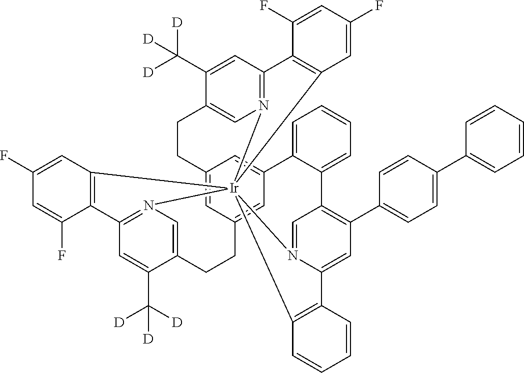

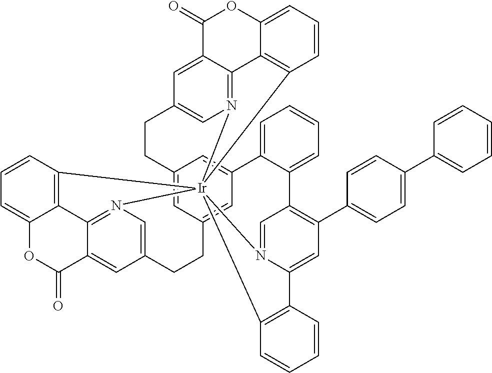

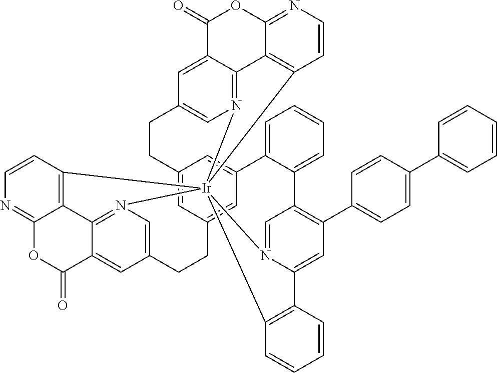

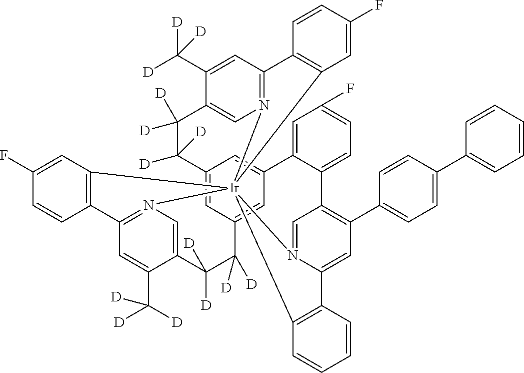

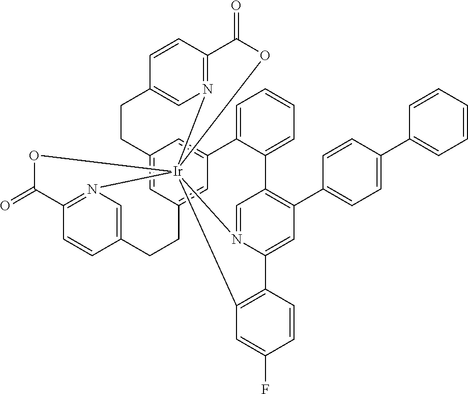

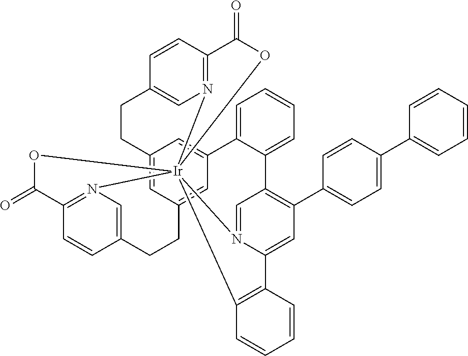

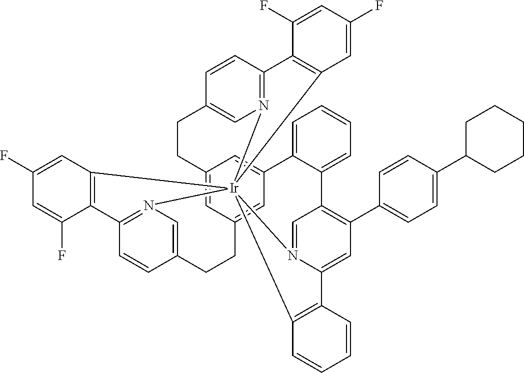

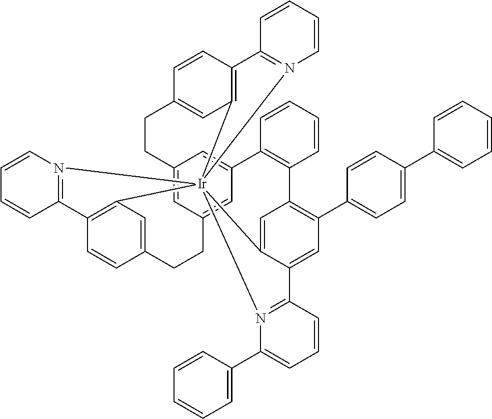

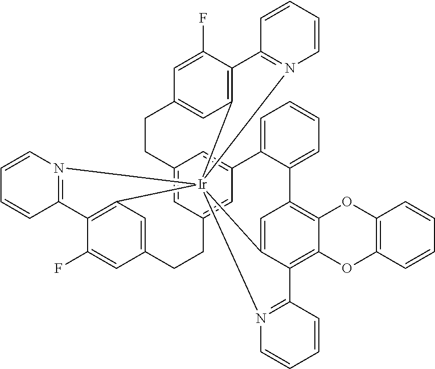

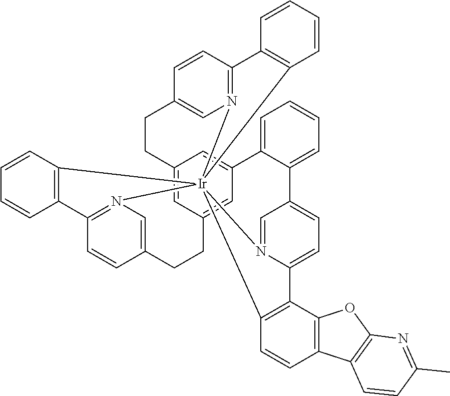

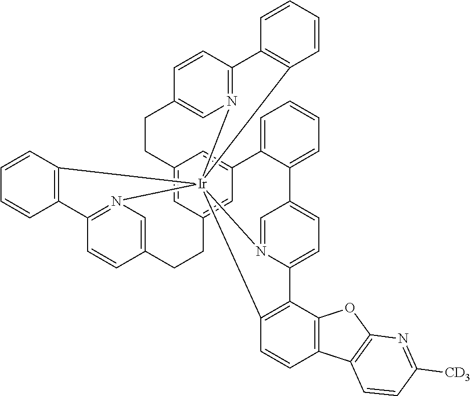

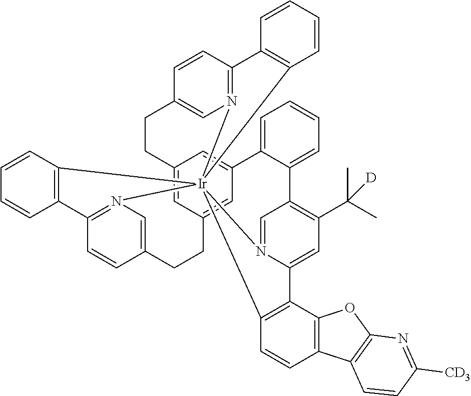

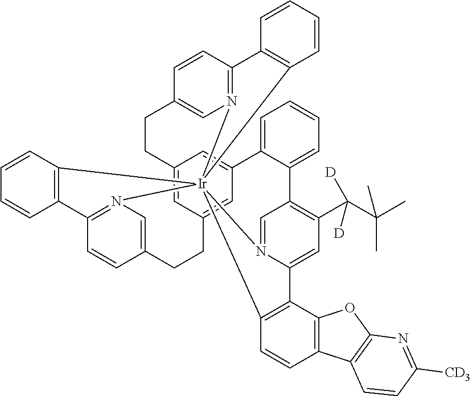

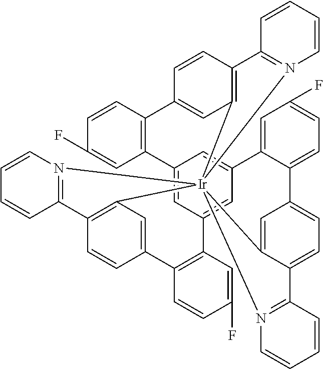

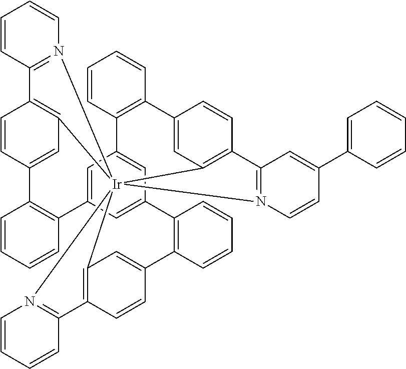

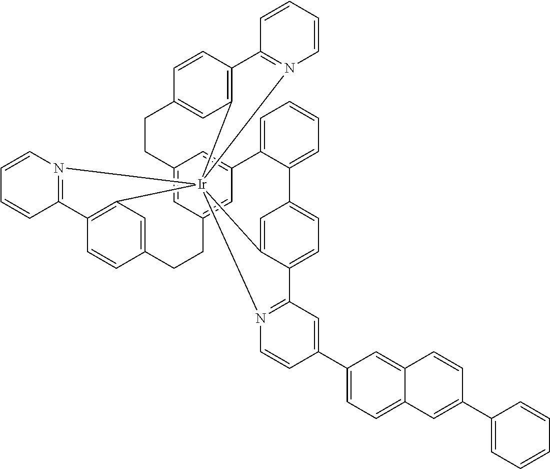

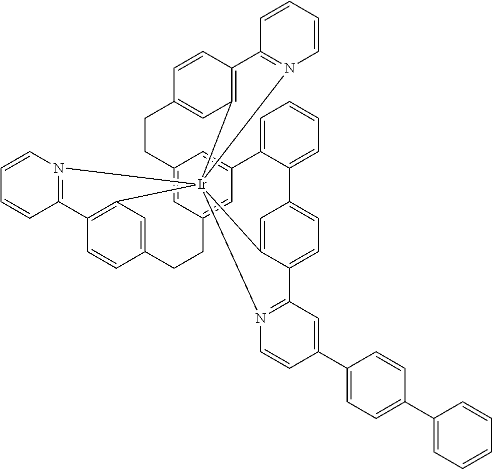

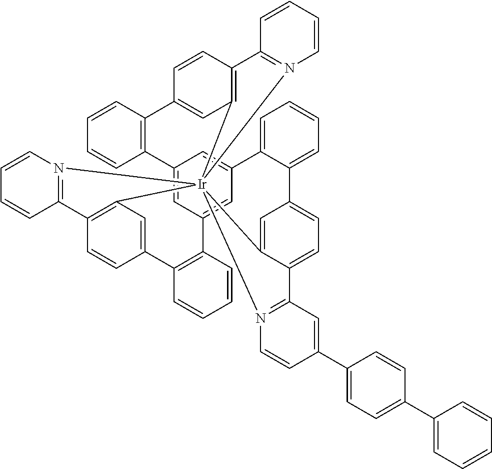

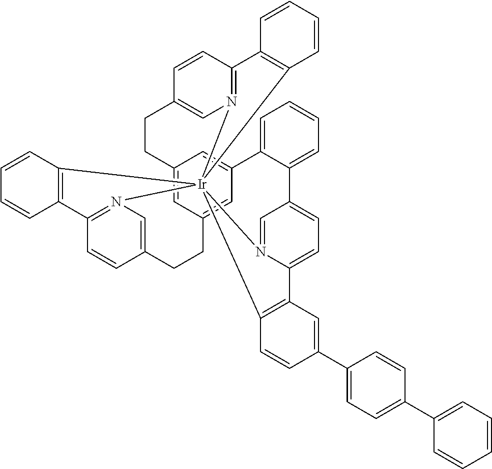

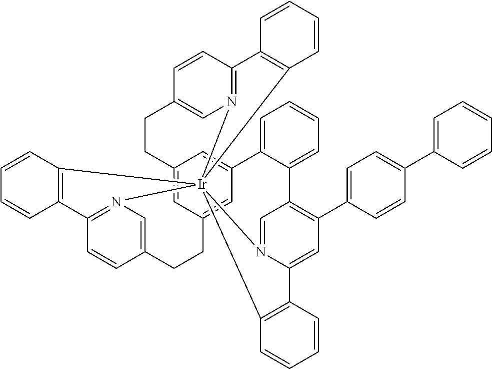

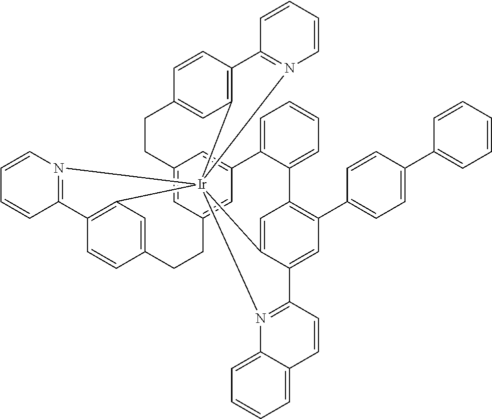

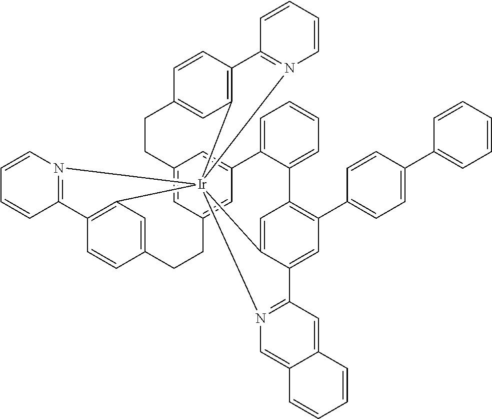

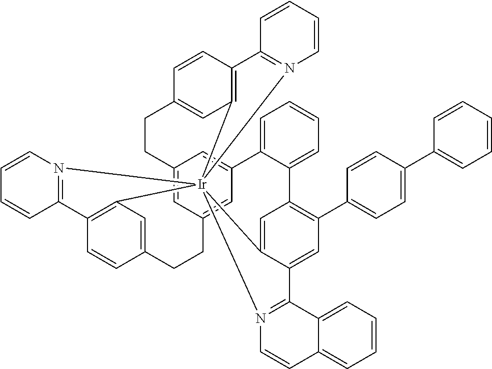

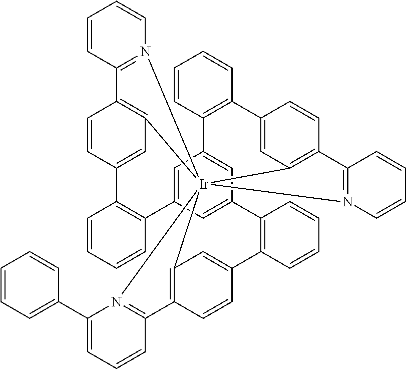

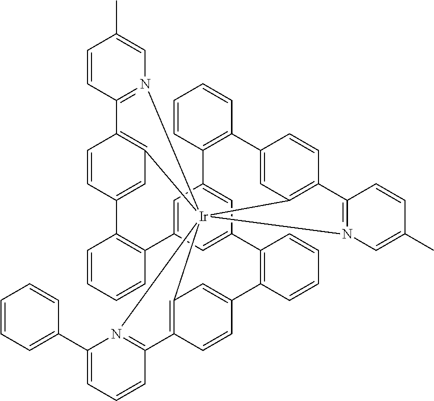

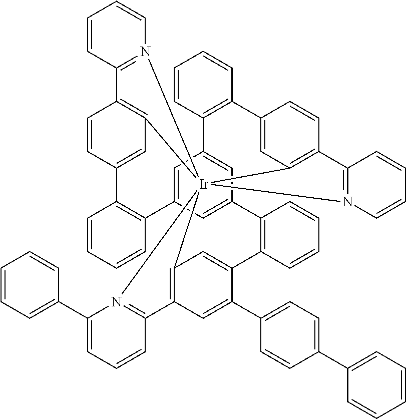

Preferred examples of phosphorescent polypodal emitters are listed in Table 5 below.

TABLE 5

CAS-1269508-30-6
CAS-1215692-34-4
CAS-1370364-40-1
CAS-1370364-42-3
CAS-1989600-74-9
CAS-1989600-75-0
CAS-1989600-77-2
CAS-1989600-78-3
CAS-1989600-79-4
CAS-1989600-82-9
CAS-1989600-83-0
CAS-1989600-84-1
CAS-1989600-85-2
CAS-1989600-86-3
CAS-1989600-87-4
CAS-1989600-88-5
CAS-1989600-89-6
CAS-1989601-11-7
CAS-1989601-23-1
CAS-1989601-26-4
CAS-1989601-28-6
CAS-1989601-29-7
CAS-1989601-33-3
CAS-1989601-40-2
CAS-1989601-41-3
CAS-1989601-42-4
CAS-1989601-43-5
CAS-1989601-44-6
CAS-1989601-45-7
CAS-1989601-46-8
CAS-1989601-47-9
CAS-1989601-48-0
CAS-1989601-49-1
CAS-1989601-50-4
CAS-1989601-51-5
CAS-1989601-52-6
CAS-1989601-53-7
CAS-1989601-54-8
CAS-1989601-55-9
CAS-1989601-56-0
CAS-1989601-57-1
CAS-1989601-58-2
CAS-1989601-59-3
CAS-1989601-60-6
CAS-1989601-61-7
CAS-1989601-62-8
CAS-1989601-63-9
CAS-1989601-64-0
CAS-1989601-65-1
CAS-1989601-66-2
CAS-1989601-67-3
CAS-1989604-35-4
CAS-1989604-36-5
CAS-1989604-37-6
CAS-1989604-38-7
CAS-1989604-39-8
CAS-1989604-40-1
CAS-1989604-41-2
CAS-1989604-42-3
CAS-1989604-43-4
CAS-1989604-45-6
CAS-1989604-46-7
CAS-1989604-47-8
CAS-1989604-48-9
CAS-1989604-49-0
CAS-1989604-50-3
CAS-1989604-52-5
CAS-1989604-53-6
CAS-1989604-54-7
CAS-1989604-55-8
CAS-1989604-56-9
CAS-1989604-57-0
CAS-1989604-58-1
CAS-1989604-59-2
CAS-1989604-60-5
CAS-1989604-61-6
CAS-1989604-62-7
CAS-1989604-63-8
CAS-1989604-64-9
CAS-1989604-65-0
CAS-1989604-66-1
CAS-1989604-67-2
CAS-1989604-68-3
CAS-1989604-69-4
CAS-1989604-70-7
CAS-1989604-71-8
CAS-1989604-72-9
CAS-1989604-73-0
CAS-1989604-74-1
CAS-1989604-75-2
CAS-1989604-76-3
CAS-1989604-77-4
CAS-1989604-78-5
CAS-1989604-79-6
CAS-1989604-80-9
CAS-1989604-81-0
CAS-1989604-82-1
CAS-1989604-83-2
CAS-1989604-84-3
CAS-1989604-85-4
CAS-1989604-86-5
CAS-1989604-87-6
CAS-1989658-39-0
CAS-1989658-41-4
CAS-1989658-43-6
CAS-1989658-47-0
CAS-1989658-49-2
CAS-2088184-07-8
CAS-2088184-08-9
CAS-2088184-09-0
CAS-2088184-10-3
CAS-2088184-11-4
CAS-2088184-13-6
CAS-2088184-14-7
CAS-2088184-15-8
CAS-2088184-16-9
CAS-2088184-17-0
CAS-2088184-18-1
CAS-2088184-19-2
CAS-2088184-20-5
CAS-2088184-21-6
CAS-2088184-22-7
CAS-2088184-23-8
CAS-2088184-24-9
CAS-2088184-25-0
CAS-2088184-26-1
CAS-2088184-27-2
CAS-2088184-28-3
CAS-2088184-29-4
CAS-2088184-30-7
CAS-2088184-32-9
CAS-2088184-34-1
CAS-2088184-35-2
CAS-2088184-36-3
CAS-2088184-37-4
CAS-2088184-38-5
CAS-2088184-39-6
CAS-2088184-40-9
CAS-2088184-41-0
CAS-2088184-42-1
CAS-2088184-43-2
CAS-2088184-44-3
CAS-2088184-45-4
CAS-2088184-46-5
CAS-2088184-47-6
CAS-2088184-48-7
CAS-2088184-49-8
CAS-2088184-50-1
CAS-2088184-51-2
CAS-2088184-52-3
CAS-2088184-53-4
CAS-2088184-54-5
CAS-2088184-55-6
CAS-1989601-68-4
CAS-1989601-69-5
CAS-1989601-70-8
CAS-1989601-71-9
CAS-1989601-72-0
CAS-1989601-73-1
CAS-1989601-74-2
CAS-1989601-75-3
CAS-1989601-76-4
CAS-1989601-77-5
CAS-1989601-78-6
CAS-1989601-79-7
CAS-1989601-80-0
CAS-1989601-81-1
CAS-1989601-82-2
CAS-1989601-83-3
CAS-1989601-84-4
CAS-1989601-85-5
CAS-1989601-86-6
CAS-1989601-87-7
CAS-1989601-88-8
CAS-1989601-89-9
CAS-1989601-90-2
CAS-1989601-91-3
CAS-1989601-92-4
CAS-1989601-93-5
CAS-1989601-94-6
CAS-1989601-95-7
CAS-1989601-96-8
CAS-1989601-97-9
CAS-1989601-98-0
CAS-1989601-99-1
CAS-1989602-00-7
CAS-1989602-01-8
CAS-1989602-02-9
CAS-1989602-03-0
CAS-1989602-04-1
CAS-1989602-05-2
CAS-1989602-06-3
CAS-1989602-07-4
CAS-1989602-08-5
CAS-1989602-09-6
CAS-1989602-10-9
CAS-1989602-11-0
CAS-1989602-12-1
CAS-1989602-13-2
CAS-1989602-14-3
CAS-1989602-15-4
CAS-1989602-16-5
CAS-1989602-17-6
CAS-1989602-18-7
CAS-1989604-88-7
CAS-1989604-89-8
CAS-1989604-90-1
CAS-1989604-92-3
CAS-1989604-93-4
CAS-1989604-94-5
CAS-1989604-95-6
CAS-1989604-96-7
CAS-1989604-97-8
CAS-1989605-09-5
CAS-1989605-10-8
CAS-1989605-11-9
CAS-1989605-13-1
CAS-1989605-14-2
CAS-1989605-15-3
CAS-1989605-16-4
CAS-1989605-17-5
CAS-1989605-18-6
CAS-1989605-19-7
CAS-1989605-20-0
CAS-1989605-21-1
CAS-1989605-22-2
CAS-1989605-23-3
CAS-1989605-24-4
CAS-1989605-25-5
CAS-1989605-26-6
CAS-1989605-27-7
CAS-1989605-28-8
CAS-1989605-29-9
CAS-1989605-30-2
CAS-1989605-31-3
CAS-1989605-32-4
CAS-1989605-33-5
CAS-1989605-34-6
CAS-1989605-35-7
CAS-1989605-36-8
CAS-1989605-37-9
CAS-1989605-38-0
CAS-1989605-39-1
CAS-1989605-40-4
CAS-1989605-41-5
CAS-1989605-42-6
CAS-1989605-43-7
CAS-1989605-44-8
CAS-1989605-45-9
CAS-1989605-46-0
CAS-1989605-47-1
CAS-1989605-48-2
CAS-1989605-49-3
CAS-1989605-50-6
CAS-1989605-51-7
CAS-2088184-56-7
CAS-2088184-57-8
CAS-2088184-58-9
CAS-2088184-59-0
CAS-2088184-60-3
CAS-2088184-61-4
CAS-2088184-62-5
CAS-2088184-63-6
CAS-2088184-64-7
CAS-2088184-65-8
CAS-2088184-66-9
CAS-2088184-67-0
CAS-2088184-68-1
CAS-2088184-69-2
CAS-2088184-70-5
CAS-2088184-71-6
CAS-2088184-72-7
CAS-2088184-73-8
CAS-2088184-74-9
CAS-2088184-75-0
CAS-2088184-76-1
CAS-2088184-77-2
CAS-2088184-78-3
CAS-2088184-79-4
CAS-2088184-80-7
CAS-2088184-81-8
CAS-2088184-82-9
CAS-2088184-83-0
CAS-2088184-84-1
CAS-2088184-85-2
CAS-2088184-86-3
CAS-2088184-87-4
CAS-2088184-88-5
CAS-2088184-89-6
CAS-2088184-90-9
CAS-2088184-91-0
CAS-2088184-92-1
CAS-2088184-93-2
CAS-2088184-94-3
CAS-2088184-95-4
CAS-2088184-96-5
CAS-2088184-97-6
CAS-2088184-98-7
CAS-2088184-99-8
CAS-2088185-00-4
CAS-2088185-01-5
CAS-2088185-02-6
CAS-2088185-03-7
CAS-2088185-04-8
CAS-2088185-05-9
CAS-2088185-06-0
CAS-1989602-19-8
CAS-1989602-20-1
CAS-1989602-21-2
CAS-1989602-22-3
CAS-1989602-23-4
CAS-1989602-24-5
CAS-1989602-25-6
CAS-1989602-26-7
CAS-1989602-27-8
CAS-1989602-28-9
CAS-1989602-29-0
CAS-1989602-30-3
CAS-1989602-31-4
CAS-1989602-32-5
CAS-1989602-33-6
CAS-1989602-34-7
CAS-1989602-35-8
CAS-1989602-36-9
CAS-1989602-37-0
CAS-1989602-38-1
CAS-1989602-39-2
CAS-1989602-40-5
CAS-1989602-41-6
CAS-1989602-42-7
CAS-1989602-43-8
CAS-1989602-44-9
CAS-1989602-45-0
CAS-1989602-46-1
CAS-1989602-47-2
CAS-1989602-48-3
CAS-1989602-49-4
CAS-1989602-50-7
CAS-1989602-51-8
CAS-1989602-52-9
CAS-1989602-53-0
CAS-1989602-54-1
CAS-1989602-55-2
CAS-1989602-56-3
CAS-1989602-57-4
CAS-1989602-58-5
CAS-1989602-59-6
CAS-1989602-60-9
CAS-1989602-61-0
CAS-1989602-62-1
CAS-1989602-63-2
CAS-1989602-64-3
CAS-1989602-65-4
CAS-1989602-66-5
CAS-1989602-67-6
CAS-1989602-68-7
CAS-1989602-69-8
CAS-1989605-52-8
CAS-1989605-53-9
CAS-1989605-54-0
CAS-1989605-55-1
CAS-1989605-56-2
CAS-1989605-57-3
CAS-1989605-58-4
CAS-1989605-59-5
CAS-1989605-61-9
CAS-1989605-62-0
CAS-1989605-63-1
CAS-1989605-64-2
CAS-1989605-65-3
CAS-1989605-66-4
CAS-1989605-67-5
CAS-1989605-68-6
CAS-1989605-69-7
CAS-1989605-70-0
CAS-1989605-71-1
CAS-1989605-72-2
CAS-1989605-73-3
CAS-1989605-74-4
CAS-1989605-75-5
CAS-1989605-76-6
CAS-1989605-77-7
CAS-1989605-78-8
CAS-1989605-79-9
CAS-1989605-81-3
CAS-1989605-82-4
CAS-1989605-83-5
CAS-1989605-84-6
CAS-1989605-85-7
CAS-1989605-86-8
CAS-1989605-87-9
CAS-1989605-88-0
CAS-1989605-89-1
CAS-1989605-90-4
CAS-1989605-91-5
CAS-1989605-92-6
CAS-1989605-93-7
CAS-1989605-94-8
CAS-1989605-95-9
CAS-1989605-96-0
CAS-1989605-97-1
CAS-1989605-98-2
CAS-1989605-99-3
CAS-1989606-00-9
CAS-1989606-01-0
CAS-1989606-04-3
CAS-1989606-05-4
CAS-1989606-06-5
CAS-2088185-07-1
CAS-2088185-08-2
CAS-2088185-09-3
CAS-2088185-10-6
CAS-2088185-11-7
CAS-2088185-12-8
CAS-2088185-13-9
CAS-2088185-14-0
CAS-2088185-15-1
CAS-2088185-16-2
CAS-2088185-17-3
CAS-2088185-18-4
CAS-2088185-19-5
CAS-2088185-20-8
CAS-2088185-21-9
CAS-2088185-22-0
CAS-2088185-23-1
CAS-2088185-32-2
CAS-2088185-33-3
CAS-2088185-34-4
CAS-2088185-35-5
CAS-2088185-36-6
CAS-2088185-37-7
CAS-2088185-38-8
CAS-2088185-39-9
CAS-2088185-40-2
CAS-2088185-41-3
CAS-2088185-42-4
CAS-2088185-43-5
CAS-2088185-44-6
CAS-2088185-45-7
CAS-2088185-46-8
CAS-2088185-47-9
CAS-2088185-48-0
CAS-2088185-49-1
CAS-2088185-50-4
CAS-2088185-51-5
CAS-2088185-52-6
CAS-2088185-53-7
CAS-2088185-54-8
CAS-2088185-55-9
CAS-2088185-56-0
CAS-2088185-57-1
CAS-2088185-58-2
CAS-2088185-59-3
CAS-2088185-60-6
CAS-2088185-61-7
CAS-2088185-62-8
CAS-2088185-63-9
CAS-2088185-64-0
CAS-2088185-65-1
CAS-1989602-70-1
CAS-1989602-71-2
CAS-1989602-72-3
CAS-1989602-73-4
CAS-1989602-74-5
CAS-1989602-75-6
CAS-1989602-76-7
CAS-1989602-77-8
CAS-1989602-78-9
CAS-1989602-79-0
CAS-1989602-80-3
CAS-1989602-82-5
CAS-1989602-84-7
CAS-1989602-85-8
CAS-1989602-86-9
CAS-1989602-87-0
CAS-1989602-88-1
CAS-1989604-00-3
CAS-1989604-01-4
CAS-1989604-02-5
CAS-1989604-03-6
CAS-1989604-04-7
CAS-1989604-05-8
CAS-1989604-06-9
CAS-1989604-07-0
CAS-1989604-08-1
CAS-1989604-09-2
CAS-1989604-10-5
CAS-1989604-11-6
CAS-1989604-13-8
CAS-1989604-14-9
CAS-1989604-15-0
CAS-1989604-16-1
CAS-1989604-17-2
CAS-1989604-18-3
CAS-1989604-19-4
CAS-1989604-20-7
CAS-1989604-21-8
CAS-1989604-22-9
CAS-1989604-23-0
CAS-1989604-24-1
CAS-1989604-25-2
CAS-1989604-26-3
CAS-1989604-27-4
CAS-1989604-28-5
CAS-1989604-29-6
CAS-1989604-30-9
CAS-1989604-31-0
CAS-1989604-32-1
CAS-1989604-33-2
CAS-1989604-34-3
CAS-1989606-07-6
CAS-1989606-08-7
CAS-1989606-09-8
CAS-1989606-10-1
CAS-1989606-11-2
CAS-1989606-12-3
CAS-1989606-13-4
CAS-1989606-14-5
CAS-1989606-15-6
CAS-1989606-16-7
CAS-1989606-17-8
CAS-1989606-18-9
CAS-1989606-19-0
CAS-1989606-20-3
CAS-1989606-21-4
CAS-1989606-22-5
CAS-1989606-23-6
CAS-1989606-24-7
CAS-1989606-26-9
CAS-1989606-27-0
CAS-1989606-28-1
CAS-1989606-29-2
CAS-1989606-30-5
CAS-1989606-31-6
CAS-1989606-32-7
CAS-1989606-33-8
CAS-1989606-34-9
CAS-1989606-35-0
CAS-1989606-36-1
CAS-1989606-37-2
CAS-1989606-38-3
CAS-1989606-39-4
CAS-1989606-40-7
CAS-1989606-41-8
CAS-1989606-42-9
CAS-1989606-43-0
CAS-1989606-44-1
CAS-1989606-45-2
CAS-1989606-46-3
CAS-1989606-48-5
CAS-1989606-49-6
CAS-1989606-53-2
CAS-1989606-55-4
CAS-1989606-56-5
CAS-1989606-61-2
CAS-1989606-62-3
CAS-1989606-63-4
CAS-1989606-67-8
CAS-1989606-69-0
CAS-1989606-70-3
CAS-1989606-74-7
CAS-2088185-66-2
CAS-2088185-67-3
CAS-2088185-68-4
CAS-2088185-69-5
CAS-2088185-70-8
CAS-2088185-71-9
CAS-2088185-72-0
CAS-2088185-73-1
CAS-2088185-74-2
CAS-2088185-75-3
CAS-2088185-76-4
CAS-2088185-77-5
CAS-2088185-78-6
CAS-2088185-79-7
CAS-2088185-80-0
CAS-2088185-81-1
CAS-2088185-82-2
CAS-2088185-83-3
CAS-2088185-84-4
CAS-2088185-85-5
CAS-2088185-86-6
CAS-2088185-87-7
CAS-2088185-88-8
CAS-2088185-89-9
CAS-2088185-90-2
CAS-2088185-91-3
CAS-2088185-92-4
CAS-2088185-93-5
CAS-2088185-94-6
CAS-2088185-95-7
CAS-2088185-96-8
CAS-2088185-97-9
CAS-2088185-98-0
CAS-2088185-99-1
CAS-2088186-00-7
CAS-2088186-01-8
CAS-2088186-02-9
CAS-2088195-88-2
CAS-2088195-89-3
CAS-2088195-90-6
CAS-2088195-91-7
CAS-861806-70-4
CAS-1269508-30-6

In the composition/mixture of the invention, preferably any mixture M1 to M1597, as described above, is combined with a compound of the formula (3) or a compound from Table 4 or 5.

The composition of the invention preferably consists of at least one compound of the formula (1), at least one compound of the formula (2) and one or two emitters selected from compounds of the formula (3), Table 4 or Table 5.

The light-emitting layer in the organic electroluminescent device containing a composition as described above or described with preference and at least one phosphorescent emitter is preferably an infrared-emitting or yellow-, orange-, red-, green-, blue- or ultraviolet-emitting layer, more preferably a yellow- or green-emitting layer and most preferably a green-emitting layer. containing at least one phosphorescent emitter preferably forms an infrared-emitting or yellow-, orange-, red-, green-, blue- or ultraviolet-emitting layer, more preferably a yellow- or green-emitting layer and most preferably a green-emitting layer.

A yellow-emitting layer is understood here to mean a layer having a photoluminescence maximum within the range from 540 to 570 nm. An orange-emitting layer is understood to mean a layer having a photoluminescence maximum within the range from 570 to 600 nm. A red-emitting layer is understood to mean a layer having a photoluminescence maximum within the range from 600 to 750 nm. A green-emitting layer is understood to mean a layer having a photoluminescence maximum within the range from 490 to 540 nm. A blue-emitting layer is understood to mean a layer having a photoluminescence maximum within the range from 440 to 490 nm. The photoluminescence maximum of the layer is determined here by measuring the photoluminescence spectrum of the layer having a layer thickness of 50 nm at room temperature, said layer having the composition of the invention, i.e. comprising emitter and matrix.

The photoluminescence spectrum of the layer is recorded, for example, with a commercial photoluminescence spectrometer.

The photoluminescence spectrum of the emitter chosen is generally measured in oxygen-free solution, 10⁻⁵ molar, generally at room temperature, a suitable solvent being any in which the chosen emitter dissolves in the concentration mentioned. Particularly suitable solvents are typically toluene or 2-methyl-THF, but also dichloromethane. Measurement is effected with a commercial photoluminescence spectrometer. The triplet energy T1 in eV is determined from the photoluminescence spectra of the emitters. Firstly, the peak maximum PImax. (in nm) of the photoluminescence spectrum is determined. The peak maximum PImax. (in nm) is then converted to eV by: E(T1 in eV)=1240/E(T1 in nm)=1240/PImax. (in nm).

Preferred phosphorescent emitters are accordingly infrared emitters, preferably of the formula (3) or from Table 4 or 5, the triplet energy T₁ of which is preferably ˜1.9 eV to ˜1.0 eV.

Preferred phosphorescent emitters are accordingly red emitters, preferably of the formula (3) or from Table 4 or 5, the triplet energy T₁ of which is preferably ˜2.1 eV to ˜1.9 eV.

Preferred phosphorescent emitters are accordingly yellow emitters, preferably of the formula (3) or from Table 4 or 5, the triplet energy T₁ of which is preferably ˜2.3 eV to ˜2.1 eV.

Preferred phosphorescent emitters are accordingly green emitters, preferably of the formula (3) or from Table 4 or 5, the triplet energy T₁ of which is preferably ˜2.5 eV to ˜2.3 eV.

Preferred phosphorescent emitters are accordingly blue emitters, preferably of the formula (3) or from Table 4 or 5, the triplet energy T₁ of which is preferably ˜3.1 eV to ˜2.5 eV.

Preferred phosphorescent emitters are accordingly ultraviolet emitters of the formula (3) or from Table 4 or 5, the triplet energy T₁ of which is preferably ˜4.0 eV to ˜3.1 eV.

Particularly preferred phosphorescent emitters are accordingly green or yellow emitters, preferably of the formula (3) or from Table 4 or 5 as described above.

Very particularly preferred phosphorescent emitters are accordingly green emitters, preferably of the formula (3) or from Table 4 or 5, the triplet energy T₁ of which is preferably ˜2.5 eV to ˜2.3 eV.

Most preferably, green emitters, preferably of the formula (3) or from Table 4 or 5, as described above, are selected for the composition of the invention or emitting layer of the invention.

Preferred fluorescent emitters are selected from the class of the arylamines. An arylamine or an aromatic amine in the context of this invention is understood to mean a compound containing three substituted or unsubstituted aromatic or heteroaromatic ring systems bonded directly to the nitrogen. Preferably, at least one of these aromatic or heteroaromatic ring systems is a fused ring system, more preferably having at least 14 aromatic ring atoms. Preferred examples of these are aromatic anthraceneamines, aromatic anthracenediamines, aromatic pyreneamines, aromatic pyrenediamines, aromatic chryseneamines or aromatic chrysenediamines. An aromatic anthraceneamine is understood to mean a compound in which a diarylamino group is bonded directly to an anthracene group, preferably in the 9 position. An aromatic anthracenediamine is understood to mean a compound in which two diarylamino groups are bonded directly to an anthracene group, preferably in the 9, 10 positions. Aromatic pyreneamines, pyrenediamines, chryseneamines and chrysenediamines are defined analogously, where the diarylamino groups are bonded to the pyrene preferably in the 1 position or 1, 6 positions.

Further preferred fluorescent emitters are indenofluoreneamines or -diamines, for example according to WO 2006/108497 or WO 2006/122630, benzoindenofluoreneamines or -diamines, for example according to WO 2008/006449, and dibenzoindenofluoreneamines or -diamines, for example according to WO 2007/140847, and the indenofluorene derivatives having fused aryl groups disclosed in WO 2010/012328.

In a further preferred embodiment of the invention, the composition of the invention is used as a component of mixed matrix systems. The mixed matrix systems preferably comprise three or four different matrix materials, more preferably three different matrix materials (in other words, one further matrix component in addition to the composition of the invention). Examples of suitable matrix materials which can be used in combination with the composition of the invention as matrix components in a mixed matrix system are selected from wide band gap materials, electron transport materials (ETM) and hole transport materials (HTM).

Preference is given to using mixed matrix systems in phosphorescent organic electroluminescent devices. One source of more detailed information about mixed matrix systems is the application WO 2010/108579. Particularly suitable matrix materials which can be used in combination with the composition of the invention as matrix components of a mixed matrix system in phosphorescent or fluorescent organic electroluminescent devices are selected from the preferred matrix materials specified below for phosphorescent emitters or the preferred matrix materials for fluorescent emitters, according to what type of emitter is used. Preferably, the mixed matrix system is optimized for an emitter of the formula (3) or from Table 4 or 5.

Various substance classes are useful as further host materials, preferably for fluorescent emitters, as well as the composition of the invention as described above, more preferably comprising a mixture of materials selected from M1 to M1597. Preferred further host materials are selected from the classes of the oligoarylenes (e.g. 2,2′,7,7′-tetraphenylspirobifluorene according to EP 676461 or dinaphthylanthracene), especially of the oligoarylenes containing fused aromatic groups, the oligoarylenevinylenes (e.g. DPVBi or spiro-DPVBi according to EP 676461), the polypodal metal complexes (for example according to WO 2004/081017), the hole-conducting compounds (for example according to WO 2004/058911), the electron-conducting compounds, especially ketones, phosphine oxides, sulfoxides, etc. (for example according to WO 2005/084081 and WO 2005/084082), the atropisomers (for example according to WO 2006/048268), the boronic acid derivatives (for example according to WO 2006/117052) or the benzanthracenes (for example according to WO 2008/145239). Particularly preferred host materials are selected from the classes of the oligoarylenes comprising naphthalene, anthracene, benzanthracene and/or pyrene or atropisomers of these compounds, the oligoarylenevinylenes, the ketones, the phosphine oxides and the sulfoxides. Very particularly preferred matrix materials are selected from the classes of the oligoarylenes comprising anthracene, benzanthracene, benzophenanthrene and/or pyrene or atropisomers of these compounds. An oligoarylene in the context of this invention shall be understood to mean a compound in which at least three aryl or arylene groups are bonded to one another.

Various substance classes are useful as useful further matrix materials, preferably for phosphorescent emitters, as well as the composition of the invention as described above, more preferably comprising a mixture of materials selected from M1 to M1597. Preferred further matrix materials are selected from the classes of the aromatic amines, especially triarylamines, for example according to US 2005/0069729, carbazole derivatives (e.g. CBP, N,N-biscarbazolylbiphenyl) or compounds according to WO 2005/039246, US 2005/0069729, JP 2004/288381, EP 1205527 or WO 2008/086851, bridged carbazole derivatives, for example according to WO 2011/088877 and WO 2011/128017, indenocarbazole derivatives, for example according to WO 2010/136109 and WO 2011/000455, azacarbazole derivatives, for example according to EP 1617710, EP 1617711, EP 1731584, JP 2005/347160, indolocarbazole derivatives, for example according to WO 2007/063754 or WO 2008/056746, ketones, for example according to WO 2004/093207 or WO 2010/006680, phosphine oxides, sulfoxides and sulfones, for example according to WO 2005/003253, oligophenylenes, bipolar matrix materials, for example according to WO 2007/137725, silanes, for example according to WO 2005/111172, azaboroles or boronic esters, for example according to WO 2006/117052, triazine derivatives, for example according to WO 2010/015306, WO 2007/063754 or WO 2008/056746, zinc complexes, for example according to EP 652273 or WO 2009/062578, aluminium complexes, e.g. BAlq, diazasilole derivatives and tetraazasilole derivatives, for example according to WO 2010/054729, diazaphosphole derivatives, for example according to WO 2010/054730, and aluminium complexes, e.g. BAlQ.

In an alternative embodiment of the present invention, the composition, aside from the constituents of electron-transporting host and hole-transporting host, does not contain any further constituents, i.e. any functional materials. This embodiment concerns material mixtures that are used as such for production of the organic layer, preferably the emitting layer. These systems are also referred to as premix systems that are used as the sole material source in the vapour deposition and have a constant mixing ratio in the vapour deposition. In this way, it is possible in a simple and rapid manner to achieve the vapour deposition of a layer with homogeneous distribution of the components without a need for precise actuation of a multitude of material sources.

The invention accordingly further provides a composition consisting of a compound of the formula (1), (1a) to (1h) or a compound selected from 1 to 36 and 67 to 81 and a compound of the formula (2), (2a) to (2l) or a compound selected from 37 to 66a.

The composition of the invention as described above or described as preferred is suitable for use in an organic electronic device. An organic electronic device is understood here to mean a device containing at least one layer containing at least one organic compound. The device may also comprise inorganic materials or else layers formed entirely from inorganic materials.

The invention accordingly further provides for the use of a composition as described above or described as preferred, especially of a mixture selected from M1 to M1597, in an organic electronic device.

The components or constituents of the compositions may be processed by vapour deposition or from solution. If the compositions are applied from solution, formulations of the composition of the invention comprising at least one further solvent are required. These formulations may, for example, be solutions, dispersions or emulsions. For this purpose, it may be preferable to use mixtures of two or more solvents.

The present invention therefore further provides a formulation comprising a composition of the invention and at least one solvent.

Suitable and preferred solvents are, for example, toluene, anisole, o-, m- or p-xylene, methyl benzoate, mesitylene, tetralin, veratrole, THF, methyl-THF, THP, chlorobenzene, dioxane, phenoxytoluene, especially 3-phenoxytoluene, (−)-fenchone, 1,2,3,5-tetramethylbenzene, 1,2,4,5-tetramethylbenzene, 1-methylnaphthalene, 2-methylbenzothiazole, 2-phenoxyethanol, 2-pyrrolidinone, 3-methylanisole, 4-methylanisole, 3,4-dimethylanisole, 3,5-dimethylanisole, acetophenone, α-terpineol, benzothiazole, butyl benzoate, cumene, cyclohexanol, cyclohexanone, cyclohexylbenzene, decalin, dodecylbenzene, ethyl benzoate, indane, methyl benzoate, NMP, p-cymene, phenetole, 1,4-diisopropylbenzene, dibenzyl ether, diethylene glycol butyl methyl ether, triethylene glycol butyl methyl ether, diethylene glycol dibutyl ether, triethylene glycol dimethyl ether, diethylene glycol monobutyl ether, tripropylene glycol dimethyl ether, tetraethylene glycol dimethyl ether, 2-isopropylnaphthalene, pentylbenzene, hexylbenzene, heptylbenzene, octylbenzene, 1,1-bis(3,4-dimethylphenyl)ethane, hexamethylindane or mixtures of these solvents.

The formulation may also comprise at least one further organic or inorganic compound which is likewise used in the electronic device, especially an emitting compound, especially a phosphorescent emitter and/or a further matrix material. Suitable emitting compounds and further matrix materials have already been detailed above.

The present invention also provides for the use of the composition of the invention in an organic electronic device, preferably in an electron-transporting layer and/or in an emitting layer.

The organic electronic device is preferably selected from organic integrated circuits (OICs), organic field-effect transistors (OFETs), organic thin-film transistors (OTFTs), organic electroluminescent devices, organic solar cells (OSCs), organic optical detectors and organic photoreceptors, particular preference being given to organic electroluminescent devices.

Very particularly preferred organic electroluminescent devices containing at least one compound of the formula (1) and at least one compound of the formula (2), as described above or described as preferred, are organic light-emitting transistors (OLETs), organic field-quench devices (OFQDs), organic light-emitting electrochemical cells (OLECs, LECs, LEECs), organic laser diodes (0-lasers) and organic light-emitting diodes (OLEDs); OLECs and OLEDs are especially preferred and OLEDs are the most preferred.

Preferably, the composition of the invention as described above or described as preferred is used in a layer having an electron-transporting function in an electronic device. The layer is preferably an electron injection layer (EIL), an electron transport layer (ETL), a hole blocker layer (HBL) and/or an emission layer (EML), more preferably an ETL, EIL and/or an EML. Most preferably, the composition of the invention is used in an EML, especially as matrix material or as premix system.

Therefore, the present invention further provides an organic electronic device which is especially selected from one of the aforementioned electronic devices and which comprises the composition of the invention, as described above or described as preferred, preferably in an emission layer (EML), in an electron transport layer (ETL), in an electron injection layer (EIL) and/or in a hole blocker layer (HBL), very preferably in an EML, EIL and/or ETL and most preferably in an EML.

When the layer is an emitting layer, it is especially preferably a phosphorescent layer which is characterized in that it comprises, in addition to the composition as described above or described as preferred, a phosphorescent emitter, especially together with an emitter of the formula (3) or from Table 4 or 5 or a preferred emitter as described above.

In a particularly preferred embodiment of the present invention, therefore, the electronic device is an organic electroluminescent device, most preferably an organic light-emitting diode (OLED), containing the composition of the invention as described above or described hereinafter together with a phosphorescent emitter in the emission layer (EML).

In a particularly preferred embodiment of the present invention, the organic electroluminescent device is therefore one comprising an anode, a cathode and at least one organic layer comprising at least one light-emitting layer, wherein the at least one light-emitting layer contains at least one compound of the formula (1) as host material 1 and at least one compound of the formula (2) as host material 2, where the compounds of the formulae (1) and (2) have structures as described above or described as preferred or described in combination as a specific composition or mixture.

In a particularly preferred embodiment of the present invention, the organic electroluminescent device is therefore one comprising an anode, a cathode and at least one organic layer comprising at least one light-emitting layer, wherein the at least one light-emitting layer contains at least one compound of the formula (1) as host material 1 and at least one compound of the formula (2) as host material 2, where the compounds of the formulae (1) and (2) have structures as described above or described as preferred or described in combination as a specific composition or mixture, and wherein the at least one emission layer contains a phosphorescent emitter.

The light-emitting layer in the device of the invention, as described above, contains preferably between 99.9% and 1% by volume, further preferably between 99% and 10% by volume, especially preferably between 98% and 60% by volume, very especially preferably between 97% and 80% by volume, of matrix material composed of at least one compound of the formula (1) and at least one compound of the formula (2) as described above, based on the overall composition of emitter and matrix material. Correspondingly, the light-emitting layer in the device of the invention preferably contains between 0.1% and 99% by volume, further preferably between 1% and 90% by volume, more preferably between 2% and 40% by volume, most preferably between 3% and 20% by volume, of the emitter based on the overall composition of the light-emitting layer composed of emitter and matrix material. If the compounds are processed from solution, preference is given to using the corresponding amounts in % by weight rather than the above-specified amounts in % by volume.

The light-emitting layer in the device of the invention, as described above, preferably contains the matrix material of the formula (1) and the matrix material of the formula (2) in a percentage by volume ratio between 3:1 and 1:3, preferably between 1:2.5 and 1:1, more preferably between 1:2 and 1:1. If the compounds are processed from solution, preference is given to using the corresponding ratio in % by weight rather than the above-specified ratio in % by volume.

Apart from the cathode, anode and the layer comprising the composition of the invention, an electronic device may comprise further layers. These are selected, for example, from in each case one or more hole injection layers, hole transport layers, hole blocker layers, light-emitting layers, electron transport layers, electron injection layers, electron blocker layers, exciton blocker layers, interlayers, charge generation layers (IDMC 2003, Taiwan, Session 21 OLED (5), T. Matsumoto, T. Nakada, J. Endo, K. Mori, N. Kawamura, A. Yokoi, J. Kido, Multiphoton Organic EL Device Having Charge Generation Layer) and/or organic or inorganic p/n junctions. However, it should be pointed out that not necessarily every one of these layers need be present.

The sequence of layers in an organic electroluminescent device is preferably as follows:

anode/hole injection layer/hole transport layer/light-emitting layer/electron transport layer/electron injection layer/cathode.

The sequence of the layers is a preferred sequence.

At the same time, it should be pointed out again that not all the layers mentioned need be present and/or that further layers may additionally be present.

An organic electroluminescent device of the invention may contain two or more light-emitting layers. According to the invention, at least one of the light-emitting layers contains the combination of compounds of the formula (1) and compounds of the formula (2), as described above. More preferably, these emission layers in this case have several emission maxima between 380 nm and 750 nm overall, such that the overall result is white emission; in other words, various emitting compounds which may fluoresce or phosphoresce and which emit blue or yellow or orange or red light are used in the light-emitting layers. Especially preferred are three-layer systems, i.e. systems having three light-emitting layers, where the three layers show blue, green and orange or red emission (for the basic construction see, for example, WO 2005/011013). It should be noted that, for the production of white light, rather than a plurality of colour-emitting emitter compounds, an emitter compound used individually which emits over a broad wavelength range may also be suitable.

Suitable charge transport materials as usable in the hole injection or hole transport layer or electron blocker layer or in the electron transport layer of the organic electroluminescent device of the invention are, for example, the compounds disclosed in Y. Shirota et al., Chem. Rev. 2007, 107(4), 953-1010, or other materials as used in these layers according to the prior art.

Materials used for the electron transport layer may be any materials as used according to the prior art as electron transport materials in the electron transport layer. Especially suitable are aluminium complexes, for example Alq₃, zirconium complexes, for example Zrq₄, benzimidazole derivatives, triazine derivatives, pyrimidine derivatives, pyridine derivatives, pyrazine derivatives, quinoxaline derivatives, quinoline derivatives, oxadiazole derivatives, aromatic ketones, lactams, boranes, diazaphosphole derivatives and phosphine oxide derivatives. Further suitable materials are derivatives of the abovementioned compounds as disclosed in JP 2000/053957, WO 2003/060956, WO 2004/028217, WO 2004/080975 and WO 2010/072300.

Preferred hole transport materials are especially materials which can be used in a hole transport, hole injection or electron blocker layer, such as indenofluoreneamine derivatives (for example according to WO 06/122630 or WO 06/100896), the amine derivatives disclosed in EP 1661888, hexaazatriphenylene derivatives (for example according to WO 01/049806), amine derivatives having fused aromatic systems (for example according to U.S. Pat. No. 5,061,569), the amine derivatives disclosed in WO 95/09147, monobenzoindenofluoreneamines (for example according to WO 08/006449), dibenzoindenofluoreneamines (for example according to WO 07/140847), spirobifluoreneamines (for example according to WO 2012/034627 or the as yet unpublished EP 12000929.5), fluoreneamines (for example according to WO 2014/015937, WO 2014/015938 and WO 2014/015935), spirodibenzopyranamines (for example according to WO 2013/083216) and dihydroacridine derivatives (for example WO 2012/150001).

Preferred cathodes of electronic devices are metals having a low work function, metal alloys or multilayer structures composed of various metals, for example alkaline earth metals, alkali metals, main group metals or lanthanoids (e.g. Ca, Ba, Mg, Al, In, Mg, Yb, Sm, etc.). Additionally suitable are alloys composed of an alkali metal or alkaline earth metal and silver, for example an alloy composed of magnesium and silver. In the case of multilayer structures, in addition to the metals mentioned, it is also possible to use further metals having a relatively high work function, for example Ag or Al, in which case combinations of the metals such as Ca/Ag, Mg/Ag or Ba/Ag, for example, are generally used. It may also be preferable to introduce a thin interlayer of a material having a high dielectric constant between a metallic cathode and the organic semiconductor. Examples of useful materials for this purpose are alkali metal or alkaline earth metal fluorides, but also the corresponding oxides or carbonates (e.g. LiF, Li₂O, BaF₂, MgO, NaF, CsF, Cs₂CO₃, etc.). It is also possible to use lithium quinolinate (LiQ) for this purpose. The layer thickness of this layer is preferably between 0.5 and 5 nm.

Preferred anodes are materials having a high work function. Preferably, the anode has a work function of greater than 4.5 eV versus vacuum. Firstly, metals having a high redox potential are suitable for this purpose, for example Ag, Pt or Au. Secondly, metal/metal oxide electrodes (e.g. Al/Ni/NiOₓ, Al/PtOₓ) may also be preferred. For some applications, at least one of the electrodes has to be transparent or partly transparent in order to enable either the irradiation of the organic material (organic solar cell) or the emission of light (OLED, O-LASER). Preferred anode materials here are conductive mixed metal oxides. Particular preference is given to indium tin oxide (ITO) or indium zinc oxide (IZO). Preference is further given to conductive doped organic materials, especially conductive doped polymers. In addition, the anode may also consist of two or more layers, for example of an inner layer of ITO and an outer layer of a metal oxide, preferably tungsten oxide, molybdenum oxide or vanadium oxide.

The organic electronic device, in the course of production, is appropriately (according to the application) structured, contact-connected and finally sealed, since the lifetime of the devices of the invention is shortened in the presence of water and/or air.

In a further preferred embodiment, the organic electronic device comprising the composition of the invention is characterized in that one or more organic layers comprising the composition of the invention are coated by a sublimation method. In this case, the materials are applied by vapour deposition in vacuum sublimation systems at an initial pressure of less than 10⁻⁵ mbar, preferably less than 10⁻⁶ mbar. In this case, however, it is also possible that the initial pressure is even lower, for example less than 10⁻⁷ mbar.

Preference is likewise given to an organic electroluminescent device, characterized in that one or more layers are coated by the OVPD (organic vapour phase deposition) method or with the aid of a carrier gas sublimation. In this case, the materials are applied at a pressure between 10⁻⁵ mbar and 1 bar. A special case of this method is the OVJP (organic vapour jet printing) method, in which the materials are applied directly by a nozzle and thus structured (for example, M. S. Arnold et al., Appl. Phys. Lett. 2008, 92, 053301).

Preference is additionally given to an organic electroluminescent device, characterized in that one or more organic layers comprising the composition of the invention are produced from solution, for example by spin-coating, or by any printing method, for example screen printing, flexographic printing, nozzle printing or offset printing, but more preferably LITI (light-induced thermal imaging, thermal transfer printing) or inkjet printing. For this purpose, soluble compounds of the components of the composition of the invention are needed. High solubility can be achieved by suitable substitution of the corresponding compounds. Processing from solution has the advantage that the layer comprising the composition of the invention can be applied in a very simple and inexpensive manner. This technique is especially suitable for the mass production of organic electronic devices.

In addition, hybrid methods are possible, in which, for example, one or more layers are applied from solution and one or more further layers are applied by vapour deposition.

These methods are known in general terms to those skilled in the art and can be applied to organic electroluminescent devices.

The invention therefore further provides a process for producing an organic electronic device comprising a composition of the invention as described above or described as preferred, characterized in that at least one organic layer comprising a composition of the invention is applied by gas phase deposition, especially by a sublimation method and/or by an OVPD (organic vapour phase deposition) method and/or with the aid of carrier gas sublimation, or from solution, especially by spin-coating or by a printing method.

In the production of an organic electronic device by means of gas phase deposition, there are two methods in principle by which an organic layer which is to comprise the composition of the invention and which may comprise multiple different constituents can be applied, or applied by vapour deposition, to any substrate. Firstly, the materials used can each be initially charged in a material source and ultimately evaporated from the different material sources (“co-evaporation”). Secondly, the various materials can be premixed (premix systems) and the mixture can be initially charged in a single material source from which it is ultimately evaporated (“premix evaporation”). In this way, it is possible in a simple and rapid manner to achieve the vapour deposition of a layer with homogeneous distribution of the components without a need for precise actuation of a multitude of material sources.

The invention accordingly further provides a process characterized in that the at least one compound of the formula (1) as described above or described as preferred and the at least one compound of the formula (2) as described above or described as preferred are deposited from the gas phase successively or simultaneously from at least two material sources, optionally with other materials as described above or described as preferred, and form the organic layer.

In a preferred embodiment of the present invention, the at least one organic layer is applied by means of gas phase deposition, wherein the constituents of the composition are premixed and evaporated from a single material source. For this embodiment, the following mixtures are especially suitable: M4 (1+40), M5 (1+41), M24 (2+37), M26 (2+39), M33 (2+46), M44 (2+57), M48 (3+38), M50 (3+40), M70 (4+37), M72 (4+39), M81 (4+48), M100 (5+44), M101 (5+45), M117 (6+38), M130 (6+51), M146 (7+44), M165 (8+40), M166 (8+41), M238 (11+44), M285 (13+42), M301 (13+58), M330 (15+38), M332 (15+40), M333 (15+41), M358 (16+43), M359 (16+44), M379 (17+41), M380 (17+42), M543 (24+44), M562 (25+40), M592 (26+44), M655 (29+38), M657 (29+40), M726 (32+40), M727 (32+41), M772 (34+40) and M773 (34+41).

The invention accordingly further provides a process characterized in that the composition of the invention as described above or described as preferred is utilized as material source for the gas phase deposition of the host system and, optionally together with further materials, forms the organic layer.

The invention further provides a process for producing an organic electronic device comprising a composition of the invention as described above or described as preferred, characterized in that the formulation of the invention as described above is used to apply the organic layer.

The compositions of the invention and the devices of the invention feature the following surprising advantages over the prior art:

The use of the compositions of the invention in organic electronic devices, especially in an organic electroluminescent device, and especially in an OLED or OLEC, leads to distinct increases in power efficiency with comparable or improved lifetime of the devices.

As apparent in Example 1 adduced below, however, it is possible through the use of prior art compounds, for example the compound SoA1, to achieve a good voltage but a relatively low power efficiency at low emitter concentrations in the EML of 8% in example C1.

An improvement in power efficiency and/or lifetime at comparable operating voltage can be achieved by means of the inventive combination of the compounds of the formula (1) as described above with compounds of the formula (2) as described above.

This improvement in power efficiency at comparable operating voltage can preferably be achieved by virtue of the inventive combination of the compounds of the formula (1) as described above with compounds of the formula (2) as described above at emitter concentrations of 2 to 25 percent by volume, preferably at emitter concentrations of 5 to 15 percent by volume, more preferably at emitter concentrations of 7, 8 and 12 percent by volume, in the emission layer.

This improvement in power efficiency and lifetime at comparable operating voltage for specific combinations can preferably be achieved by virtue of the inventive combination of the compounds of the formula (1) as described above with compounds of the formula (2) as described above at emitter concentrations of 2 to 25 percent by volume, preferably at emitter concentrations of 5 to 15 percent by volume, more preferably at emitter concentrations of 7, 8 and 12 percent by volume, in the emission layer.

The difference in the compound of the formula (1) represented by compound 4 from prior art compounds, such as SoA1, lies in the attachment to the dibenzofuran in the 8 position.

It was unforeseeable to the person skilled in the art that this change in position of the substituent brings about an improvement in the power efficiency of electronic devices, especially of OLEDs, of about 10% to 30%, with comparable or improved lifetime.

The compositions of the invention are of very good suitability for use in an emission layer and exhibit improved performance data, especially in respect of lifetime, operating voltage and/or power efficiency, over compounds from the prior art as described above.

The compositions of the invention can easily be processed and are therefore of very good suitability for mass production in commercial use.

The compositions of the invention can be premixed and vapour-deposited from a single material source, and so it is possible in a simple and rapid manner to produce an organic layer with homogeneous distribution of the components used.

These abovementioned advantages are not accompanied by a deterioration in the further electronic properties of an electronic device.

It should be pointed out that variations of the embodiments described in the present invention are covered by the scope of this invention. Any feature disclosed in the present invention may, unless this is explicitly ruled out, be exchanged for alternative features which serve the same purpose or an equivalent or similar purpose. Any feature disclosed in the present invention, unless stated otherwise, should therefore be considered as an example from a generic series or as an equivalent or similar feature.

All features of the present invention may be combined with one another in any manner, unless particular features and/or steps are mutually exclusive. This is especially true of preferred features of the present invention. Equally, features of non-essential combinations may be used separately (and not in combination).

The technical teaching disclosed with the present invention may be abstracted and combined with other examples.

The invention is illustrated in more detail by the examples which follow, without any intention of restricting it thereby.

General Methods:

Determination of Orbital Energies and Electronic States

The HOMO and LUMO energies and the triplet level and the singlet levels of the materials are determined via quantum-chemical calculations. For this purpose, in the present case, the “Gaussian09, Revision D.01” software package (Gaussian Inc.) is used. For calculation of organic substances without metals (referred to as the “org.” method), a geometry optimization is first conducted by the semi-empirical method AM1 (Gaussian input line “#AM1 opt”) with charge 0 and multiplicity 1. Subsequently, on the basis of the optimized geometry, a (single-point) energy calculation is effected for the electronic ground state and the triplet level. This is done using the TDDFT (time dependent density functional theory) method B3PW91 with the 6-31G(d) basis set (Gaussian input line “#B3PW91/6-31G(d) td=(50-50, nstates=4)”) (charge 0, multiplicity 1). For organometallic compounds (referred to as the “M-org.” method), the geometry is optimized by the Hartree-Fock method and the LanL2 MB basis set (Gaussian input line “#HF/LanL2 MB opt”) (charge 0, multiplicity 1). The energy calculation is effected, as described above, analogously to that for the organic substances, except that the “LanL2DZ” basis set is used for the metal atom and the “6-31G(d)” basis set for the ligands (Gaussian input line “#B3PW91/gen pseudo=lanl2 td=(50-50, nstates=4)”). From the energy calculation, the HOMO is obtained as the last orbital occupied by two electrons (alpha occ. eigenvalues) and LUMO as the first unoccupied orbital (alpha virt. eigenvalues) in Hartree units, where HEh and LEh represent the HOMO energy in Hartree units and the LUMO energy in Hartree units respectively. This is used to determine the HOMO and LUMO value in electron volts, calibrated by cyclic voltammetry measurements, as follows:

HOMO (eV)=(HEh*27.212)*0.8308−1.118;

LUMO (eV)=(LEh*27.212)*1.0658−0.5049.

The triplet level T1 of a material is defined as the relative excitation energy (in eV) of the triplet state having the lowest energy which is found by the quantum-chemical energy calculation.

The singlet level S1 of a material is defined as the relative excitation energy (in eV) of the singlet state having the second-lowest energy which is found by the quantum-chemical energy calculation.

The energetically lowest singlet state is referred to as S0.

The method described herein is independent of the software package used and always gives the same results. Examples of frequently utilized programs for this purpose are “Gaussian09” (Gaussian Inc.) and Q-Chem 4.1 (Q-Chem, Inc.). In the present case, the energies are calculated using the software package “Gaussian09, Revision D.01”.

### EXAMPLE 1: PRODUCTION OF THE OLEDS

Examples I1 to I55 which follow (see Table 6) present the use of the material combinations of the invention in OLEDs by comparison with examples C1 to C11.

Pretreatment for Examples C1-I55: Glass plaques coated with structured ITO (indium tin oxide) of thickness 50 nm are treated prior to coating, first with an oxygen plasma, followed by an argon plasma. These plasma-treated glass plaques form the substrates to which the OLEDs are applied.

The OLEDs basically have the following layer structure: substrate/hole injection layer (HIL)/hole transport layer (HTL)/electron blocker layer (EBL)/emission layer (EML)/optional hole blocker layer (HBL)/electron transport layer (ETL)/optional electron injection layer (EIL) and finally a cathode. The cathode is formed by an aluminium layer of thickness 100 nm. The exact structure of the OLEDs can be found in table 6. The materials required for production of the OLEDs are shown in Table 8. The device data of the OLEDs are listed in Table 7. Examples C1, C2, C3, C10 and C11 are comparative examples with an electron-transporting host according to prior art CN107973786. Examples C4, C5, C6 and C7 are comparative examples with the host according to prior art WO 2015/014435. Examples C8 and C9 are comparative examples with the host according to prior art KR20160046077. Examples I1 to I55 show data for OLEDs of the invention.

All materials are applied by thermal vapour deposition in a vacuum chamber. In this case, the emission layer always consists of at least two matrix materials and an emitting dopant (emitter) which is added to the matrix material(s) in a particular proportion by volume by co-evaporation. Details given in such a form as SoA1:40:TEG3 (32%:60%:8%) mean here that the material SoA1 is present in the layer in a proportion by volume of 32%, compound 40 as a co-host in a proportion of 60%, and TEG3 in a proportion of 8%. Analogously, the electron transport layer may also consist of a mixture of two materials.

The OLEDs are characterized in a standard manner. For this purpose, the electroluminescence spectra and the current efficiency (SE, measured in cd/A) as a function of luminance, calculated from current-voltage-luminance characteristics (IUL characteristics) assuming Lambertian radiation characteristics, and the lifetime are measured. The electroluminescence spectra are determined at a luminance of 1000 cd/m², and the CIE 1931 x and y colour coordinates are calculated therefrom. The parameter U10 in Table 7 refers to the voltage which is required for a current density of 10 mA/cm². PE10 refers to the power efficiency attained at 10 mA/cm². The lifetime LT is defined as the time after which the luminance drops to a certain proportion L1 in the course of operation with the same starting brightness L0. A figure of L1=80% in Table 7 means that the lifetime in hours (h) reported in the LT column corresponds to the time after which the luminance falls to 80% of its starting value.

In other words, for example, given an L0 of 20 000 cd/m², this would be the time taken for the sample to have only a luminance of

L1=0.8×L0=16 000 cd/m².

Use of Mixtures of the Invention in OLEDs

The material combinations of the invention can be used in the emission layer in phosphorescent green OLEDs. The inventive combinations of the compounds 2, 3, 4, 5, 6, 9, 11, 13, 14, 17, 18, 22, 28, 30, 31, 32, 33, 34, 67, 69, 70, 72, 75, 76, 77 and 79 with compound 37, 38, 40, 41, 42, 43, 44, 47, 48, 49, 52, 56, 58, 60, 61, 62, 63, 64, 65, 66 or 66a are used in examples 11 to 155 as matrix material in the emission layer, as described in Table 6. The results from Table 7 are directly comparable when the same emitter has been used, for example C1 with I1 or I1 with I4 or C2 with I2.

For instance, on comparison of the inventive examples with the corresponding comparative examples, such as I1 versus C1, I2 versus C2, I3 versus C3, I27 versus C4, I28, versus C5, I29 versus C6, I30 versus C7, I31 versus C8, I32 versus C9, I33 versus I10 and I34 versus C11, it is clearly apparent that the inventive examples each show a distinct advantage in lifetime.

TABLE 6
Structure of the OLEDs

| | HIL | HTL | EBL | EML | HBL | ETL | EIL |
|---|---|---|---|---|---|---|---|
| Ex | thickness | thickness | thickness | thickness | thickness | thickness | thickness |
| C1 | HTCN | SpMA1 | SpMA2 | SoA1:40:TEG3 | ST2 | ST2:LiQ | LiQ |
| | 5 nm | 230 nm | 20 nm | (32%:60%:8%) 30 nm | 10 nm | (50%:50%) | 1 nm |
| | | | | | | 30 nm | |
| C 2 | HTCN | SpMA1 | SpMA2 | SoA1:48:TEG1 | ST2 | ST2:LiQ | LiQ |
| | 5 nm | 230 nm | 20 nm | (59%:29%:12%) | 10 nm | (50%:50%) | 1 nm |
| | | | | 30 nm | | 30 nm | |
| C 3 | HTCN | SpMA1 | SpMA2 | SoA1:44:TEG2 | ST2 | ST2:LiQ | LiQ |
| | 5 nm | 230 nm | 20 nm | (31%:62%:7%) 40 nm | 10 nm | (50%:50%) | 1 nm |
| | | | | | | 30 nm | |
| I1 | HTCN | SpMA1 | SpMA2 | 4:40:TEG3 | ST2 | ST2:LiQ | LiQ |
| | 5 nm | 230 nm | 20 nm | (32%:60%:8%) 30 nm | 10 nm | (50%:50%) | 1 nm |
| | | | | | | 30 nm | |
| I2 | HTCN | SpMA1 | SpMA2 | 4:48:TEG1 | ST2 | ST2:LiQ | LiQ |
| | 5 nm | 230 nm | 20 nm | (59%:29%:12%) | 10 nm | (50%:50%) | 1 nm |
| | | | | 30 nm | | 30 nm | |
| I3 | HTCN | SpMA1 | SpMA2 | 4:44:TEG2 | ST2 | ST2:LiQ | LiQ |
| | 5 nm | 230 nm | 20 nm | (31%:62%:7%) 40 nm | 5 nm | (50%:50%) | 1 nm |
| | | | | | | 30 nm | |
| I4 | HTCN | SpMA1 | SpMA2 | 4:40:TEG3 | ST2 | ST2:LiQ | LiQ |
| | 5 nm | 215 nm | 20 nm | (31%:62%:7%) 40 nm | 5 nm | (50%:50%) | 1 nm |
| | | | | | | 30 nm | |
| I5 | HTCN | SpMA1 | SpMA2 | 4:40:TEG2 | ST2 | ST2:LiQ | LiQ |
| | 5 nm | 215 nm | 20 nm | (31%:62%:7%) 40 nm | 5 nm | (50%:50%) | 1 nm |
| | | | | | | 30 nm | |
| I6 | HTCN | SpMA1 | SpMA2 | 3:40:TEG3 | ST2 | ST2:LiQ | LiQ |
| | 5 nm | 215 nm | 20 nm | (31%:62%:7%) 40 nm | 5 nm | (50%:50%) | 1 nm |
| | | | | | | 30 nm | |
| I7 | HTCN | SpMA1 | SpMA2 | 3:40:TEG2 | ST2 | ST2:LiQ | LiQ |
| | 5 nm | 215 nm | 20 nm | (33%:60%:7%) 40 nm | 5 nm | (50%:50%) | 1 nm |
| | | | | | | 30 nm | |
| I8 | HTCN | SpMA1 | SpMA2 | 3:38:TEG3 | ST2 | ST2:LiQ | LiQ |
| | 5 nm | 215nm | 20 nm | (31%:62%:7%) 40 nm | 5 nm | (50%:50%) | 1 nm |
| | | | | | | 30 nm | |
| I9 | HTCN | SpMA1 | SpMA2 | 3:38:TEG2 | ST2 | ST2:LiQ | LiQ |
| | 5 nm | 215 nm | 20 nm | (33%:60%:7%) 40 nm | 5 nm | (50%:50%) | 1 nm |
| | | | | | | 30 nm | |
| I10 | HTCN | SpMA1 | SpMA2 | 3:48:TEG1 | ST2 | ST2:LiQ | LiQ |
| | 5 nm | 230 nm | 20 nm | (59%:29%:7%) 30 nm | 10 nm | (50%:50%) | 1 nm |
| | | | | | | 30 nm | |
| I11 | HTCN | SpMA1 | SpMA2 | 5:48:TEG1 | ST2 | ST2:LiQ | LiQ |
| | 5 nm | 230 nm | 20 nm | (59%:29%:7%) 30 nm | 10 nm | (50%:50%) | 1 nm |
| | | | | | | 30 nm | |
| I12 | HTCN | SpMA1 | SpMA2 | 4:37:TEG3 | ST2 | ST2:LiQ | LiQ |
| | 5 nm | 230 nm | 20 nm | (32%:60%:8%) 30 nm | 10 nm | (50%:50%) | 1 nm |
| | | | | | | 30 nm | |
| I13 | HTCN | SpMA1 | SpMA2 | 6:38:TEG2 | ST2 | ST2:LiQ | LiQ |
| | 5 nm | 215 nm | 20 nm | (31%:62%:7%) 40 nm | 5 nm | (50%:50%) | 1 nm |
| | | | | | | 30 nm | |
| I14 | HTCN | SpMA1 | SpMA2 | 6:58:TEG2 | ST2 | ST2:LiQ | LiQ |
| | 5 nm | 215 nm | 20 nm | (31%:62%:7%) 40 nm | 5 nm | (50%:50%) | 1 nm |
| | | | | | | 30 nm | |
| I15 | HTCN | SpMA1 | SpMA2 | 9:37:TEG2 | ST2 | ST2:LiQ | LiQ |
| | 5 nm | 215 nm | 20 nm | (33%:60%:7%) 40 nm | 5 nm | (50%:50%) | 1 nm |
| | | | | | | 30 nm | |
| I16 | HTCN | SpMA1 | SpMA2 | 9:47:TEG2 | ST2 | ST2:LiQ | LiQ |
| | 5 nm | 215 nm | 20 nm | (71%:22%:7%) 40 nm | 5 nm | (50%:50%) | 1 nm |
| | | | | | | 30 nm | |
| I17 | HTCN | SpMA1 | SpMA2 | 11:44:TEG2 | ST2 | ST2:LiQ | LiQ |
| | 5 nm | 215 nm | 20 nm | (33%:60%:7%) 40 nm | 5 nm | (50%:50%) | 1 nm |
| | | | | | | 30 nm | |
| I18 | HTCN | SpMA1 | SpMA2 | 11:52:TEG2 | ST2 | ST2:LiQ | LiQ |
| | 5 nm | 215 nm | 20 nm | (33%:60%:7%) 40 nm | 5 nm | (50%:50%) | 1 nm |
| | | | | | | 30 nm | |
| I19 | HTCN | SpMA1 | SpMA2 | 13:48:TEG1 | ST2 | ST2:LiQ | LiQ |
| | 5 nm | 230 nm | 20 nm | (59%:29%:12%) | 10 nm | (50%:50%) | 1 nm |
| | | | | 30 nm | | 30 nm | |
| I20 | HTCN | SpMA1 | SpMA2 | 14:40:TEG2 | ST2 | ST2:LiQ | LiQ |
| | 5 nm | 215 nm | 20 nm | (33%:60%:7%) 40 nm | 5 nm | (50%:50%) | 1 nm |
| | | | | | | 30 nm | |
| I21 | HTCN | SpMA1 | SpMA2 | 17:38:TEG2 | ST2 | ST2:LiQ | LiQ |
| | 5 nm | 215 nm | 20 nm | (33%:60%:7%) 40 nm | 5 nm | (50%:50%) | 1 nm |
| | | | | | | 30 nm | |
| I22 | HTCN | SpMA1 | SpMA2 | 17:52:TEG2 | ST2 | ST2:LiQ | LiQ |
| | 5 nm | 215 nm | 20 nm | (33%:60%:7%) 40 nm | 5 nm | (50%:50%) | 1 nm |
| | | | | | | 30 nm | |
| I23 | HTCN | SpMA1 | SpMA2 | 18:47:TEG2 | ST2 | ST2:LiQ | LiQ |
| | 5 nm | 215 nm | 20 nm | (71%:22%:7%) 40 nm | 5 nm | (50%:50%) | 1 nm |
| | | | | | | 30 nm | |
| I24 | HTCN | SpMA1 | SpMA2 | 22:56:TEG2 | ST2 | ST2:LiQ | LiQ |
| | 5 nm | 215 nm | 20 nm | (31%:62%:7%) 40 nm | 5 nm | (50%:50%) | 1 nm |
| | | | | | | 30 nm | |
| I25 | HTCN | SpMA1 | SpMA2 | 31:44:TEG2 | ST2 | ST2:LiQ | LiQ |
| | 5 nm | 215 nm | 20 nm | (33%:60%:7%) 40 nm | 5 nm | (50%:50%) | 1 nm |
| | | | | | | 30 nm | |
| I26 | HTCN | SpMA1 | SpMA2 | 33:56:TEG2 | ST2 | ST2:LiQ | LiQ |
| | 5 nm | 215 nm | 20 nm | (31%:62%:7%) 40 nm | 5 nm | (50%:50%) | 1 nm |
| | | | | | | 30 nm | |
| C4 | HTCN | SpMA1 | SpMA2 | SoA2:62:TEG3 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I27 | HTCN | SpMA1 | SpMA2 | 4:62:TEG3 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| C5 | HTCN | SpMA1 | SpMA2 | SoA2:62:TEG2 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I28 | HTCN | SpMA1 | SpMA2 | 4:62:TEG2 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| C6 | HTCN | SpMA1 | SpMA2 | SoA3:62:TEG3 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I29 | HTCN | SpMA1 | SpMA2 | 3:62:TEG3 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| C7 | HTCN | SpMA1 | SpMA2 | SoA3:62:TEG2 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I30 | HTCN | SpMA1 | SpMA2 | 3:62:TEG2 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| C8 | HTCN | SpMA1 | SpMA2 | SoA4:60:TEG3 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I31 | HTCN | SpMA1 | SpMA2 | 3:60:TEG3 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| C9 | HTCN | SpMA1 | SpMA2 | SoA4:60:TEG2 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I32 | HTCN | SpMA1 | SpMA2 | 3:60:TEG2 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| C10 | HTCN | SpMA1 | SpMA2 | SoA5:38:TEG3 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I33 | HTCN | SpMA1 | SpMA2 | 67:38:TEG3 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| C11 | HTCN | SpMA1 | SpMA2 | SoA5:38:TEG2 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I34 | HTCN | SpMA1 | SpMA2 | 67:38:TEG2 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I35 | HTCN | SpMA1 | SpMA2 | 70:37:TEG2 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I36 | HTCN | SpMA1 | SpMA2 | 69:37:TEG2 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I37 | HTCN | SpMA1 | SpMA2 | 70:63:TEG2 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I38 | HTCN | SpMA1 | SpMA2 | 34:66:TEG3 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I39 | HTCN | SpMA1 | SpMA2 | 30:65:TEG2 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I40 | HTCN | SpMA1 | SpMA2 | 72:41:TEG2 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I41 | HTCN | SpMA1 | SpMA2 | 72:41:TEG3 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I42 | HTCN | SpMA1 | SpMA2 | 72:63:TEG2 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I43 | HTCN | SpMA1 | SpMA2 | 75:42:TEG1 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I44 | HTCN | SpMA1 | SpMA2 | 75:60:TEG2 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I45 | HTCN | SpMA1 | SpMA2 | 76:37:TEG3 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I46 | HTCN | SpMA1 | SpMA2 | 77:43:TEG2 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I47 | HTCN | SpMA1 | SpMA2 | 77:44:TEG2 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I48 | HTCN | SpMA1 | SpMA2 | 77:61:TEG1 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I49 | HTCN | SpMA1 | SpMA2 | 79:40:TEG3 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I50 | HTCN | SpMA1 | SpMA2 | 79:49:TEG3 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I51 | HTCN | SpMA1 | SpMA2 | 79:47:TEG3 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I52 | HTCN | SpMA1 | SpMA2 | 28:66:TEG2 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I53 | HTCN | SpMA1 | SpMA2 | 2:64:TEG1 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I54 | HTCN | SpMA1 | SpMA2 | 32:62:TEG2 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |
| I55 | HTCN | SpMA1 | SpMA2 | 3:66a:TEG3 | ST2 | ST2:LiQ | LiQ |
| | 5 nm | 215 nm | 20 nm | (32%:60%:8%) 40 nm | 5 nm | (50%:50%) | 1 nm |
| | | | | | | 30 nm | |

TABLE 7
Data of the OLEDs

| | | PE10 | CIE x/y at | L0 | L1 | LT |
|---|---|---|---|---|---|---|
| Ex. | U10 | (cd/A) | 1000 cd/cm² | (Cd/m²) | (%) | (h) |
| C1 | 4.4 | 58 | 0.36/0.60 | 20000 | 80 | 790 |
| C2 | 4.5 | 52 | 0.35/0.61 | 20000 | 80 | 245 |
| C3 | 4.8 | 74 | 0.34/0.63 | 20000 | 80 | 1790 |
| I1 | 4.4 | 69 | 0.36/0.60 | 20000 | 80 | 890 |
| I2 | 4.3 | 68 | 0.36/0.61 | 20000 | 80 | 270 |
| I3 | 5.0 | 92 | 0.34/0.63 | 20000 | 80 | 1950 |
| I4 | 4.9 | 75 | 0.33/0.62 | 20000 | 80 | 1170 |
| I5 | 4.6 | 88 | 0.34/0.63 | 20000 | 80 | 2100 |
| I6 | 5.0 | 73 | 0.33/0.62 | 20000 | 80 | 1220 |
| I7 | 4.6 | 90 | 0.34/0.63 | 20000 | 80 | 2700 |
| I8 | 4.9 | 72 | 0.33/0.62 | 20000 | 80 | 1250 |
| I9 | 4.5 | 89 | 0.34/0.63 | 20000 | 80 | 2750 |
| I10 | 4.4 | 71 | 0.35/0.61 | 20000 | 80 | 360 |
| I11 | 4.1 | 66 | 0.35/0.61 | 20000 | 80 | 490 |
| I12 | 4.4 | 68 | 0.36/0.60 | 20000 | 80 | 910 |
| I13 | 4.6 | 87 | 0.34/0.63 | 20000 | 80 | 2150 |
| I14 | 4.6 | 86 | 0.34/0.63 | 20000 | 80 | 2000 |
| I15 | 4.5 | 88 | 0.34/0.63 | 20000 | 80 | 2600 |
| I16 | 4.4 | 78 | 0.34/0.63 | 20000 | 80 | 1510 |
| I17 | 4.9 | 95 | 0.34/0.63 | 20000 | 80 | 2510 |
| I18 | 4.2 | 87 | 0.34/0.63 | 20000 | 80 | 1890 |
| I19 | 4.3 | 67 | 0.36/0.61 | 20000 | 80 | 255 |
| I20 | 4.6 | 89 | 0.34/0.63 | 20000 | 80 | 2600 |
| I21 | 4.6 | 90 | 0.34/0.63 | 20000 | 80 | 2500 |
| I22 | 4.2 | 88 | 0.34/0.63 | 20000 | 80 | 1910 |
| I23 | 4.4 | 77 | 0.34/0.63 | 20000 | 80 | 1530 |
| I24 | 5.1 | 78 | 0.34/0.63 | 20000 | 80 | 1310 |
| I25 | 4.9 | 95 | 0.34/0.63 | 20000 | 80 | 2520 |
| I26 | 5.1 | 76 | 0.34/0.63 | 20000 | 80 | 1290 |
| C4 | 5.2 | 71 | 0.33/0.62 | 20000 | 80 | 1090 |
| I27 | 5.2 | 73 | 0.33/0.62 | 20000 | 80 | 1560 |
| C5 | 5.0 | 85 | 0.34/0.63 | 20000 | 80 | 1640 |
| I28 | 4.9 | 86 | 0.34/0.63 | 20000 | 80 | 2250 |
| C6 | 5.3 | 70 | 0.33/0.62 | 20000 | 80 | 980 |
| I29 | 5.4 | 74 | 0.33/0.62 | 20000 | 80 | 1770 |
| C7 | 5.1 | 83 | 0.34/0.63 | 20000 | 80 | 1960 |
| I30 | 4.9 | 88 | 0.34/0.63 | 20000 | 80 | 2930 |
| C8 | 5.2 | 75 | 0.33/0.62 | 20000 | 80 | 780 |
| I31 | 5.4 | 74 | 0.33/0.62 | 20000 | 80 | 1120 |
| C9 | 4.8 | 89 | 0.34/0.63 | 20000 | 80 | 860 |
| I32 | 4.8 | 90 | 0.34/0.63 | 20000 | 80 | 1570 |
| C10 | 4.9 | 67 | 0.33/0.62 | 20000 | 80 | 800 |
| I33 | 5.0 | 75 | 0.33/0.62 | 20000 | 80 | 1240 |
| C11 | 4.9 | 79 | 0.34/0.63 | 20000 | 80 | 1640 |
| I34 | 4.8 | 84 | 0.34/0.63 | 20000 | 80 | 1990 |
| I35 | 4.5 | 92 | 0.34/0.63 | 20000 | 80 | 2550 |
| I36 | 4.6 | 91 | 0.34/0.63 | 20000 | 80 | 2130 |
| I37 | 4.8 | 89 | 0.34/0.63 | 20000 | 80 | 2880 |
| I38 | 5.2 | 73 | 0.33/0.62 | 20000 | 80 | 1950 |
| I39 | 4.9 | 85 | 0.34/0.63 | 20000 | 80 | 1640 |
| I40 | 4.6 | 88 | 0.34/0.63 | 20000 | 80 | 2530 |
| I41 | 4.7 | 73 | 0.33/0.62 | 20000 | 80 | 1400 |
| I42 | 4.8 | 85 | 0.34/0.63 | 20000 | 80 | 2970 |
| I43 | 4.5 | 70 | 0.36/0.61 | 20000 | 80 | 330 |
| I44 | 4.9 | 93 | 0.34/0.63 | 20000 | 80 | 1780 |
| I45 | 4.6 | 74 | 0.33/0.62 | 20000 | 80 | 1220 |
| I46 | 4.8 | 90 | 0.34/0.63 | 20000 | 80 | 1710 |
| I47 | 4.9 | 88 | 0.34/0.63 | 20000 | 80 | 1950 |
| I48 | 5.3 | 71 | 0.36/0.61 | 20000 | 80 | 470 |
| I49 | 5.0 | 72 | 0.33/0.62 | 20000 | 80 | 1290 |
| I50 | 4.6 | 76 | 0.33/0.62 | 20000 | 80 | 960 |
| I51 | 4.7 | 65 | 0.33/0.62 | 20000 | 80 | 1140 |
| I52 | 5.1 | 87 | 0.34/0.63 | 20000 | 80 | 2640 |
| I53 | 4.7 | 73 | 0.36/0.61 | 20000 | 80 | 460 |
| I54 | 4.9 | 94 | 0.34/0.63 | 20000 | 80 | 2020 |
| I55 | 5.2 | 71 | 0.33/0.62 | 20000 | 80 | 1850 |

TABLE 8
Structural formulae of the materials in the OLEDs

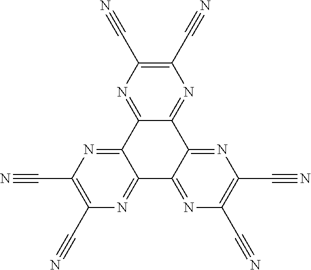 [SMILES: N#Cc1nc2c3nc(C#N)c(C#N)nc3c3nc(C#N)c(C#N)nc3c2nc1C#N]

HTCN

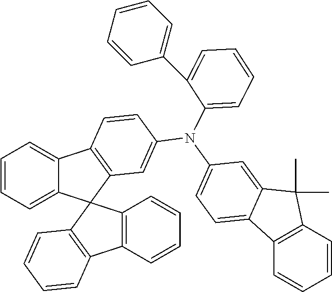 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

SpA1

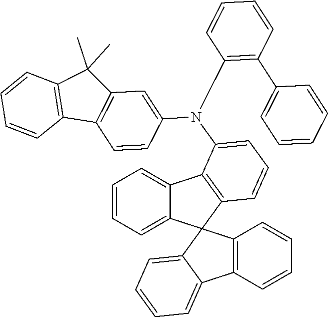 [SMILES: CC1(C)c2ccccc2-c2ccc(N(c3ccccc3-c3ccccc3)c3cccc4c3-c3ccccc3C43c4ccccc4-c4ccccc43)cc21]

SpMA2

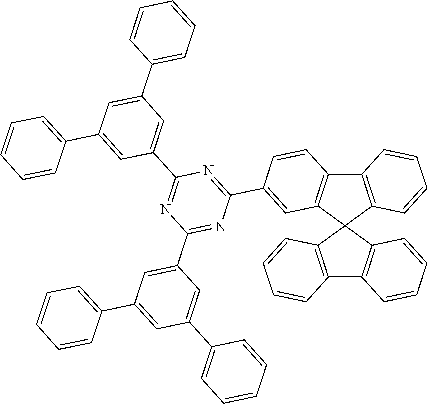 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1]

ST2

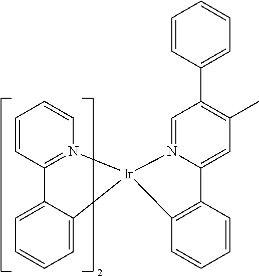

TEG1

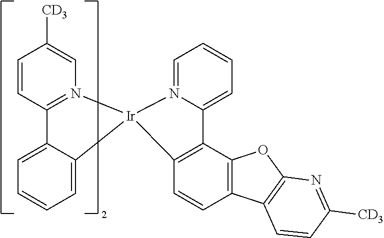

TEG2

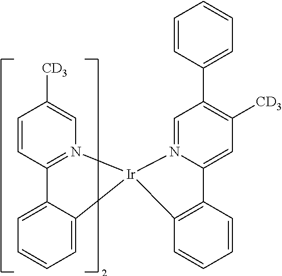

TEG3

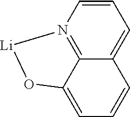

LiQ

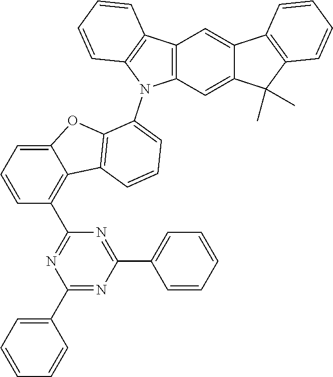 [SMILES: CC1(C)c2ccccc2-c2cc3c4ccccc4n(-c4cccc5c4oc4cccc(-c6nc(-c7ccccc7)nc(-c7ccccc7)n6)c45)c3cc21]

SoA1 [CAS-2226338-95-8]

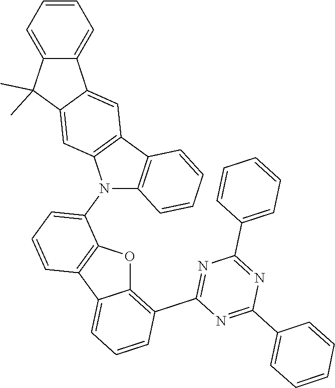 [SMILES: CC1(C)c2ccccc2-c2cc3c4ccccc4n(-c4cccc5c4oc4c(-c6nc(-c7ccccc7)nc(-c7ccccc7)n6)cccc45)c3cc21]

SoA2 [CAS-1651195-45-7]

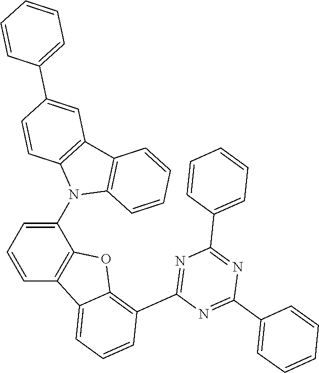 [SMILES: c1ccc(-c2ccc3c(c2)c2ccccc2n3-c2cccc3c2oc2c(-c4nc(-c5ccccc5)nc(-c5ccccc5)n4)cccc23)cc1]

SoA3 [CAS-1651195-58-2]

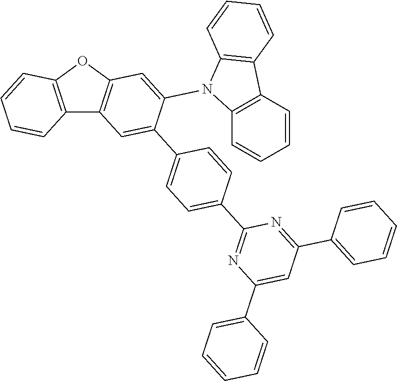 [SMILES: c1ccc(-c2cc(-c3ccccc3)nc(-c3ccc(-c4cc5c(cc4-n4c6ccccc6c6ccccc64)oc4ccccc45)cc3)n2)cc1]

SoA4 [CAS-1829595-17-6]

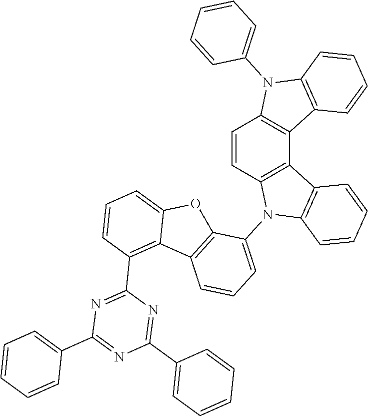 [SMILES: c1ccc(-c2nc(-c3ccccc3)nc(-c3cccc4oc5c(-n6c7ccccc7c7c8c9ccccc9n(-c9ccccc9)c8ccc76)cccc5c34)n2)cc1]

SoA5 [CAS-2226339-15-5]

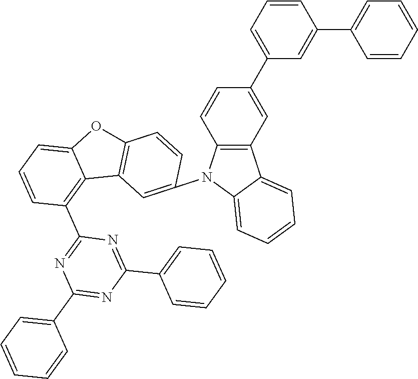 [SMILES: c1ccc(-c2cccc(-c3ccc4c(c3)c3ccccc3n4-c3ccc4oc5cccc(-c6nc(-c7ccccc7)nc(-c7ccccc7)n6)c5c4c3)c2)cc1]

3

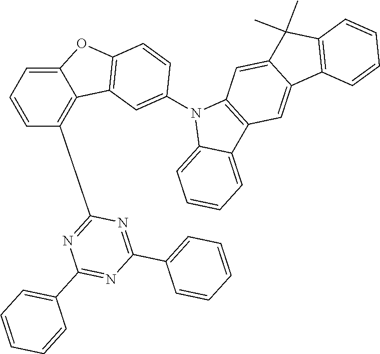 [SMILES: CC1(C)c2ccccc2-c2cc3c4ccccc4n(-c4ccc5oc6cccc(-c7nc(-c8ccccc8)nc(-c8ccccc8)n7)c6c5c4)c3cc21]

4

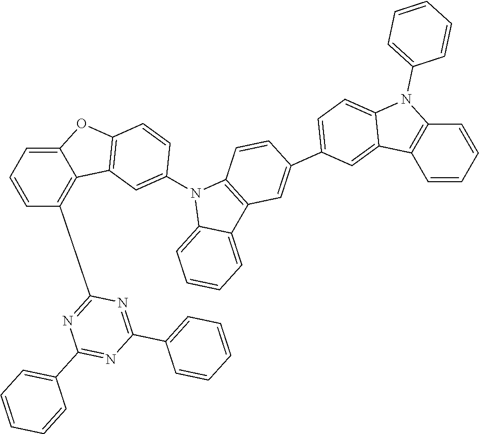 [SMILES: c1ccc(-c2nc(-c3ccccc3)nc(-c3cccc4oc5ccc(-n6c7ccccc7c7cc(-c8ccc9c(c8)c8ccccc8n9-c8ccccc8)ccc76)cc5c34)n2)cc1]

5

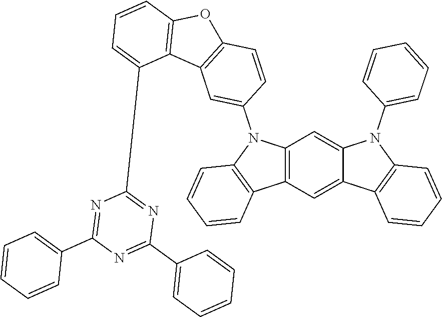 [SMILES: c1ccc(-c2nc(-c3ccccc3)nc(-c3cccc4oc5ccc(-n6c7ccccc7c7cc8c9ccccc9n(-c9ccccc9)c8cc76)cc5c34)n2)cc1]

6

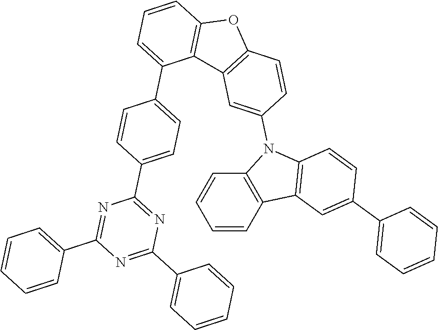 [SMILES: c1ccc(-c2ccc3c(c2)c2ccccc2n3-c2ccc3oc4cccc(-c5ccc(-c6nc(-c7ccccc7)nc(-c7ccccc7)n6)cc5)c4c3c2)cc1]

9

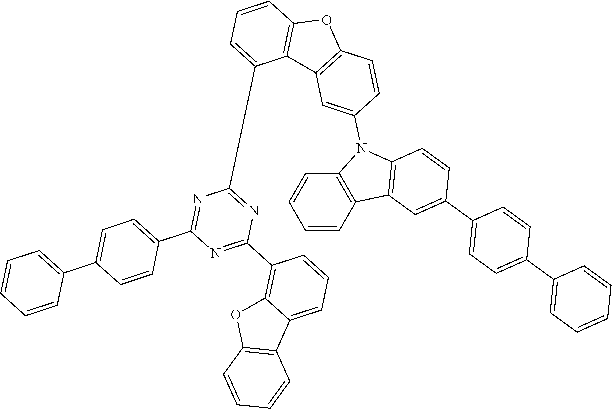 [SMILES: c1ccc(-c2ccc(-c3ccc4c(c3)c3ccccc3n4-c3ccc4oc5cccc(-c6nc(-c7ccc(-c8ccccc8)cc7)nc(-c7cccc8c7oc7ccccc78)n6)c5c4c3)cc2)cc1]

11

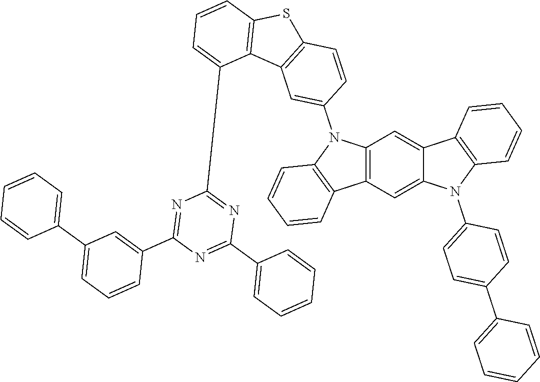 [SMILES: c1ccc(-c2ccc(-n3c4ccccc4c4cc5c(cc43)c3ccccc3n5-c3ccc4sc5cccc(-c6nc(-c7ccccc7)nc(-c7cccc(-c8ccccc8)c7)n6)c5c4c3)cc2)cc1]

13

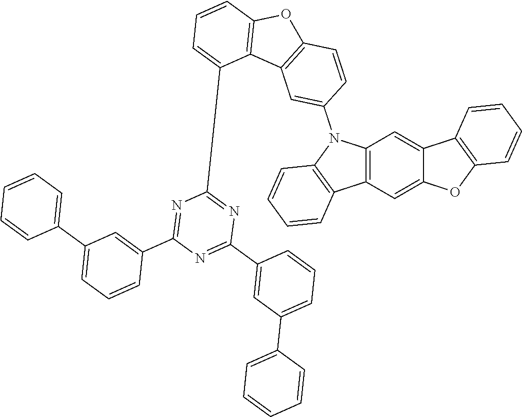 [SMILES: c1ccc(-c2cccc(-c3nc(-c4cccc(-c5ccccc5)c4)nc(-c4cccc5oc6ccc(-n7c8ccccc8c8cc9oc%10ccccc%10c9cc87)cc6c45)n3)c2)cc1]

14

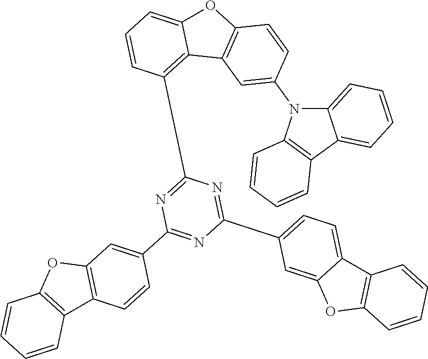 [SMILES: c1ccc2c(c1)oc1cc(-c3nc(-c4ccc5c(c4)oc4ccccc45)nc(-c4cccc5oc6ccc(-n7c8ccccc8c8ccccc87)cc6c45)n3)ccc12]

17

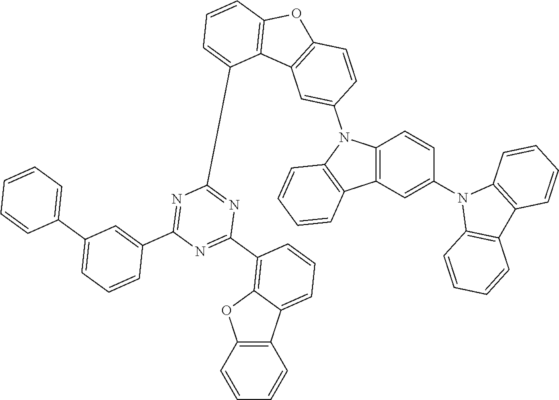 [SMILES: c1ccc(-c2cccc(-c3nc(-c4cccc5c4oc4ccccc45)nc(-c4cccc5oc6ccc(-n7c8ccccc8c8cc(-n9c%10ccccc%10c%10ccccc%109)ccc87)cc6c45)n3)c2)cc1]

18

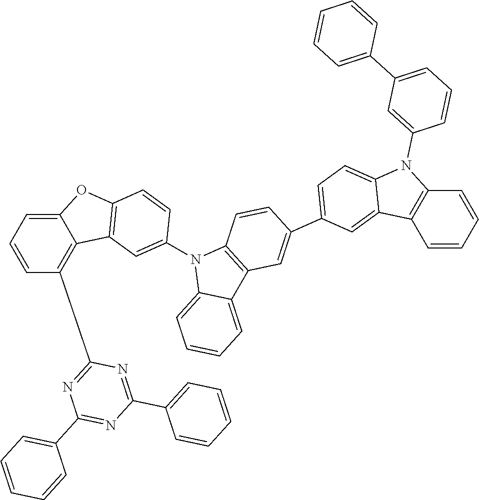 [SMILES: c1ccc(-c2cccc(-n3c4ccccc4c4cc(-c5ccc6c(c5)c5ccccc5n6-c5ccc6oc7cccc(-c8nc(-c9ccccc9)nc(-c9ccccc9)n8)c7c6c5)ccc43)c2)cc1]

22

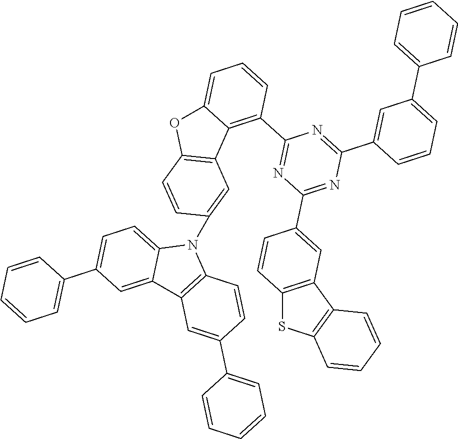 [SMILES: c1ccc(-c2cccc(-c3nc(-c4ccc5sc6ccccc6c5c4)nc(-c4cccc5oc6ccc(-n7c8ccc(-c9ccccc9)cc8c8cc(-c9ccccc9)ccc87)cc6c45)n3)c2)cc1]

28

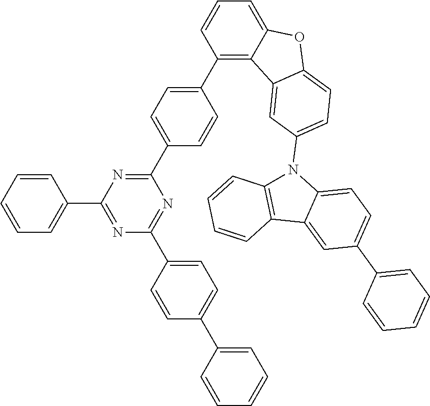 [SMILES: c1ccc(-c2ccc(-c3nc(-c4ccccc4)nc(-c4ccc(-c5cccc6oc7ccc(-n8c9ccccc9c9cc(-c%10ccccc%10)ccc98)cc7c56)cc4)n3)cc2)cc1]

30

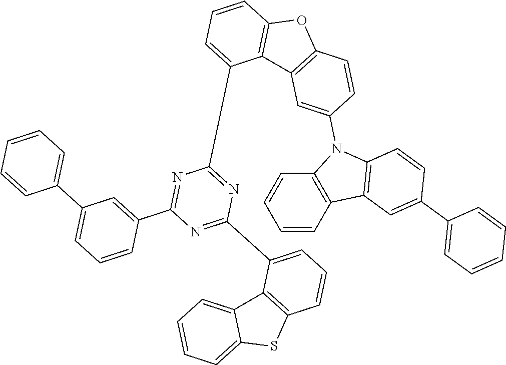 [SMILES: c1ccc(-c2cccc(-c3nc(-c4cccc5oc6ccc(-n7c8ccccc8c8cc(-c9ccccc9)ccc87)cc6c45)nc(-c4cccc5sc6ccccc6c45)n3)c2)cc1]

31

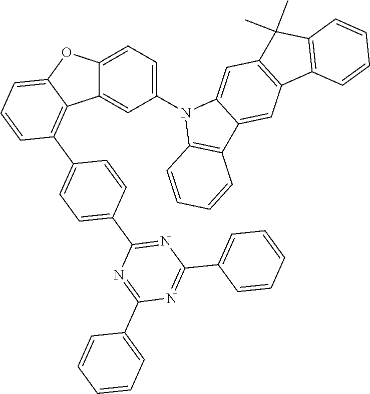 [SMILES: CC1(C)c2ccccc2-c2cc3c4ccccc4n(-c4ccc5oc6cccc(-c7ccc(-c8nc(-c9ccccc9)nc(-c9ccccc9)n8)cc7)c6c5c4)c3cc21]

32

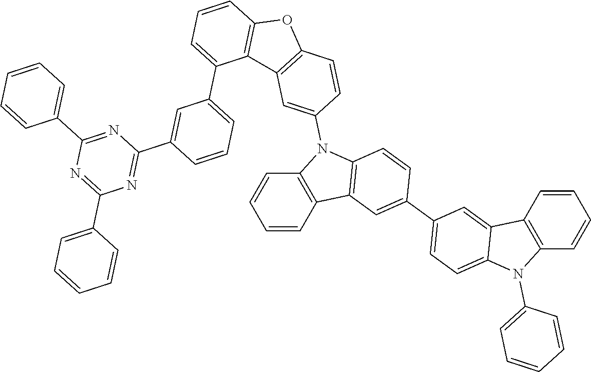 [SMILES: c1ccc(-c2nc(-c3ccccc3)nc(-c3cccc(-c4cccc5oc6ccc(-n7c8ccccc8c8cc(-c9ccc%10c(c9)c9ccccc9n%10-c9ccccc9)ccc87)cc6c45)c3)n2)cc1]

33

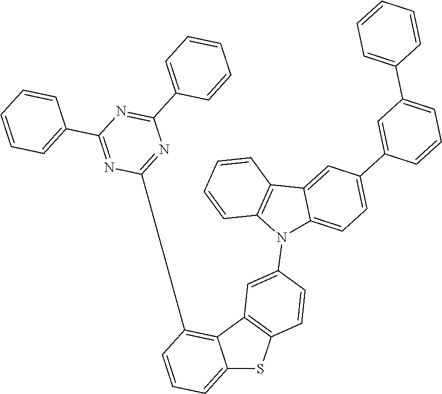 [SMILES: c1ccc(-c2cccc(-c3ccc4c(c3)c3ccccc3n4-c3ccc4sc5cccc(-c6nc(-c7ccccc7)nc(-c7ccccc7)n6)c5c4c3)c2)cc1]

34

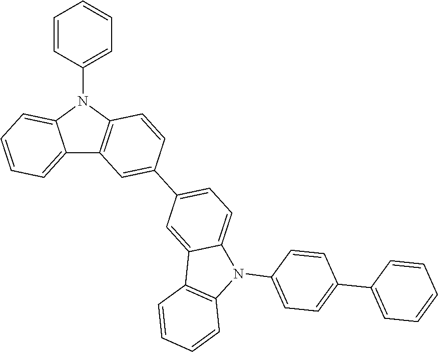 [SMILES: c1ccc(-c2ccc(-n3c4ccccc4c4cc(-c5ccc6c(c5)c5ccccc5n6-c5ccccc5)ccc43)cc2)cc1]

37

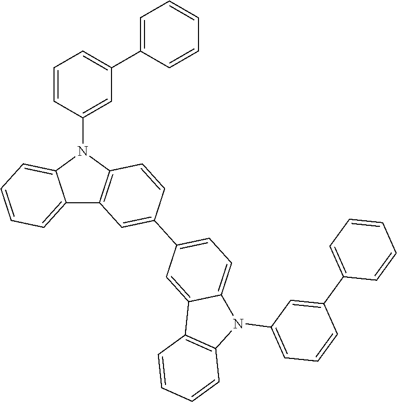 [SMILES: c1ccc(-c2cccc(-n3c4ccccc4c4cc(-c5ccc6c(c5)c5ccccc5n6-c5cccc(-c6ccccc6)c5)ccc43)c2)cc1]

38

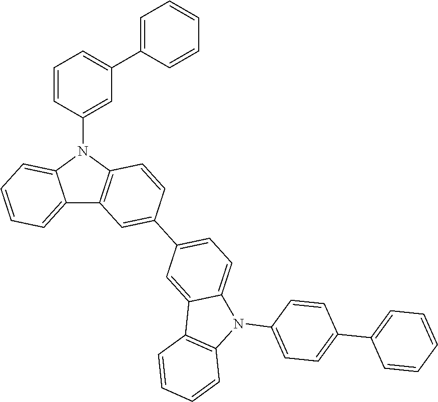 [SMILES: c1ccc(-c2ccc(-n3c4ccccc4c4cc(-c5ccc6c(c5)c5ccccc5n6-c5cccc(-c6ccccc6)c5)ccc43)cc2)cc1]

40

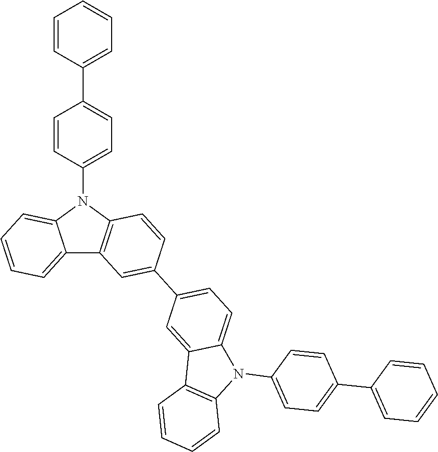 [SMILES: c1ccc(-c2ccc(-n3c4ccccc4c4cc(-c5ccc6c(c5)c5ccccc5n6-c5ccc(-c6ccccc6)cc5)ccc43)cc2)cc1]

41

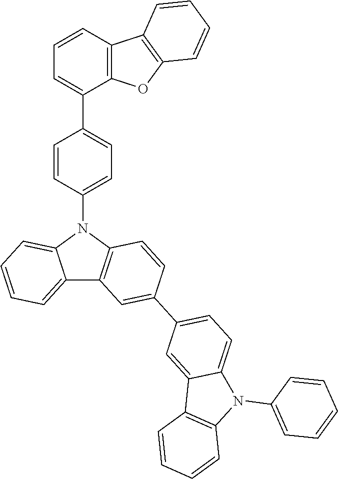 [SMILES: c1ccc(-n2c3ccccc3c3cc(-c4ccc5c(c4)c4ccccc4n5-c4ccc(-c5cccc6c5oc5ccccc56)cc4)ccc32)cc1]

42

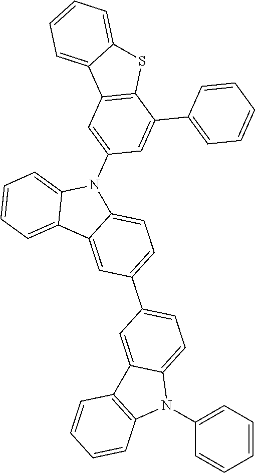 [SMILES: c1ccc(-c2cc(-n3c4ccccc4c4cc(-c5ccc6c(c5)c5ccccc5n6-c5ccccc5)ccc43)cc3c2sc2ccccc23)cc1]

43

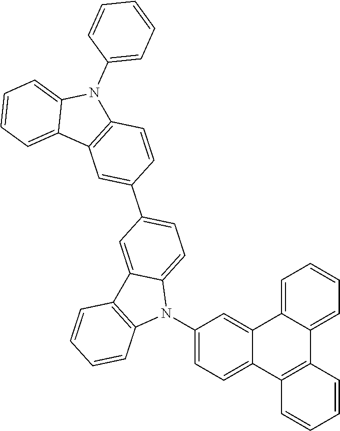 [SMILES: c1ccc(-n2c3ccccc3c3cc(-c4ccc5c(c4)c4ccccc4n5-c4ccc5c6ccccc6c6ccccc6c5c4)ccc32)cc1]

44

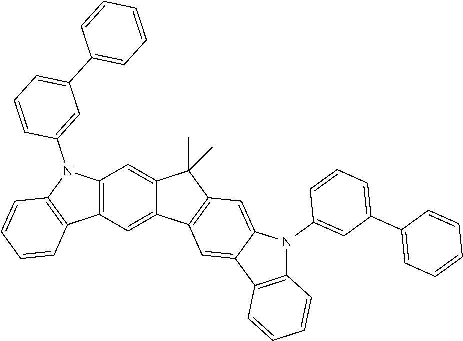 [SMILES: CC1(C)c2cc3c(cc2-c2cc4c5ccccc5n(-c5cccc(-c6ccccc6)c5)c4cc21)c1ccccc1n3-c1cccc(-c2ccccc2)c1]

47

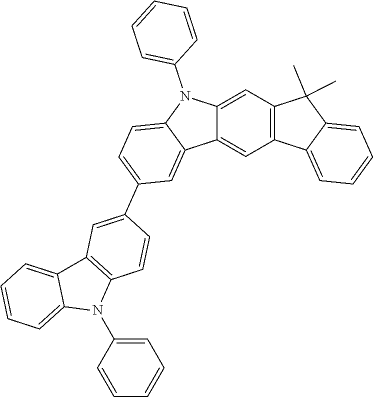 [SMILES: CC1(C)c2ccccc2-c2cc3c4cc(-c5ccc6c(c5)c5ccccc5n6-c5ccccc5)ccc4n(-c4ccccc4)c3cc21]

48

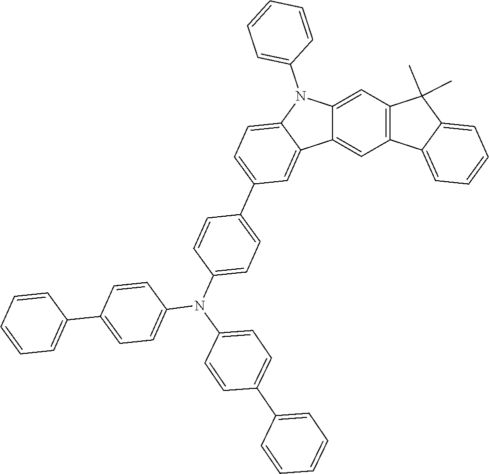 [SMILES: CC1(C)c2ccccc2-c2cc3c4cc(-c5ccc(N(c6ccc(-c7ccccc7)cc6)c6ccc(-c7ccccc7)cc6)cc5)ccc4n(-c4ccccc4)c3cc21]

49

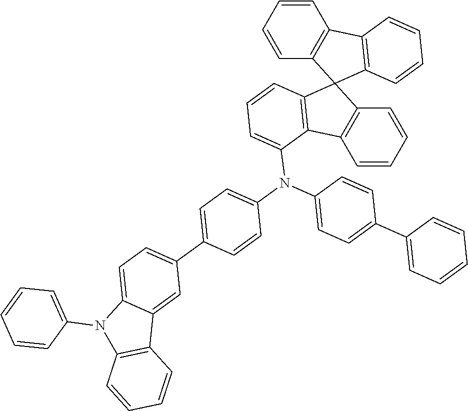 [SMILES: c1ccc(-c2ccc(N(c3ccc(-c4ccc5c(c4)c4ccccc4n5-c4ccccc4)cc3)c3cccc4c3-c3ccccc3C43c4ccccc4-c4ccccc43)cc2)cc1]

52

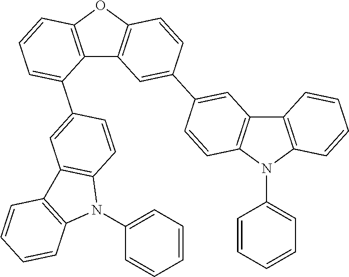 [SMILES: c1ccc(-n2c3ccccc3c3cc(-c4ccc5oc6cccc(-c7ccc8c(c7)c7ccccc7n8-c7ccccc7)c6c5c4)ccc32)cc1]

56

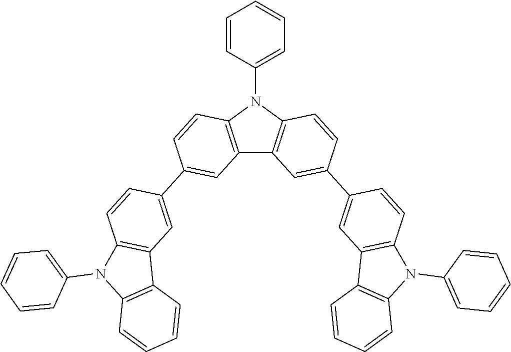 [SMILES: c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1]

58

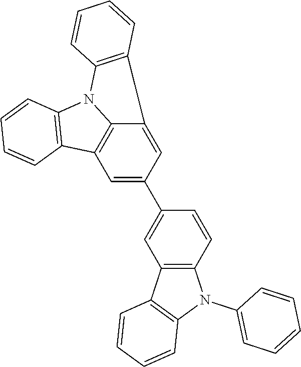 [SMILES: c1ccc(-n2c3ccccc3c3cc(-c4cc5c6ccccc6n6c7ccccc7c(c4)c56)ccc32)cc1]

60

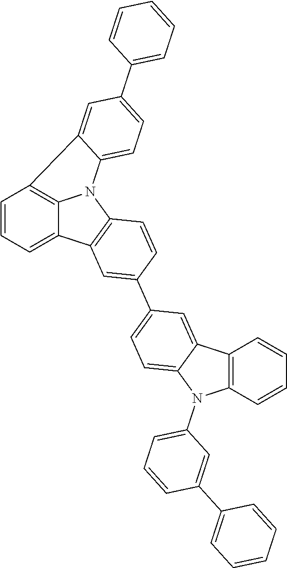 [SMILES: c1ccc(-c2cccc(-n3c4ccccc4c4cc(-c5ccc6c(c5)c5cccc7c8cc(-c9ccccc9)ccc8n6c75)ccc43)c2)cc1]

66a

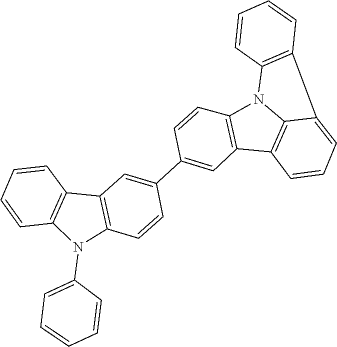 [SMILES: c1ccc(-n2c3ccccc3c3cc(-c4ccc5c(c4)c4cccc6c7ccccc7n5c64)ccc32)cc1]

61

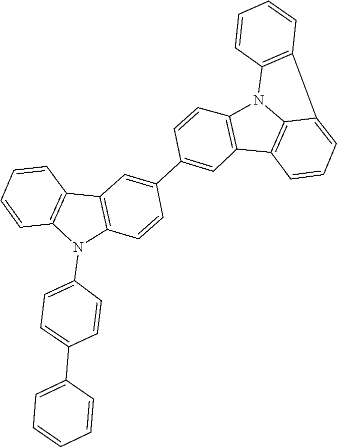 [SMILES: c1ccc(-c2ccc(-n3c4ccccc4c4cc(-c5ccc6c(c5)c5cccc7c8ccccc8n6c75)ccc43)cc2)cc1]

63

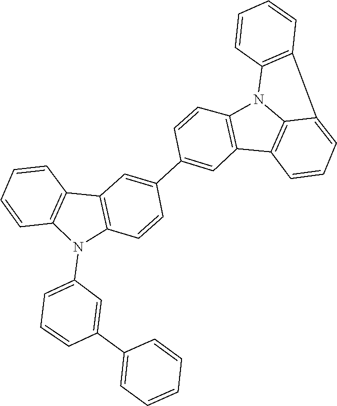 [SMILES: c1ccc(-c2cccc(-n3c4ccccc4c4cc(-c5ccc6c(c5)c5cccc7c8ccccc8n6c75)ccc43)c2)cc1]

62

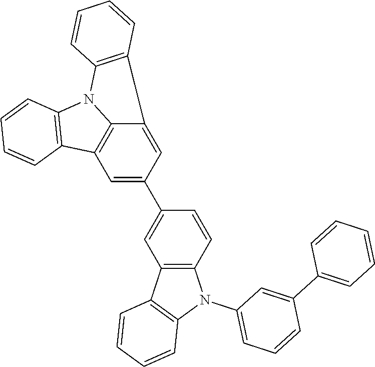 [SMILES: c1ccc(-c2cccc(-n3c4ccccc4c4cc(-c5cc6c7ccccc7n7c8ccccc8c(c5)c67)ccc43)c2)cc1]

65

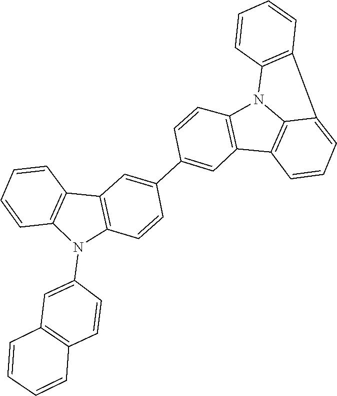 [SMILES: c1ccc2cc(-n3c4ccccc4c4cc(-c5ccc6c(c5)c5cccc7c8ccccc8n6c75)ccc43)ccc2c1]

64

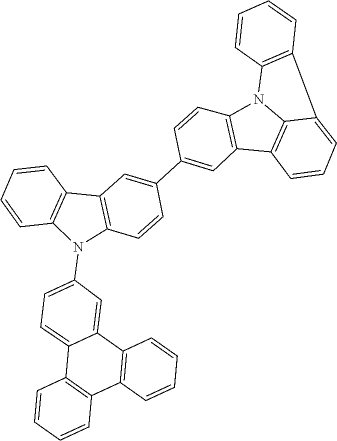 [SMILES: c1ccc2c(c1)c1ccccc1c1cc(-n3c4ccccc4c4cc(-c5ccc6c(c5)c5cccc7c8ccccc8n6c75)ccc43)ccc21]

66

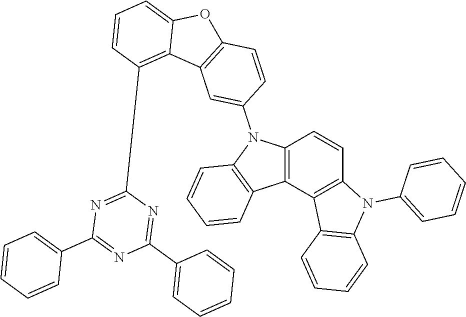 [SMILES: c1ccc(-c2nc(-c3ccccc3)nc(-c3cccc4oc5ccc(-n6c7ccccc7c7c8c9ccccc9n(-c9ccccc9)c8ccc76)cc5c34)n2)cc1]

67

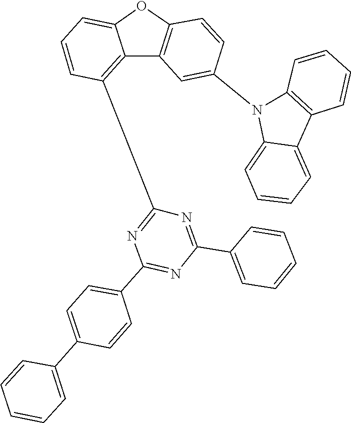 [SMILES: c1ccc(-c2ccc(-c3nc(-c4ccccc4)nc(-c4cccc5oc6ccc(-n7c8ccccc8c8ccccc87)cc6c45)n3)cc2)cc1]

69

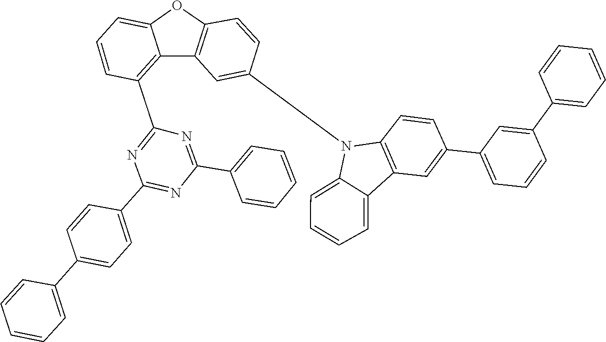 [SMILES: c1ccc(-c2ccc(-c3nc(-c4ccccc4)nc(-c4cccc5oc6ccc(-n7c8ccccc8c8cc(-c9cccc(-c%10ccccc%10)c9)ccc87)cc6c45)n3)cc2)cc1]

70

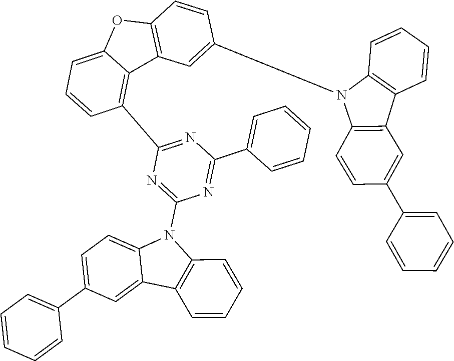 [SMILES: c1ccc(-c2ccc3c(c2)c2ccccc2n3-c2ccc3oc4cccc(-c5nc(-c6ccccc6)nc(-n6c7ccccc7c7cc(-c8ccccc8)ccc76)n5)c4c3c2)cc1]

72

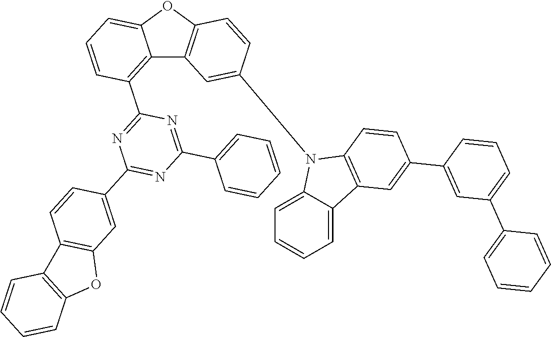 [SMILES: c1ccc(-c2cccc(-c3ccc4c(c3)c3ccccc3n4-c3ccc4oc5cccc(-c6nc(-c7ccccc7)nc(-c7ccc8c(c7)oc7ccccc78)n6)c5c4c3)c2)cc1]

75

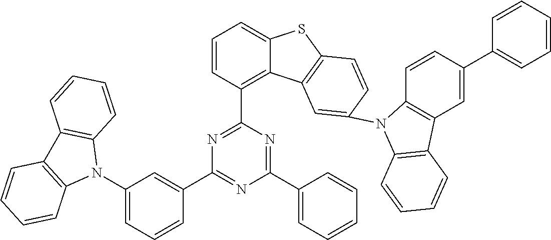 [SMILES: c1ccc(-c2ccc3c(c2)c2ccccc2n3-c2ccc3sc4cccc(-c5nc(-c6ccccc6)nc(-c6cccc(-n7c8ccccc8c8ccccc87)c6)n5)c4c3c2)cc1]

76

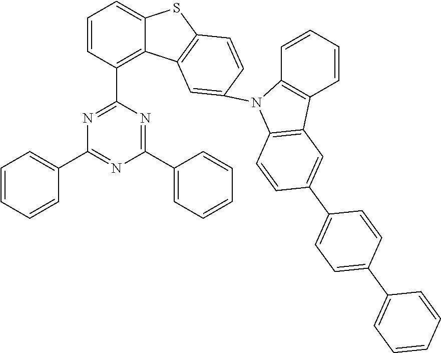 [SMILES: c1ccc(-c2ccc(-c3ccc4c(c3)c3ccccc3n4-c3ccc4sc5cccc(-c6nc(-c7ccccc7)nc(-c7ccccc7)n6)c5c4c3)cc2)cc1]

77

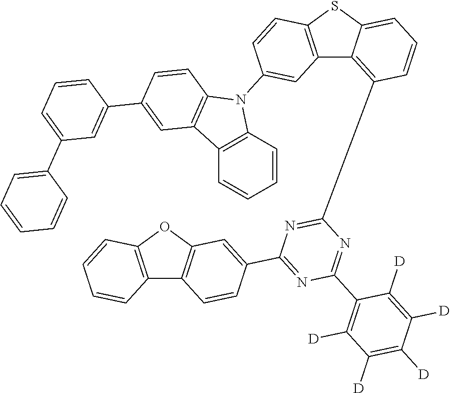 [SMILES: [2H]c1c([2H])c([2H])c(-c2nc(-c3ccc4c(c3)oc3ccccc34)nc(-c3cccc4sc5ccc(-n6c7ccccc7c7cc(-c8cccc(-c9ccccc9)c8)ccc76)cc5c34)n2)c([2H])c1[2H]]

79

### EXAMPLE 2: SYNTHESIS OF COMPOUNDS

### a) 2-{12-chloro-8-oxatricyclo[7.4.0.0^{2,7}]trideca-1(13),2(7),3,5,9,11-hexaen-3-yl}-4-{8-oxatricyclo[7.4.0.0^{2,7}]trideca-1(9),2,4,6,10,12-hexaen-3-yl}-6-phenyl-1,3,5-triazine

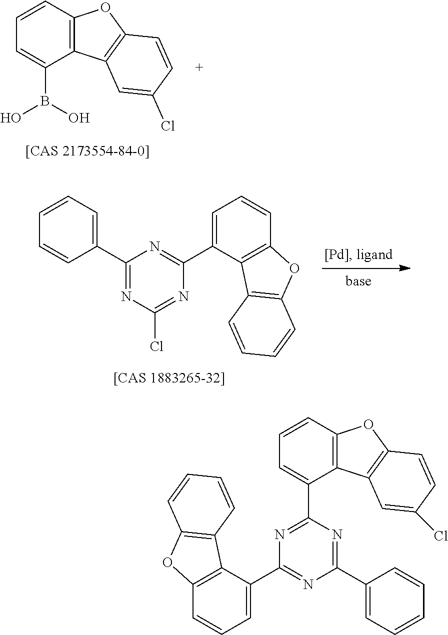 [SMILES: OB(O)c1cccc2oc3ccc(Cl)cc3c12 ; Clc1nc(-c2ccccc2)nc(-c2cccc3oc4ccccc4c23)n1 ; Clc1ccc2oc3cccc(-c4nc(-c5ccccc5)nc(-c5cccc6oc7ccccc7c56)n4)c3c2c1]

58 g (210 mmol; 1.00 eq.) of 1-boronyl-8-chlorodibenzofuran [CAS 162667-19-4], 90.2 g (252 mmol; 1.20 eq.) of 2-chloro-4-{8-oxatricyclo[7.4.0.0^{2,7}]trideca-1 (9),2(7),3,5,10,12-hexaen-3-yl}-6-phenyl-1,3,5-triazine [CAS 1883265-32-4] and 44.5 g (420 mmol, 2.00 eq.) of sodium carbonate [CAS 497-19-8] are suspended in a mixture of 1000 ml of dioxane [CAS 123-91-1], 1000 ml of toluene [CAS 108-88-3] and 400 ml of water. To this suspension is added 4.85 g (4.20 mmol/0.02 eq.) of tetrakis(triphenylphosphine)palladium(0) [CAS 14221-01-3], and the reaction mixture is heated under reflux for 16 h. After cooling, the organic phase is removed, filtered through silica gel, washed three times with 200 ml of water and then concentrated to dryness. The yield is 79.1 g (151 mmol; 72% of theory).

Rather than 1-boronyl-8-chlorodibenzofuran [CAS 162667-19-4], it is also possible to use 8-chloro-1-(4,4,5,5-tetramethyl-1,3,2-dioxaborolan-2-yl)dibenzothiophene [CAS-2140848-96-8].

In an analogous manner, it is possible to obtain the following compounds:

| No. | Reactant 1 | Product | Yield |
|---|---|---|---|
| 1a | 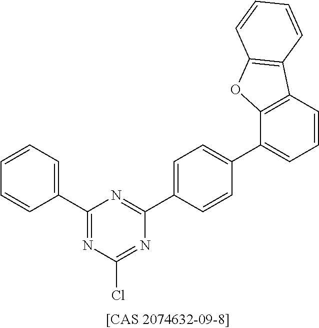 [SMILES: Clc1nc(-c2ccccc2)nc(-c2ccc(-c3cccc4c3oc3ccccc34)cc2)n1] | 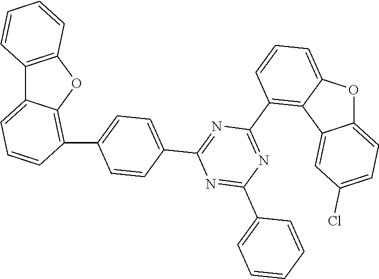 [SMILES: Clc1ccc2oc3cccc(-c4nc(-c5ccccc5)nc(-c5ccc(-c6cccc7c6oc6ccccc67)cc5)n4)c3c2c1] | 80% |
| 2a | 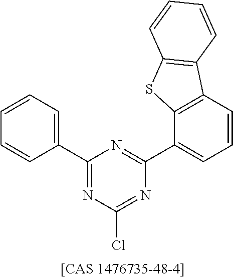 [SMILES: Clc1nc(-c2ccccc2)nc(-c2cccc3c2sc2ccccc23)n1] | 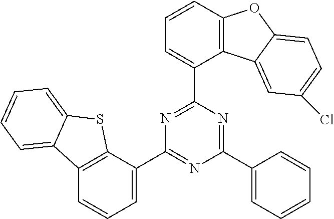 [SMILES: Clc1ccc2oc3cccc(-c4nc(-c5ccccc5)nc(-c5cccc6c5sc5ccccc56)n4)c3c2c1] | 65% |
| 3a | 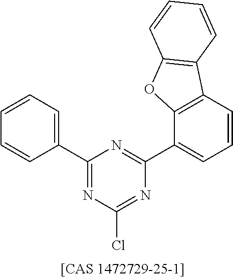 [SMILES: Clc1nc(-c2ccccc2)nc(-c2cccc3c2oc2ccccc23)n1] | 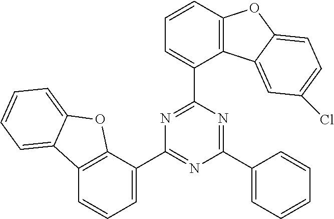 [SMILES: Clc1ccc2oc3cccc(-c4nc(-c5ccccc5)nc(-c5cccc6c5oc5ccccc56)n4)c3c2c1] | 67% |
| 4a | 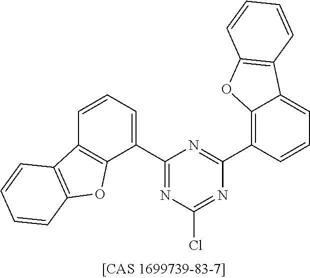 [SMILES: Clc1nc(-c2cccc3c2oc2ccccc23)nc(-c2cccc3c2oc2ccccc23)n1] | 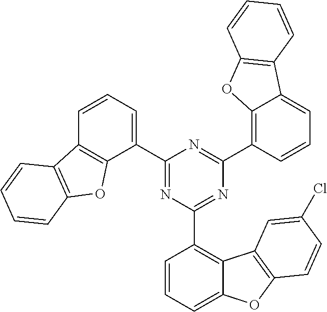 [SMILES: Clc1ccc2oc3cccc(-c4nc(-c5cccc6c5oc5ccccc56)nc(-c5cccc6c5oc5ccccc56)n4)c3c2c1] | 75% |
| 5a | 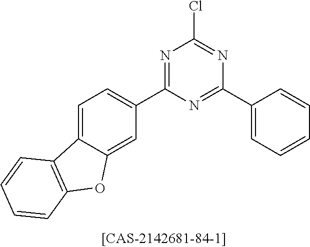 [SMILES: Clc1nc(-c2ccccc2)nc(-c2ccc3c(c2)oc2ccccc23)n1] | 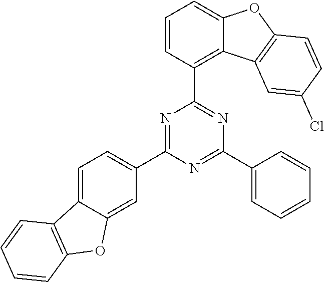 [SMILES: Clc1ccc2oc3cccc(-c4nc(-c5ccccc5)nc(-c5ccc6c(c5)oc5ccccc56)n4)c3c2c1] | 72% |
| 6a | 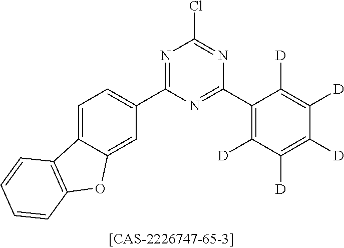 [SMILES: [2H]c1c([2H])c([2H])c(-c2nc(Cl)nc(-c3ccc4c(c3)oc3ccccc34)n2)c([2H])c1[2H]] | 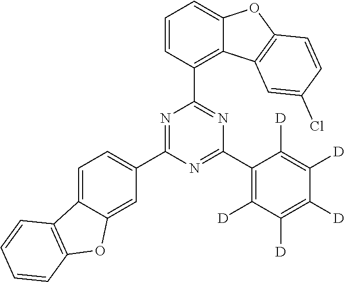 [SMILES: [2H]c1c([2H])c([2H])c(-c2nc(-c3ccc4c(c3)oc3ccccc34)nc(-c3cccc4oc5ccc(Cl)cc5c34)n2)c([2H])c1[2H]] | 74% |
| 7a | 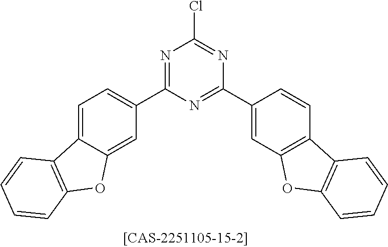 [SMILES: Clc1nc(-c2ccc3c(c2)oc2ccccc23)nc(-c2ccc3c(c2)oc2ccccc23)n1] | 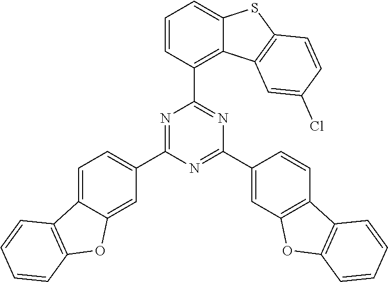 [SMILES: Clc1ccc2sc3cccc(-c4nc(-c5ccc6c(c5)oc5ccccc56)nc(-c5ccc6c(c5)oc5ccccc56)n4)c3c2c1] | 67% |
| 8a | 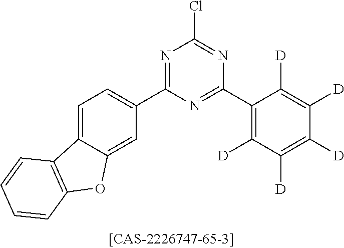 [SMILES: [2H]c1c([2H])c([2H])c(-c2nc(Cl)nc(-c3ccc4c(c3)oc3ccccc34)n2)c([2H])c1[2H]] | 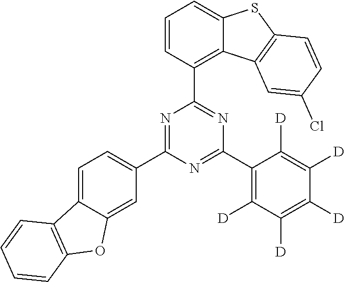 [SMILES: [2H]c1c([2H])c([2H])c(-c2nc(-c3ccc4c(c3)oc3ccccc34)nc(-c3cccc4sc5ccc(Cl)cc5c34)n2)c([2H])c1[2H]] | 65% |
| 9a | 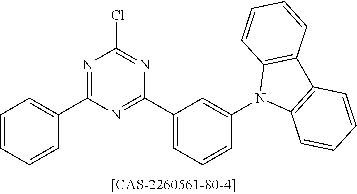 [SMILES: Clc1nc(-c2ccccc2)nc(-c2cccc(-n3c4ccccc4c4ccccc43)c2)n1] | 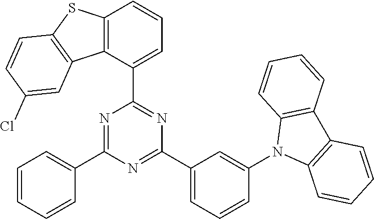 [SMILES: Clc1ccc2sc3cccc(-c4nc(-c5ccccc5)nc(-c5cccc(-n6c7ccccc7c7ccccc76)c5)n4)c3c2c1] | 62% |
| 10a | 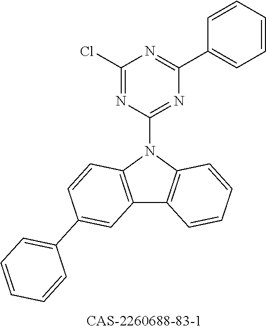 [SMILES: Clc1nc(-c2ccccc2)nc(-n2c3ccccc3c3cc(-c4ccccc4)ccc32)n1] | 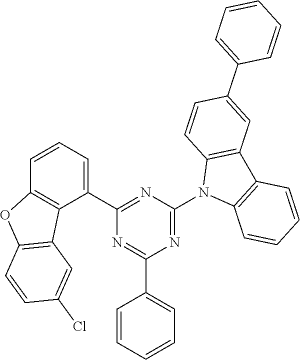 [SMILES: Clc1ccc2oc3cccc(-c4nc(-c5ccccc5)nc(-n5c6ccccc6c6cc(-c7ccccc7)ccc65)n4)c3c2c1] | 58% |
| 11a | 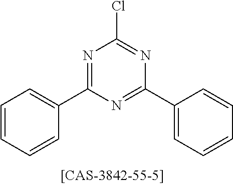 [SMILES: Clc1nc(-c2ccccc2)nc(-c2ccccc2)n1] | 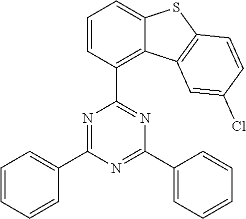 [SMILES: Clc1ccc2sc3cccc(-c4nc(-c5ccccc5)nc(-c5ccccc5)n4)c3c2c1] | 75% |

### b) 3-Biphenyl-3-yl-9-[9-(4,6-diphenyl-[1,3,5]triazin-2-yl)-dibenzofuran-2-yl]-9H-carbazole

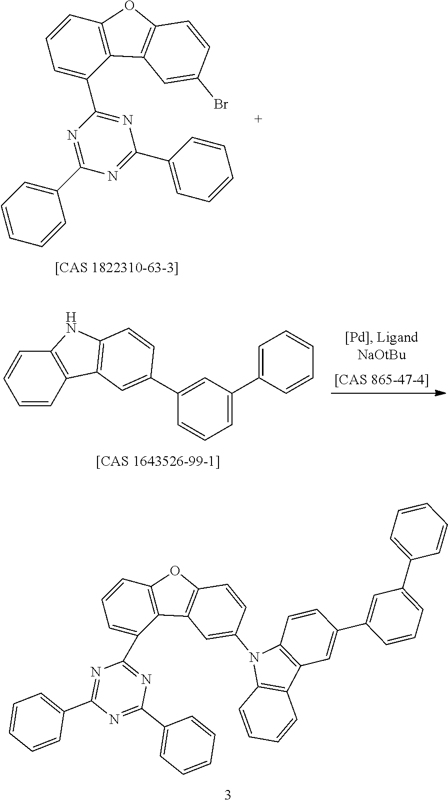 [SMILES: Brc1ccc2oc3cccc(-c4nc(-c5ccccc5)nc(-c5ccccc5)n4)c3c2c1 ; c1ccc(-c2cccc(-c3ccc4[nH]c5ccccc5c4c3)c2)cc1 ; c1ccc(-c2cccc(-c3ccc4c(c3)c3ccccc3n4-c3ccc4oc5cccc(-c6nc(-c7ccccc7)nc(-c7ccccc7)n6)c5c4c3)c2)cc1]

21.4 g (42.7 mmol; 1.00 eq.) of 2-{12-bromo-8-oxatricyclo[7.4.0.0²⁷]trideca-1(9),2(7),3,5,12-hexaen-3-yl}-4,6-diphenyl-1,3,5-triazine [CAS 1822310-63-3], 13.0 g (40.7 mmol; 1.10 eq.) of 3-biphenyl-3-yl-9H-carbazole [CAS 1643526-99-1] and 7.82 g (81.4 mmol; 2.00 eq.) of sodium tert-butoxide [CAS 865-47-4] are suspended in 500 ml of ortho-xylene [CAS 95-47-6]. To this suspension are added 1.50 g (3.66 mmol; 9 mol %) of dicyclohexyl(2′,6′-dimethoxybiphenyl-2-yl)phosphine (SPhos) [CAS 657408-07-6] and 1.12 g (1.22 mmol; 3 mol %) of tris(dibenzylideneacetone)dipalladium [CAS 51364-51-3], and the reaction mixture is heated under reflux for 16 h. The reaction mixture is cooled down to room temperature and the solvent is removed under reduced pressure. The solids obtained are washed with 300 ml of ethanol and the recrystallized repeatedly for a mixture of heptane and xylene. After a hot filtration through Alox followed by sublimation under high vacuum, the purified product is obtained as a colourless solid, 21.1 g (29.5 mmol; 69%).

In an analogous manner, it is possible to obtain the following compounds:

| No. | Reactant 1 | Reactant 2 |
|---|---|---|
| 1b | 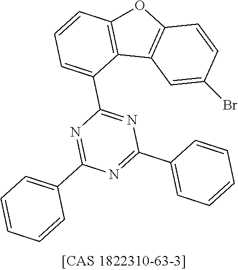 [SMILES: Brc1ccc2oc3cccc(-c4nc(-c5ccccc5)nc(-c5ccccc5)n4)c3c2c1] | 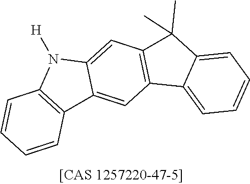 [SMILES: CC1(C)c2ccccc2-c2cc3c(cc21)[nH]c1ccccc13] |
| SoA | 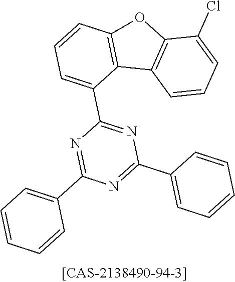 [SMILES: Clc1cccc2c1oc1cccc(-c3nc(-c4ccccc4)nc(-c4ccccc4)n3)c12] | 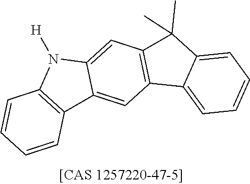 [SMILES: CC1(C)c2ccccc2-c2cc3c(cc21)[nH]c1ccccc13] |
| 2b | 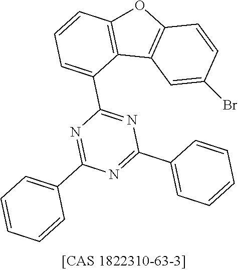 [SMILES: Brc1ccc2oc3cccc(-c4nc(-c5ccccc5)nc(-c5ccccc5)n4)c3c2c1] | 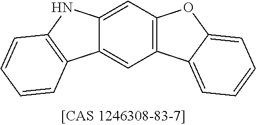 [SMILES: c1ccc2c(c1)[nH]c1cc3oc4ccccc4c3cc12] |
| 3b | 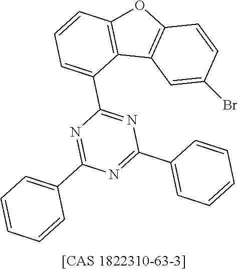 [SMILES: Brc1ccc2oc3cccc(-c4nc(-c5ccccc5)nc(-c5ccccc5)n4)c3c2c1] | 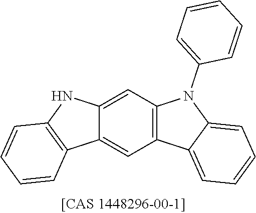 [SMILES: c1ccc(-n2c3ccccc3c3cc4c(cc32)[nH]c2ccccc24)cc1] |
| 4b | 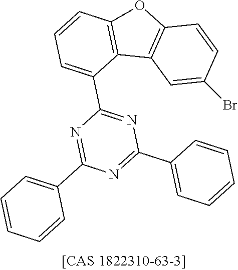 [SMILES: Brc1ccc2oc3cccc(-c4nc(-c5ccccc5)nc(-c5ccccc5)n4)c3c2c1] | 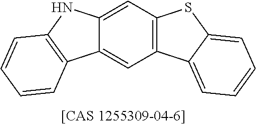 [SMILES: c1ccc2c(c1)[nH]c1cc3sc4ccccc4c3cc12] |
| 5b | 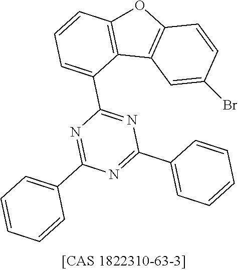 [SMILES: Brc1ccc2oc3cccc(-c4nc(-c5ccccc5)nc(-c5ccccc5)n4)c3c2c1] | 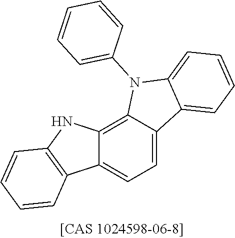 [SMILES: c1ccc(-n2c3ccccc3c3ccc4c5ccccc5[nH]c4c32)cc1] |
| 6b | 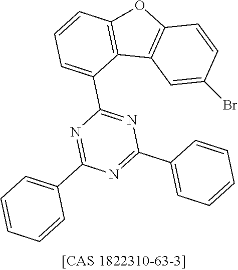 [SMILES: Brc1ccc2oc3cccc(-c4nc(-c5ccccc5)nc(-c5ccccc5)n4)c3c2c1] | 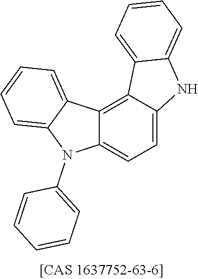 [SMILES: c1ccc(-n2c3ccccc3c3c4c(ccc32)[nH]c2ccccc24)cc1] |
| 7b | 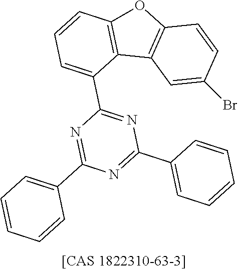 [SMILES: Brc1ccc2oc3cccc(-c4nc(-c5ccccc5)nc(-c5ccccc5)n4)c3c2c1] | 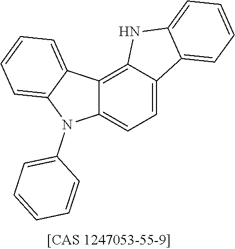 [SMILES: c1ccc(-n2c3ccccc3c3c4[nH]c5ccccc5c4ccc32)cc1] |
| 8b | 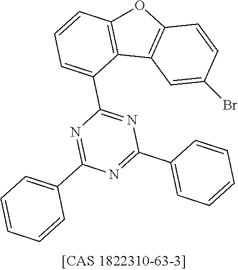 [SMILES: Brc1ccc2oc3cccc(-c4nc(-c5ccccc5)nc(-c5ccccc5)n4)c3c2c1] | 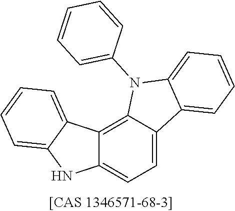 [SMILES: c1ccc(-n2c3ccccc3c3ccc4[nH]c5ccccc5c4c32)cc1] |
| 9b | 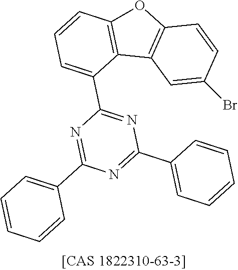 [SMILES: Brc1ccc2oc3cccc(-c4nc(-c5ccccc5)nc(-c5ccccc5)n4)c3c2c1] | 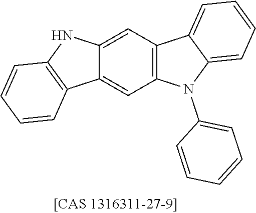 [SMILES: c1ccc(-n2c3ccccc3c3cc4[nH]c5ccccc5c4cc32)cc1] |
| 10b | 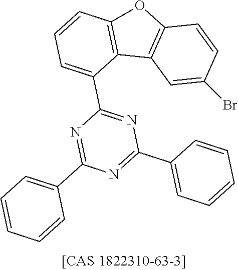 [SMILES: Brc1ccc2oc3cccc(-c4nc(-c5ccccc5)nc(-c5ccccc5)n4)c3c2c1] | 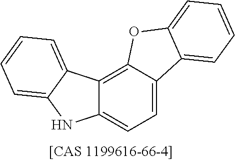 [SMILES: c1ccc2c(c1)[nH]c1ccc3c4ccccc4oc3c12] |
| 11b | 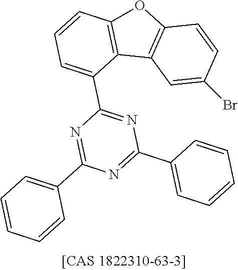 [SMILES: Brc1ccc2oc3cccc(-c4nc(-c5ccccc5)nc(-c5ccccc5)n4)c3c2c1] | 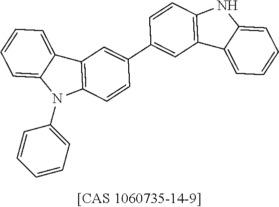 [SMILES: c1ccc(-n2c3ccccc3c3cc(-c4ccc5[nH]c6ccccc6c5c4)ccc32)cc1] |
| 12b | 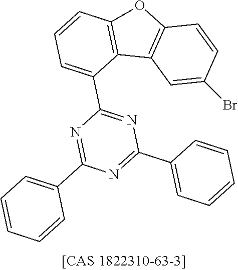 [SMILES: Brc1ccc2oc3cccc(-c4nc(-c5ccccc5)nc(-c5ccccc5)n4)c3c2c1] | 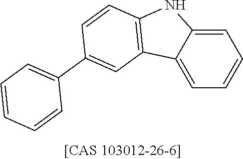 [SMILES: c1ccc(-c2ccc3[nH]c4ccccc4c3c2)cc1] |
| 13b | 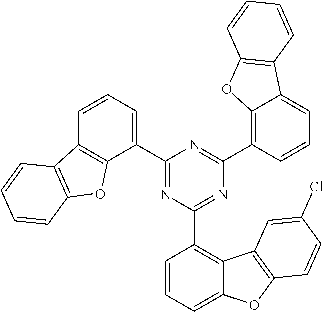 [SMILES: Clc1ccc2oc3cccc(-c4nc(-c5cccc6c5oc5ccccc56)nc(-c5cccc6c5oc5ccccc56)n4)c3c2c1] | 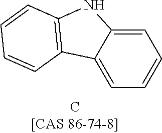 [SMILES: c1ccc2c(c1)[nH]c1ccccc12] |
| 14b | 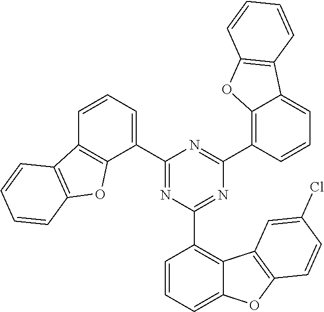 [SMILES: Clc1ccc2oc3cccc(-c4nc(-c5cccc6c5oc5ccccc56)nc(-c5cccc6c5oc5ccccc56)n4)c3c2c1] | 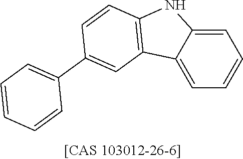 [SMILES: c1ccc(-c2ccc3[nH]c4ccccc4c3c2)cc1] |
| 15b | 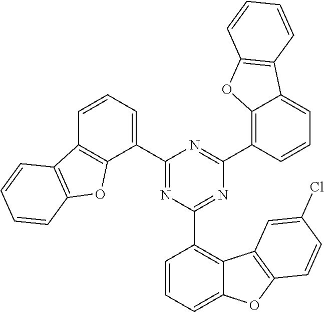 [SMILES: Clc1ccc2oc3cccc(-c4nc(-c5cccc6c5oc5ccccc56)nc(-c5cccc6c5oc5ccccc56)n4)c3c2c1] | 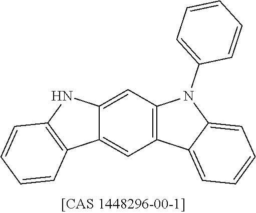 [SMILES: c1ccc(-n2c3ccccc3c3cc4c(cc32)[nH]c2ccccc24)cc1] |
| 16b | 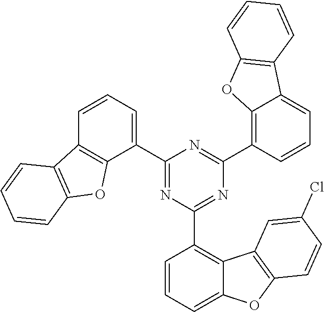 [SMILES: Clc1ccc2oc3cccc(-c4nc(-c5cccc6c5oc5ccccc56)nc(-c5cccc6c5oc5ccccc56)n4)c3c2c1] | 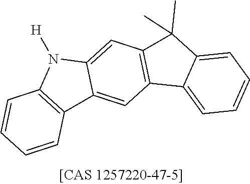 [SMILES: CC1(C)c2ccccc2-c2cc3c(cc21)[nH]c1ccccc13] |
| 17b | 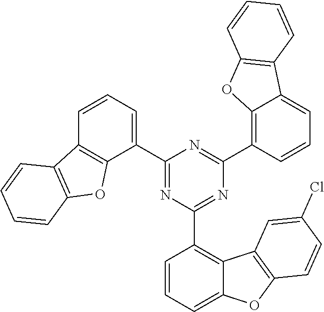 [SMILES: Clc1ccc2oc3cccc(-c4nc(-c5cccc6c5oc5ccccc56)nc(-c5cccc6c5oc5ccccc56)n4)c3c2c1] | 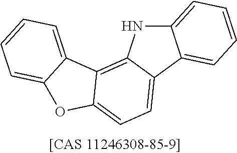 [SMILES: c1ccc2c(c1)[nH]c1c2ccc2oc3ccccc3c21] |
| 18b | 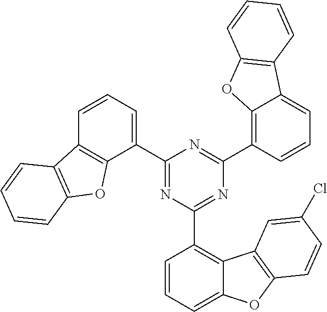 [SMILES: Clc1ccc2oc3cccc(-c4nc(-c5cccc6c5oc5ccccc56)nc(-c5cccc6c5oc5ccccc56)n4)c3c2c1] | 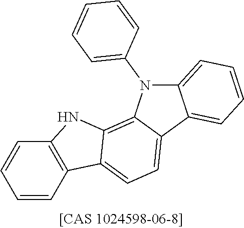 [SMILES: c1ccc(-n2c3ccccc3c3ccc4c5ccccc5[nH]c4c32)cc1] |
| 19b | 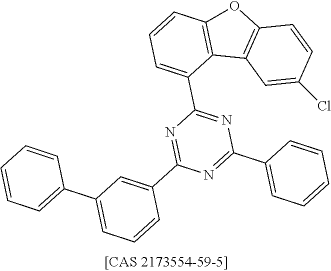 [SMILES: Clc1ccc2oc3cccc(-c4nc(-c5ccccc5)nc(-c5cccc(-c6ccccc6)c5)n4)c3c2c1] | 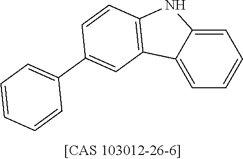 [SMILES: c1ccc(-c2ccc3[nH]c4ccccc4c3c2)cc1] |
| 20b | 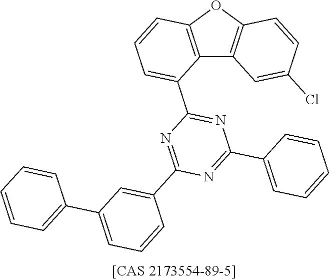 [SMILES: Clc1ccc2oc3cccc(-c4nc(-c5ccccc5)nc(-c5cccc(-c6ccccc6)c5)n4)c3c2c1] | 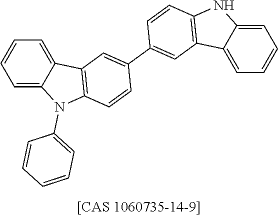 [SMILES: c1ccc(-n2c3ccccc3c3cc(-c4ccc5[nH]c6ccccc6c5c4)ccc32)cc1] |
| 21b | 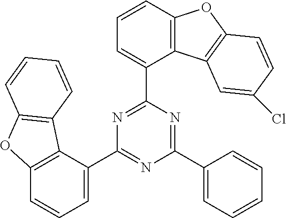 [SMILES: Clc1ccc2oc3cccc(-c4nc(-c5ccccc5)nc(-c5cccc6oc7ccccc7c56)n4)c3c2c1] | 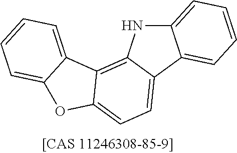 [SMILES: c1ccc2c(c1)[nH]c1c2ccc2oc3ccccc3c21] |
| 22b | 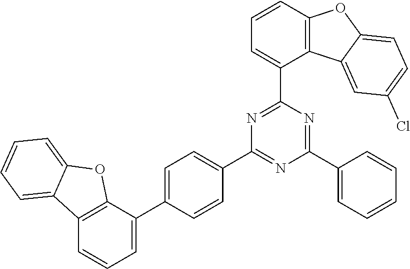 [SMILES: Clc1ccc2oc3cccc(-c4nc(-c5ccccc5)nc(-c5ccc(-c6cccc7c6oc6ccccc67)cc5)n4)c3c2c1] | 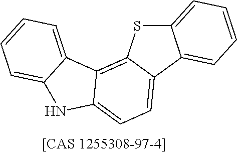 [SMILES: c1ccc2c(c1)[nH]c1ccc3c4ccccc4sc3c12] |
| 23b | 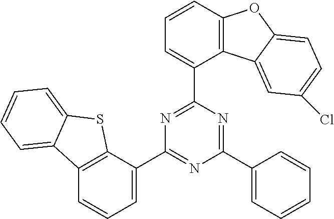 [SMILES: Clc1ccc2oc3cccc(-c4nc(-c5ccccc5)nc(-c5cccc6c5sc5ccccc56)n4)c3c2c1] | 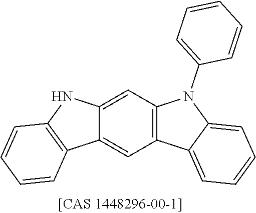 [SMILES: c1ccc(-n2c3ccccc3c3cc4c(cc32)[nH]c2ccccc24)cc1] |
| 24b | 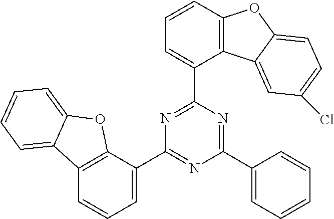 [SMILES: Clc1ccc2oc3cccc(-c4nc(-c5ccccc5)nc(-c5cccc6c5oc5ccccc56)n4)c3c2c1] | 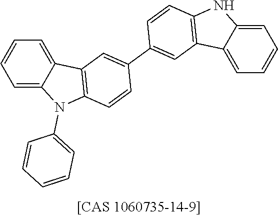 [SMILES: c1ccc(-n2c3ccccc3c3cc(-c4ccc5[nH]c6ccccc6c5c4)ccc32)cc1] |
| 25b | 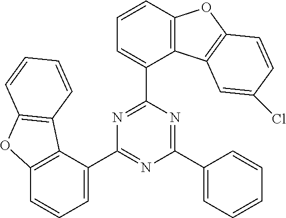 [SMILES: Clc1ccc2oc3cccc(-c4nc(-c5ccccc5)nc(-c5cccc6oc7ccccc7c56)n4)c3c2c1] | 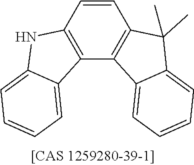 [SMILES: CC1(C)c2ccccc2-c2c1ccc1[nH]c3ccccc3c21] |
| 26b | 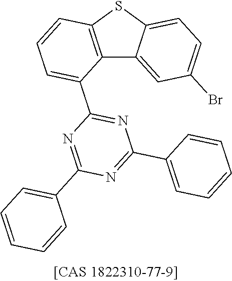 [SMILES: Brc1ccc2sc3cccc(-c4nc(-c5ccccc5)nc(-c5ccccc5)n4)c3c2c1] | 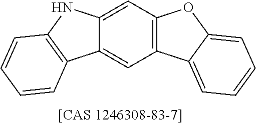 [SMILES: c1ccc2c(c1)[nH]c1cc3oc4ccccc4c3cc12] |
| 27b | 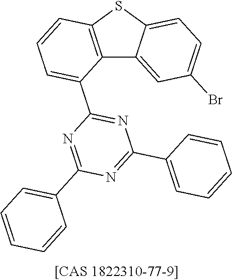 [SMILES: Brc1ccc2sc3cccc(-c4nc(-c5ccccc5)nc(-c5ccccc5)n4)c3c2c1] | 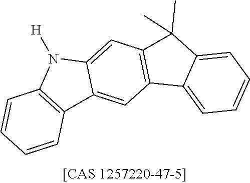 [SMILES: CC1(C)c2ccccc2-c2cc3c(cc21)[nH]c1ccccc13] |
| 28b | 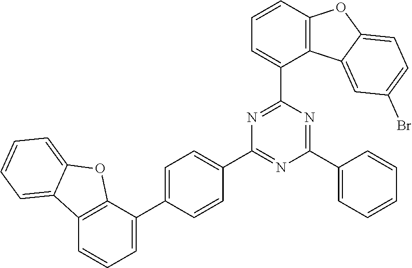 [SMILES: Brc1ccc2oc3cccc(-c4nc(-c5ccccc5)nc(-c5ccc(-c6cccc7c6oc6ccccc67)cc5)n4)c3c2c1] | 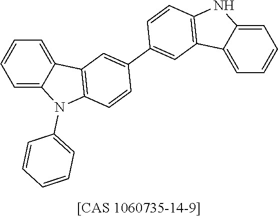 [SMILES: c1ccc(-n2c3ccccc3c3cc(-c4ccc5[nH]c6ccccc6c5c4)ccc32)cc1] |
| 29b | 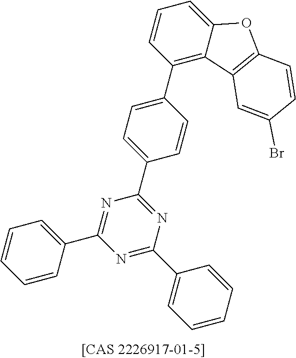 [SMILES: Brc1ccc2oc3cccc(-c4ccc(-c5nc(-c6ccccc6)nc(-c6ccccc6)n5)cc4)c3c2c1] | 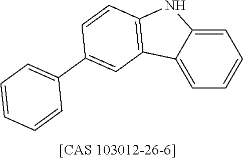 [SMILES: c1ccc(-c2ccc3[nH]c4ccccc4c3c2)cc1] |
| 30b | 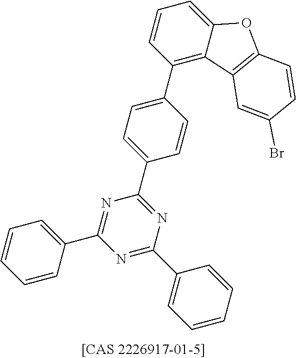 [SMILES: Brc1ccc2oc3cccc(-c4ccc(-c5nc(-c6ccccc6)nc(-c6ccccc6)n5)cc4)c3c2c1] | 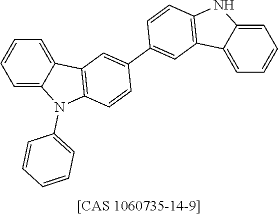 [SMILES: c1ccc(-n2c3ccccc3c3cc(-c4ccc5[nH]c6ccccc6c5c4)ccc32)cc1] |
| 31b | 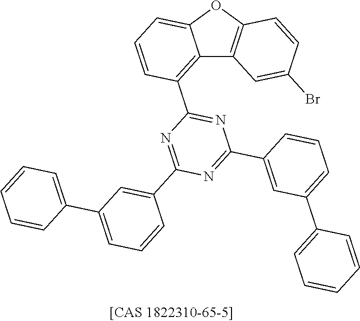 [SMILES: Brc1ccc2oc3cccc(-c4nc(-c5cccc(-c6ccccc6)c5)nc(-c5cccc(-c6ccccc6)c5)n4)c3c2c1] | 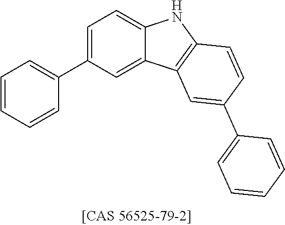 [SMILES: c1ccc(-c2ccc3[nH]c4ccc(-c5ccccc5)cc4c3c2)cc1] |
| 32b | 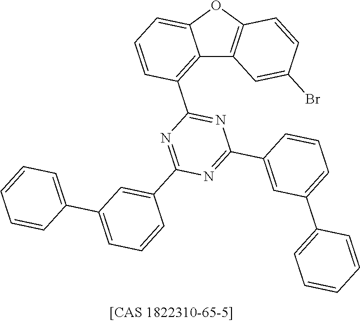 [SMILES: Brc1ccc2oc3cccc(-c4nc(-c5cccc(-c6ccccc6)c5)nc(-c5cccc(-c6ccccc6)c5)n4)c3c2c1] | 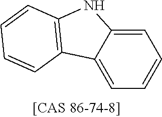 [SMILES: c1ccc2c(c1)[nH]c1ccccc12] |
| 33b | 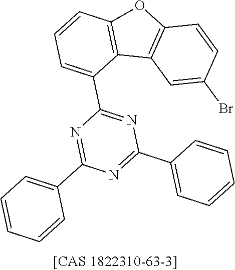 [SMILES: Brc1ccc2oc3cccc(-c4nc(-c5ccccc5)nc(-c5ccccc5)n4)c3c2c1] | 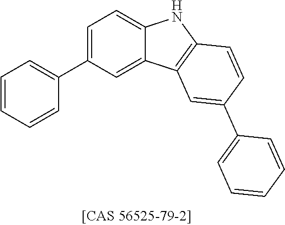 [SMILES: c1ccc(-c2ccc3[nH]c4ccc(-c5ccccc5)cc4c3c2)cc1] |
| 34b | 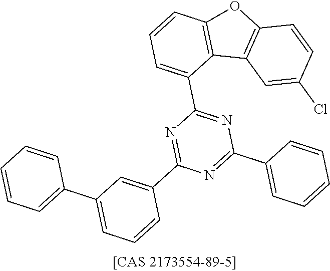 [SMILES: Clc1ccc2oc3cccc(-c4nc(-c5ccccc5)nc(-c5cccc(-c6ccccc6)c5)n4)c3c2c1] | 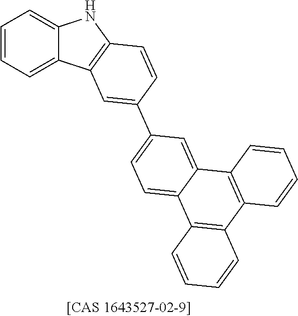 [SMILES: c1ccc2c(c1)[nH]c1ccc(-c3ccc4c5ccccc5c5ccccc5c4c3)cc12] |
| 35b | 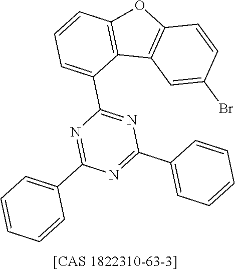 [SMILES: Brc1ccc2oc3cccc(-c4nc(-c5ccccc5)nc(-c5ccccc5)n4)c3c2c1] | 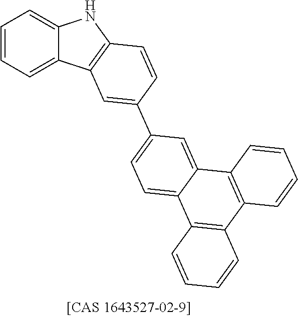 [SMILES: c1ccc2c(c1)[nH]c1ccc(-c3ccc4c5ccccc5c5ccccc5c4c3)cc12] |
| 36b | 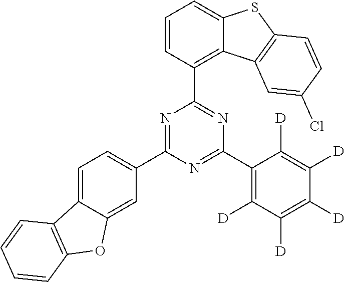 [SMILES: [2H]c1c([2H])c([2H])c(-c2nc(-c3ccc4c(c3)oc3ccccc34)nc(-c3cccc4sc5ccc(Cl)cc5c34)n2)c([2H])c1[2H]] | 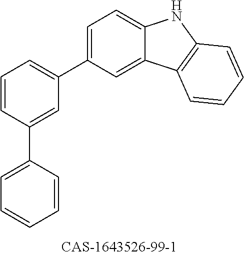 [SMILES: c1ccc(-c2cccc(-c3ccc4[nH]c5ccccc5c4c3)c2)cc1] |
| 37b | 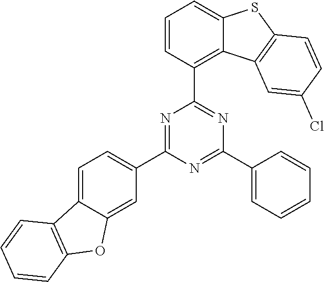 [SMILES: Clc1ccc2sc3cccc(-c4nc(-c5ccccc5)nc(-c5ccc6c(c5)oc5ccccc56)n4)c3c2c1] | 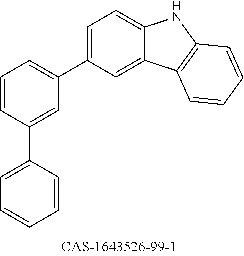 [SMILES: c1ccc(-c2cccc(-c3ccc4[nH]c5ccccc5c4c3)c2)cc1] |
| 38b | 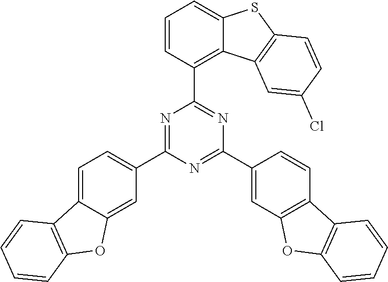 [SMILES: Clc1ccc2sc3cccc(-c4nc(-c5ccc6c(c5)oc5ccccc56)nc(-c5ccc6c(c5)oc5ccccc56)n4)c3c2c1] | 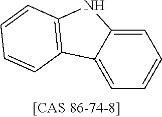 [SMILES: c1ccc2c(c1)[nH]c1ccccc12] |
| 39b | 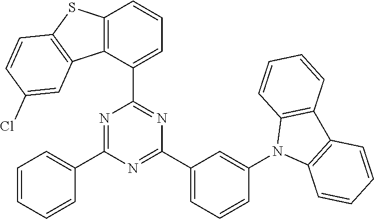 [SMILES: Clc1ccc2sc3cccc(-c4nc(-c5ccccc5)nc(-c5cccc(-n6c7ccccc7c7ccccc76)c5)n4)c3c2c1] | 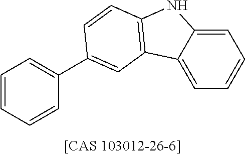 [SMILES: c1ccc(-c2ccc3[nH]c4ccccc4c3c2)cc1] |
| 40b | 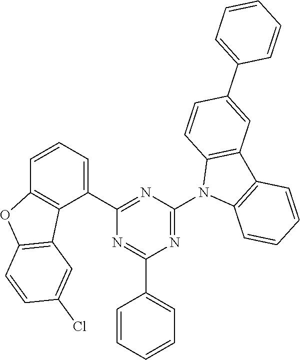 [SMILES: Clc1ccc2oc3cccc(-c4nc(-c5ccccc5)nc(-n5c6ccccc6c6cc(-c7ccccc7)ccc65)n4)c3c2c1] | 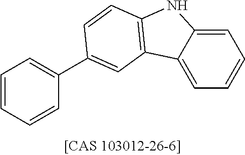 [SMILES: c1ccc(-c2ccc3[nH]c4ccccc4c3c2)cc1] |
| 41b | 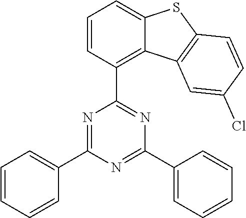 [SMILES: Clc1ccc2sc3cccc(-c4nc(-c5ccccc5)nc(-c5ccccc5)n4)c3c2c1] | 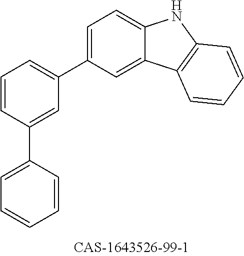 [SMILES: c1ccc(-c2cccc(-c3ccc4[nH]c5ccccc5c4c3)c2)cc1] |
| 42b | 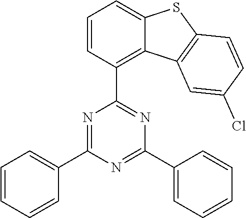 [SMILES: Clc1ccc2sc3cccc(-c4nc(-c5ccccc5)nc(-c5ccccc5)n4)c3c2c1] | 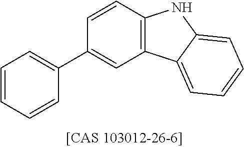 [SMILES: c1ccc(-c2ccc3[nH]c4ccccc4c3c2)cc1] |
| 43b | 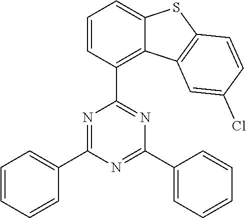 [SMILES: Clc1ccc2sc3cccc(-c4nc(-c5ccccc5)nc(-c5ccccc5)n4)c3c2c1] | 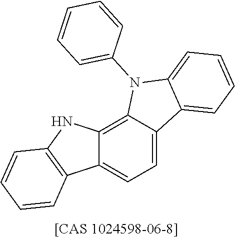 [SMILES: c1ccc(-n2c3ccccc3c3ccc4c5ccccc5[nH]c4c32)cc1] |
| 44b | 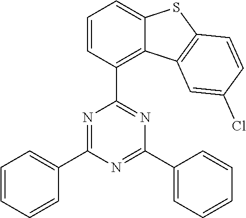 [SMILES: Clc1ccc2sc3cccc(-c4nc(-c5ccccc5)nc(-c5ccccc5)n4)c3c2c1] | 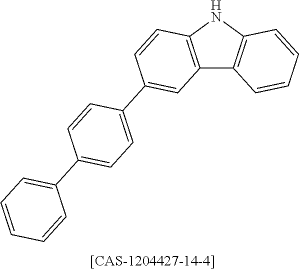 [SMILES: c1ccc(-c2ccc(-c3ccc4[nH]c5ccccc5c4c3)cc2)cc1] |
| No. | Product | Yield |
| 1b | 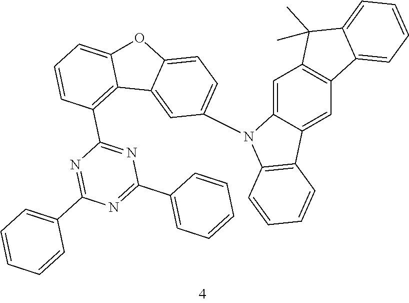 [SMILES: CC1(C)c2ccccc2-c2cc3c4ccccc4n(-c4ccc5oc6cccc(-c7nc(-c8ccccc8)nc(-c8ccccc8)n7)c6c5c4)c3cc21] | 83% |
| SoA | 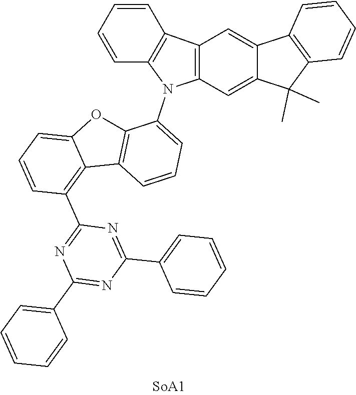 [SMILES: CC1(C)c2ccccc2-c2cc3c4ccccc4n(-c4cccc5c4oc4cccc(-c6nc(-c7ccccc7)nc(-c7ccccc7)n6)c45)c3cc21] | 73% |
| 2b | 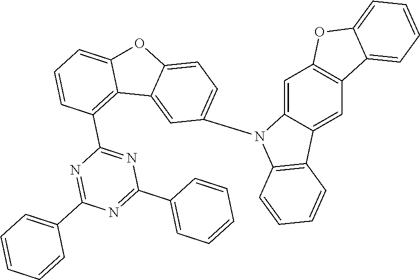 [SMILES: c1ccc(-c2nc(-c3ccccc3)nc(-c3cccc4oc5ccc(-n6c7ccccc7c7cc8c(cc76)oc6ccccc68)cc5c34)n2)cc1] | 81% |
| 3b | 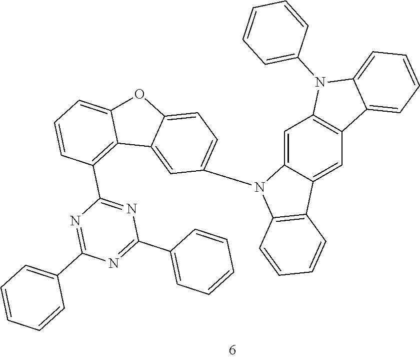 [SMILES: c1ccc(-c2nc(-c3ccccc3)nc(-c3cccc4oc5ccc(-n6c7ccccc7c7cc8c9ccccc9n(-c9ccccc9)c8cc76)cc5c34)n2)cc1] | 77% |
| 4b | 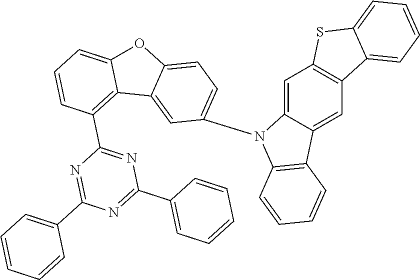 [SMILES: c1ccc(-c2nc(-c3ccccc3)nc(-c3cccc4oc5ccc(-n6c7ccccc7c7cc8c(cc76)sc6ccccc68)cc5c34)n2)cc1] | 80% |
| 5b | 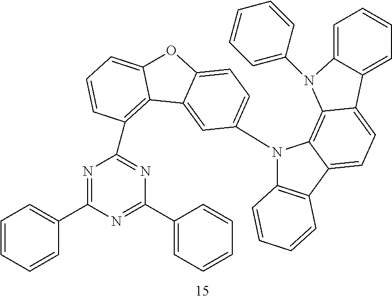 [SMILES: c1ccc(-c2nc(-c3ccccc3)nc(-c3cccc4oc5ccc(-n6c7ccccc7c7ccc8c9ccccc9n(-c9ccccc9)c8c76)cc5c34)n2)cc1] | 47% |
| 6b | 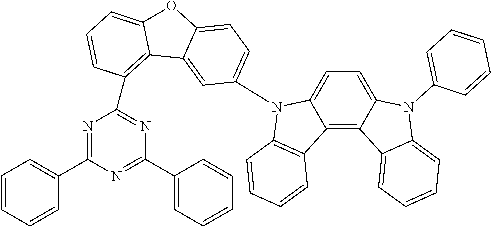 [SMILES: c1ccc(-c2nc(-c3ccccc3)nc(-c3cccc4oc5ccc(-n6c7ccccc7c7c8c9ccccc9n(-c9ccccc9)c8ccc76)cc5c34)n2)cc1] | 70% |
| 7b | 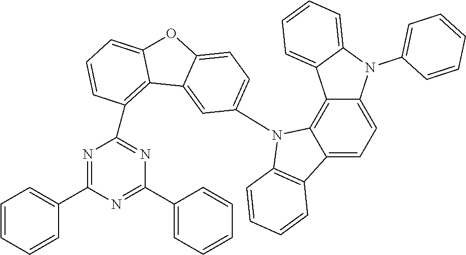 [SMILES: c1ccc(-c2nc(-c3ccccc3)nc(-c3cccc4oc5ccc(-n6c7ccccc7c7ccc8c(c9ccccc9n8-c8ccccc8)c76)cc5c34)n2)cc1] | 61% |
| 8b | 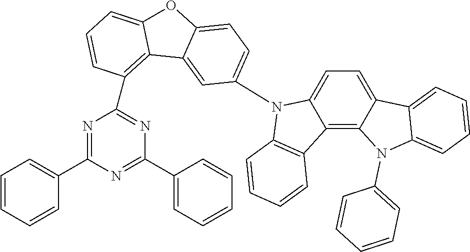 [SMILES: c1ccc(-c2nc(-c3ccccc3)nc(-c3cccc4oc5ccc(-n6c7ccccc7c7c6ccc6c8ccccc8n(-c8ccccc8)c67)cc5c34)n2)cc1] | 65% |
| 9b | 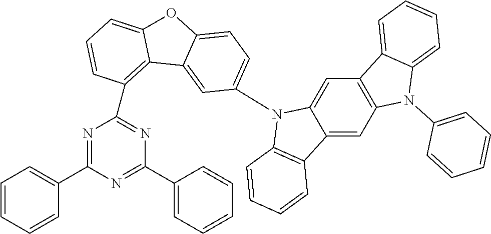 [SMILES: c1ccc(-c2nc(-c3ccccc3)nc(-c3cccc4oc5ccc(-n6c7ccccc7c7cc8c(cc76)c6ccccc6n8-c6ccccc6)cc5c34)n2)cc1] | 84% |
| 10b | 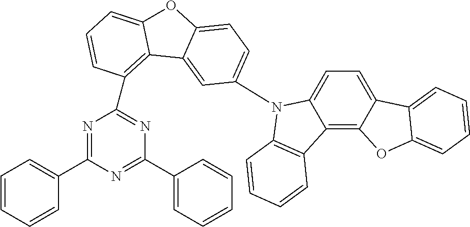 [SMILES: c1ccc(-c2nc(-c3ccccc3)nc(-c3cccc4oc5ccc(-n6c7ccccc7c7c8oc9ccccc9c8ccc76)cc5c34)n2)cc1] | 81% |
| 11b | 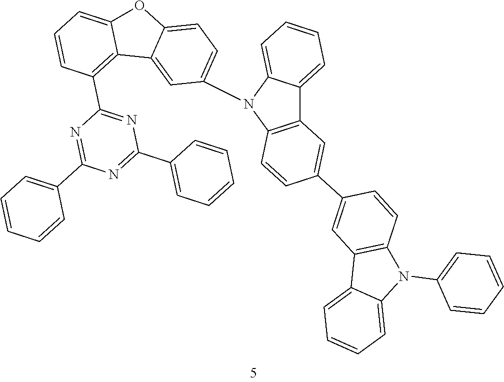 [SMILES: c1ccc(-c2nc(-c3ccccc3)nc(-c3cccc4oc5ccc(-n6c7ccccc7c7cc(-c8ccc9c(c8)c8ccccc8n9-c8ccccc8)ccc76)cc5c34)n2)cc1] | 72% |
| 12b | 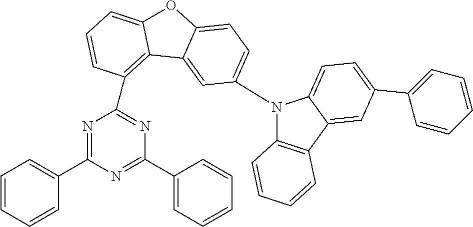 [SMILES: c1ccc(-c2ccc3c(c2)c2ccccc2n3-c2ccc3oc4cccc(-c5nc(-c6ccccc6)nc(-c6ccccc6)n5)c4c3c2)cc1] | 88% |
| 13b | 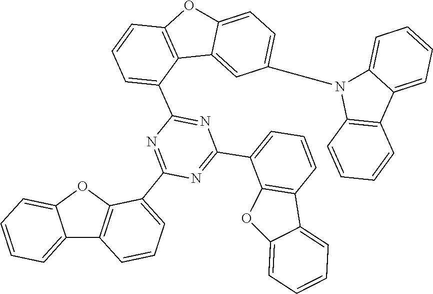 [SMILES: c1ccc2c(c1)oc1c(-c3nc(-c4cccc5c4oc4ccccc45)nc(-c4cccc5oc6ccc(-n7c8ccccc8c8ccccc87)cc6c45)n3)cccc12] | 62% |
| 14b | 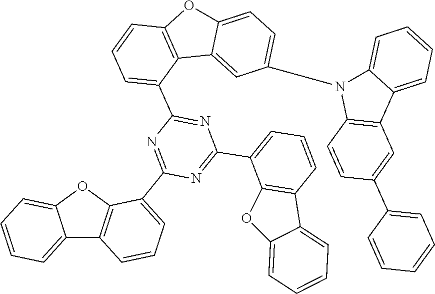 [SMILES: c1ccc(-c2ccc3c(c2)c2ccccc2n3-c2ccc3oc4cccc(-c5nc(-c6cccc7c6oc6ccccc67)nc(-c6cccc7c6oc6ccccc67)n5)c4c3c2)cc1] | 68% |
| 15b | 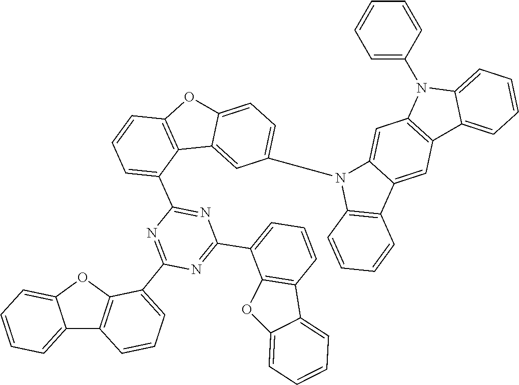 [SMILES: c1ccc(-n2c3ccccc3c3cc4c5ccccc5n(-c5ccc6oc7cccc(-c8nc(-c9cccc%10c9oc9ccccc9%10)nc(-c9cccc%10c9oc9ccccc9%10)n8)c7c6c5)c4cc32)cc1] | 58% |
| 16b | 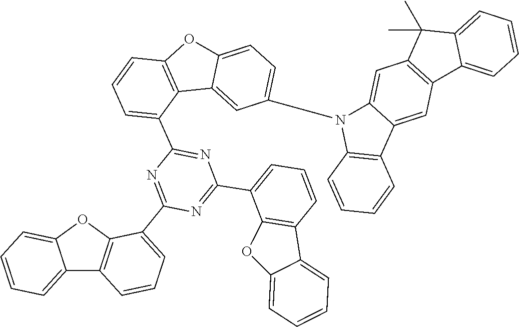 [SMILES: CC1(C)c2ccccc2-c2cc3c4ccccc4n(-c4ccc5oc6cccc(-c7nc(-c8cccc9c8oc8ccccc89)nc(-c8cccc9c8oc8ccccc89)n7)c6c5c4)c3cc21] | 61% |
| 17b | 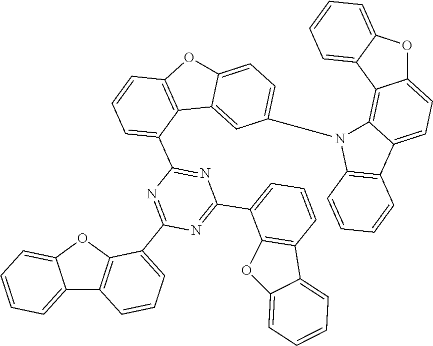 [SMILES: c1ccc2c(c1)oc1c(-c3nc(-c4cccc5c4oc4ccccc45)nc(-c4cccc5oc6ccc(-n7c8ccccc8c8ccc9oc%10ccccc%10c9c87)cc6c45)n3)cccc12] | 70% |
| 18b | 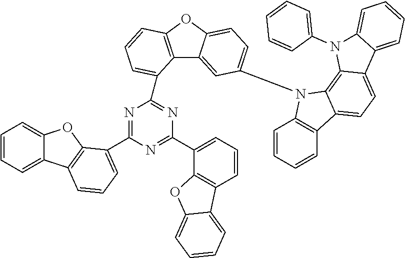 [SMILES: c1ccc(-n2c3ccccc3c3ccc4c5ccccc5n(-c5ccc6oc7cccc(-c8nc(-c9cccc%10c9oc9ccccc9%10)nc(-c9cccc%10c9oc9ccccc9%10)n8)c7c6c5)c4c32)cc1] | 67% |
| 19b | 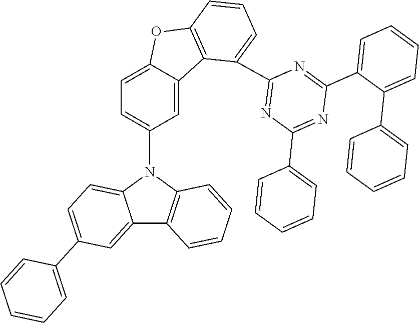 [SMILES: c1ccc(-c2ccc3c(c2)c2ccccc2n3-c2ccc3oc4cccc(-c5nc(-c6ccccc6)nc(-c6ccccc6-c6ccccc6)n5)c4c3c2)cc1] | 72% |
| 20b | 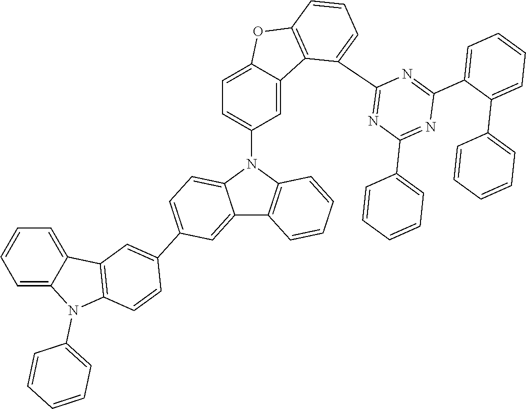 [SMILES: c1ccc(-c2nc(-c3ccccc3-c3ccccc3)nc(-c3cccc4oc5ccc(-n6c7ccccc7c7cc(-c8ccc9c(c8)c8ccccc8n9-c8ccccc8)ccc76)cc5c34)n2)cc1] | 71% |
| 21b | 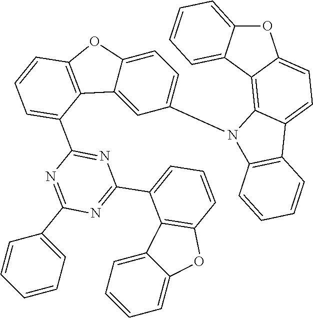 [SMILES: c1ccc(-c2nc(-c3cccc4oc5ccccc5c34)nc(-c3cccc4oc5ccc(-n6c7ccccc7c7ccc8oc9ccccc9c8c76)cc5c34)n2)cc1] | 72% |
| 22b | 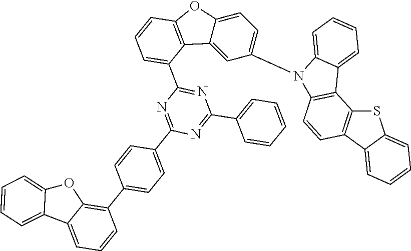 [SMILES: c1ccc(-c2nc(-c3ccc(-c4cccc5c4oc4ccccc45)cc3)nc(-c3cccc4oc5ccc(-n6c7ccccc7c7c8sc9ccccc9c8ccc76)cc5c34)n2)cc1] | 65% |
| 23b | 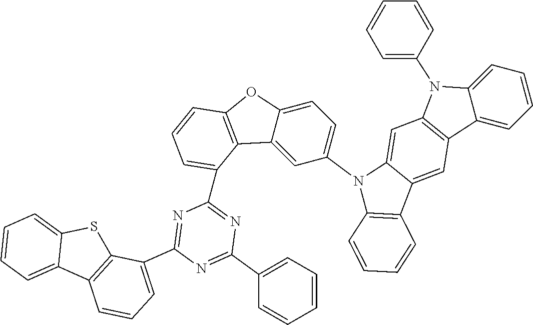 [SMILES: c1ccc(-c2nc(-c3cccc4c3sc3ccccc34)nc(-c3cccc4oc5ccc(-n6c7ccccc7c7cc8c9ccccc9n(-c9ccccc9)c8cc76)cc5c34)n2)cc1] | 66% |
| 24b | 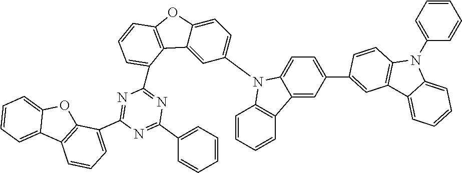 [SMILES: c1ccc(-c2nc(-c3cccc4c3oc3ccccc34)nc(-c3cccc4oc5ccc(-n6c7ccccc7c7cc(-c8ccc9c(c8)c8ccccc8n9-c8ccccc8)ccc76)cc5c34)n2)cc1] | 83% |
| 25b | 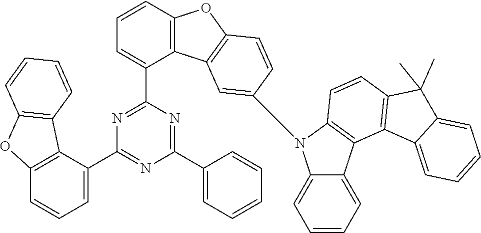 [SMILES: CC1(C)c2ccccc2-c2c1ccc1c2c2ccccc2n1-c1ccc2oc3cccc(-c4nc(-c5ccccc5)nc(-c5cccc6oc7ccccc7c56)n4)c3c2c1] | 80% |
| 26b | 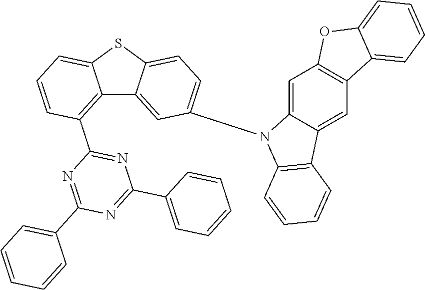 [SMILES: c1ccc(-c2nc(-c3ccccc3)nc(-c3cccc4sc5ccc(-n6c7ccccc7c7cc8c(cc76)oc6ccccc68)cc5c34)n2)cc1] | 52% |
| 27b | 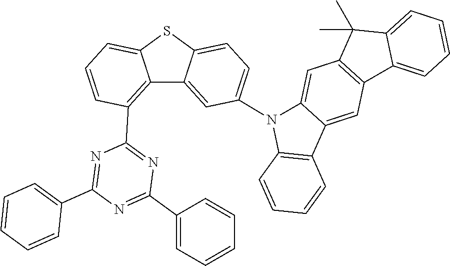 [SMILES: CC1(C)c2ccccc2-c2cc3c4ccccc4n(-c4ccc5sc6cccc(-c7nc(-c8ccccc8)nc(-c8ccccc8)n7)c6c5c4)c3cc21] | 71% |
| 28b | 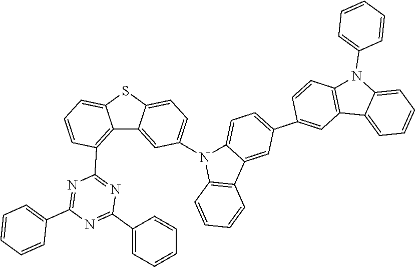 [SMILES: c1ccc(-c2nc(-c3ccccc3)nc(-c3cccc4sc5ccc(-n6c7ccccc7c7cc(-c8ccc9c(c8)c8ccccc8n9-c8ccccc8)ccc76)cc5c34)n2)cc1] | 68% |
| 29b | 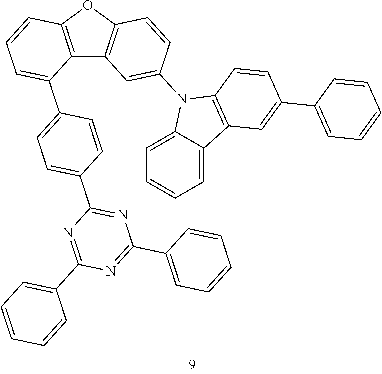 [SMILES: c1ccc(-c2ccc3c(c2)c2ccccc2n3-c2ccc3oc4cccc(-c5ccc(-c6nc(-c7ccccc7)nc(-c7ccccc7)n6)cc5)c4c3c2)cc1] | 65% |
| 30b | 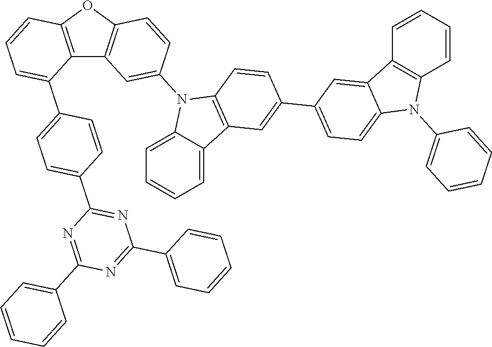 [SMILES: c1ccc(-c2nc(-c3ccccc3)nc(-c3ccc(-c4cccc5oc6ccc(-n7c8ccccc8c8cc(-c9ccc%10c(c9)c9ccccc9n%10-c9ccccc9)ccc87)cc6c45)cc3)n2)cc1] | 63% |
| 31b | 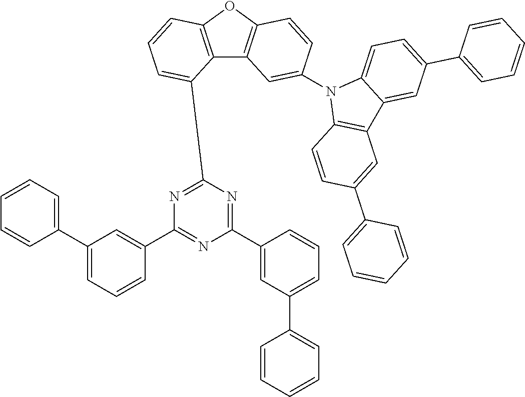 [SMILES: c1ccc(-c2cccc(-c3nc(-c4cccc(-c5ccccc5)c4)nc(-c4cccc5oc6ccc(-n7c8ccc(-c9ccccc9)cc8c8cc(-c9ccccc9)ccc87)cc6c45)n3)c2)cc1] | 72% |
| 32b | 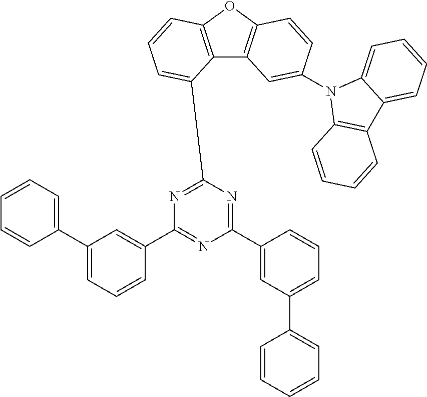 [SMILES: c1ccc(-c2cccc(-c3nc(-c4cccc(-c5ccccc5)c4)nc(-c4cccc5oc6ccc(-n7c8ccccc8c8ccccc87)cc6c45)n3)c2)cc1] | 59% |
| 33b | 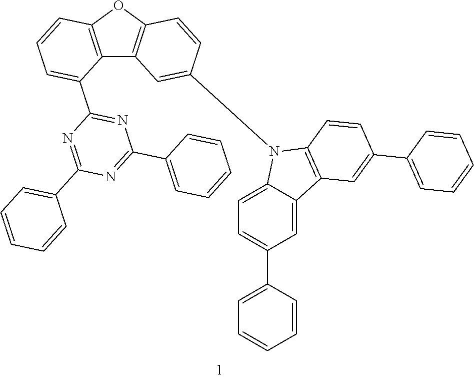 [SMILES: c1ccc(-c2ccc3c(c2)c2cc(-c4ccccc4)ccc2n3-c2ccc3oc4cccc(-c5nc(-c6ccccc6)nc(-c6ccccc6)n5)c4c3c2)cc1] | 56% |
| 34b | 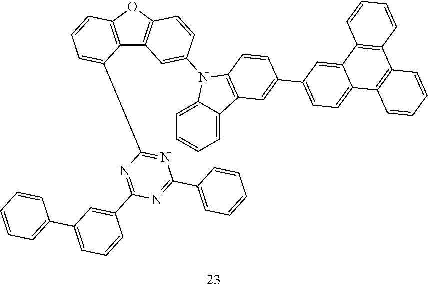 [SMILES: c1ccc(-c2cccc(-c3nc(-c4ccccc4)nc(-c4cccc5oc6ccc(-n7c8ccccc8c8cc(-c9ccc%10c%11ccccc%11c%11ccccc%11c%10c9)ccc87)cc6c45)n3)c2)cc1] | 60% |
| 35b | 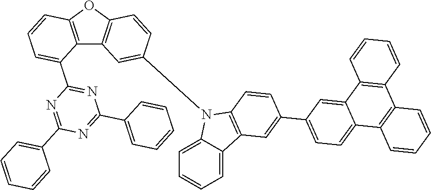 [SMILES: c1ccc(-c2nc(-c3ccccc3)nc(-c3cccc4oc5ccc(-n6c7ccccc7c7cc(-c8ccc9c%10ccccc%10c%10ccccc%10c9c8)ccc76)cc5c34)n2)cc1] | 69% |
| 36b | 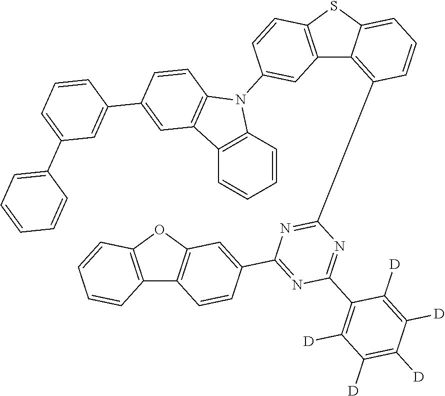 [SMILES: [2H]c1c([2H])c([2H])c(-c2nc(-c3ccc4c(c3)oc3ccccc34)nc(-c3cccc4sc5ccc(-n6c7ccccc7c7cc(-c8cccc(-c9ccccc9)c8)ccc76)cc5c34)n2)c([2H])c1[2H]] | 63% |
| 37b | 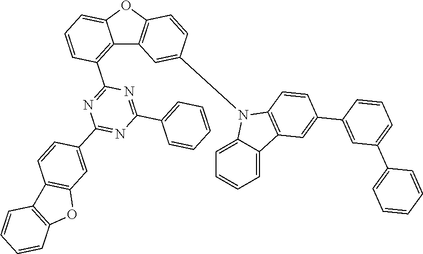 [SMILES: c1ccc(-c2cccc(-c3ccc4c(c3)c3ccccc3n4-c3ccc4oc5cccc(-c6nc(-c7ccccc7)nc(-c7ccc8c(c7)oc7ccccc78)n6)c5c4c3)c2)cc1] | 66% |
| 38b | 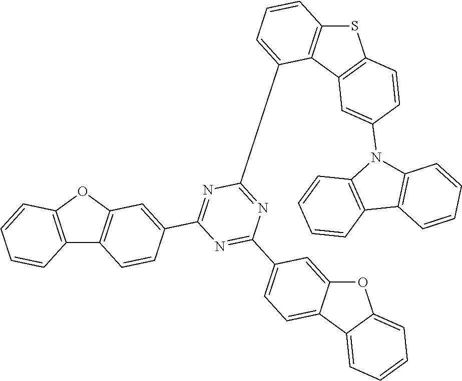 [SMILES: c1ccc2c(c1)oc1cc(-c3nc(-c4ccc5c(c4)oc4ccccc45)nc(-c4cccc5sc6ccc(-n7c8ccccc8c8ccccc87)cc6c45)n3)ccc12] | 70% |
| 39b | 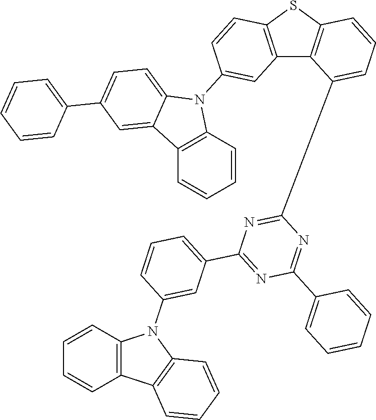 [SMILES: c1ccc(-c2ccc3c(c2)c2ccccc2n3-c2ccc3sc4cccc(-c5nc(-c6ccccc6)nc(-c6cccc(-n7c8ccccc8c8ccccc87)c6)n5)c4c3c2)cc1] | 61% |
| 40b | 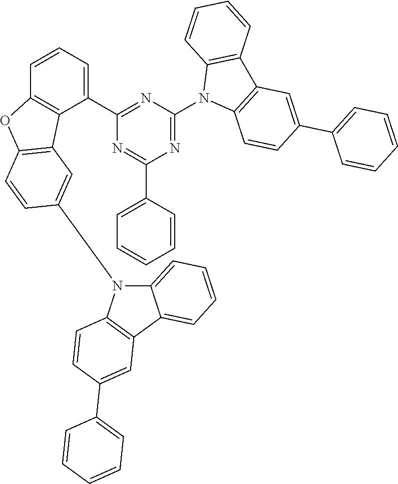 [SMILES: c1ccc(-c2ccc3c(c2)c2ccccc2n3-c2ccc3oc4cccc(-c5nc(-c6ccccc6)nc(-n6c7ccccc7c7cc(-c8ccccc8)ccc76)n5)c4c3c2)cc1] | 77% |
| 41b | 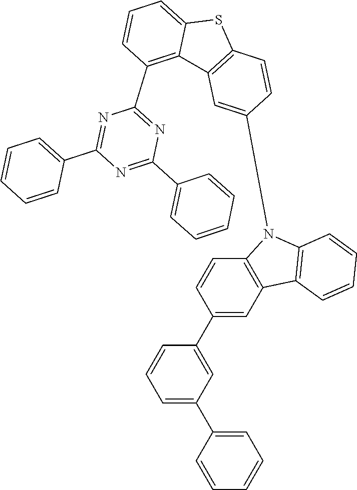 [SMILES: c1ccc(-c2cccc(-c3ccc4c(c3)c3ccccc3n4-c3ccc4sc5cccc(-c6nc(-c7ccccc7)nc(-c7ccccc7)n6)c5c4c3)c2)cc1] | 70% |
| 42b | 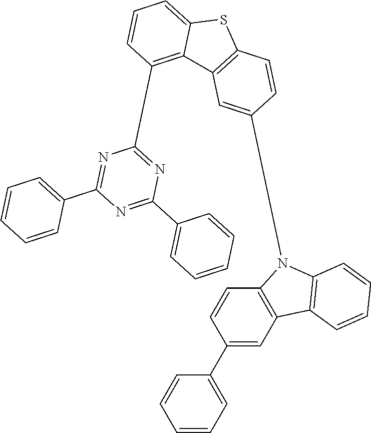 [SMILES: c1ccc(-c2ccc3c(c2)c2ccccc2n3-c2ccc3sc4cccc(-c5nc(-c6ccccc6)nc(-c6ccccc6)n5)c4c3c2)cc1] | 52% |
| 43b | 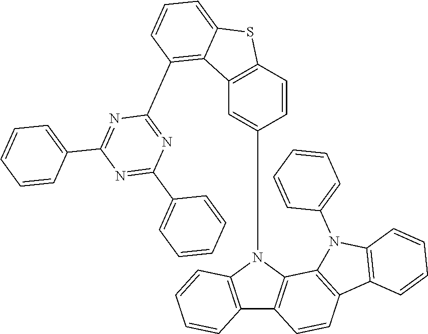 [SMILES: c1ccc(-c2nc(-c3ccccc3)nc(-c3cccc4sc5ccc(-n6c7ccccc7c7ccc8c9ccccc9n(-c9ccccc9)c8c76)cc5c34)n2)cc1] | 46% |
| 44b | 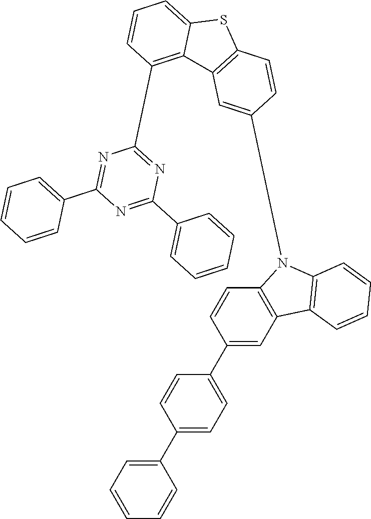 [SMILES: c1ccc(-c2ccc(-c3ccc4c(c3)c3ccccc3n4-c3ccc4sc5cccc(-c6nc(-c7ccccc7)nc(-c7ccccc7)n6)c5c4c3)cc2)cc1] | 55% |

1. Composition comprising at least one compound of the formula (1) and at least one compound of the formula (2) 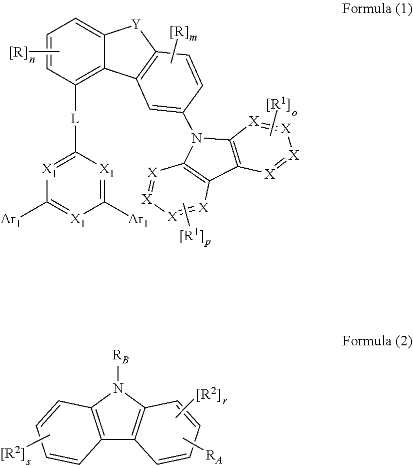
where the symbols and indices used are as follows:
X₁ is the same or different at each instance and is CR⁰ or N, with the proviso that at least one X₁ group is N;
X is the same or different at each instance and is C or N, where two adjacent X may be bonded to a ring system of the formula A, 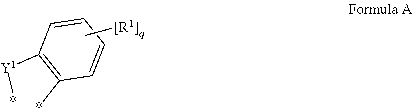
where * at each instance is the bonding site to an X,
Y¹ is selected from NAr₁, C(R*)₂, O and S;
Y is selected from O and S;
L is the same or different at each instance and is a single bond or an aromatic ring system which has 6 to 30 aromatic ring atoms and may be substituted by one or more R⁵ radicals;
n and m at each instance are independently 0, 1, 2 or 3,
o, p and q at each instance are independently 0, 1, 2, 3 or 4;
Ar₁ at each instance is independently an aryl or heteroaryl group which has 5 to 40 aromatic ring atoms and may be substituted by one or more R³ radicals;
R_{A} is H, -L₃-Ar₄ or -L₁-N(Ar)₂;
R_{B} is Ar₃ or -L₂-N(Ar)₂;
L₁, L₂ are the same or different at each instance and are a single bond or an aromatic or heteroaromatic ring system which has 5 to 30 aromatic ring atoms and may be substituted by one or more R³ radicals;
L₃ is a single bond or an aromatic or heteroaromatic ring system which has 5 to 30 aromatic ring atoms and may be substituted by one or more R³ radicals, where one substituent R³ may form a ring with a substituent R² on the carbazole;
Ar₃ is an aromatic ring system having 6 to 40 aromatic ring atoms or a heteroaromatic ring system having 10 to 40 aromatic ring atoms, which may be substituted by one or more R³ radicals;
Ar₄ is the same or different at each instance and is an unsubstituted or substituted 9-arylcarbazolyl or unsubstituted or substituted carbazol-9-yl, which may be substituted by one or more R⁴ radicals, and where one or more instances each of two R⁴ radicals or one R⁴ radical together with one R² radical may independently form a monocyclic or polycyclic, aliphatic, aromatic or heteroaromatic ring, where aryl is an aromatic or heteroaromatic ring system which has 5 to 30 aromatic ring atoms and may be substituted by R³;
R* is the same or different at each instance and is a straight-chain alkyl group having 1 to 10 carbon atoms or an aryl group having 6 to 12 carbon atoms, where two substituents R* together may form a monocyclic or polycyclic, aliphatic, aromatic or heteroaromatic ring system which may be substituted by one or more substituents R⁵;
R⁰, R, R¹, R² are the same or different at each instance and are selected from the group consisting of H, D, F, Cl, Br, I, CN, NO₂, N(Ar)₂, N(R³)₂, C(═O)Ar, C(═O)R³, P(═O)(Ar)₂, P(Ar)₂, B(Ar)₂, Si(Ar)₃, Si(R³)₃, a straight-chain alkyl, alkoxy or thioalkyl group having 1 to 20 carbon atoms or a branched or cyclic alkyl, alkoxy or thioalkyl group having 3 to 20 carbon atoms or an alkenyl group having 2 to 20 carbon atoms, each of which may be substituted by one or more R³ radicals, where one or more nonadjacent CH₂ groups may be replaced by R³C═CR³, Si(R³)₂, C═O, C═S, C═NR³, P(═O)(R³), SO, SO₂, NR³, O, S or CONR³ and where one or more hydrogen atoms may be replaced by D, F, Cl, Br, I, CN or NO₂, an aromatic or heteroaromatic ring system which has 5 to 40 aromatic ring atoms and may be substituted in each case by one or more R³ radicals, an aryloxy or heteroaryloxy group which has 5 to 40 aromatic ring atoms and may be substituted by one or more R³ radicals, or an aralkyl or heteroaralkyl group which has 5 to 40 aromatic ring atoms and may be substituted by one or more R³ radicals; at the same time, it is optionally possible for two substituents R⁰ and/or R and/or R¹ and/or R² bonded to the same carbon atom or to adjacent carbon atoms to form a monocyclic or polycyclic, aliphatic, aromatic or heteroaromatic ring system which may be substituted by one or more R³ radicals;
R³ is the same or different at each instance and is selected from the group consisting of H, D, F, CN, N(Ar)₂, an aliphatic hydrocarbyl radical having 1 to 20 carbon atoms, or an aromatic or heteroaromatic ring system having 5 to 30 aromatic ring atoms in which one or more hydrogen atoms may be replaced by D, F, Cl, Br, I or CN and which may be substituted by one or more alkyl groups each having 1 to 4 carbon atoms; at the same time, it is possible for two or more adjacent R³ substituents together to form a mono- or polycyclic, aliphatic ring system;
R⁴ is the same or different at each instance and is selected from the group consisting of H, D, F, CN, an aliphatic hydrocarbyl radical having 1 to 20 carbon atoms, or an aromatic or heteroaromatic ring system having 5 to 30 aromatic ring atoms in which one or more hydrogen atoms may be replaced by D, F, Cl, Br, I, a straight-chain or branched alkyl group having 1 to 4 carbon atoms or CN; at the same time, two or more adjacent R⁴ substituents together may form a mono- or polycyclic ring system;
R⁵ is the same or different at each instance and is selected from the group consisting of D, F, CN and an aryl group having 6 to 18 carbon atoms; at the same time, two or more adjacent substituents R⁵ together may form a mono- or polycyclic, aliphatic ring system;
Ar is the same or different at each instance and is an aromatic or heteroaromatic ring system which has 5 to 30 aromatic ring atoms and may be substituted by one or more nonaromatic R³ radicals; at the same time, two Ar radicals bonded to the same nitrogen atom, phosphorus atom or boron atom may also be bridged to one another by a single bond or a bridge selected from N(R³), C(R³)₂, O and S, and
r at each instance is independently 0, 1, 2 or 3;
s at each instance is independently 0, 1, 2, 3 or 4.

2. The composition according to claim 1, characterized in that Y in formula (1) is O.

3. The composition according to claim 1, characterized in that the compound of the formula (2) conforms to one of the formulae (2a) to (2d) 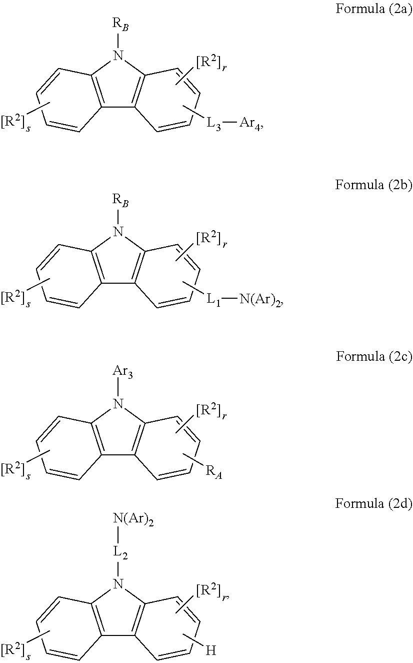
where the symbols and indices L₁, L₂, L₃, Ar, Ar₃, Ar₄, R², r and s used are as defined in claim 1.

4. The composition according to claim 1, wherein the composition comprises at least one further compound selected from the group consisting of hole injection materials, hole transport materials, hole blocker materials, wide band gap materials, fluorescent emitters, phosphorescent emitters, host materials, matrix materials, electron blocker materials, electron transport materials and electron injection materials, n-dopants and p-dopants.

5. The composition according to the claim 1, wherein composition consists of a compound of the formula (1) and a compound of the formula (2).

6. A formulation comprising the composition according to claim 1 and at least one solvent.

7. Use of the composition according to claim 1 in an organic electronic device.

8. Use according to claim 7, characterized in that the organic electronic device is selected from the group of organic integrated circuits (OICs), organic field-effect transistors (OFETs), organic thin-film transistors (OTFTs), organic electroluminescent devices, organic solar cells (OSCs), organic optical detectors and organic photoreceptors.

9. An organic electronic device comprising at least one composition according to claim 1 in at least one organic layer.

10. The device according to claim 9, wherein the device is selected from the group of organic integrated circuits (OICs), organic field-effect transistors (OFETs), organic thin-film transistors (OTFTs), organic electroluminescent devices, organic solar cells (OSCs), organic optical detectors and organic photoreceptors.

11. The device according to claim 9, characterized in that the device is an electroluminescent device selected from the group consisting of organic light-emitting transistors (OLETs), organic field quench devices (OFQDs), organic light-emitting electrochemical cells (OLECs, LECs, LEECs), organic laser diodes (O-lasers) and organic light-emitting diodes (OLEDs).

12. The device according to claim 9, wherein the device comprises the composition in an emission layer (EML), in an electron transport layer (ETL), in an electron injection layer (EIL) and/or in a hole blocker layer (HBL).

13. The device according to claim 11, comprising an anode, a cathode and at least one organic layer containing at least one light emitting layer, characterized in that it contains the composition in the at least one emission layer together with a phosphorescent emitter.

14. A process for producing the device according to claim 9, wherein at least one organic layer comprising composition is applied by gas phase deposition or from solution.

15. The process according to claim 14, characterized in that the at least one compound of the formula (1) and the at least one compound of the formula (2) are deposited from the gas phase successively or simultaneously from at least two material sources, optionally together with further materials, and form the organic layer.

16. The process according to claim 14, characterized in that the composition is utilized as material source for gas phase deposition of the host system and forms the organic layer optionally together with further materials.

17. The process according to claim 14, characterized in that a formulation comprising the composition and the solvent is used in order to apply the organic layer.
